(19) United States
(12) Patent Application Publication
(10) Pub. No.: US 2024/0138170 A1
(43) Pub. Date: Apr. 25, 2024

(54) LIGHT EMITTING ELEMENT AND POLYCYCLIC COMPOUND FOR THE SAME

(71) Applicant: Samsung Display Co., Ltd., Yongin-si (KR)

(72) Inventors: CHANSEOK OH, Yongin-si (KR); SUN YOUNG PAK, Yongin-si (KR); JUNHA PARK, Yongin-si (KR); Kyoung SUNWOO, Yongin-si (KR); MUN-KI SIM, Yongin-si (KR)

(73) Assignee: Samsung Display Co., Ltd., Yongin-si\ (KR)

(21) Appl. No.: 18/350,883

(22) Filed: Jul. 12, 2023

(30) Foreign Application Priority Data
Sep. 16, 2022 (KR) 10-2022-0117369

(51) Int. Cl. H10K 50/11; C09K 11/06; H10K 85/30; H10K 85/60

(52) U.S. Cl. CPC H10K 50/11; C09K 11/06; H10K 85/342; H10K 85/346; H10K 85/658; C07B 2200/05; C09K 2211/185

(57) ABSTRACT

Embodiments provide a light emitting element that includes a first electrode, a second electrode disposed on the first electrode, and an emission layer disposed between the first electrode and the second electrode. The emission layer includes a first compound, and at least one of a second compound or a third compound. The first compound is represented by Formula 1, which is explained in the specification:

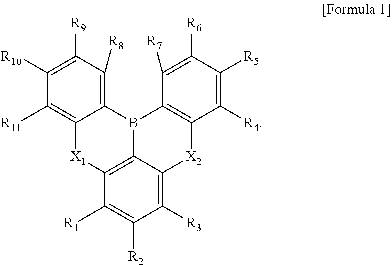

### CROSS-REFERENCE TO RELATED APPLICATION(S)

This application claims priority to and benefits of Korean Patent Application No. 10-2022-0117369 under 35 U.S.C. § 119, filed on Sep. 16, 2022 in the Korean Intellectual Property Office, the entire contents of which are incorporated herein by reference.

### BACKGROUND

### 1. Technical Field

The disclosure relates to a polycyclic compound and a light emitting element including the same.

### 2. Description of the Related Art

Active development continues for an organic electroluminescence display device as an image display device. The organic electroluminescence display device includes a so-called self-luminescent light emitting element in which holes and electrons respectively injected from a first electrode and a second electrode recombine in an emission layer, so that a luminescent material in the emission layer emits light to achieve display.

In the application of a light emitting element to a display device, there is a demand for a light emitting element having low driving voltage, high luminous efficiency, and a long service life, and continuous development is required on materials for a light emitting element that are capable of stably achieving such characteristics.

In order to implement a highly efficient organic electroluminescence device, technologies pertaining to phosphorescence emission using triplet state energy or to delayed fluorescence which uses the phenomenon of the collision of triplet excitons to generate singlet excitons (triplet-triplet annihilation (TTA)) are being developed, and development is currently directed to thermally activated delayed fluorescence (TADF) materials using delayed fluorescence phenomenon.

### SUMMARY

The disclosure provides a light emitting element in which luminous efficiency and an element service life are improved.

The disclosure also provides a polycyclic compound that is capable of improving luminous efficiency and service life of a light emitting element.

An embodiment provides a light emitting element which may include: a first electrode; a second electrode disposed on the first electrode; and an emission layer disposed between the first electrode and the second electrode, wherein the emission layer may include a first compound represented by Formula 1, and at least one of a second compound represented by Formula HT or a third compound represented by Formula ET:

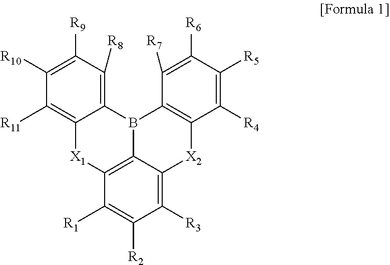

In Formula 1, at least one of X₁ or X₂ may each independently be N(Rₓ₁), the remainder of X₁ or X₂ may be N(Rₓ₂), O, or S; and Rₓ₁ may be a group represented by any one of Formula 2-1 to Formula 2-4. In Formula 1, Rₓ₂ and R₁ to R₁₁ may each independently be a hydrogen atom, a deuterium atom, a halogen atom, a cyano group, a substituted or unsubstituted amine group, a substituted or unsubstituted silyl group, a substituted or unsubstituted alkyl group having 1 to 10 carbon atoms, a substituted or unsubstituted cycloalkyl group having 3 to 10 ring-forming carbon atoms, a substituted or unsubstituted aryl group having 6 to 60 ring-forming carbon atoms, a substituted or unsubstituted heterocycloalkyl group having 2 to 10 ring-forming carbon atoms, or a substituted or unsubstituted heteroaryl group having 2 to 60 ring-forming carbon atoms.

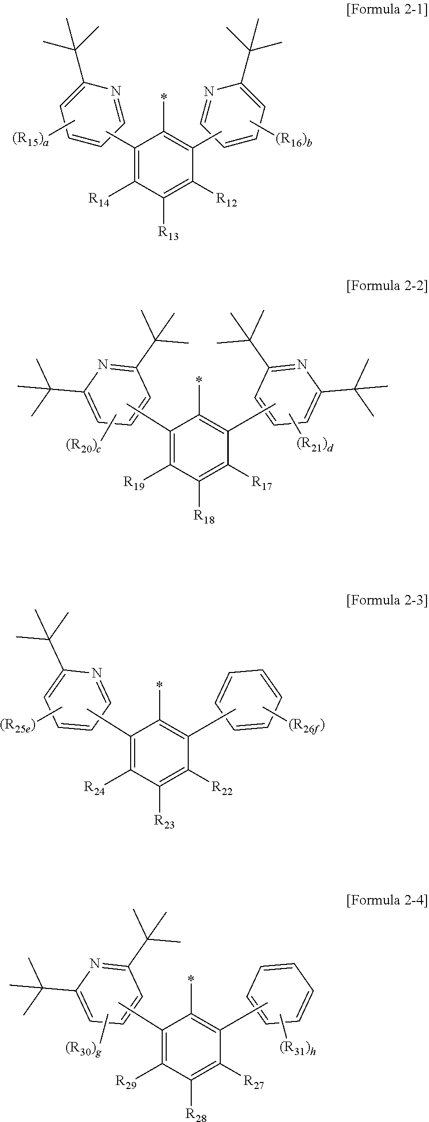

In Formula 2-1 to Formula 2-4, R₁₂ to R₃₁ may each independently be a hydrogen atom, a deuterium atom, a halogen atom, a cyano group, a substituted or unsubstituted amine group, a substituted or unsubstituted silyl group, a substituted or unsubstituted alkyl group having 1 to 10 carbon atoms, a substituted or unsubstituted cycloalkyl group having 3 to 10 ring-forming carbon atoms, a substituted or unsubstituted aryl group having 6 to 60 ring-forming carbon atoms, a substituted or unsubstituted heterocycloalkyl group having 2 to 10 ring-forming carbon atoms, or a substituted or unsubstituted heteroaryl group having 2 to 60 ring-forming carbon atoms. In Formula 2-1 to Formula 2-4, a, b, and e may each independently be an integer from 0 to 3; c, d, and e may each independently be an integer from 0 to 2; and f and h may each independently be an integer from 0 to 4.

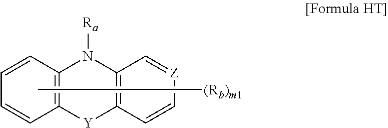

In Formula HT, Rₐ and R_{b} may each independently be a hydrogen atom, a deuterium atom, a cyano group, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. In Formula HT, m1 may be an integer from 0 to 7; Y may be a direct linkage, C(R_{y1})(R_{y2}), or Si(R_{y3})(R_{y4}); and Z may be C(R_{z}) or N. In Formula HT, R_{y1} to R_{y4} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; and R_{z} may be a hydrogen atom or a deuterium atom.

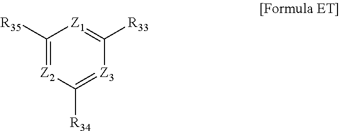

In Formula ET, Z₁ to Z₃ may each independently be N or C(R₃₆); and at least one of Z₁ to Z₃ may each be N. In Formula ET, R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring.

In an embodiment, the emission layer may further include a fourth compound represented by Formula PS:

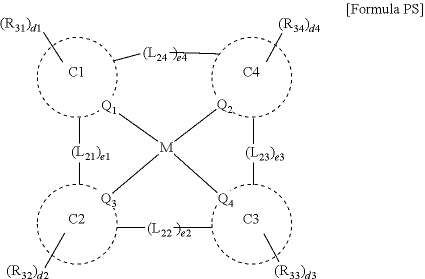

In Formula PS, M may be Pt or Ir; and Q₁ to Q₄ may each independently be C or N. In Formula PS, C1 to C4 may each independently be a substituted or unsubstituted hydrocarbon ring having 5 to 30 ring-forming carbon atoms or a substituted or unsubstituted heterocyclic group having 2 to 30 ring-forming carbon atoms; and e1 to e4 may each independently be 0 or 1. In Formula PS, L₂₁ to L₂₄ may each independently be a direct linkage,

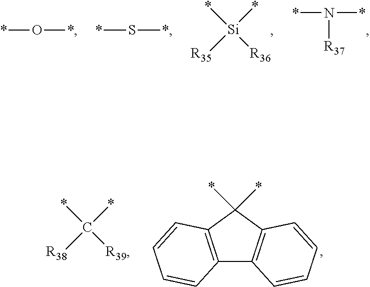

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; and d1 to d4 may each independently be an integer from 0 to 4. In Formula PS, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In an embodiment, the first compound represented by Formula 1 may be represented by Formula 4:

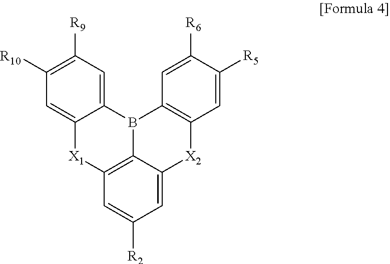

In Formula 4, R₂, R₅, R₆, R₉, R₁₀, X₁, and X₂ may be the same as defined in Formula 1.

In an embodiment, the first compound represented by Formula 4 may be represented by any one of Formula 4-1 to Formula 4-3:

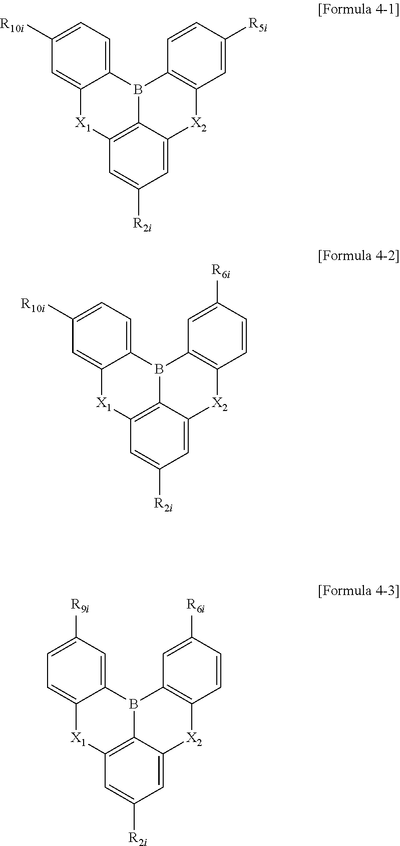

In Formula 4-1 to Formula 4-3, R₂ᵢ, R₅ᵢ, R₆ᵢ, R₉ᵢ, and R₁₀ᵢ may each independently be a hydrogen atom, a deuterium atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms; and X₁ and X₂ may be the same as defined in Formula 1.

In an embodiment, the first compound represented by Formula 1 may be represented by any one of Formula 5-1 to Formula 5-7:

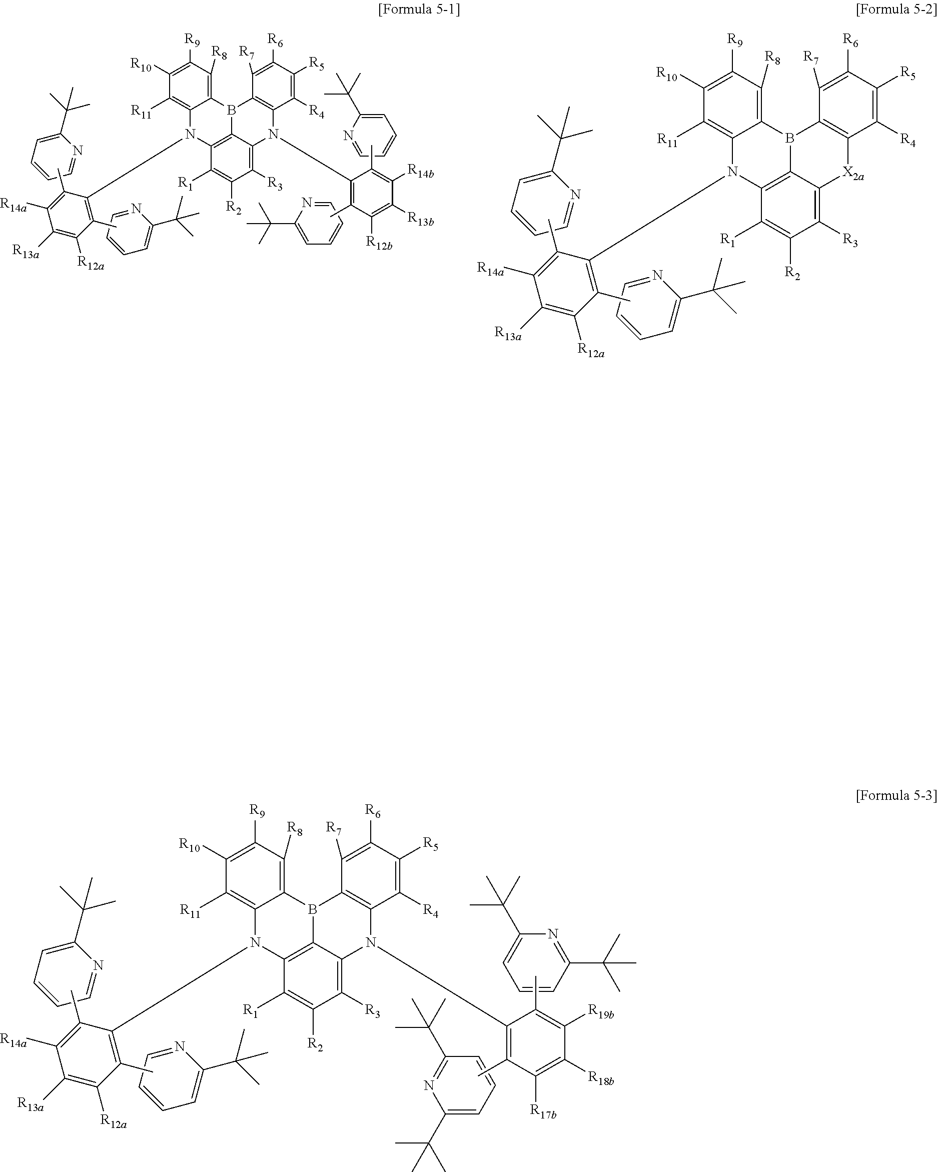

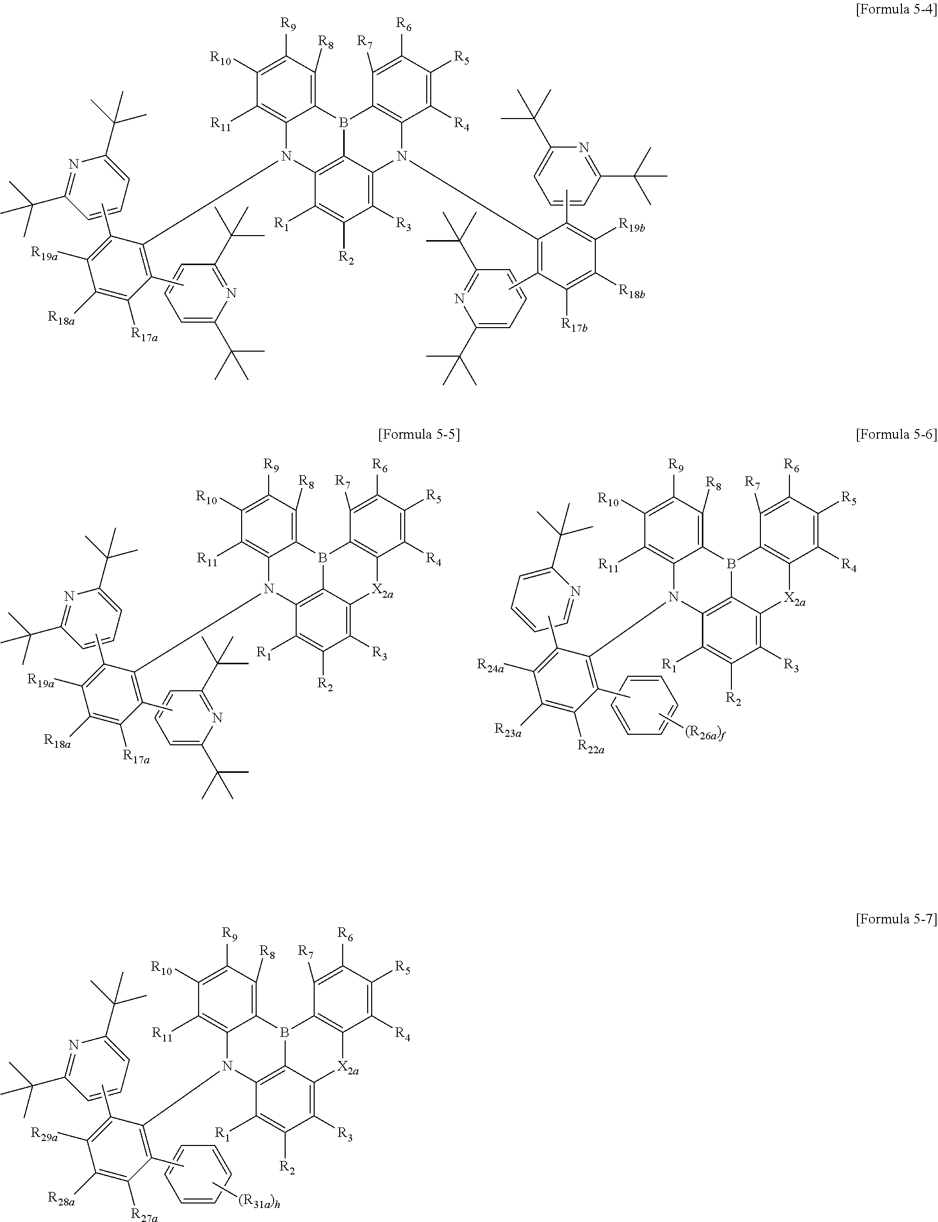

In Formula 5-1 to Formula 5-7, R₁₂ₐ to R₁₄ₐ, R_{12b} to R_{14b}, R₁₇ₐ to R₁₉ₐ, R_{17b} to R_{19b}, R₂₂ₐ to R₂₄ₐ, R₂₆ₐ, R₂₇ₐ to R₂₉ₐ, and R₃₁ₐ may each independently be a hydrogen atom, a deuterium atom, a substituted or unsubstituted alkyl group having 1 to 10 carbon atoms, or a substituted or unsubstituted aryl group having 6 to 60 ring-forming carbon atoms. In Formula 5-1 to Formula 5-7, X₂ₐ may be N(Rₓ₂), O, or S; and f, h, Rₓ₂, and R₁ to R₁₁ may be the same as defined in Formula 1.

In an embodiment, the first compound represented by Formula 1 may be represented by any one of Formula 6-1 to Formula 6-7:

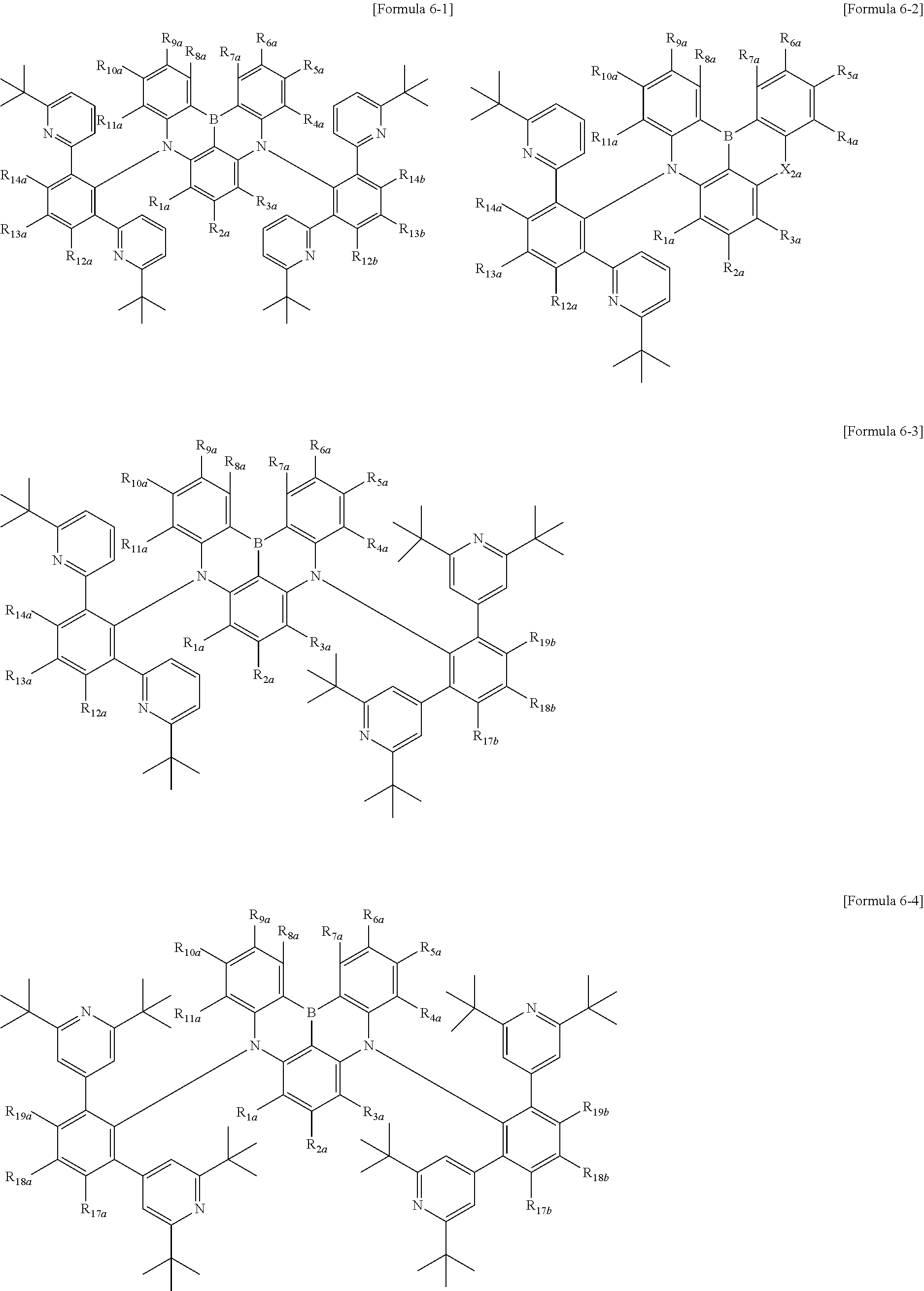

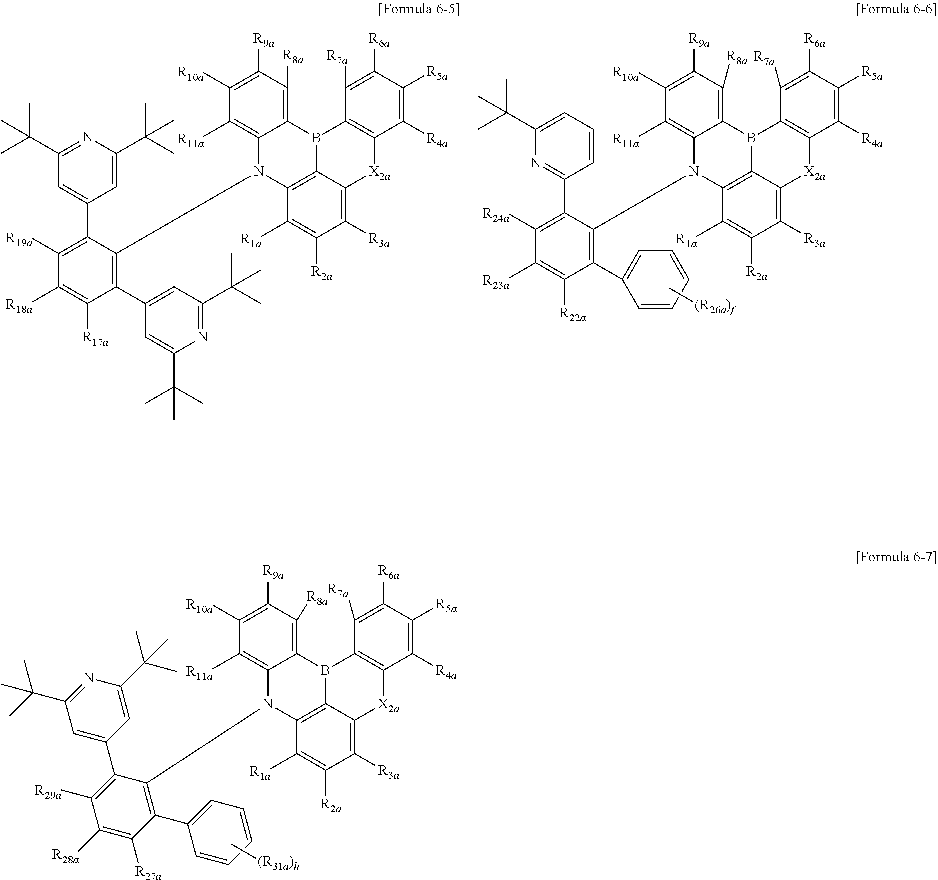

In Formula 6-1 to Formula 6-7, R₁ₐ to R₁₁ₐ may each independently be a hydrogen atom, a deuterium atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms. In Formula 6-1 to Formula 6-7, R₁₂ₐ to R₁₄ₐ, R_{12b} to R₁₄ₑ, R₁₇ₐ to R₁₉ₐ, R_{17b} to R_{19b}, R₂₂ₐ to R₂₄ₐ, R₂₆ₐ, R₂₇ₐ to R₂₉ₐ, and R₃₁ₐ may each independently be a hydrogen atom, a deuterium atom, a substituted or unsubstituted alkyl group having 1 to 10 carbon atoms, or a substituted or unsubstituted aryl group having 6 to 60 ring-forming carbon atoms; X₂ₐ may be N(Rₓ₂), O, or S; and f, h, and Rₓ₂ may be the same as defined in Formula 1.

In an embodiment, the first compound represented by Formula 1 may be represented by any one of Formula 7-1 to Formula 7-7:

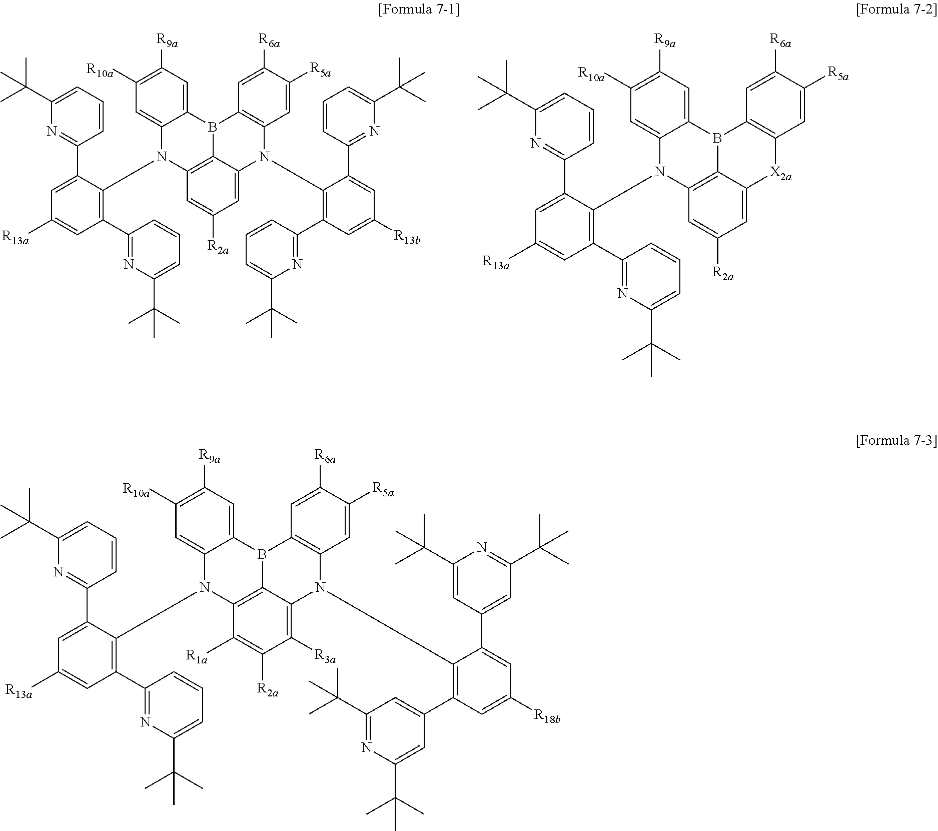

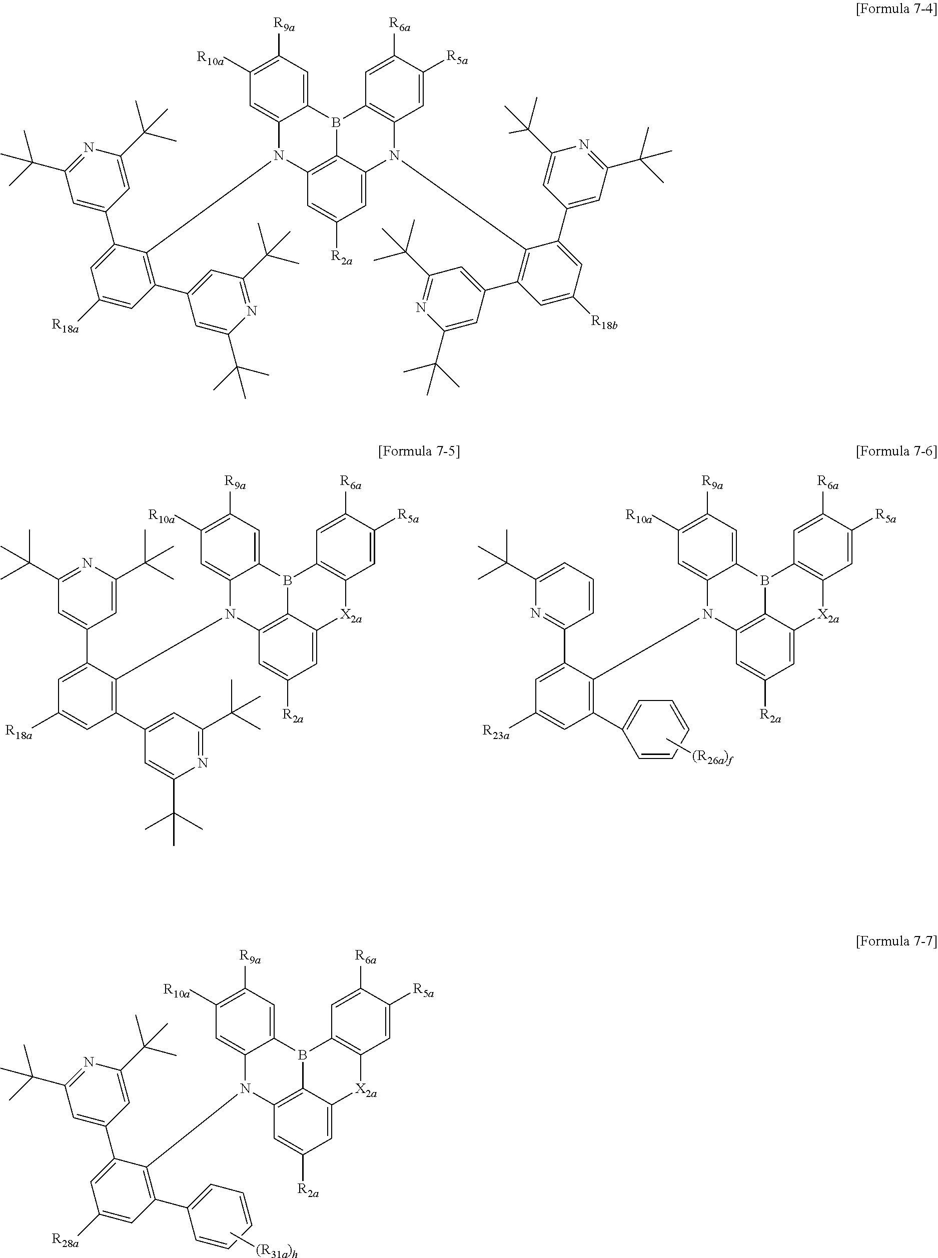

In Formula 7-1 to Formula 7-7, R₂ₐ, Rₛₐ, R₆ₐ, R₉ₐ, and R₁₀ₐ may each independently be a hydrogen atom, a deuterium atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms. In Formula 7-1 to Formula 7-7, R₁₃ₐ, R_{13b}, R₁₈ₐ, R_{18b}, R₂₃ₐ, R₂₆ₐ, R₂₈ₐ, and R₃₁ₐ may each independently be a hydrogen atom, a deuterium atom, a substituted or unsubstituted alkyl group having 1 to 10 carbon atoms, or a substituted or unsubstituted aryl group having 6 to 60 ring-forming carbon atoms; X₂ₐ may be N(Rₓ₂), O, or S; and f, h, and Rₓ₂ may be the same as defined in Formula 1.

In an embodiment, Rₓ₂ may be a substituted or unsubstituted aryl group having 6 to 30 ring-forming carbon atoms.

In an embodiment, R₁₂ to R₃₁ may each independently be a hydrogen atom, a deuterium atom, a substituted or unsubstituted t-butyl group, or a substituted or unsubstituted phenyl group.

In an embodiment, R₁ to R₁₁ may each independently be: a hydrogen atom or a deuterium atom; or a group represented by any one of Formula RS-1 to Formula RS-5:

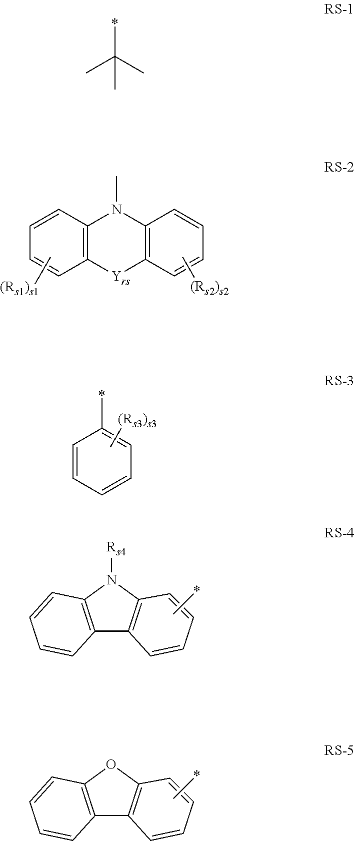

In Formula RS-2, Yᵣₛ may be a direct linkage, or C(Rₛₐ₁)(Rₛₐ₂); Rₛ₁, Rₛ₂, Rₛₐ₁, and Rₛₐ₂ may each independently be a hydrogen atom, a deuterium atom, a cyano group, or a substituted or unsubstituted alkyl group having 1 to 10 carbon atoms, or may be bonded to an adjacent group to form a ring; and s1 and s2 may each independently be an integer from 0 to 4. In Formula RS-3 and Formula RS-4, Rₛ₃ and Rₛ₄ may each independently be a hydrogen atom, a deuterium atom, a substituted or unsubstituted alkyl group having 1 to 10 carbon atoms, or a substituted or unsubstituted aryl group having 6 to 15 ring-forming carbon atoms; and s3 may be an integer from 0 to 5.

In an embodiment, the emission layer may include the first compound, the second compound, and the third compound.

In an embodiment, the emission layer may include the first compound, the second compound, the third compound, and the fourth compound.

In an embodiment, the first compound represented by Formula 1 may include at least one compound selected from Compound Group 1, which is explained below.

An embodiment provides a polycyclic compound may be represented by Formula 1, which is explained herein.

In an embodiment, Formula 2-1 may be represented by Formula 3-1; Formula 2-2 may be represented by Formula 3-2; Formula 2-3 may be represented by Formula 3-3; and Formula 2-4 may be represented by Formula 3-4, wherein Formula 3-1 to Formula 3-4 are explained below.

In an embodiment, Formula 1 may be represented by Formula 4, which is explained herein.

In an embodiment, Formula 4 may be represented by any one of Formula 4-1 to Formula 4-3, which are explained herein.

In an embodiment, Formula 1 may be represented by any one of Formula 5-1 to Formula 5-7, which are explained herein.

In an embodiment, Formula 1 may be represented by any one of Formula 6-1 to Formula 6-7, which are explained herein.

In an embodiment, Formula 1 may be represented by any one of Formula 7-1 to Formula 7-7, which are explained herein.

In an embodiment, the polycyclic compound represented by Formula 1 may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment; and

FIG. 11 is a schematic perspective view of an electronic device including a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is unsubstituted or substituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, an alkenyl group may be a hydrocarbon group that includes at least one carbon-carbon double bond in the middle or a terminus of an alkyl group having 2 or more carbon atoms. An alkenyl group may be linear or branched. The number of carbon atoms in an alkenyl group is not specifically limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or a terminus of an alkyl group having 2 or more carbon atoms. An alkynyl group may be linear or branched. Although the number of carbon atoms in an alkynyl group is not specifically limited, it may be 2 to 30, 2 to 20, or 2 to 10. Examples of an alkynyl group may include an ethynyl group, a propynyl group, etc., without limitation.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. The aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group are as follows. However, embodiments are not limited thereto.

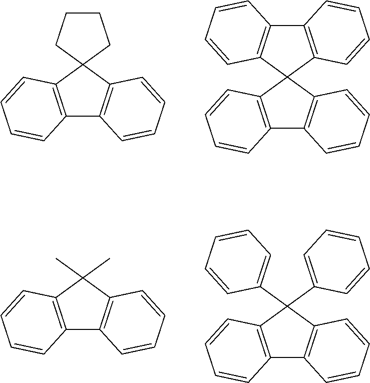

In the specification, a heterocyclic group may be any functional group or substituent derived from a ring containing at least one of B, O, N, P, Si, S, or Se as a heteroatom. A heterocyclic group may be an aliphatic heterocyclic group or an aromatic heterocyclic group. An aromatic heterocyclic group may be a heteroaryl group. An aliphatic heterocycle and an aromatic heterocycle may each independently be monocyclic or polycyclic. If a heterocyclic group includes two or more heteroatoms, the two or more heteroatoms may be the same as or different from each other.

In the specification, an aliphatic heterocyclic group may include at least one of B, O, N, P, Si, or S as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, or S as a heteroatom. When a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. The above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in an amino group is not specifically limited, but may be 1 to 30. The amino group may be an alkyl amino group, an aryl amino group, or a heteroaryl amino group. Examples of an amino group may include a methylamino group, a dimethylamino group, a phenylamino group, a diphenylamino group, a naphthylamino group, a 9-methyl-anthracenylamino group, a triphenylamino group, etc., but are not limited thereto.

In the specification, the number of carbon atoms in a carbonyl group is not specifically limited, but may be 1 to 40, 1 to 30, or 1 to 20. For example, a carbonyl group may have one of the following structures, but embodiments are not limited thereto.

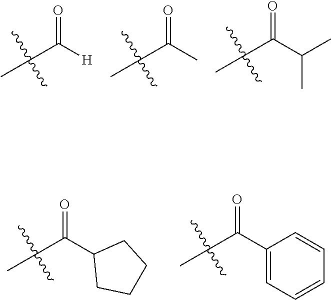

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not specifically limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not specifically limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, etc., but embodiments are not limited thereto.

In the specification, the alkyl group in an alkylthio group, an alkylsulfoxy group, an alkylaryl group, an alkylamino group, an alkyl boron group, an alkyl silyl group, or an alkyl amine group may be the same as an example of the alkyl group as described above.

In the specification, the aryl group in an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

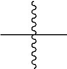

In the specification, the symbols and -* each represent a bonding position to a neighboring atom.

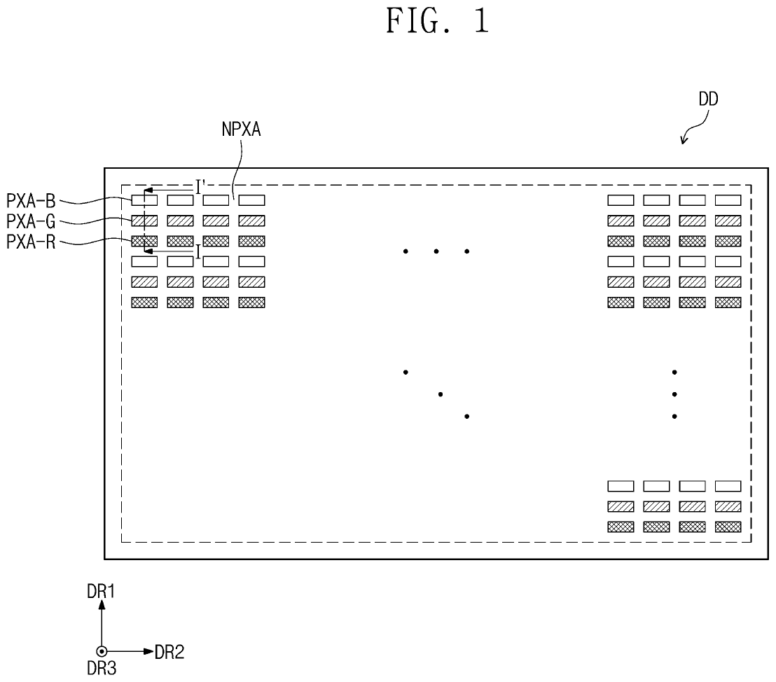

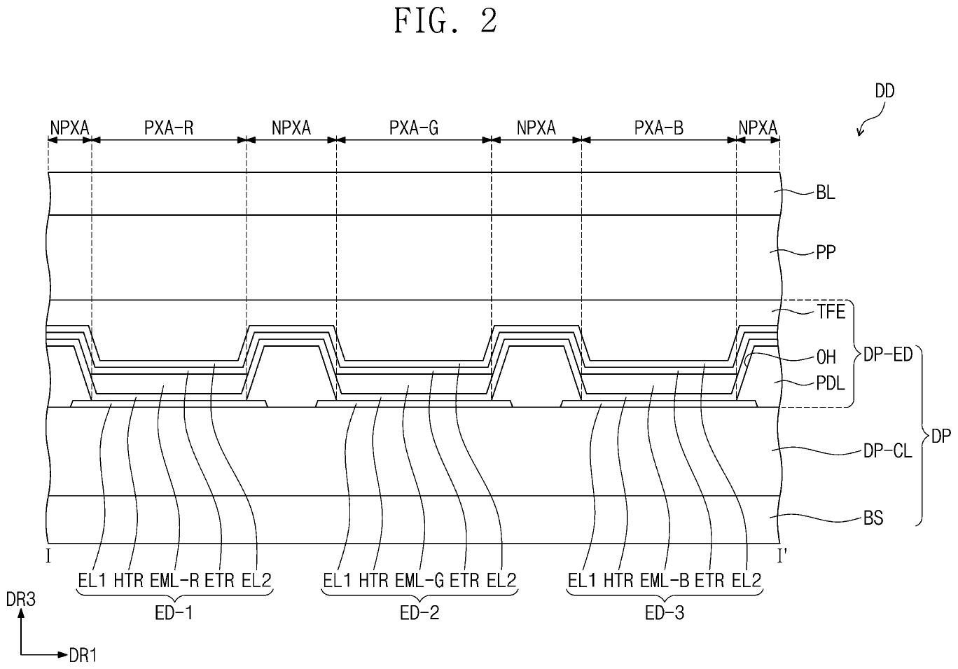

FIG. 1 is a schematic plan view of an embodiment of a display device DD. FIG. 2 is a schematic cross-sectional view of the display device DD according to an embodiment. FIG. 2 is a schematic cross-sectional view illustrating a part taken along line I-I′ of FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP and may control light reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

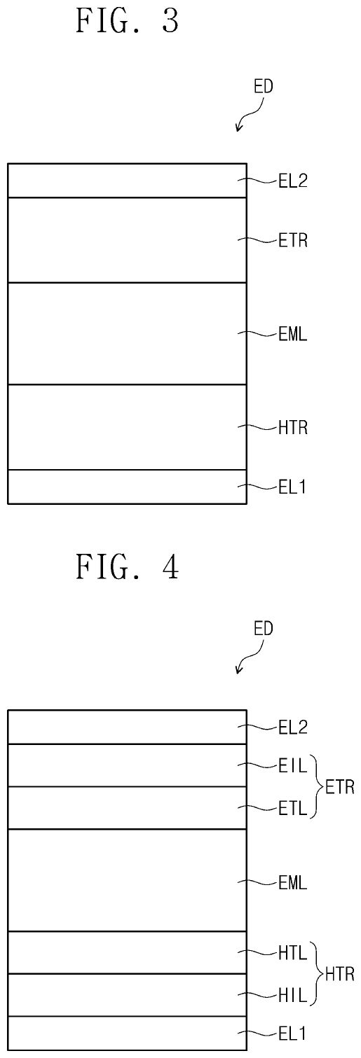

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and a hole transport region HTR, an electron transport region ETR, and a second electrode EL2 are each provided as a common layer for the light emitting elements ED-1, ED-2, and ED-3. However, embodiments are not limited thereto. Although not shown in FIG. 2, in an embodiment, the hole transport region HTR and the electron transport region ETR may each be provided by being patterned inside the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may each be provided by being patterned by an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed of a single layer or of multiple layers. The encapsulation layer TFE may include at least one insulation layer. In an embodiment, the encapsulation layer TFE according to an embodiment may include at least one inorganic film (hereinafter, an encapsulation-inorganic film). In another embodiment, the encapsulation layer TFE may include at least one organic film (hereinafter, an encapsulation-organic film) and at least one encapsulation-inorganic film.

The encapsulation-inorganic film may protect the display element layer DP-ED from moisture and/or oxygen, and the encapsulation-organic film may protect the display element layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region which emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting areas NPXA may be areas between adjacent light emitting areas PXA-R, PXA-G, and PXA-B, and which may correspond to the pixel defining film PDL. For example, in an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated. For example, the display device DD may include a red light emitting region PXA-R, a green light emitting region PXA-G, and a blue light emitting region PXA-B that are separated from each other.

In the display device DD according to an embodiment, the light emitting elements ED-1, ED-2, and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may each emit light in a same wavelength range, or at least one light emitting element may emit light in a wavelength range that is different from the others. For example, the first to third light emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be alternately arranged in this order along a first directional axis DR1.

FIGS. 1 and 2 illustrate that the light emitting regions PXA-R, PXA-G, and PXA-B each have a similar area, but embodiments are not limited thereto. In an embodiment, the light emitting regions PXA-R, PXA-G, and PXA-B may have different areas from each other, according to a wavelength range of emitted light. For example, the areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics which are required for the display device DD. For example, the light emitting regions PXA-R, PXA-G, and PXA-B may be provided in a pentile configuration (such as a PENTILE® configuration) or in a diamond configuration (such as a Diamond Pixel™ configuration).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

In the display device DD according to an embodiment illustrated in FIG. 2, at least one of the first to third light emitting elements ED-1, ED-2, and ED-3 may include a polycyclic compound according to an embodiment, which will be described below.

Hereinafter, FIGS. 3 to 6 are each a schematic cross-sectional view ofa light emitting element according to an embodiment. The light emitting element ED according to embodiments may each include a first electrode EL1, a second electrode EL2 facing the first electrode EL1, and at least one functional layer disposed between the first electrode EL1 and the second electrode EL2. The light emitting element ED may include a polycyclic compound according to an embodiment, which will be described below, in at least one functional layer. In the specification, the polycyclic compound according to an embodiment may be referred to as a first compound.

The light emitting elements ED may each include, as the at least one functional layer, a hole transport region HTR, an emission layer EML, and an electron transport region ETR, which may be stacked in that order. Referring to FIG. 3, the light emitting element ED may include a first electrode EL1, a hole transport region HTR, an emission layer EML, an electron transport region ETR, and a second electrode EL2, which are stacked in that order. The light emitting element ED according to an embodiment may include the polycyclic compound according to an embodiment, which will be described below, in the emission layer EML.

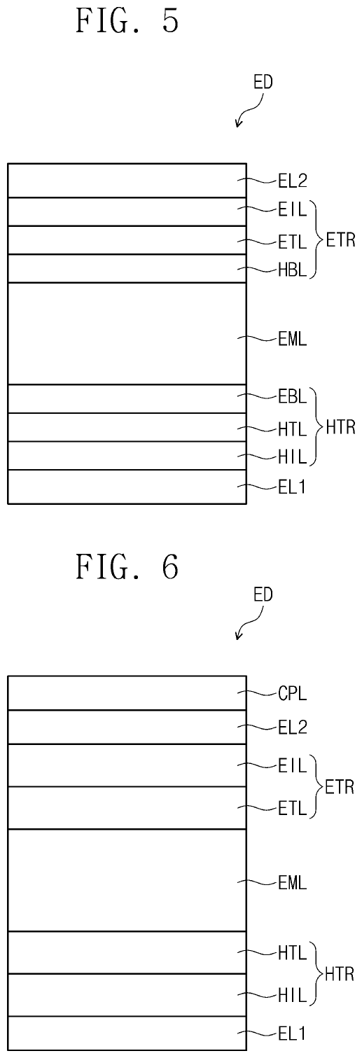

In comparison to FIG. 3, FIG. 4 illustrates a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 illustrates a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 illustrates a schematic cross-sectional view of a light emitting element ED according to an embodiment that includes a capping layer CPL disposed on a second electrode EL2.

In the light emitting element ED according to an embodiment, the first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, a compound thereof, a mixture thereof, or an oxide thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. The first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR is provided on the first electrode EL1. The hole transport region HTR may be a layer consisting of a single material, a layer including different materials, or a structure including multiple layers including different materials.

The hole transport region HTR may include at least one of a hole injection layer HIL, a hole transport layer HTL, a buffer layer (not shown), an emission-auxiliary layer (not shown), or an electron blocking layer EBL. Although not shown in the drawings, in an embodiment, the hole transport region HTR may include multiple hole transport layers.

In embodiments, the hole transport region HTR may have a single layer structure of the hole injection layer HIL or the hole transport layer HTL, or may have a single layer structure formed of a hole injection material and a hole transport material. In an embodiment, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), or a hole transport layer HTL/buffer layer (not shown) are stacked in its respective stated order from the first electrode EL1, but embodiments are not limited thereto.

A thickness of the hole transport region HTR may be, for example, in a range of about 50 Å to about 15,000 Å. The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

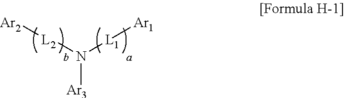

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups and multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In yet another embodiment, the compound represented by Formula H-1 may be a carbazole-based compound in which at least one of Ar₁ or Ar₂ includes a substituted or unsubstituted carbazole group, or may be a fluorene-based compound in which at least one of Ar₁ or Ar₂ includes a substituted or unsubstituted fluorene group.

The compound represented by Formula H-1 may be any compound selected from Compound Group H. However, the compounds listed in Compound Group H are only examples, and the compounds represented by Formula H-1 are not limited to Compound Group H:

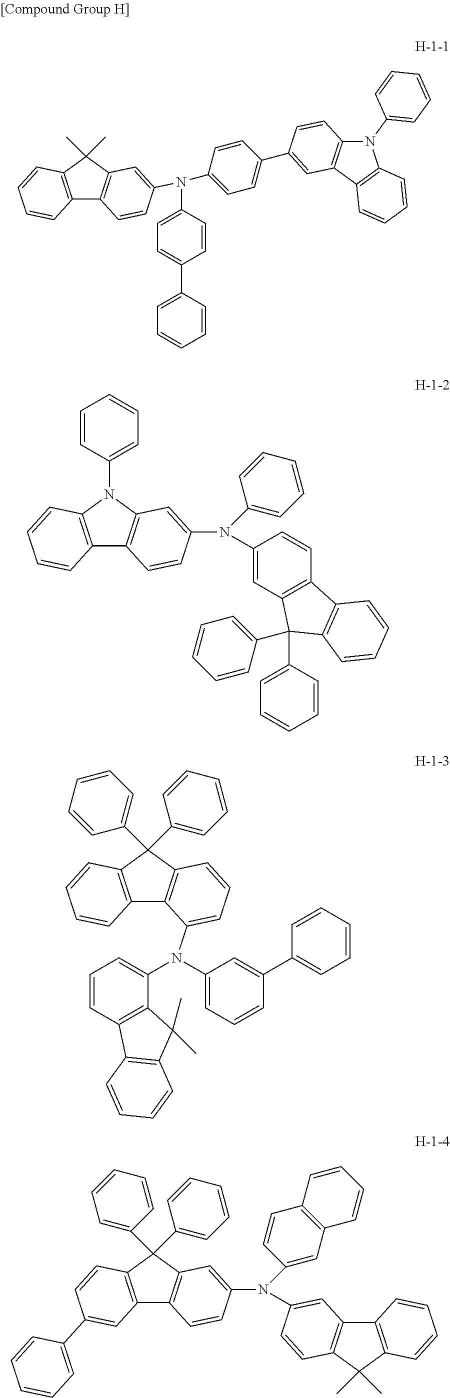 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

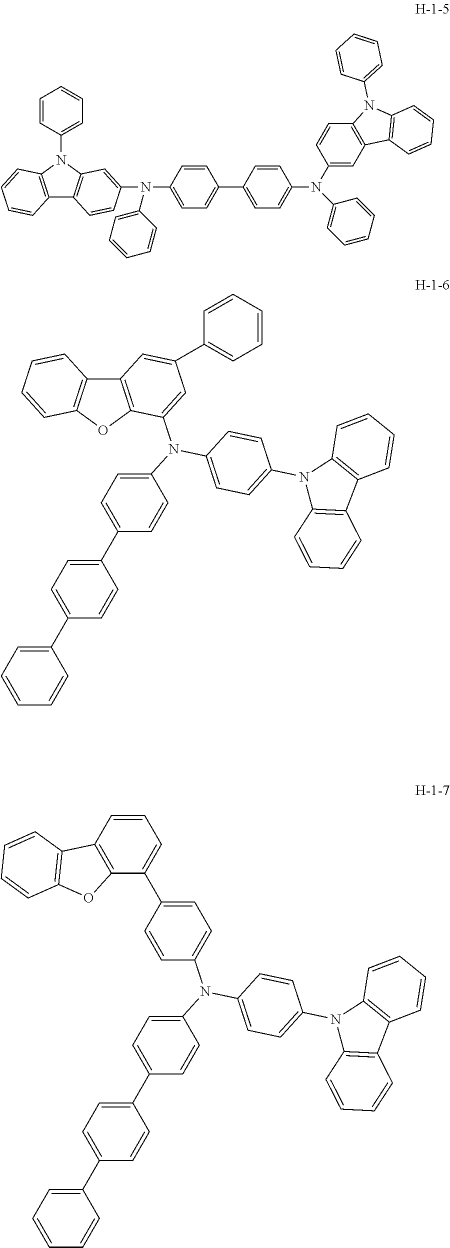 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

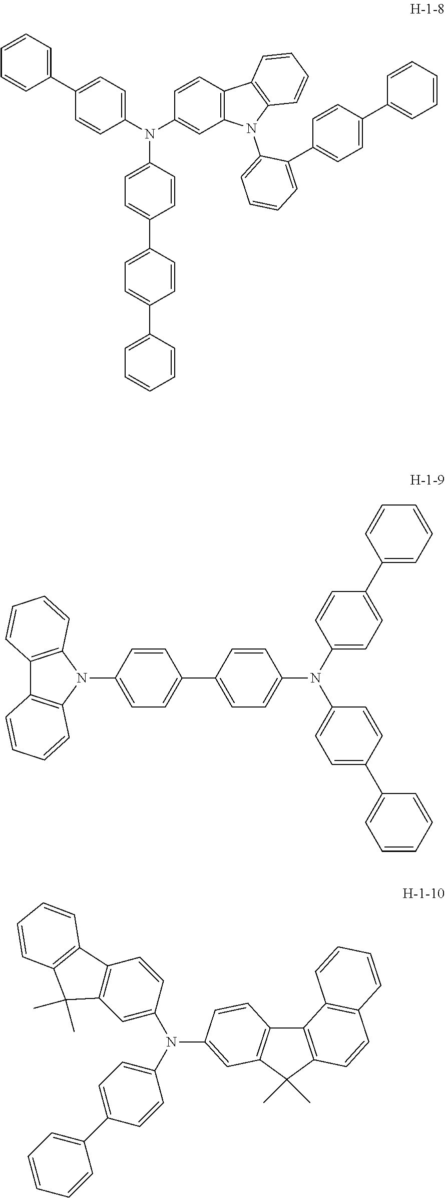 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

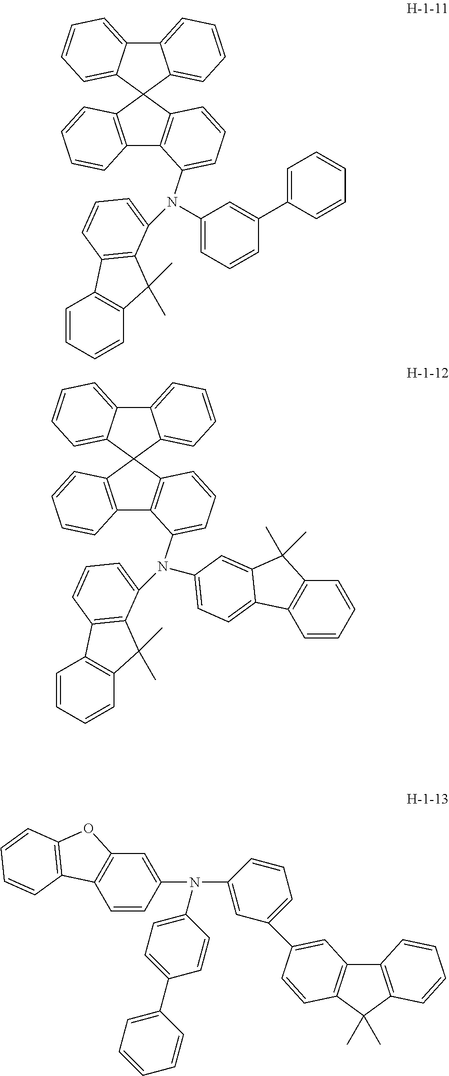

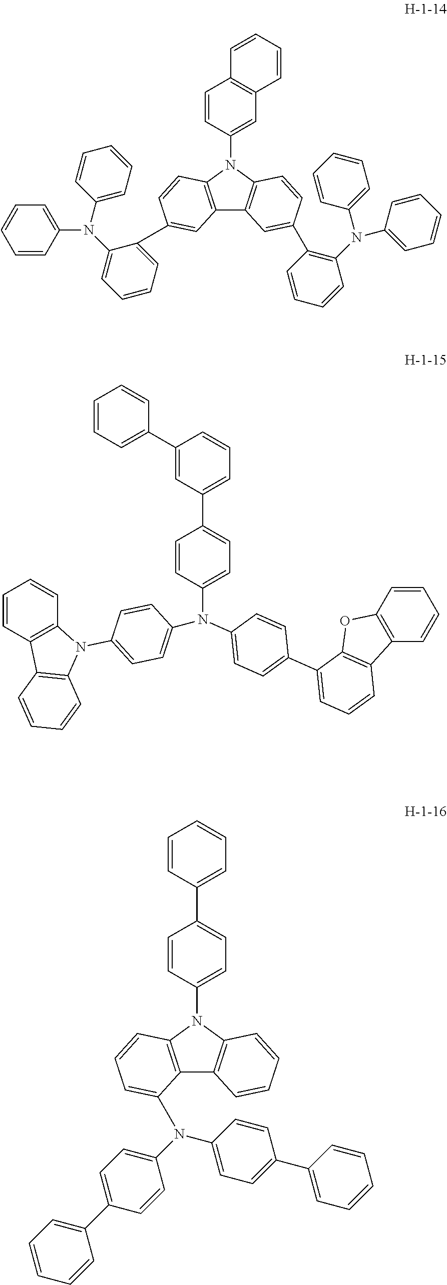 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

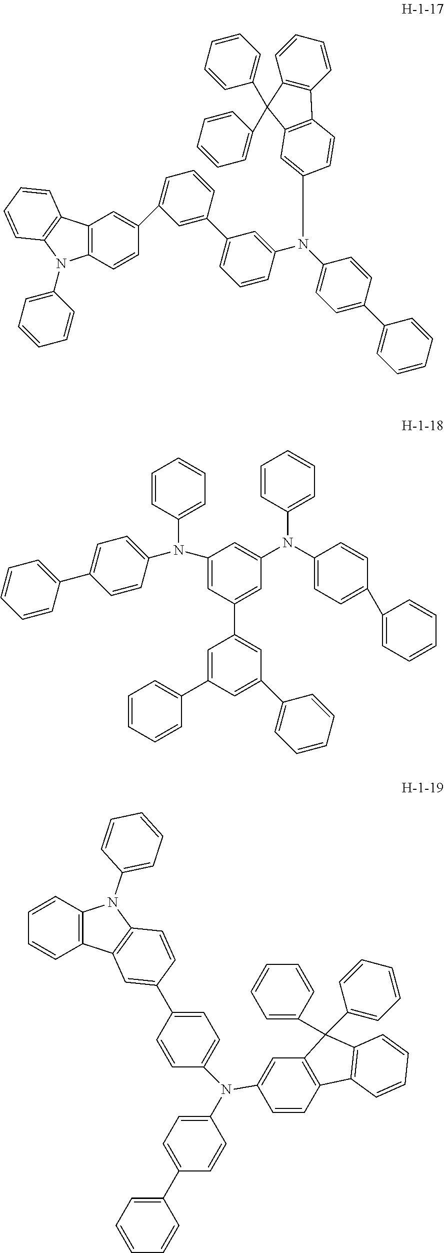 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may further include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(1-naphthyl)-N-phenylamino]-triphenylamine (1-TNATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB or NPD of α-NPD), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenyl amine-based derivative such as 4,4′,4″-tris(N-carbazolyl)triphenylamine (TCTA), or N,N′-bis(3-methylphenyl)-N,N′-diphenyl-[1,1′-biphenyl]-4,4′-diamine (TPD), N,N′-di(naphthalene-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have, for example, a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 A. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7, 8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown), an emission-auxiliary layer (not shown), or an electron blocking layer EBL, in addition to the hole injection layer HIL and the hole transport layer HTL. The buffer layer (not shown) may compensate for a resonance distance according to a wavelength of light emitted from the emission layer EML and may thus increase light emission efficiency. A material that may be included in the hole transport region HTR may be used as a material in the buffer layer (not shown). The electron blocking layer EBL may prevent electron injection from an electron transport region ETR to the hole transport region HTR. The emission-auxiliary layer (not shown) may improve charge balance between holes and electrons. When the hole transport region HTR includes an electron blocking layer EBL, the electron blocking layer EBL may include the function of the emission-auxiliary layer.

The emission layer EML is provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

In the light emitting element ED according to an embodiment, the emission layer EML may include a first compound. The first compound corresponds to the polycyclic compound according to an embodiment. The polycyclic compound may include a fused ring core that includes a boron atom (B) and two heteroatoms as ring-forming atoms. In the polycyclic compound, the fused ring core may be a structure in which first to third aromatic rings are fused via the boron atom and the two heteroatoms. The first to third aromatic rings may each independently be substituted or unsubstituted benzene rings.

In the polycyclic compound, at least one of the two heteroatoms in the fused ring core is a nitrogen atom (N), and the remainder thereof may be an oxygen atom (O) or a sulfur atom (S). The polycyclic compound may include a pyridine unit that is linked to at least one nitrogen atom of the fused ring core. The pyridine unit may include a first pyridine unit and a second pyridine unit. The first pyridine unit may be a 2-tert-butylpyridine group that is linked to a nitrogen atom of the fused ring core by using a substituted or unsubstituted benzene ring as a linker. The second pyridine unit may be a 2,6-di-tert-butylpyridine group that is linked to a nitrogen atom of the fused ring core by using a substituted or unsubstituted benzene ring as a linker. The polycyclic compound may include at least one first pyridine unit or at least one second pyridine unit.

The polycyclic compound may include at least one of a first substituent in which two first pyridine units are bonded to a benzene ring linker, a second substituent in which two second pyridine units are bonded to a benzene ring linker, a third substituent in which one first pyridine unit is bonded to a benzene ring linker, or a fourth substituent in which one second pyridine unit is bonded to a benzene ring linker. The first pyridine unit and the second pyridine unit may each be linked an at ortho position to a nitrogen atom of the fused ring core.

The polycyclic compound according to an embodiment may be represented by Formula 1:

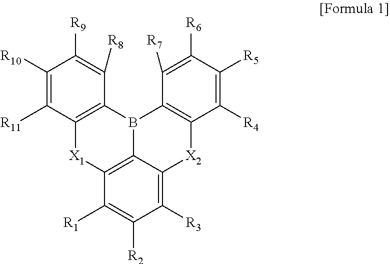

In Formula 1, at least one of X₁ or X₂ may each independently be N(Rₓ₁); and the remainder of X₁ or X₂ may each independently be N(Rₓ₂), O or S. For example, any one of X₁ and X₂ may be N(Rₓ₁), and the other may be N(Rₓ₂), O or S. As another example, X₁ and X₂ may each independently be N(Rₓ₁). When X₁ and X₂ are each N(Rₓ₁), the two Rₓ₁ groups may be the same as or different from each other.

In an embodiment, Rₓ₁ may be a group represented by any one of Formula 2-1 to Formula 2-4. Formula 2-1 to Formula 2-4 may respectively correspond to the first substituent to the fourth substituent. The polycyclic compound may include any one of the first substituent to the fourth substituent, or two first substituents, two second substituents, two third substituents, or two fourth substituents. In an embodiment, the polycyclic compound may include any two of the first to fourth substituents, and two selected substituents may be different from each other. For example, the polycyclic compound may include one of the first substituent and one of the second substituent.

In Formula 1, Rₓ₂ and R₁ to R₁₁ may each independently be a hydrogen atom, a deuterium atom, a halogen atom, a cyano group, a substituted or unsubstituted amine group, a substituted or unsubstituted silyl group, a substituted or unsubstituted alkyl group having 1 to 10 carbon atoms, a substituted or unsubstituted cycloalkyl group having 3 to 10 ring-forming carbon atoms, a substituted or unsubstituted aryl group having 6 to 60 ring-forming carbon atoms, a substituted or unsubstituted heterocycloalkyl group having 2 to 10 ring-forming carbon atoms, or a substituted or unsubstituted heteroaryl group having 2 to 60 ring-forming carbon atoms.

In an embodiment, Rₓ₂ may be a substituted or unsubstituted aryl group having 6 to 30 ring-forming carbon atoms. For example, Rₓ₂ may be a substituted or unsubstituted phenyl group, a substituted or unsubstituted biphenyl group, or a substituted or unsubstituted terphenyl group. When Rₓ₂ is substituted, Rₓ₂ may be substituted with a t-butyl group, a phenyl group, etc.

In an embodiment, R₁ to R₁₁ may each independently be a hydrogen atom, a deuterium atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms. In an embodiment, R₁ to R₁₁ may each independently be: a hydrogen atom or a deuterium atom; or a group represented by any one of Formula RS-1 to Formula RS-5:

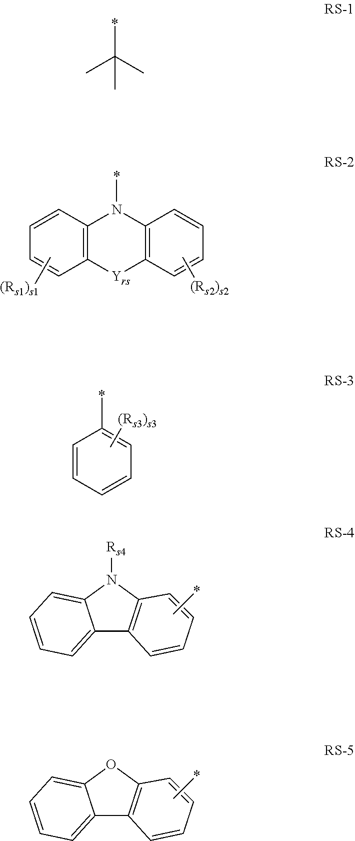

In Formula RS-2, Yᵣₛ may be a direct linkage or C(Rₛₐ₁)(Rₛₐ₂). When Yᵣₛ is a direct linkage, Formula RS-2 may include a substituted or unsubstituted carbazole group. When Yᵣₛ is C(Rₛₐ₁)(Rₛₐ₂), Formula RS-2 may include a substituted or unsubstituted dihydroacridine group.

In Formula RS-2, Rₛ₁, Rₛ₂, Rₛₐ₁, and Rₛₐ₂ may each independently be a hydrogen atom, a deuterium atom, a cyano group, or a substituted or unsubstituted alkyl group having 1 to 10 carbon atoms, or may be bonded to an adjacent group to form a ring. For example, Rₛ₁ and Rₛ₂ may each independently be a hydrogen atom, a deuterium atom, a cyano group, or a substituted or unsubstituted t-butyl group. In an embodiment, when Formula RS-2 includes multiple groups of Rₛ₁ of Rₛ₂, two adjacent Rₛ₁ groups may be bonded to each other to form a heterocycle, or two adjacent two Rₛ₂ groups may be bonded to each other to form a heterocycle. For example, Rₛₐ₁ and Rₛₐ₂ may each independently be a substituted or unsubstituted phenyl group, or Rₛₐ₁ and Rₛₐ₂ may be bonded to each other to form a hydrocarbon ring.

In Formula RS-2, s1 and s2 may each independently be an integer from 0 to 4. When s1 and s2 are each 2 or more, multiple groups of Rₛ₁ and multiple groups of Rₛ₂ may all be the same or at least one group thereof may be different from the remainder. For example, s1 and s2 may each independently be 0, 1, or 4. In an embodiment, a case where s1 is 0 may be the same as a case where s1 is 4 and Rₛ₁ groups are all hydrogen atoms. It may be understood that when s1 is 0, Formula RS-2 does not include Rₛ₁. A case where s2 is 0 may be the same as a case where s2 is 4 and Rₛ₂ groups are all hydrogen atoms. It may be understood that when s2 is 0, Formula RS-2 does not include Rₛ₂.

In Formula RS-3 and Formula RS-4, Rₛ₃ and Rₛ₄ may each independently be a hydrogen atom, a deuterium atom, a substituted or unsubstituted alkyl group having 1 to 10 carbon atoms, or a substituted or unsubstituted aryl group having 6 to 15 ring-forming carbon atoms. For example, Rₛ₃ may be a hydrogen atom, a deuterium atom, or a substituted or unsubstituted t-butyl group, and Rₛ₄ may be a substituted or unsubstituted phenyl group.

In Formula RS-3, s3 may be an integer from 0 to 5. When s3 is 2 or greater, multiple Rₛ₃ groups may all be the same or at least one group thereof may be different from the remainder. In an embodiment, a case where s3 is 0 may be the same as a case where s3 is 5 and Rₛ₃ groups are all hydrogen atoms. It may be understood that when s3 is 0, Formula RS-3 does not include Rₛ₃.

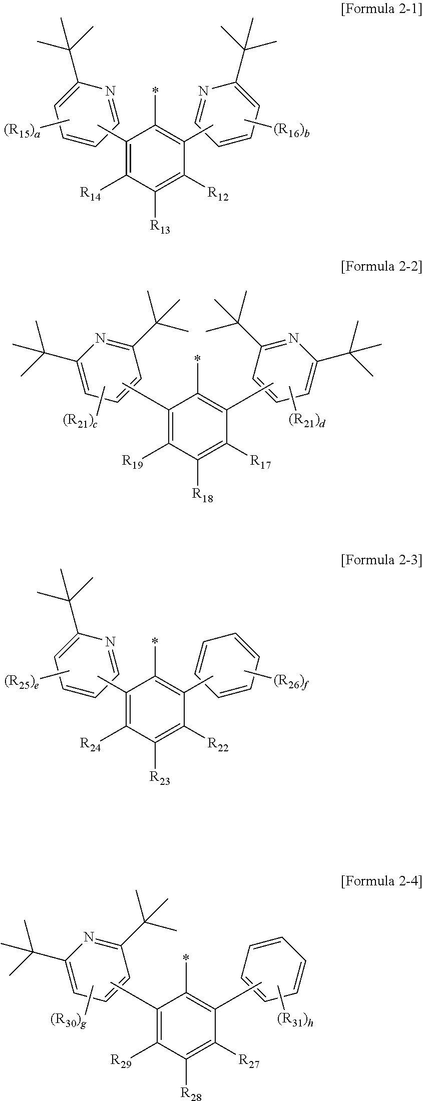

In Formula 2-1 to Formula 2-4, R₁₂ to R₃₁ may each independently be a hydrogen atom, a deuterium atom, a halogen atom, a cyano group, a substituted or unsubstituted amine group, a substituted or unsubstituted silyl group, a substituted or unsubstituted alkyl group having 1 to 10 carbon atoms, a substituted or unsubstituted cycloalkyl group having 3 to 10 ring-forming carbon atoms, a substituted or unsubstituted aryl group having 6 to 60 ring-forming carbon atoms, a substituted or unsubstituted heterocycloalkyl group having 2 to 10 ring-forming carbon atoms, or a substituted or unsubstituted heteroaryl group having 2 to 60 ring-forming carbon atoms.

For example, R₁₂ to R₃₁ may each independently be a hydrogen atom, a deuterium atom, a substituted or unsubstituted alkyl group having 1 to 10 carbon atoms, or a substituted or unsubstituted aryl group having 6 to 60 ring-forming carbon atoms. In an embodiment, R₁₂ to R₃₁ may each independently be a hydrogen atom, a deuterium atom, a substituted or unsubstituted t-butyl group, or a substituted or unsubstituted phenyl group. In Formula 2-1 to Formula 2-4, * represents a position linked to Formula 1.

In Formula 2-1 and Formula 2-3, a, b, and e may each independently be an integer from 0 to 3. When a, b, and e are each 2 or greater, multiple groups of each of R₁₅, R₁₆, and R₂₅ may be the same, or at least one group thereof may be different from the remainder. A case where a is 0 may be the same as a case where a is 3 and three R₁₅ groups are all hydrogen atoms. It may be understood that when a is 0, R₁₅ is not substituted at Formula 2-1. A case where b is 0 may be the same as a case where b is 3 and three R₁₆ groups are all hydrogen atoms. It may be understood that when b is 0, R₁₆ is not substituted at Formula 2-1. A case where e is 0 may be the same as a case where e is 3 and three R₂₅ groups are all hydrogen atoms. It may be understood that when e is 0, R₂₅ is not substituted at Formula 2-3.

In Formula 2-2 and Formula 2-4, c, d, and g may each independently be an integer from 0 to 2. When a, b, and g are each 2 or greater, multiple groups of each of R₂₀′ R₂₁, and R₃₀ may be the same, or at least one group thereof may be different from the remainder. A case where c is 0 may be the same as a case where c is 2 and two R₂₀ groups are all hydrogen atoms. It may be understood that when c is 0, R₂₀ is not substituted at Formula 2-2. A case where d is 0 may be the same as a case where d is 2 and two R₂₁ groups are all hydrogen atoms. It may be understood that when d is 0, R₂₁ is not substituted at Formula 2-2. A case where g is 0 may be the same as a case where g is 2 and two R₃₀ groups are all hydrogen atoms. It may be understood that when g is 0, R₃₀ is not substituted at Formula 2-4.

In Formula 2-3 and Formula 2-4, f and h may each independently be an integer from 0 to 5. When f and h are each 2 or greater, multiple groups of each of R₂₆ and R₃₁ may be the same, or at least one group thereof may be different from the remainder. A case where f is 0 may be the same as a case where f is 5 and R₂₆ groups are all hydrogen atoms. It may be understood that when f is 0, R₂₆ is not substituted at Formula 2-3. A case where h is 0 may be the same as a case where h is 5 and R₃₁ groups are all hydrogen atoms. It may be understood that when h is 0, R₃₁ is not substituted at Formula 2-4.

The polycyclic compound may include a deuterium atom as a substituent. For example, in the polycyclic compound represented by Formula 1, at least one of R₁ to R₁₁, X₁, and X₂ may include a deuterium atom, or a substituent containing a deuterium atom. However, this is only an example, and embodiments are not limited thereto.

In an embodiment, Formula 2-1 may be represented by Formula 3-1. Formula 3-1 represents a case where a bonding position of two first pyridine units to a benzene ring linker is further defined in Formula 2-1. For example, Formula 3-1 corresponds to a case where a bonding position of two 2-tert-butylpyridine groups is further defined in Formula 2-1.

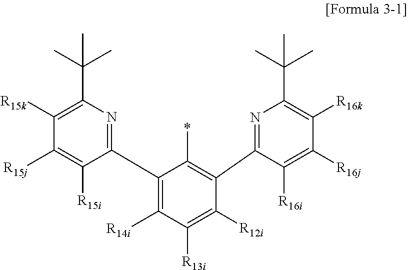

In Formula 3-1, R₁₂ᵢ, R₁₃ᵢ, R₁₄ᵢ, R₁₅ᵢ to R₁₅ₖ, and R₁₆ᵢ to R₁₆ₖ may each independently be a hydrogen atom, a deuterium atom, a substituted or unsubstituted alkyl group having 1 to 10 carbon atoms, or a substituted or unsubstituted aryl group having 6 to 60 ring-forming carbon atoms. For example, R₁₂ᵢ, R₁₃ᵢ, R₁₄ᵢ, R₁₅ᵢ to R₁₅ₖ, and R₁₆ᵢ to R₁₆ₖ may each independently be a hydrogen atom, a deuterium atom, a substituted or unsubstituted t-butyl group, or a substituted or unsubstituted phenyl group.

In an embodiment, Formula 2-2 may be represented by Formula 3-2. Formula 3-2 represents a case where a bonding position of two second pyridine units to benzene ring linker is further defined in Formula 2-2. For example, Formula 3-2 corresponds to a case where a bonding position of two 2,6-di-tert-butylpyridine groups is further defined in Formula 2-2.

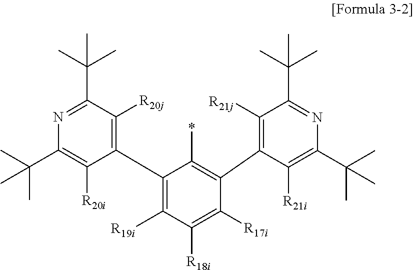

In Formula 3-2, R₁₇ᵢ, R₁₈ᵢ, R₁₉ᵢ, R₂₀ᵢ, R₂₀ⱼ, R₂₁ᵢ, and R₂ᵢⱼ may each independently be a hydrogen atom, a deuterium atom, a substituted or unsubstituted alkyl group having 1 to 10 carbon atoms, or a substituted or unsubstituted aryl group having 6 to 60 ring-forming carbon atoms. For example, R₁₇ᵢ, R₁₈ᵢ, R₁₉ᵢ, R₂₀ᵢ, R₂₀ⱼ, R₂₁ᵢ, and R₂₁ⱼ may each independently be a hydrogen atom, a deuterium atom, a substituted or unsubstituted t-butyl group, or a substituted or unsubstituted phenyl group.

In an embodiment, Formula 2-3 may be represented by Formula 3-3. Formula 3-3 represents a case where bonding positions of a first pyridine unit and a substituted or unsubstituted phenyl group to a benzene ring linker are further defined in Formula 2-3. For example, Formula 3-3 corresponds to a case where bonding positions of a 2-tert-butylpyridine group and a substituted or unsubstituted phenyl group are further defined in Formula 2-3.

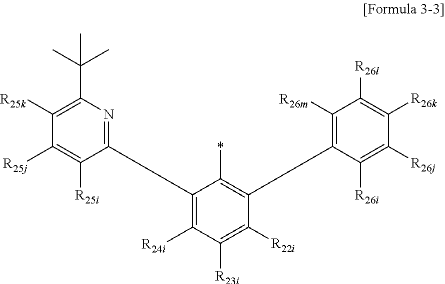

In Formula 3-3, R₂₂ᵢ, R₂₃ᵢ, R₂₄ᵢ, R₂₅ᵢ to R₂₅ₖ, and R₂₆ᵢ to R₂₆ₘ may each independently be a hydrogen atom, a deuterium atom, a substituted or unsubstituted alkyl group having 1 to 10 carbon atoms, or a substituted or unsubstituted aryl group having 6 to 60 ring-forming carbon atoms. For example, R₂₂ᵢ, R₂₃ᵢ, R₂₄ᵢ, and R₂₅ᵢ to R₂₅ₖ may each independently be a hydrogen atom, a deuterium atom, or a substituted or unsubstituted t-butyl group. For example, R₂₆ᵢ to R₂₆ₘ may each independently be a hydrogen atom or a deuterium atom.

In an embodiment, Formula 2-4 may be represented by Formula 3-4. Formula 3-4 represents a case where bonding positions of a second pyridine unit and a substituted or unsubstituted phenyl group to a benzene ring linker are further defined in Formula 2-4. For example, Formula 3-4 corresponds to a case where bonding positions of a 2,6-di-tert-butylpyridine group and a substituted or unsubstituted phenyl group are further defined in Formula 2-4.

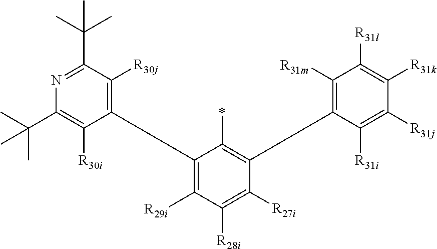

In Formula 3-4, R₂₇ᵢ, R₂₈ᵢ, R₂₉ᵢ, R₃₀ᵢ, R₃₀ⱼ, and R₃₁ᵢ to R₃₁ₘ may each independently be a hydrogen atom, a deuterium atom, a substituted or unsubstituted alkyl group having 1 to 10 carbon atoms, or a substituted or unsubstituted aryl group having 6 to 60 ring-forming carbon atoms. For example, R₂₇ᵢ, R₂₈ᵢ, R₂₉ᵢ, R₃₀ᵢ, and R₃₀ⱼ may each independently be a hydrogen atom, a deuterium atom, or a substituted or unsubstituted t-butyl group. For example, R₃₁ᵢ to R₃₁ₘ may each independently be a hydrogen atom or a deuterium atom.

In an embodiment, the polycyclic compound may be represented by Formula 4. Formula 4 represents a case where a bonding position of a substituent is further defined in Formula 1. Formula 4 represents case where R₁, R₃, R₄, R₇, R₈, and R₁ are hydrogen atoms in Formula 1. In Formula 4, R₂, R₅, R₆, R₉, R₁₀, X₁, and X₂ are the same as described in Formula 1.

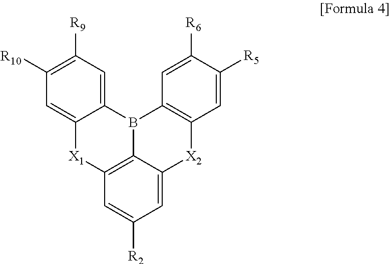

In an embodiment, the polycyclic compound represented by Formula 4 may be represented by any one of Formula 4-1 to Formula 4-3. Formula 4-1 to Formula 4-3 each represents a case where R₂, R₅, R₆, R₉, and R₁₀ are further defined in Formula 4. In Formula 4-1 to Formula 4-3, X₁ and X₂ are the same as described in Formula 1.

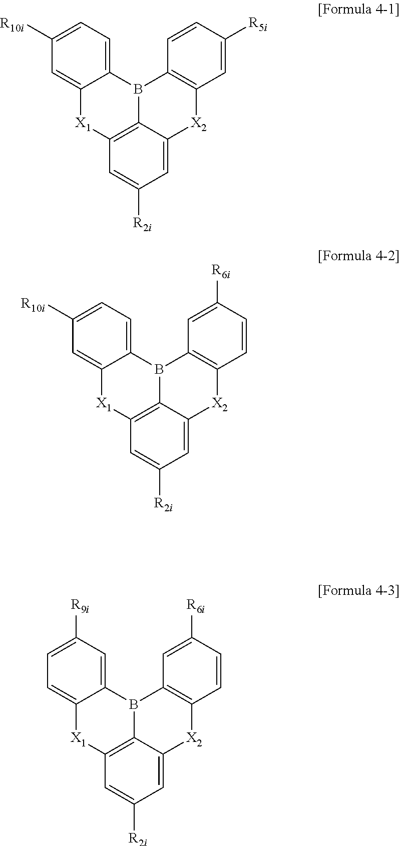

In Formula 4-1 to Formula 4-3, R₂ᵢ, R₅ᵢ, R₆ᵢ, R₉ᵢ, and R₁₀ᵢ may each independently be a hydrogen atom, a deuterium atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms. For example, R₂ᵢ, R₅ᵢ, R₆ᵢ, R₉ᵢ, and R₁₀ᵢ may each independently be a hydrogen atom or a deuterium atom, or may be a group represented any one of Formula RS-1 to Formula RS-5 as described above.

In an embodiment, the polycyclic compound represented by Formula 1 may be represented by any one of Formula 5-1 to Formula 5-7. Formula 5-1 to Formula 5-7 each corresponds to an embodiment where X₁ and X₂ are further defined in Formula 1.

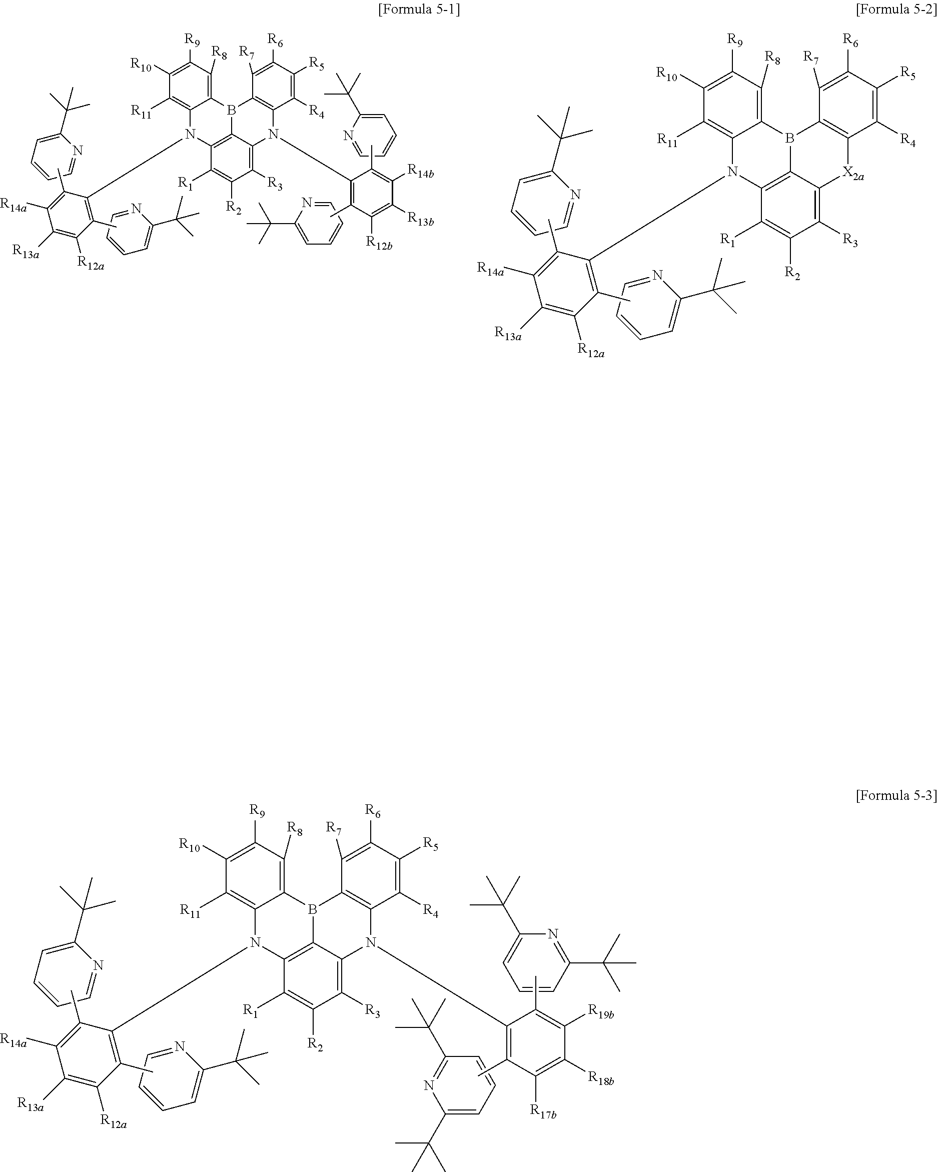

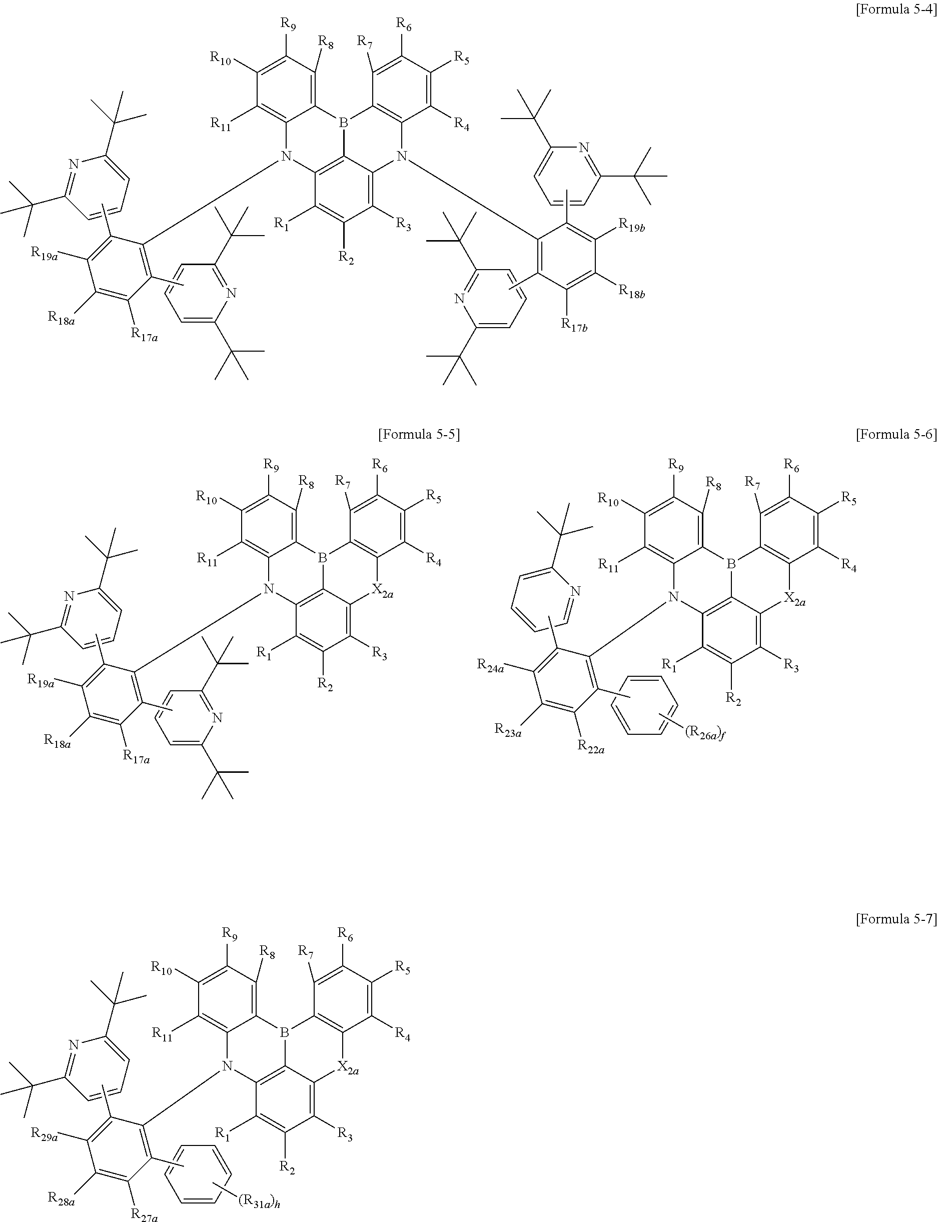

In Formula 5-1 to Formula 5-7, R₁₂ₐ to R₁₄ₐ, R_{12b} to R_{14b}, R₁₇ₐ to R₁₉ₐ, R_{17b} to R_{19b}, R₂₂ₐ to R₂₄ₐ, R₂₆ₐ, R₂₇ₐ to R₂₉ₐ, and R₃₁ₐ may each independently be a hydrogen atom, a deuterium atom, a substituted or unsubstituted alkyl group having 1 to 10 carbon atoms, or a substituted or unsubstituted aryl group having 6 to 60 ring-forming carbon atoms. For example, R₁₂ₐ to R₁₄ₐ, R_{12b} to R_{14b}, R₁₇ₐ to R₁₉ₐ, R_{17b} to R_{19b}, R₂₂ₐ to R₂₄ₐ, and R₂₇ₐ to R₂₉ₐ may each independently be a hydrogen atom, a deuterium atom, a substituted or unsubstituted t-butyl group, or a substituted or unsubstituted phenyl group. For example, R₂₆ₐ and R₃₁ₐ may be each independently a hydrogen atom or a deuterium atom. In Formula 5-1 to Formula 5-7, R₁ to R₁₁, f, and h are the same as described in Formula 1.

In Formula 5-2, Formula 5-5, Formula 5-6, and Formula 5-7, X₂ₐ may be N(Rₓ₂), O, or S. In Formula 5-2, Formula 5-5, Formula 5-6, and Formula 5-7, Rₓ₂ is the same as described in Formula 1.

In an embodiment, the polycyclic compound represented by Formula 1 may be represented by any one of Formula 6-1 to Formula 6-7. Formula 6-1 to Formula 6-7 each corresponds to an embodiment where R₁ to R₁₁, X₁, and X₂ are further defined in Formula 1. In Formula 6-6 and Formula 6-7, f and h are the same as described in Formula 1.

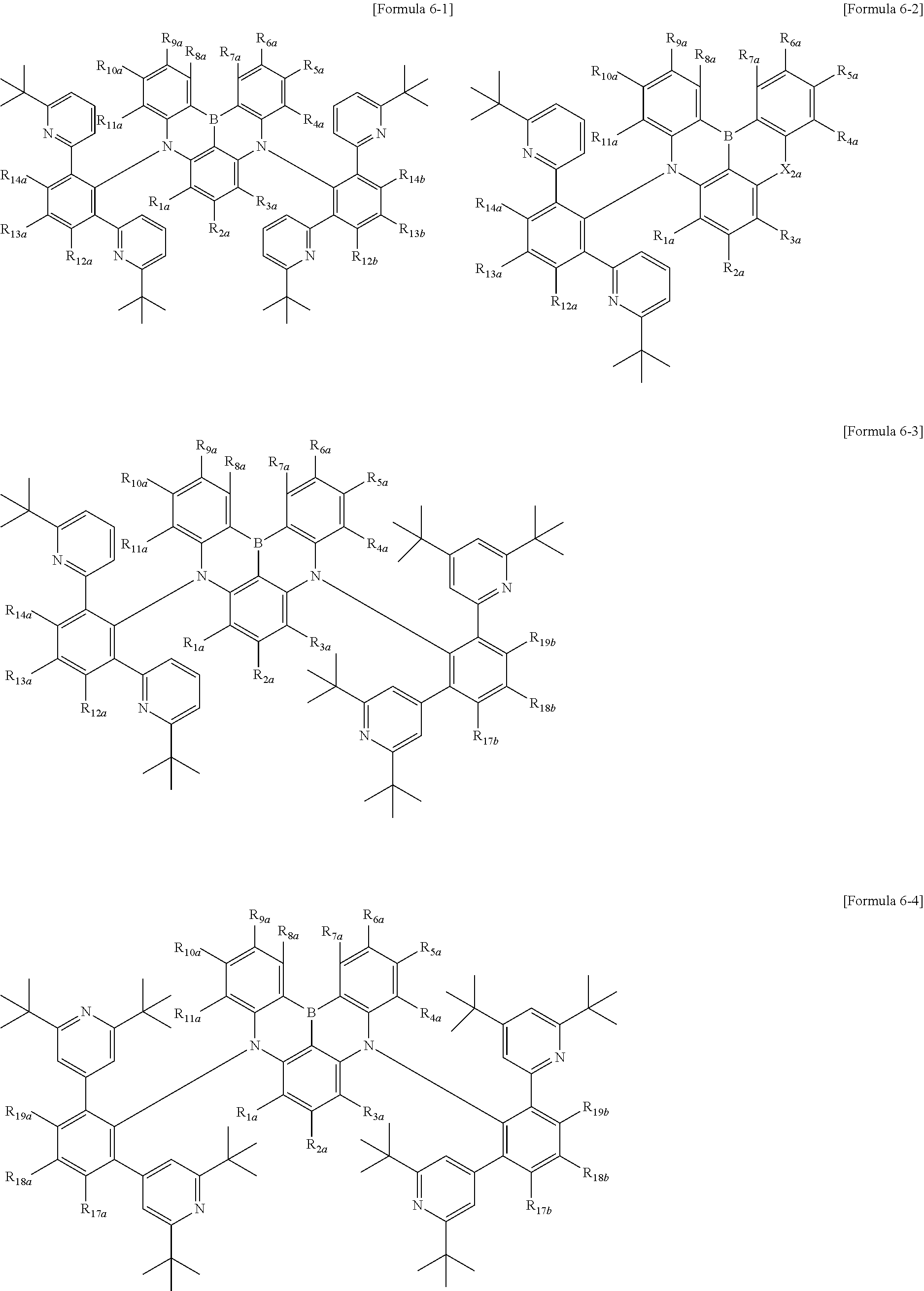

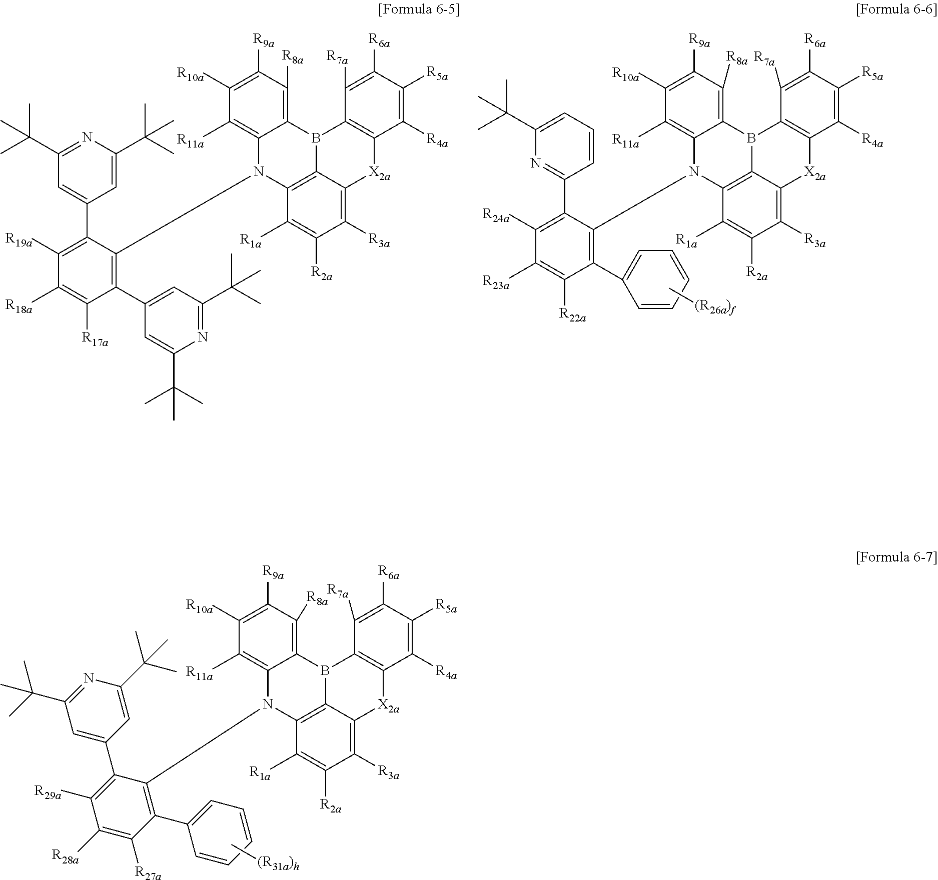

In Formula 6-1 to Formula 6-7, R₁ₐ to R₁₁ₐ may each independently be a hydrogen atom, a deuterium atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms. For example, R₁ₐ to R₁₁ₐ may each independently be a hydrogen atom or a deuterium atom, or may be a group represented by any one of Formula RS-1 to Formula RS-5 as described above. In an embodiment, at least one of R₁ₐ to R₃ₐ, at least one of R₄ₐ to R₇ₐ, and at least one of R₈ₐ to R₁₁ₐ may each independently be a group represented by any one of Formula RS-1 to Formula RS-5, and the remainder thereof may each independently be hydrogen atoms or deuterium atoms.

In Formula 6-1 to Formula 6-7, R₁₂ₐ to R₁₄ₐ, R_{12b} to R_{14b}, R₁₇ₐ to R₁₉ₐ, R_{17b} to R_{19b}, R₂₂ₐ to R₂₄ₐ, R₂₆ₐ, R₂₇ₐ to R₂₉ₐ, and R₃₁ₐ may each independently be a hydrogen atom, a deuterium atom, a substituted or unsubstituted alkyl group having 1 to 10 carbon atoms, or a substituted or unsubstituted aryl group having 6 to 60 ring-forming carbon atoms. For example, R₁₂ₐ to R₁₄ₐ, R_{12b} to R_{14b}, R₁₇ₐ to R₁₉ₐ, and R_{17b} to R_{19b} may each independently be a hydrogen atom, a deuterium atom, a substituted or unsubstituted t-butyl group, or a substituted or unsubstituted phenyl group.

In Formula 6-2 and Formula 6-5 to Formula 6-7, X₂ₐ may be N(Rₓ₂), O, or S. In Formula 6-2 and Formula 6-5 to Formula 6-7, Rₓ₂ is the same as described in Formula 1.

In an embodiment, the polycyclic compound represented by Formula 1 may be represented by any one of Formula 7-1 to Formula 7-7. Formula 7-1 to Formula 7-7 each corresponds to an embodiment where R₁ to R₁₁, X₁, and X₂ are further defined in Formula 1. In Formula 7-6 and Formula 7-7, f and h are the same as described in Formula 1.

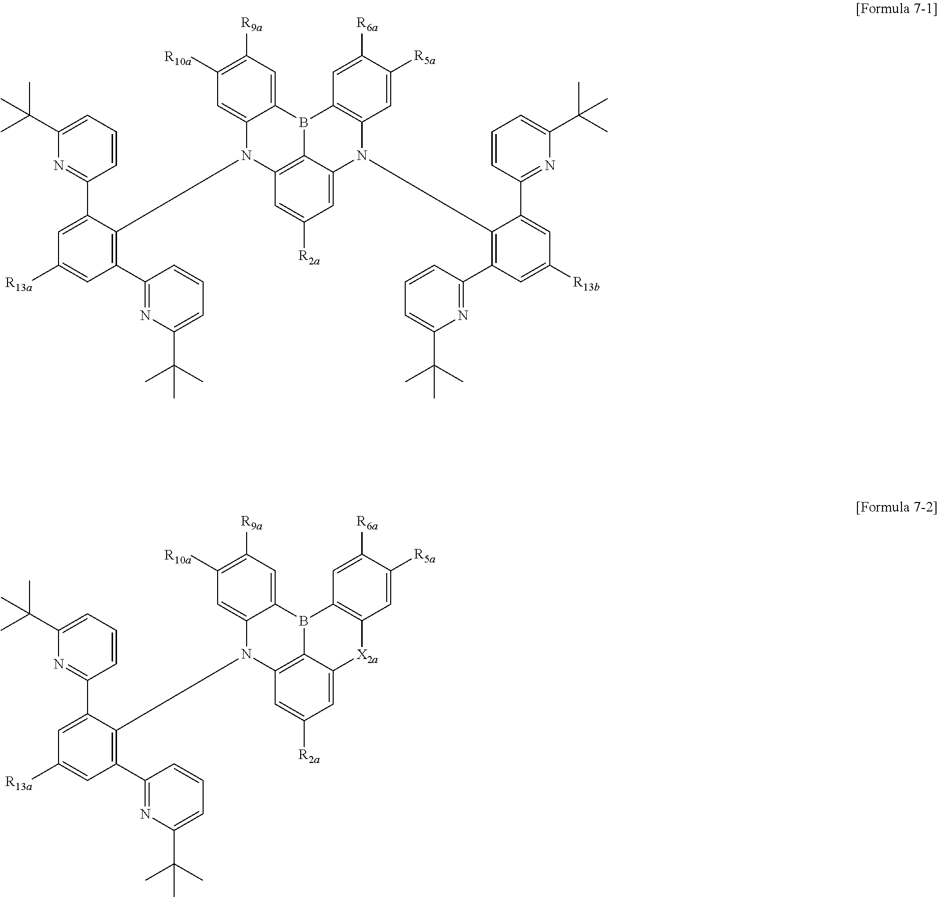

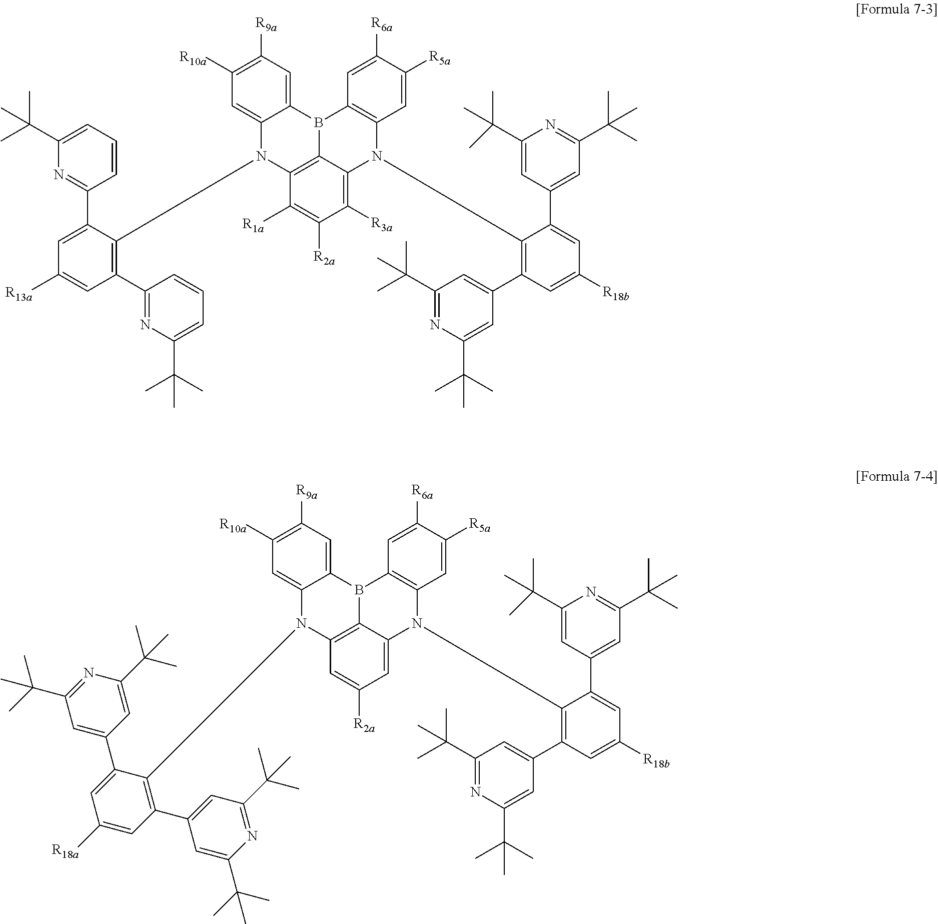

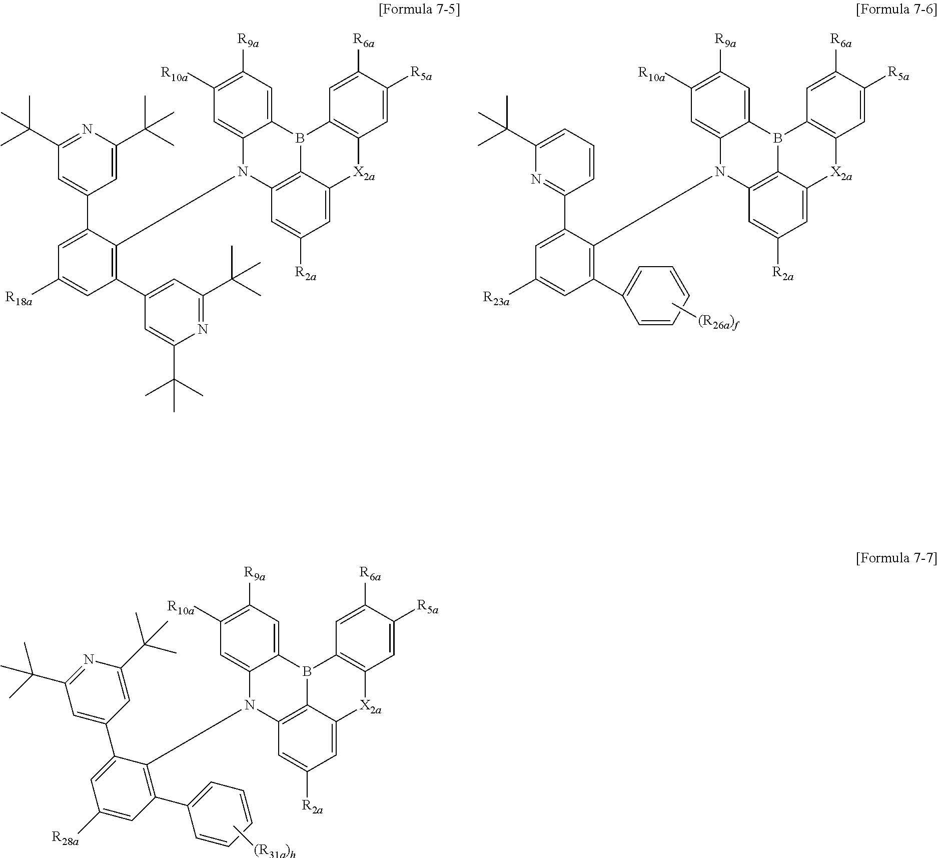

In Formula 7-1 to Formula 7-7, R₂ₐ, R₅ₐ, R₆ₐ, R₉ₐ, and R₁₀ₐ may each independently be a hydrogen atom, a deuterium atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms. For example, R₂ₐ, R₅ₐ, R₆ₐ, R₉ₐ, and R₁₀ₐ may each independently be a hydrogen atom or a deuterium atom, or may be a group represented by any one of Formula RS-1 to Formula RS-5 as described above.

In Formula 7-1 to Formula 7-7, R₁₃ₐ, R_{13b}, R₁₈ₐ, R_{18b}, R₂₃ₐ, R₂₆ₐ, R₂₈ₐ, and R₃₁ₐ may each independently be a hydrogen atom, a deuterium atom, a substituted or unsubstituted alkyl group having 1 to 10 carbon atoms, or a substituted or unsubstituted aryl group having 6 to 60 ring-forming carbon atoms. For example, R₁₃ₐ, R_{13b}, R₁₈ₐ, R_{18b}, R₂₃ₐ, and R₂₈ₐ may each independently be a hydrogen atom, a deuterium atom, a substituted or unsubstituted t-butyl group, or a substituted or unsubstituted phenyl group, and R₂₆ₐ and R₃₁ₐ may each independently be a hydrogen atom or a deuterium atom.

In Formula 7-2, Formula 7-5, Formula 7-6, and Formula 7-7, X₂ₐ may be N(Rₓ₂), 0, or S. In Formula 7-2, Formula 7-5, Formula 7-6, and Formula 7-7, Rₓ₂ is the same as described in Formula 1.

In an embodiment, the polycyclic compound may be any one compound selected from Compound Group 1. In an embodiment, the light emitting element ED may include at least one compound selected from Compound Group 1. In Compound Group 1, D represents a deuterium atom, t-Bu represents an unsubstituted t-butyl group, and Ph represents an unsubstituted phenyl group.

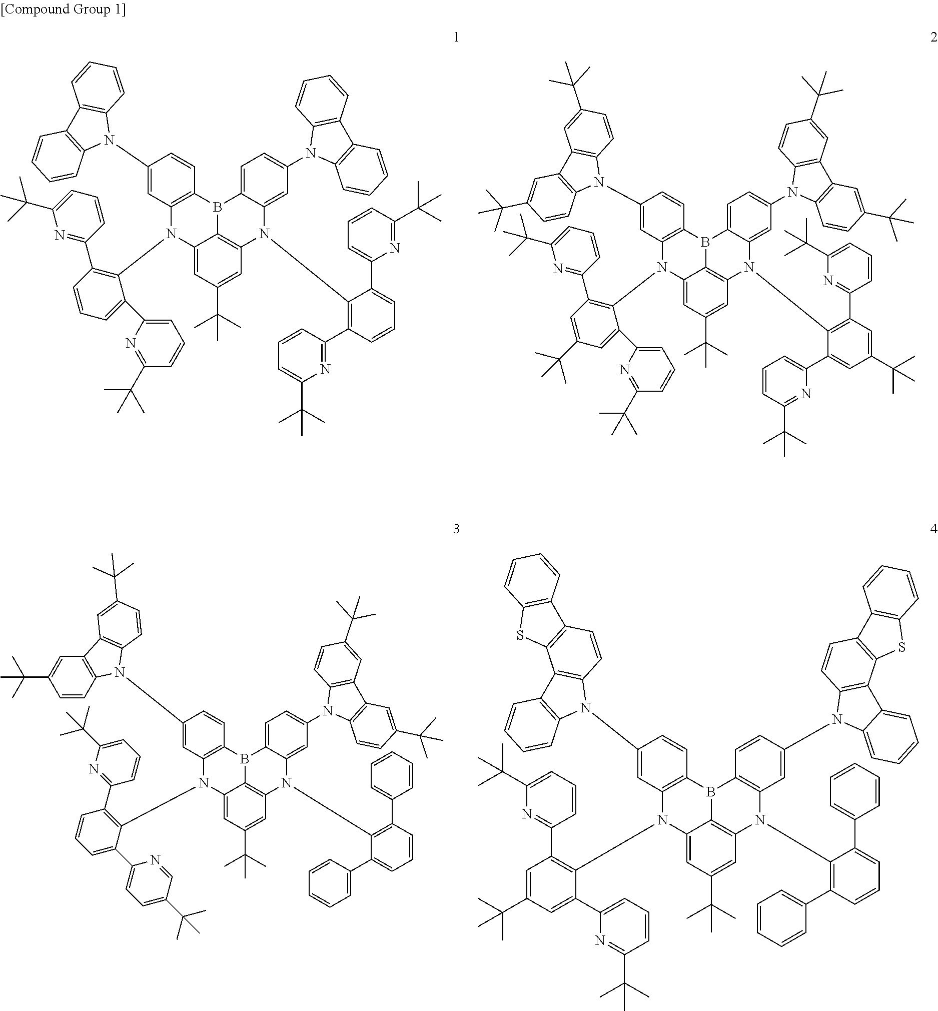

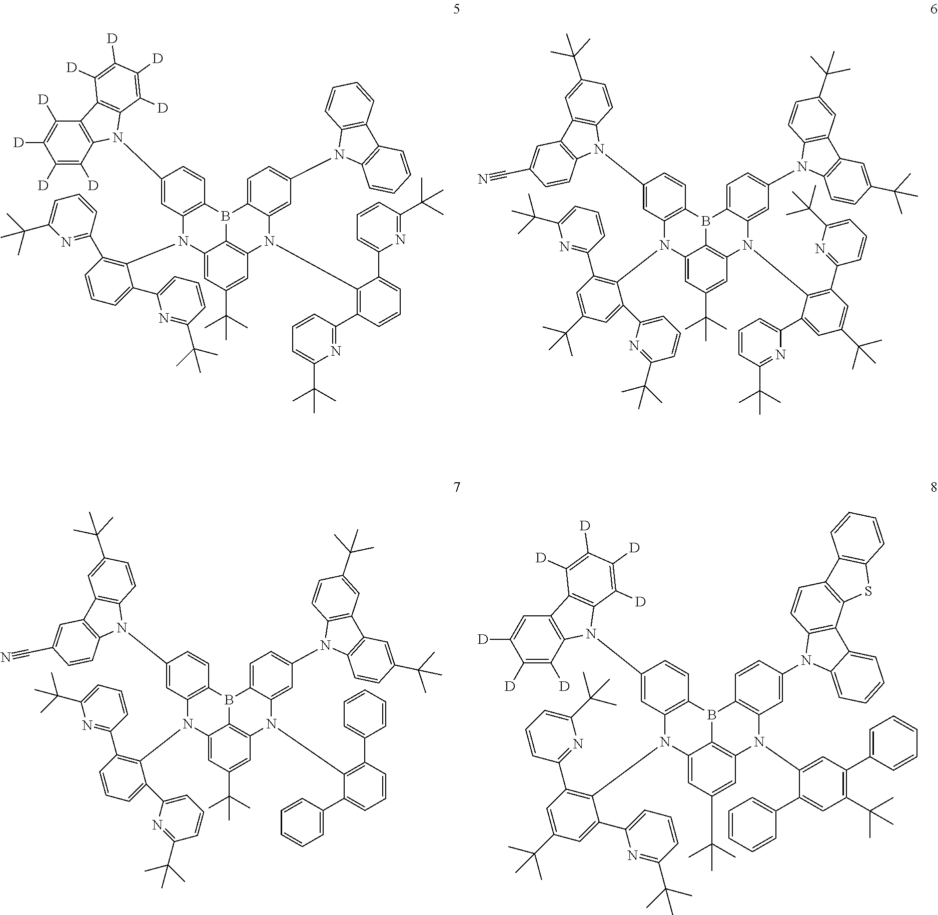

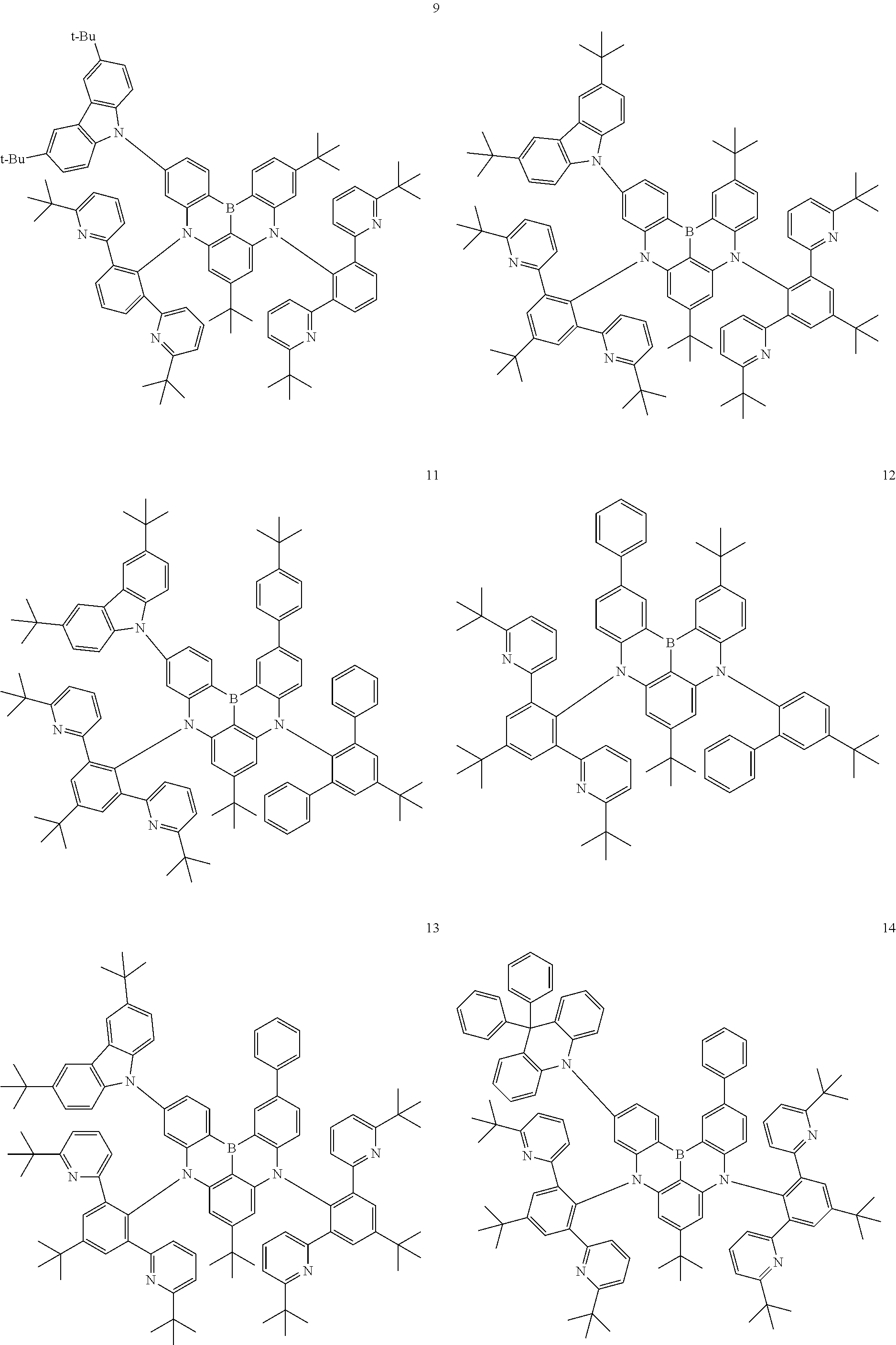

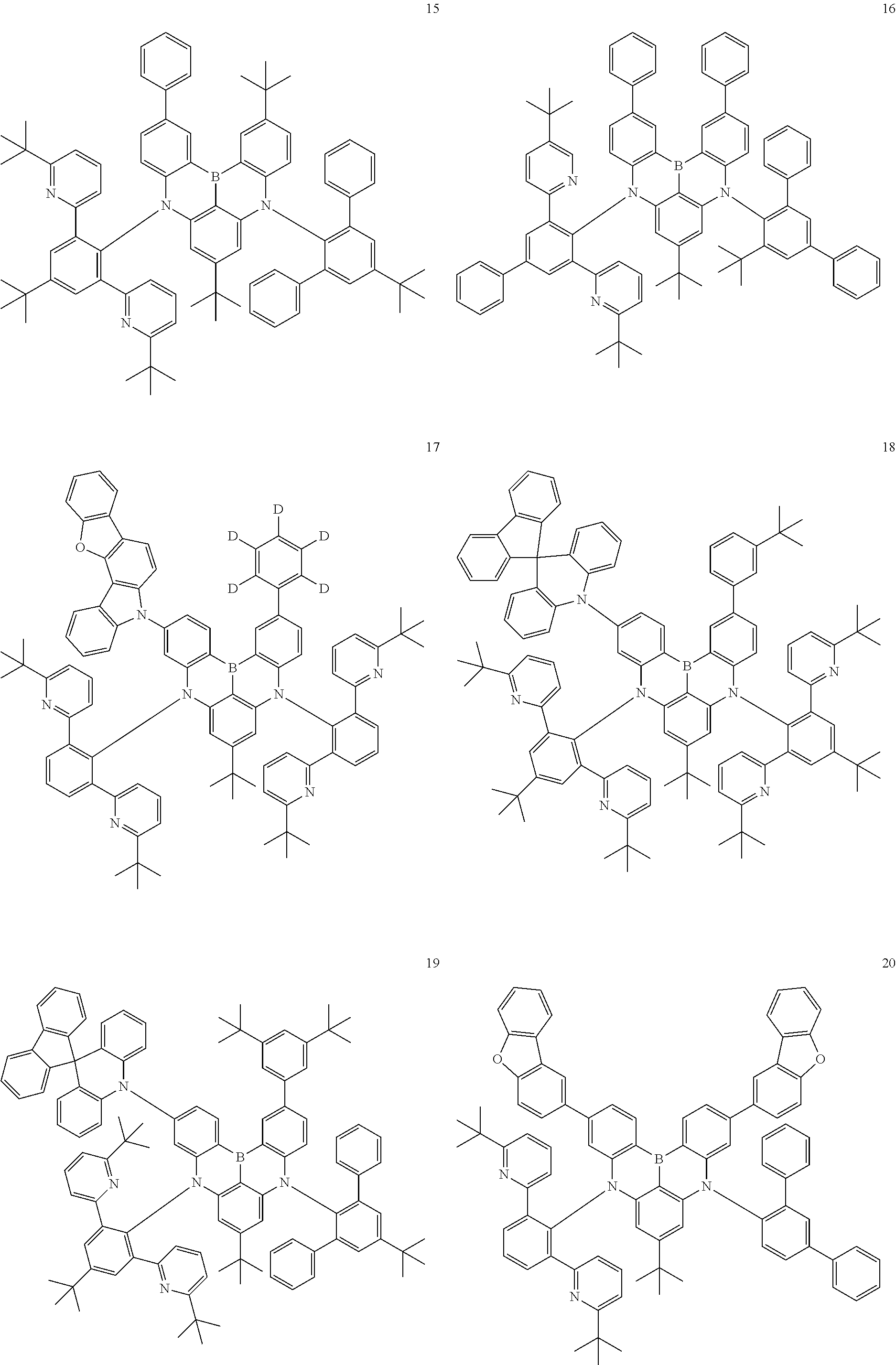

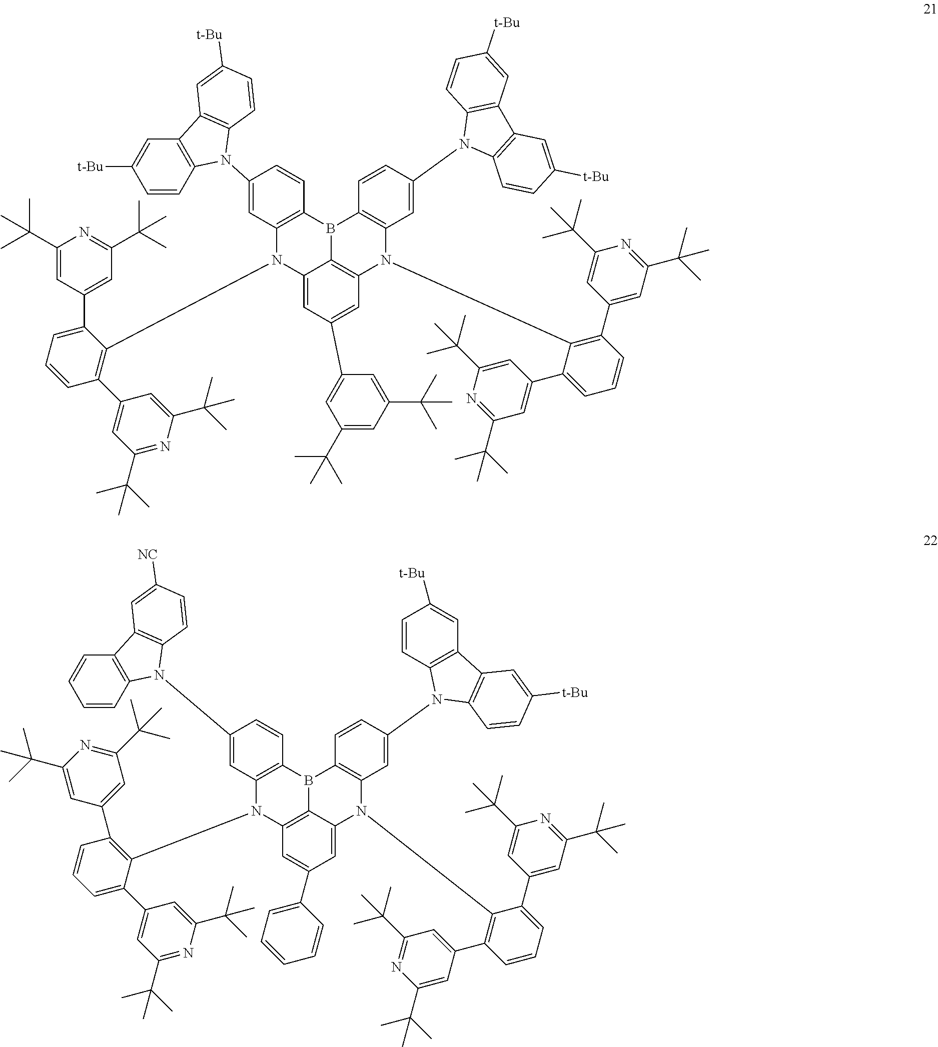

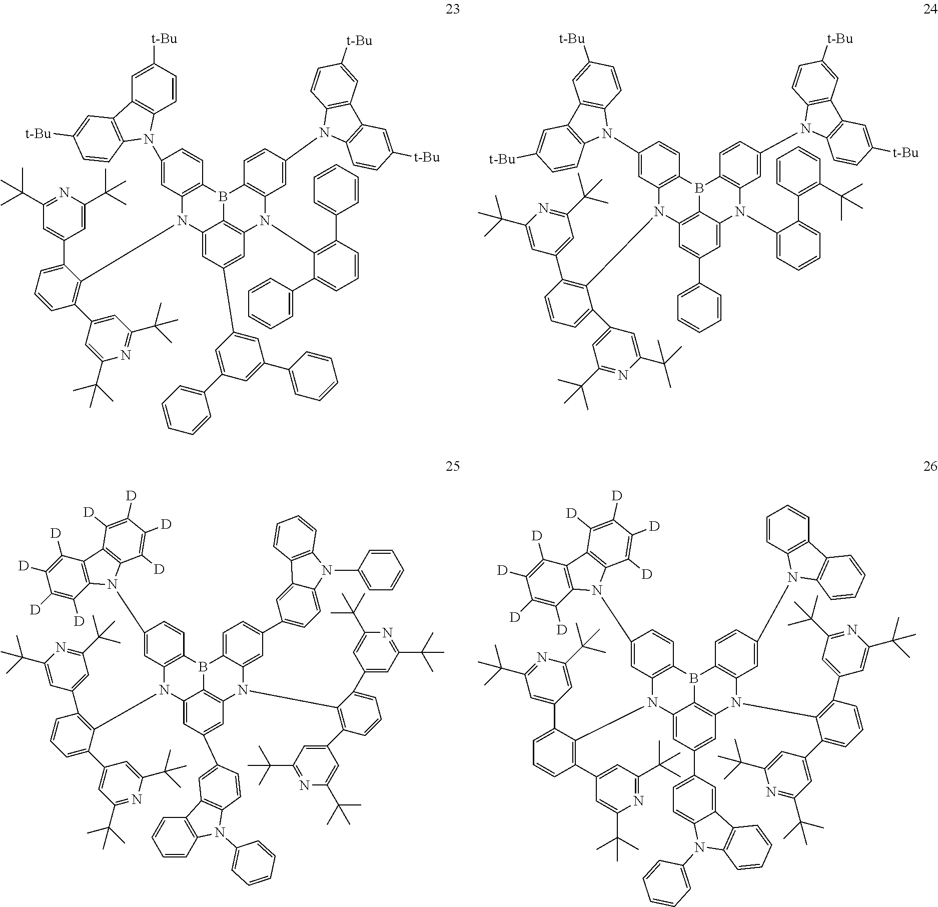

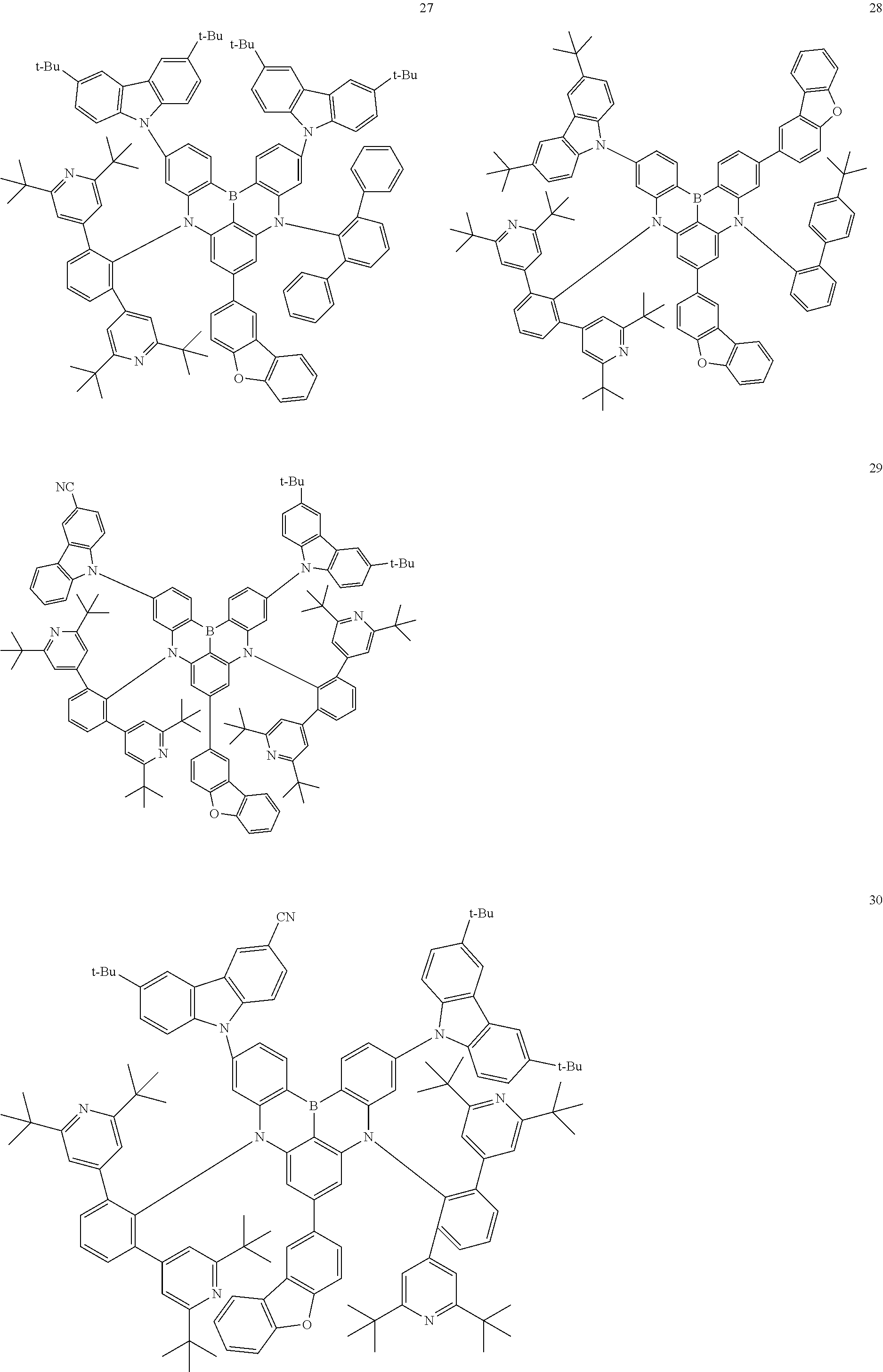

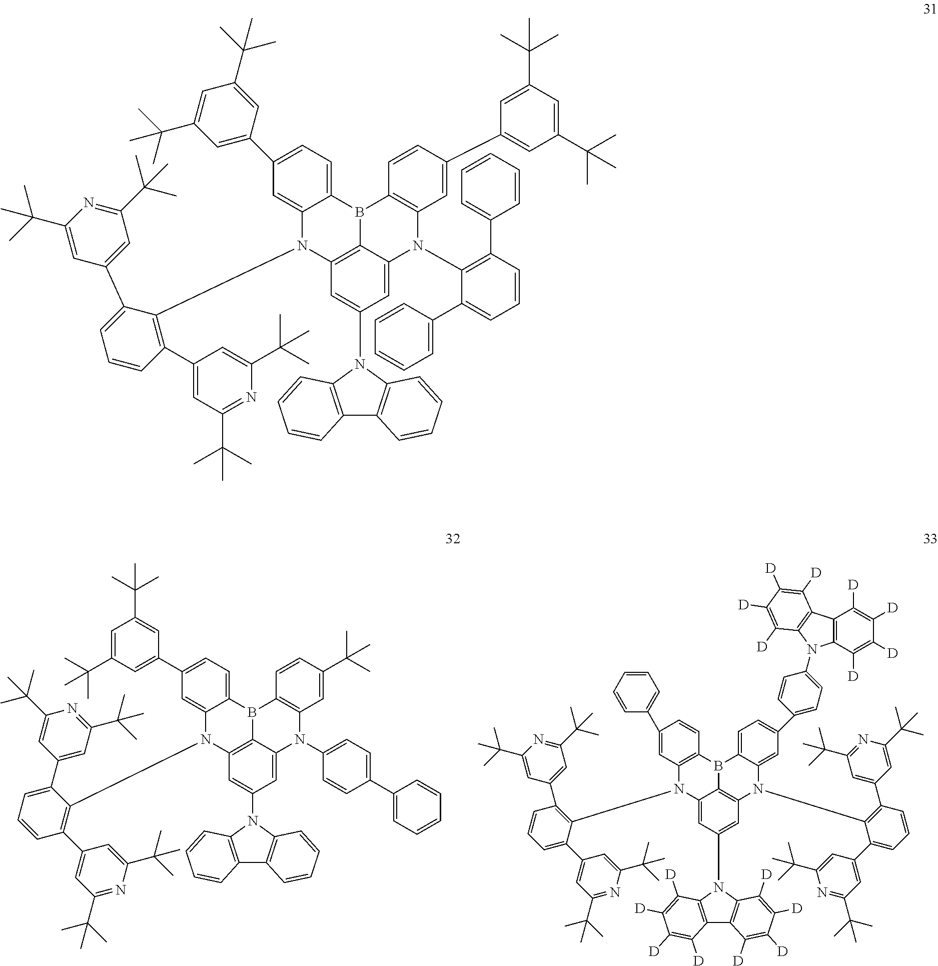

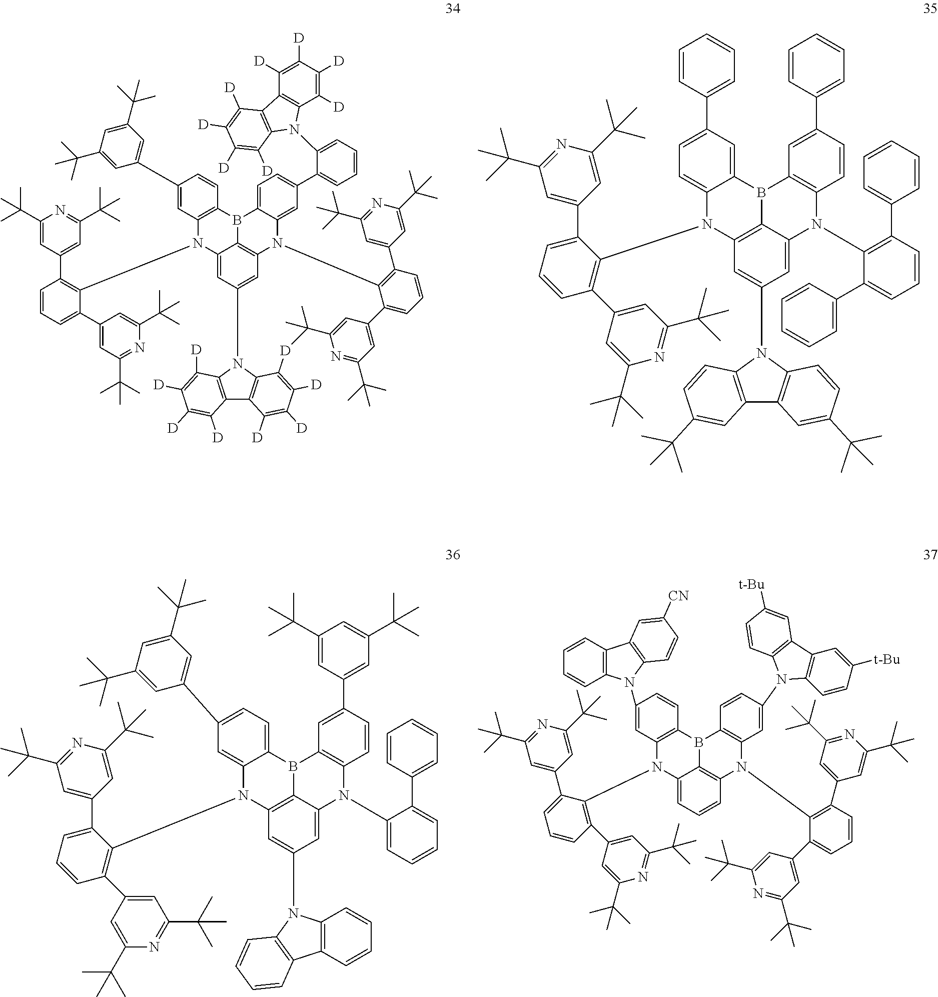

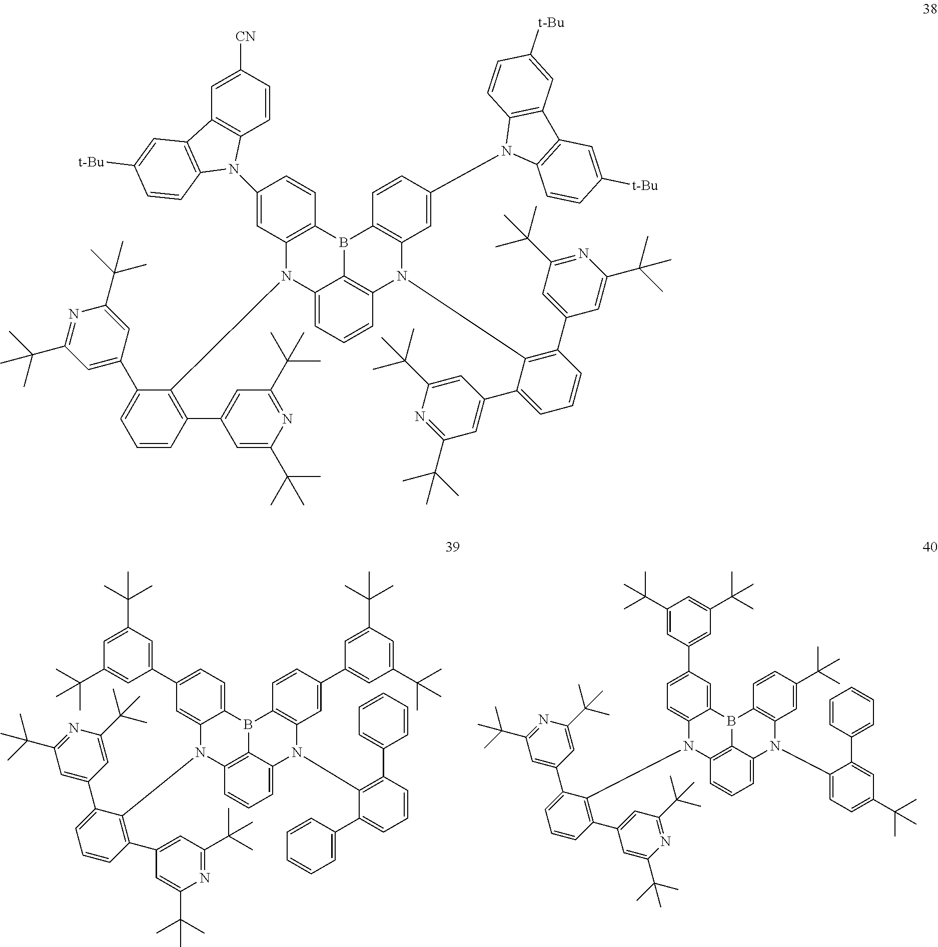

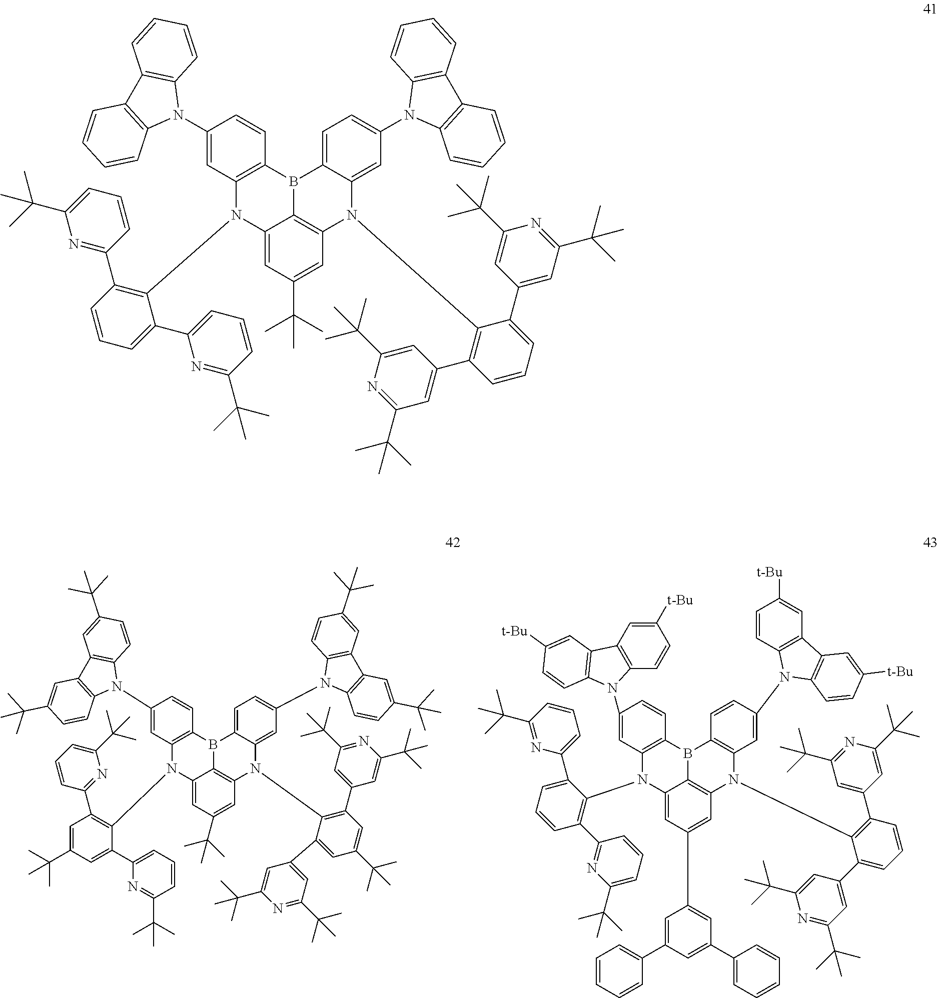

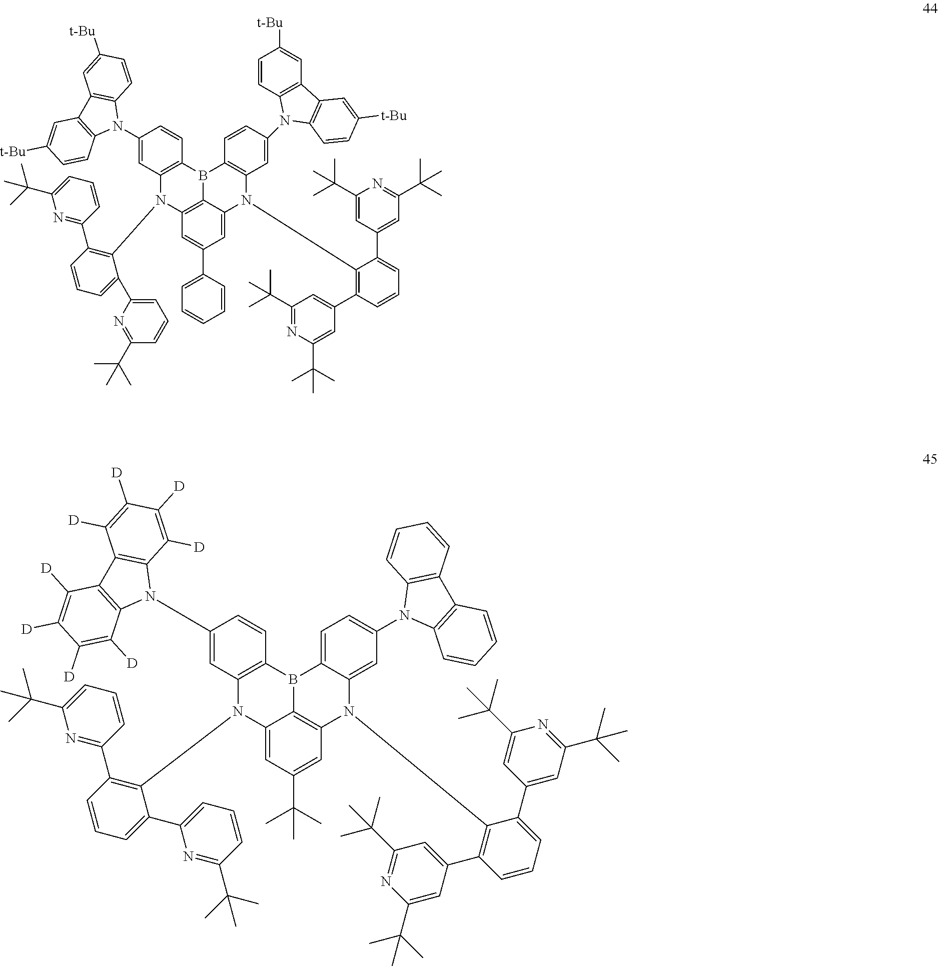

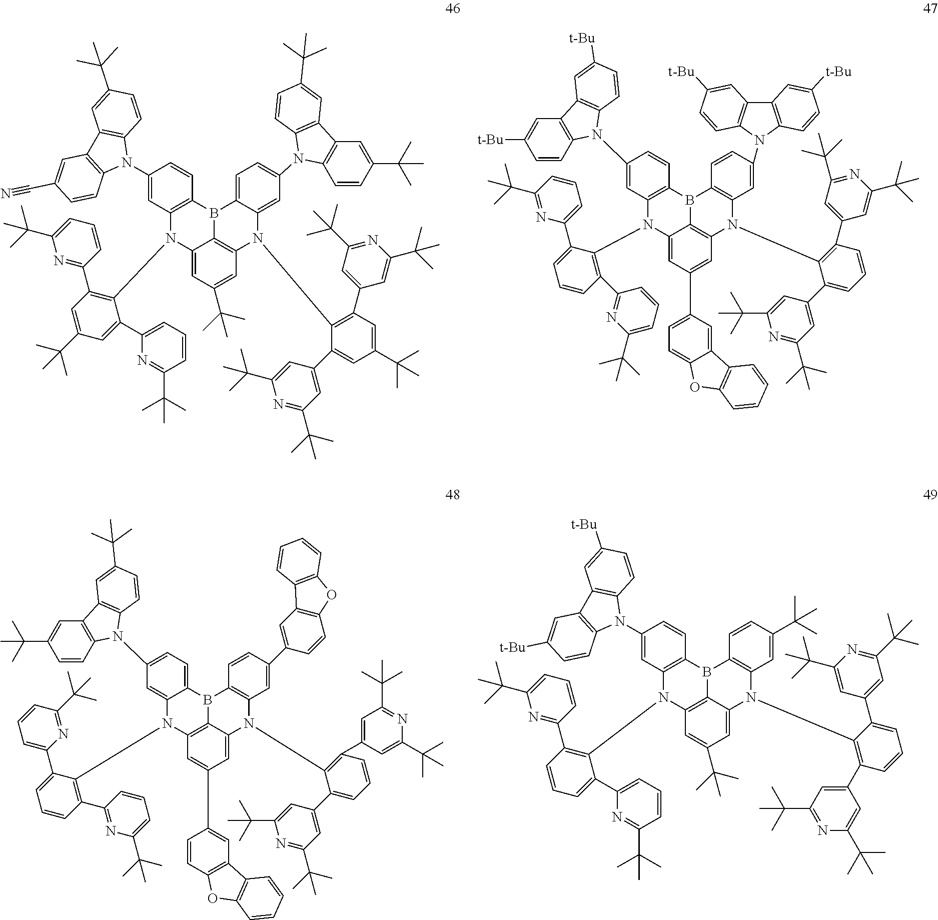

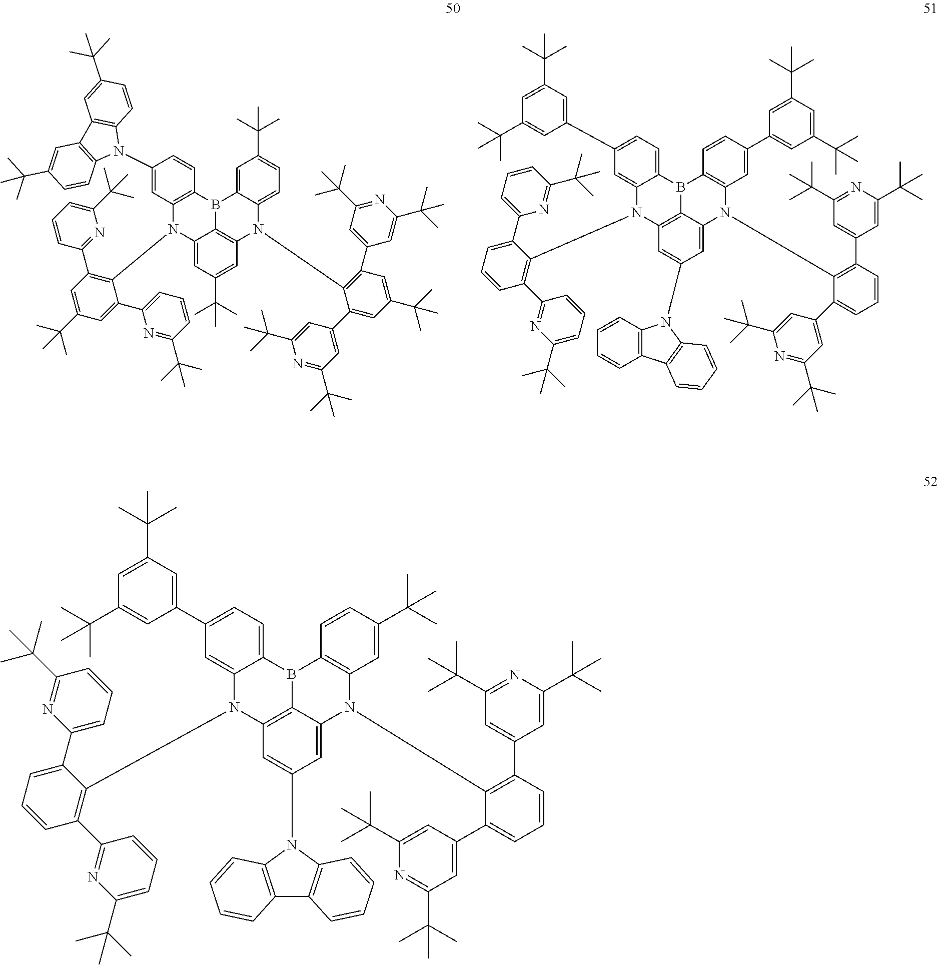

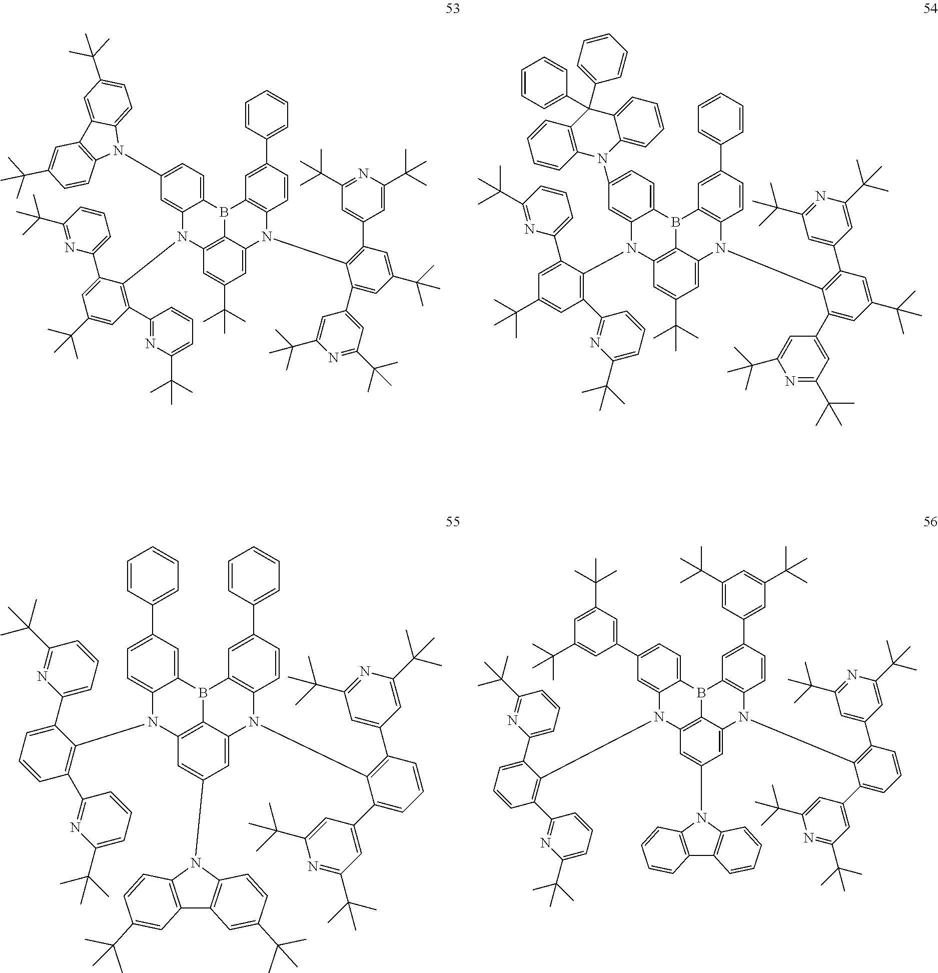

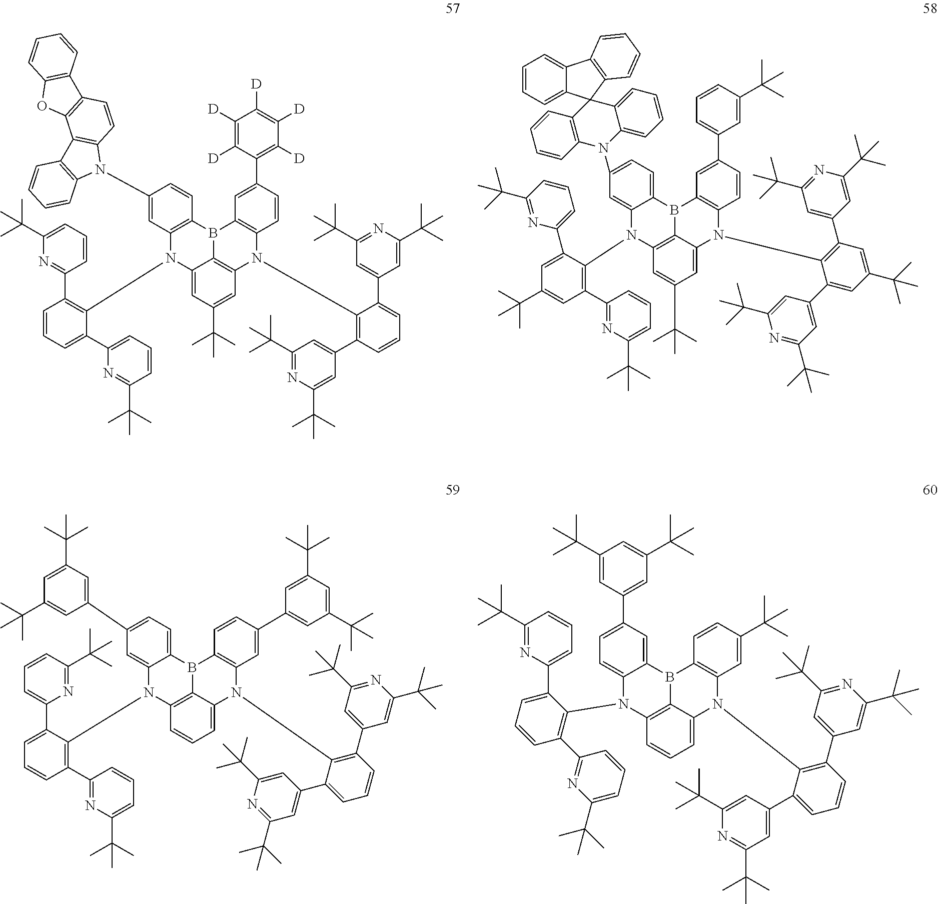

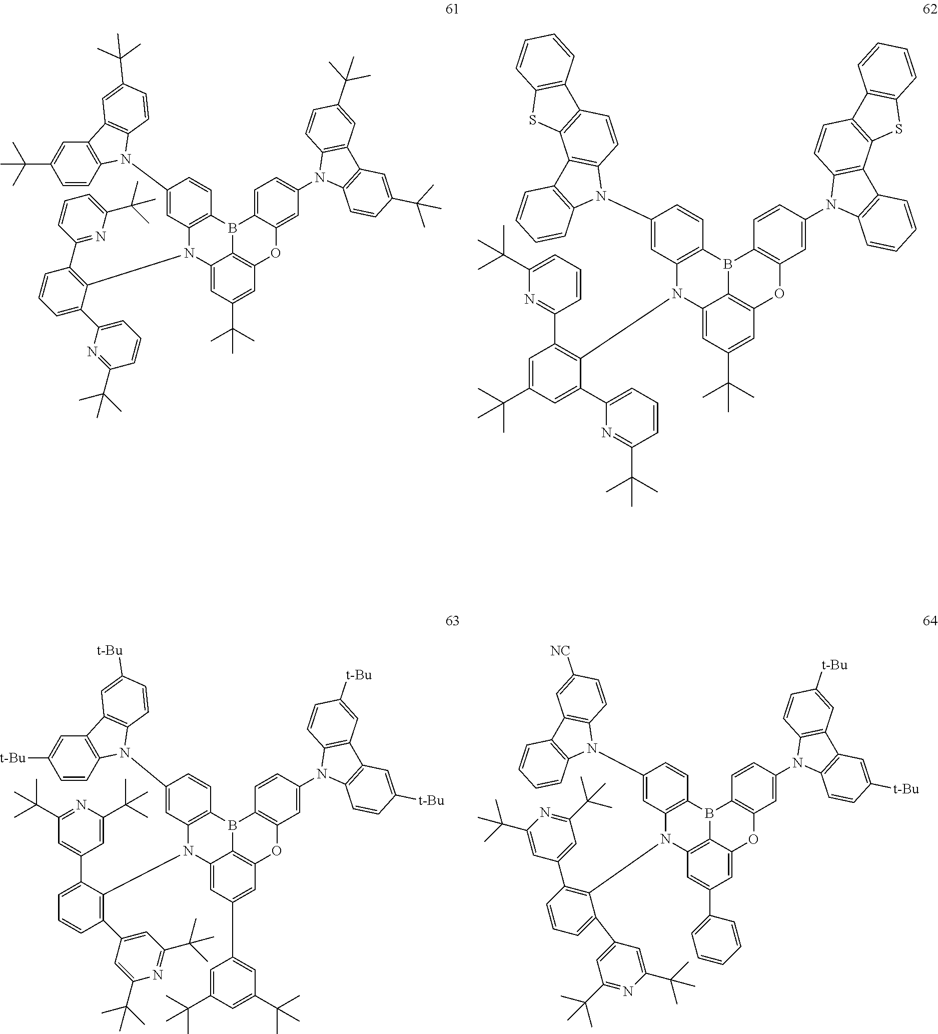

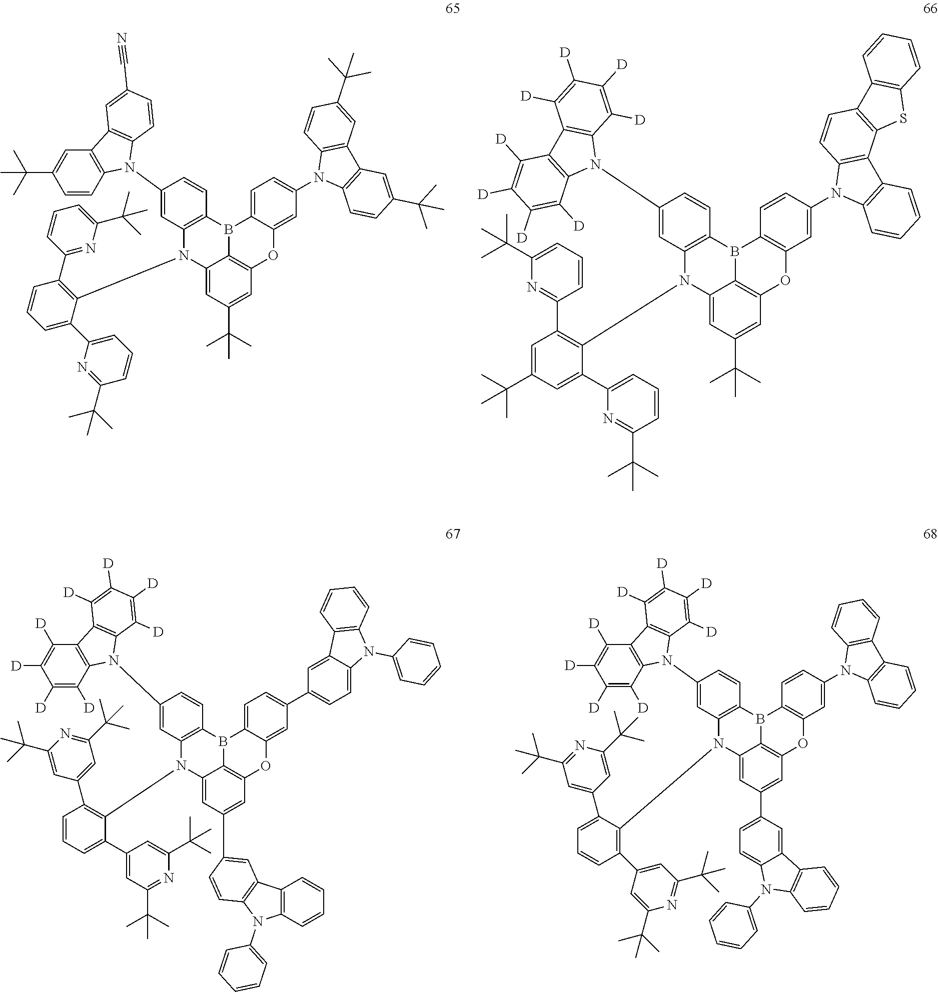

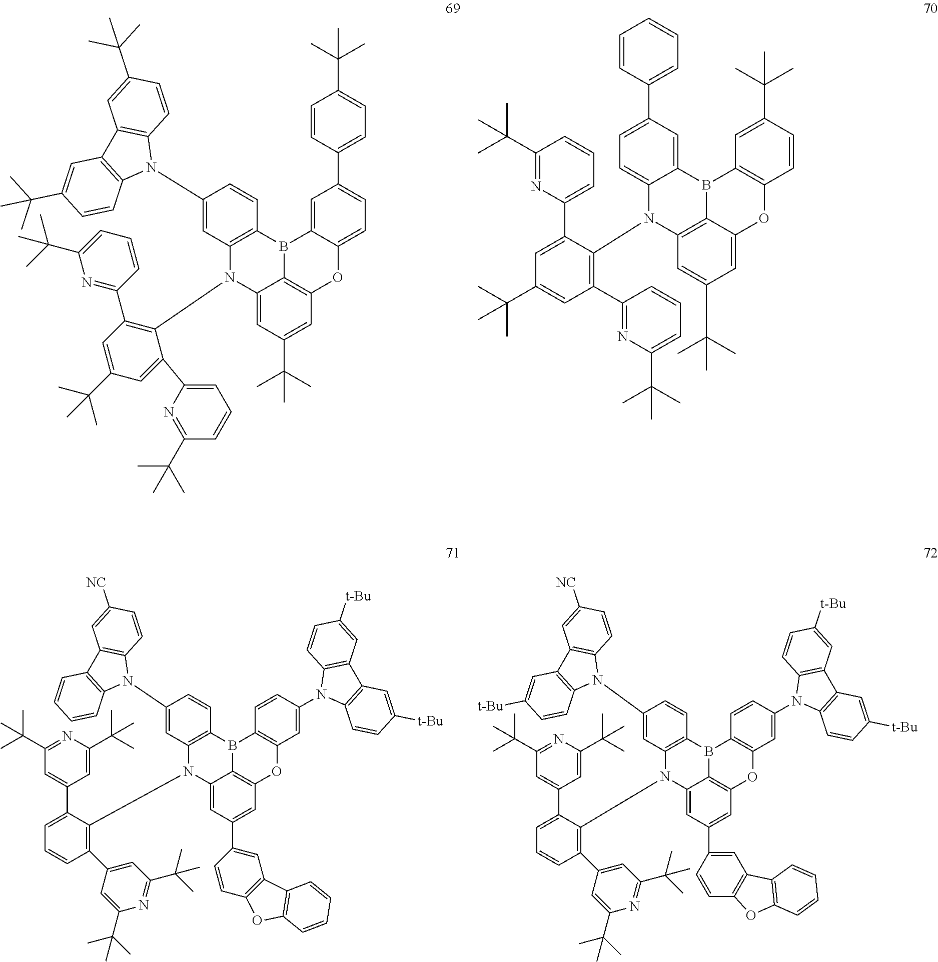

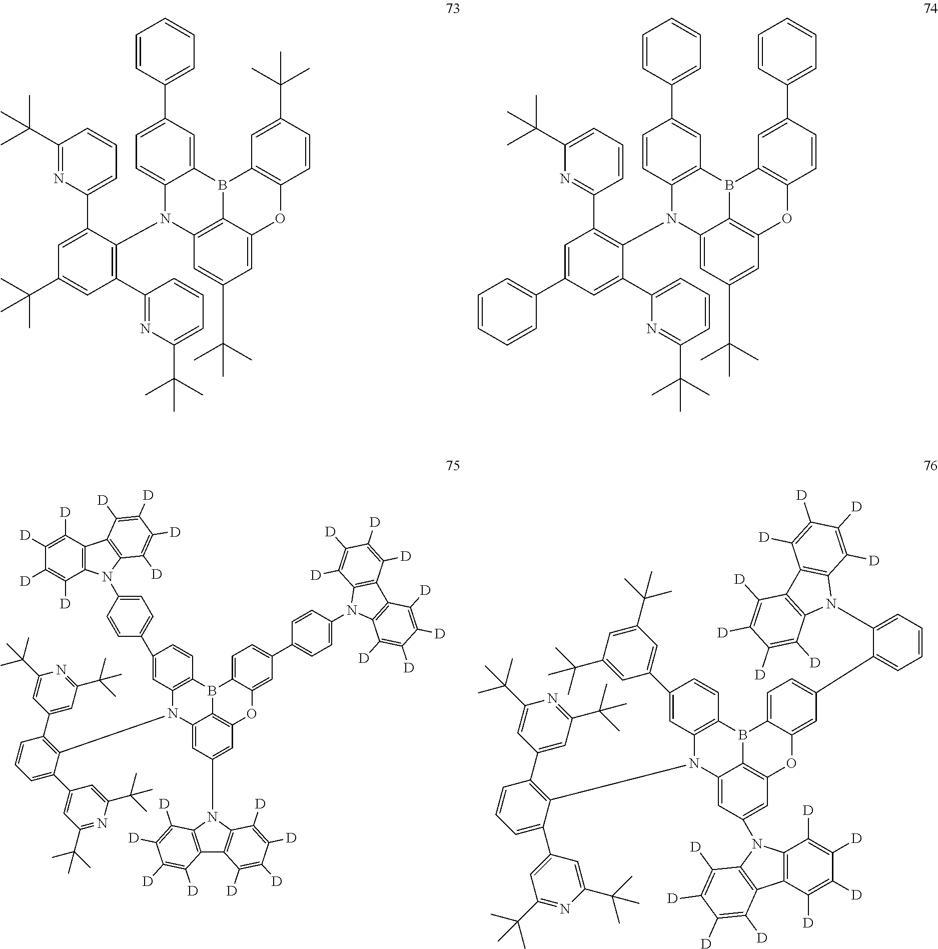

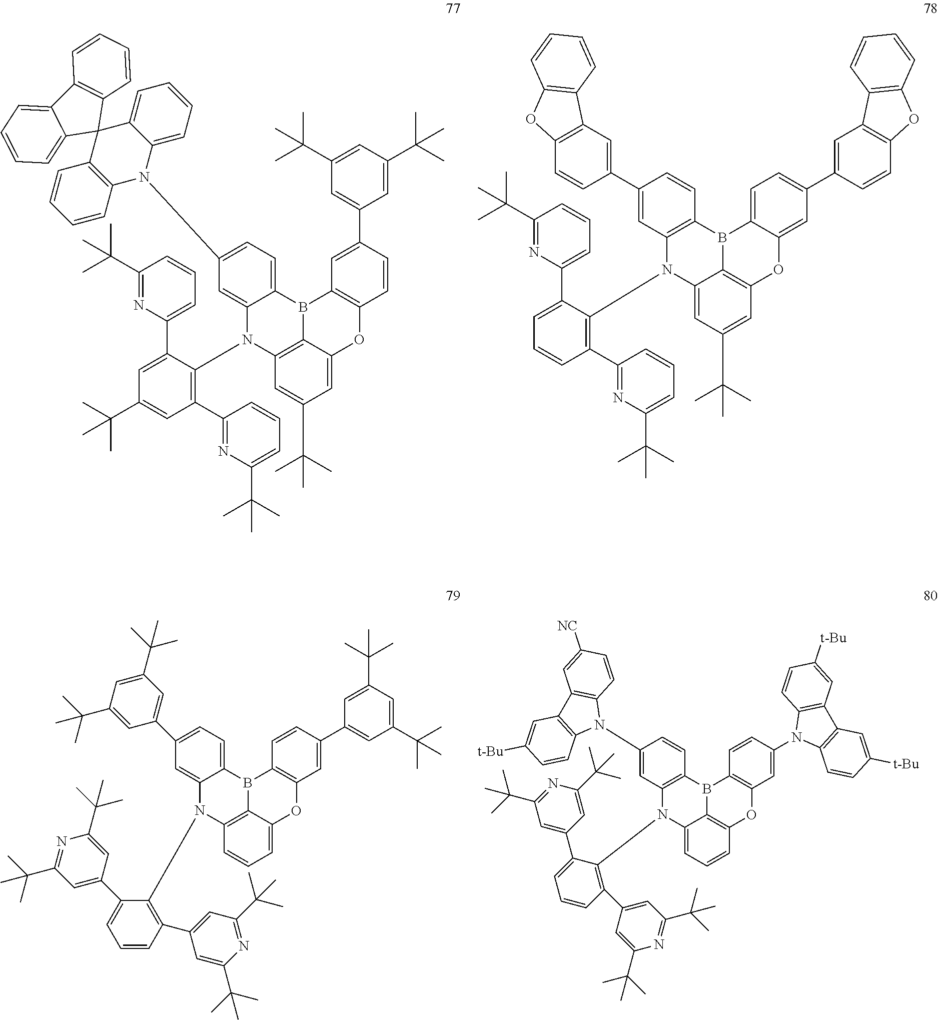

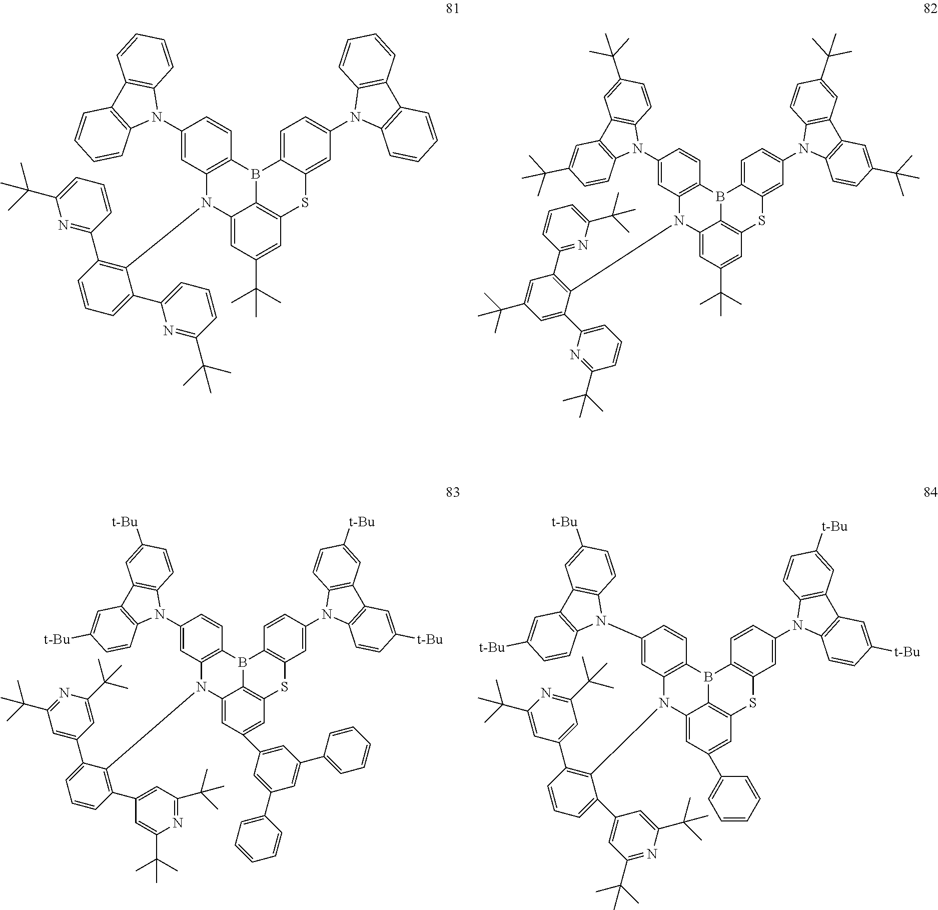

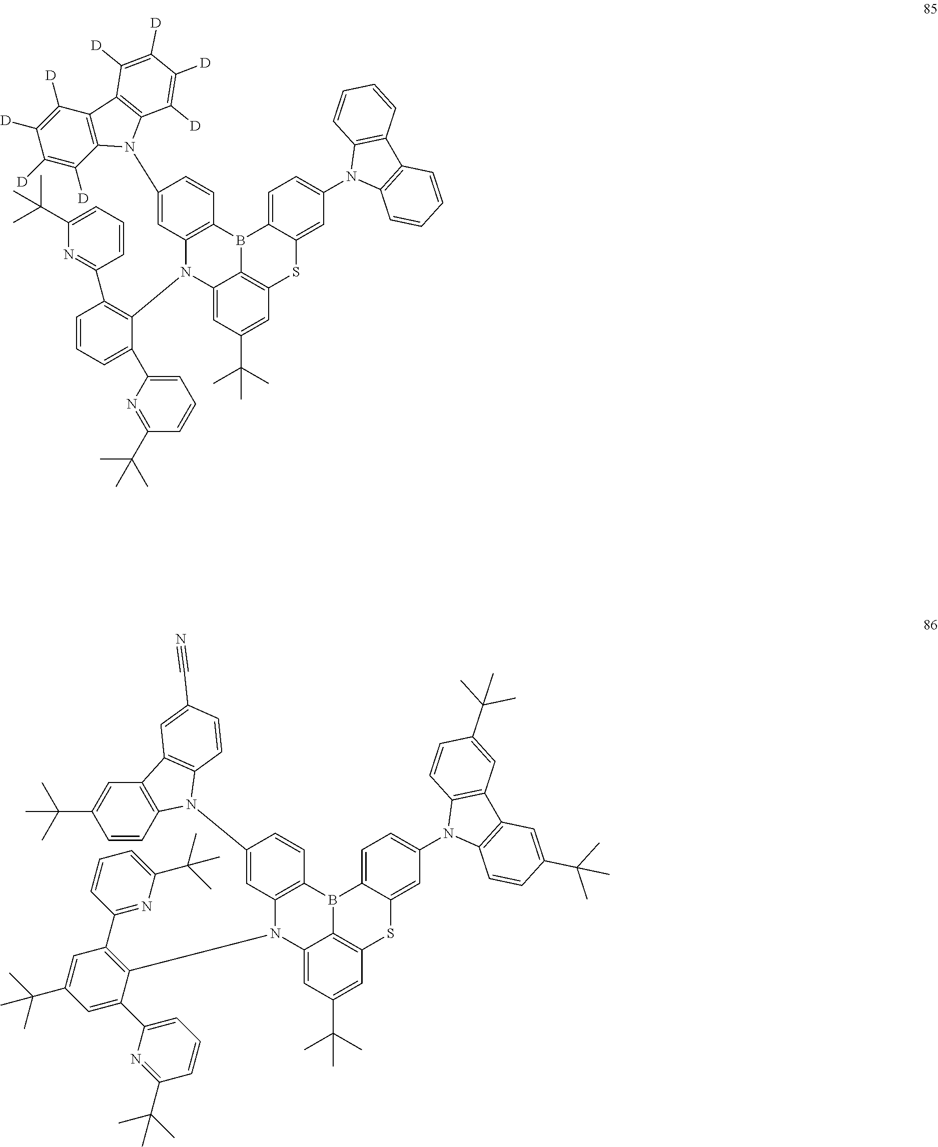 [SMILES: [2H]c1c([2H])c([2H])c2c(c1[2H])c1c([2H])c([2H])c([2H])c([2H])c1n2-c1ccc2c(c1)N(c1c(-c3cccc(C(C)(C)C)n3)cccc1-c1cccc(C(C)(C)C)n1)c1cc(C(C)(C)C)cc3c1B2c1ccc(-n2c4ccccc4c4ccccc42)cc1S3 ; CC(C)(C)c1cc(-c2cccc(C(C)(C)C)n2)c(N2c3cc(-n4c5ccc(C#N)cc5c5cc(C(C)(C)C)ccc54)ccc3B3c4ccc(-n5c6ccc(C(C)(C)C)cc6c6cc(C(C)(C)C)ccc65)cc4Sc4cc(C(C)(C)C)cc2c43)c(-c2cccc(C(C)(C)C)n2)c1]

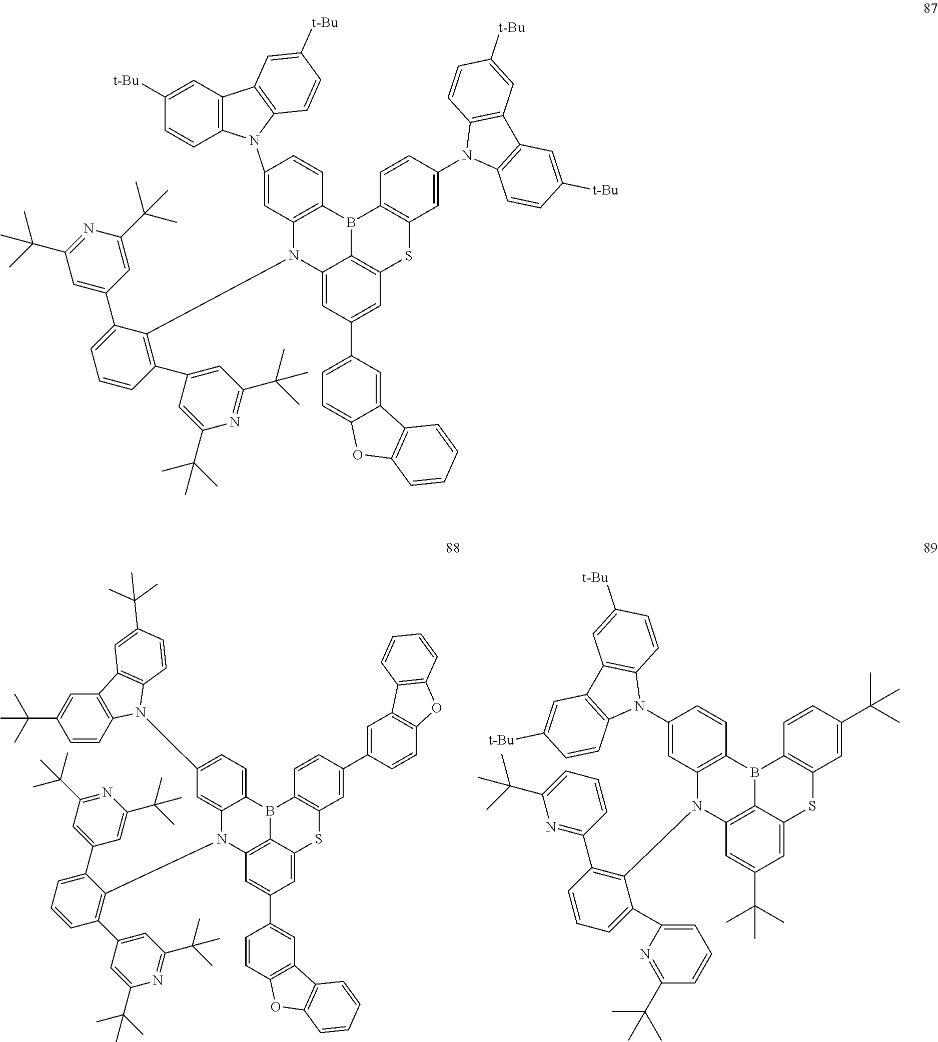

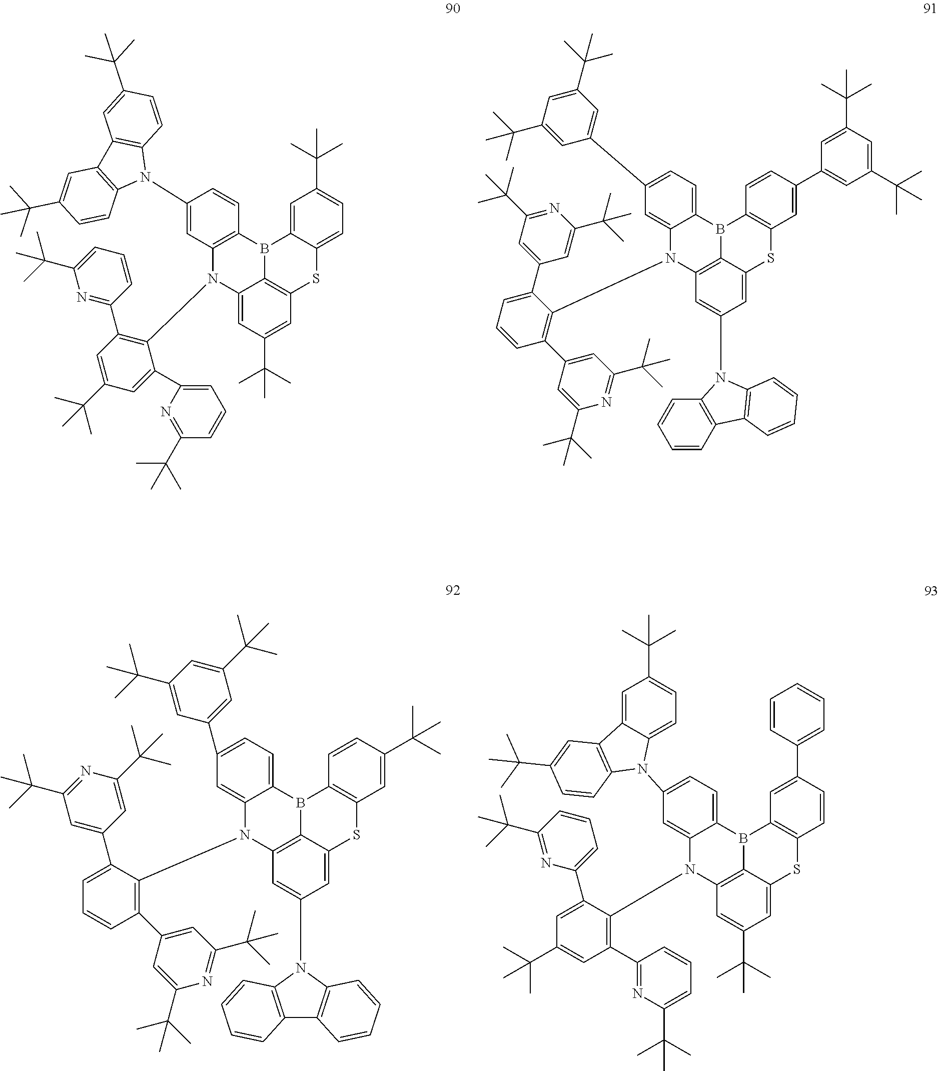

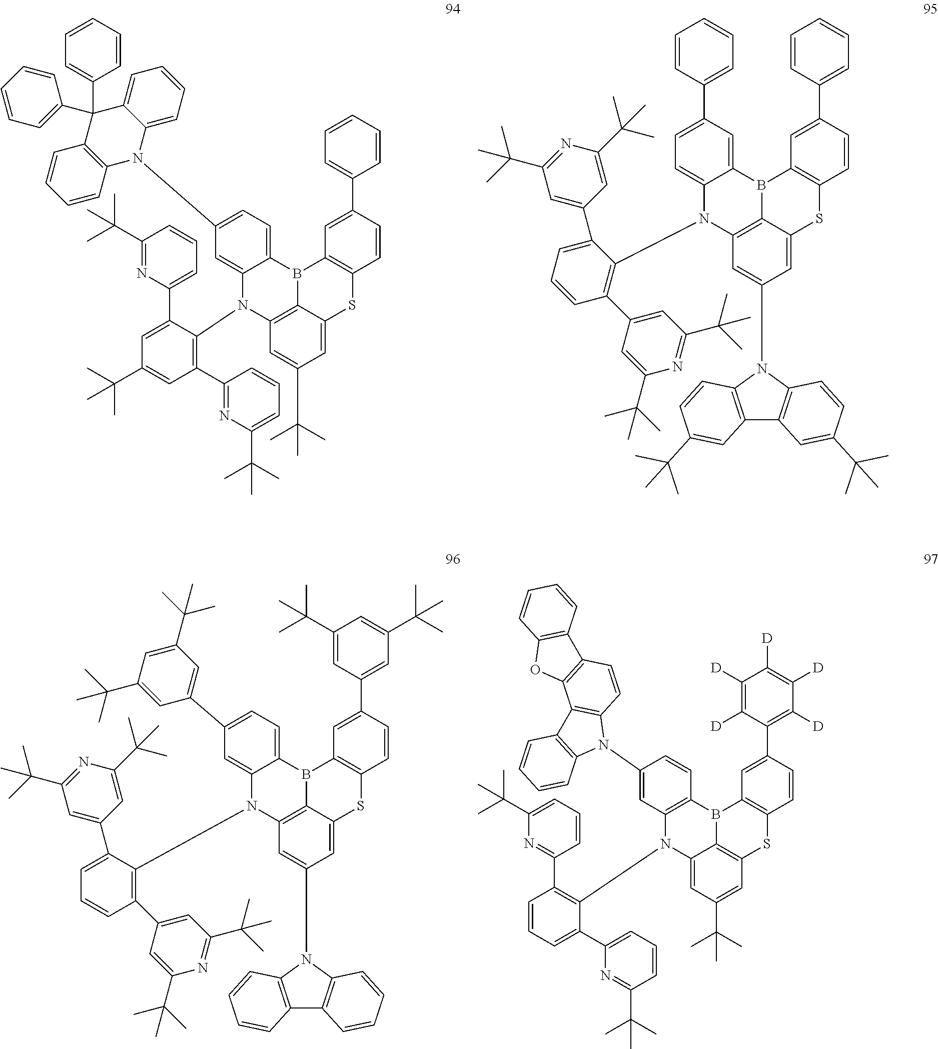

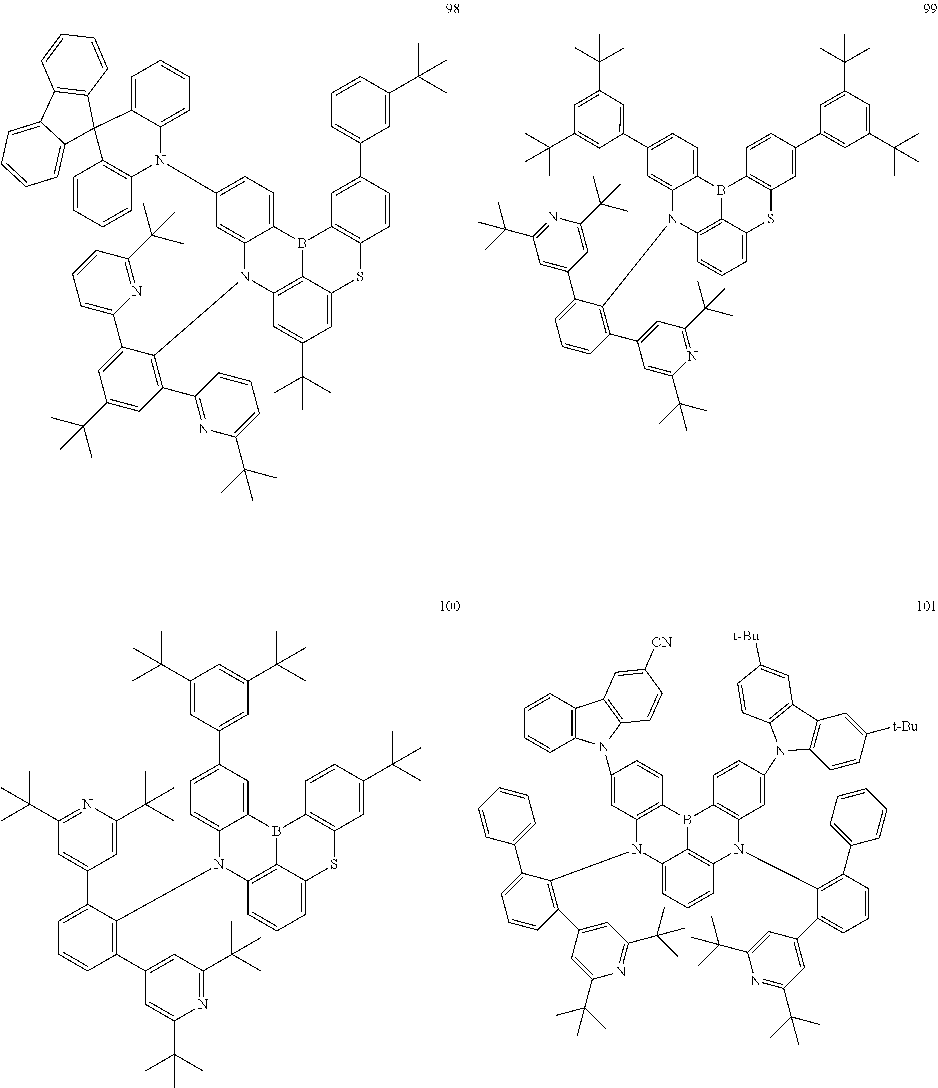

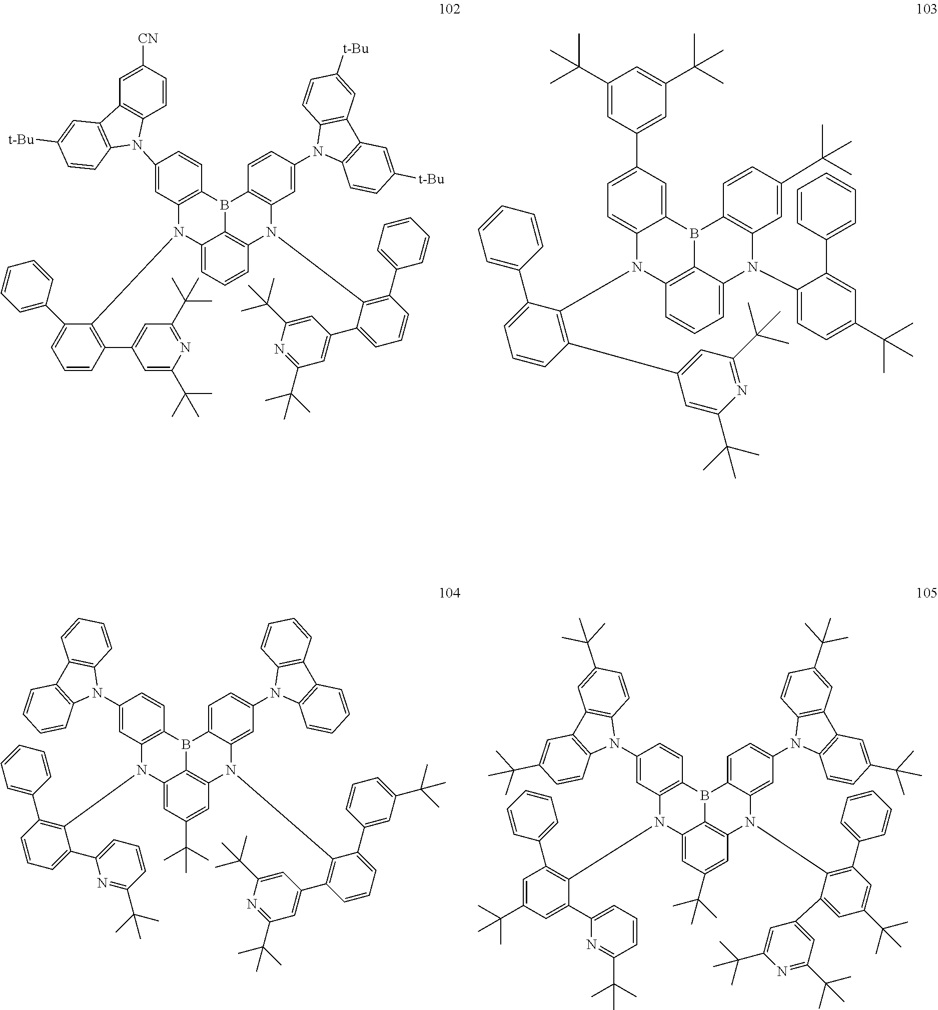

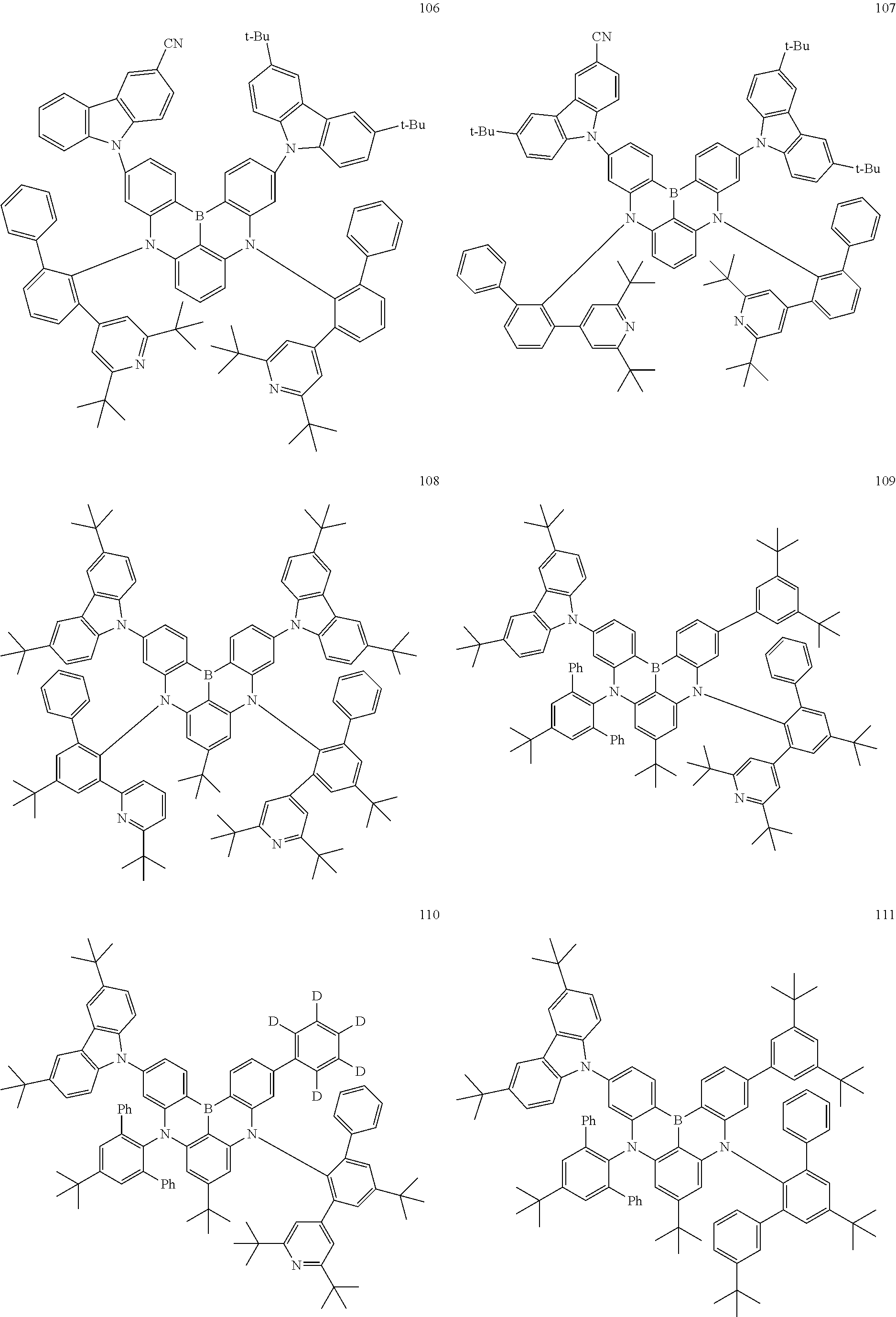

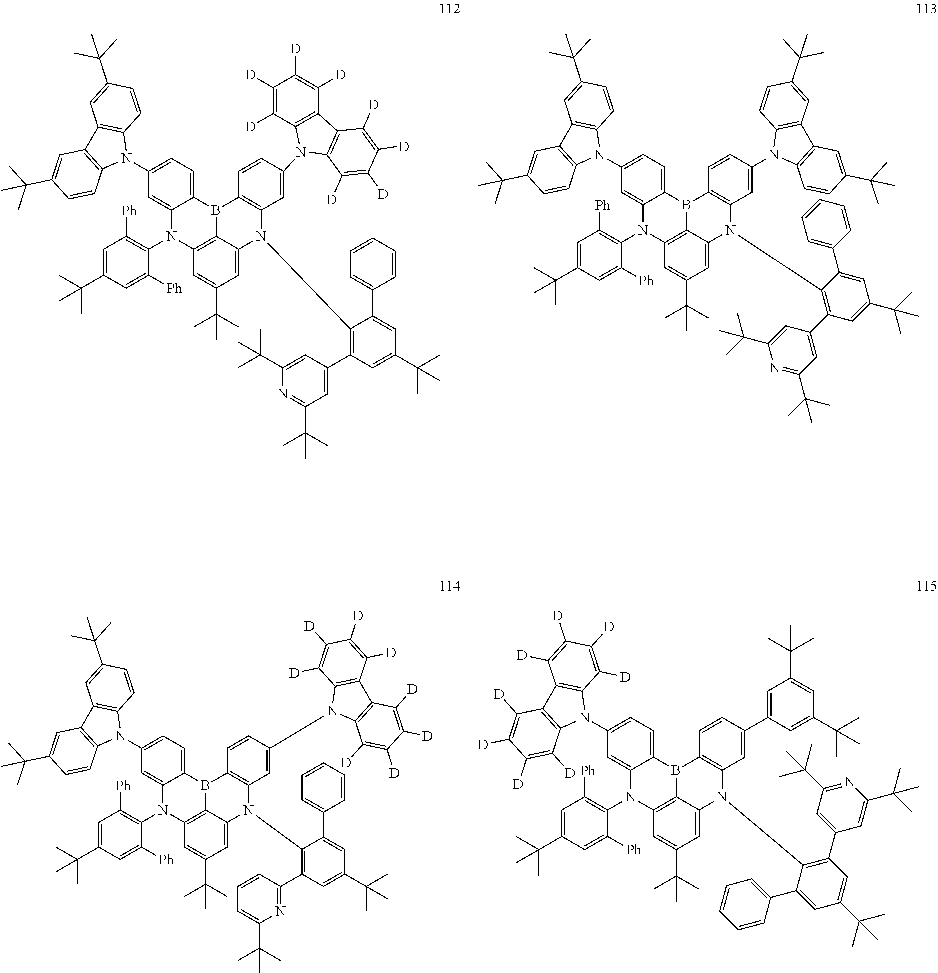

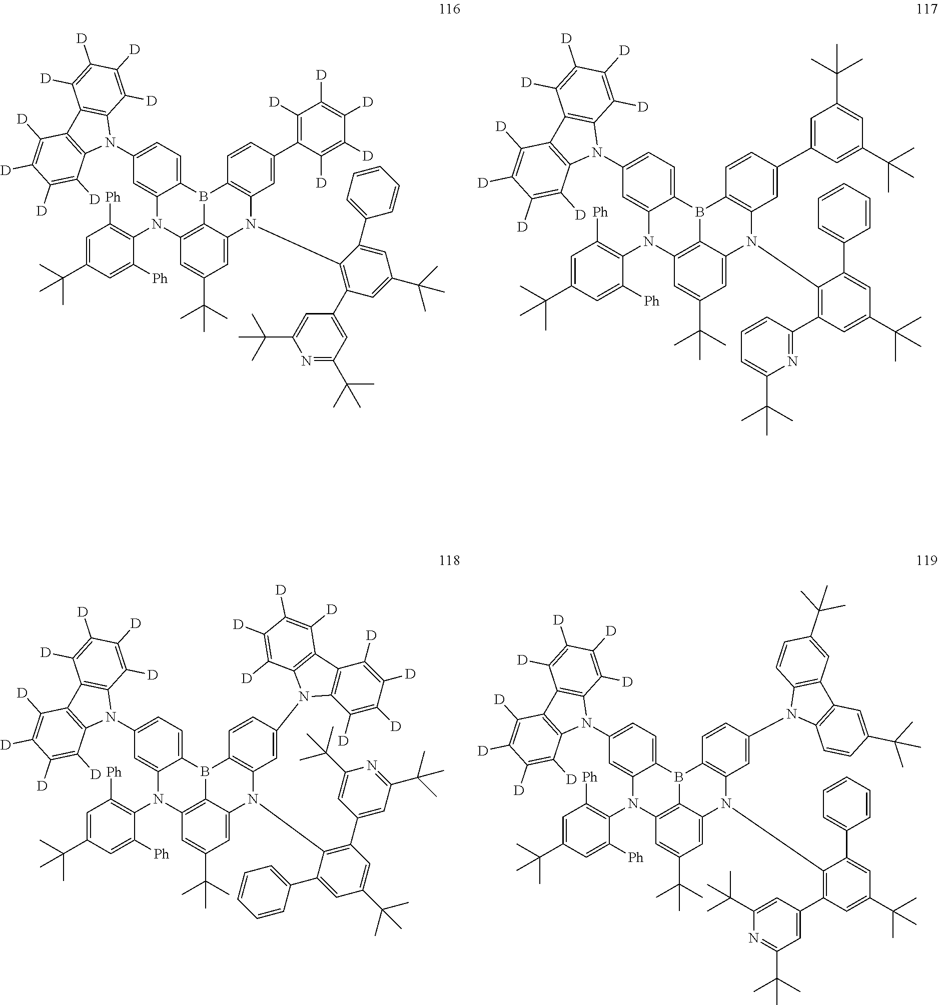

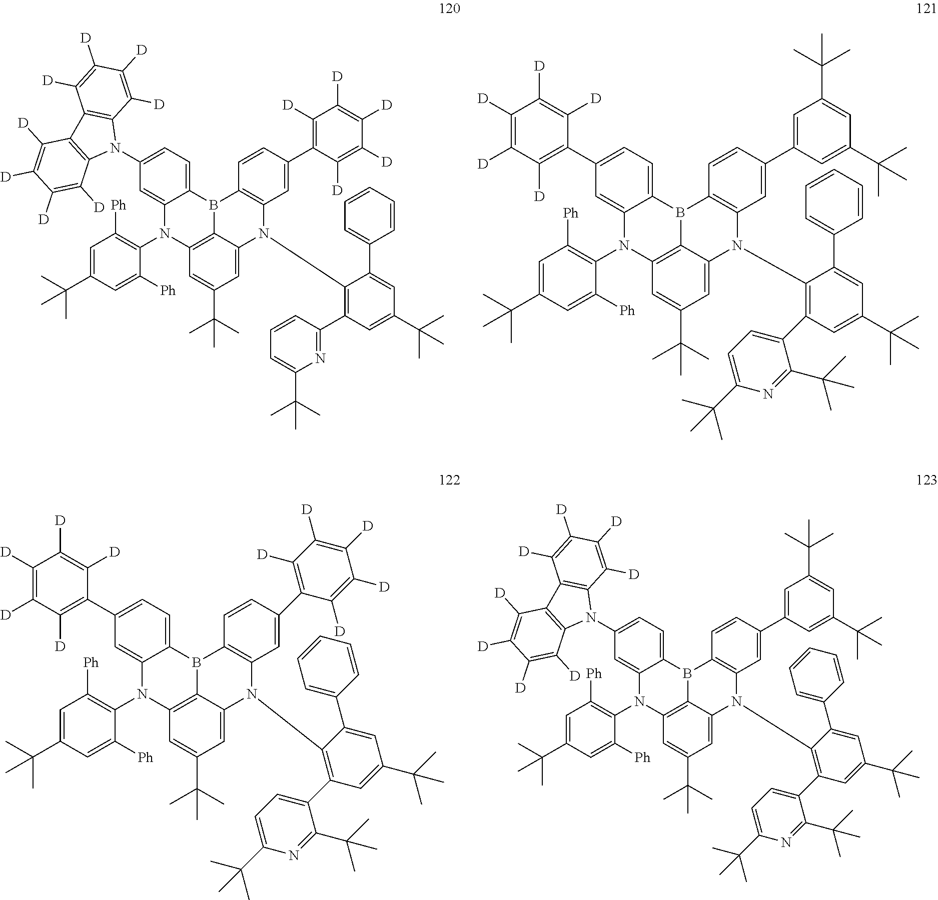

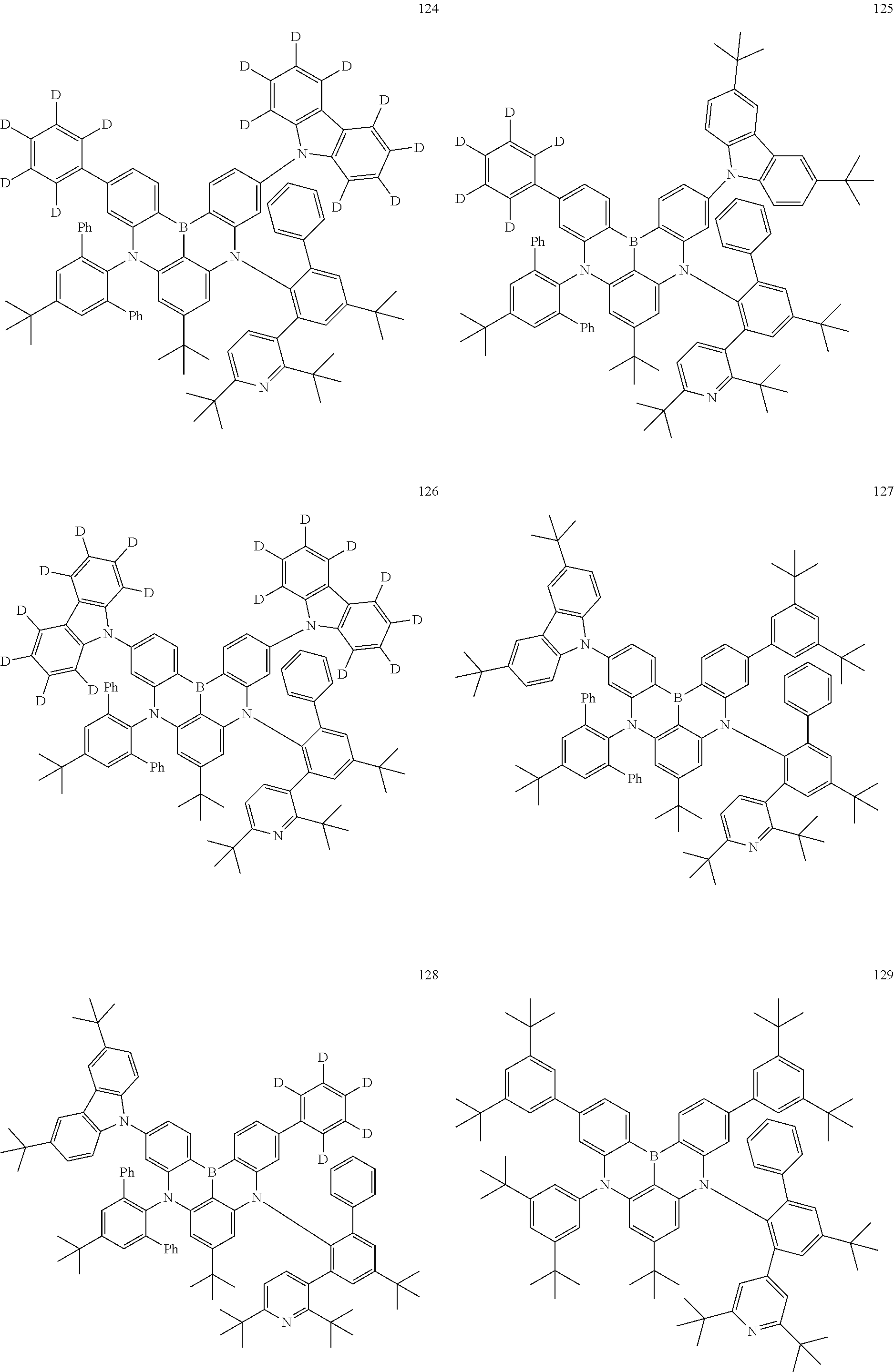

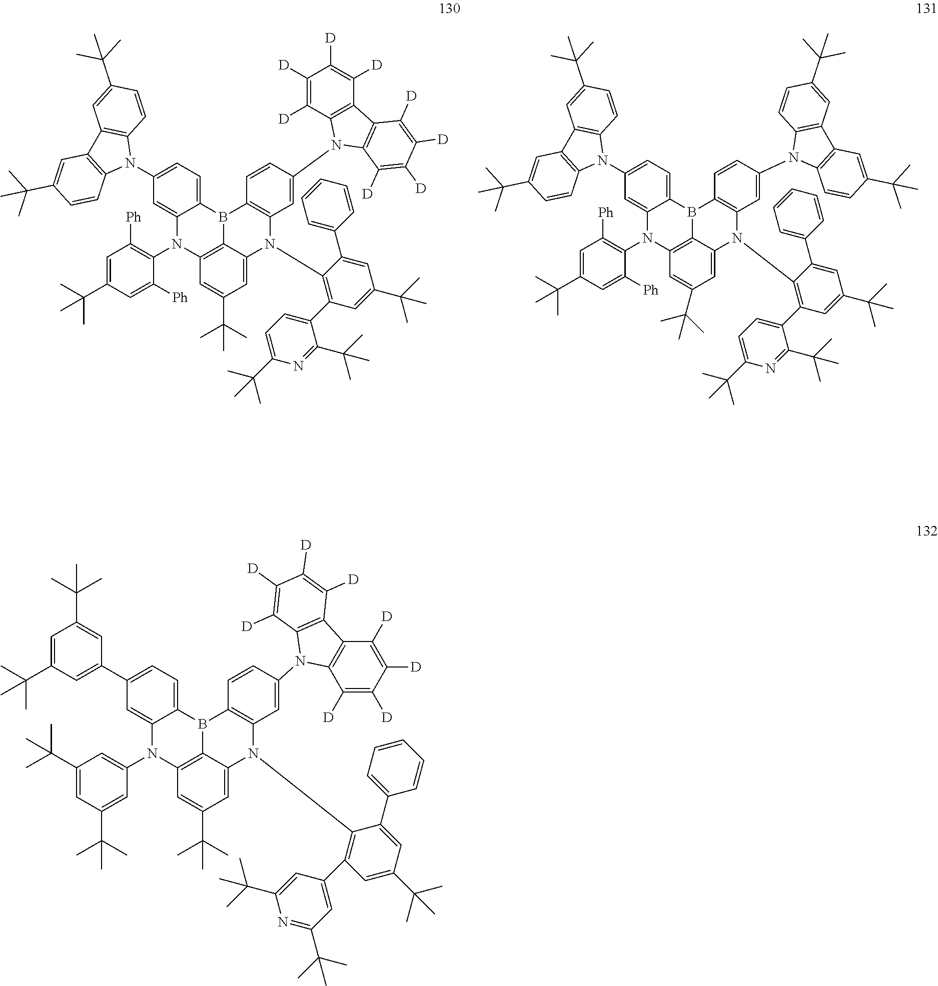

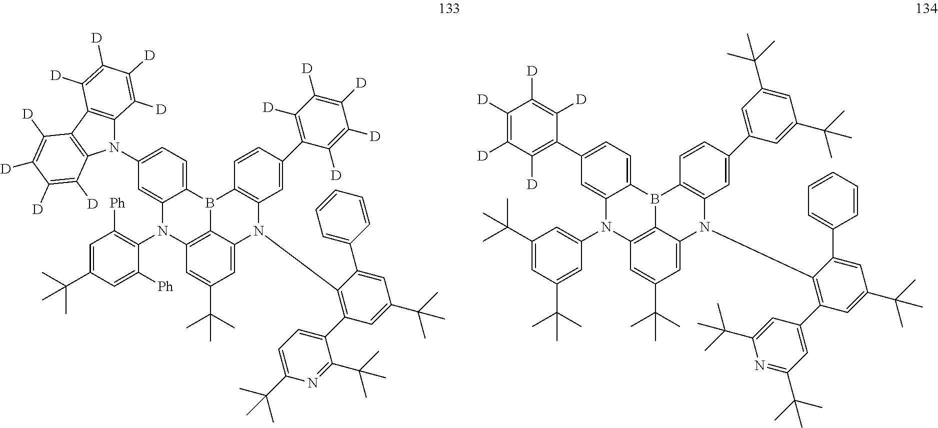 [SMILES: [2H]c1c([2H])c([2H])c(-c2ccc3c(c2)N(c2c(-c4ccccc4)cc(C(C)(C)C)cc2-c2ccc(C(C)(C)C)nc2C(C)(C)C)c2cc(C(C)(C)C)cc4c2B3c2ccc(-n3c5c([2H])c([2H])c([2H])c([2H])c5c5c([2H])c([2H])c([2H])c([2H])c53)cc2N4c2c(-c3ccccc3)cc(C(C)(C)C)cc2-c2ccccc2)c([2H])c1[2H] ; [2H]c1c([2H])c([2H])c(-c2ccc3c(c2)N(c2cc(C(C)(C)C)cc(C(C)(C)C)c2)c2cc(C(C)(C)C)cc4c2B3c2ccc(-c3cc(C(C)(C)C)cc(C(C)(C)C)c3)cc2N4c2c(-c3ccccc3)cc(C(C)(C)C)cc2-c2cc(C(C)(C)C)nc(C(C)(C)C)c2)c([2H])c1[2H]]

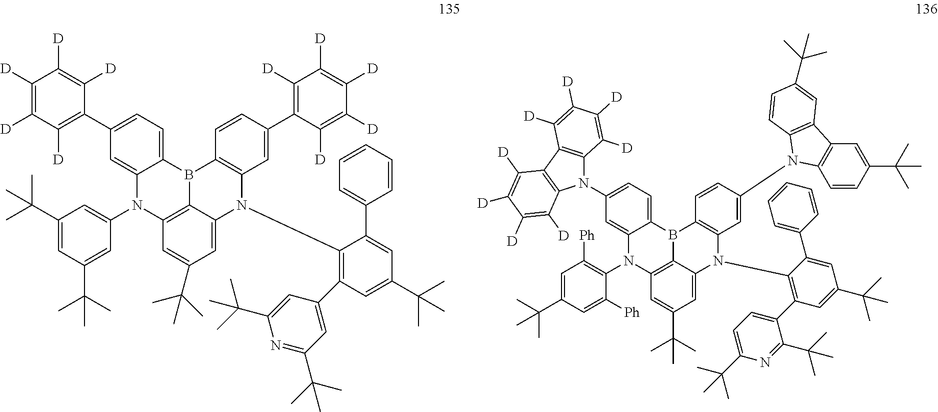 [SMILES: [2H]c1c([2H])c([2H])c(-c2ccc3c(c2)N(c2cc(C(C)(C)C)cc(C(C)(C)C)c2)c2cc(C(C)(C)C)cc4c2B3c2ccc(-c3c([2H])c([2H])c([2H])c([2H])c3[2H])cc2N4c2c(-c3ccccc3)cc(C(C)(C)C)cc2-c2cc(C(C)(C)C)nc(C(C)(C)C)c2)c([2H])c1[2H] ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4ccc(C(C)(C)C)cc4c4cc(C(C)(C)C)ccc42)cc1N3c1c(-c2ccccc2)cc(C(C)(C)C)cc1-c1ccc(C(C)(C)C)nc1C(C)(C)C]

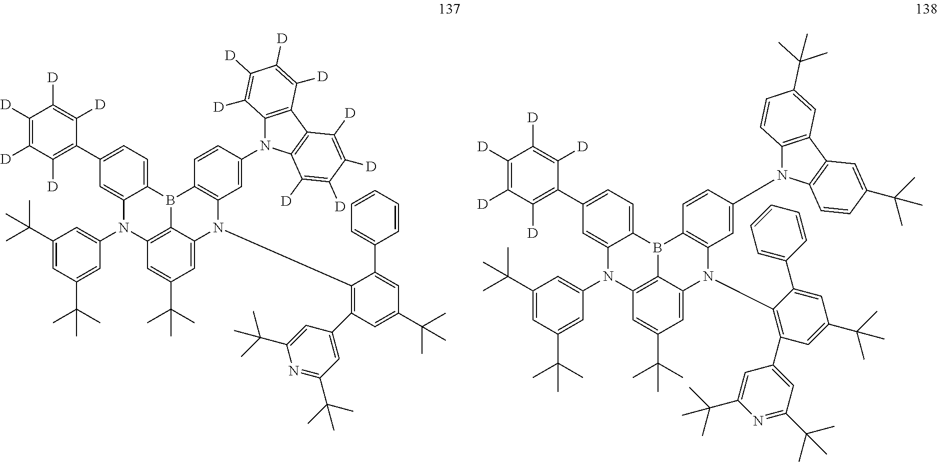 [SMILES: [2H]c1c([2H])c([2H])c(-c2ccc3c(c2)N(c2cc(C(C)(C)C)cc(C(C)(C)C)c2)c2cc(C(C)(C)C)cc4c2B3c2ccc(-n3c5c([2H])c([2H])c([2H])c([2H])c5c5c([2H])c([2H])c([2H])c([2H])c53)cc2N4c2c(-c3ccccc3)cc(C(C)(C)C)cc2-c2cc(C(C)(C)C)nc(C(C)(C)C)c2)c([2H])c1[2H] ; [2H]c1c([2H])c([2H])c(-c2ccc3c(c2)N(c2cc(C(C)(C)C)cc(C(C)(C)C)c2)c2cc(C(C)(C)C)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2cc(C(C)(C)C)nc(C(C)(C)C)c2)c([2H])c1[2H]]

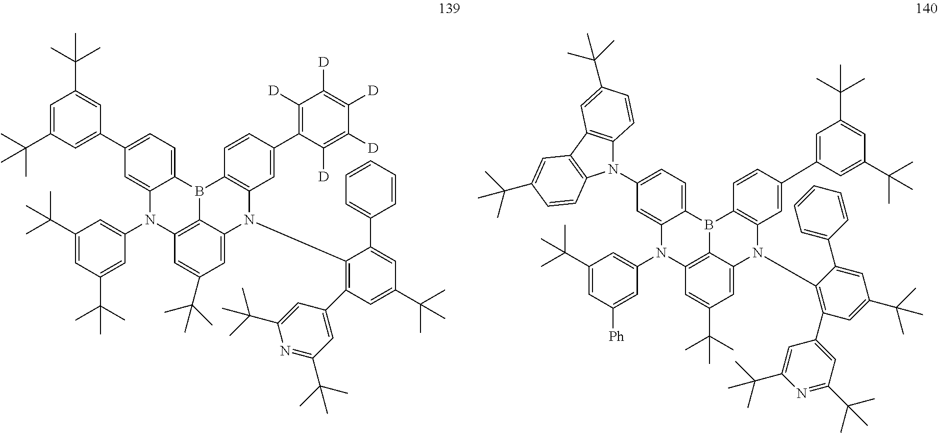 [SMILES: [2H]c1c([2H])c([2H])c(-c2ccc3c(c2)N(c2c(-c4ccccc4)cc(C(C)(C)C)cc2-c2cc(C(C)(C)C)nc(C(C)(C)C)c2)c2cc(C(C)(C)C)cc4c2B3c2ccc(-c3cc(C(C)(C)C)cc(C(C)(C)C)c3)cc2N4c2cc(C(C)(C)C)cc(C(C)(C)C)c2)c([2H])c1[2H] ; CC(C)(C)c1cc(-c2ccccc2)cc(N2c3cc(-n4c5ccc(C(C)(C)C)cc5c5cc(C(C)(C)C)ccc54)ccc3B3c4ccc(-c5cc(C(C)(C)C)cc(C(C)(C)C)c5)cc4N(c4c(-c5ccccc5)cc(C(C)(C)C)cc4-c4cc(C(C)(C)C)nc(C(C)(C)C)c4)c4cc(C(C)(C)C)cc2c43)c1]

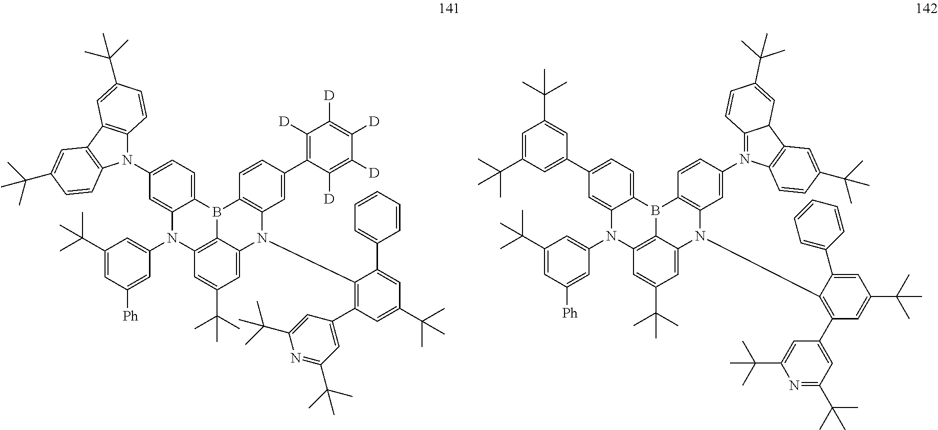

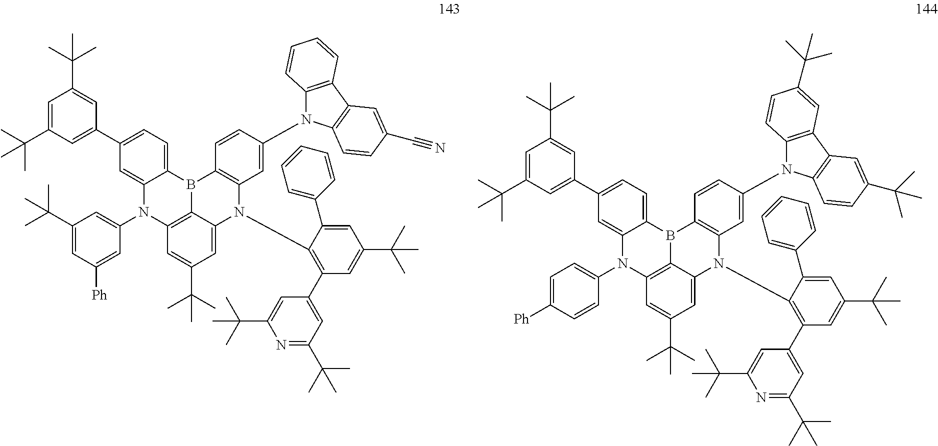 [SMILES: CC(C)(C)c1cc(-c2ccccc2)cc(N2c3cc(-c4cc(C(C)(C)C)cc(C(C)(C)C)c4)ccc3B3c4ccc(-n5c6ccccc6c6cc(C#N)ccc65)cc4N(c4c(-c5ccccc5)cc(C(C)(C)C)cc4-c4cc(C(C)(C)C)nc(C(C)(C)C)c4)c4cc(C(C)(C)C)cc2c43)c1 ; CC(C)(C)c1cc(-c2ccc3c(c2)N(c2ccc(-c4ccccc4)cc2)c2cc(C(C)(C)C)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2cc(C(C)(C)C)nc(C(C)(C)C)c2)cc(C(C)(C)C)c1]

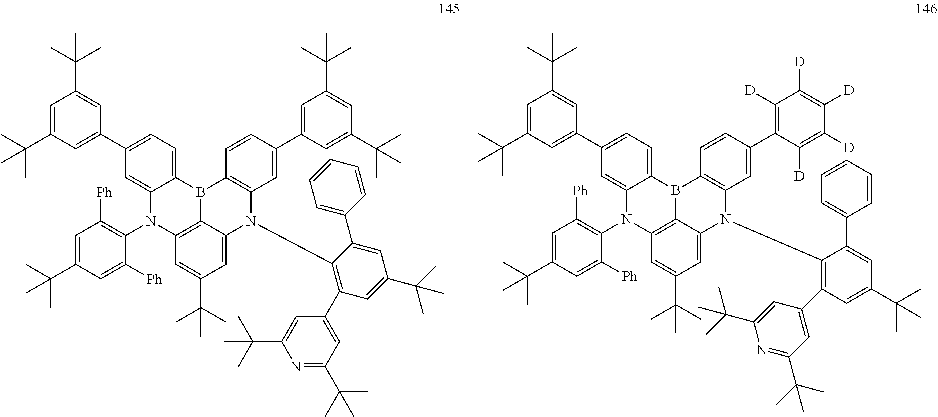 [SMILES: CC(C)(C)c1cc(-c2ccc3c(c2)N(c2c(-c4ccccc4)cc(C(C)(C)C)cc2-c2ccccc2)c2cc(C(C)(C)C)cc4c2B3c2ccc(-c3cc(C(C)(C)C)cc(C(C)(C)C)c3)cc2N4c2c(-c3ccccc3)cc(C(C)(C)C)cc2-c2cc(C(C)(C)C)nc(C(C)(C)C)c2)cc(C(C)(C)C)c1 ; [2H]c1c([2H])c([2H])c(-c2ccc3c(c2)N(c2c(-c4ccccc4)cc(C(C)(C)C)cc2-c2cc(C(C)(C)C)nc(C(C)(C)C)c2)c2cc(C(C)(C)C)cc4c2B3c2ccc(-c3cc(C(C)(C)C)cc(C(C)(C)C)c3)cc2N4c2c(-c3ccccc3)cc(C(C)(C)C)cc2-c2ccccc2)c([2H])c1[2H]]

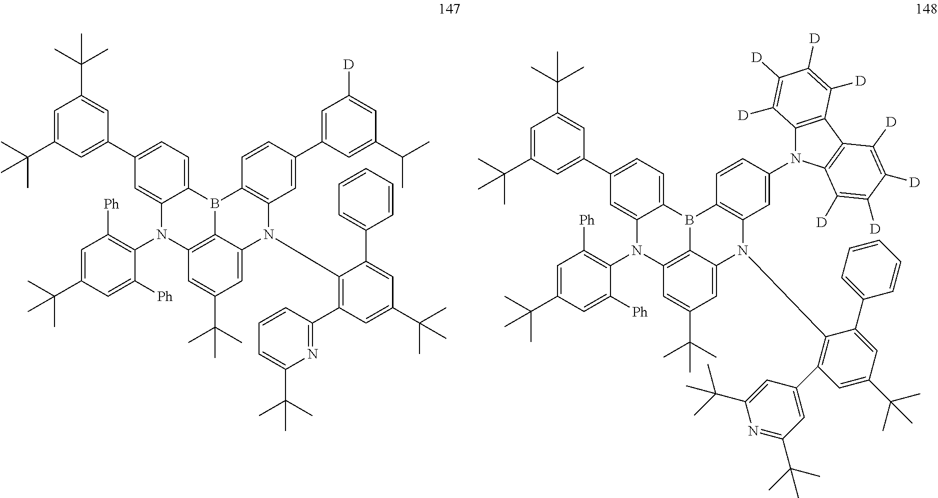 [SMILES: [2H]c1cc(-c2ccc3c(c2)N(c2c(-c4ccccc4)cc(C(C)(C)C)cc2-c2cccc(C(C)(C)C)n2)c2cc(C(C)(C)C)cc4c2B3c2ccc(-c3cc(C(C)(C)C)cc(C(C)(C)C)c3)cc2N4c2c(-c3ccccc3)cc(C(C)(C)C)cc2-c2ccccc2)cc(C(C)C)c1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cc(C(C)(C)C)nc(C(C)(C)C)c1)c1cc(C(C)(C)C)cc3c1B2c1ccc(-c2cc(C(C)(C)C)cc(C(C)(C)C)c2)cc1N3c1c(-c2ccccc2)cc(C(C)(C)C)cc1-c1ccccc1]

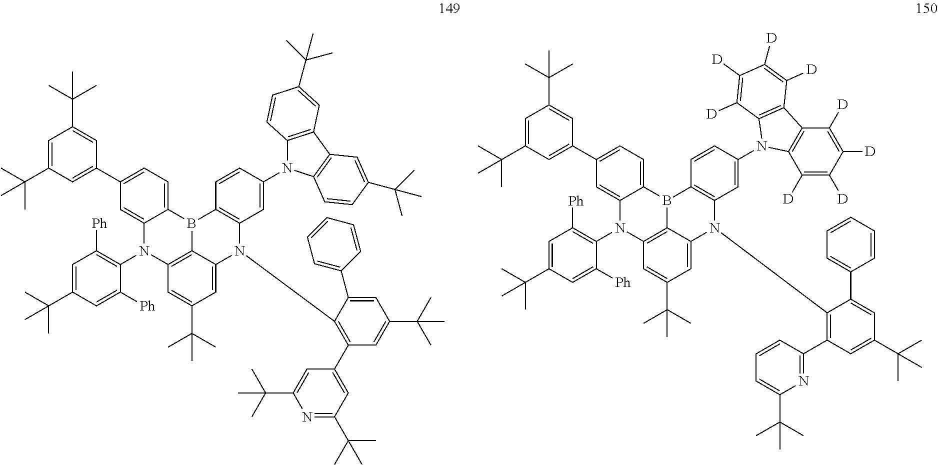 [SMILES: CC(C)(C)c1cc(-c2ccc3c(c2)N(c2c(-c4ccccc4)cc(C(C)(C)C)cc2-c2ccccc2)c2cc(C(C)(C)C)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2cc(C(C)(C)C)nc(C(C)(C)C)c2)cc(C(C)(C)C)c1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc(C(C)(C)C)n1)c1cc(C(C)(C)C)cc3c1B2c1ccc(-c2cc(C(C)(C)C)cc(C(C)(C)C)c2)cc1N3c1c(-c2ccccc2)cc(C(C)(C)C)cc1-c1ccccc1]

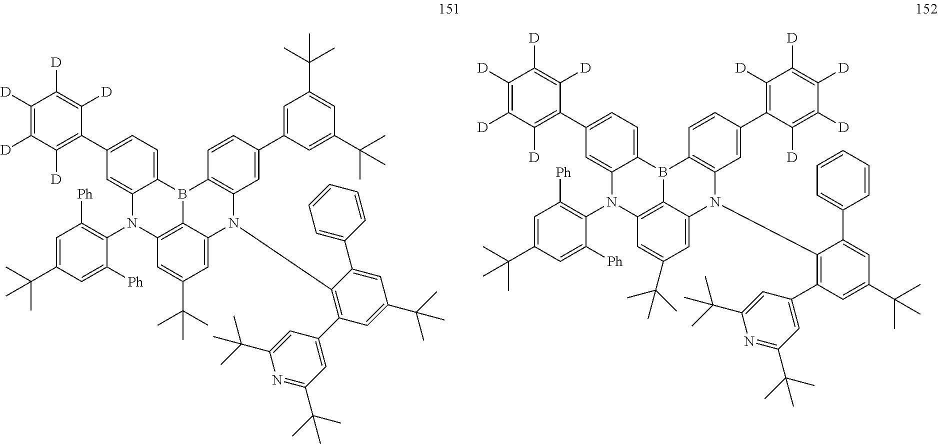 [SMILES: [2H]c1c([2H])c([2H])c(-c2ccc3c(c2)N(c2c(-c4ccccc4)cc(C(C)(C)C)cc2-c2ccccc2)c2cc(C(C)(C)C)cc4c2B3c2ccc(-c3cc(C(C)(C)C)cc(C(C)(C)C)c3)cc2N4c2c(-c3ccccc3)cc(C(C)(C)C)cc2-c2cc(C(C)(C)C)nc(C(C)(C)C)c2)c([2H])c1[2H] ; [2H]c1c([2H])c([2H])c(-c2ccc3c(c2)N(c2c(-c4ccccc4)cc(C(C)(C)C)cc2-c2ccccc2)c2cc(C(C)(C)C)cc4c2B3c2ccc(-c3c([2H])c([2H])c([2H])c([2H])c3[2H])cc2N4c2c(-c3ccccc3)cc(C(C)(C)C)cc2-c2cc(C(C)(C)C)nc(C(C)(C)C)c2)c([2H])c1[2H]]

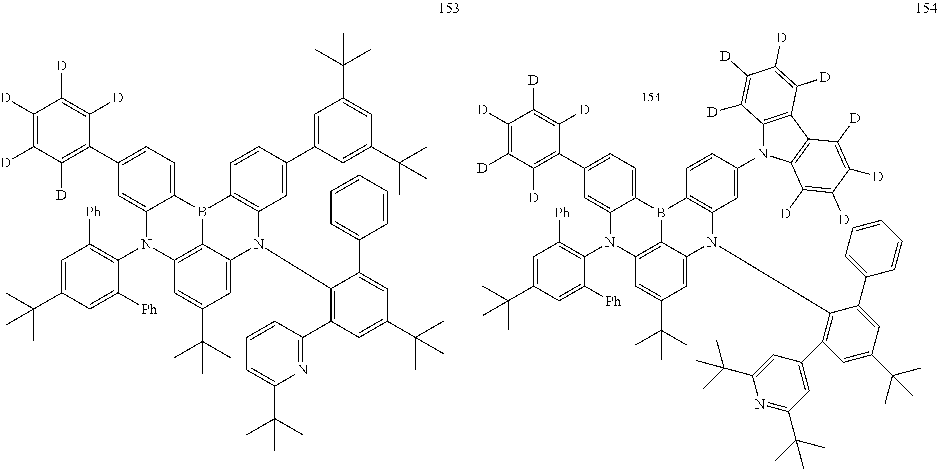

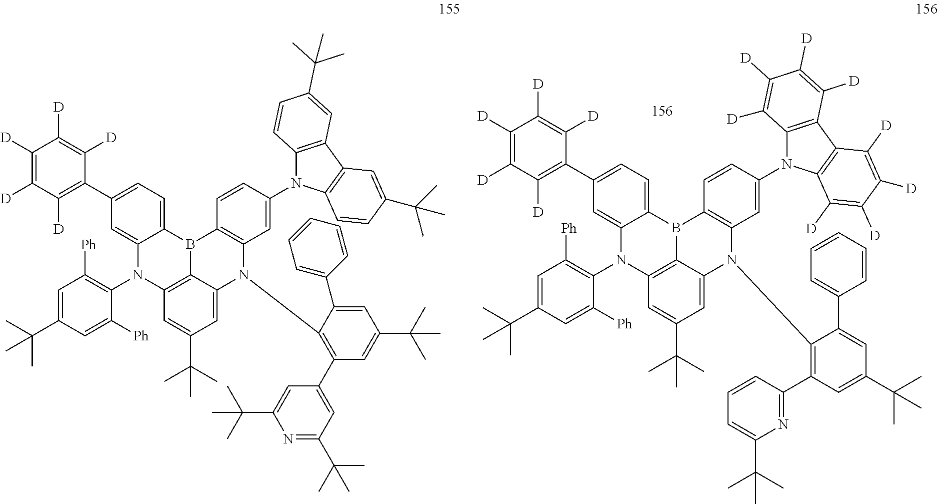 [SMILES: [2H]c1c([2H])c([2H])c(-c2ccc3c(c2)N(c2c(-c4ccccc4)cc(C(C)(C)C)cc2-c2ccccc2)c2cc(C(C)(C)C)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2cc(C(C)(C)C)nc(C(C)(C)C)c2)c([2H])c1[2H] ; [2H]c1c([2H])c([2H])c(-c2ccc3c(c2)N(c2c(-c4ccccc4)cc(C(C)(C)C)cc2-c2ccccc2)c2cc(C(C)(C)C)cc4c2B3c2ccc(-n3c5c([2H])c([2H])c([2H])c([2H])c5c5c([2H])c([2H])c([2H])c([2H])c53)cc2N4c2c(-c3ccccc3)cc(C(C)(C)C)cc2-c2cccc(C(C)(C)C)n2)c([2H])c1[2H]]

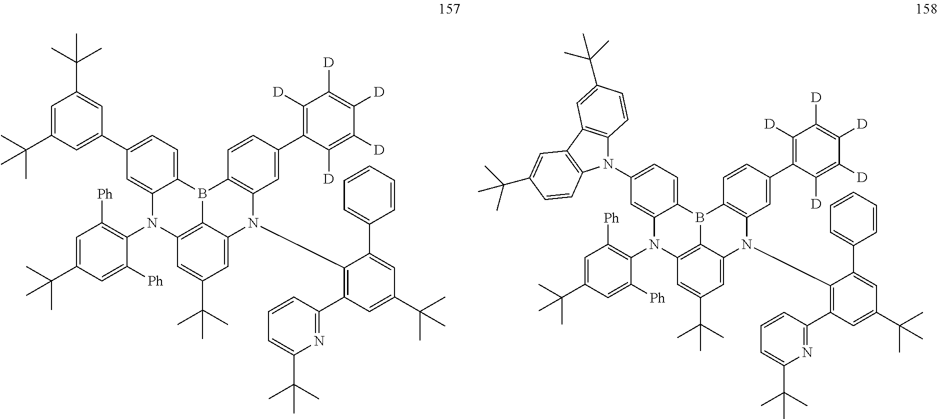 [SMILES: [2H]c1c([2H])c([2H])c(-c2ccc3c(c2)N(c2c(-c4ccccc4)cc(C(C)(C)C)cc2-c2cccc(C(C)(C)C)n2)c2cc(C(C)(C)C)cc4c2B3c2ccc(-c3cc(C(C)(C)C)cc(C(C)(C)C)c3)cc2N4c2c(-c3ccccc3)cc(C(C)(C)C)cc2-c2ccccc2)c([2H])c1[2H] ; [2H]c1c([2H])c([2H])c(-c2ccc3c(c2)N(c2c(-c4ccccc4)cc(C(C)(C)C)cc2-c2cccc(C(C)(C)C)n2)c2cc(C(C)(C)C)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2ccccc2)c([2H])c1[2H]]

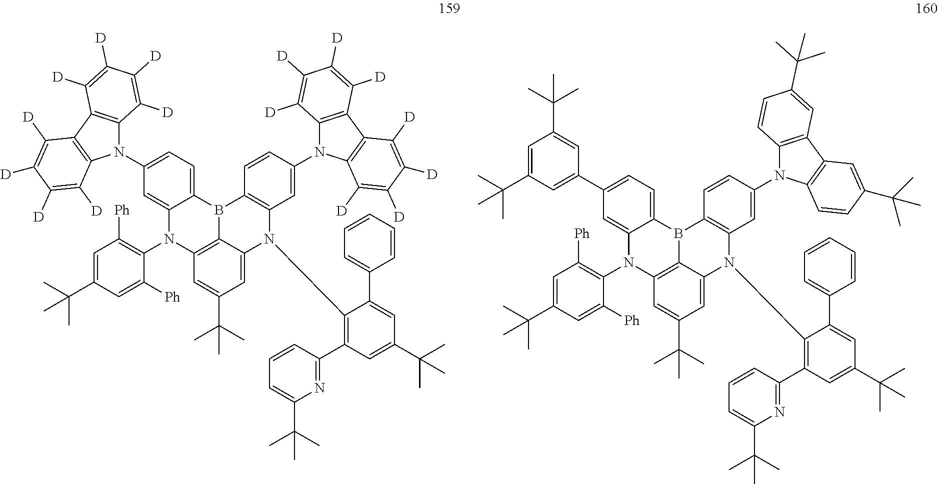 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc(C(C)(C)C)n1 ; CC(C)(C)c1cc(-c2ccc3c(c2)N(c2c(-c4ccccc4)cc(C(C)(C)C)cc2-c2ccccc2)c2cc(C(C)(C)C)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2cccc(C(C)(C)C)n2)cc(C(C)(C)C)c1]

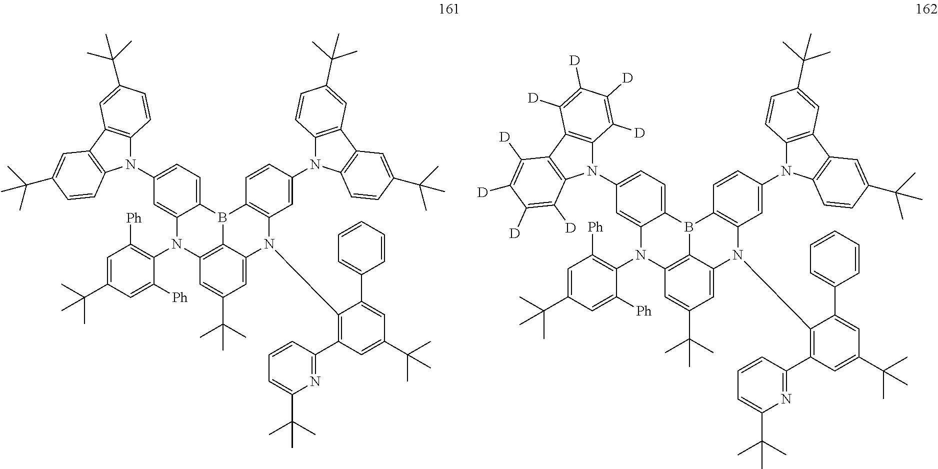

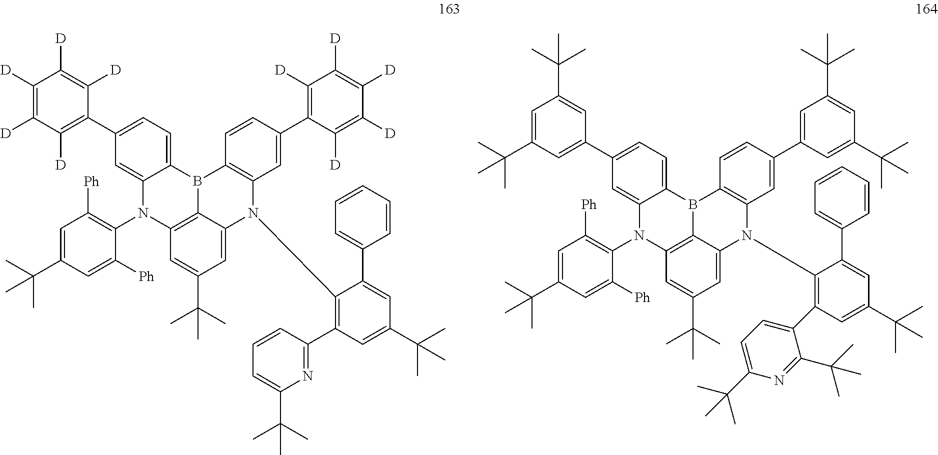 [SMILES: [2H]c1c([2H])c([2H])c(-c2ccc3c(c2)N(c2c(-c4ccccc4)cc(C(C)(C)C)cc2-c2ccccc2)c2cc(C(C)(C)C)cc4c2B3c2ccc(-c3c([2H])c([2H])c([2H])c([2H])c3[2H])cc2N4c2c(-c3ccccc3)cc(C(C)(C)C)cc2-c2cccc(C(C)(C)C)n2)c([2H])c1[2H] ; CC(C)(C)c1cc(-c2ccc3c(c2)N(c2c(-c4ccccc4)cc(C(C)(C)C)cc2-c2ccccc2)c2cc(C(C)(C)C)cc4c2B3c2ccc(-c3cc(C(C)(C)C)cc(C(C)(C)C)c3)cc2N4c2c(-c3ccccc3)cc(C(C)(C)C)cc2-c2ccc(C(C)(C)C)nc2C(C)(C)C)cc(C(C)(C)C)c1]

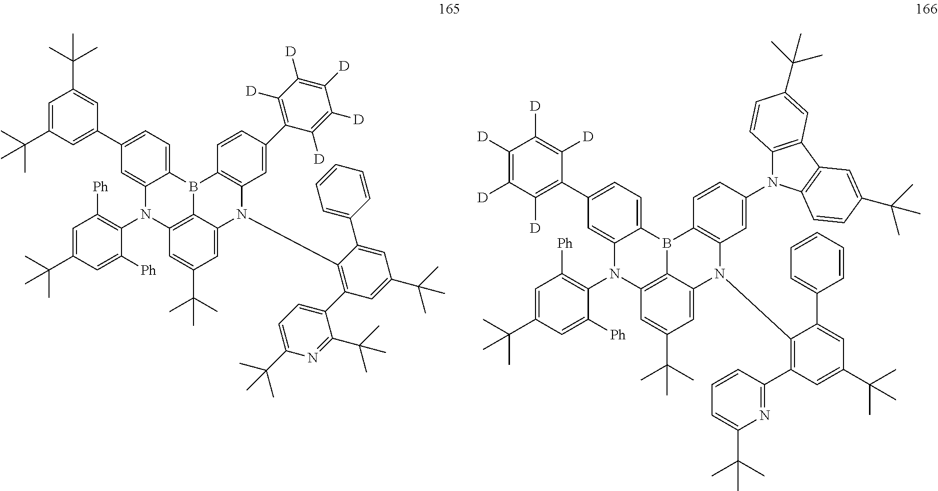 [SMILES: [2H]c1c([2H])c([2H])c(-c2ccc3c(c2)N(c2c(-c4ccccc4)cc(C(C)(C)C)cc2-c2ccc(C(C)(C)C)nc2C(C)(C)C)c2cc(C(C)(C)C)cc4c2B3c2ccc(-c3cc(C(C)(C)C)cc(C(C)(C)C)c3)cc2N4c2c(-c3ccccc3)cc(C(C)(C)C)cc2-c2ccccc2)c([2H])c1[2H] ; [2H]c1c([2H])c([2H])c(-c2ccc3c(c2)N(c2c(-c4ccccc4)cc(C(C)(C)C)cc2-c2ccccc2)c2cc(C(C)(C)C)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2cccc(C(C)(C)C)n2)c([2H])c1[2H]]

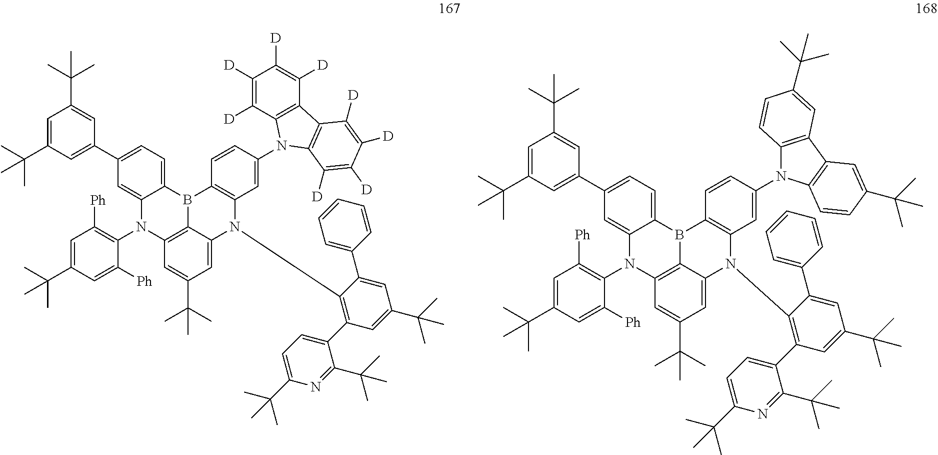 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccc(C(C)(C)C)nc1C(C)(C)C)c1cc(C(C)(C)C)cc3c1B2c1ccc(-c2cc(C(C)(C)C)cc(C(C)(C)C)c2)cc1N3c1c(-c2ccccc2)cc(C(C)(C)C)cc1-c1ccccc1 ; CC(C)(C)c1cc(-c2ccc3c(c2)N(c2c(-c4ccccc4)cc(C(C)(C)C)cc2-c2ccccc2)c2cc(C(C)(C)C)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2ccc(C(C)(C)C)nc2C(C)(C)C)cc(C(C)(C)C)c1]

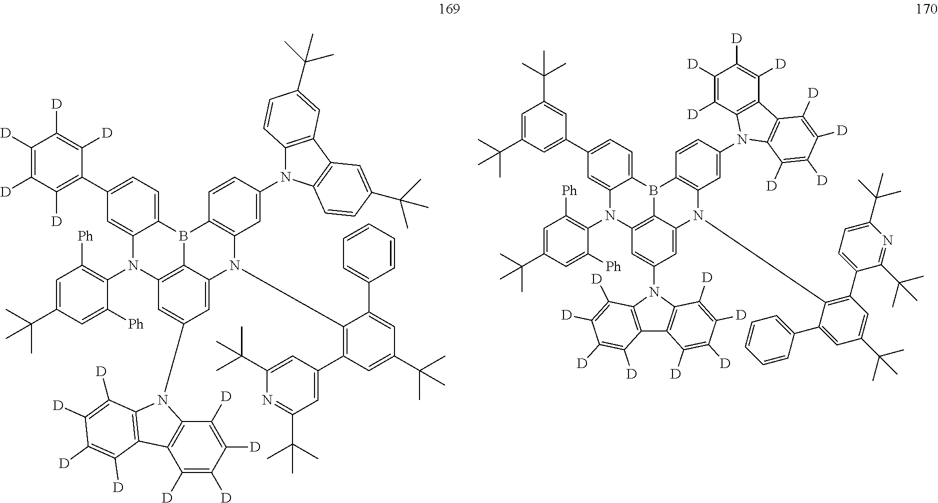

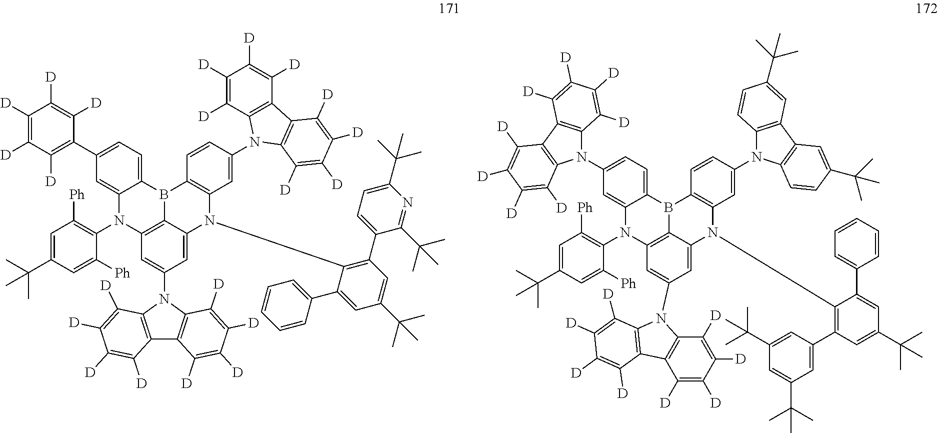

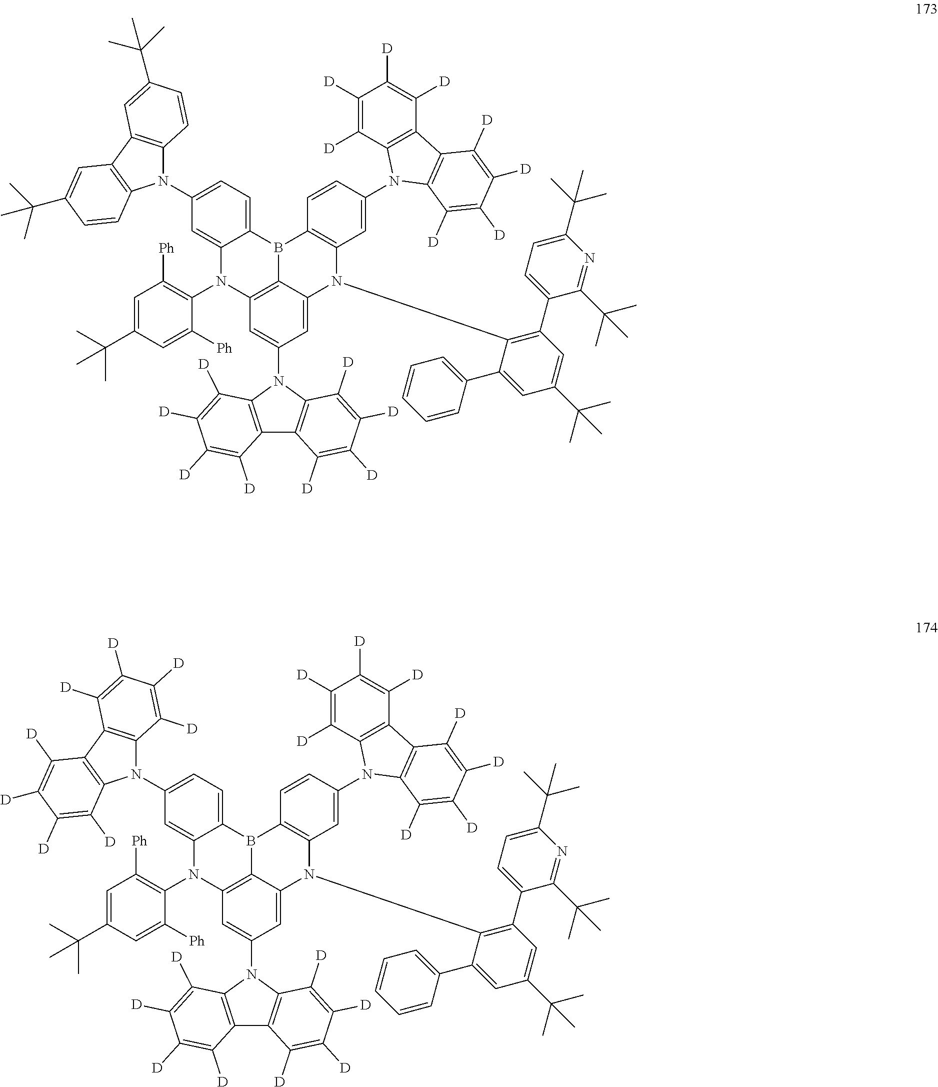

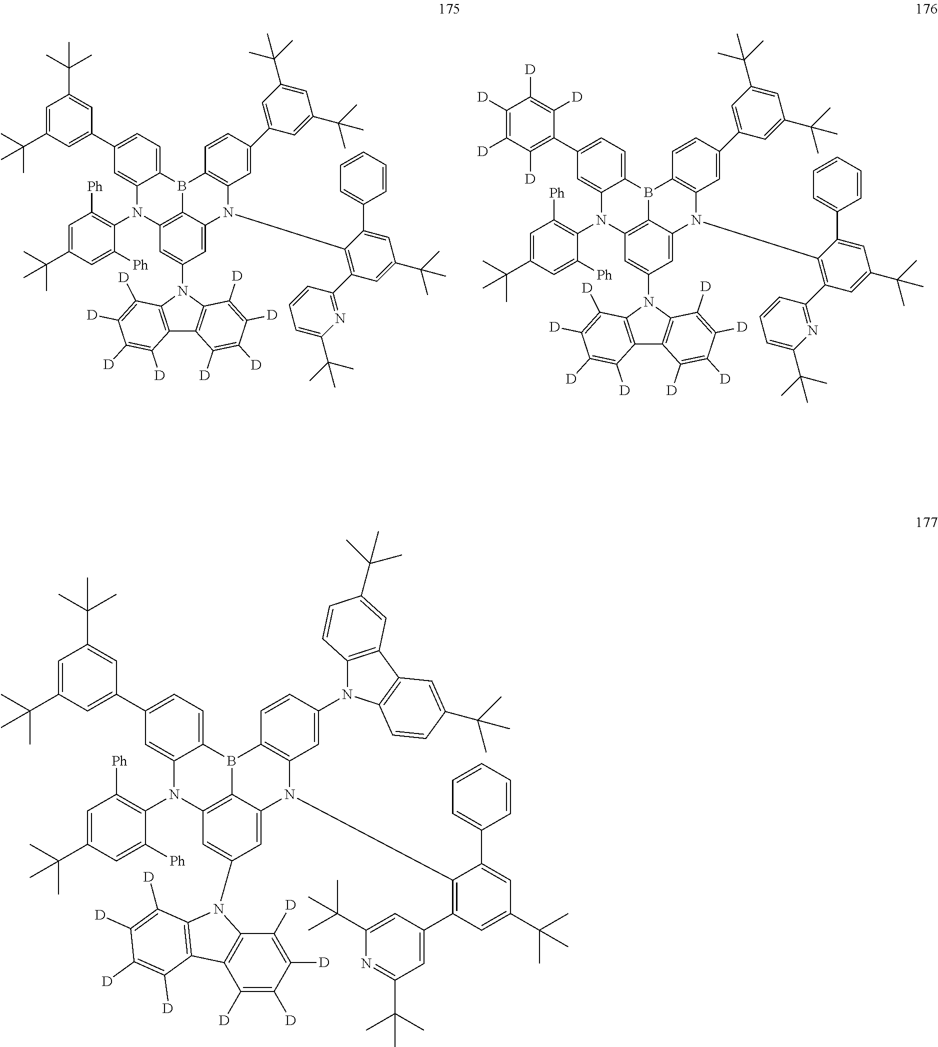

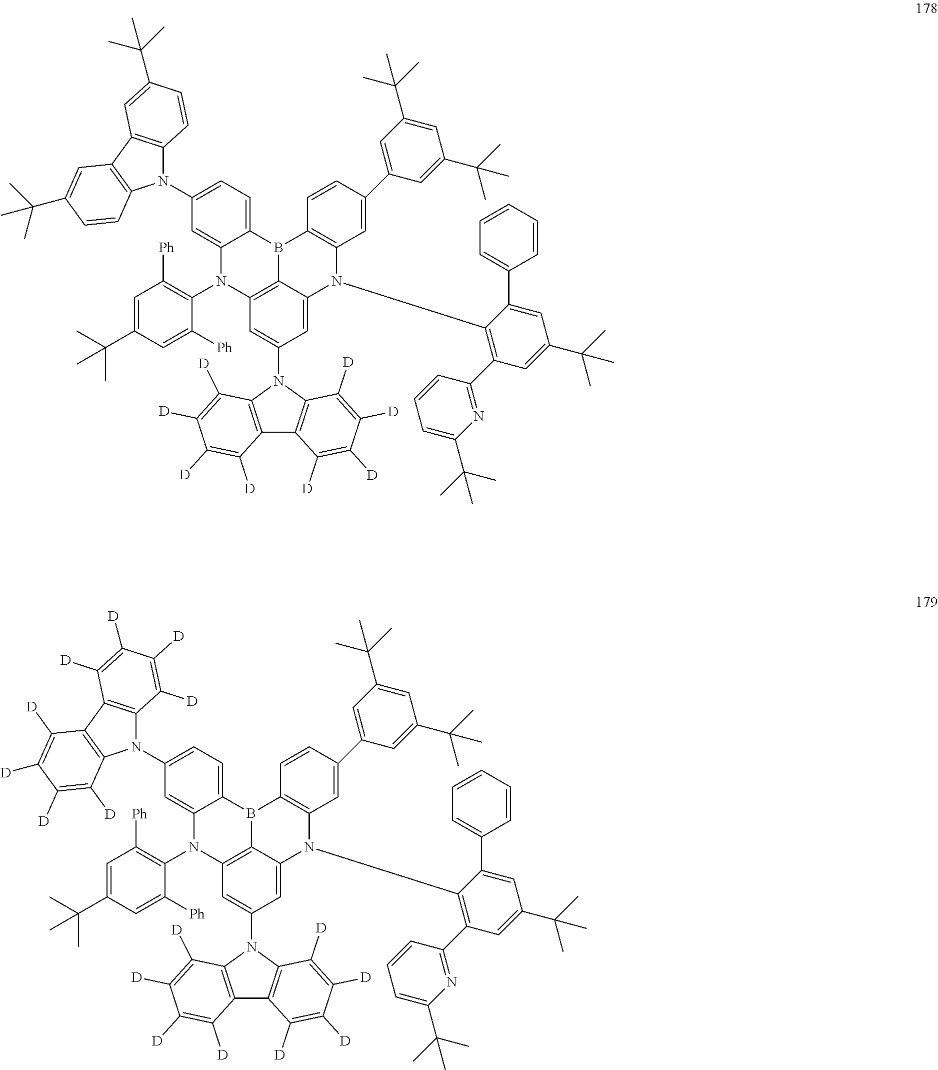

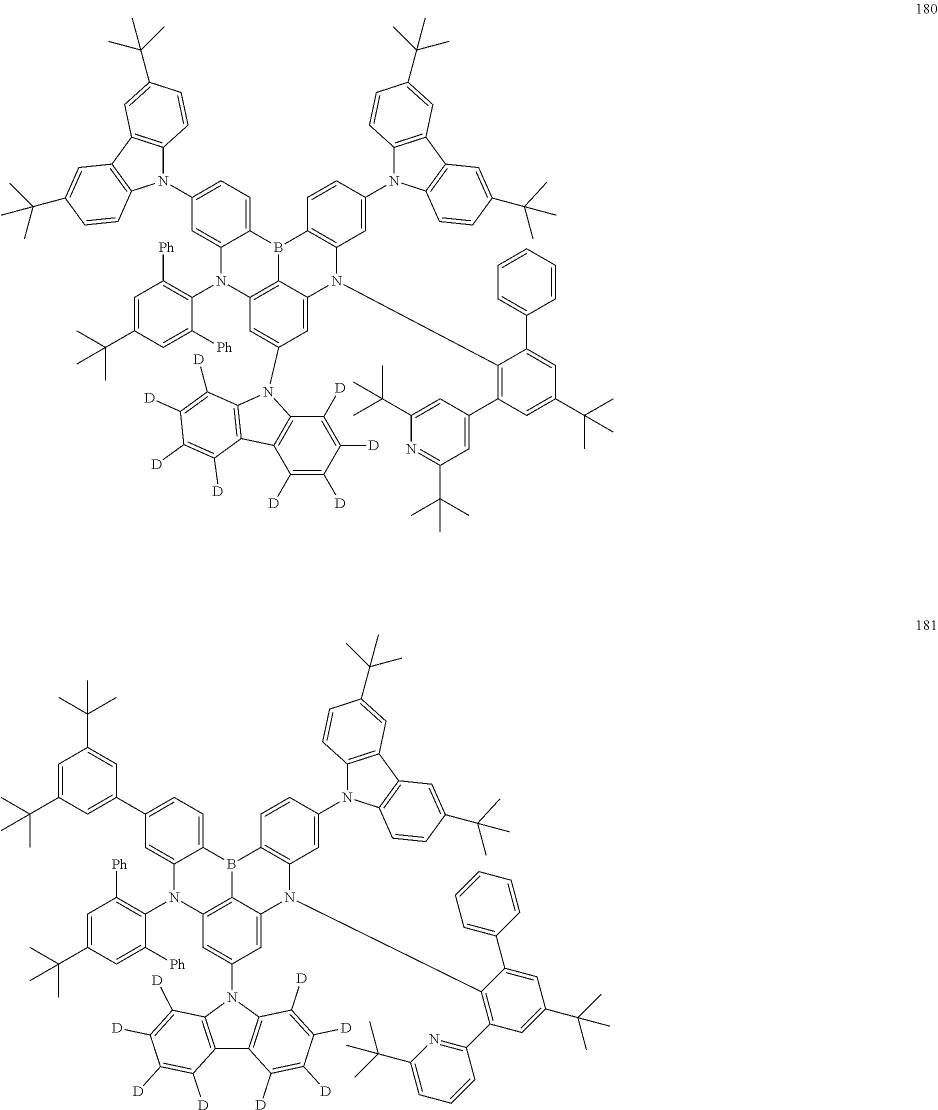

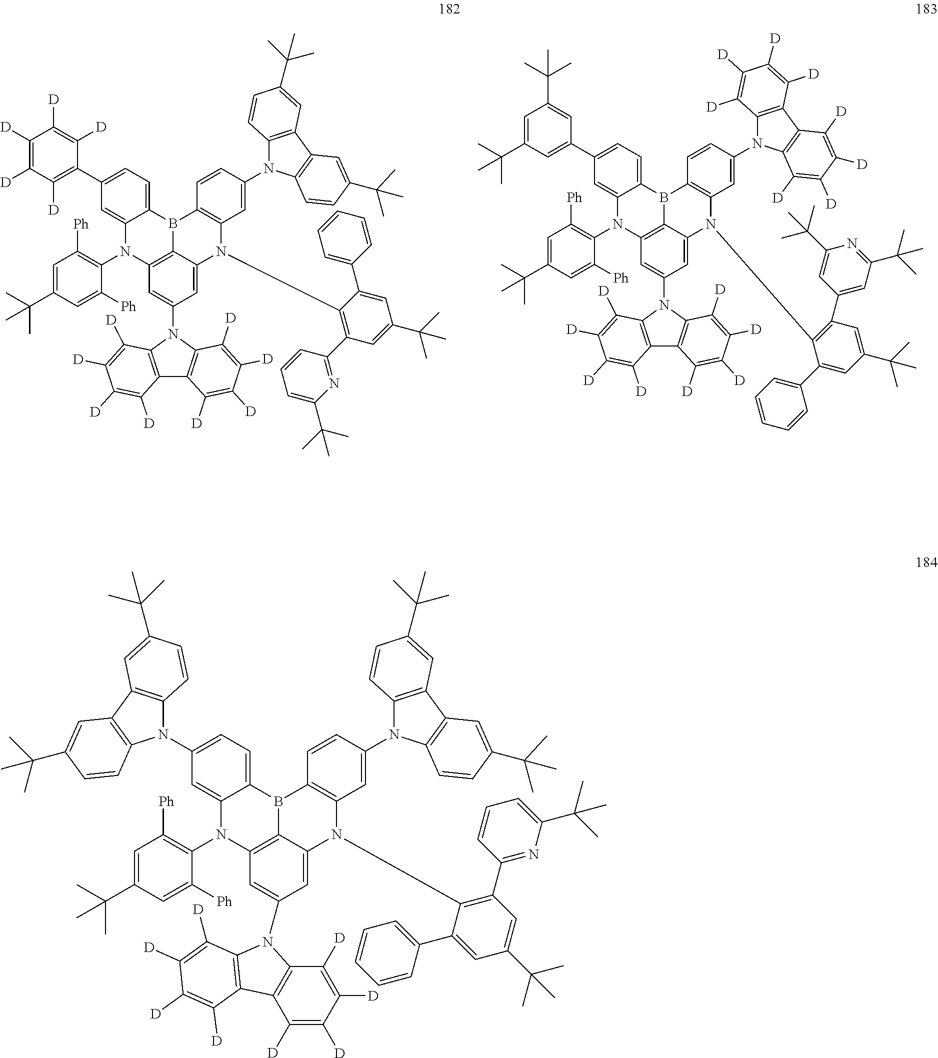

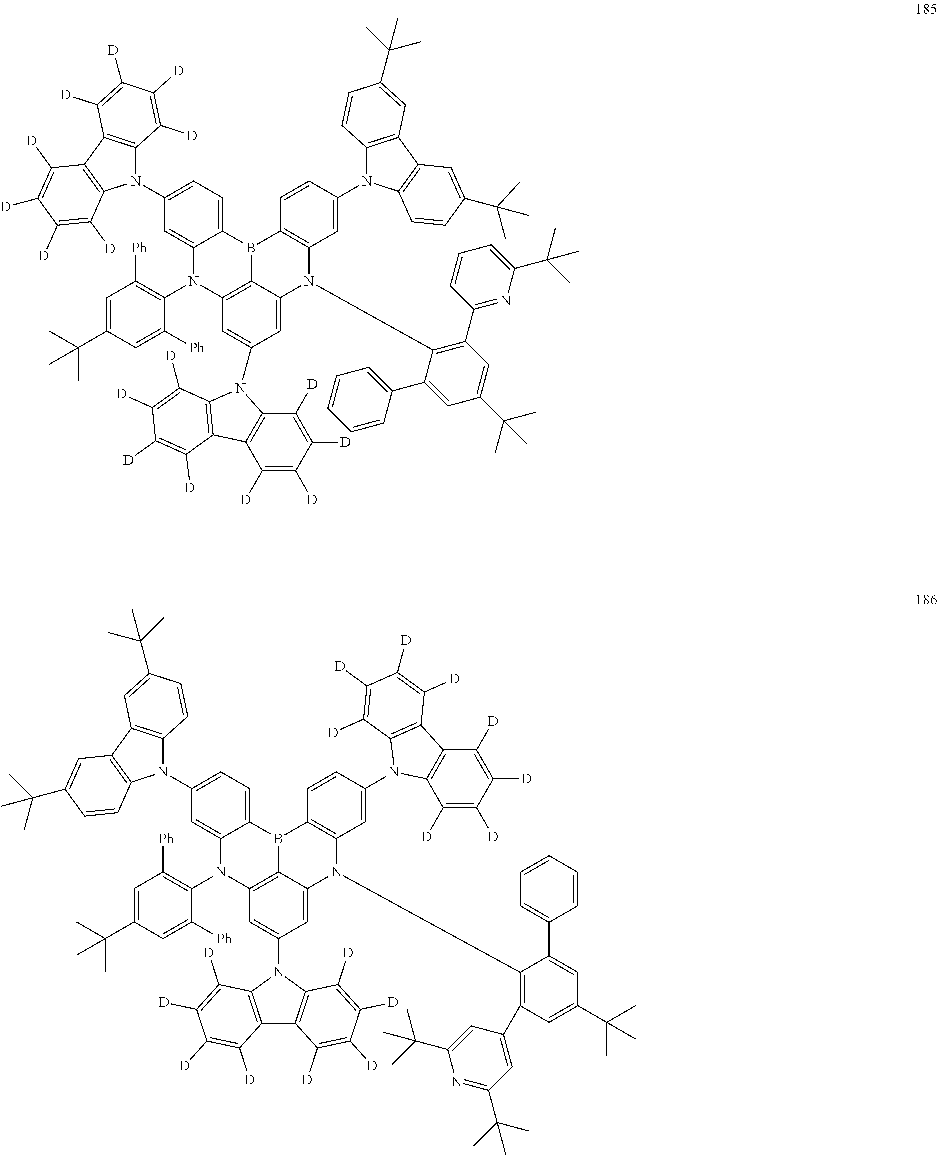

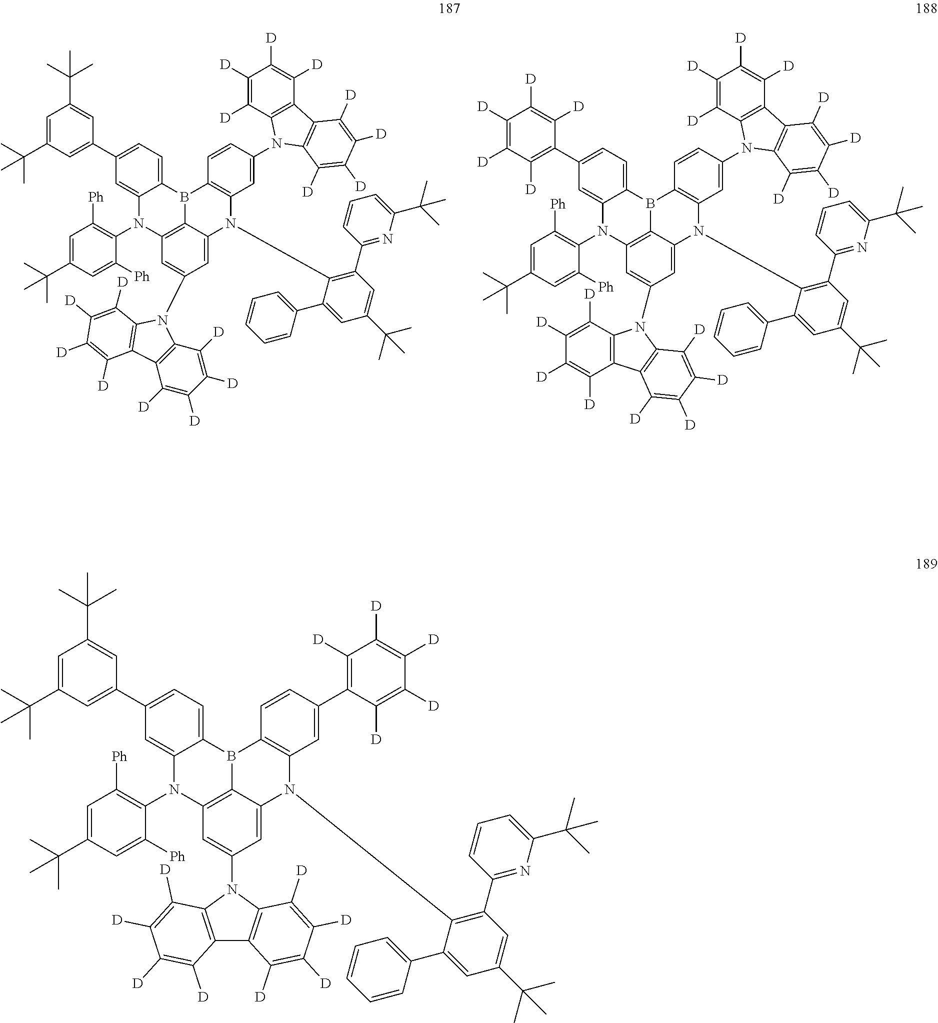

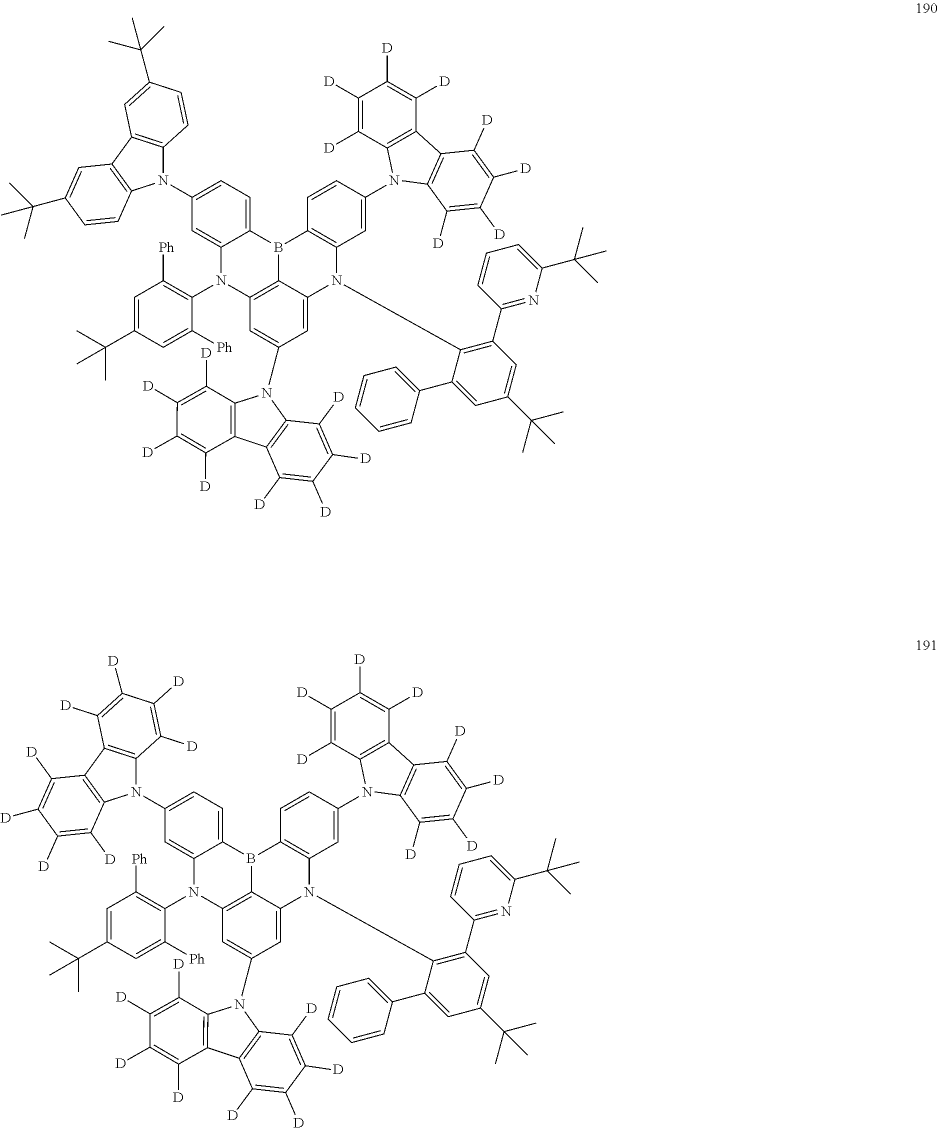

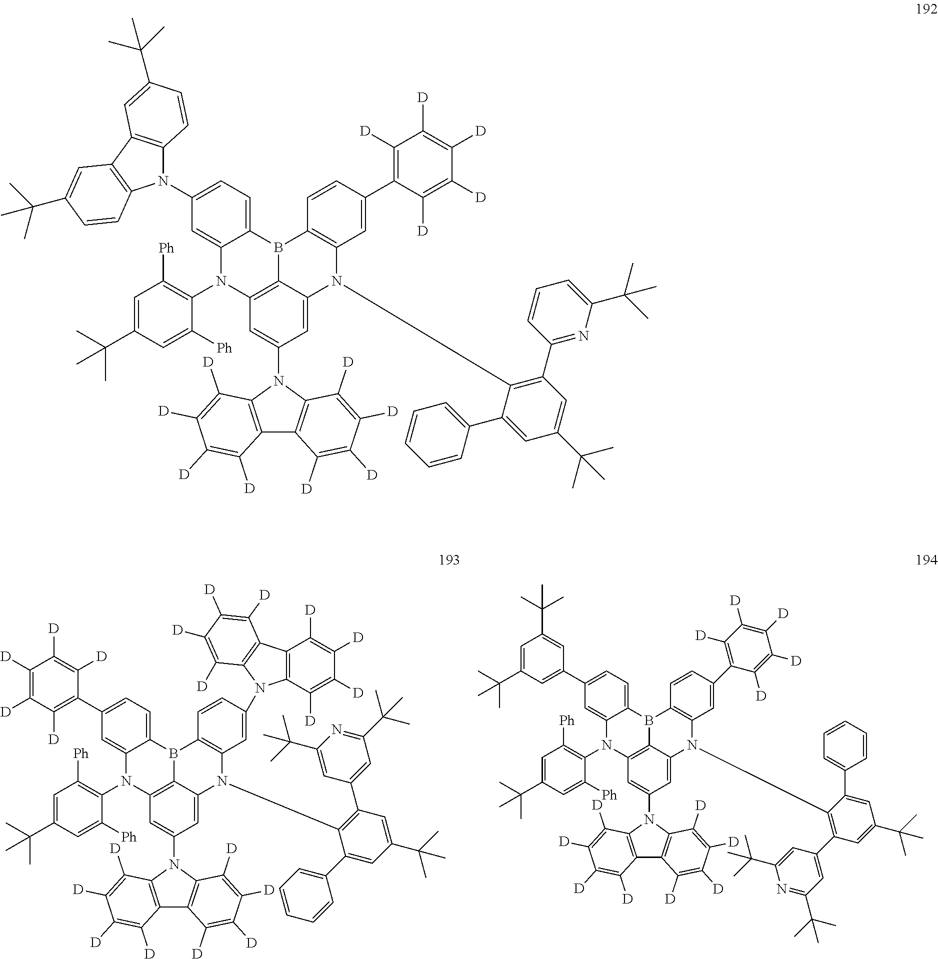

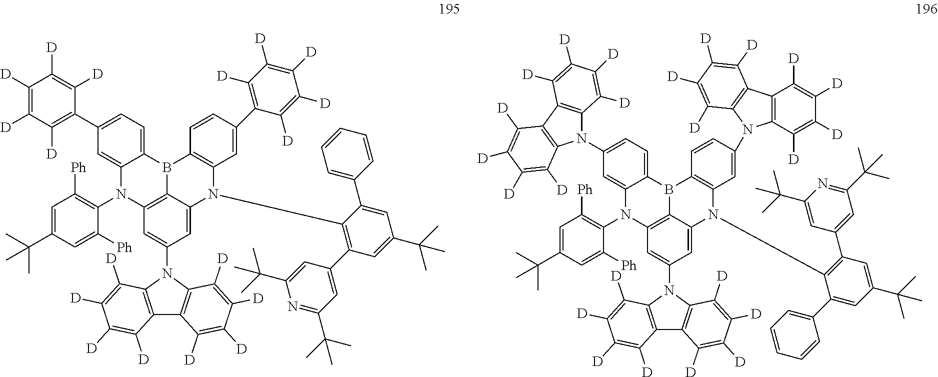

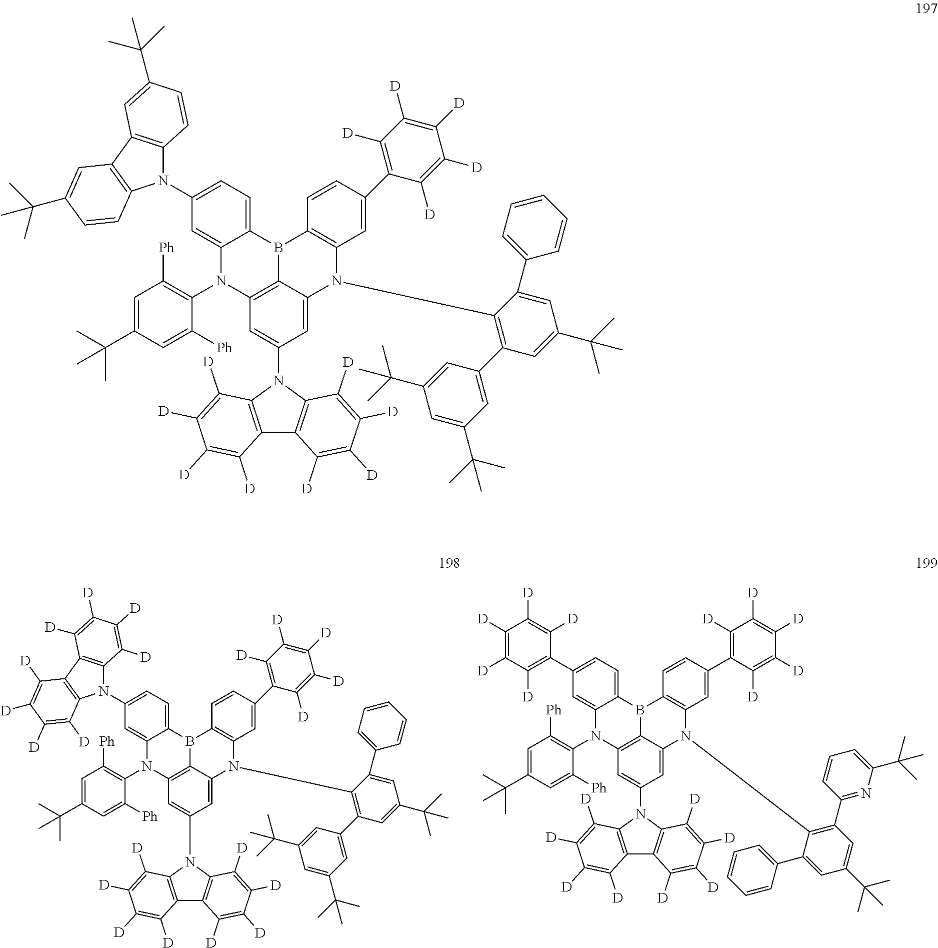

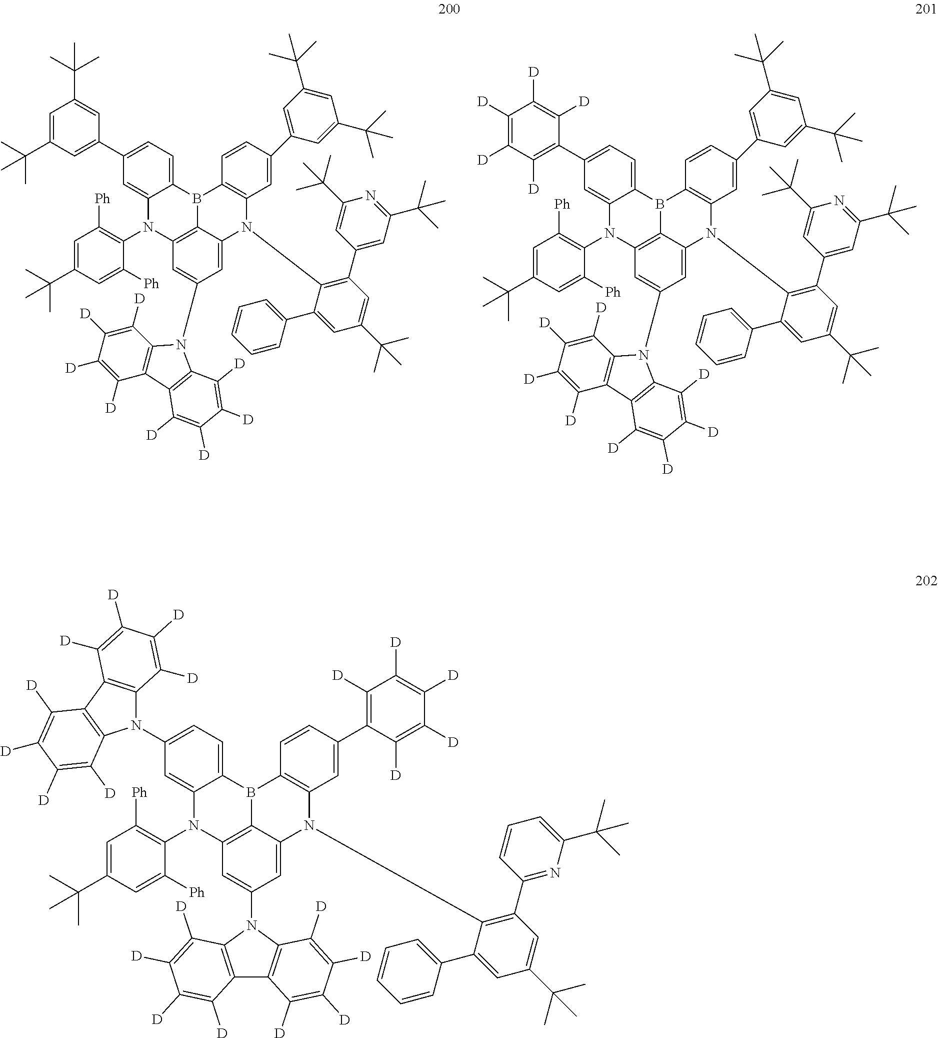

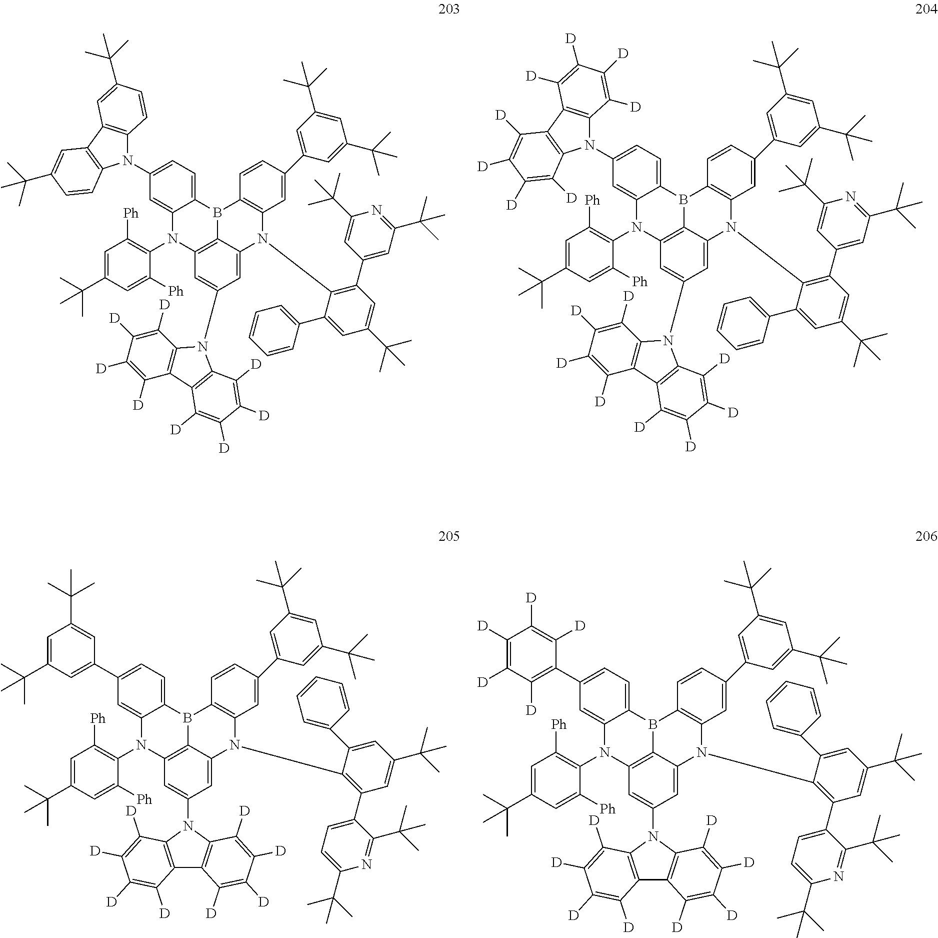

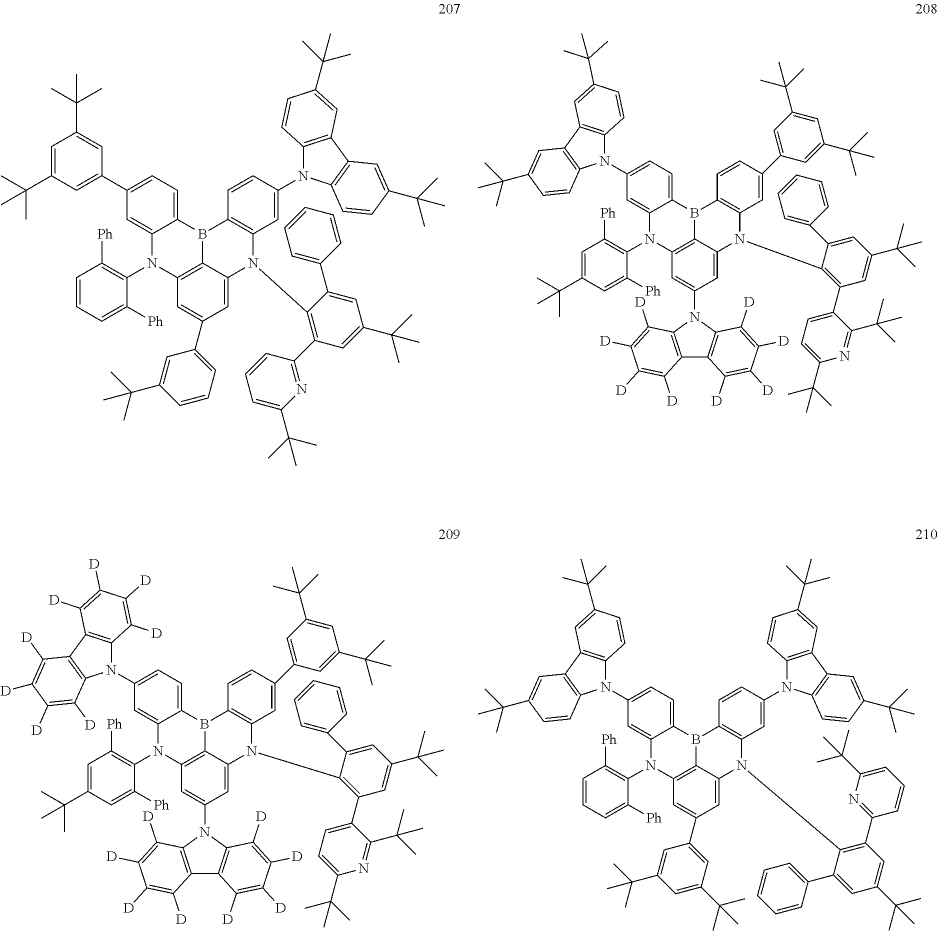

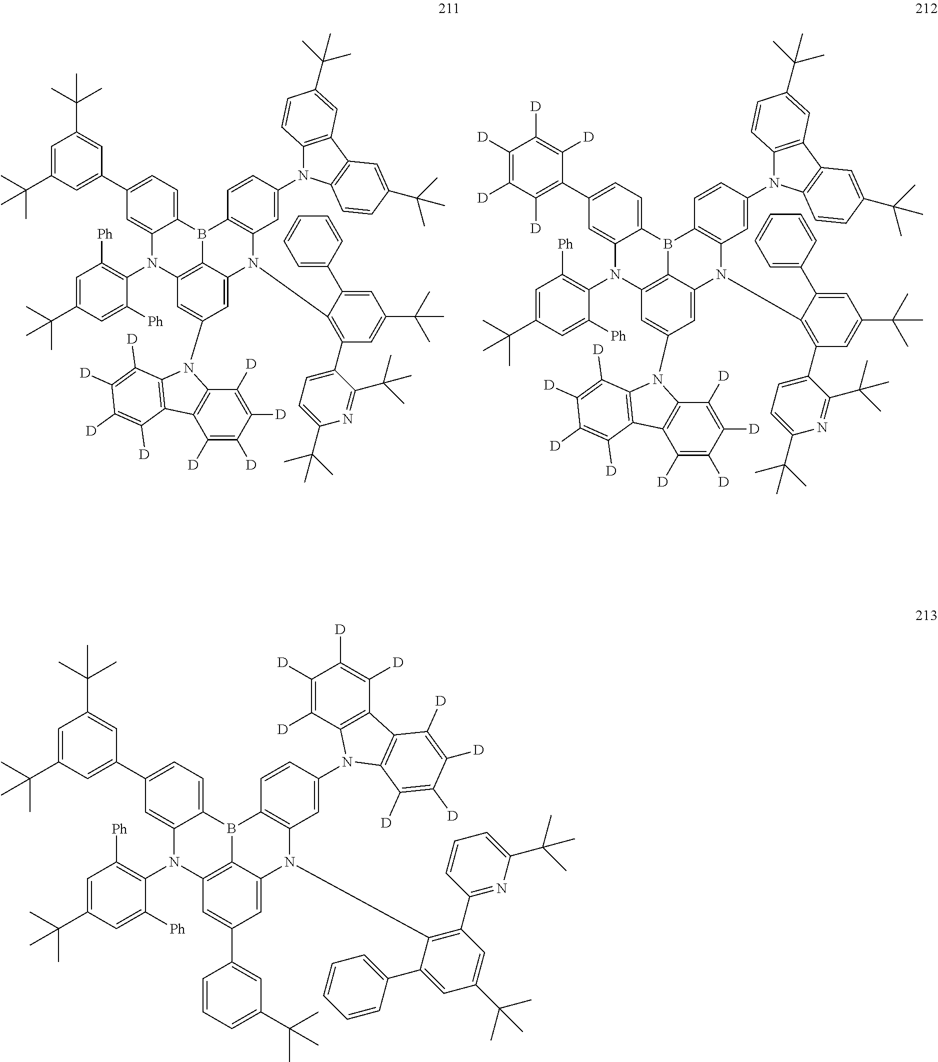

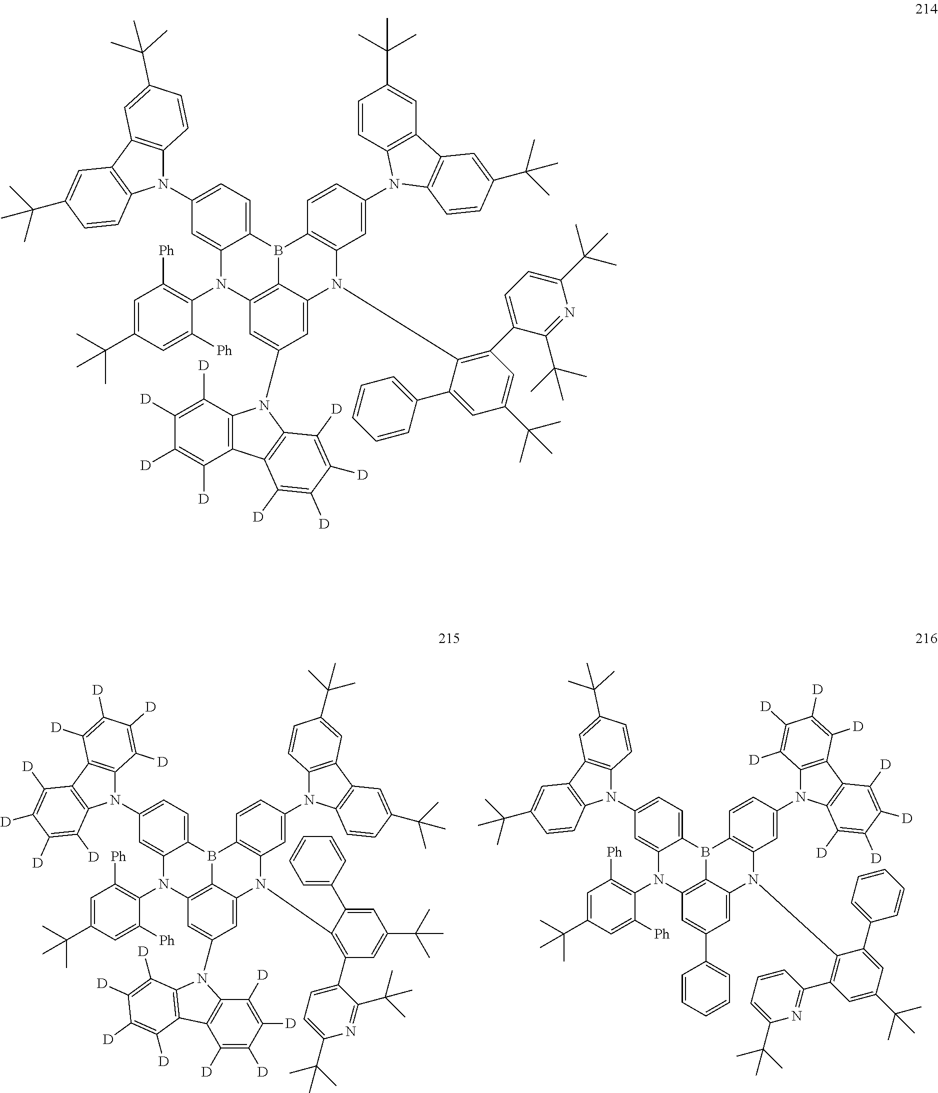

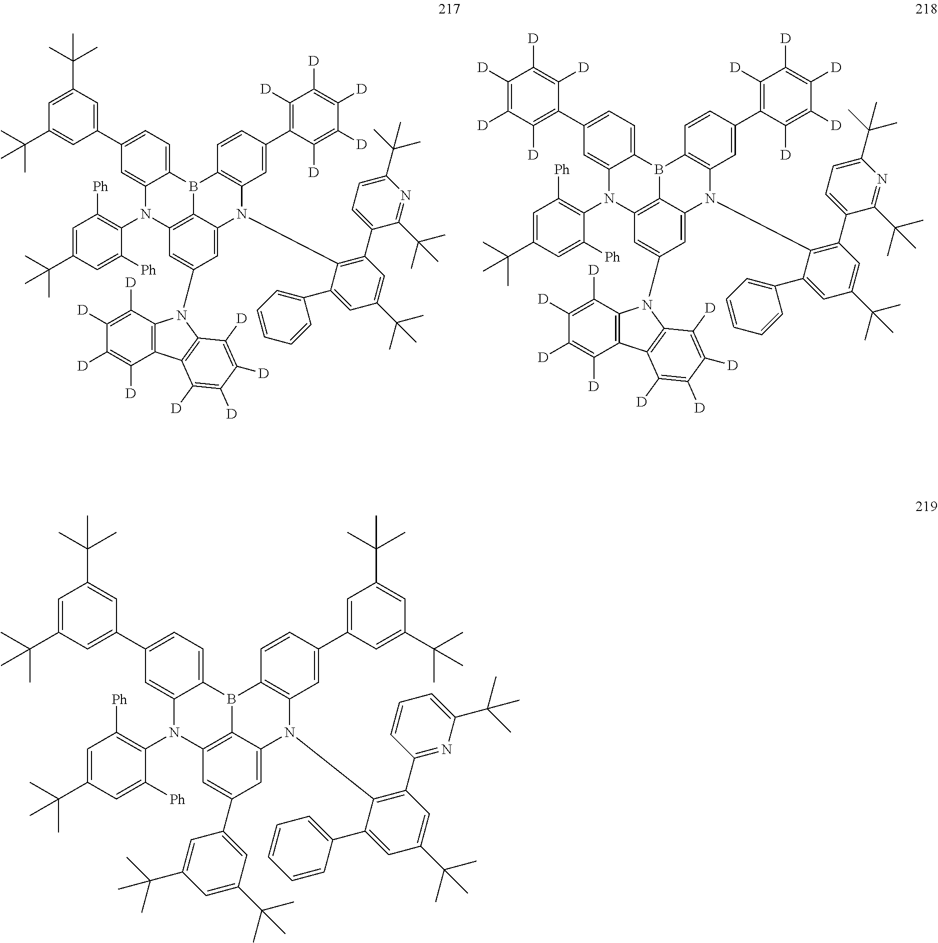

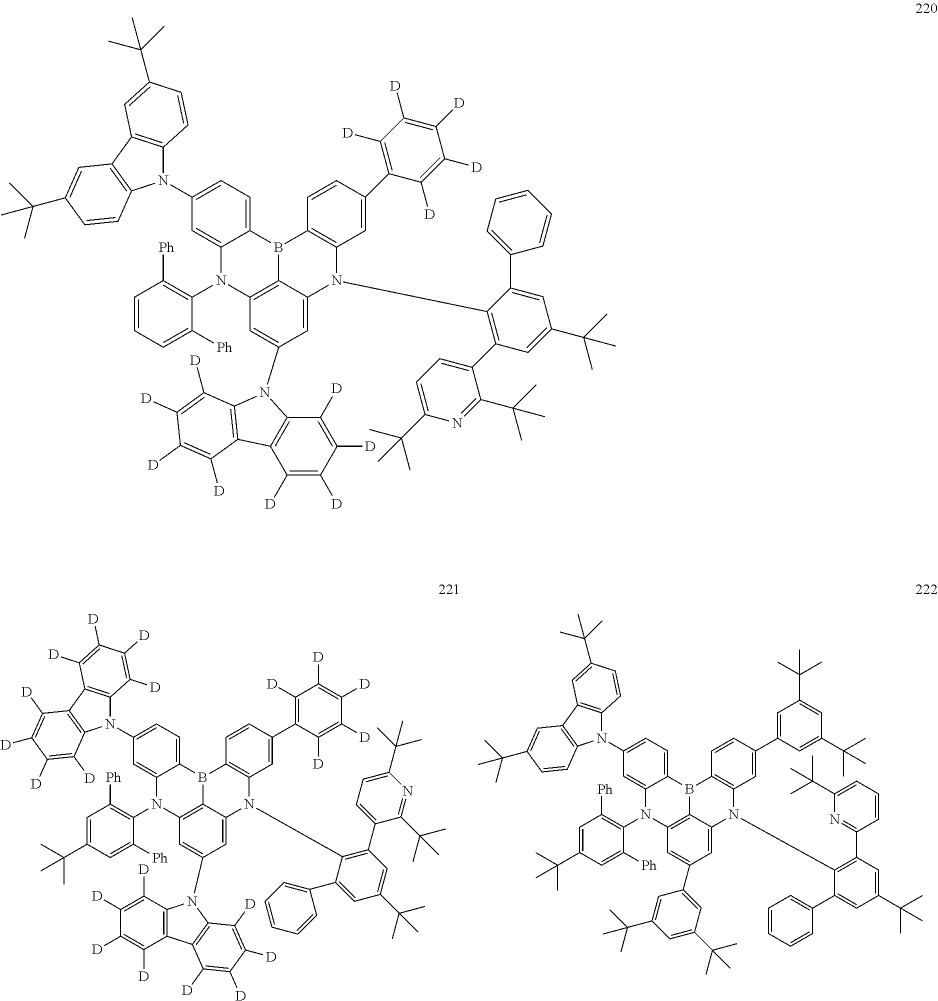

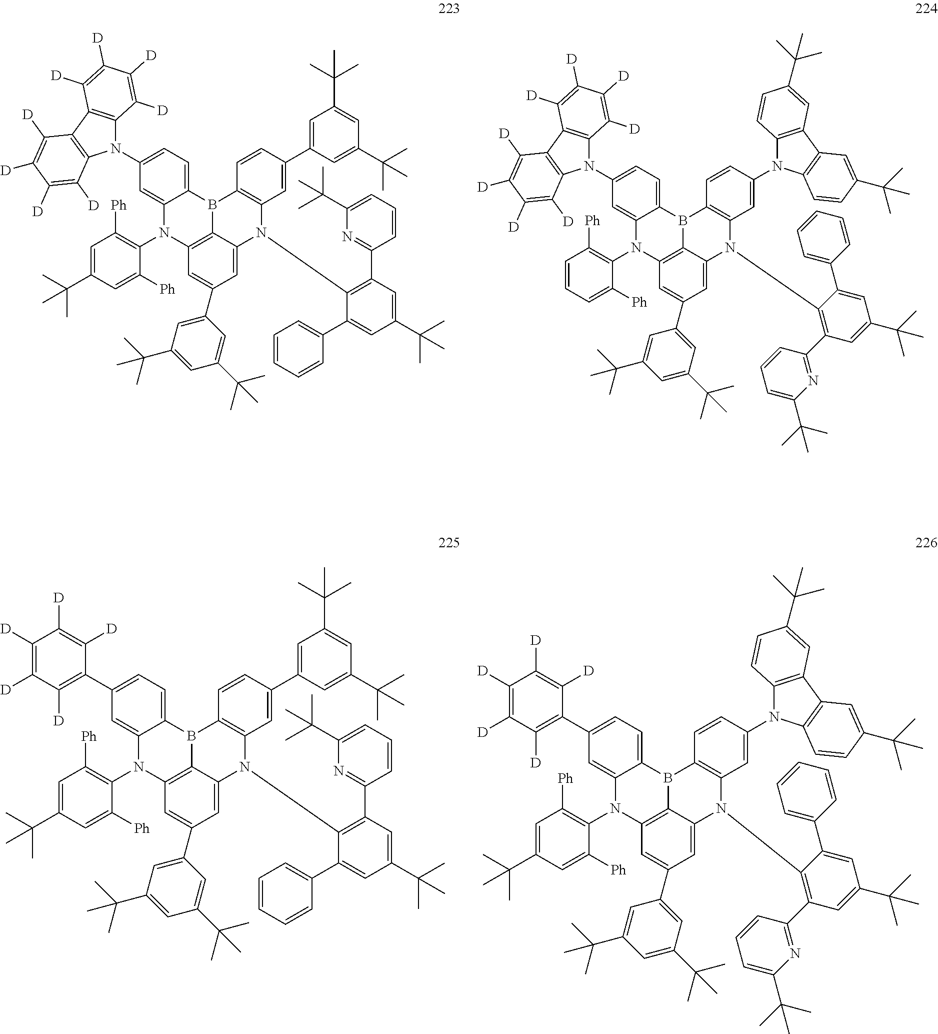

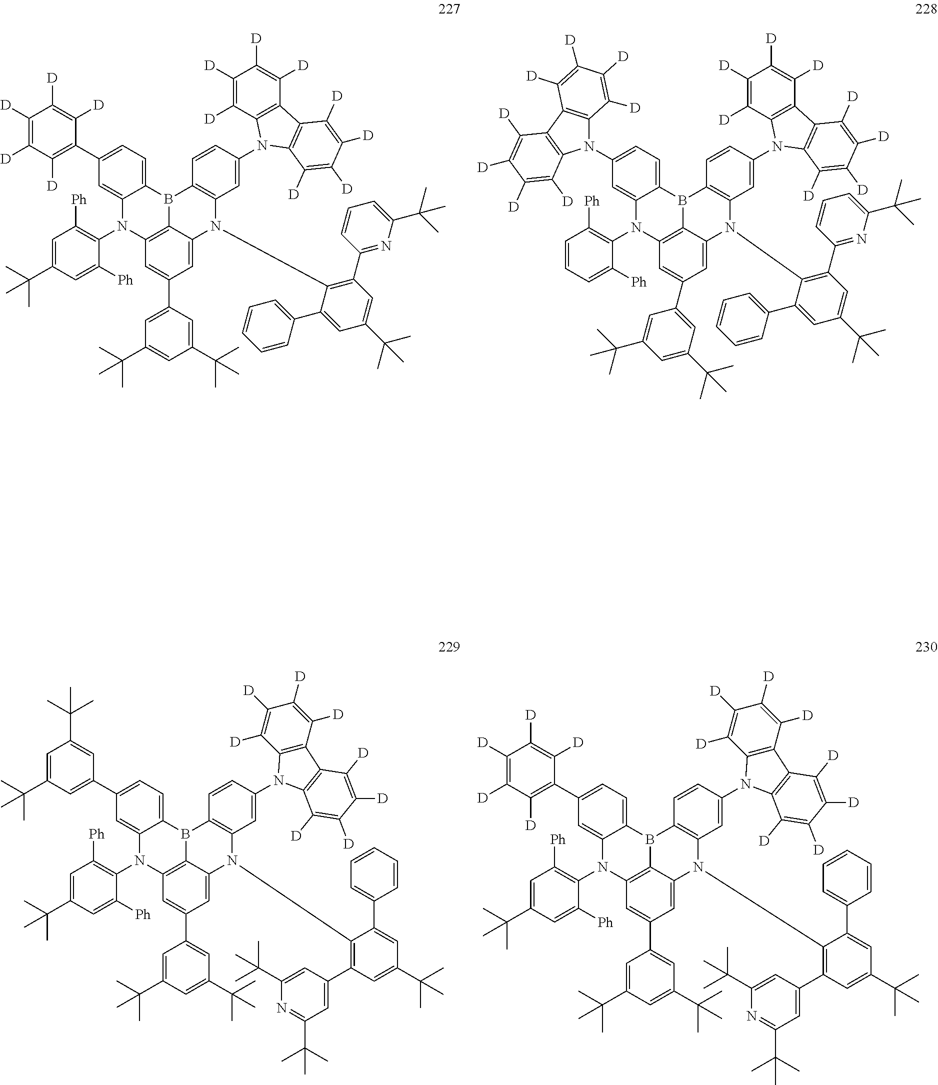

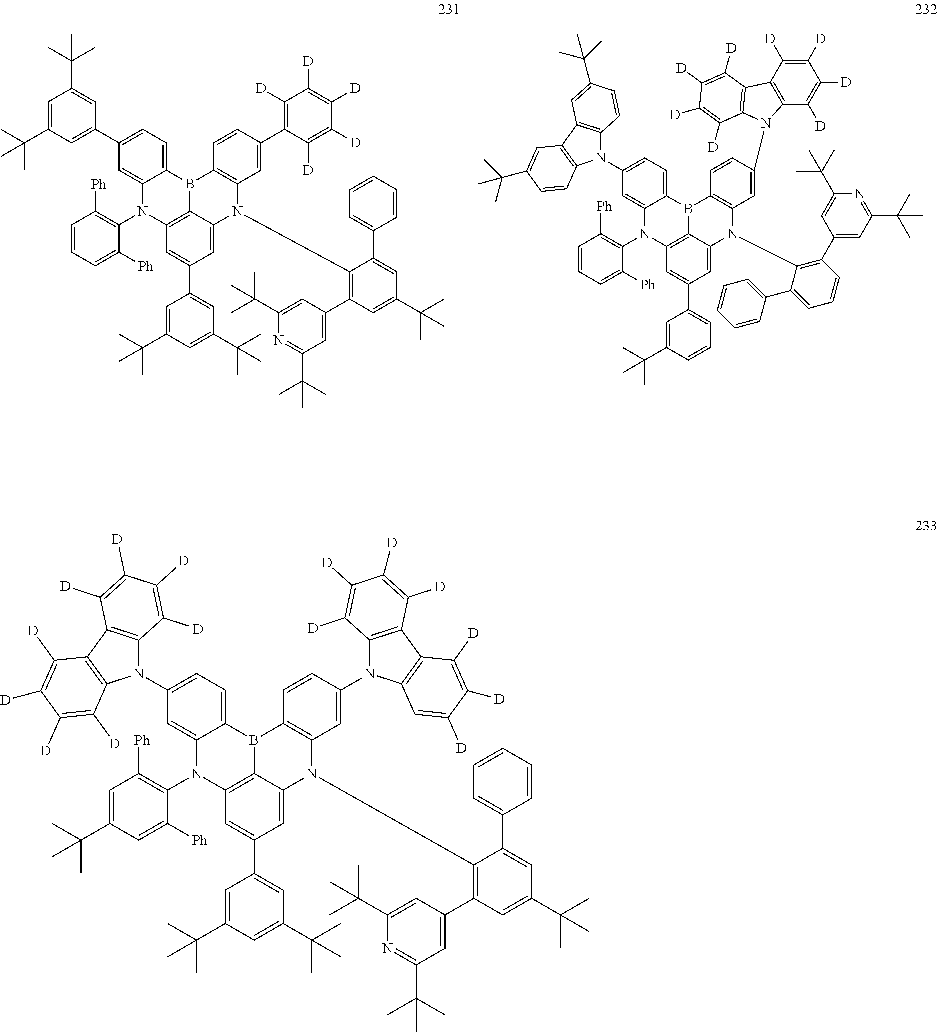

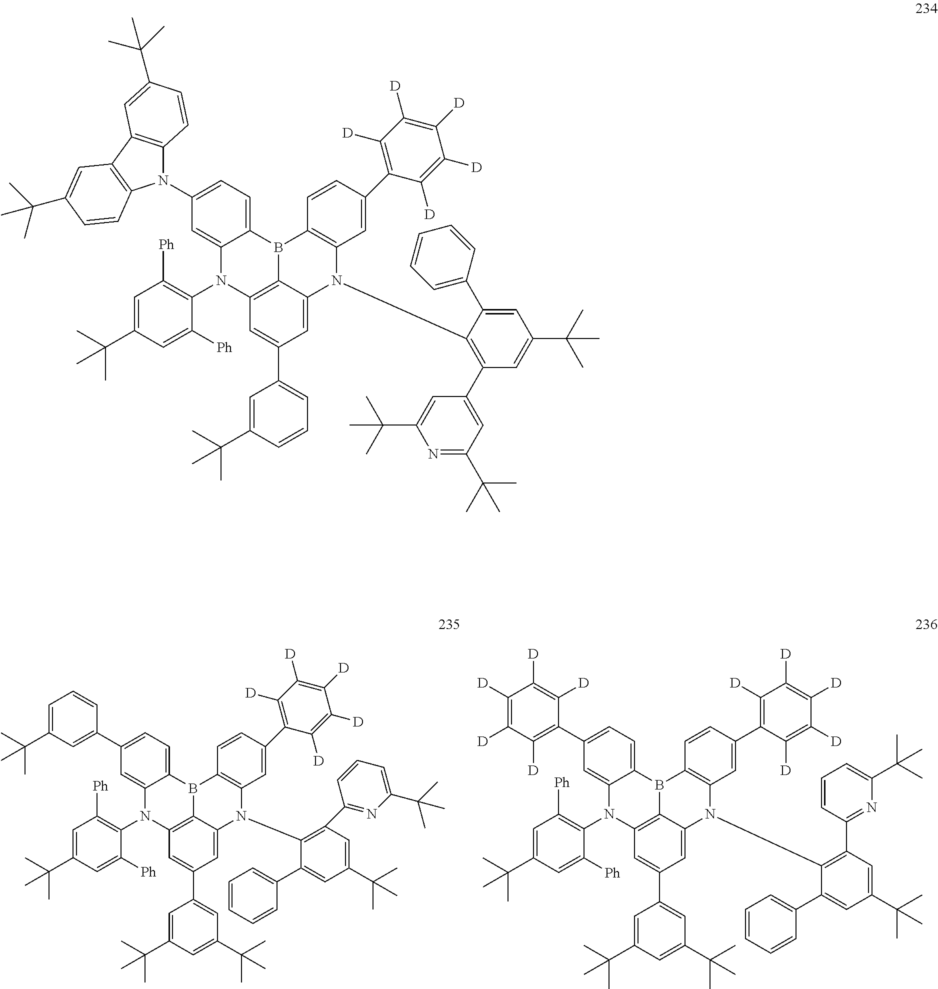

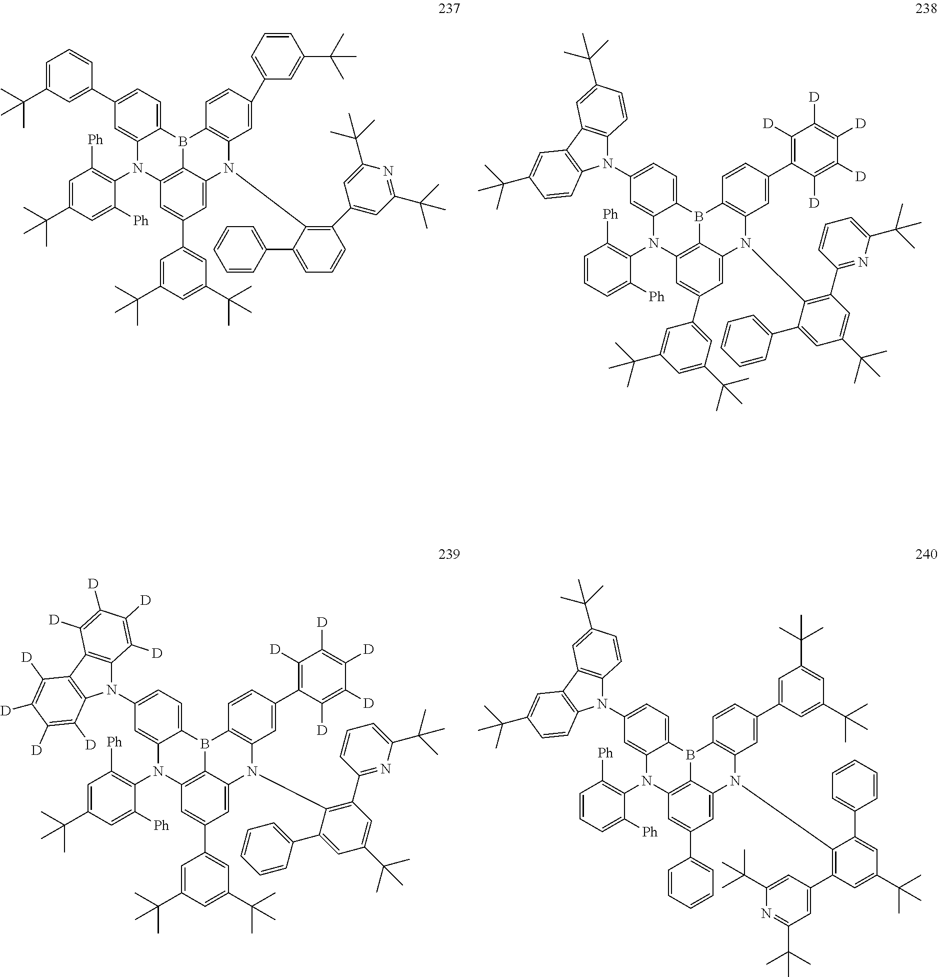

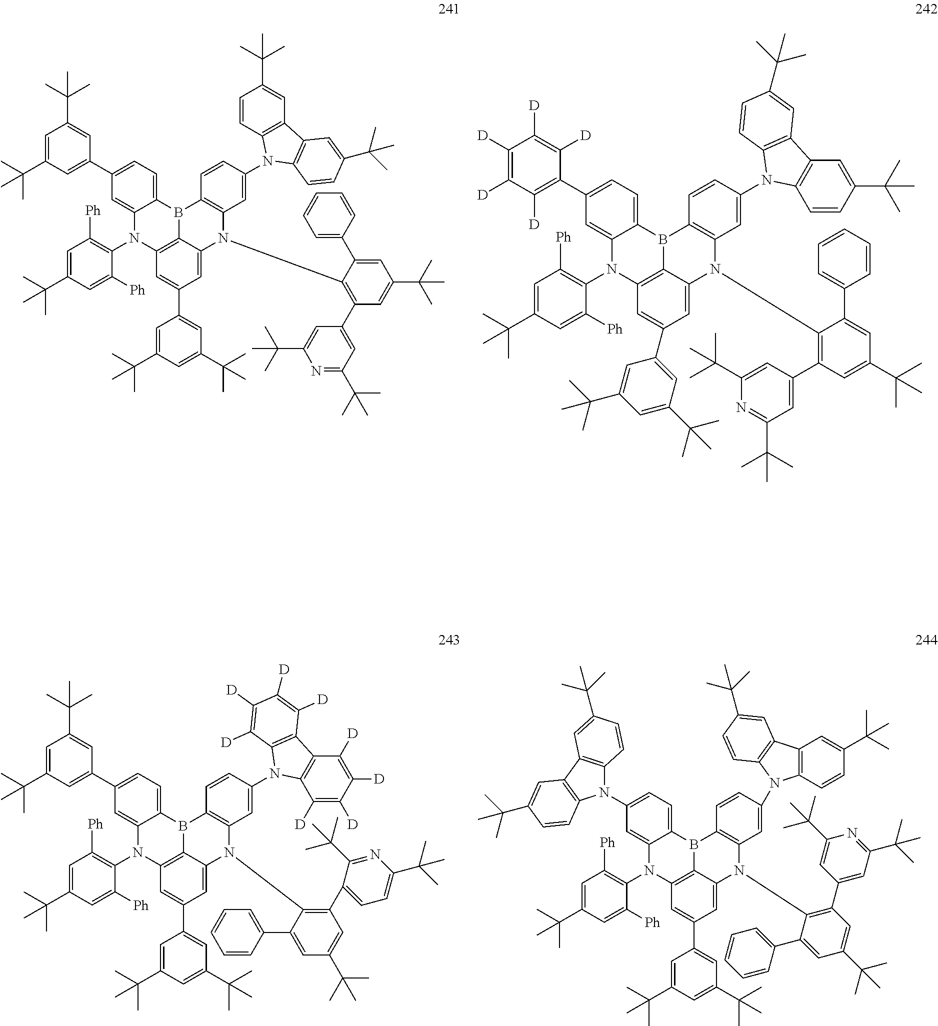

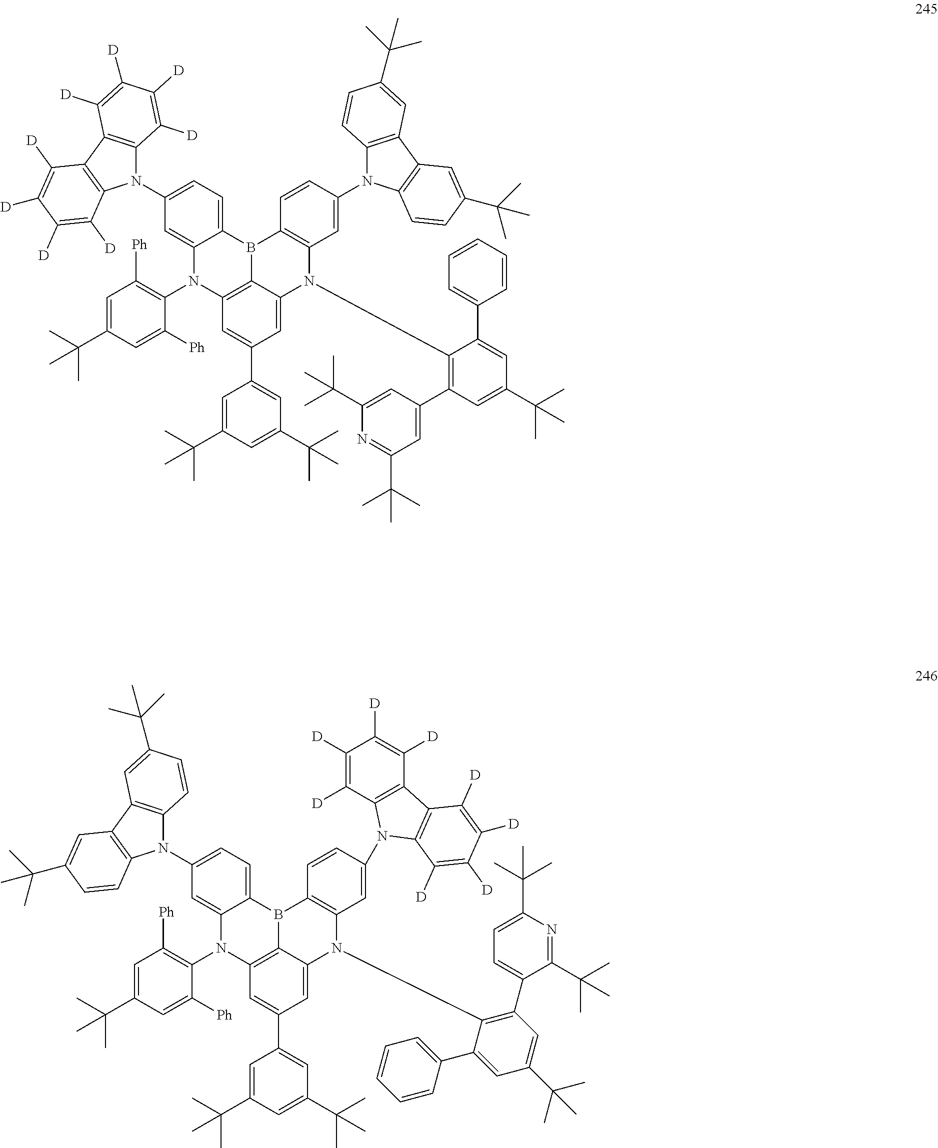

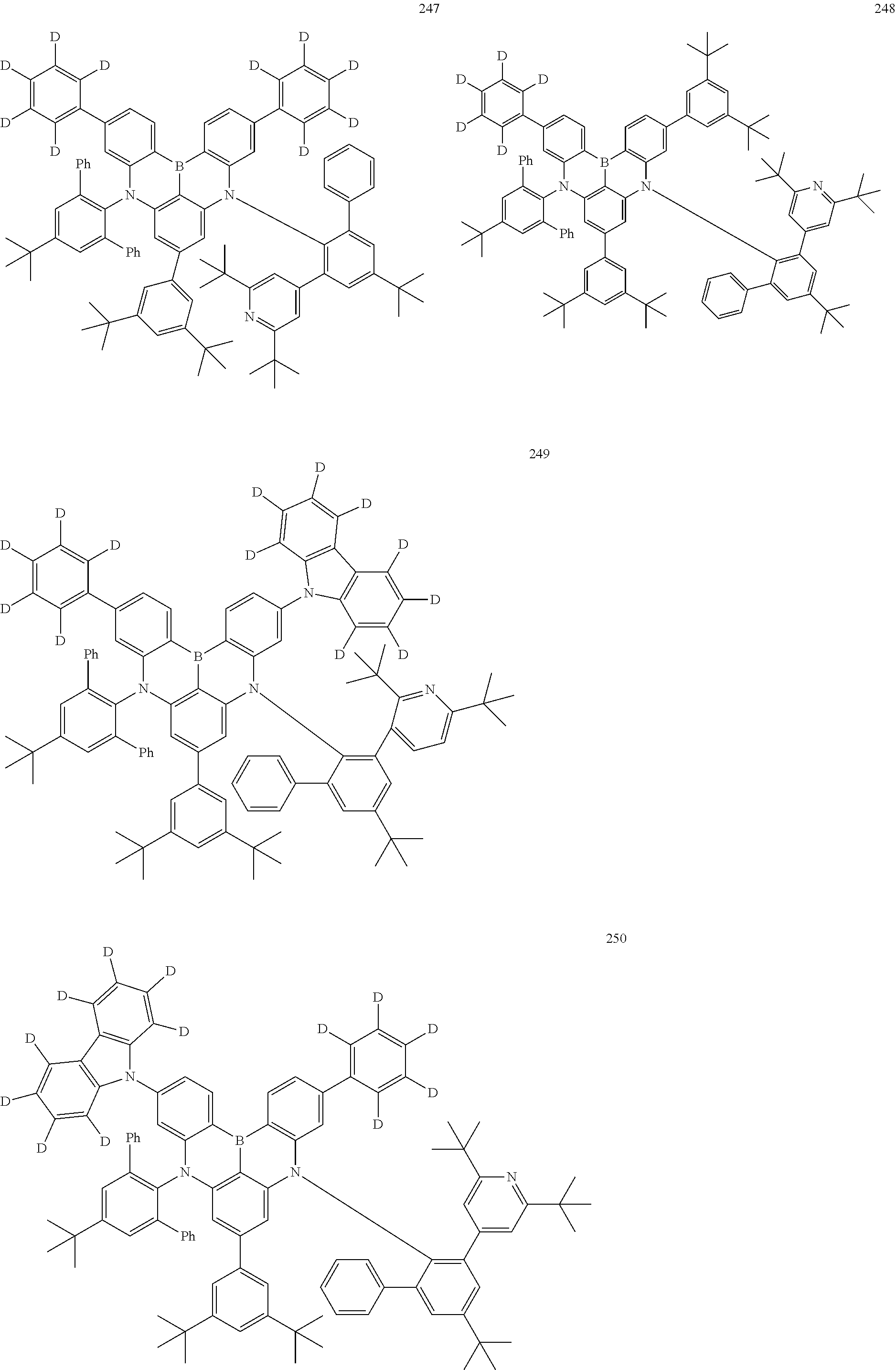

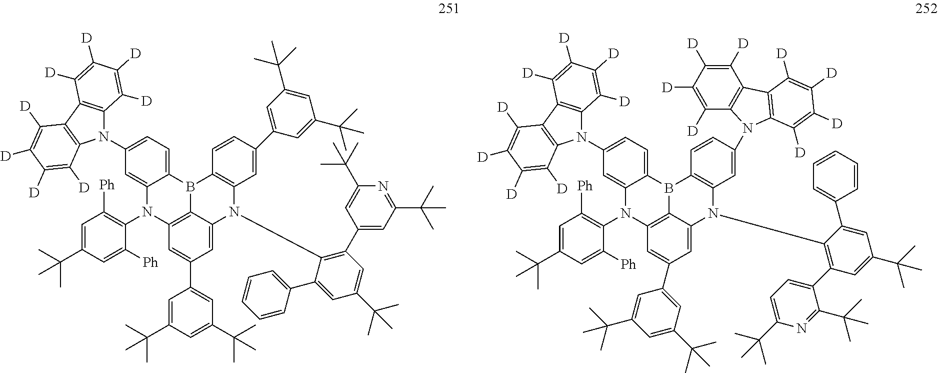

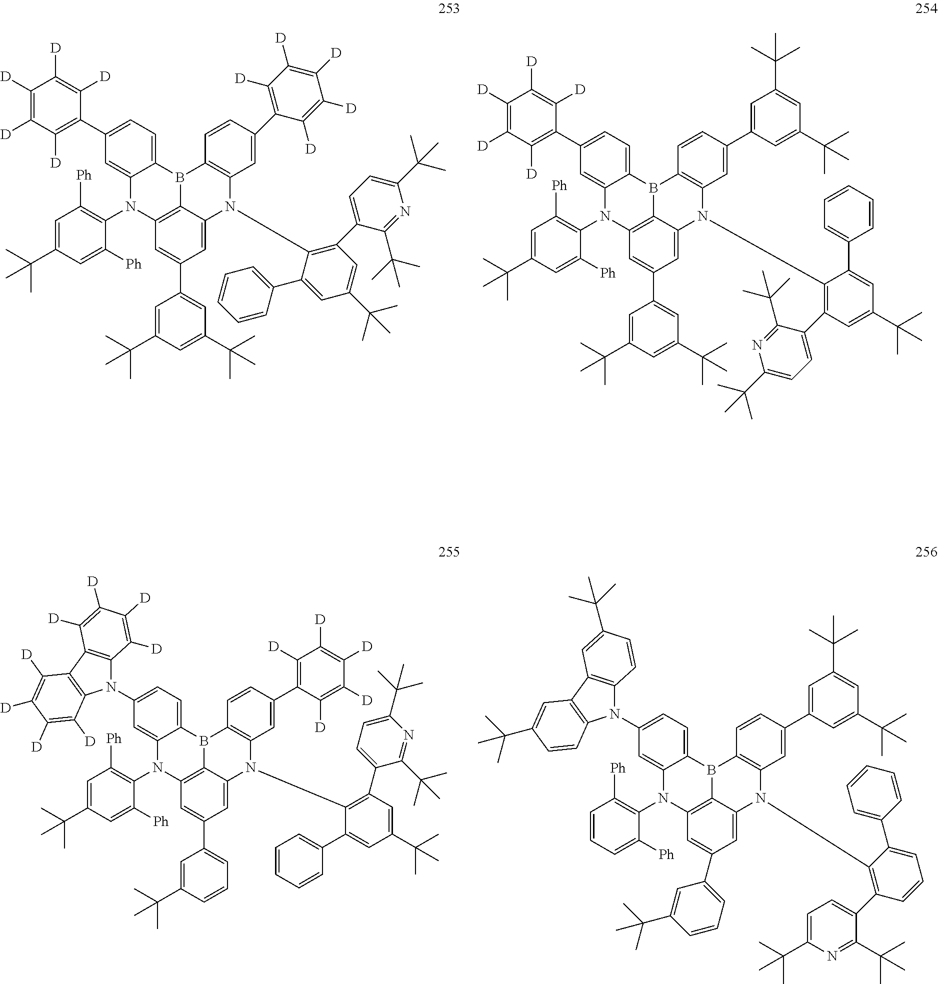

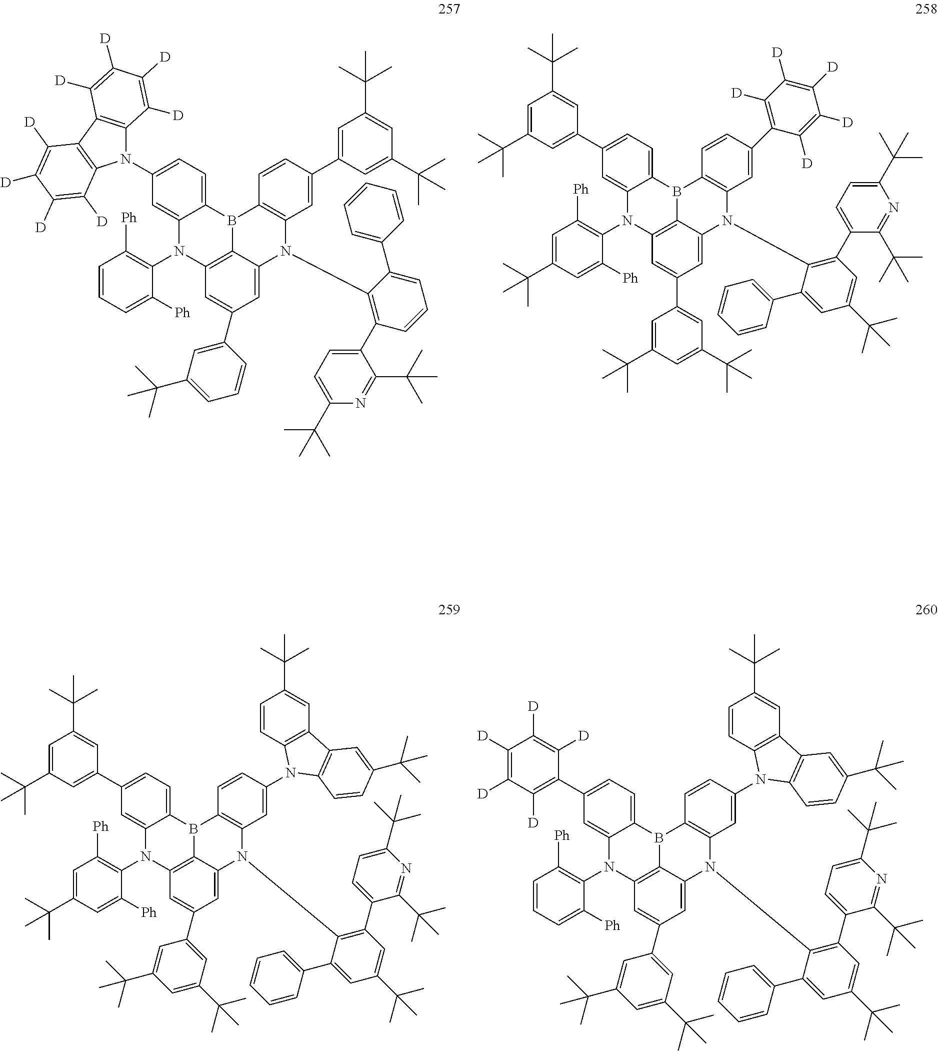

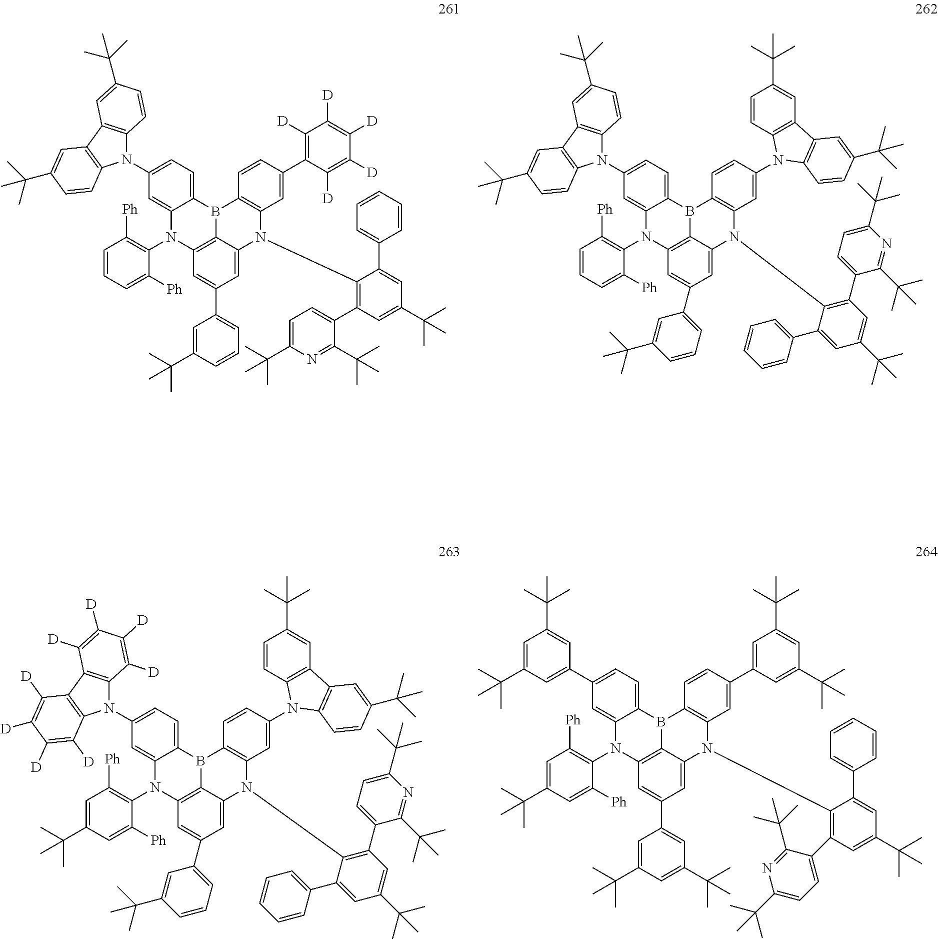

The polycyclic compound represented by Formula 1 may include a fused ring that includes a boron atom (B) and at least one nitrogen atom (N) as ring-forming atoms, and a pyridine unit linked to the fused ring core. The pyridine unit may be linked to the nitrogen atom (N) of the fused ring core via a benzene ring linker.

In the polycyclic compound, a benzene ring linker that is bonded to a nitrogen atom of the fused core part exhibits high electron density characteristics at an ortho-position of the benzene ring linker with respect to the nitrogen atom. The polycyclic compound may have enhanced multiple resonance effects due to highest occupied molecular orbital (HOMO)-lowest unoccupied molecular orbital (LUMO) sequential separation between atoms by the introduction of a pyridine unit exhibiting electron-withdrawing properties to a position of high electron density via the benzene ring linker.

The pyridine unit may include a first pyridine unit in which a t-butyl group is linked at an ortho-position to the nitrogen atom of the pyridine unit and a second pyridine unit in which two t-butyl groups are each linked at an ortho-position to the nitrogen atom of the pyridine unit. The pyridine unit may inhibit Dexter energy transfer in the pyridine unit itself by bonding one or two t-butyl groups at an ortho-position to the nitrogen atom of the pyridine unit, and may contribute to the inhibition of Dexter energy transfer between molecules. The polycyclic compound including the pyridine unit further induces HOMO-LUMO separation between the pyridine unit and the fused ring core, in addition to HOMO-LUMO separation within the fused ring core, and thus may exhibit increased characteristics of delayed fluorescence phenomena. An ortho-position to the nitrogen atom of the pyridine unit is an active site having radical activity, but the pyridine unit included in the polycyclic compound according to an embodiment may have a t-butyl group bonded to an ortho-position with the nitrogen atom of the pyridine unit, and thus interactions with non-covalent electron pairs of the nitrogen atom during borylation may be inhibited.

The polycyclic compound according to an embodiment has a fused ring core that includes a boron atom and at least one nitrogen atom as ring-forming atoms, and a structure in which the pyridine unit is connected to the fused ring core, so that multiple resonance effects may be further enhanced. The polycyclic compound may have excellent electrical characteristics, high charge transport characteristics and luminescence characteristics, and a high glass transition temperature so that crystallization may be prevented. Thus, when included in a light emitting element, the polycyclic compound may contribute to improvements in luminous efficiency and service life of the light emitting element.

The polycyclic compound may be included in the emission layer EML. The polycyclic compound may be included as a dopant material in the emission layer EML. The polycyclic compound may be a thermally activated delayed fluorescence material. The polycyclic compound may be used as a thermally activated delayed fluorescence (TADF) dopant. For example, in the light emitting element ED, the emission layer EML may include, as a thermally activated delayed fluorescence dopant, at least one compound selected from Compound Group 1 as described above. However, a use of the polycyclic compound is not limited thereto.

The polycyclic compound according to an embodiment may be a luminescent material having a central wavelength in a range of about 430 nm to about 490 nm. For example, the polycyclic compound may emit blue light. The polycyclic compound be a blue thermally activated delayed fluorescence (TADF) dopant. However, embodiments are not limited thereto.

In an embodiment, the emission layer EML may include the first compound, which is a polycyclic compound according to an embodiment, and at least one of a second compound or a third compound. In an embodiment, the emission layer EML may include the first compound, the second compound, and the third compound. In the emission layer EML, the second compound and the third compound may form an exciplex, and energy may be transferred from the exciplex to the first compound, thereby emitting light. In another embodiment, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In the specification, the fourth compound may be referred to as a phosphorescent sensitizer. The fourth compound may emit phosphorescence or may transfer energy to the first compound as an auxiliary dopant. However, such functions of the first to fourth compounds are only examples, and embodiments are not limited thereto.

The light emitting element ED may include the first compound, the second compound, the third compound, and the fourth compound, and the emission layer EML may include a combination of two host materials and two dopant materials. In the light emitting element ED, the emission layer EML may include the first compound which emits delayed fluorescence, the second compound and the third compound which are two different hosts, and the fourth compound that includes an organometallic complex, thereby exhibiting excellent luminous efficiency characteristics.

In an embodiment, the second compound may include a substituted or unsubstituted carbazole moiety. The third compound may include a hexagonal ring containing at least one nitrogen atom as a ring-forming atom. The fourth compound may be an organometallic complex compound. The fourth compound may be an organometallic complex compound containing platinum (Pt) or iridium (Ir) as a central metal. In embodiments, the second compound may be represented by Formula HT, and the third compound may be represented by Formula ET. The fourth compound may contain platinum (Pt) or iridium (Ir) as a central metal, and may be represented by Formula PS.

In an embodiment, the emission layer EML may include a second compound represented by Formula HT. In an embodiment, the second compound represented by Formula HT may be used as a hole transport host material for the emission layer EML.

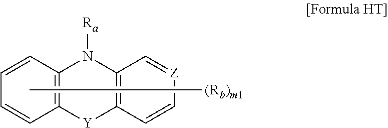

In Formula HT, m1 may be an integer from 0 to 7. When m1 is 2 or greater, multiple R_{b} groups may all be the same, or at least one group thereof may be different from the remainder. In Formula HT, Rₐ and R_{b} may each independently be a hydrogen atom, a deuterium atom, a cyano group, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, Rₐ may be a substituted phenyl group, an unsubstituted dibenzofuran group, or a substituted fluorenyl group. For example, R_{b} may be a hydrogen atom, a deuterium atom, a substituted or unsubstituted phenyl group, a substituted or unsubstituted carbazole group, or a substituted or unsubstituted the fluorenyl group. For example, two adjacent R_{b} groups may be bonded to each other to form a substituted or unsubstituted heterocycle.

In Formula HT, Y may be a direct linkage, C(R_{y1})(R_{y2}), or Si(R_{y3})(R_{y4}). For example, when Y is a direct linkage, the second compound represented by Formula HT may contain a carbazole moiety. In Formula HT, R_{y1} to R_{y4} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms. For example, R_{y1} to R_{y4} may each independently be a methyl group or a phenyl group.

In Formula HT, Z may be C(R_{z}) or a nitrogen atom (N). For example, Y may be a direct linkage, and when Z is C(R_{z}), Formula HT may include a carbazole moiety. For example, Y may be a direct linkage, and when Z is a nitrogen atom, Formula HT may include a pyridoindole moiety. In Formula HT, R_{z} may be a hydrogen atom or a deuterium atom.

In an embodiment, the second compound represented by Formula HT may be selected from Compound Group 2. In an embodiment, in the light emitting element ED, the second compound may include at least one compound selected from Compound Group 2. In Compound Group 2, D represents a deuterium atom.

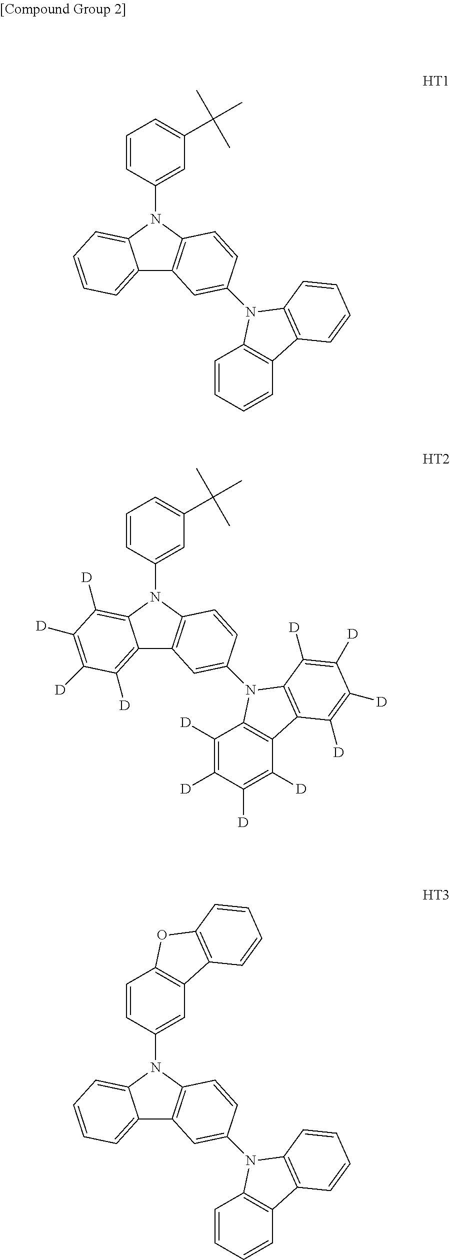 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

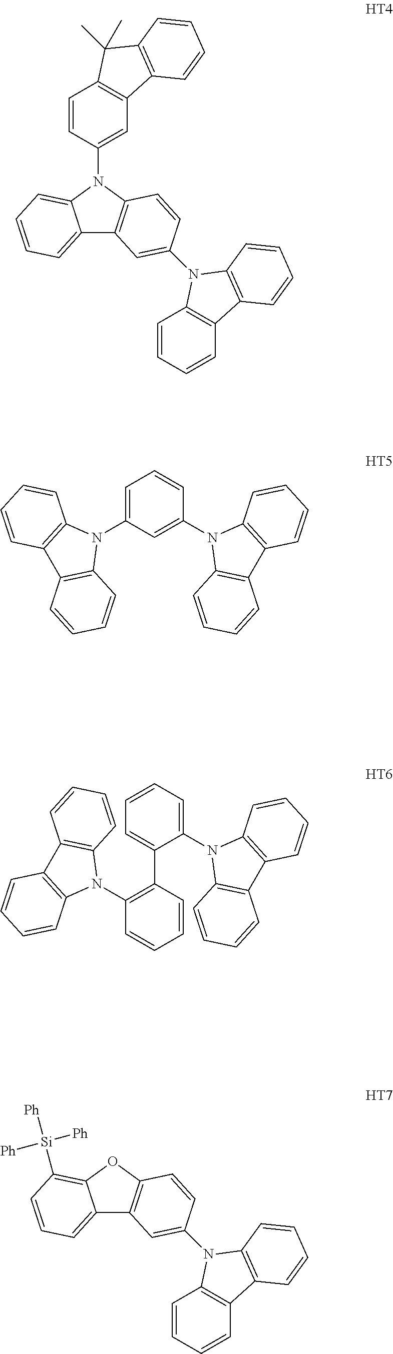 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

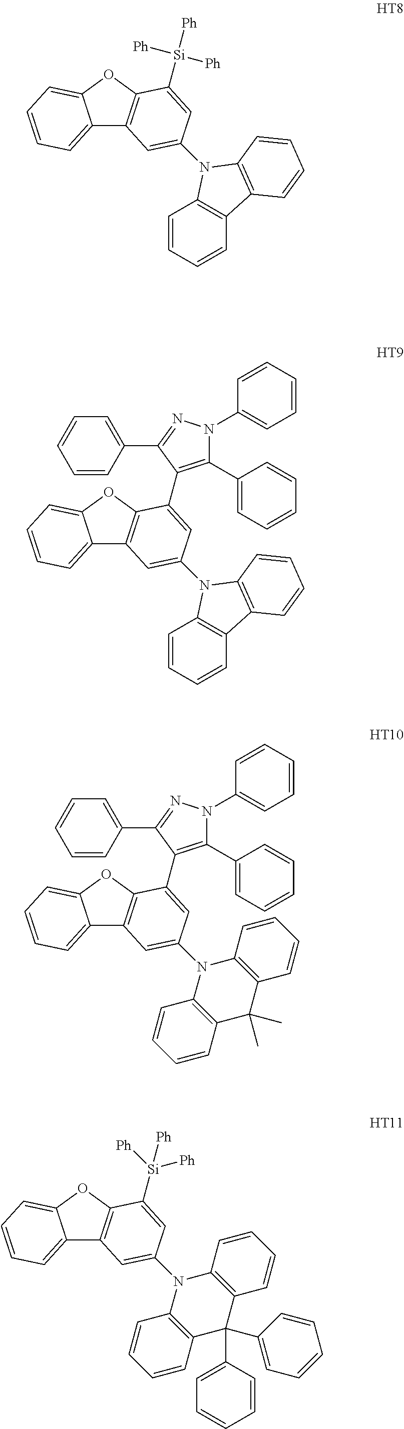 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

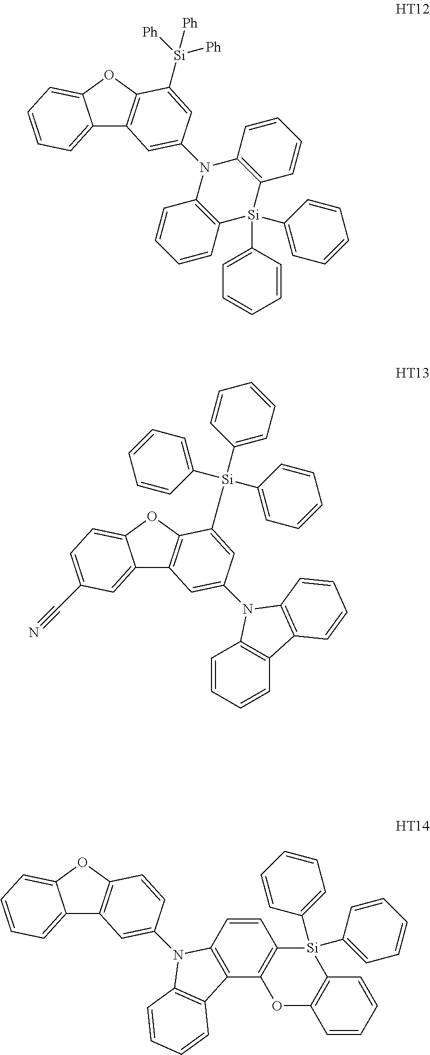 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

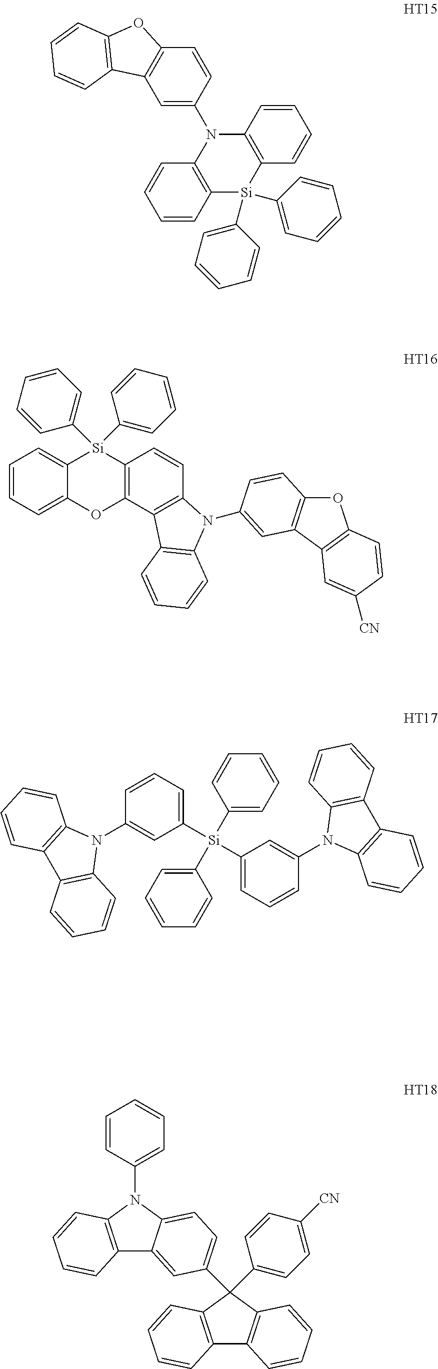 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

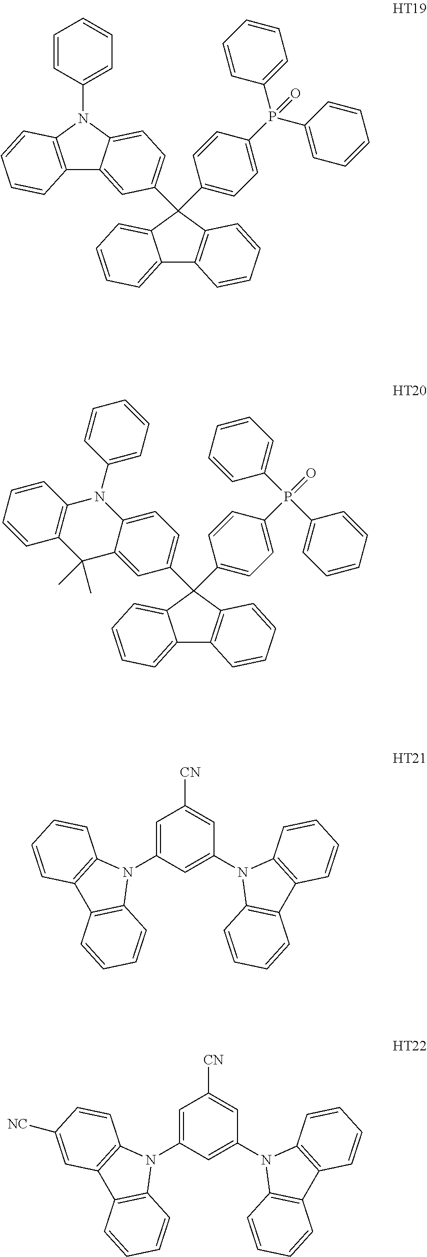 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

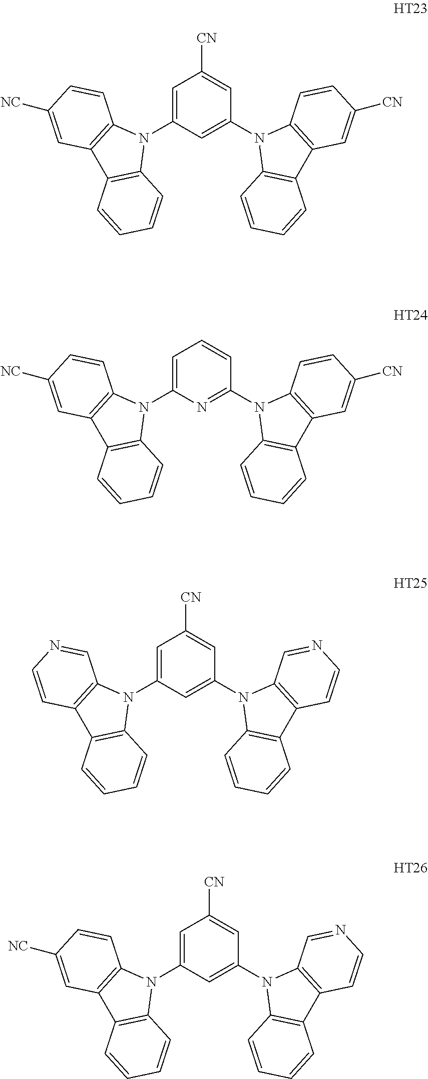 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

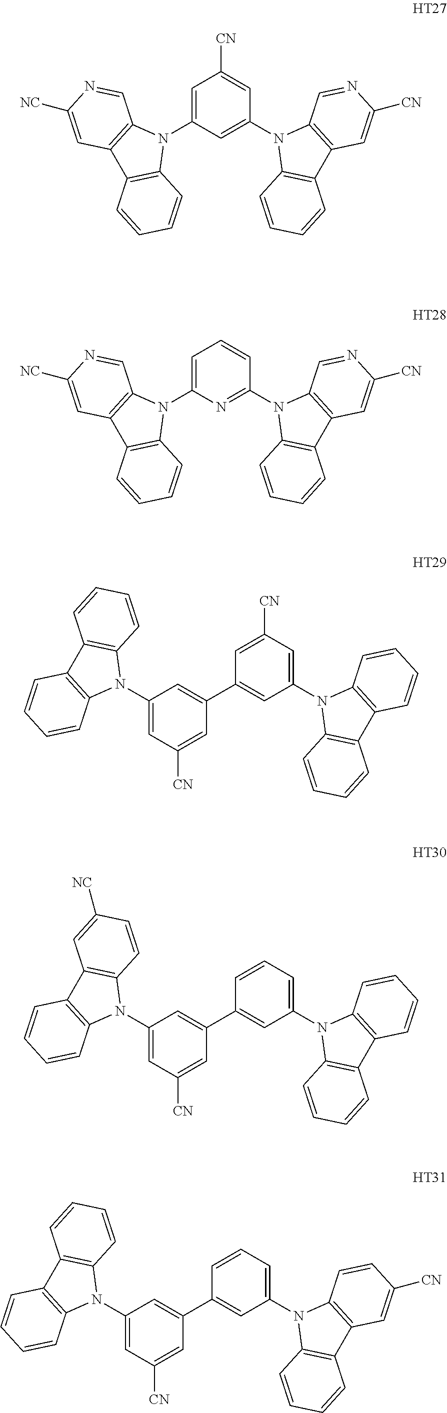 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

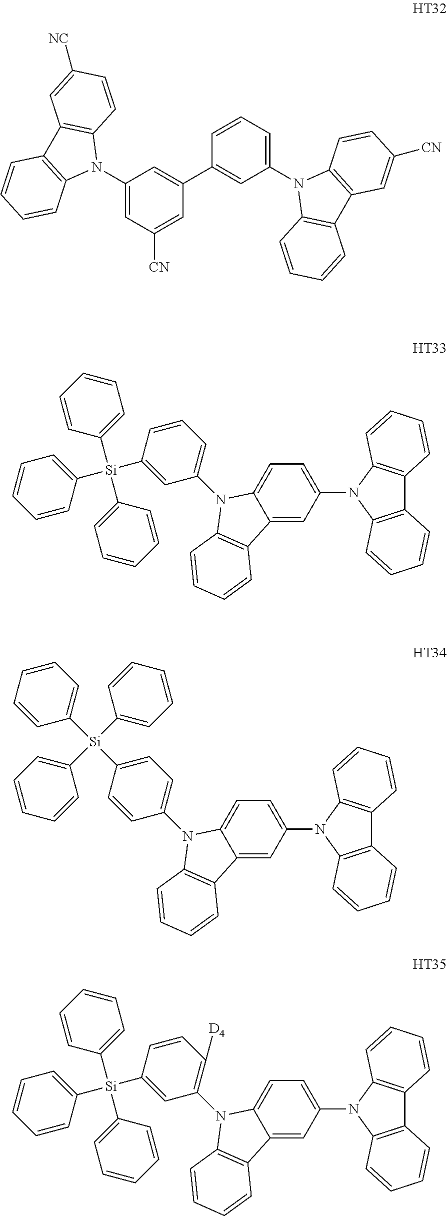

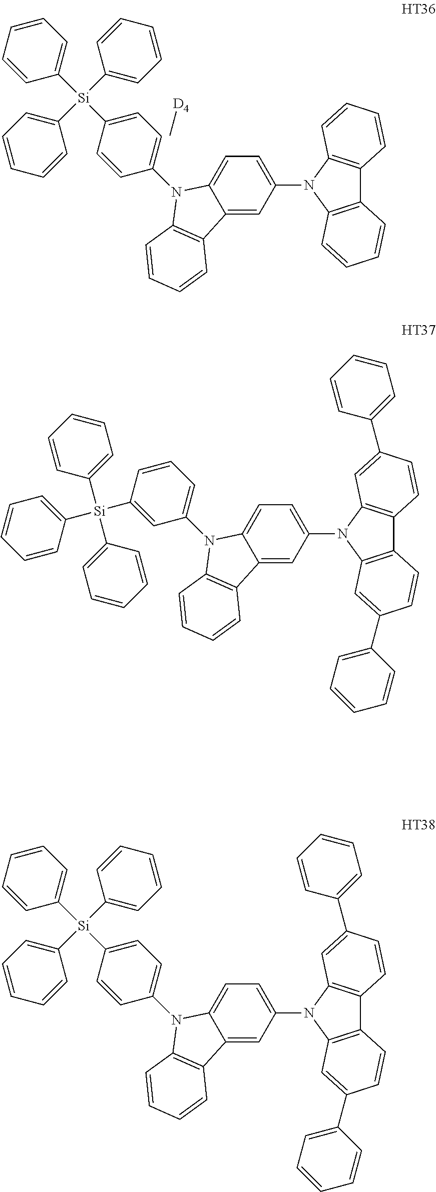

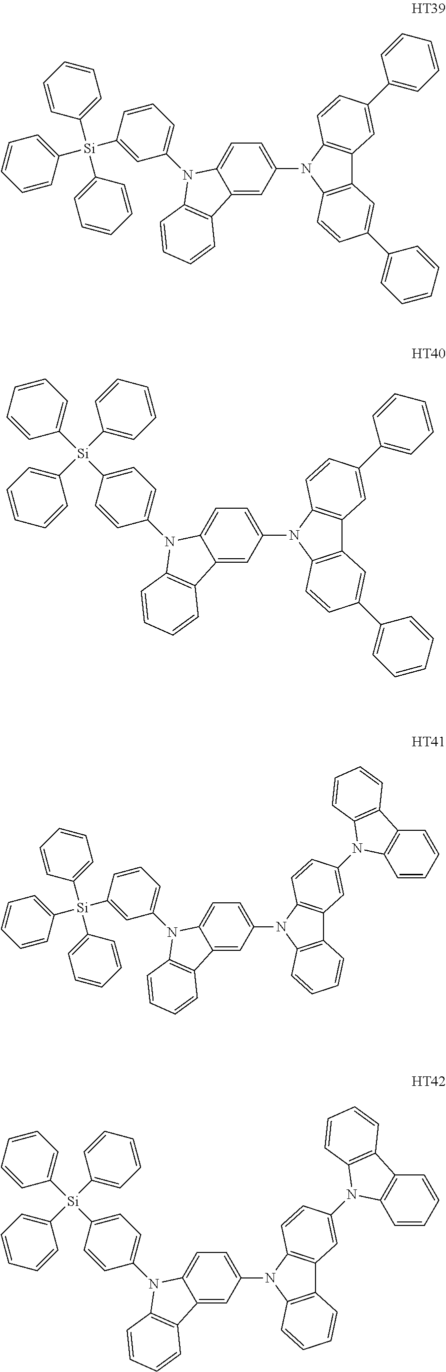 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

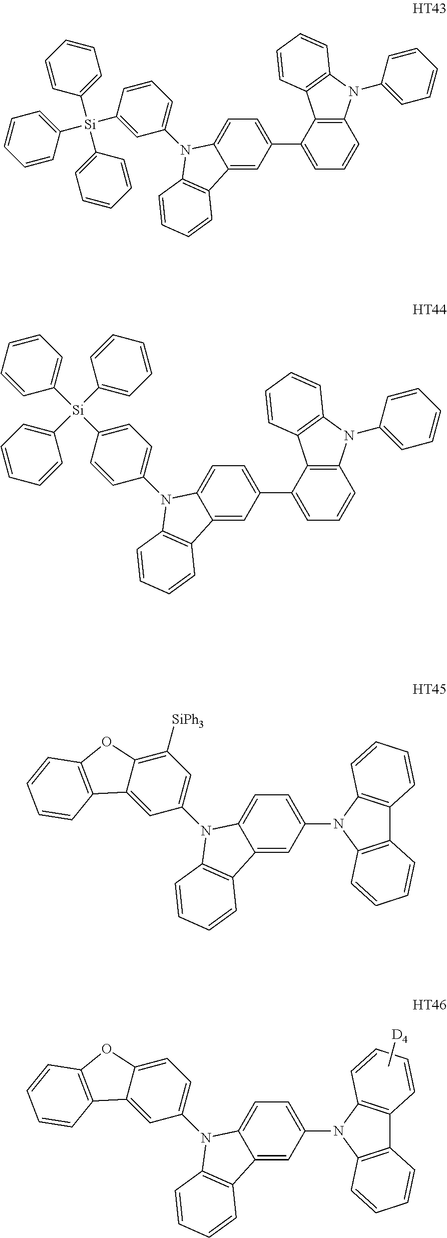

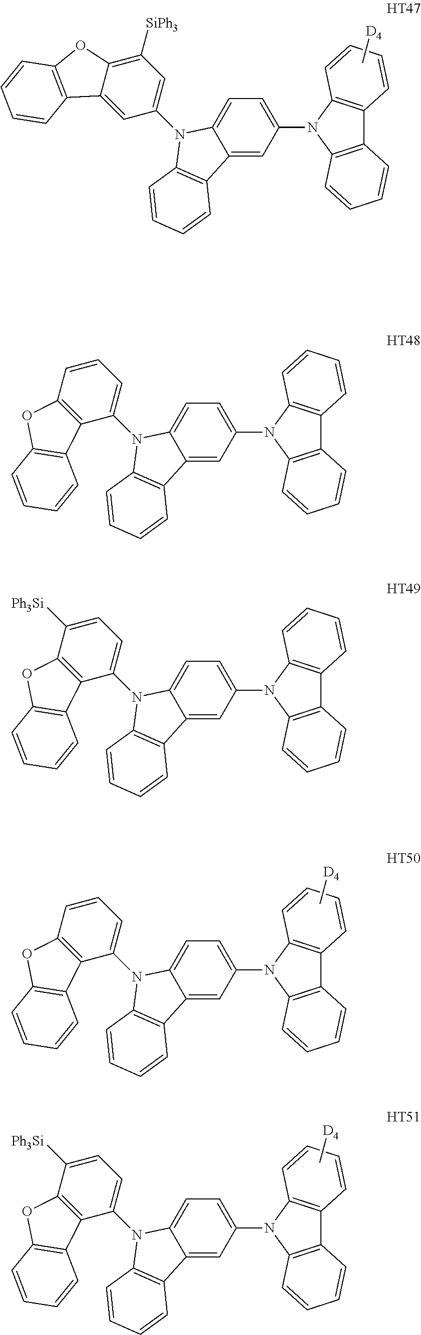

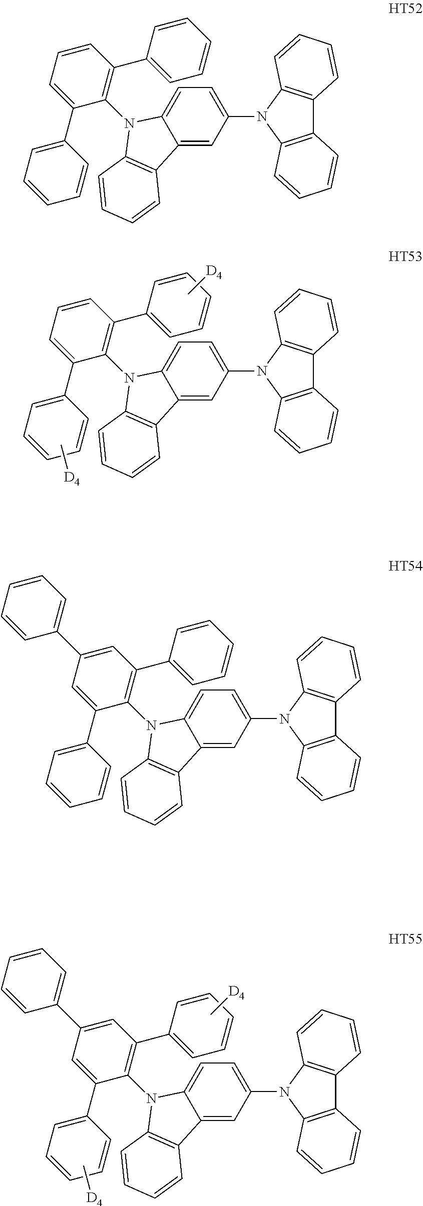

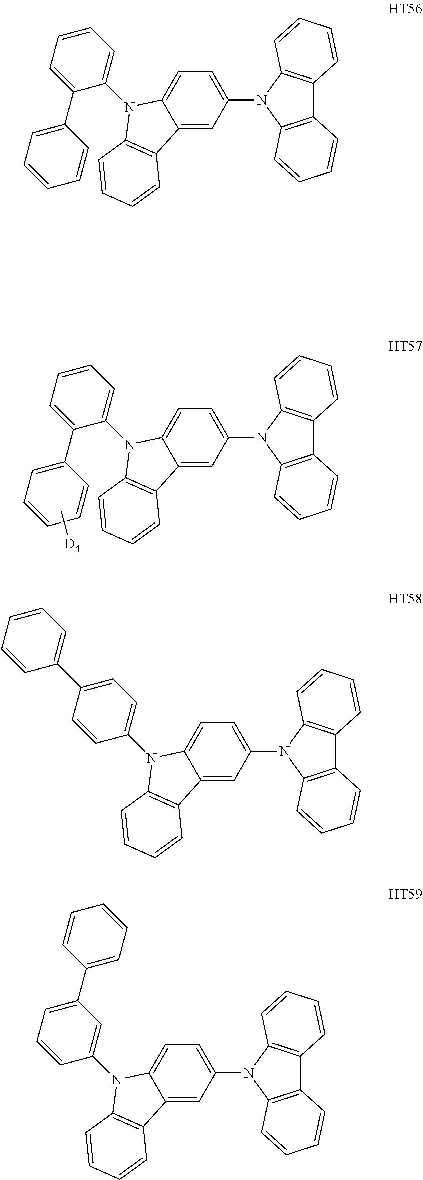

In an embodiment, the emission layer EML may include a third compound represented by Formula ET. In an embodiment, the third compound represented by Formula ET may be used as an electron transport host material for the emission layer EML.

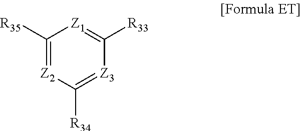

In Formula ET, Z₁ to Z₃ may each independently be N or C(R₃₆); and at least one of Z₁ to Z₃ may each be N. For example, Z₁ to Z₃ may each be N. For example, any two of Z₁ to Z₃ may each be N, and the remainder of Z₁ to Z₃ may be C(R₃₆). For example, any one of Z₁ to Z₃ may be N, and the remainder of Z₁ to Z₃ may each independently be C(R₃₆).

In Formula ET, R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₃₃ to R₃₆ may each independently be a substituted or unsubstituted phenyl group, a substituted or unsubstituted carbazole group, etc., but embodiments are not limited thereto.

In an embodiment, the third compound represented by Formula ET may be selected from Compound Group 3. In an embodiment, in the light emitting element ED, the third compound may include at least one compound selected from Compound Group 3. In Compound Group 3, D represents a deuterium atom.

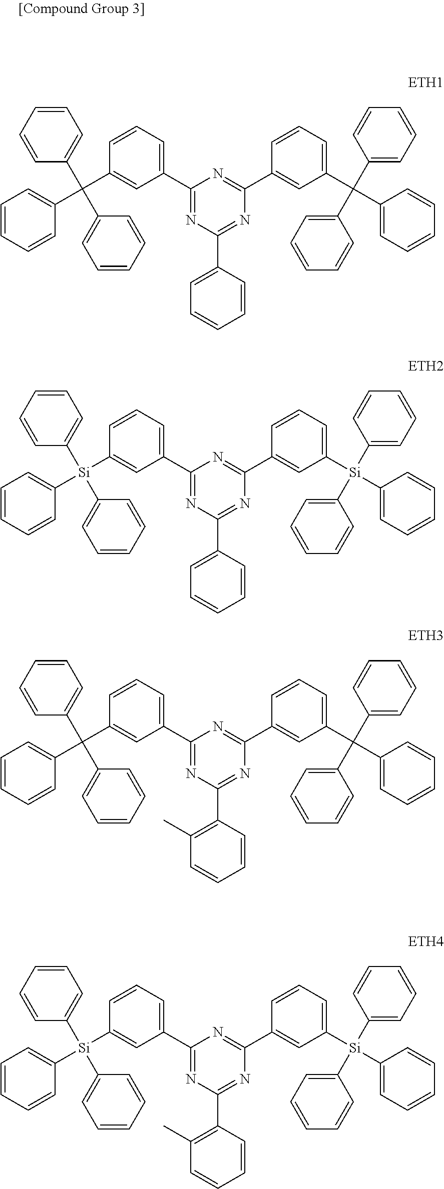 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

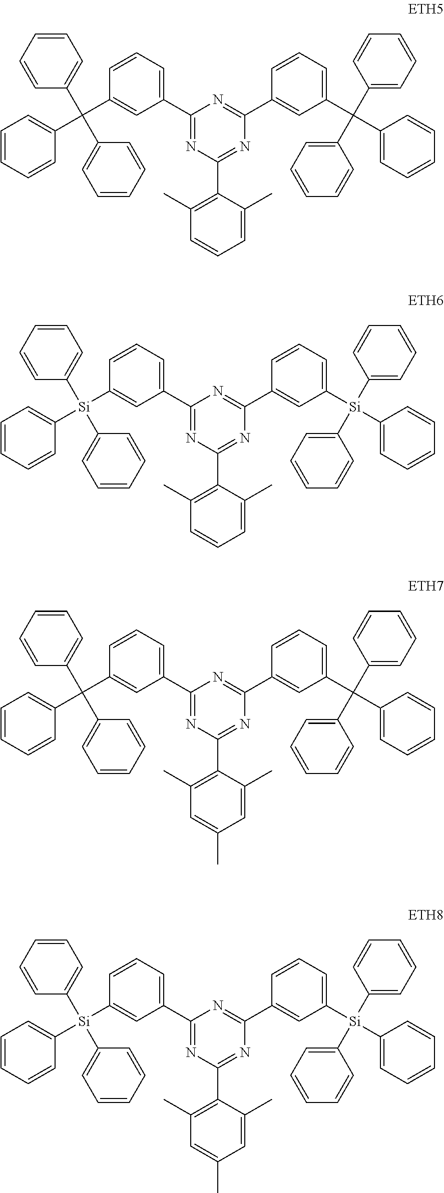 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

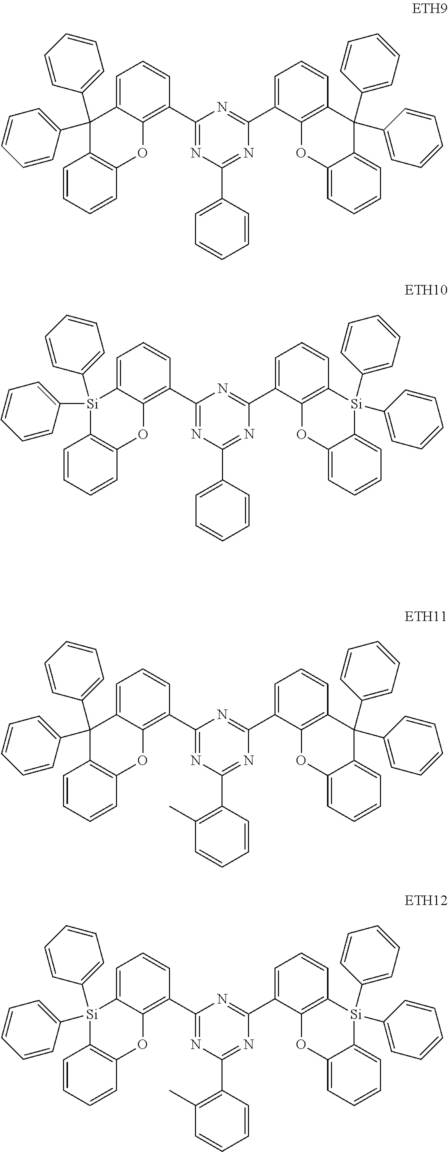 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

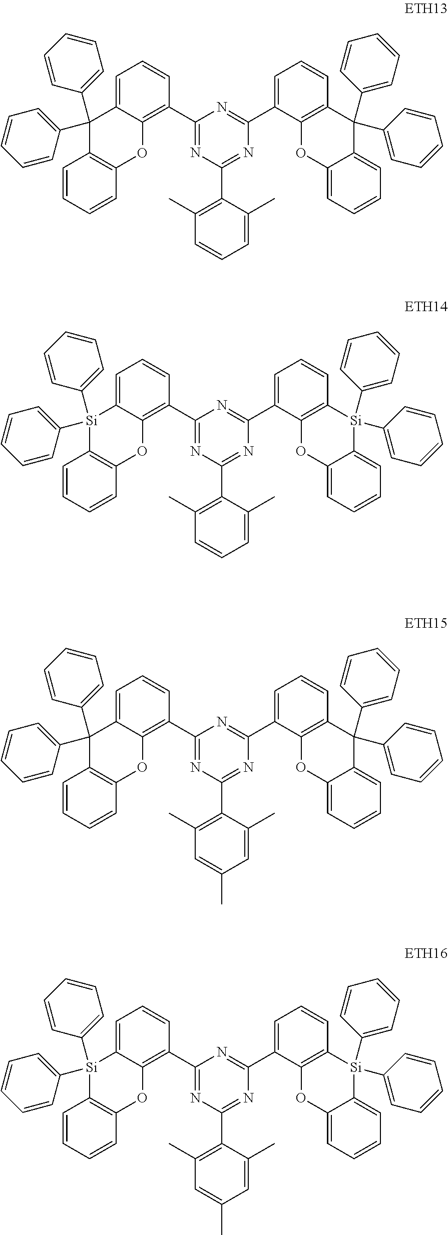 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

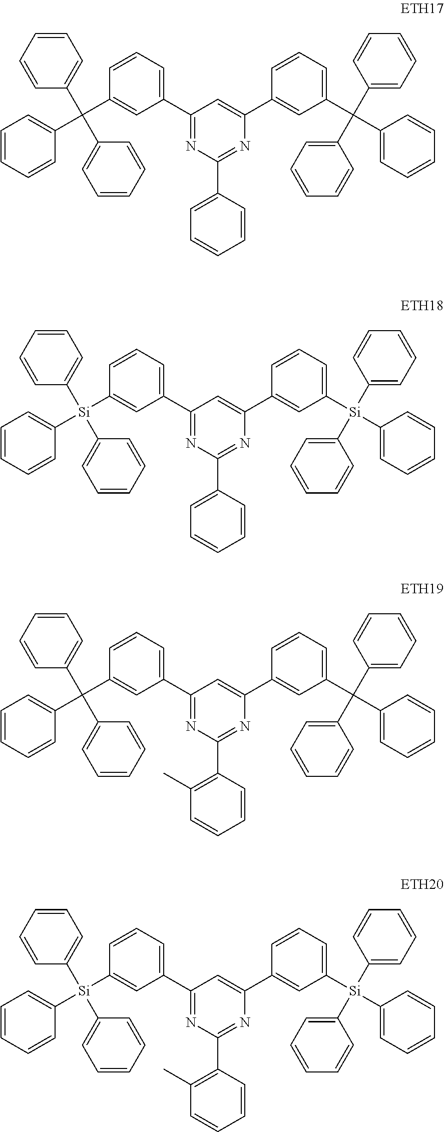 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

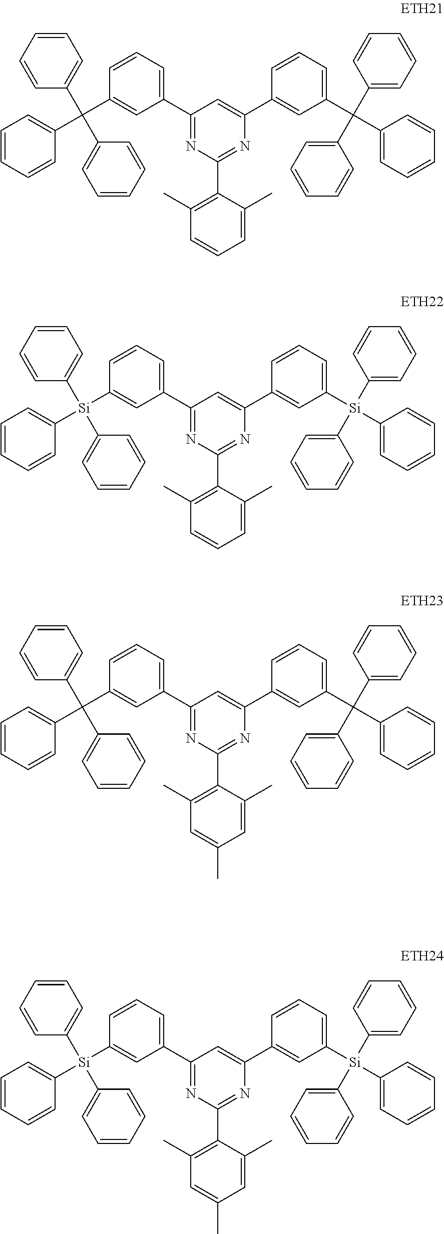 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

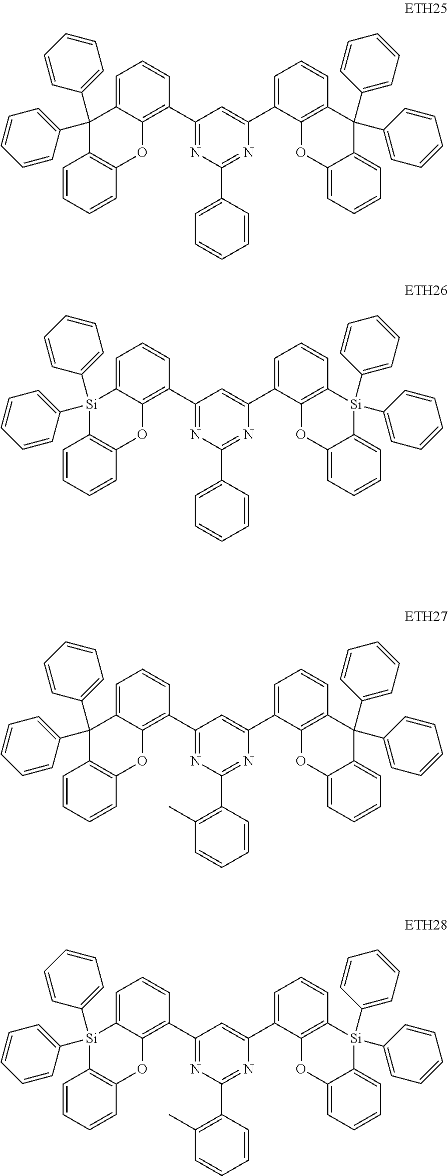 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

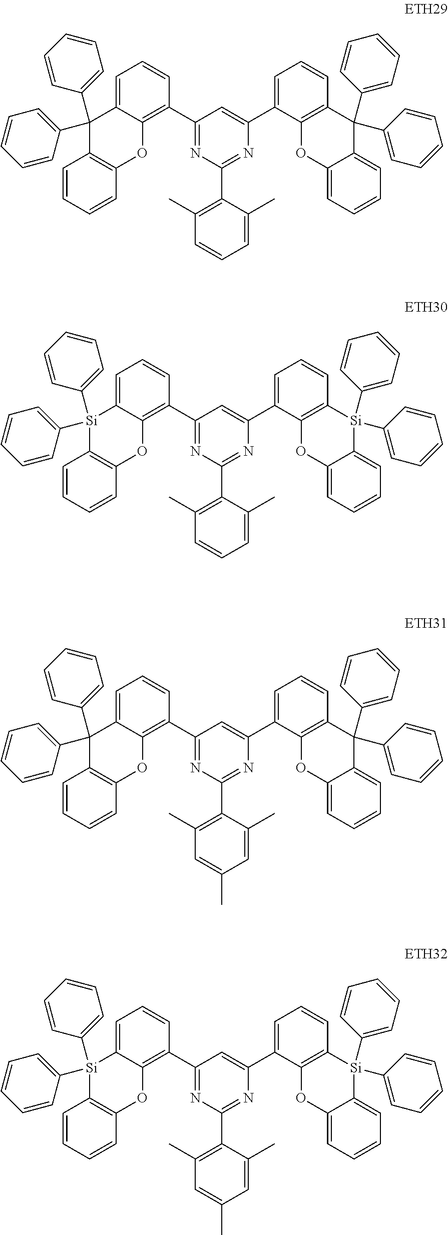 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

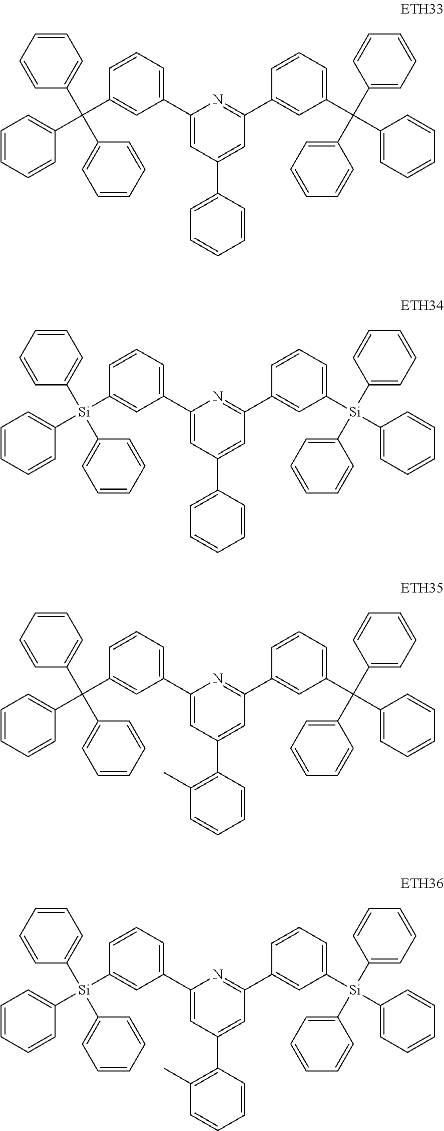 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

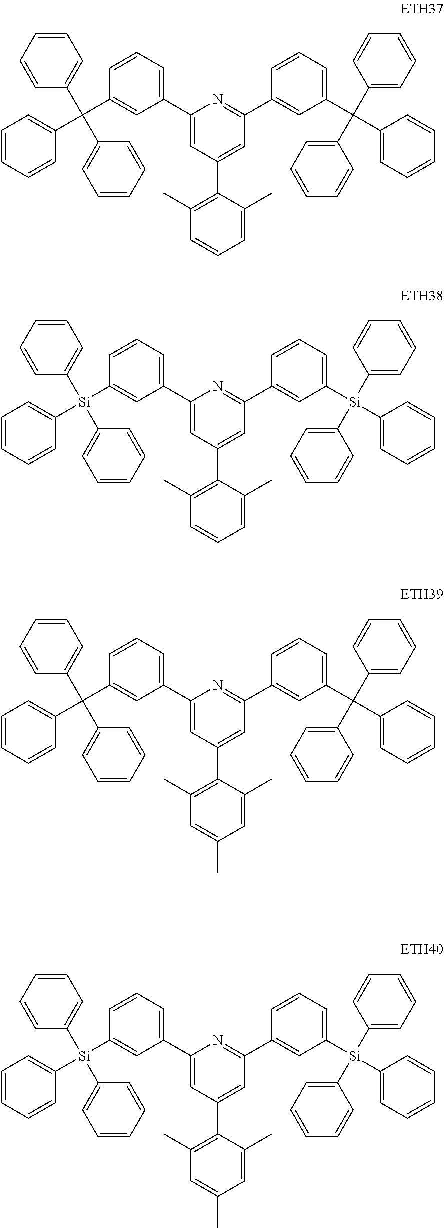 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

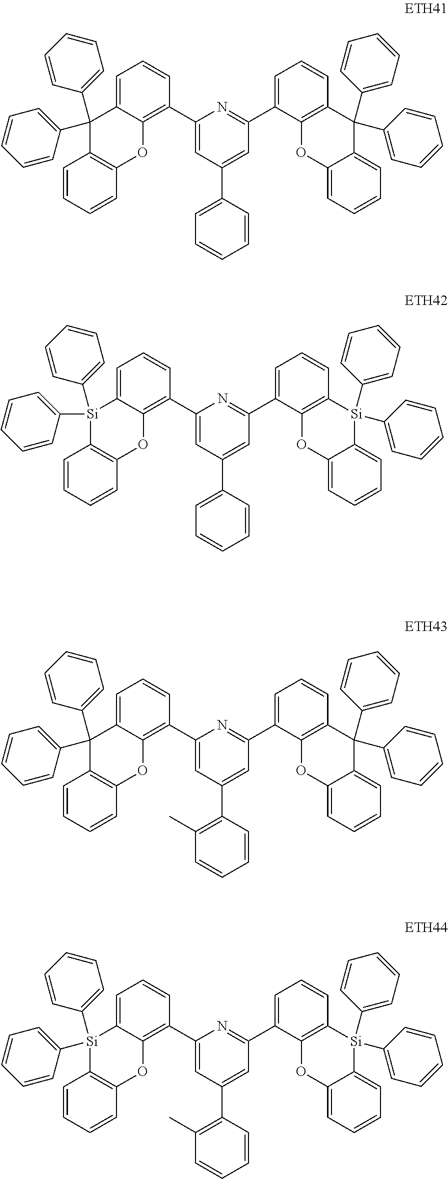 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

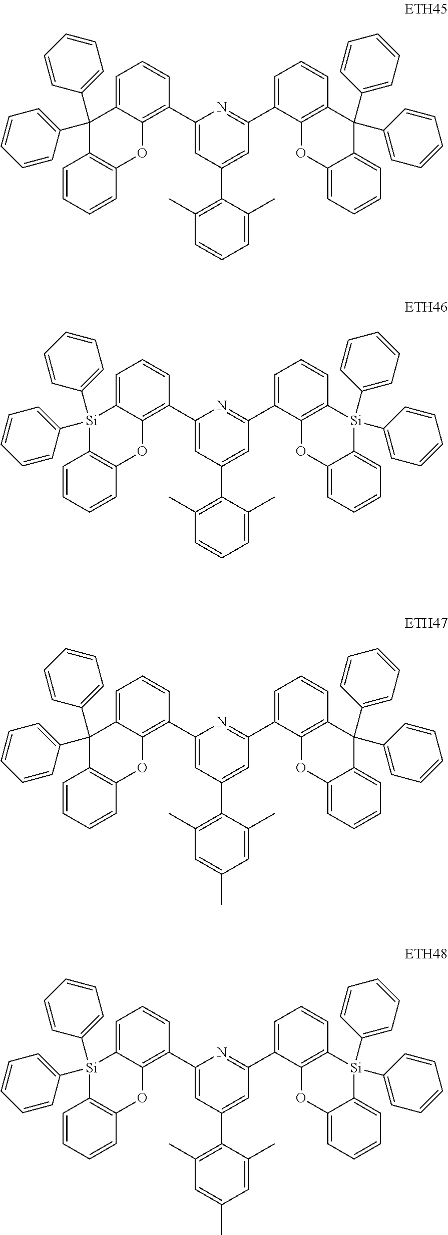 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

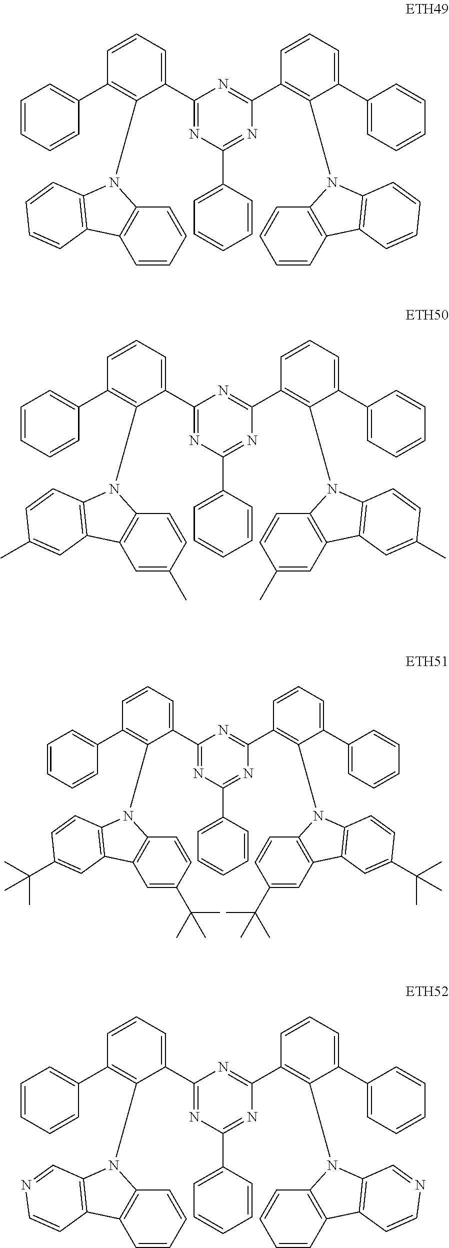

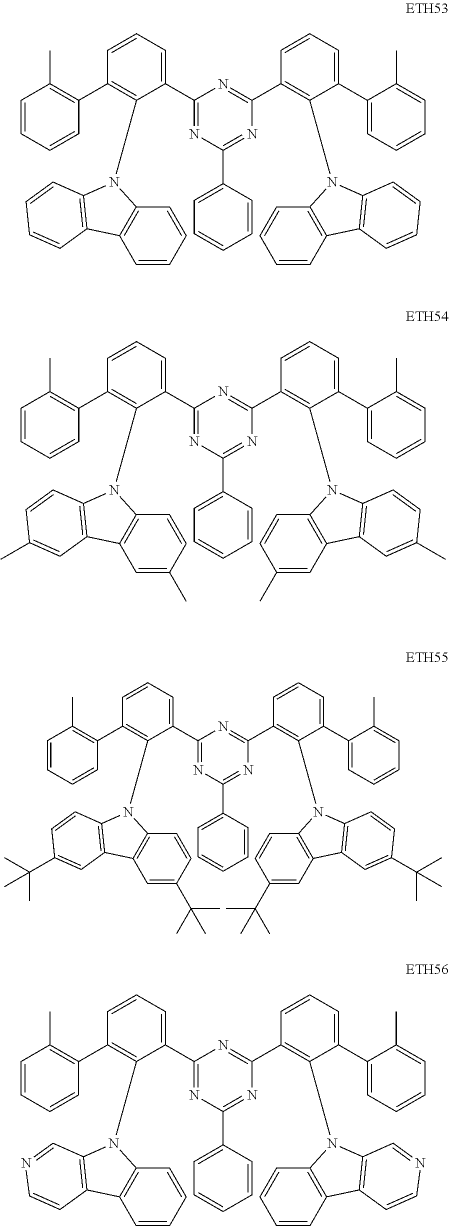

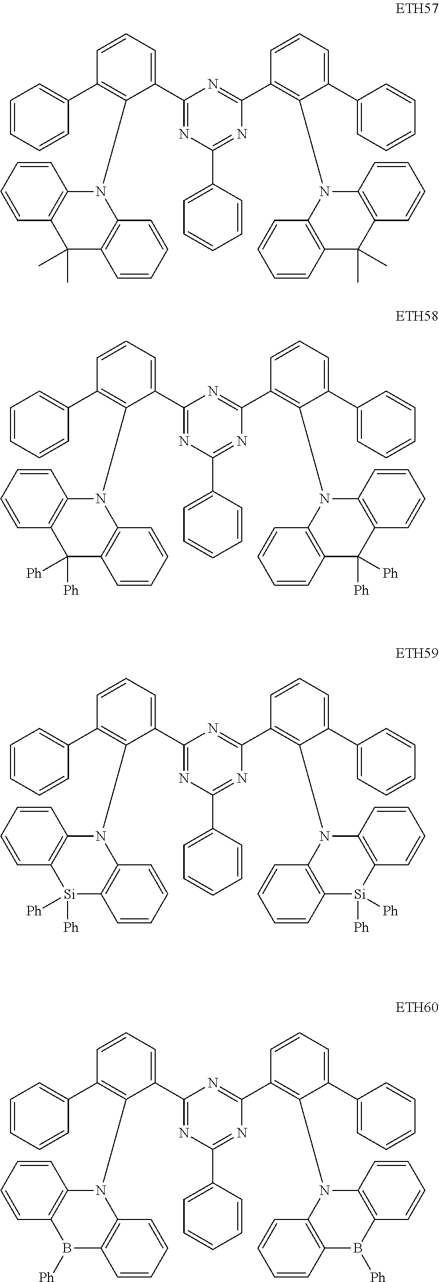

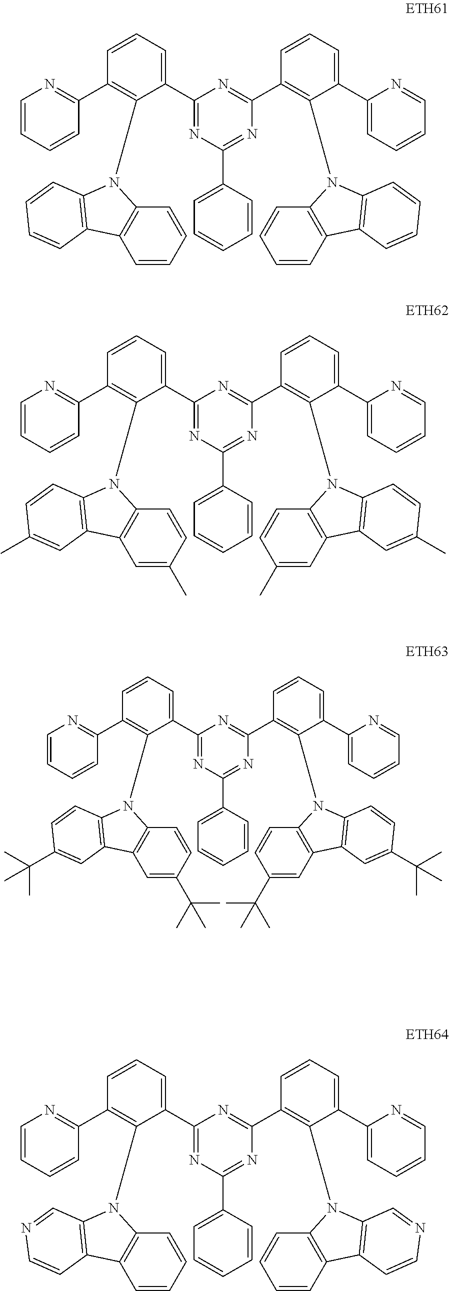

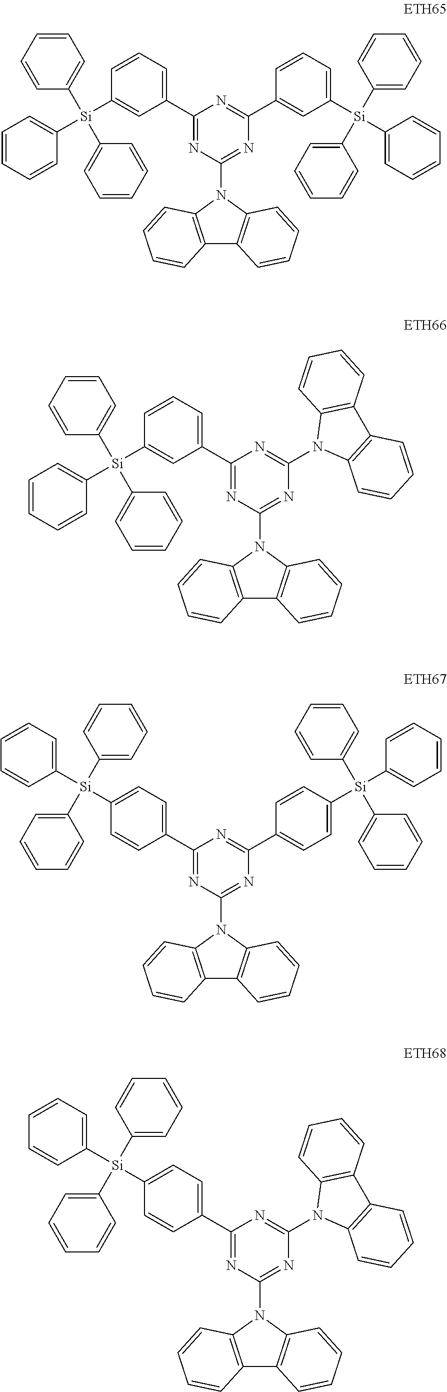 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

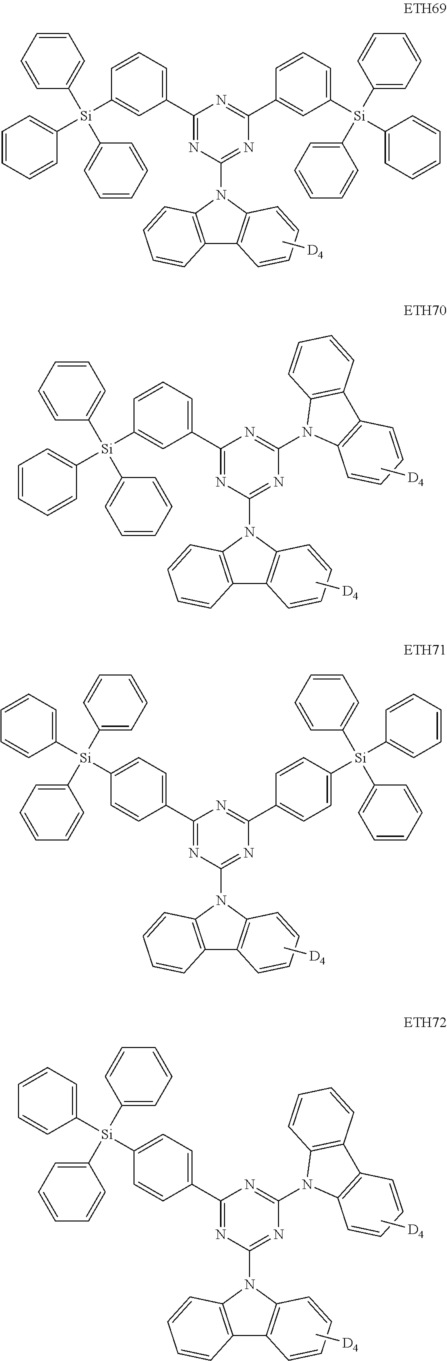

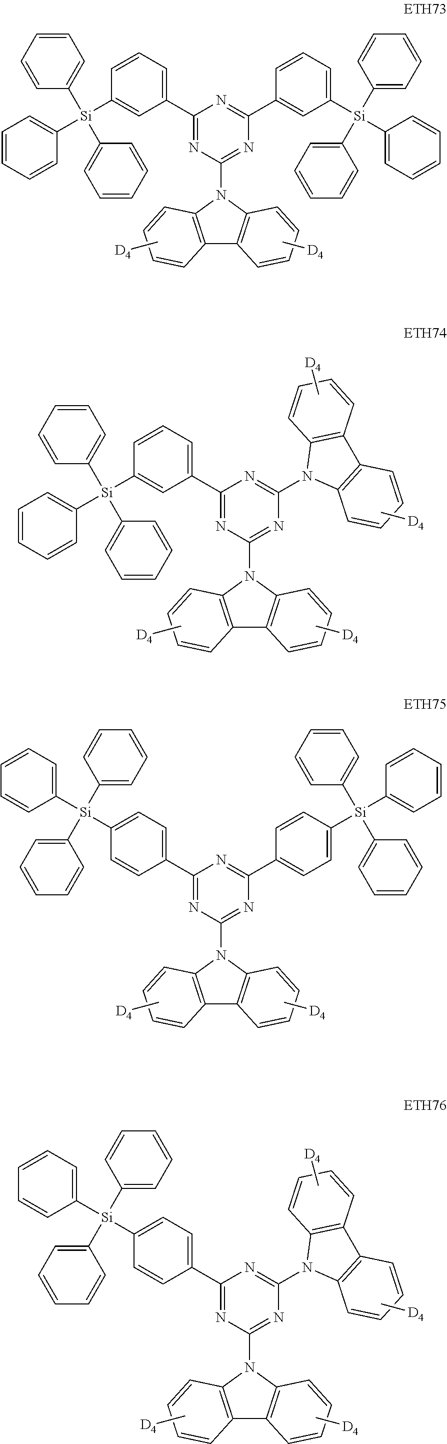

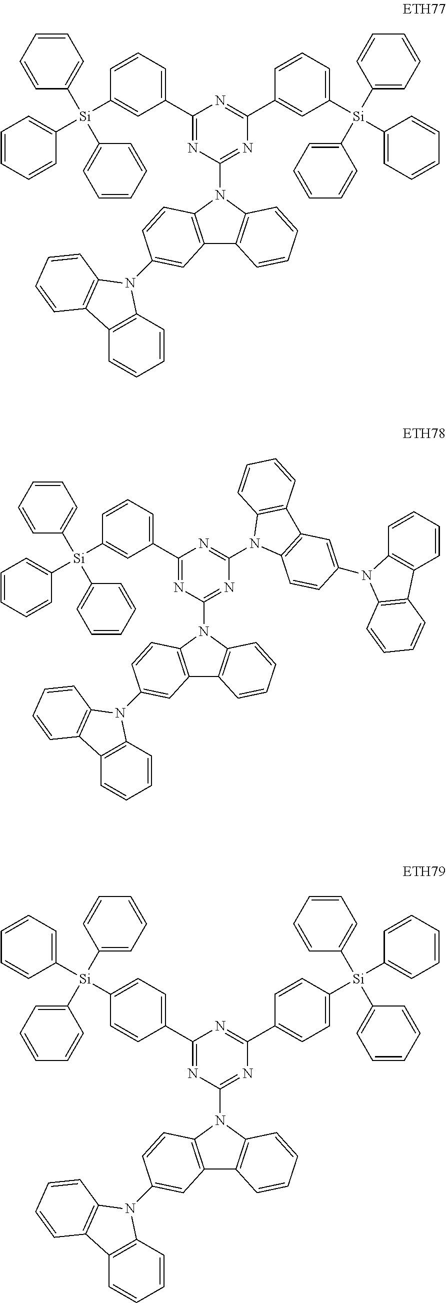 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

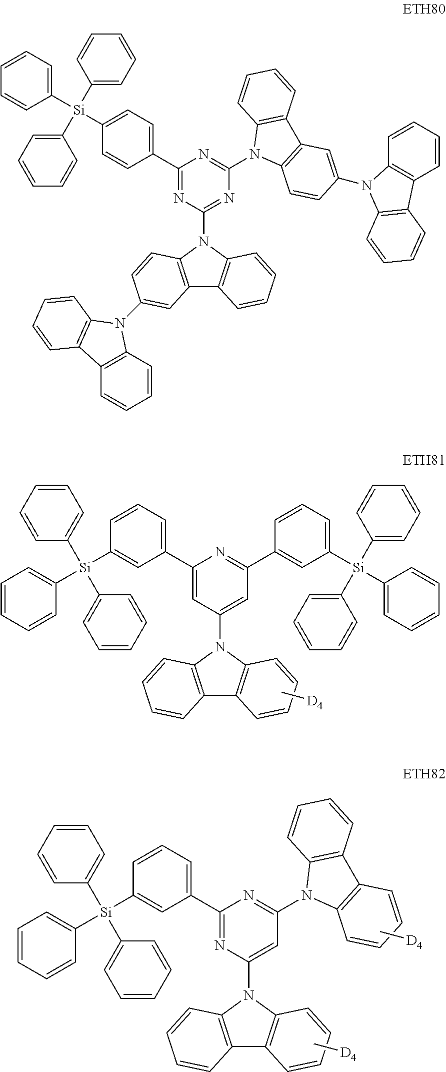

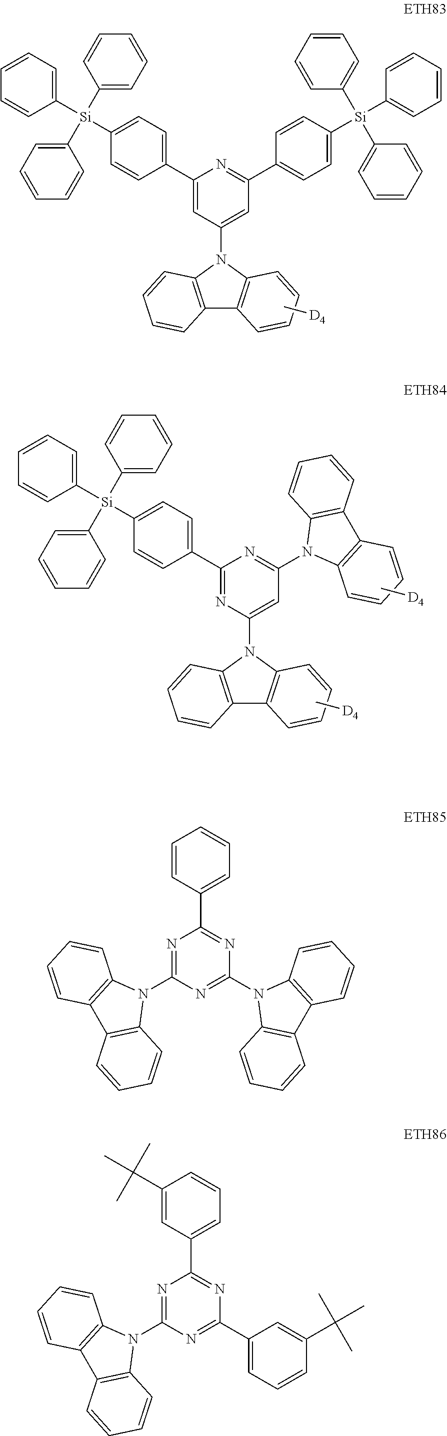

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (T1) of the exciplex formed by a hole transport host and an electron transport host may be in a range of about 2.4 eV to about 3.0 eV. A triplet energy level of the exciplex may be a value that is smaller than an energy gap of each host material. The exciplex may have a triplet energy level equal to or less than about 3.0 eV, which is an energy gap between the hole transport host and the electron transport host.

In an embodiment, the emission layer EML may include a fourth compound represented by Formula PS. In an embodiment, the fourth compound may be used as a phosphorescent sensitizer in an emission layer EML. Energy may be transferred from the fourth compound to the first compound, thereby emitting light.

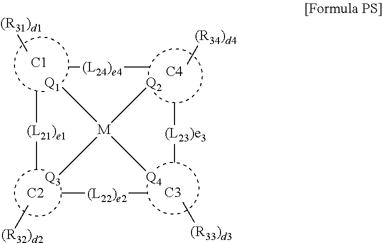

In Formula PS, M may be platinum (Pt) or iridium (Ir). In Formula PS, Q₁ to Q₄ may each independently be C or N; and C1 to C4 may each independently be a substituted or unsubstituted hydrocarbon ring group having 5 to 30 ring-forming carbon atoms or a substituted or unsubstituted heterocyclic group having 2 to 30 ring-forming carbon atoms.

In Formula PS, e1 to e4 may each independently be 0 or 1; and L₂₁ to L₂₄ may each independently be a direct linkage,

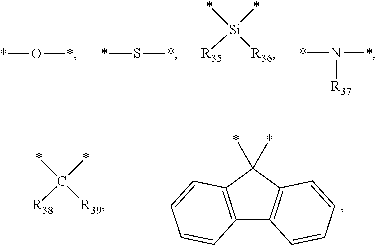

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

In Formula PS, d1 to d4 may each independently be an integer from 0 to 4. When d1 is 2 or more, multiple R₃₁ groups may be the same as each other, or at least one group thereof may be different from the remainder. When d2 is 2 or more, multiple R₃₂ groups may be the same as each other, or at least one group thereof may be different from the remainder. When d3 is 2 or more, multiple R₃₃ groups may be the same as each other, or at least one group thereof may be different from the remainder. When d4 is 2 or more, multiple R₃₄ groups may be the same as each other, or at least one group thereof may be different from the remainder.

In Formula PS, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In an embodiment, the fourth compound represented by Formula PS may be selected from Compound Group 4. In an embodiment, in the light emitting element ED, the fourth compound may include at least one compound selected from Compound Group 4.

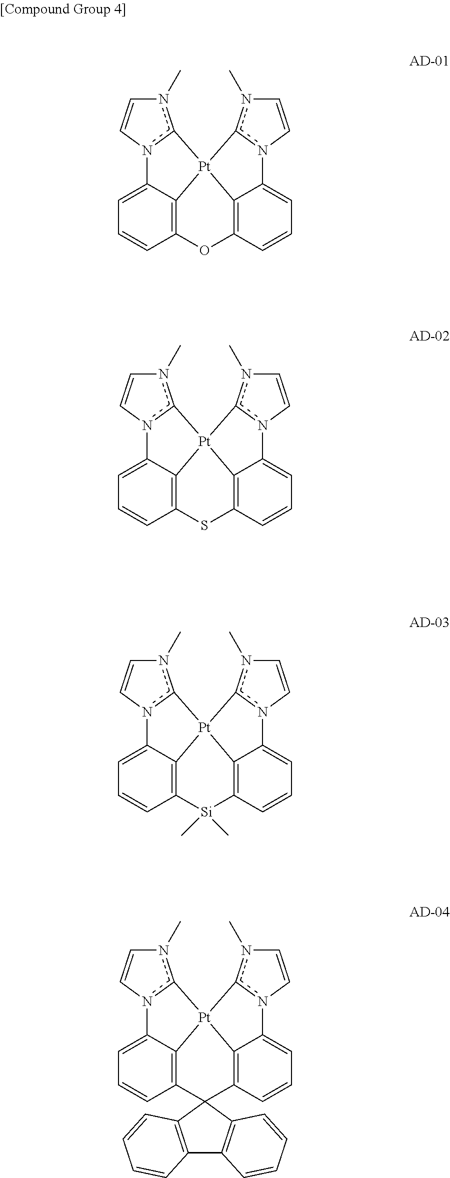

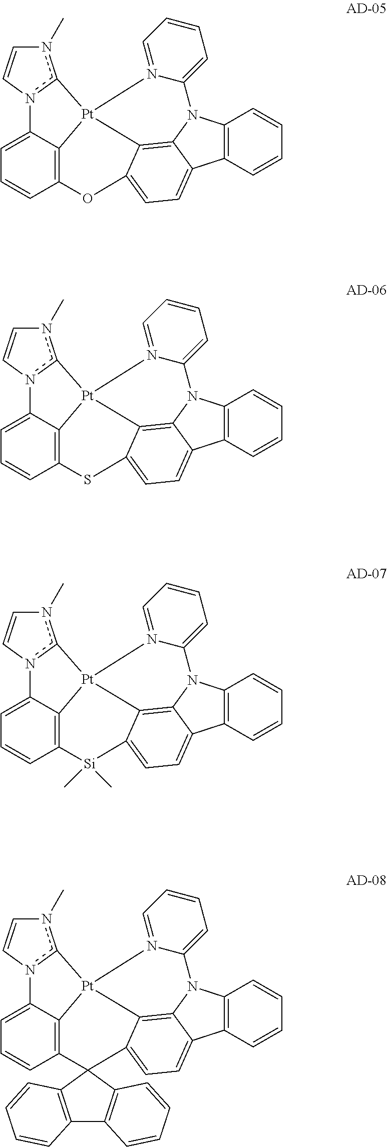

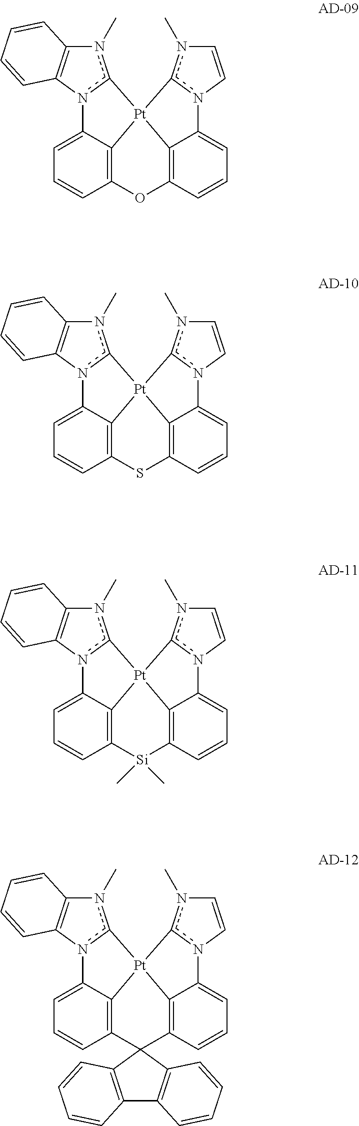

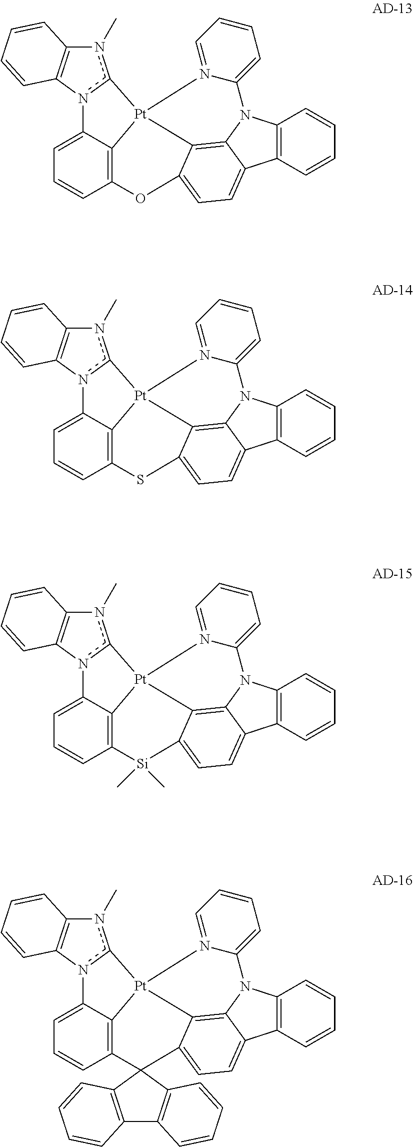

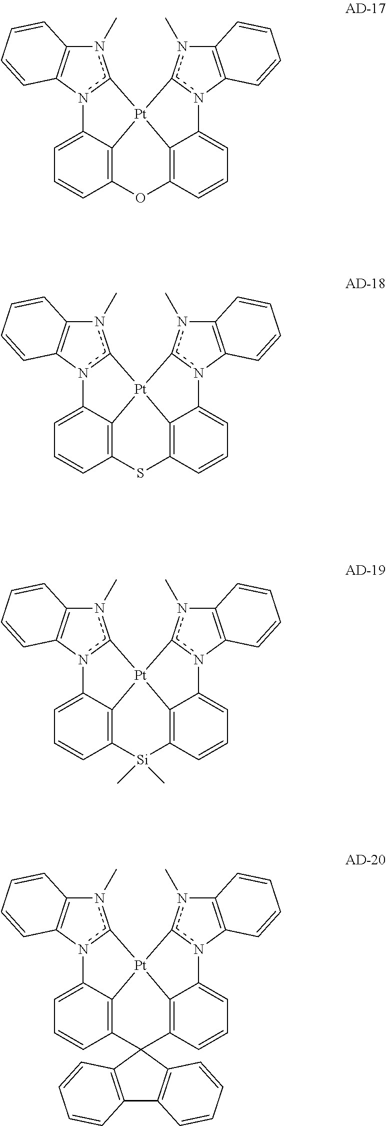

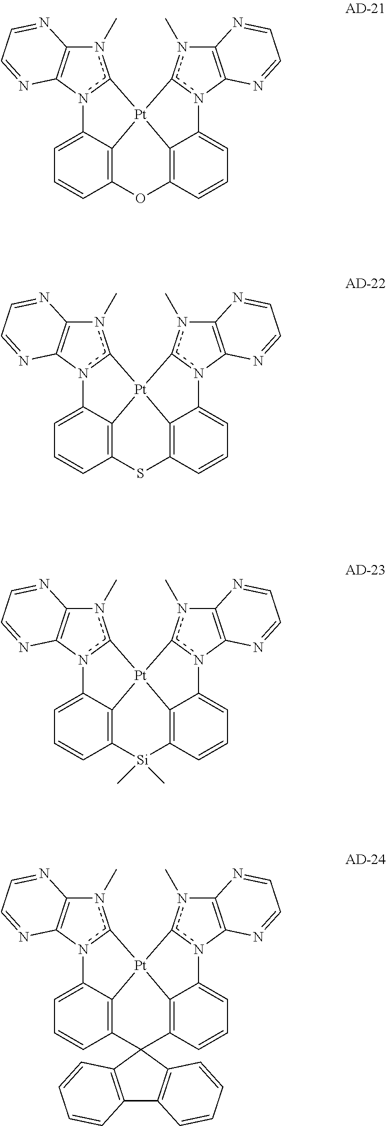

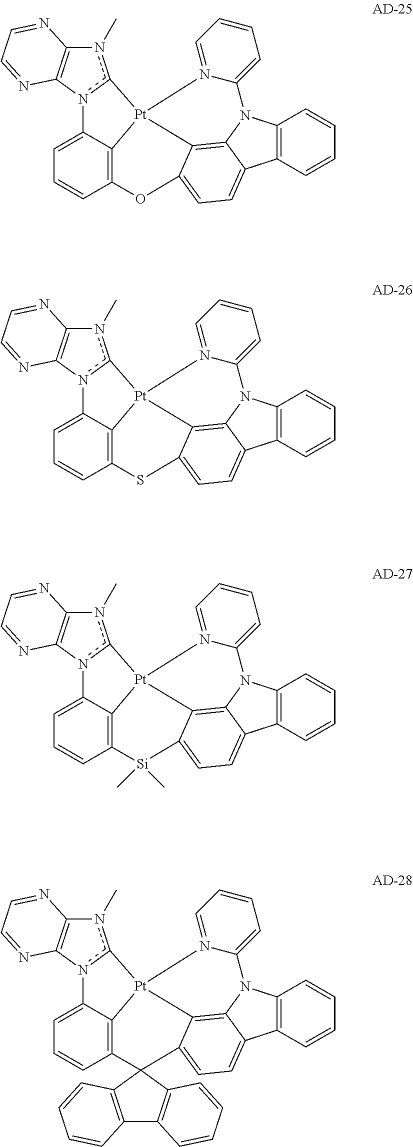

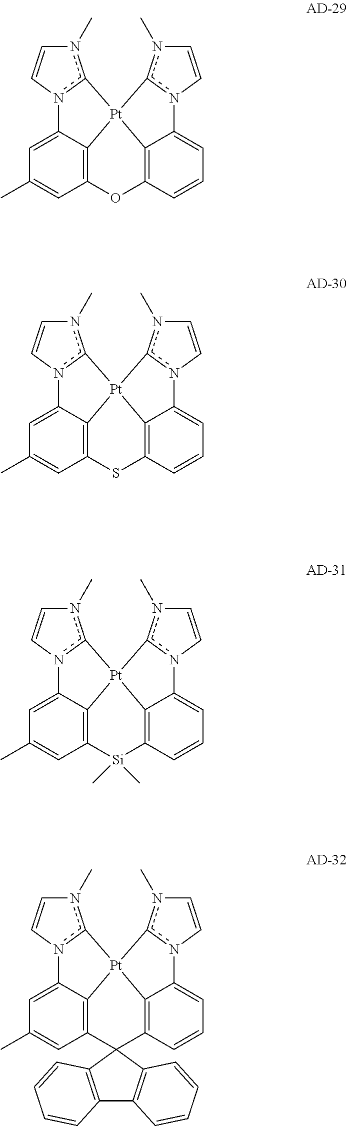

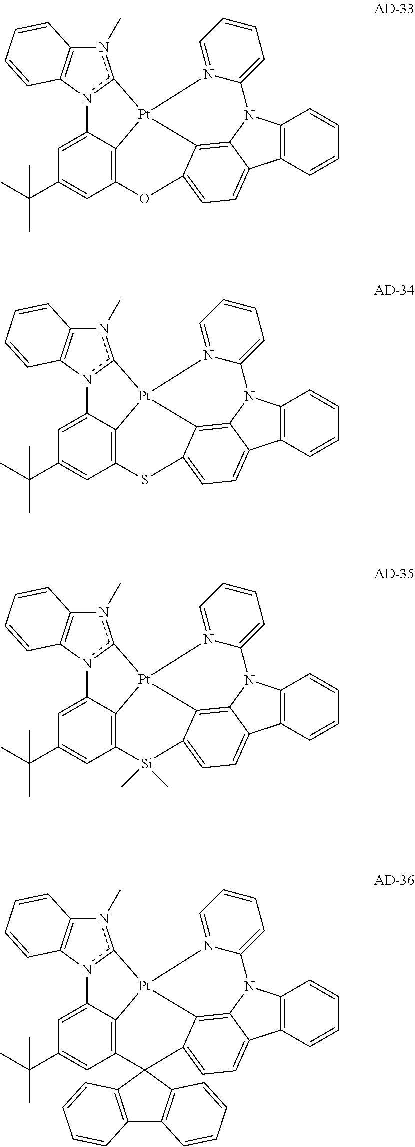

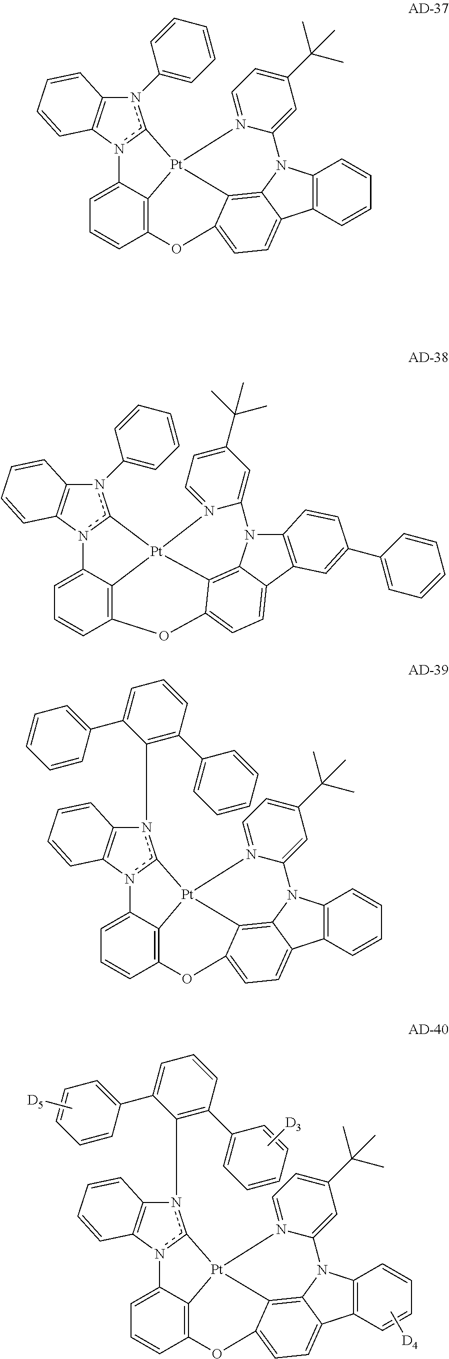

In an embodiment, the light emitting element ED may include multiple emission layers. The emission layers may be provided as a stack of emission layers, so that a light emitting element ED including multiple emission layers may emit white light. The light emitting element ED including multiple emission layers may be a light emitting element having a tandem structure. When the light emitting element ED includes multiple emission layers, at least one emission layer EML may include the first compound represented by Formula 1. When the light emitting element ED includes multiple emission layers, at least one emission layer EML may include the first compound, the second compound, the third compound, and the fourth compound as described above.

In an embodiment, the emission layer EML may further include a material for the emission layer besides the first to fourth compounds as described above. In the light emitting element ED, the emission layer EML may further include an anthracene derivative, a pyrene derivative, a fluoranthene derivative, a chrysene derivative, a dihydrobenzanthracene derivative, a triphenylene derivative, or the like. For example, the emission layer EML may further include an anthracene derivative or a pyrene derivative.

In the light emitting element ED according to embodiments as illustrated in FIGS. 3 to 6, the emission layer EML may include a compound represented by Formula E-1. The compound represented by Formula E-1 may be used as a fluorescent host material.

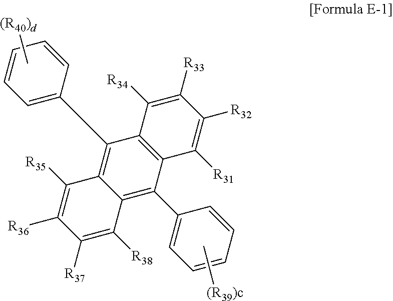

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19:

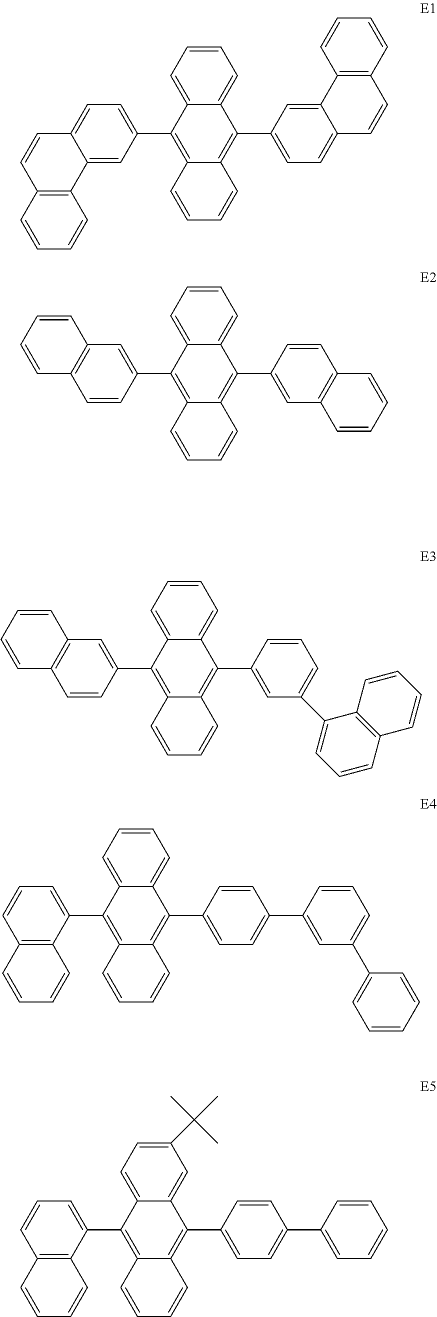

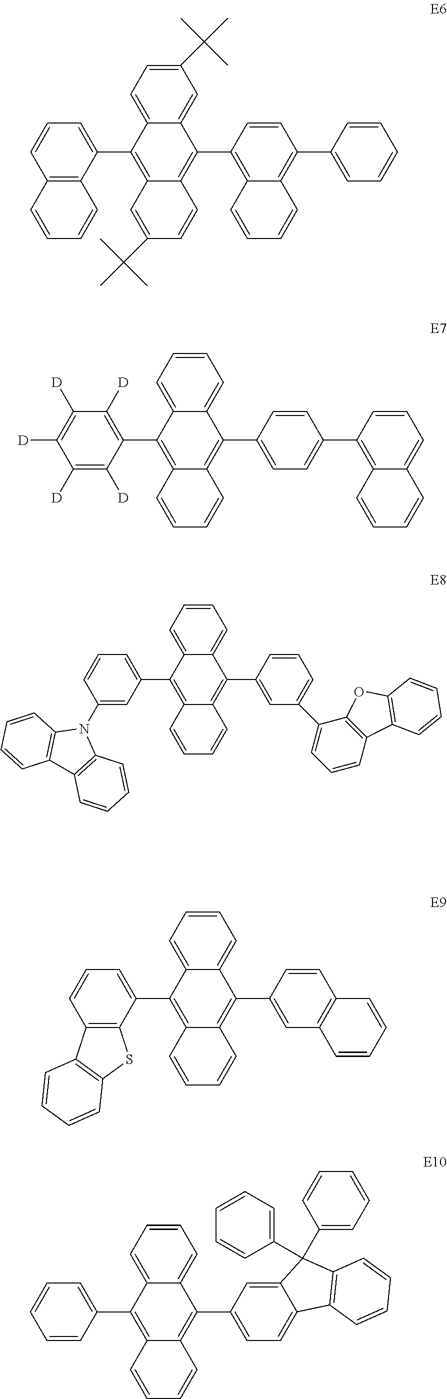

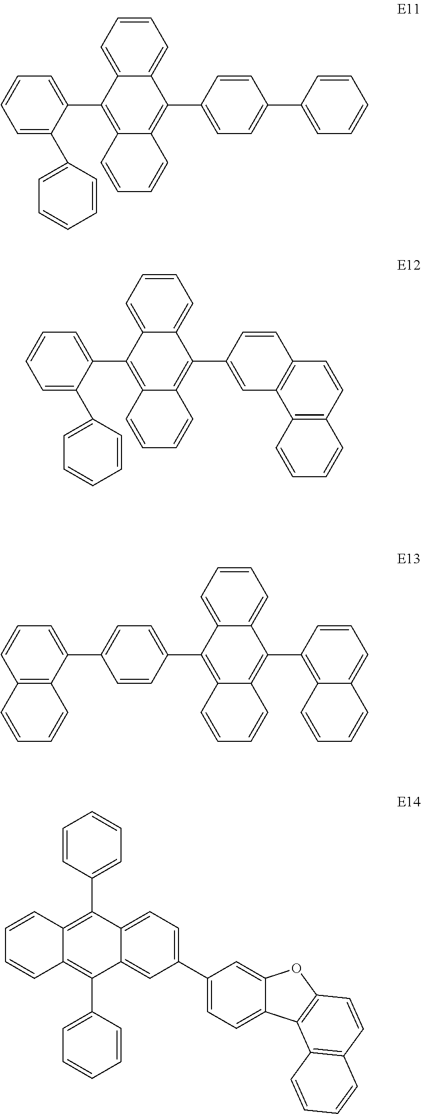

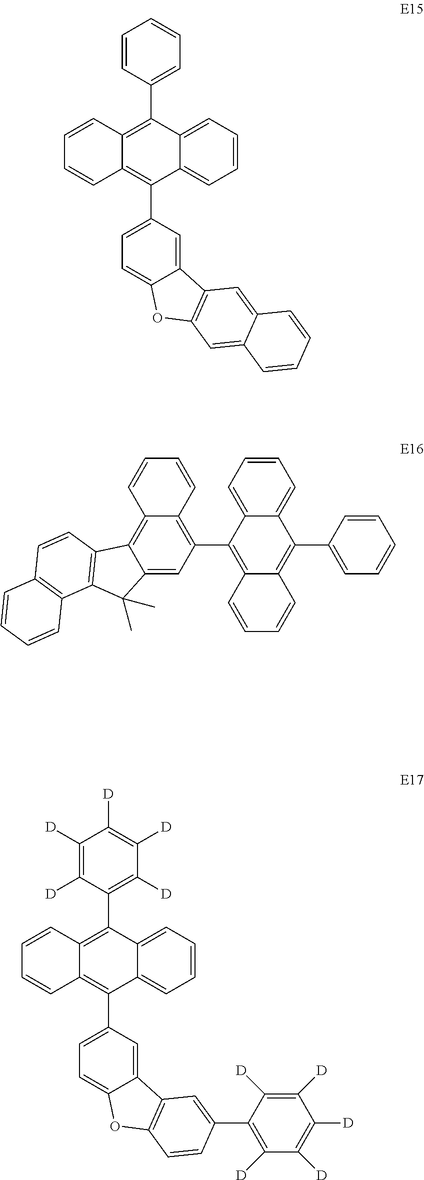

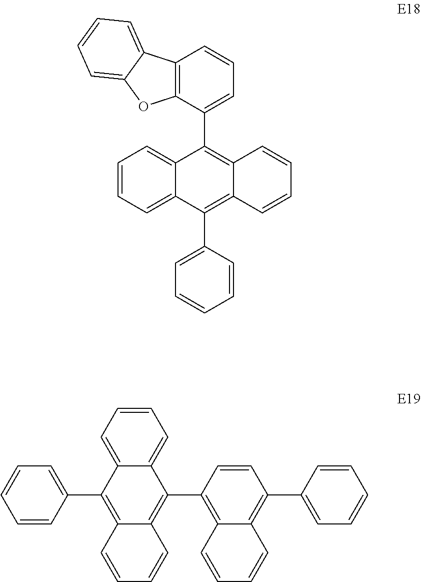

In an embodiment, the emission layer EML may include a compound represented by Formula E-2a or Formula E-2b. The compound represented by Formula E-2a or Formula E-2b may be used as a phosphorescent host material.

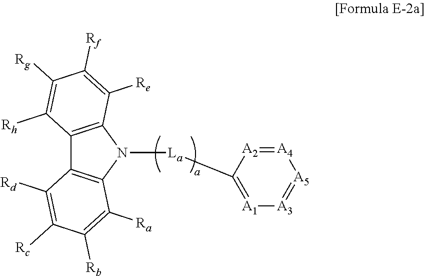

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or more, multiple Lₐ groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

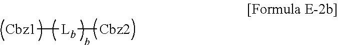

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer of 0 to 10, and when b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

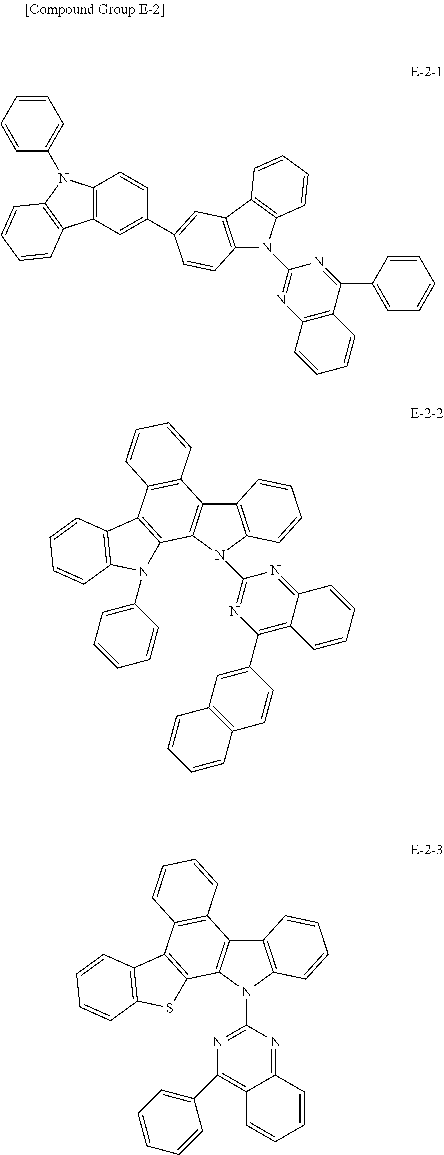 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

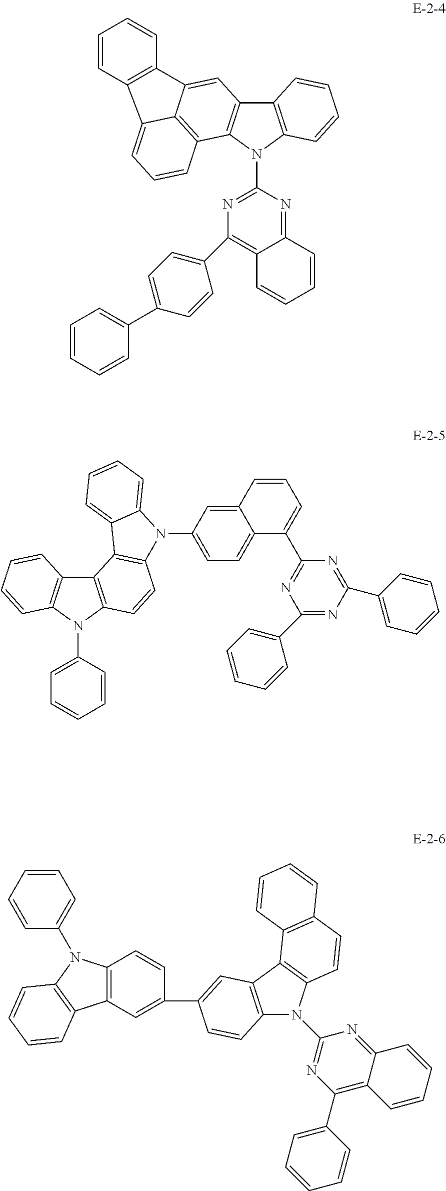 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

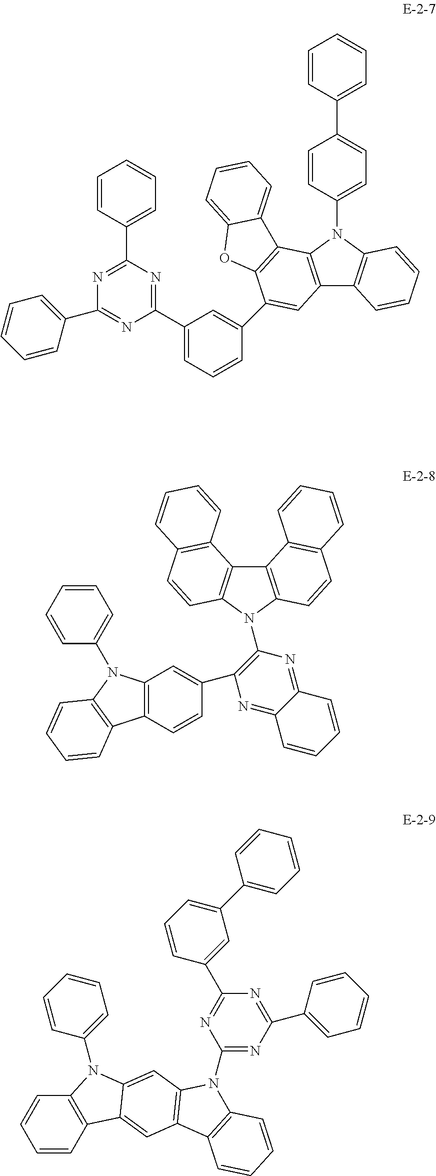 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

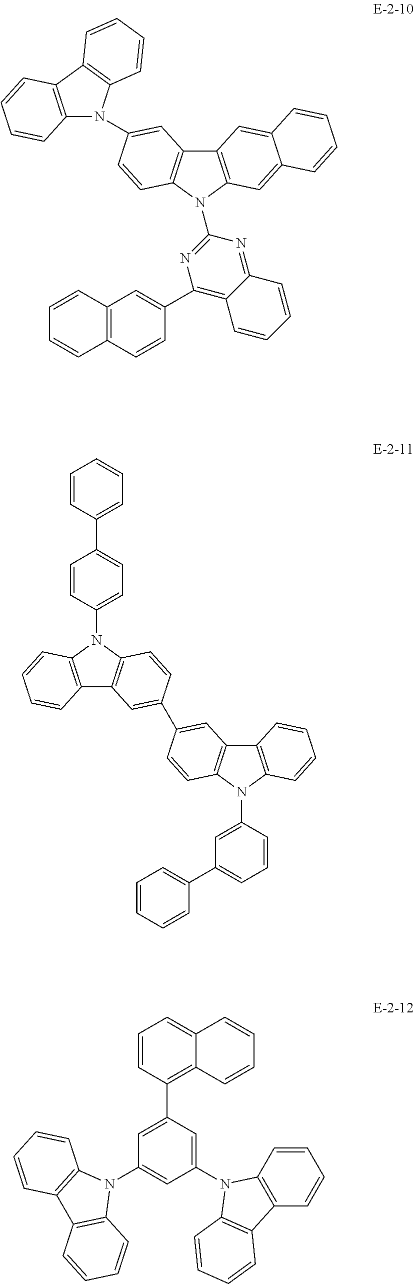 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

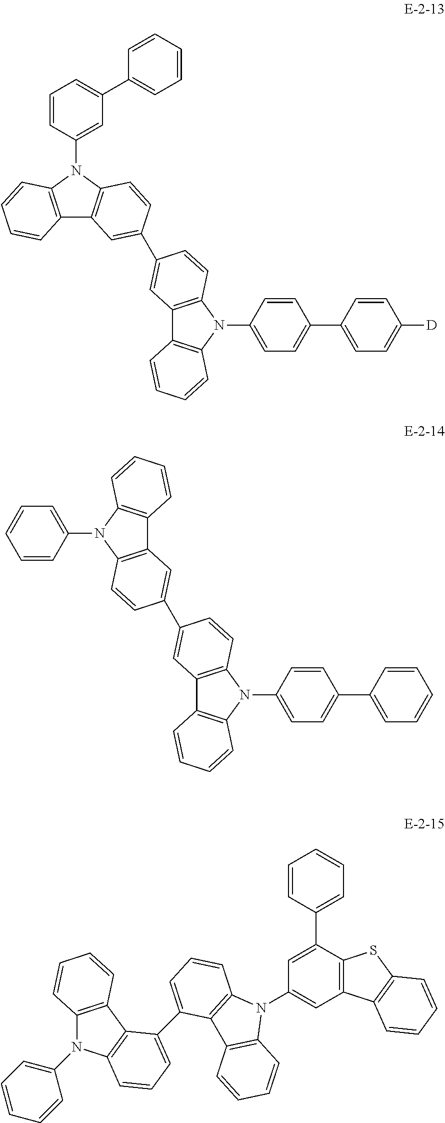 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

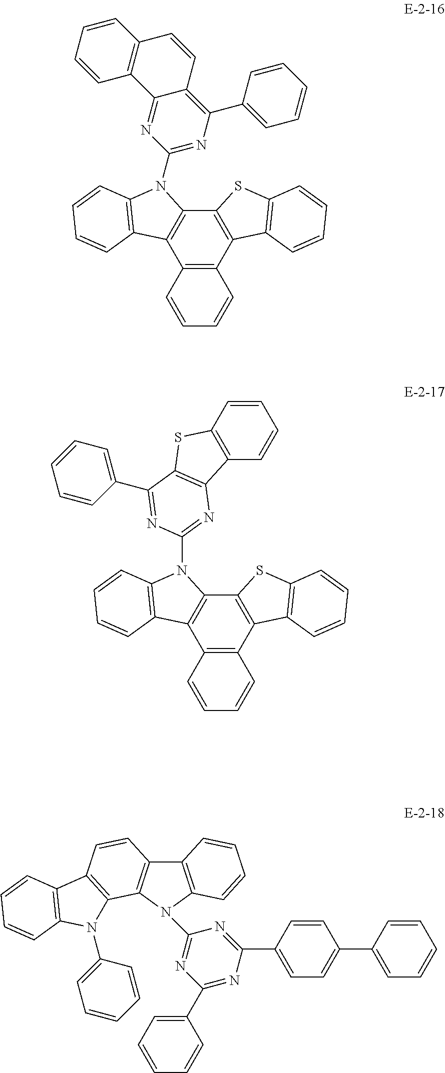 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

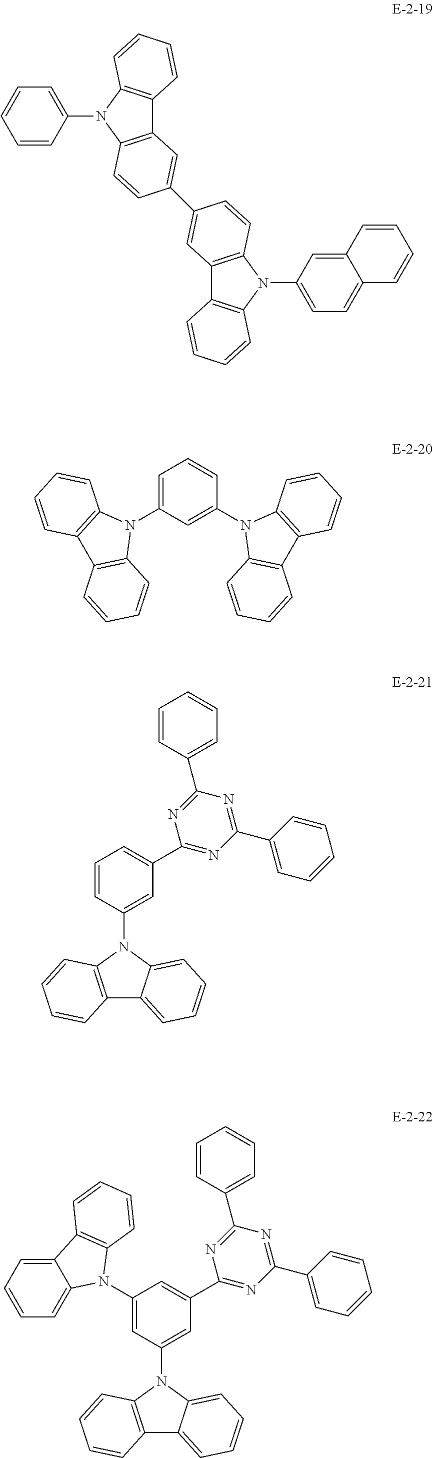 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

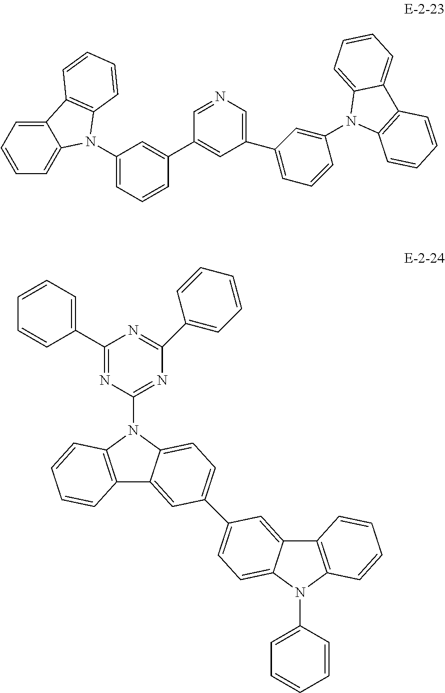 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 3,3′-di(9H-carbazol-9-yl)-1,1′-biphenyl (mCBP), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

The emission layer EML may include a compound represented by Formula M-a. The compound represented by Formula M-a may be used as a phosphorescent dopant material. In an embodiment, the compound represented by Formula M-a may be used as an auxiliary dopant material.

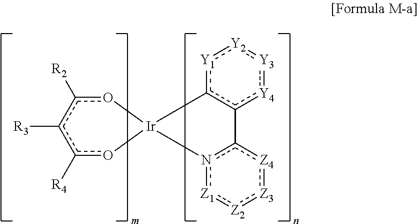

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

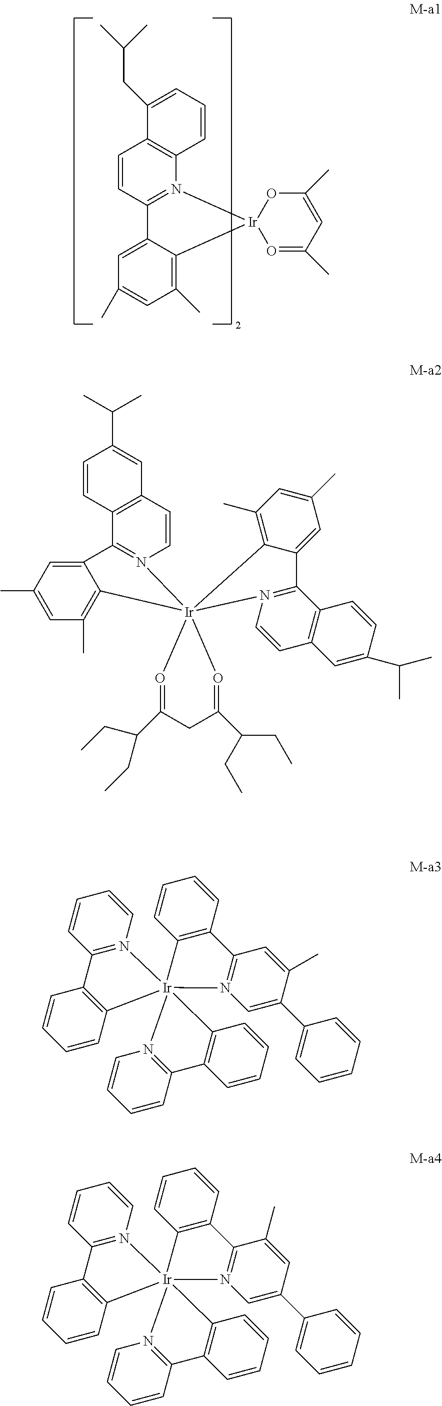

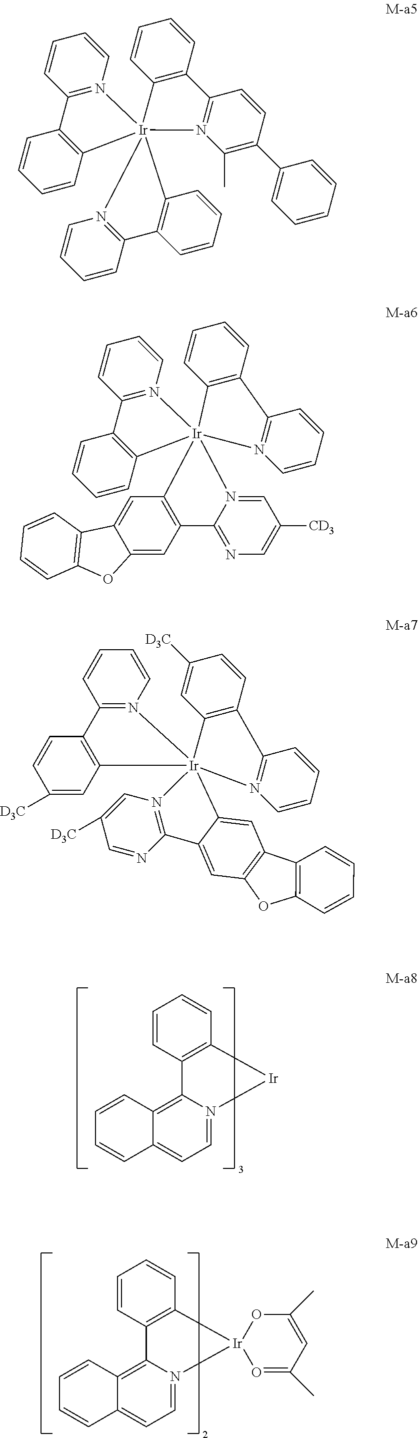

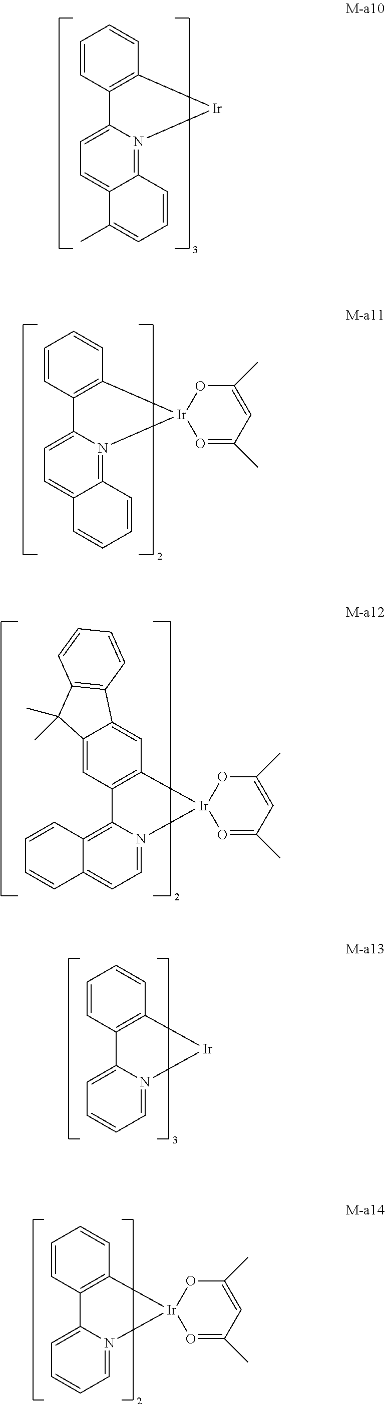

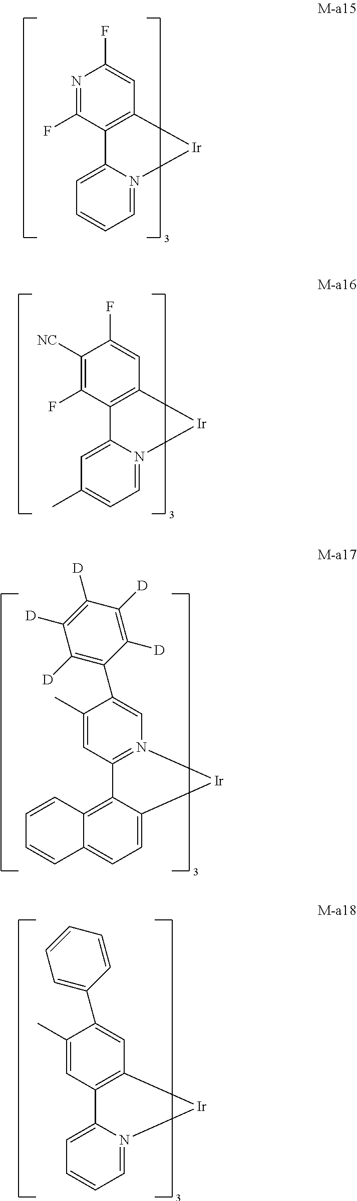

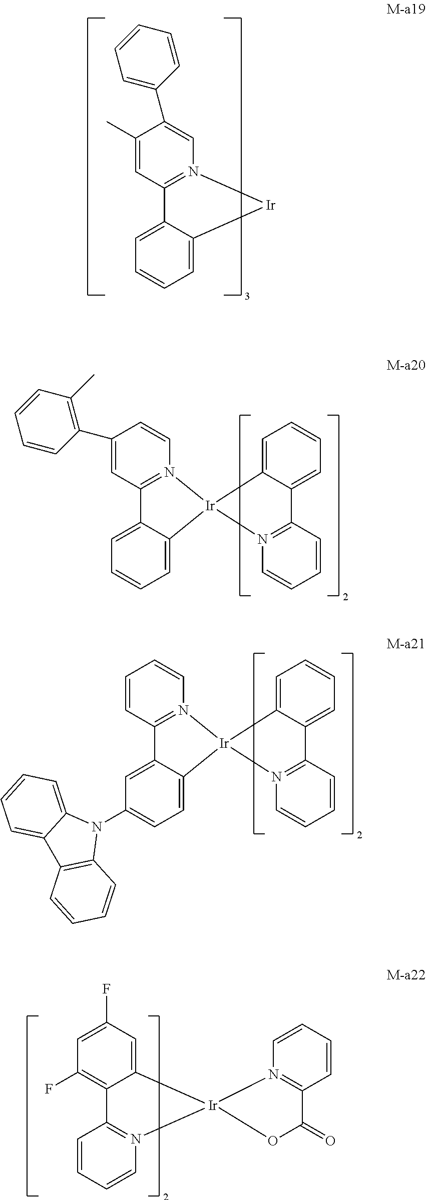

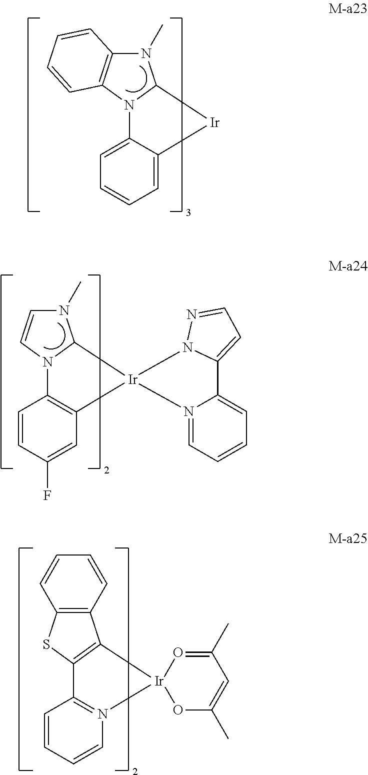

Compound M-a1 and Compound M-a2 may each be used as a red dopant material, and Compound M-a3 to Compound M-a7 may each be used as a green dopant material.

The emission layer EML may further include a compound represented by any one of Formula F-a to Formula F-c. The compound represented by Formula F-a to Formula F-c may be used as a fluorescence dopant material.

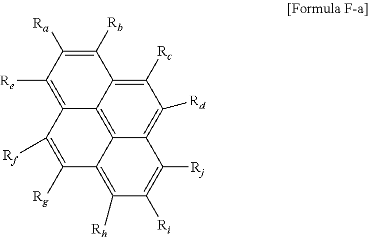

In Formula F-a, two of Rₐ to Rⱼ may each independently be substituted with a group represented by *—NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ or Ar₂ may be a heteroaryl group containing O or S as a ring-forming atom.

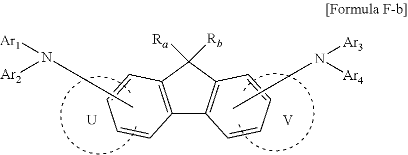

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. For example, when the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When U and V are each 0, a fused ring having a fluorene core of Formula F-b may be a cyclic compound having three rings. When U and V are each 1, a fused ring having a fluorene core of Formula F-b may be a cyclic compound having five rings.

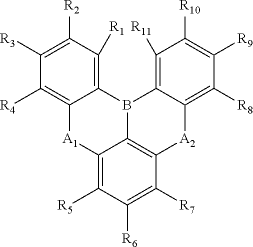

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may include, as a dopant material of the related art, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

The emission layer EML may include a quantum dot. The quantum dot may be a Group II-VI compound, a Group III-VI compound, a Group I-III-VI compound, a Group III-V compound, a Group III-II-V compound, a Group IV-VI compound, a Group IV element, a Group IV compound, or any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof; or any combination thereof.

Examples of a Group III-VI compound may include: a binary compound such as In₂S₃ or In₂Se₃; a ternary compound such as InGaS₃ or InGaSe₃; or any combination thereof.

Examples of a Group I-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ or CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or any combination thereof. A Group III-V compound may further include a Group II metal. For example, InZnP, etc., may be selected as a Group III-II-V compound.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof. Examples of a Group IV element may include Si, Ge, or any mixture thereof. Examples of a Group IV compound may include a binary compound selected from the group consisting of SiC, SiGe, and any mixture thereof.

A binary compound, a ternary compound, or a quaternary compound may be present in a particle at a uniform concentration distribution, or may be present in a particle at a partially different concentration distribution. In an embodiment, a quantum dot may have a core/shell structure in which a quantum dot surrounds another quantum dot. A quantum dot having a core/shell structure may have a concentration gradient in which the concentration of a material that is present in the shell decreases toward the core.

In embodiments, the quantum dot may have the above-described core/shell structure including a core containing nanocrystals and a shell surrounding the core. The shell of the quantum dot may serve as a protection layer to prevent the chemical deformation of the core to maintain semiconductor properties, and/or may serve as a charging layer to impart electrophoresis properties to the quantum dot. The shell may be a single layer or a multilayer. Examples of a shell of a quantum dot may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; a ternary compound such as MgAl₂O₄, CoFe₂O₄, NiFe₂O₄, and CoMn₂O₄; or any combination thereof, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in any of the above ranges. Light emitted through a quantum dot may be emitted in all directions, so that a wide viewing angle may be improved.

The form of the quantum dot is not particularly limited as long as it is a form that is used in the related art. For example, the quantum dot may have a spherical shape, a pyramidal shape, a multi-arm shape, or a cubic shape, or the quantum dot may be in the form of nanoparticles, nanotubes, nanowires, nanofibers, nanoplate particles, etc.

The quantum dot may control the color of emitted light according to a particle size thereof. Accordingly, the quantum dot may have various light emission colors such as blue, red, or green.

In the light emitting element ED according to an embodiment as illustrated in each of FIGS. 3 to 6, the electron transport region ETR is provided on the emission layer EML. The electron transport region ETR may include at least one of a hole blocking layer HBL, an electron transport layer ETL, or an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of the electron injection layer EIL or the electron transport layer ETL, or may have a single layer structure formed of an electron injection material and an electron transport material. In other embodiment, the electron transport region ETR may have a single layer structure formed of different materials, or may have a structure in which an electron transport layer ETL/electron injection layer EIL, a hole blocking layer HBL/electron transport layer ETL/electron injection layer EIL, or an electron transport layer ETL/buffer layer (not shown)/electron injection layer EIL are stacked in its respective stated order from an emission layer EML, but embodiments are not limited thereto. The electron transport region ETR may have a thickness, for example, in a range of about 1,000 Å to about 1,500 Å.

The electron transport region ETR may be formed by using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-1:

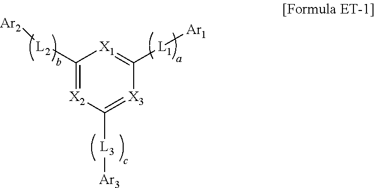

In Formula ET-1, at least one of X₁ to X₃ may each be N; and the remainder of X₁ to X₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), or any mixture thereof.

In an embodiment, the electron transport region ETR may include at least one compound selected from Compound ETl to Compound ET36:

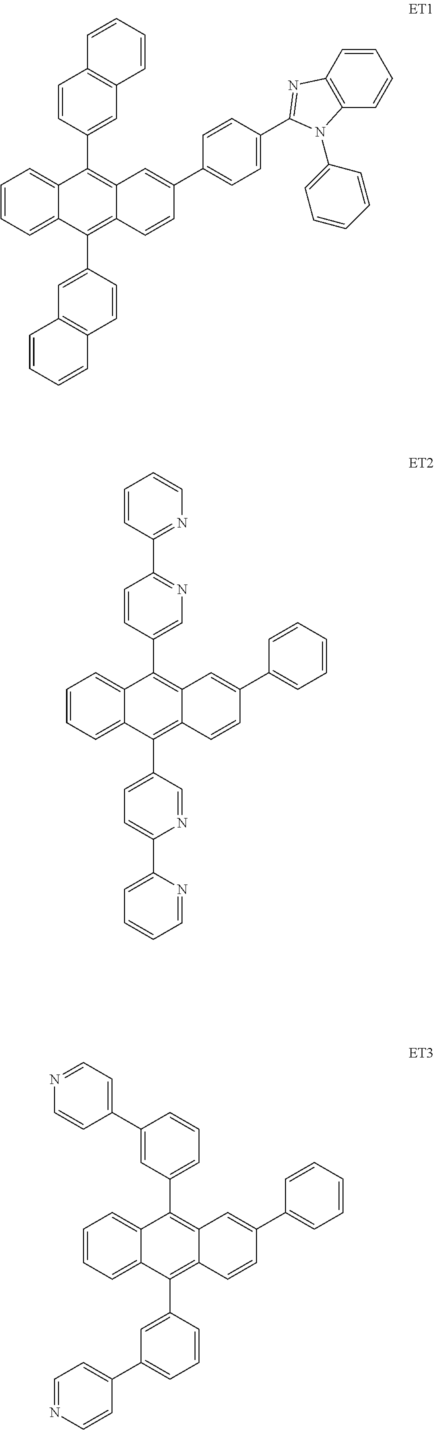 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

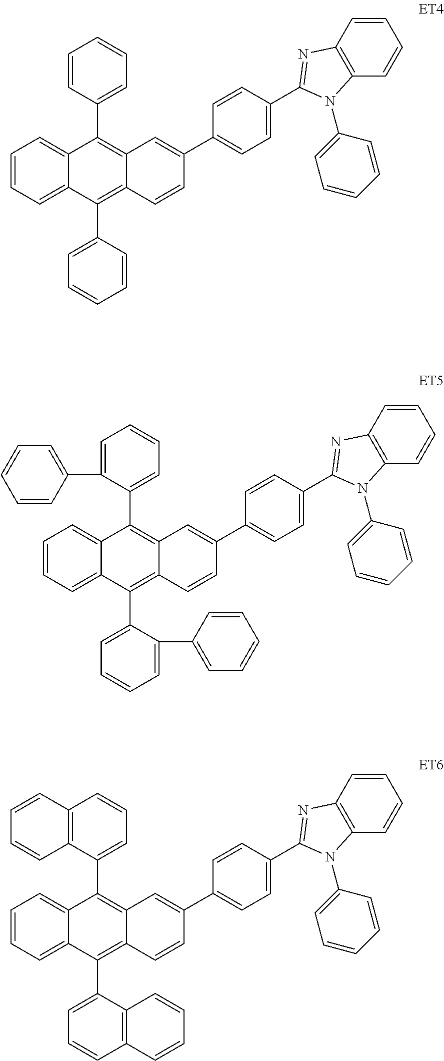 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

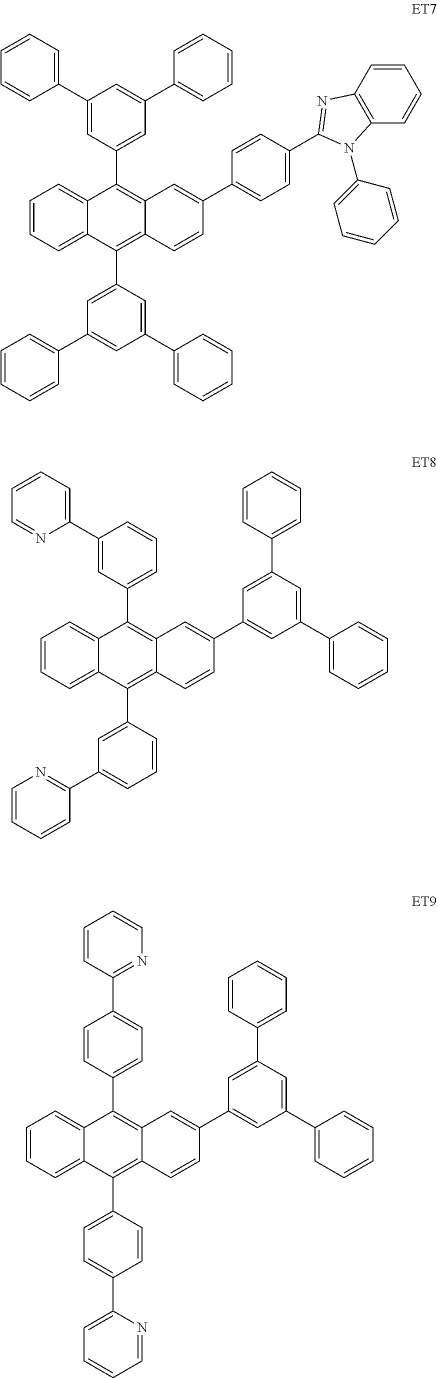 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

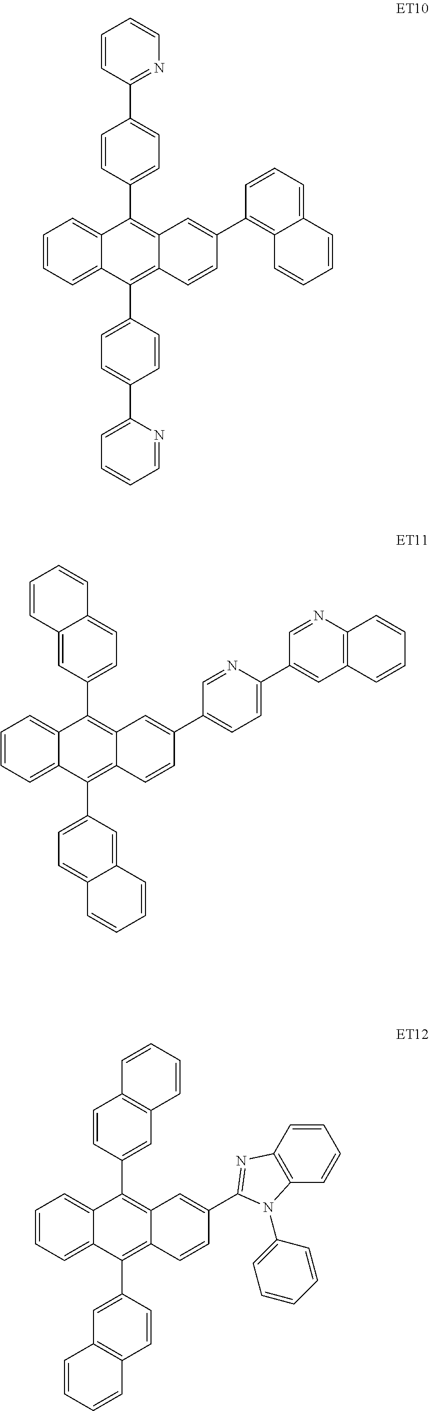 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

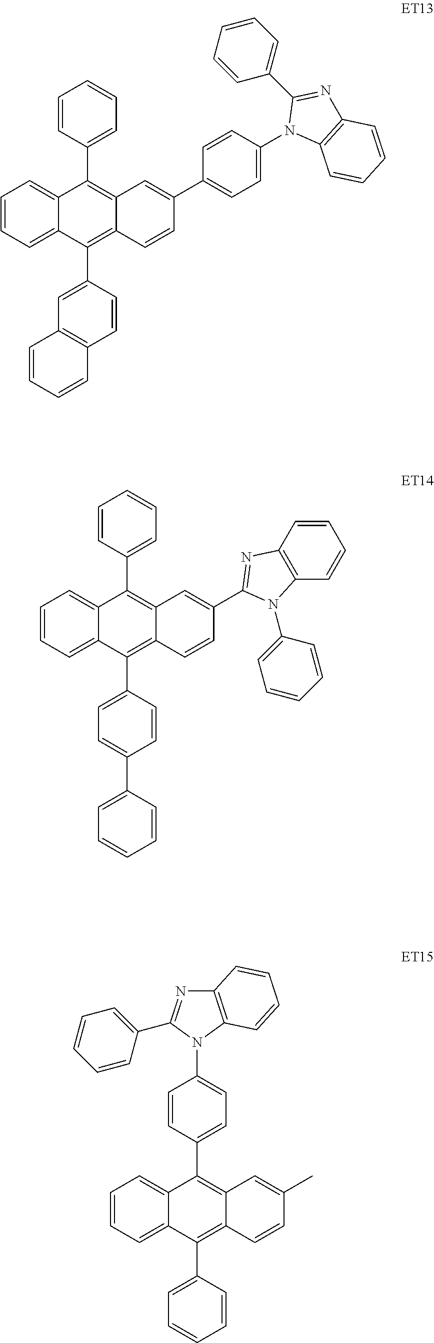 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

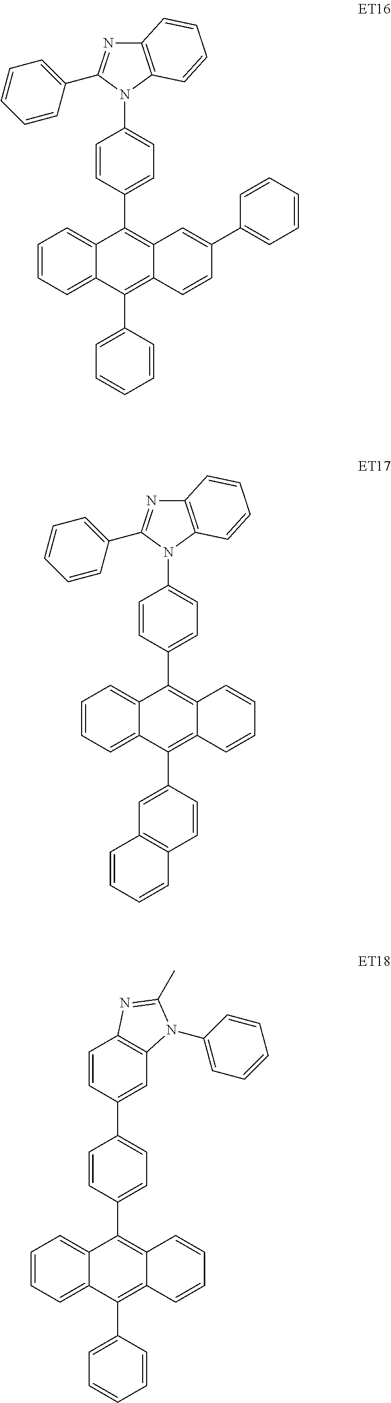 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

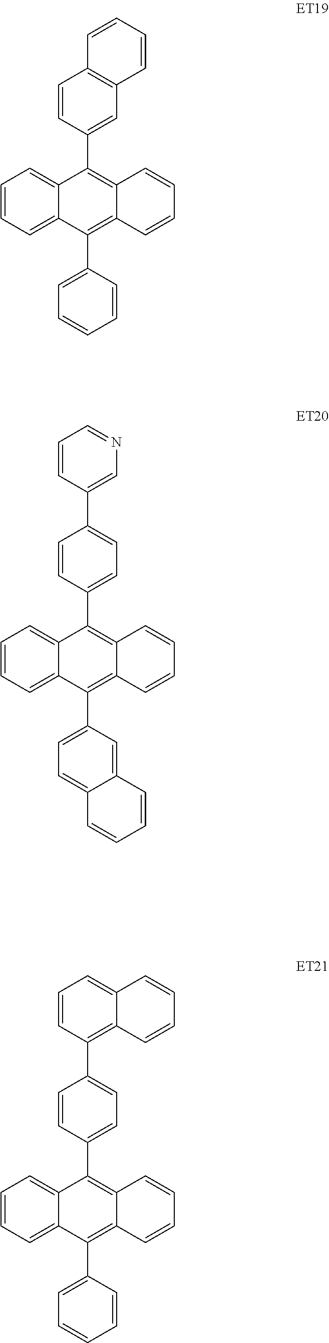

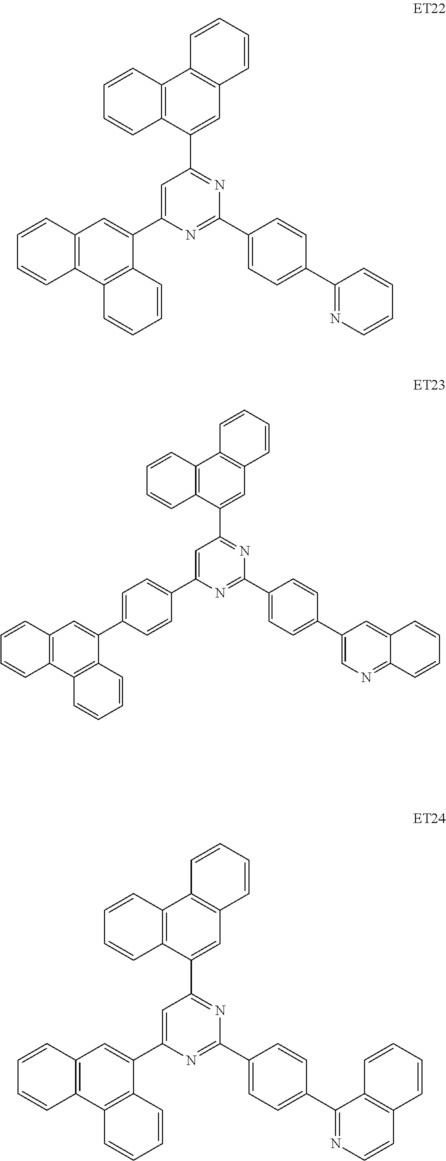 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

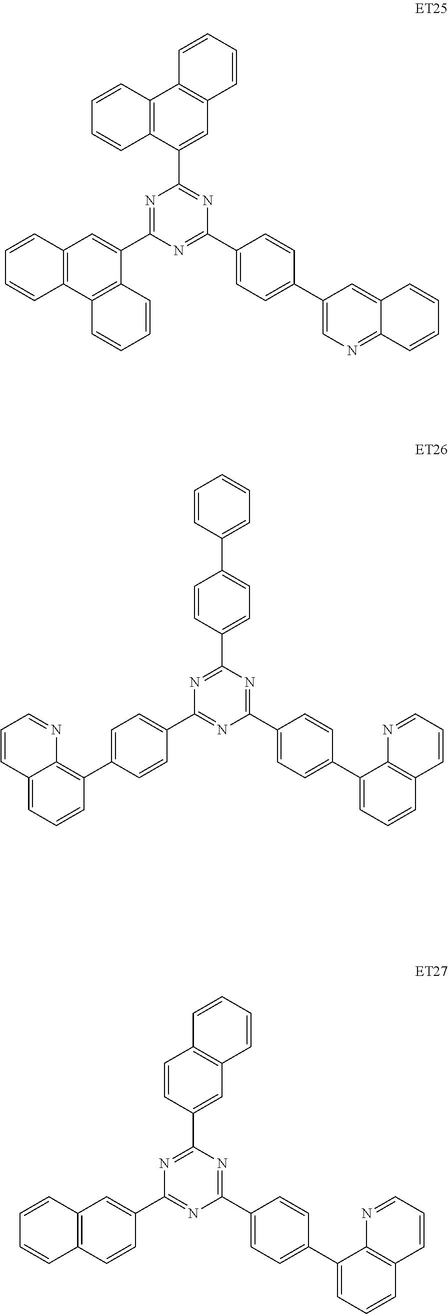 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

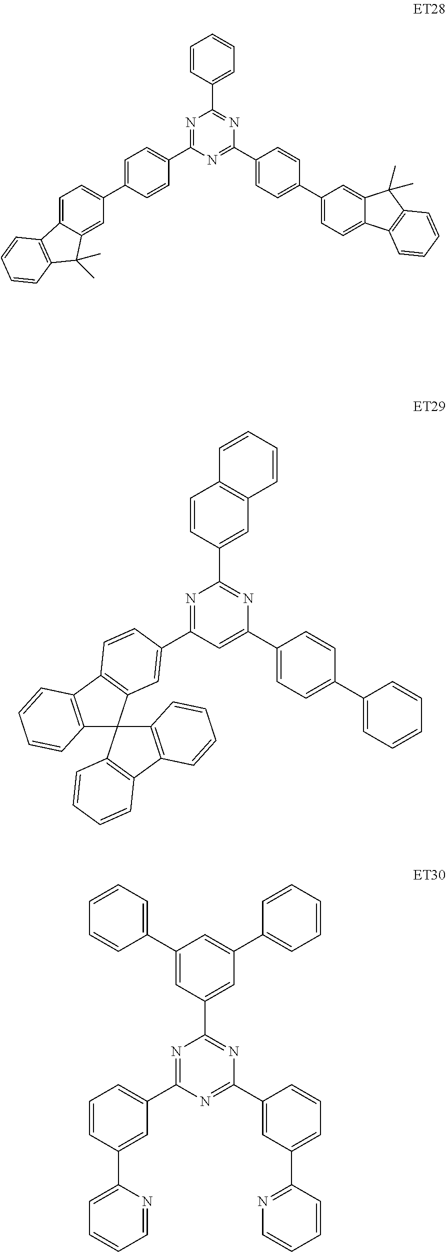 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

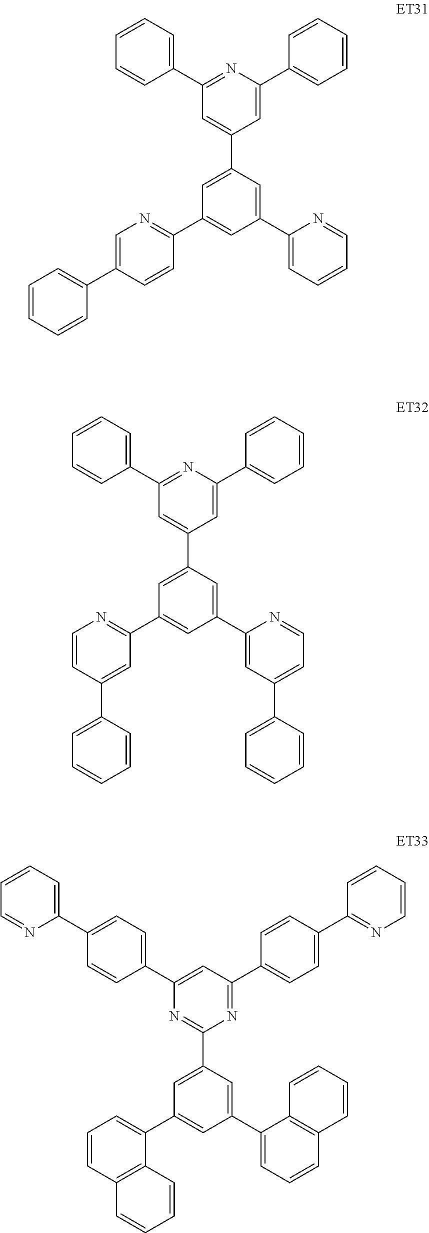 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

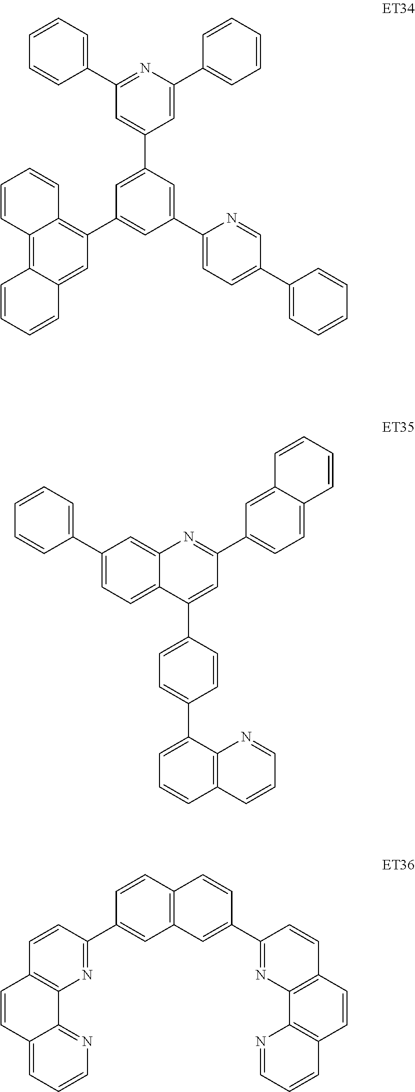 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport regions ETR may include a metal halide such as LiF, NaCl, CsF, RbCl, RbI, CuI, or KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may include a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments are not limited thereto.

The electron transport region ETR may include the above-described compounds of the hole transport region in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode. The second electrode may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, Yb, W, a compound thereof, or a mixture thereof (e.g., AgMg, AgYb, or MgYb). In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNx, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol sol-9-yl)triphenylamine (TCTA), etc., or an epoxy resin, or an acrylate such as methacrylate. However, embodiments are not limited thereto, and the capping layer CPL may include at least one of Compounds P1 to P5:

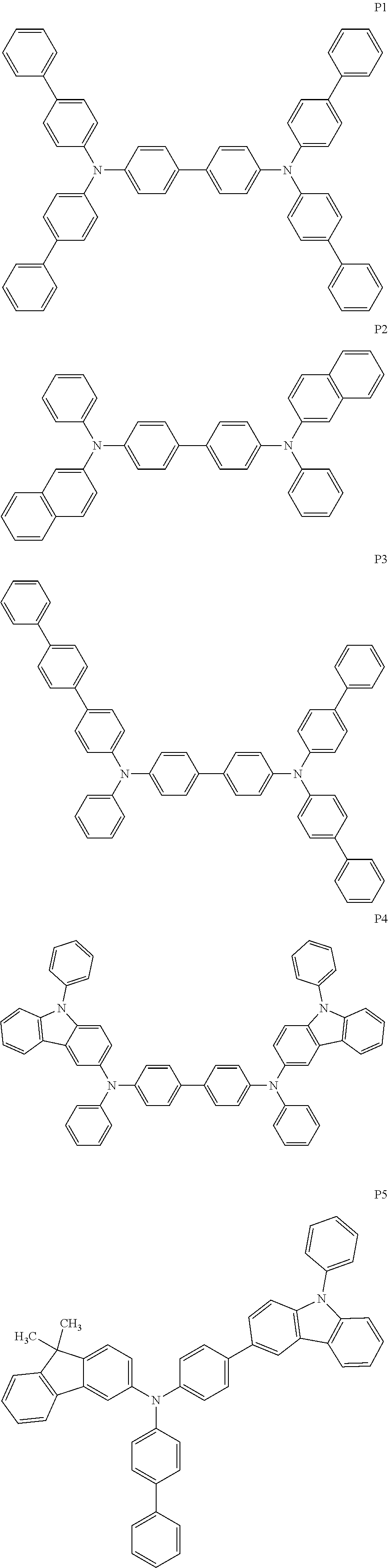 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, a refractive index of the capping layer CPL may be equal to or greater than about 1.6, with respect to light in a wavelength range of about 550 nm to about 660 nm.

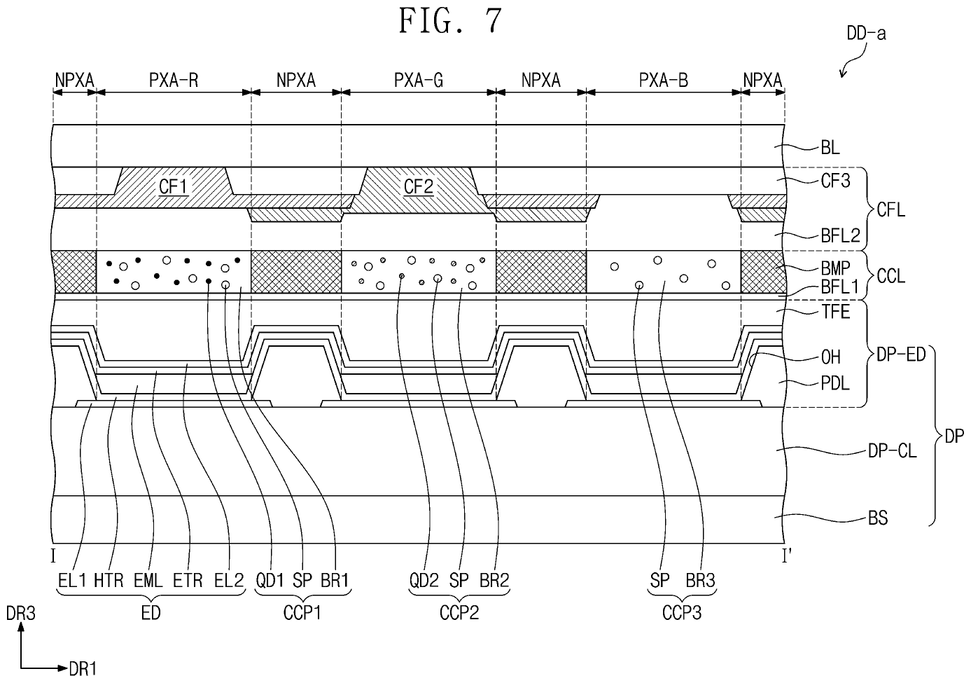

FIGS. 7 to 10 are each a schematic cross-sectional view of a display device according to an embodiment. Hereinafter, in describing the display devices according to embodiments in reference to FIGS. 7 to 10, the features which have been described above with respect FIGS. 1 to 6 will not be described again, and the differing features will be described.

Referring to FIG. 7, the display device DD-a according to an embodiment may include a display panel DP including a display element layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and a display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED illustrated in FIG. 7 may be the same as a structure of a light emitting element ED according to one of FIGS. 3 to 6 as described herein.

In the display device DD-a, the emission layer EML of the light emitting element ED may include the polycyclic compound according to an embodiment.

Referring to FIG. 7, the emission layer EML may be disposed in an opening OH defined in a pixel defining film PDL. For example, the emission layer EML, which is divided by the pixel defining film PDL and correspondingly provided to each of the light emitting regions PXA-R, PXA-G, and PXA-B may each emit light in a same wavelength range. In the display device DD-a, the emission layer EML may emit blue light. Although not shown in the drawings, in an embodiment, the emission layer EML may be provided as a common layer for each of the entire light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3, which are spaced apart from each other, but embodiments are not limited thereto. In FIG. 7, it is illustrated that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 including a first quantum dot QD1 that converts first color light provided from the light emitting element ED into second color light, a second light control part CCP2 including a second quantum dot QD2 that converts first color light into third color light, and a third light control part CCP3 that transmits first color light.

In an embodiment, the first light control part CCP1 may provide red light, which may be the second color light, and the second light control part CCP2 may provide green light, which may be the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The quantum dots QD1 and QD2 may each be a quantum dot as described herein.

The light control layer CCL may further include a scatterer SP. The first light control part CCP1 may include the first quantum dot QD1 and a scatterer SP, the second light control part CCP2 may include the second quantum dot QD2 and a scatterer SP, and the third light control part CCP3 may not include a quantum dot but may include a scatterer SP.

The scatterer SP may be inorganic particles. For example, the scatterer SP may include at least one of TiO₂, ZnO, Al₂O₃, SiO₂, or hollow silica. The scatterer SP may include any one of TiO₂, ZnO, Al₂O₃, SiO₂, and hollow silica, or the scatterer SP may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various resin compositions which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2, and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and filters CF1, CF2, and CF3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic layer. The barrier layers BFL1 and BFL2 may be formed of a single layer or formed of multiple layers.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter. The first to third filters CF1, CF2, and CF3 may be disposed to respectively correspond to a red light emitting region PXA-R, a green light emitting region PXA-G, and a blue light emitting region PXA-B.

Although not shown in the drawings, the color filter layer CFL may further include a light shielding part (not shown). The color filter layer CFL may include a light shielding part (not shown) that is disposed to overlap the boundaries between neighboring filters CF1, CF2, and CF3. The light shielding part (not shown) may be a black matrix. The light shielding part (not shown) may include an organic light shielding material or an inorganic light shielding material containing a black pigment or dye. The light shielding part (not shown) may separate boundaries between adjacent filters CF1, CF2, and CF3. In an embodiment, the light shielding part (not shown) may be formed of a blue filter.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

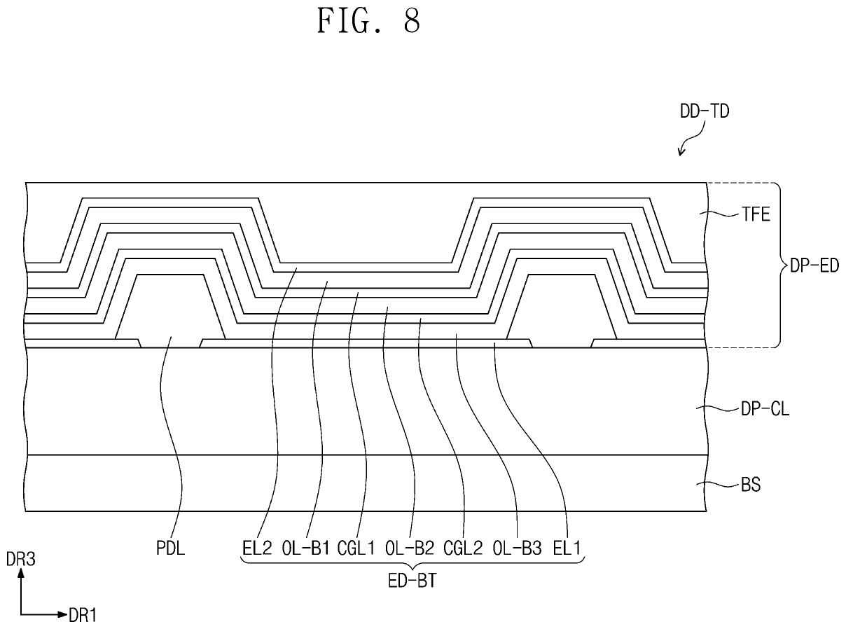

FIG. 8 is a schematic cross-sectional view of a portion of a display device according to an embodiment. FIG. 8 illustrates an embodiment of a part corresponding to the display panel DP of FIG. 7. In the display device DD-TD according to an embodiment, the light emitting element ED-BT may include light emitting structures OL-B1, OL-B2, and OL-B3. The light emitting element ED-BT may include a first electrode EL1 and a second electrode EL2 which face each other, and the light emitting structures OL-B1, OL-B2, and OL-B3 stacked in a thickness direction between the first electrode EL1 and the second electrode EL2. At least one of the light emitting structures OL-B1, OL-B2, and OL-B3 may include the polycyclic compound according to an embodiment as described herein. The light emitting structures OL-B1, OL-B2, and OL-B3 may each include an emission layer EML (FIG. 7) and a hole transport region HTR and an electron transport region ETR disposed with the emission layer EML (FIG. 7) located therebetween.

For example, the light emitting element ED-BT included in the display device DD-TD may be a light emitting element having a tandem structure and including multiple emission layers.

In an embodiment illustrated in FIG. 8, light emitted from the light emitting structures OL-B1, OL-B2, and OL-B3 may each be blue light. However, embodiments are not limited thereto, and the light respectively emitted from the light emitting structures OL-B1, OL-B2, and OL-B3 may have wavelength ranges that are different from each other. For example, the light emitting element ED-BT that includes the light emitting structures OL-B1, OL-B2, and OL-B3, which emit light having wavelength ranges that are different from each other, may emit white light.

Charge generation layers CGL1 and CGL2 may each be disposed between neighboring light emitting structures among OL-B1, OL-B2, and OL-B3. Charge generation layers CGL1 and CGL2 may each independently include a p-type charge generation layer and/or an n-type charge generation layer.

In an embodiment, at least one of the light emitting structures OL-B1, OL-B2, and OL-B3 included in the display device DD-TD may include the polycyclic compound as described herein. For example, at least one of the emission layers included in the light emitting element ED-BT may include the polycyclic compound.

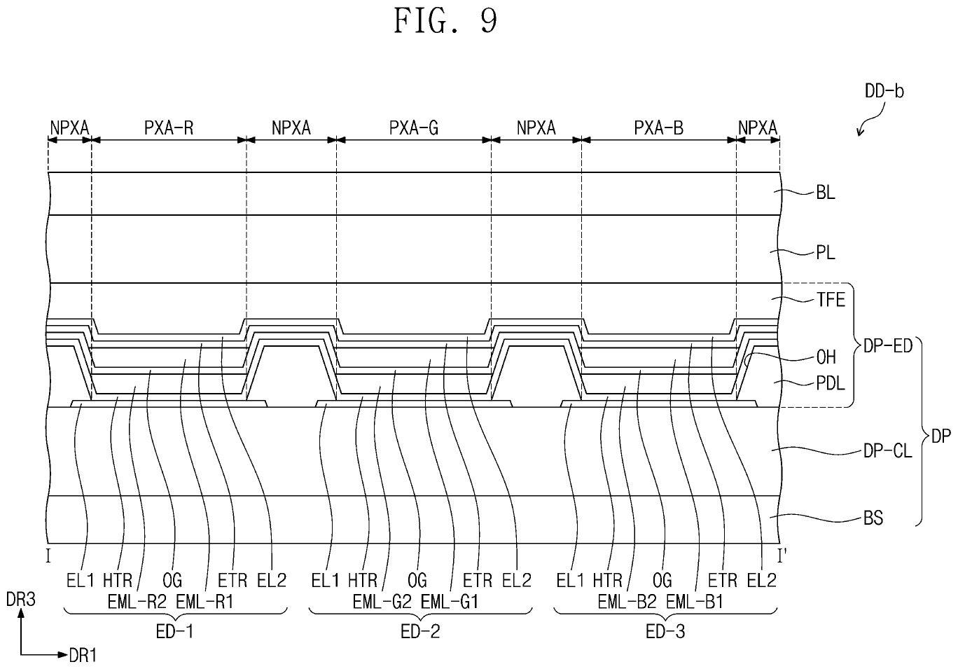

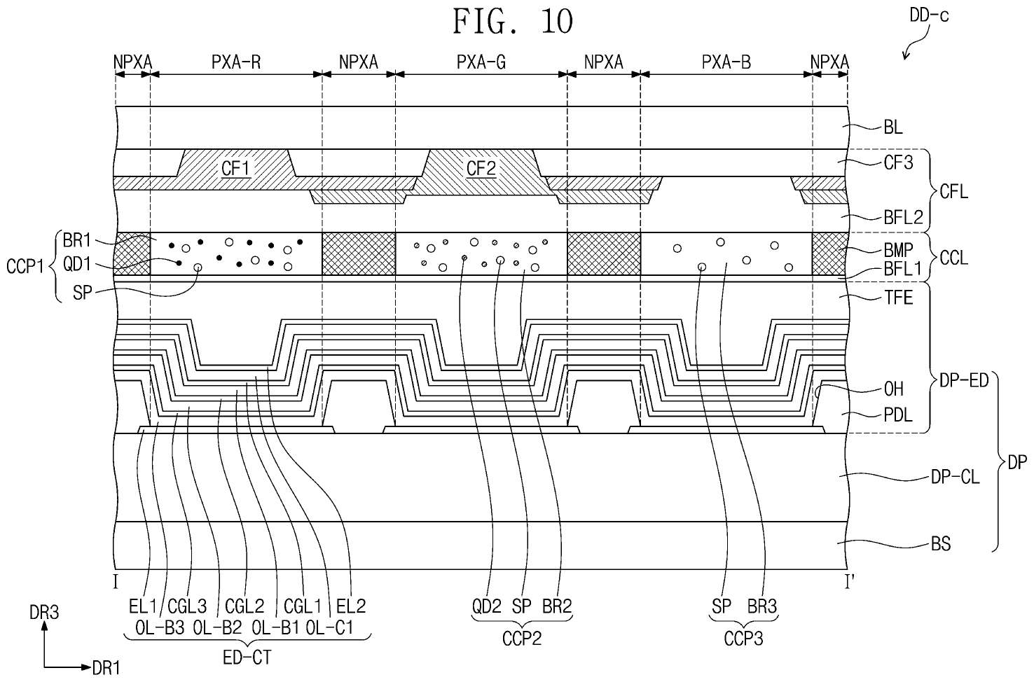

FIG. 9 is a schematic cross-sectional view of a display device DD-b according to an embodiment. The display device DD-b may include light emitting elements ED-1, ED-2, and ED-3 which each include two emission layers that are stacked. In comparison to the display device DD illustrated in FIG. 2, the embodiment illustrated in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for all of the first to third light emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2, which are stacked in that order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2, which are stacked in that order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, which are stacked in that order.

An optical auxiliary layer PL may be disposed on the display element layer DP-ED. The optical auxiliary layer PL may include a polarizing layer. The optical auxiliary layer PL may be disposed on the display panel DP and may control light reflected at the display panel DP from an external light. Although not shown in the drawings, in an embodiment, the optical auxiliary layer PL may be omitted from the display device.

At least one emission layer included in the display device DD-b illustrated in FIG. 9 may include the polycyclic compound according to an embodiment as described herein. For example, in an embodiment, at least one of the first blue emission layer EML-B1 or the second blue emission layer EML-B2 may include the polycyclic compound.

In contrast to FIGS. 8 and 9, FIG. 10 illustrates a display device DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be disposed between adjacent light emitting structures among the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength regions from each other.

Charge generation layers CGL1, CGL2, and CGL3 which are disposed between adjacent light emitting structures OL-B1, OL-B2, OL-B3, and OL-C1 may each independently include a p-type charge generation layer and/or an n-type charge generation layer.

In the display device DD-c, at least one of the light emitting structures OL-B1, OL-B2, OL-B3, and OL-C1 may each independently include the polycyclic compound according to an embodiment as described herein. For example, in an embodiment, at least one of the first to third light emitting structures OL-B1, OL-B2, and OL-B3 may each independently include the polycyclic compound.

The light emitting element ED according to an embodiment may include the polycyclic compound in at least one functional layer disposed between the first electrode EL1 and the second electrode EL2, thereby exhibiting excellent luminous efficiency and improved service life characteristics. For example, the emission layer EML of the light emitting element ED may include the polycyclic compound, and the light emitting element ED may exhibit long service life characteristics.

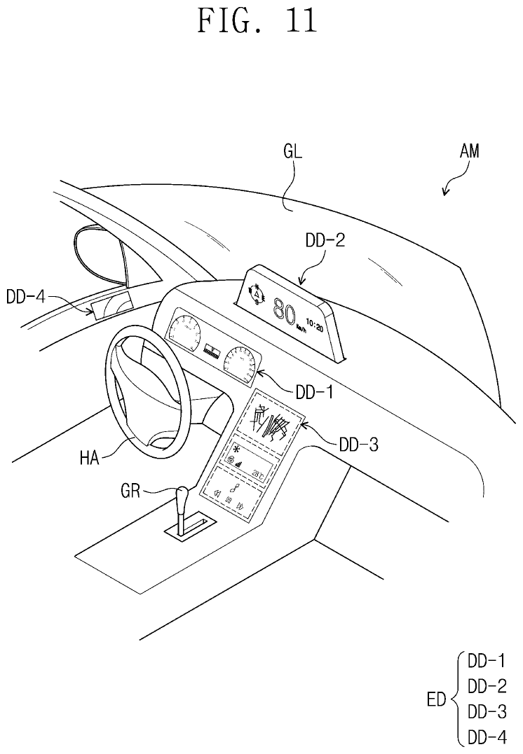

FIG. 11 is a schematic perspective view of an electronic device including a display device according to an embodiment. FIG. 11 illustrates a vehicle as an example of an electronic device that includes display devices.

Referring to FIG. 11, the electronic device ED may include display devices DD-1, DD-2, DD-3, and DD-4 for a vehicle AM. FIG. 11 illustrates the first to fourth display devices DD-1, DD-2, DD-3, and DD-4 as display devices for a vehicle AM, and which are disposed in the vehicle AM. FIG. 11 illustrates a vehicle, but this is only an example, and the first to fourth display devices DD-1, DD-2, DD-3, and DD-4 may be disposed in various transportation means such as bicycles, motorcycles, trains, ships, and airplanes. At least one of the first to fourth display devices DD-1, DD-2, DD-3, and DD-4 may have a structure according to one of the display devices DD, DD-a, DD-b, and DD-c as described in reference to FIG. 1, FIG. 2, and FIGS. 7 to 10.

In an embodiment, at least one of the first to fourth display devices DD-1, DD-2, DD-3, and DD-4 may include a light emitting element ED according to an embodiment as described with reference to FIGS. 3 to 6. The first to fourth display devices DD-1, DD-2, DD-3, and DD-4 may each independently include multiple light emitting elements ED, and the light emitting elements ED may each include a first electrode EL1, a hole transport region HTR disposed on an upper portion of the first electrode EL1, an emission layer EML disposed on an upper portion of the hole transport region HTR, an electron transport region ETR disposed on an upper portion of the emission layer EML, and a second electrode disposed on an upper portion of the electron transport region ETR. The emission layer EML may include a polycyclic compound represented by Formula 1. Accordingly, the electronic device ED may exhibit improved image quality.

Referring to FIG. 11, the vehicle AM may include a steering wheel HA and a gearshift GR for operating the vehicle AM, and a front window GL may be disposed so as to face the driver.

The first display device DD-1 may be disposed in a first region overlapping the steering wheel HA. For example, the first display device DD-1 may be a digital cluster displaying first information of the vehicle AM. The first information may include a scale for indicating a driving speed of the vehicle AM, a scale for indicating an engine speed (for example, a tachometer showing revolutions per minute (RPM)), an image for indicating a fuel state, etc. A first scale and a second scale may each be represented as a digital image.

The second display device DD-2 may be disposed in a second region facing the driver's seat and overlapping the front window GL. The driver's seat may be a seat where the steering wheel HA is disposed. For example, the second display device DD-2 may be a head up display (HUD) displaying second information of the vehicle AM. The second display device DD-2 may be optically transparent. The second information may include digital numbers for indicating a driving speed, and may further include information such as the current time.

The third display device DD-3 may be disposed in a third region adjacent to the gearshift GR. For example, the third display device DD-3 may be disposed between a driver's seat and a passenger seat and may be a center information display (CID) for a vehicle AM that displays third information. The passenger seat may be a seat that is spaced apart from the driver's seat, with the gearshift GR disposed therebetween. The third information may include information about traffic (e.g., navigation information), playing music or radio, playing video, temperatures inside the vehicle AM, etc.

The fourth display device DD-4 may be spaced apart from the steering wheel HA and the gearshift GR, and may be disposed in a fourth region adjacent to the side of the vehicle AM. For example, the fourth display device DD-4 may be a digital side-view mirror displaying fourth information. The fourth display device DD-4 may display an image outside the vehicle AM taken by a camera module disposed outside the vehicle AM. The fourth information may include an image outside the vehicle AM.

The first to fourth information as described herein are only examples, and the first to fourth display devices DD-1, DD-2, DD-3, and DD-4 may further display information about the interior and exterior of the vehicle. The first to fourth information may include information that is different from each other. However, embodiments are not limited thereto, and a part of the first to fourth information may include the same information as one another.

Hereinafter, a polycyclic compound according to an embodiment and a light emitting element according to an embodiment will be described in detail with reference to the Examples and the Comparative Examples. The Examples described below are only provided as illustrations to assist in understanding the disclosure, and the scope thereof is not limited thereto.

### EXAMPLES

1. Synthesis of Polycyclic Compound

A synthesis method of the polycyclic compound according to an embodiment will be described in detail by illustrating the synthesis methods of Compounds 13, 33, 47, 68, and 252. The synthesis methods of the polycyclic compounds as explained below are only examples, and the synthesis method of the polycyclic compound is not limited to the Examples below.

(1) Synthesis of Compound 13

Compound 13 according to an example may be synthesized, for example, by Reaction Scheme 1 below:

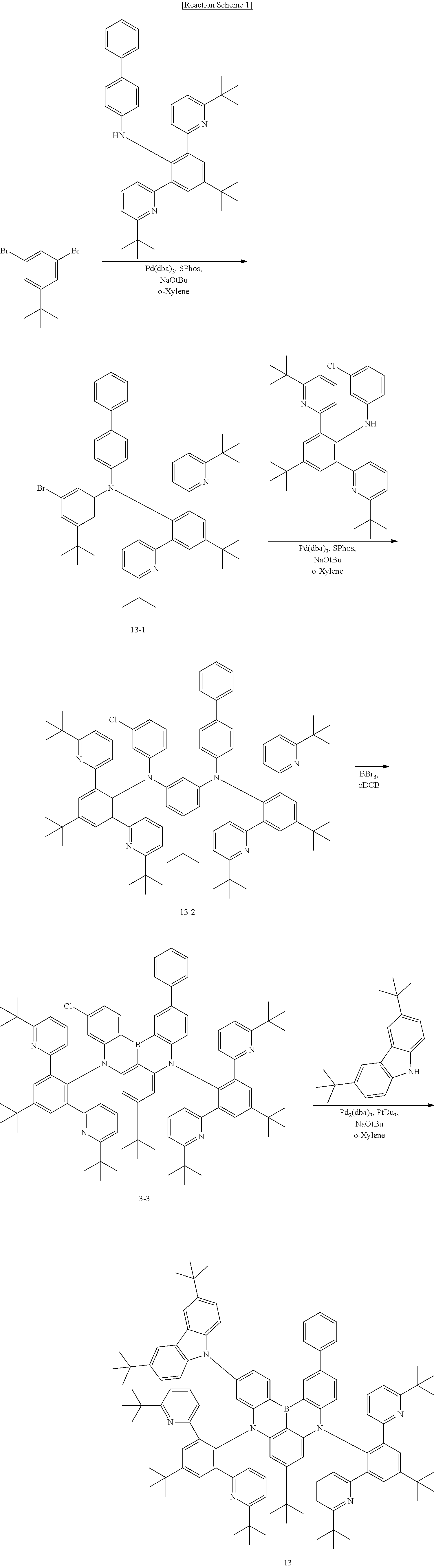

1) Synthesis of Intermediate 13-1

1,3-dibromo-5-(tert-butyl)benzene (1 eq), N-(4-(tert-butyl)-2,6-bis(6-(tert-butyl)pyridin-2-yl)phenyl)-[1,1′-biphenyl]-4-amine (1 eq), tris(dibenzylideneacetone)dipalladium(0) (0.05 eq), SPhos (0.10 eq), and sodium tert-butoxide (1.5 eq) were dissolved in o-xylene, and the resultant mixture was stirred in a nitrogen atmosphere at about 90° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 13-1. (yield: 62%)

2) Synthesis of Intermediate 13-2

Intermediate 13-1 (1 eq), 4-(tert-butyl)-2,6-bis(6-(tert-butyl)pyridin-2-yl)-N-(3-chlorophenyl)aniline (1 eq), tris(dibenzylideneacetone)dipalladium(0) (0.05 eq), SPhos (0.10 eq), and sodium tert-butoxide (1.5 eq) were dissolved in o-xylene, and the resultant mixture was stirred in a nitrogen atmosphere at about 90° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 13-2. (yield: 64%)

3) Synthesis of Intermediate 13-3

Intermediate 13-2 (1 eq) was dissolved in ortho dichlorobenzene (oDCB), the flask was cooled to about 0° C. in a nitrogen atmosphere, and BBr₃ (2.5 eq) dissolved in ortho dichlorobenzene was slowly injected thereto. After dropping was completed, the temperature was elevated to about 190° C., and the mixture was stirred for about 20 hours. After the mixture was cooled to about 0° C., triethylamine was slowly dropped to the flask until heating stopped to terminate the reaction, and n-hexane and methanol were added to the flask, thereby extracting solids. The extracted solids were obtained by filtration. The obtained solids were purified with silica filtration, and purified again through recrystallization in dichloromethane/n-hexane (MC/Hex) to obtain Intermediate 13-3. Intermediate 13-3 was finally purified by column chromatography (dichloromethane:n-hexane). (yield: 12%)

4) Synthesis of Compound 13

Intermediate 13-3 (1 eq), 3,6-di-tert-butyl-9H-carbazole (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 140° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Compound 13. (yield: 54%). The resulting product was further purified by sublimation purification to obtain final purity. The obtained compound was identified as Compound 13 through ESI-LCMS. ESI-LCMS: [M]⁺: C₁₀₄H₁₁₆BN₇, 1473.94

(2) Synthesis of Compound 33

Compound 33 according to an example may be synthesized, for example, by Reaction Scheme 2 below:

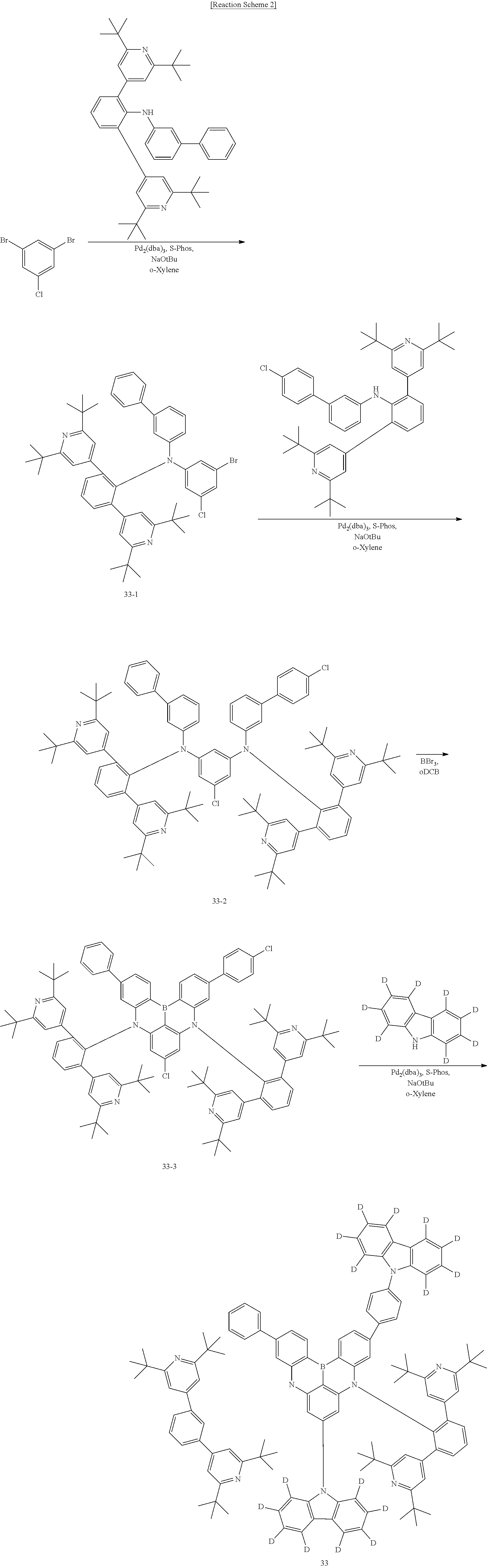

1) Synthesis of Intermediate 33-1

1,3-dibromo-5-chlorobenzene (1 eq), N-(2,6-bis(2,6-di-tert-butylpyridin-4-yl)phenyl)-[1,1′-biphenyl]-3-amine (1 eq), tris(dibenzylideneacetone)dipalladium(0) (0.05 eq), 2-dicyclohexylphosphino-2′,6′-dimethoxybiphenyl (S-Phos) (0.10 eq), and sodium tert-butoxide (1.5 eq) were dissolved in o-xylene, and the resultant mixture was stirred in a high pressure reactor at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 33-1. (yield: 48%)

2) Synthesis of Intermediate 33-2

Intermediate 33-1 (1 eq), N-(2,6-bis(2,6-di-tert-butylpyridin-4-yl)phenyl)-4′-chloro-[1,1′-biphenyl]-3-amine (1 eq), tris(dibenzylideneacetone)dipalladium(0) (0.05 eq), 2-dicyclohexylphosphino-2′,6′-dimethoxybiphenyl (S-Phos) (0.10 eq), and sodium tert-butoxide (1.5 eq) were dissolved in o-xylene, and the resultant mixture was stirred in a high pressure reactor at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 33-2. (yield: 59%)

3) Synthesis of Intermediate 33-3

Intermediate 33-2 (1 eq) was dissolved in ortho dichlorobenzene (oDCB), the flask was cooled to about 0° C. in a nitrogen atmosphere, and BBr₃ (2.5 eq) dissolved in ortho dichlorobenzene was slowly injected thereto. After dropping was completed, the temperature was elevated to about 190° C., and the mixture was stirred for about 20 hours. After the mixture was cooled to about 0° C., triethylamine was slowly dropped to the flask until heating stopped to terminate the reaction, and n-hexane and methanol were added to the flask, thereby extracting solids. The extracted solids were obtained by filtration. The obtained solids were purified with silica filtration, and purified again by column chromatography (dichloromethane:n-hexane) to obtain Intermediate 33-3. Intermediate 33-3 was finally purified by column chromatography (dichloromethane:n-hexane). (yield: 14%)

4) Synthesis of Compound 33

Intermediate 33-3 (1 eq), 9H-carbazole-1,2,3,4,5,6,7,8-d₈ (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Compound 33 (yield: 52%). The resulting product was further purified by sublimation purification to obtain final purity. The obtained compound was identified as Compound 33 through ESI-LCMS. ESI-LCMS: [M]⁺: C₁₁₈H₁₀₃D₁₆BN₈, 1675.07

(3) Synthesis of Compound 47

Compound 47 according to an example may be synthesized, for example, by Reaction Scheme 3 below:

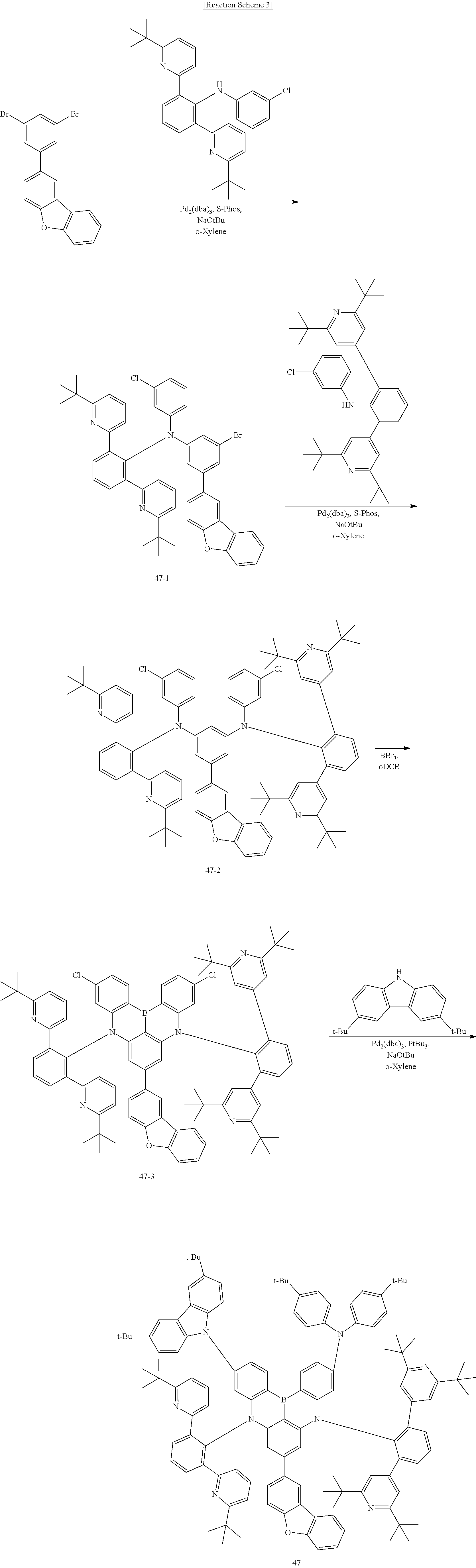

1) Synthesis of Intermediate 47-1

2-(3,5-dibromophenyl)dibenzo[b,d]furan (1 eq), 2,6-bis(6-(tert-butyl)pyridin-2-yl)-N-(3-chlorophenyl)aniline (1 eq), tris(dibenzylideneacetone)dipalladium(0) (0.05 eq), 2-dicyclohexylphosphino-2′,6′-dimethoxybiphenyl (S-Phos) (0.10 eq), and sodium tert-butoxide (1.5 eq) were dissolved in o-xylene, and the resultant mixture was stirred in a high pressure reactor at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 47-1. (yield: 53%)

2) Synthesis of Intermediate 47-2

Intermediate 47-1 (1 eq), N-(3-chlorophenyl)-2,6-bis(2,6-di-tert-butylpyridin-4-yl)aniline (1 eq), tris(dibenzylideneacetone)dipalladium(0) (0.05 eq), 2-dicyclohexylphosphino-2′,6′-dimethoxybiphenyl (S-Phos) (0.10 eq), and sodium tert-butoxide (1.5 eq) were dissolved in o-xylene, and the resultant mixture was stirred in a high pressure reactor at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 47-2. (yield: 61%)

3) Synthesis of Intermediate 47-3

Intermediate 47-2 (1 eq) was dissolved in ortho dichlorobenzene (oDCB), the flask was cooled to about 0° C. in a nitrogen atmosphere, and BBr₃ (2.5 eq) dissolved in ortho dichlorobenzene was slowly injected thereto. After dropping was completed, the temperature was elevated to about 190° C., and the mixture was stirred for about 20 hours. After the mixture was cooled to about 0° C., triethylamine was slowly dropped to the flask until heating stopped to terminate the reaction, and n-hexane and methanol were added to the flask, thereby extracting solids. The extracted solids were obtained by filtration. The obtained solids were purified with silica filtration, and purified again by column chromatography (dichloromethane:n-hexane) to obtain Intermediate 47-3. Intermediate 47-3 was finally purified by column chromatography (dichloromethane:n-hexane). (yield: 11%)

4) Synthesis of Compound 47

Intermediate 47-3 (1 eq), 3,6-di-tert-butyl-9H-carbazole (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Compound 47 (yield: 62%). The resulting product was further purified by sublimation purification to obtain final purity. The obtained compound was identified as Compound 47 through ESI-LCMS. ESI-LCMS: [M]⁺: C₁₂₆H₁₃₃BN₈O, 1785.07

(4) Synthesis of Compound 68

Compound 68 according to an example may be synthesized, for example, by Reaction Scheme 4 below:

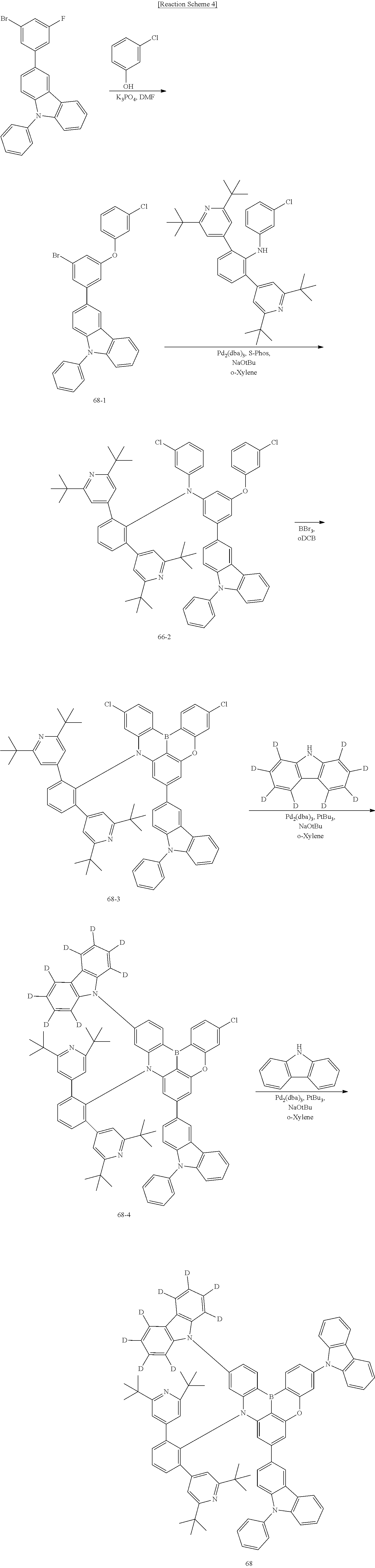

1) Synthesis of Intermediate 68-1

3-(3-bromo-5-fluorophenyl)-9-phenyl-9H-carbazole (1 eq), 3-chlorophenol (2 eq), and tripotassium phosphate (3 eq) were dissolved in dimethylformamide (DMF), and the resultant mixture was stirred at about 150° C. for about 24 hours. After cooling, the resultant mixture was dried under reduced pressure and the DMF was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 68-1. (yield: 67%)

2) Synthesis of Intermediate 68-2

Intermediate 68-1 (1 eq), N-(3-chlorophenyl)-2,6-bis(2,6-di-tert-butylpyridin-4-yl)aniline (1 eq), tris(dibenzylideneacetone)dipalladium(0) (0.05 eq), 2-dicyclohexylphosphino-2′,6′-dimethoxybiphenyl (S-Phos) (0.10 eq), and sodium tert-butoxide (1.5 eq) were dissolved in o-xylene, and the resultant mixture was stirred in a high pressure reactor at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 68-2. (yield: 57%)

3) Synthesis of Intermediate 68-3

Intermediate 68-2 (1 eq) was dissolved in ortho dichlorobenzene (oDCB), the flask was cooled to about 0° C. in a nitrogen atmosphere, and BBr₃ (2.5 eq) dissolved in ortho dichlorobenzene was slowly injected thereto. After dropping was completed, the temperature was elevated to about 190° C., and the mixture was stirred for about 20 hours. After the mixture was cooled to about 0° C., triethylamine was slowly dropped to the flask until heating stopped to terminate the reaction, and n-hexane and methanol were added to the flask, thereby extracting solids. The extracted solids were obtained by filtration. The obtained solids were purified with silica filtration, and purified again by column chromatography (dichloromethane:n-hexane) to obtain Intermediate 68-3. Intermediate 68-3 was finally purified by column chromatography (dichloromethane:n-hexane). (yield: 12%)

4) Synthesis of Intermediate 68-4

Intermediate 68-3 (1 eq), 9H-carbazole-1,2,3,4,5,6,7,8-d₈ (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized (dichloromethane:n-hexane) by column chromatography to obtain Intermediate 68-4 (yield: 62%).

5) Synthesis of Compound 68

Intermediate 68-4 (1 eq), 3,6-di-tert-butyl-9H-carbazole (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized (dichloromethane:n-hexane) by column chromatography to obtain Compound 68 (yield: 62%). The resulting product was further purified by sublimation purification to obtain final purity. The obtained compound was identified as Compound 68 through ESI-LCMS. ESI-LCMS: [M]⁺: C₉₂H7₁D8BN₆O, 1302.69

(5) Synthesis of Compound 252

Compound 252 according to an example may be synthesized by, for example, Reaction Scheme 5 below:

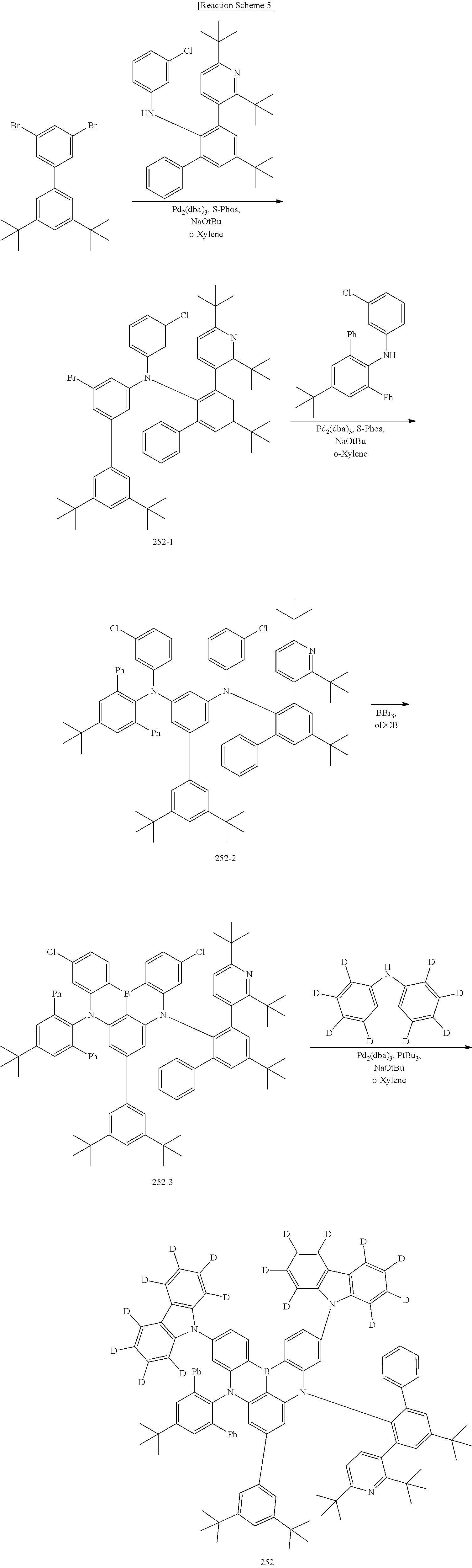

1) Synthesis of Intermediate 252-1

3,5-dibromo-3′,5′-di-tert-butyl-1,1′-biphenyl (1 eq), 5-(tert-butyl)-N-(3-chlorophenyl)-3-(2,6-di-tert-butylpyridin-3-yl)-[1,1′-biphenyl]-2-amine (1 eq), tris(dibenzylideneacetone)dipalladium(0) (0.05 eq), 2-dicyclohexylphosphino-2′,6′-dimethoxybiphenyl (S-Phos) (0.10 eq), and sodium tert-butoxide (1.5 eq) were dissolved in o-xylene, and the resultant mixture was stirred in a high pressure reactor at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 252-1. (yield: 61%)

2) Synthesis of Intermediate 252-2

Intermediate 252-1 (1 eq), 5′-(tert-butyl)-N-(3-chlorophenyl)-[1,1′:3′,1″-terphenyl]-2′-amine (1 eq), tris(dibenzylideneacetone)dipalladium(0) (0.05 eq), 2-dicyclohexylphosphino-2′,6′-dimethoxybiphenyl (S-Phos) (0.10 eq), and sodium tert-butoxide (1.5 eq) were dissolved in o-xylene, and the resultant mixture was stirred in a high pressure reactor at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 252-2. (yield: 59%)

3) Synthesis of Intermediate 252-3

Intermediate 252-2 (1 eq) was dissolved in ortho dichlorobenzene (oDCB), the flask was cooled to about 0° C. in a nitrogen atmosphere, and BBr₃ (2.5 eq) dissolved in ortho dichlorobenzene was slowly injected thereto. After dropping was completed, the temperature was elevated to about 190° C., and the mixture was stirred for about 20 hours. After the mixture was cooled to about 0° C., triethylamine was slowly dropped to the flask until heating stopped to terminate the reaction, and n-hexane and methanol were added to the flask, thereby extracting solids. The extracted solids were obtained by filtration. The obtained solids were purified with silica filtration, and purified again by column chromatography (dichloromethane:n-hexane) to obtain Intermediate 252-3. Intermediate 252-3 was finally purified by column chromatography (dichloromethane:n-hexane). (yield: 13%)

4) Synthesis of Compound 252

Intermediate 252-3 (1 eq), 9H-carbazole-1,2,3,4,5,6,7,8-d₈ (2.2 eq), tris(dibenzylideneacetone)dipalladium(0) (0.10 eq), tri-tert-butylphosphine (0.20 eq), and sodium tert-butoxide (4.0 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized (dichloromethane:n-hexane) by column chromatography to obtain Compound 252 (yield: 62%). The resulting product was further purified by sublimation purification to obtain final purity. The obtained compound was identified as Compound 252 through ESI-LCMS. ESI-LCMS: [M]⁺: C₁₀₇H₈₆D₁₆BN₅, 1483.92

2. Manufacture and Evaluation of Light Emitting Elements

Light emitting elements 1 and 2 including a polycyclic compound of an Example Compound or a Comparative Example Compound in the emission layer were manufactured as follows. Compounds 13, 33, 47, 68, and 252 that are the polycyclic compounds of Example Compounds were used as a dopant material for the emission layer to manufacture the light emitting elements of Examples 1-1 to 1-5 and Examples 2-1 to 2-5. The light emitting elements of Comparative Examples 1-1 to 1-4 and Comparative Examples 2-1 to 2-4 were respectively manufactured using Comparative Example Compounds C1 to C4 as a dopant material for the emission layer.

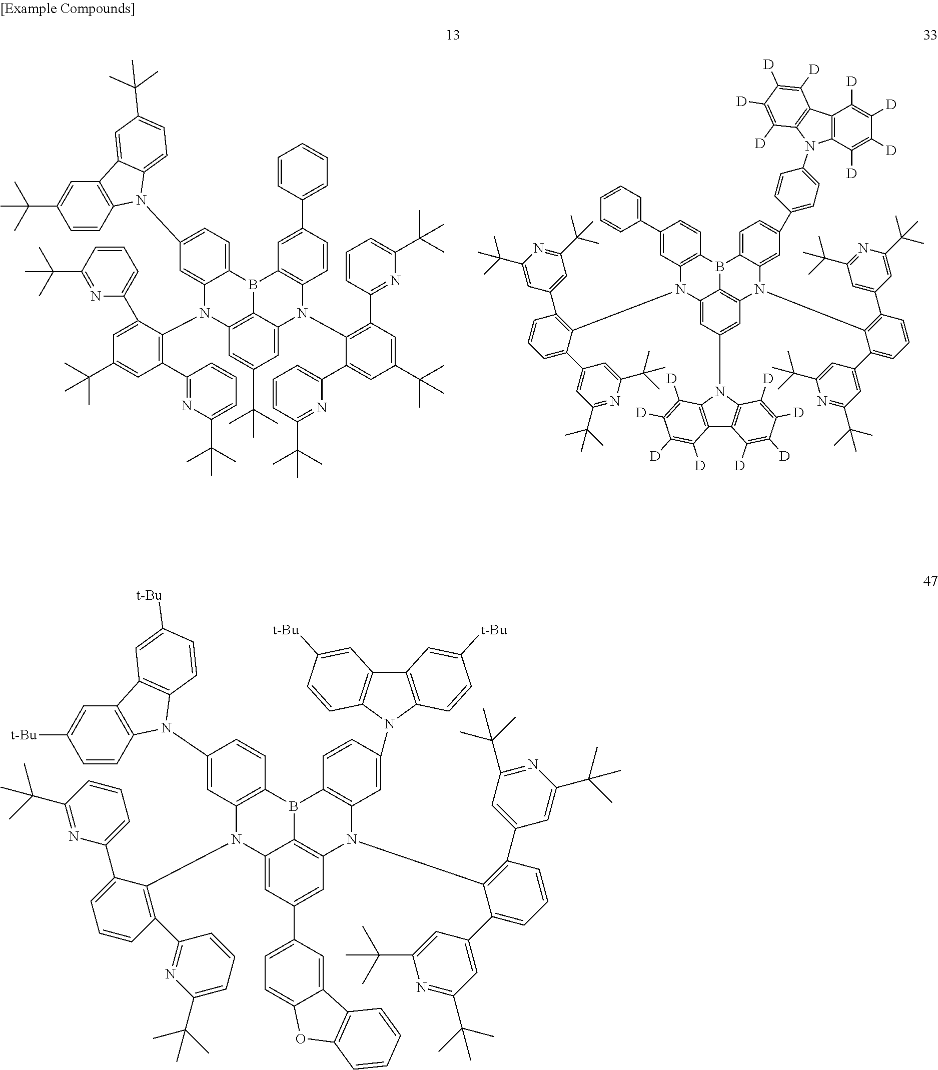

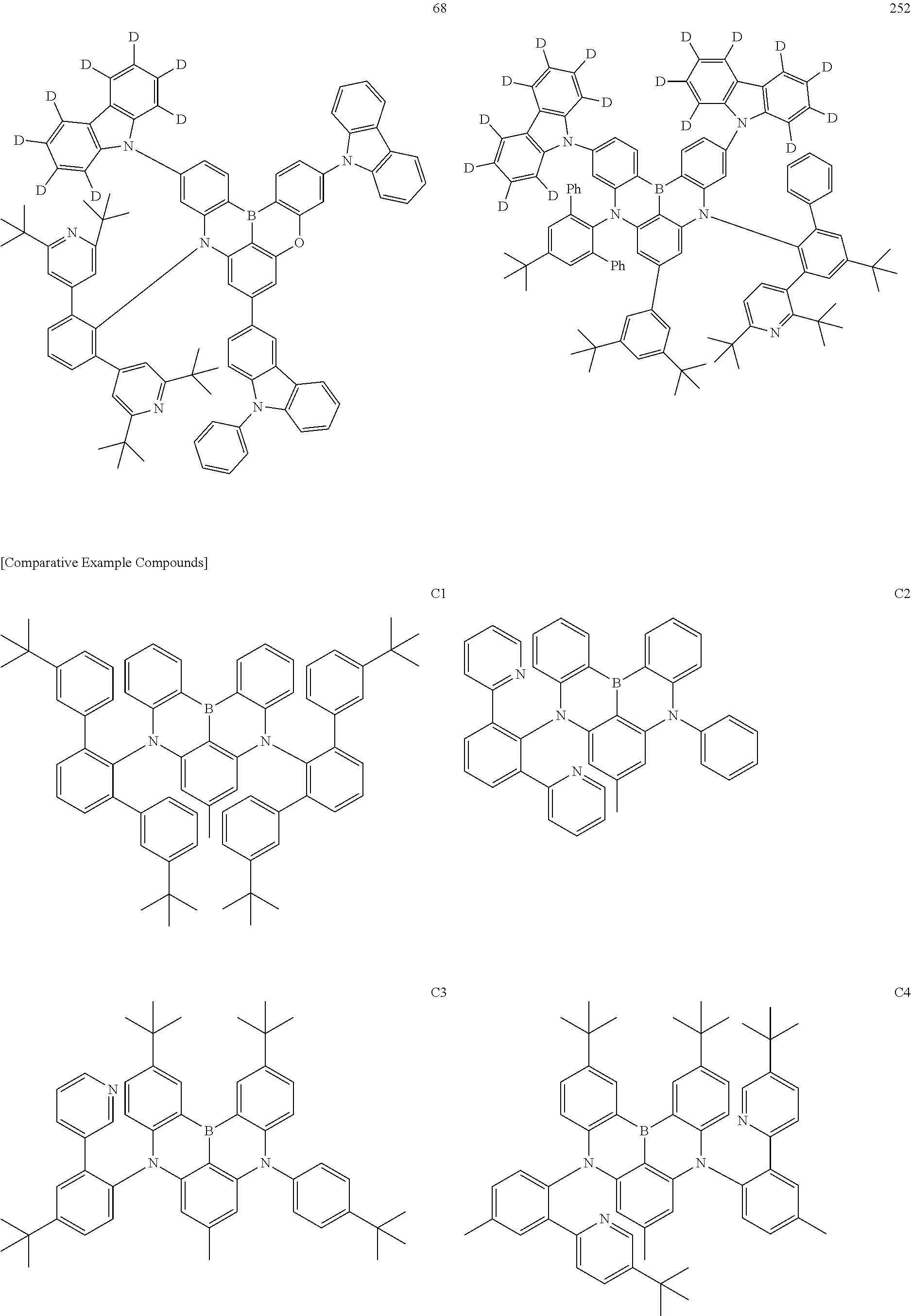

(1) Manufacture of Light Emitting Element 1

Compounds 13, 33, 47, 68, and 252 that are the polycyclic compounds of Example Compounds were used as a dopant material for the emission layer to manufacture the light emitting elements of Examples 1-1 to 1-5, respectively. Comparative Example Compound C1 to Comparative Example Compound C4 were used as a dopant material for the emission layer to manufacture the light emitting elements of Comparative Examples 1-1 to 1-4, respectively.

A glass substrate, on which an ITO electrode of about 15 Ω/cm² (about 1,200 Å) is formed as a first electrode, was cut to a size of about 50 mm×50 mm×of 0.7 mm, and cleansed by ultrasonic waves using isopropyl alcohol and pure water for about five minutes each. The glass substrate was irradiated with ultraviolet rays for about 30 minutes and exposed to ozone and cleansed, and was installed on a vacuum deposition apparatus.

On the upper portion of the first electrode, NPD was deposited to form a 300 Å-thick hole injection layer. A hole transport layer material was deposited on the upper portion of the hole injection layer to form a 200 Å-thick hole transport layer. CzSi was deposited on the upper portion of the hole transport layer to form a 100 Å-thick emission-auxiliary layer. The hole transport layer material used when Light Emitting Element 1 was manufactured is as shown in Table 1.

On the upper portion of the emission-auxiliary layer, a host mixture, a phosphorescent sensitizer, and a dopant of an Example Compound or a Comparative Example Compound were co-deposited at a weight ratio of 85:14:1 to form a 200 Å-thick emission layer. The host mixture was provided by mixing a first host HT2 and a second host EHT86 at a weight ratio of 5:5 as shown in Table 1 below. The first hosts correspond to the second compound according to an embodiment, and the second hosts correspond to the third compound according to an embodiment. AD-38 was used as the phosphorescent sensitizer as shown in Table 1 below. The phosphorescent sensitizer corresponds to the fourth compound according to an embodiment.

TSPO1 was deposited on the upper portion of the emission layer to form a 200 Å-thick hole blocking layer. TPBi was deposited on the upper portion of the hole blocking layer to form a 300 Å-thick electron transport layer. LiF was deposited on the upper portion of the electron transport layer to form a 10 Å-thick electron injection layer. Al was deposited on the upper portion of the electron injection layer to form a 3,000 Å-thick second electrode, thereby manufacturing a light emitting element.

(2) Manufacture of Light Emitting Element 2

The light emitting elements of Examples 2-1 to 2-5 were manufactured in the same manner as the light emitting elements of Examples 1-1 to 1-5, except that the phosphorescent sensitizer was not used when the emission layer was formed. The light emitting elements of Comparative Examples 2-1 to 2-4 were manufactured in the same manner as the light emitting elements of Comparative Examples 1-1 to 1-4, except that the phosphorescent sensitizer was not used when the emission layer was formed. For the light emitting elements of Examples 2-1 to 2-5 and Comparative Examples 2-1 to 2-4, when the emission layer was formed, a host mixture and a dopant were provided at a weight ratio of 99:1 and co-deposited to a thickness of about 200 Å.

Compounds used for manufacturing the light emitting elements of the Examples and the Comparative Examples are as follows. The materials below were used to manufacture the devices by subjecting commercial products to sublimation purification.

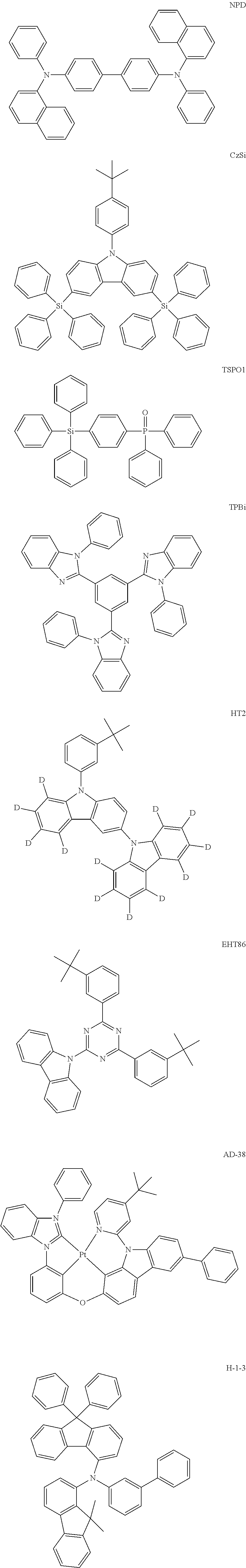

(3) Evaluation of Characteristics of Light Emitting Element 1 and Light Emitting Element 2

Characteristics of the light emitting elements of Examples 1-1 to 1-5 and Comparative Examples 1-1 to 1-4 were evaluated, and the results are listed in Table 1 below. Characteristics of the light emitting elements of Examples 2-1 to 2-5 and Comparative Examples 2-1 to 2-4 were evaluated, and the results are listed in Table 2 below.

Driving voltages (V), luminous efficiencies (cd/A), maximum external quantum efficiencies (EQEₘₐₓ, %), service lives (%), and emission colors were measured, and the results are listed in Table 1 and Table 2. The driving voltages (V), luminous efficiencies (cd/A), maximum external quantum efficiencies (EQEₘₐₓ, %), and emission colors of the light emitting elements were measured at a brightness of 1,000 cd/m² by using Keithley MU 236 and a luminance meter PR650. For the element service life, the time taken to reach 95% brightness relative to an initial brightness was measured as a service life (T₉₅). The element service life is shown in Table 1 as a relative value based on the service life in Comparative Example 1-1 as 100%.

TABLE 1

| | | Second | | | | | | | |
|---|---|---|---|---|---|---|---|---|---|
| | | compound/ | | | | | Maximum | | |
| | Hole | third | | | | | external | Element | |
| | transport | compound | | | Driving | Effi- | quantum | service | Emis- |
| | layer | (HT:ET = | Fourth | First | voltage | ciency | efficiency | life | sion |
| | material | 5:5) | compound | compound | (V) | (cd/A) | (%) | (%) | color |
| Example 1-1 | H-1-3 | HT2/EHT86 | AD-38 | Compound 13 | 4.4 | 25.7 | 25.3 | 280 | Blue |
| Example 1-2 | H-1-3 | HT2/EHT86 | AD-38 | Compound 43 | 4.4 | 26.1 | 25.4 | 260 | Blue |
| Example 1-3 | H-1-3 | HT2/EHT86 | AD-38 | Compound 64 | 4.3 | 26.6 | 25.5 | 295 | Blue |
| Example 1-4 | H-1-3 | HT2/EHT86 | AD-38 | Compound 78 | 4.2 | 24.6 | 23.1 | 250 | Blue |
| Example 1-5 | H-1-3 | HT2/EHT86 | AD-38 | Compound 252 | 4.2 | 26.9 | 25.7 | 345 | Blue |
| Comparative | H-1-3 | HT2/EHT86 | AD-38 | Comparative | 4.6 | 15.4 | 14.5 | 160 | Blue |
| Example 1-1 | | | | Example | | | | | |
| | | | | Compound C1 | | | | | |
| Comparative | H-1-3 | HT2/EHT86 | AD-38 | Comparative | 4.7 | 12.8 | 11.6 | 100 | Blue |
| Example 1-2 | | | | Example | | | | | |
| | | | | Compound C2 | | | | | |
| Comparative | H-1-3 | HT2/EHT86 | AD-38 | Comparative | 4.5 | 15.7 | 14.8 | 145 | Blue |
| Example 1-3 | | | | Example | | | | | |
| | | | | Compound C3 | | | | | |
| Comparative | H-1-3 | HT2/EHT86 | AD-38 | Comparative | 4.6 | 16.1 | 15.5 | 155 | Blue |
| Example 1-4 | | | | Example | | | | | |
| | | | | Compound C4 | | | | | |

TABLE 2

| | | | | | Maximum | |
|---|---|---|---|---|---|---|
| | Hole | Second | | | external | |
| | transport | compound/third | | | quantum | |
| | layer | compound | | Efficiency | efficiency | Emission |
| | material | (HT:ET = 5:5) | Fourth compound | (cd/A) | (%) | color |
| Example 2-1 | H-1-3 | HT2/EHT86 | Compound 13 | 8.4 | 8.2 | Blue |
| Example 2-2 | H-1-3 | HT2/EHT86 | Compound 43 | 8.5 | 8.3 | Blue |
| Example 2-3 | H-1-3 | HT2/EHT86 | Compound 64 | 8.7 | 8.3 | Blue |
| Example 2-4 | H-1-3 | HT2/EHT86 | Compound 78 | 8.0 | 7.5 | Blue |
| Example 2-5 | H-1-3 | HT2/EHT86 | Compound 252 | 8.7 | 8.4 | Blue |
| Comparative | H-1-3 | HT2/EHT86 | Comparative Example | 4.9 | 4.6 | Blue |
| Example 2-1 | | | Compound C1 | | | |
| Comparative | H-1-3 | HT2/EHT86 | Comparative Example | 4.1 | 3.7 | Blue |
| Example 2-2 | | | Compound C2 | | | |
| Comparative | H-1-3 | HT2/EHT86 | Comparative Example | 5.0 | 4.7 | Blue |
| Example 2-3 | | | Compound C3 | | | |
| Comparative | H-1-3 | HT2/EHT86 | Comparative Example | 5.0 | 4.6 | Blue |
| Example 2-4 | | | Compound C4 | | | |

Referring to Table 1, it may be seen that Examples 1-1 to 1-5, which are light emitting elements to which the polycyclic compound according to an embodiment is applied, exhibit element characteristics of low driving voltage, high luminous efficiency, high maximum external quantum efficiency, and long service life as compared with Comparative Examples 1-1 to 1-4. Referring to Table 2, it may be seen that Examples 2-1 to 2-5, which are light emitting elements to which the polycyclic compound according to an embodiment is applied as a single dopant, exhibit high luminous efficiency and high maximum external quantum efficiency as compared with Comparative Examples 2-1 to 2-4.

In the light emitting elements of the Examples, the polycyclic compound included in the emission layer includes the pyridine unit linked to the nitrogen atom of the fused ring core. The polycyclic compound may have more enhanced multiple resonance effects due to HOMO-LUMO sequential separation between atoms by the introduction of the pyridine unit having electron-withdrawing properties to a position of high electron density. Thus, the light emitting element including the polycyclic compound according to an embodiment may have improvements in delayed fluorescence characteristics, achieve blue shift emission, and exhibit photoluminescence quantum yield (PLQY).

In the polycyclic compound according to an embodiment, the pyridine unit has a structure in which a t-butyl group is introduced at an ortho-position with respect to the nitrogen atom of the pyridine. The ortho-position to the nitrogen atom of the pyridine is a position with strong activity, and the t-butyl group is linked and thus molecular stability may be improved. The polycyclic compound contains the pyridine unit, thus may exhibit steric hindrance characteristics, and may effectively suppress Dexter energy transfer between the molecules.

Comparative Example Compound C1 does not contain a pyridine unit. Comparative Example Compound C2 and Comparative Example Compound C3 each contain a pyridine group linked to a fused ring core, but do not contain a t-butyl group at an ortho-position to the nitrogen atom of the pyridine. Comparative Example Compound C4 contains only one first pyridine unit to a linker of a benzene ring linked to a nitrogen atom of the fused ring core. Comparative Example Compounds C1 to C4 may have low molecular stability and no steric hindrance characteristics, and thus it may be difficult to suppress Dexter energy transfer between the molecules. Thus, it is thought that the light emitting elements of Comparative Examples in which Comparative Examples Compounds are applied to emission layers exhibit deteriorated element characteristics compared to Examples.

The light emitting element of an embodiment may exhibit improved element characteristics with high efficiency and a long service life.

The polycyclic compound according to an embodiment may be included in the emission layer of the light emitting element, thereby contributing to improving luminous efficiency and service life of the light emitting element.

The polycyclic compound according to an embodiment may include a boron-containing fused ring core and a pyridine unit bonded to the fused ring core, thereby contributing to improvements in efficiency and service life of the light emitting element.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
an emission layer disposed between the first electrode and the second electrode, wherein
the emission layer comprises:
a first compound represented by Formula 1; and
at least one of a second compound represented by Formula HT, or a third compound represented by Formula ET: 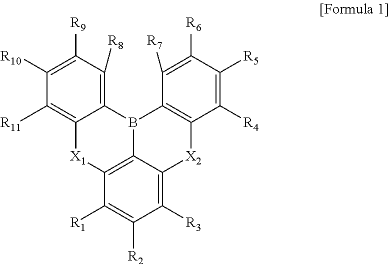
wherein in Formula 1,
at least one of X₁ or X₂ is each independently N(Rₓ₁), and
the remainder of X₁ or X₂ is N(Rₓ₂), O or S,
Rₓ₁ is a group represented by one of Formula 2-1 to Formula 2-4, and
Rₓ₂ and R₁ to R₁₁ are each independently a hydrogen atom, a deuterium atom, a halogen atom, a cyano group, a substituted or unsubstituted amine group, a substituted or unsubstituted silyl group, a substituted or unsubstituted alkyl group having 1 to 10 carbon atoms, a substituted or unsubstituted cycloalkyl group having 3 to 10 ring-forming carbon atoms, a substituted or unsubstituted aryl group having 6 to 60 ring-forming carbon atoms, a substituted or unsubstituted heterocycloalkyl group having 2 to 10 ring-forming carbon atoms, or a substituted or unsubstituted heteroaryl group having 2 to 60 ring-forming carbon atoms; 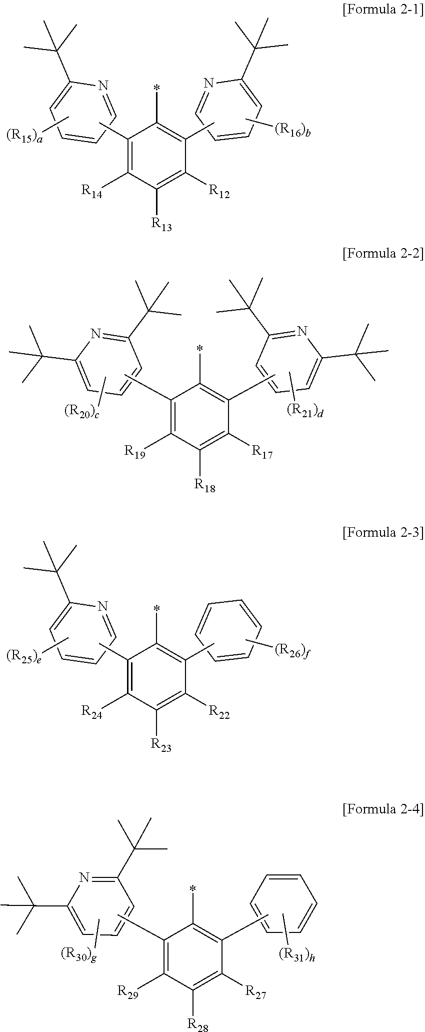
wherein in Formula 2-1 to Formula 2-4,
R₁₂ to R₃₁ are each independently a hydrogen atom, a deuterium atom, a halogen atom, a cyano group, a substituted or unsubstituted amine group, a substituted or unsubstituted silyl group, a substituted or unsubstituted alkyl group having 1 to 10 carbon atoms, a substituted or unsubstituted cycloalkyl group having 3 to 10 ring-forming carbon atoms, a substituted or unsubstituted aryl group having 6 to 60 ring-forming carbon atoms, a substituted or unsubstituted heterocycloalkyl group having 2 to 10 ring-forming carbon atoms, or a substituted or unsubstituted heteroaryl group having 2 to 60 ring-forming carbon atoms,
a, b, and e are each independently an integer from 0 to 3,
c, d, and g are each independently an integer from 0 to 2, and
f and h are each independently an integer from 0 to 5; 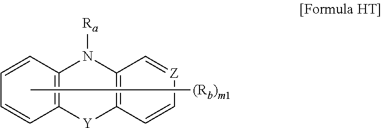
wherein in Formula HT,
Rₐ and R_{b} are each independently a hydrogen atom, a deuterium atom, a cyano group, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
m1 is an integer from 0 to 7,
Y is a direct linkage, C(R_{y1})(R_{y2}), or Si(R_{y3})(R_{y4}),
Z is C(R_{z}) or N,
R_{y1} to R_{y4} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and
R_{z} is a hydrogen atom or a deuterium atom; 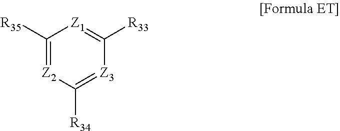
wherein in Formula ET,
Z₁ to Z₃ are each independently N or (R₃₆),
at least one of Z₁ to Z₃ is each N, and
R₃₃ to R₃₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring.

2. The light emitting element of claim 1, wherein the emission layer further comprises a fourth compound represented by Formula PS: 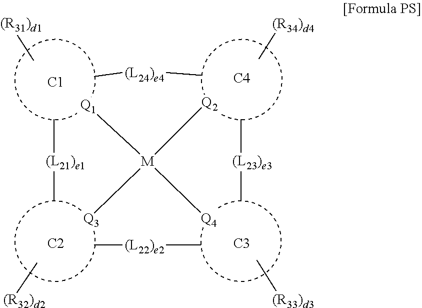
wherein in Formula PS,
M is Pt or Ir,
Q₁ to Q₄ are each independently C or N,
C1 to C4 are each independently a substituted or unsubstituted hydrocarbon ring group having 5 to 30 ring-forming carbon atoms or a substituted or unsubstituted heterocyclic group having 2 to 30 ring-forming carbon atoms,
e1 to e4 are each independently 0 or 1,
L₂₁ to L₂₄ are each independently a direct linkage, 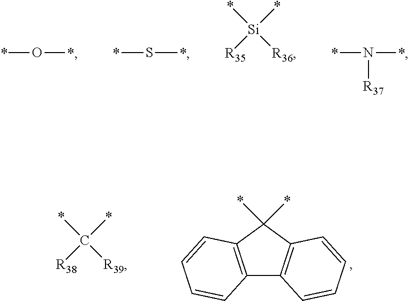
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer from 0 to 4, and
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

3. The light emitting element of claim 1, wherein the first compound is represented by Formula 4: 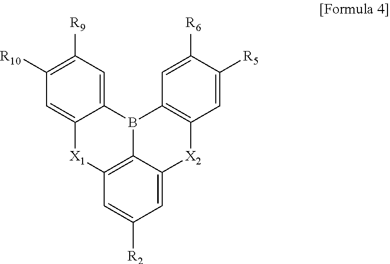
wherein in Formula 4,
R₂, R₅, R₆, R₉, R₁₀, X₁, and X₂ are the same as defined in Formula 1.

4. The light emitting element of claim 3, wherein the first compound is represented by one of Formula 4-1 to Formula 4-3: 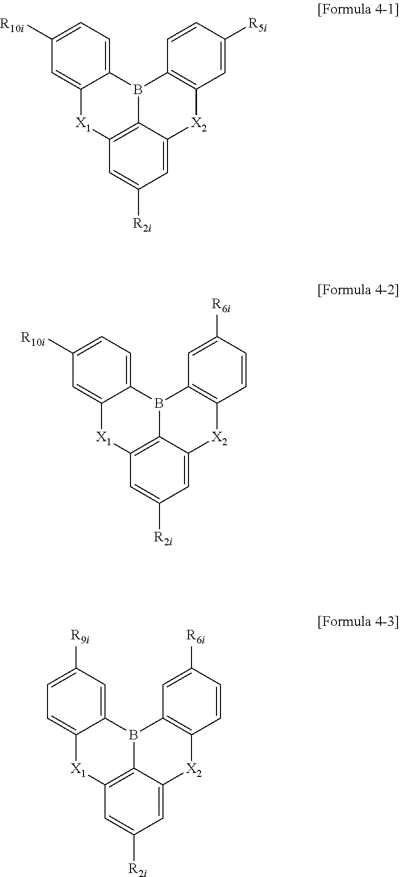
wherein in Formula 4-1 to Formula 4-3,
R₂ᵢ, R₅ᵢ, R₆ᵢ, R₉ᵢ, and R₁₀ᵢ are each independently a hydrogen atom, a deuterium atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms, and
X₁ and X₂ are the same as defined in Formula 1.

5. The light emitting element of claim 1, wherein the first compound is represented by one of Formula 5-1 to Formula 5-7: 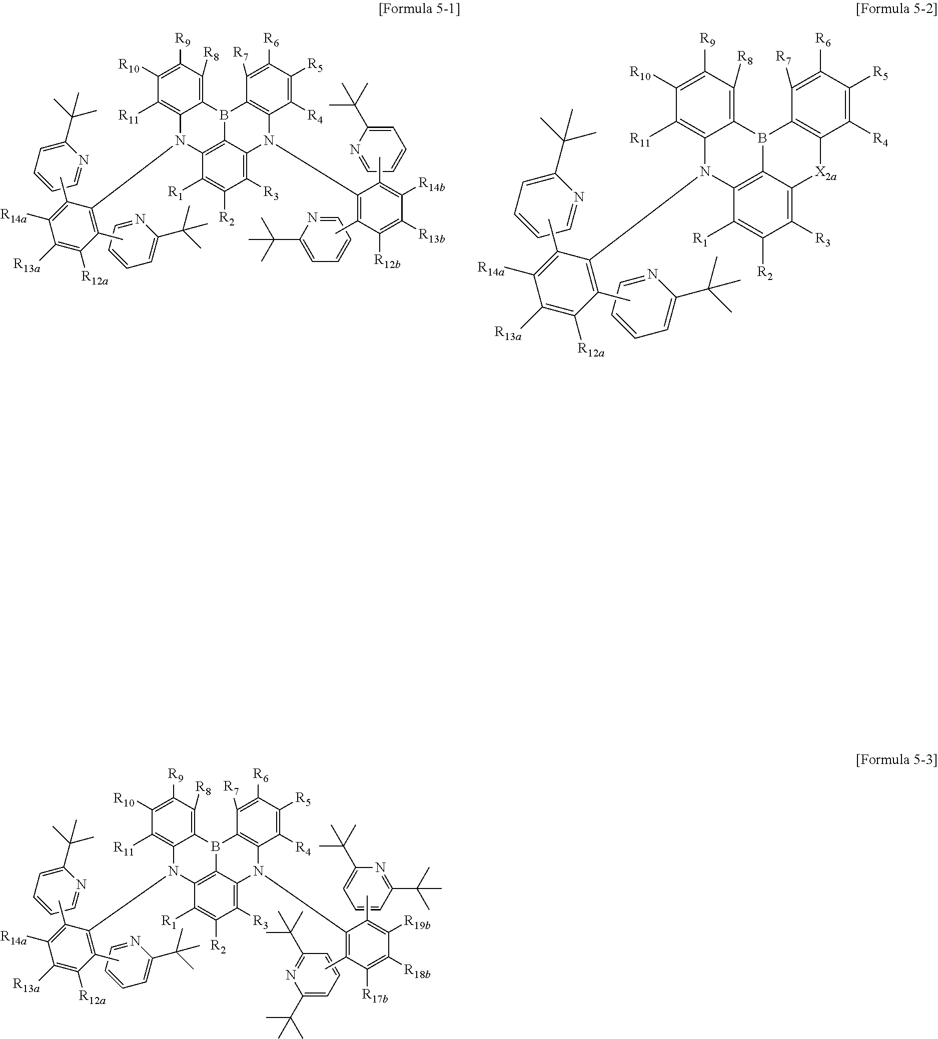 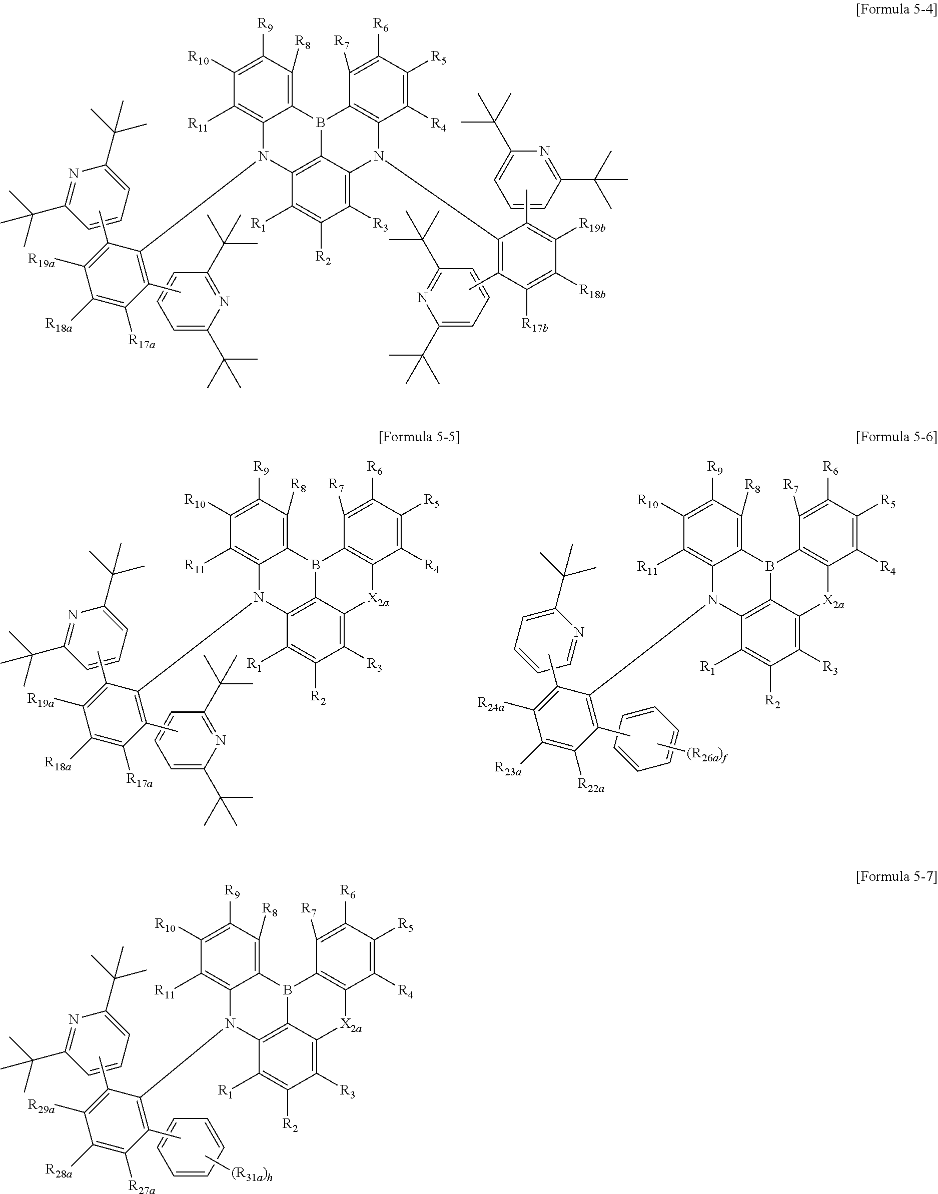
wherein in Formula 5-1 to Formula 5-7,
R₁₂ₐ to R₁₄ₐ, R₁₂ₘ to R_{14b}, R₁₇ₐ to R₁₉ₐ, R_{17b} to R_{19b}, R₂₂ₐ to R₂₄ₐ, R₂₆ₐ, R₂₇ₐ to R₂₉ₐ, and R₃₁ₐ are each independently a hydrogen atom, a deuterium atom, a substituted or unsubstituted alkyl group having 1 to 10 carbon atoms, or a substituted or unsubstituted aryl group having 6 to 60 ring-forming carbon atoms,
X₂ₐ is N(Rₓ₂), O or S, and
f, h, Rₓ₂, and R₁ to R₁₁ are the same as defined in Formula 1.

6. The light emitting element of claim 1, wherein the first compound is represented by one of Formula 6-1 to Formula 6-7: 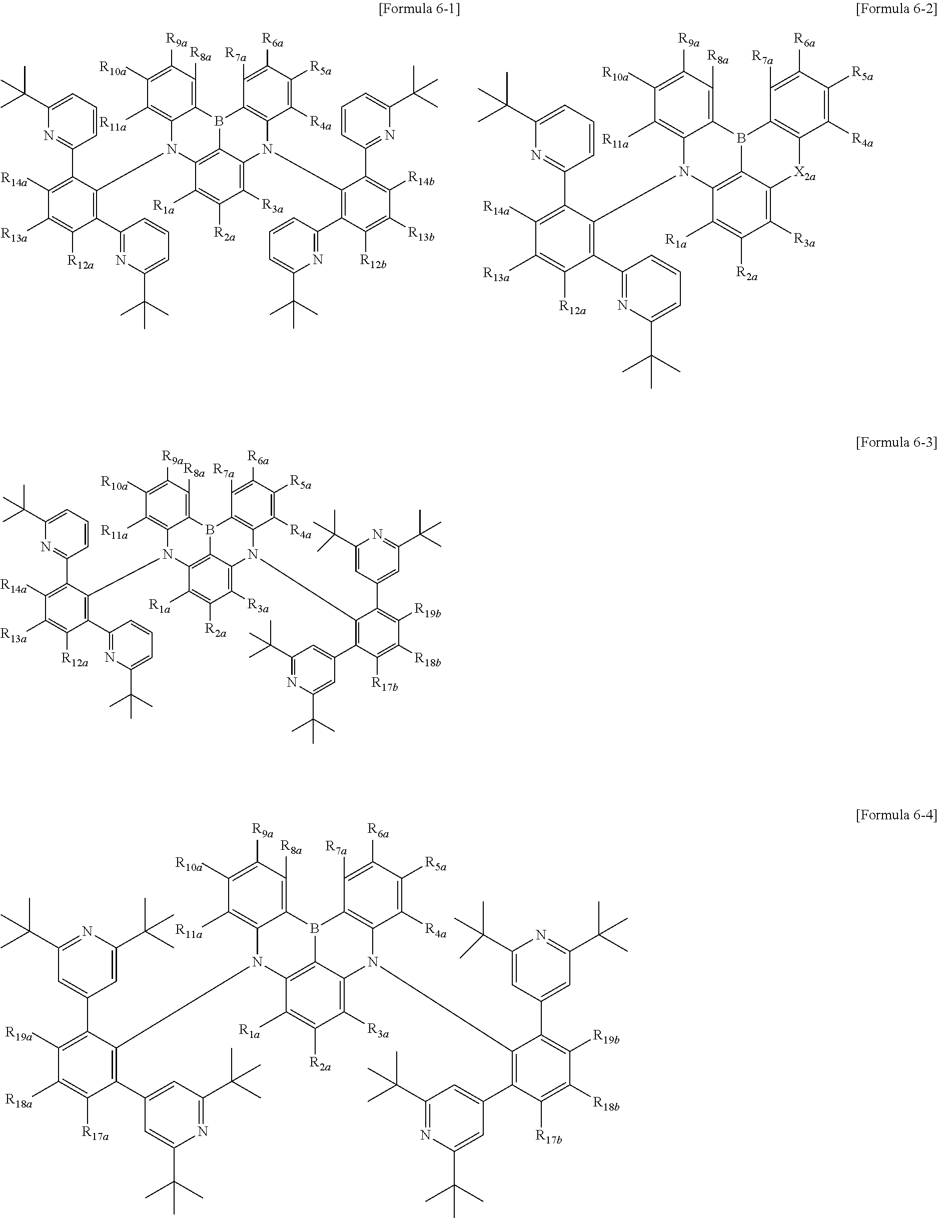 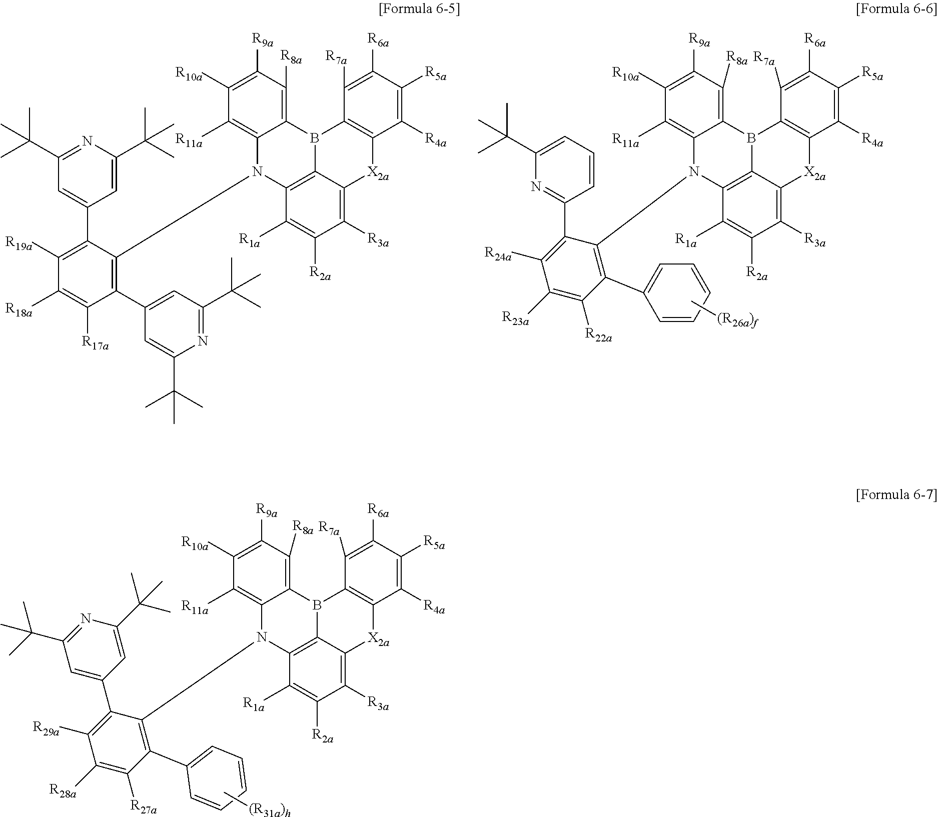
wherein in Formula 6-1 to Formula 6-7,
R₁ₐ to R₁₁ₐ are each independently a hydrogen atom, a deuterium atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms,
R₁₂ₐ to R₁₄ₐ, R_{12b} to R_{14b}, R₁₇ₐ to R₁₉ₐ, R_{17b} to R_{19b}, R₂₂ₐ to R₂₄ₐ, R₂₆ₐ, R₂₇ₐ to R₂₉ₐ, and R₃₁ₐ are each independently a hydrogen atom, a deuterium atom, a substituted or unsubstituted alkyl group having 1 to 10 carbon atoms, or a substituted or unsubstituted aryl group having 6 to 60 ring-forming carbon atoms,
X₂ₐ is N(Rₓ₂), O or S, and
f, h, and Rₓ₂ are the same as defined in Formula 1.

7. The light emitting element of claim 1, wherein the first compound is represented by one of Formula 7-1 to Formula 7-7: 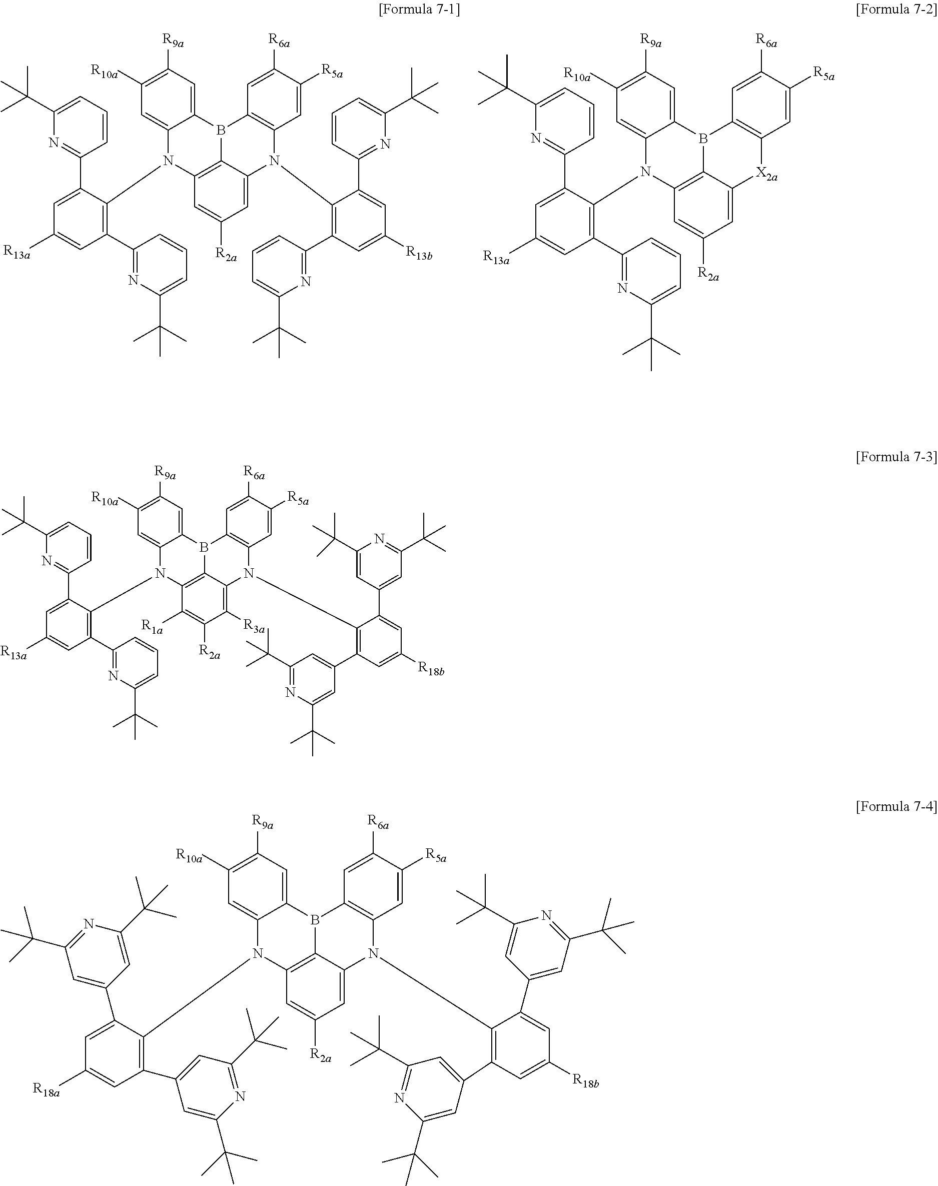 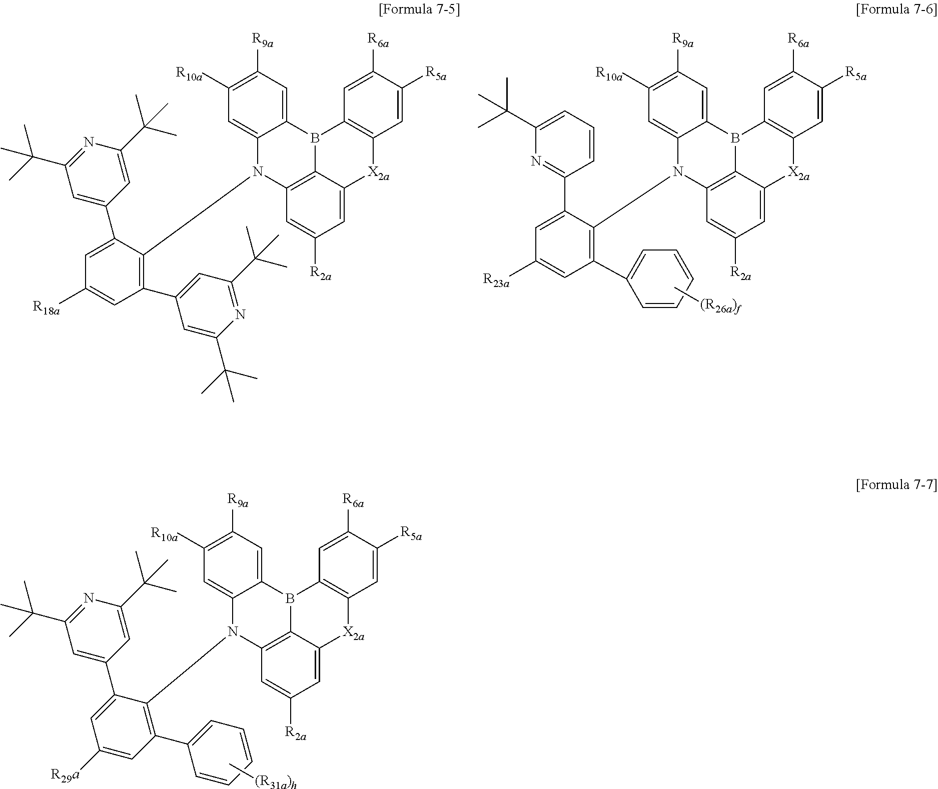
wherein in Formula 7-1 to Formula 7-7,
R₂ₐ, R₅ₐ, R₆ₐ, R₉ₐ, and R₁₀ₐ are each independently a hydrogen atom, a deuterium atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms,
R₁₃ₐ, R_{13b}, R₁₈ₐ, R_{18b}, R₂₃ₐ, R₂₆ₐ, R₂₈ₐ, and R₃₁ₐ are each independently a hydrogen atom, a deuterium atom, a substituted or unsubstituted alkyl group having 1 to 10 carbon atoms, or a substituted or unsubstituted aryl group having 6 to 60 ring-forming carbon atoms,
X₂ₐ is N(Rₓ₂), O or S, and
f, h, and Rₓ₂ are the same as defined in Formula 1.

8. The light emitting element of claim 1, wherein Rₓ₂ is a substituted or unsubstituted aryl group having 6 to 30 ring-forming carbon atoms.

9. The light emitting element of claim 1, wherein R₁₂ to R₃₁ are each independently a hydrogen atom, a deuterium atom, a substituted or unsubstituted t-butyl group, or a substituted or unsubstituted phenyl group.

10. The light emitting element of claim 1, wherein R₁ to R₁₁ are each independently:
a hydrogen atom or a deuterium atom; or
a group represented by one of Formula RS-1 to Formula RS-5: 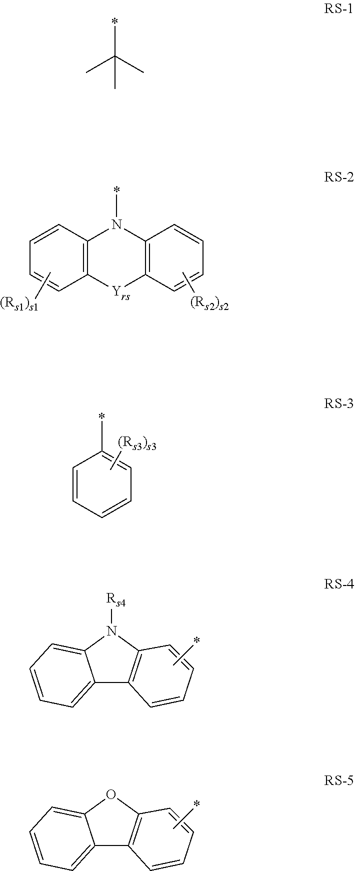
wherein in Formula RS-2,
Yᵣₛ is a direct linkage or C(Rₛₐ₁)(Rₛₐ₂),
R₅ᵢ, Rₛ₂, Rₛₐ₁, and Rₛₐ₂ are each independently a hydrogen atom, a deuterium atom, a cyano group, or a substituted or unsubstituted alkyl group having 1 to 10 carbon atoms, or are bonded to an adjacent group to form a ring, and
s1 and s2 are each independently an integer from 0 to 4, and
wherein in Formula RS-3 and Formula RS-4,
Rₛ₃ and Rₛ₄ are each independently a hydrogen atom, a deuterium atom, a substituted or unsubstituted alkyl group having 1 to 10 carbon atoms, or a substituted or unsubstituted aryl group having 6 to 15 ring-forming carbon atoms, and
s3 is an integer from 0 to 5.

11. The light emitting element of claim 1, wherein the emission layer comprises the first compound, the second compound, and the third compound.

12. The light emitting element of claim 2, wherein the emission layer comprises the first compound, the second compound, the third compound, and the fourth compound.

13. The light emitting element of claim 1, wherein the first compound includes at least one compound selected from Compound Group 1:
[Compound Group 1] 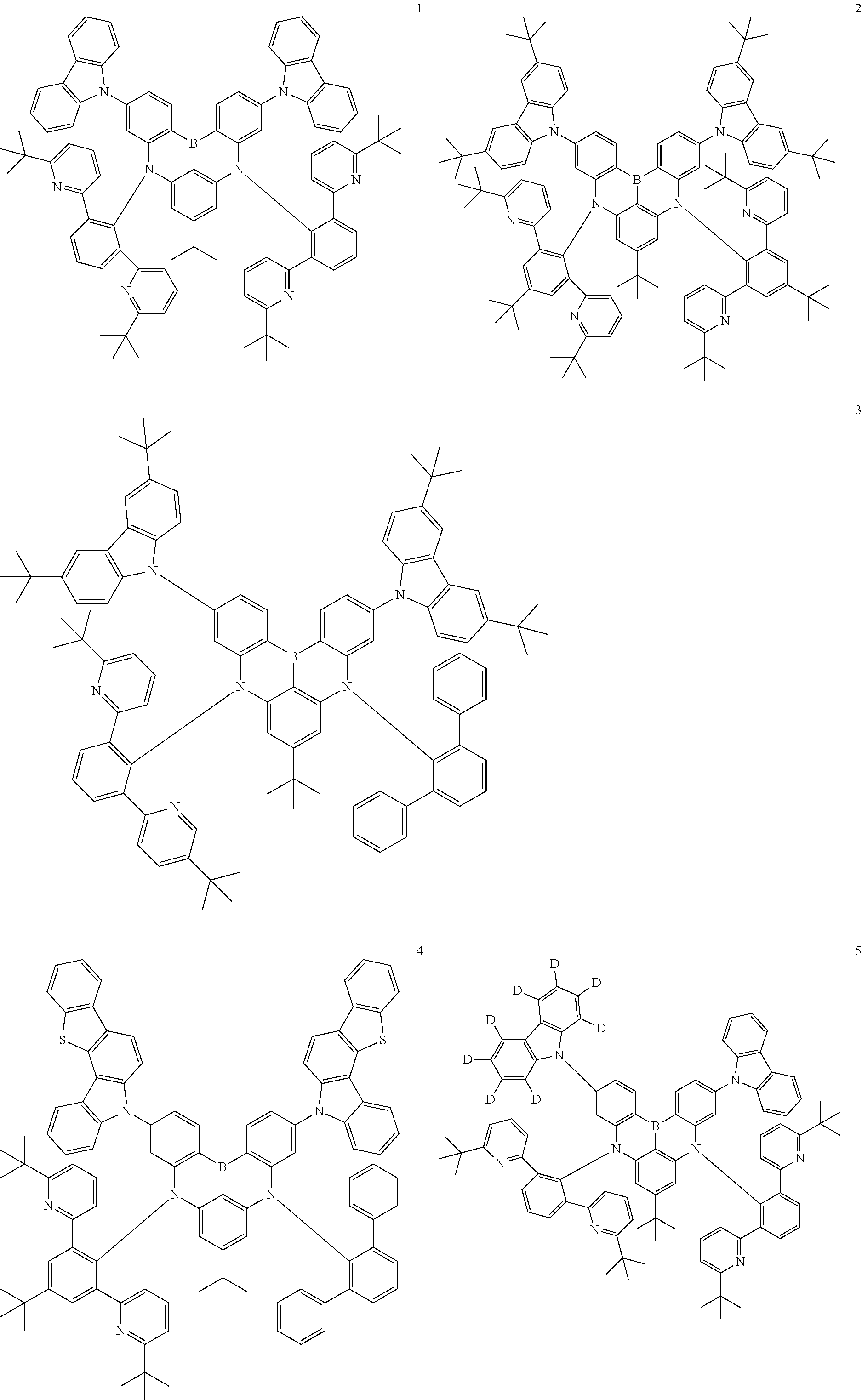 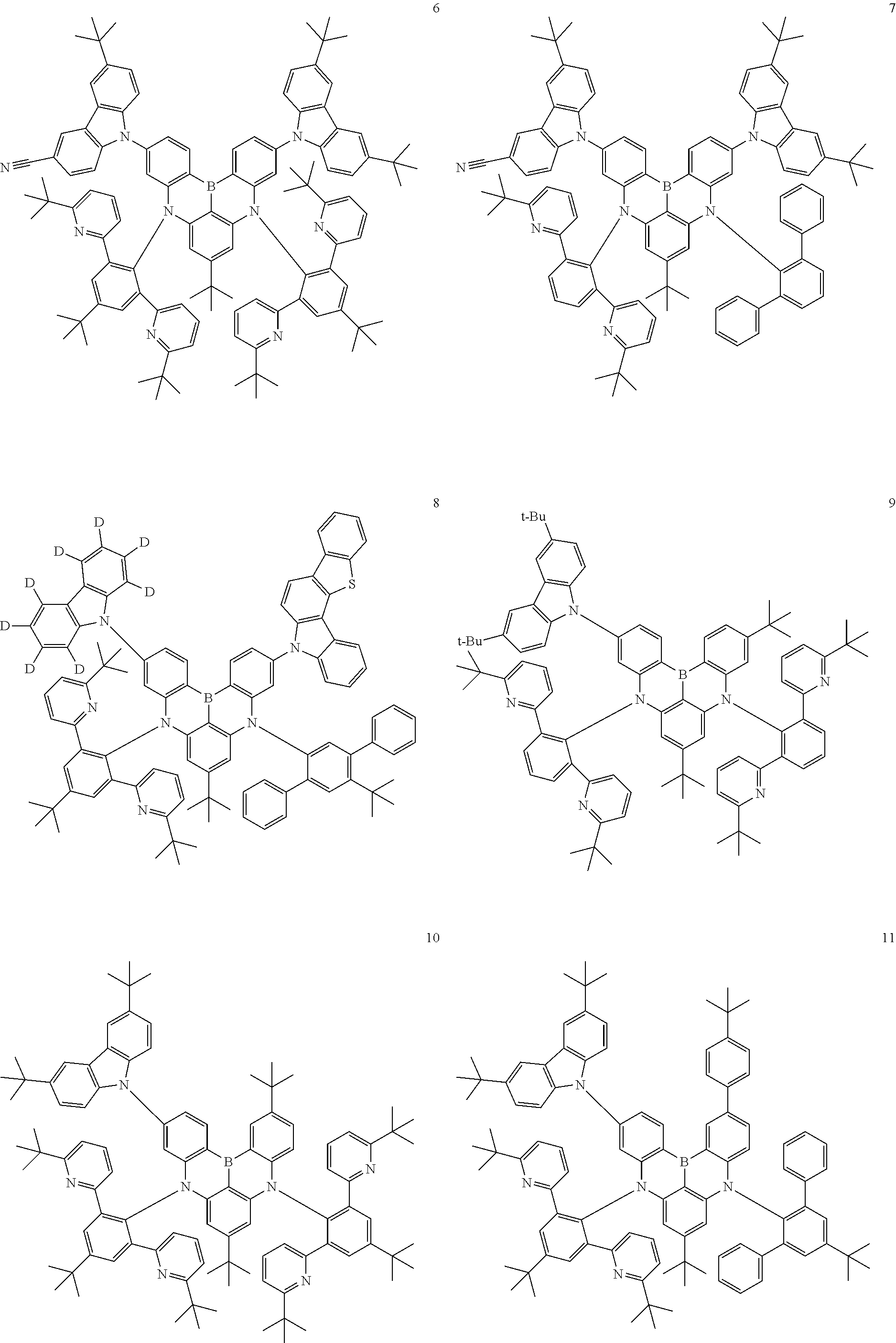 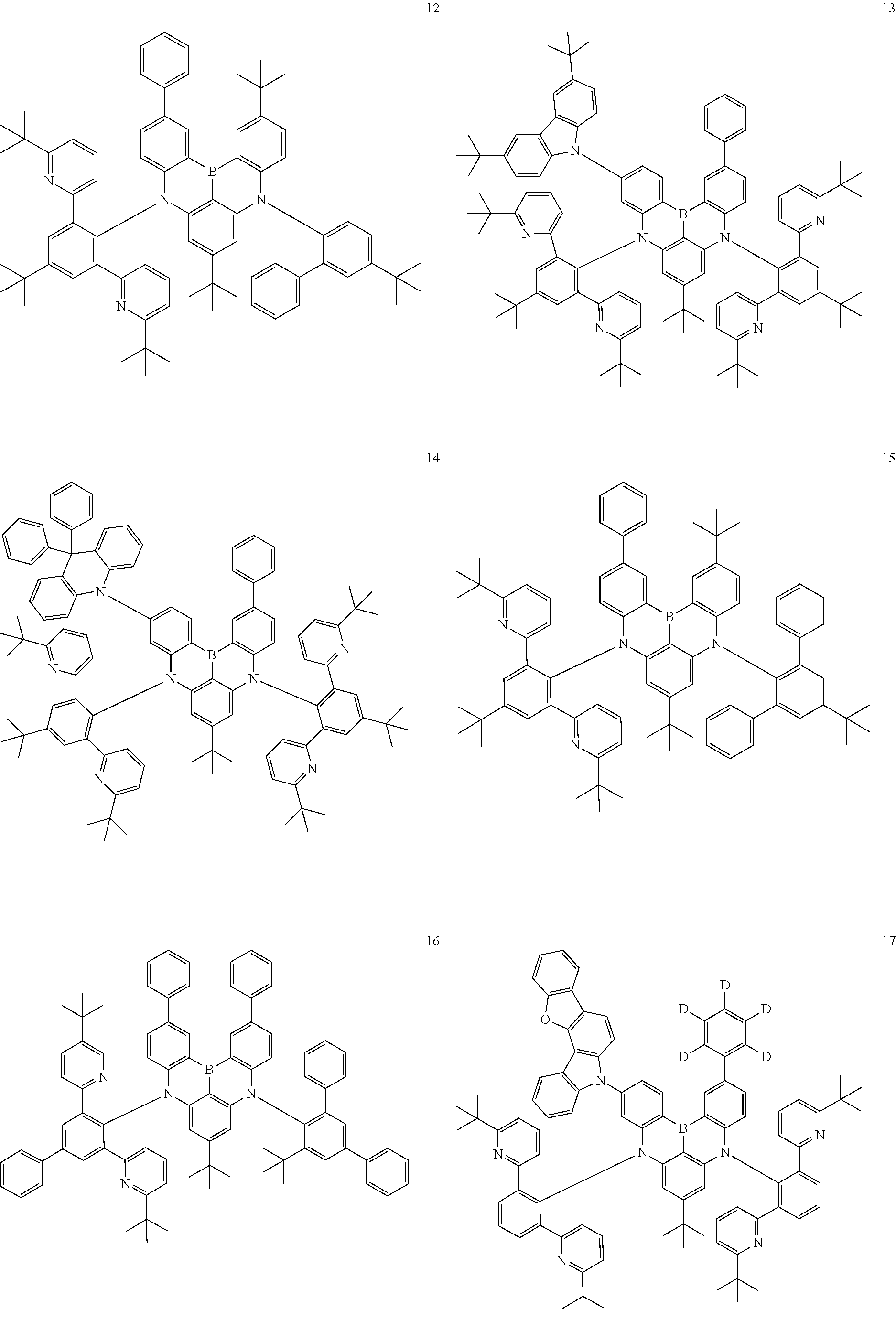 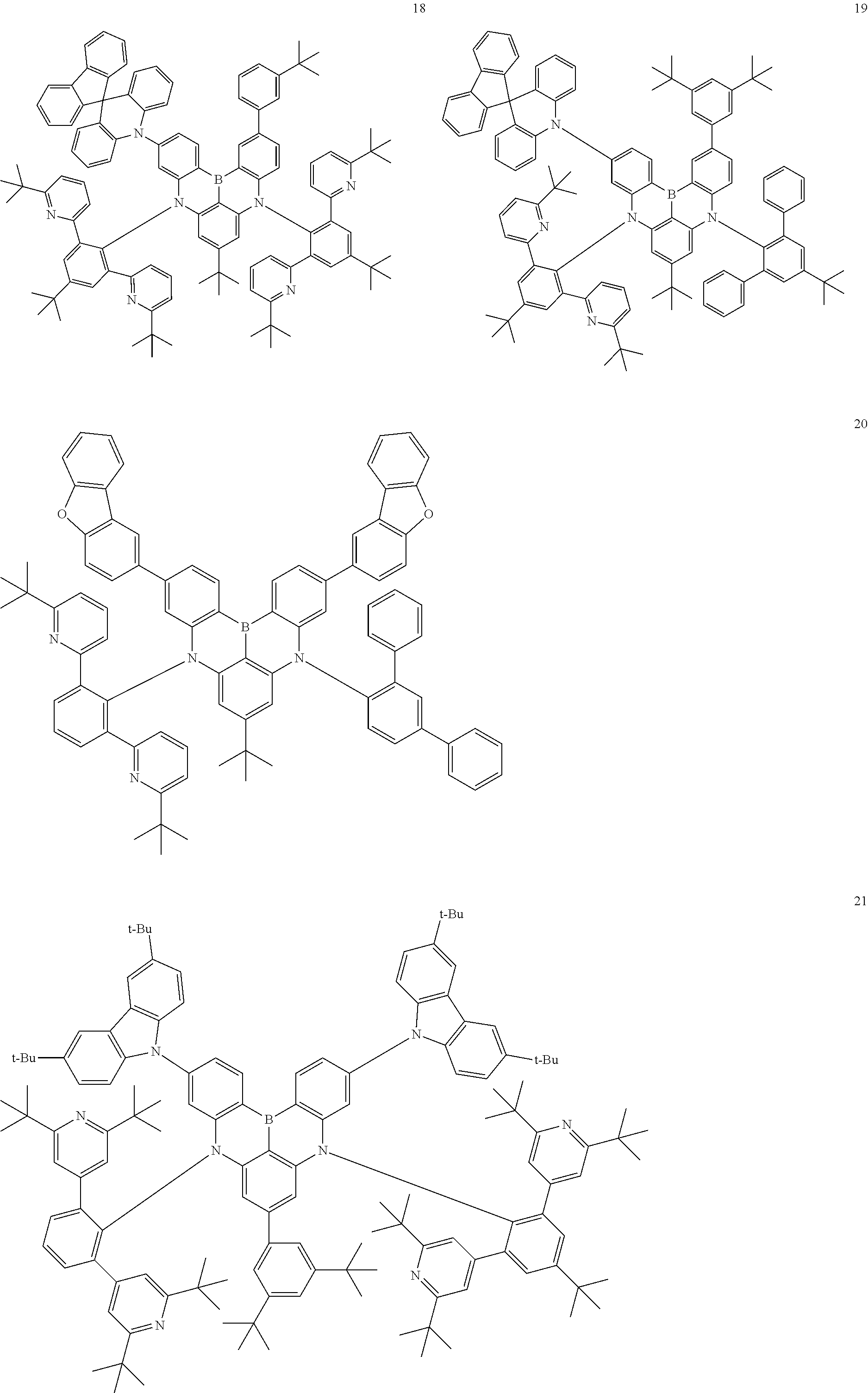 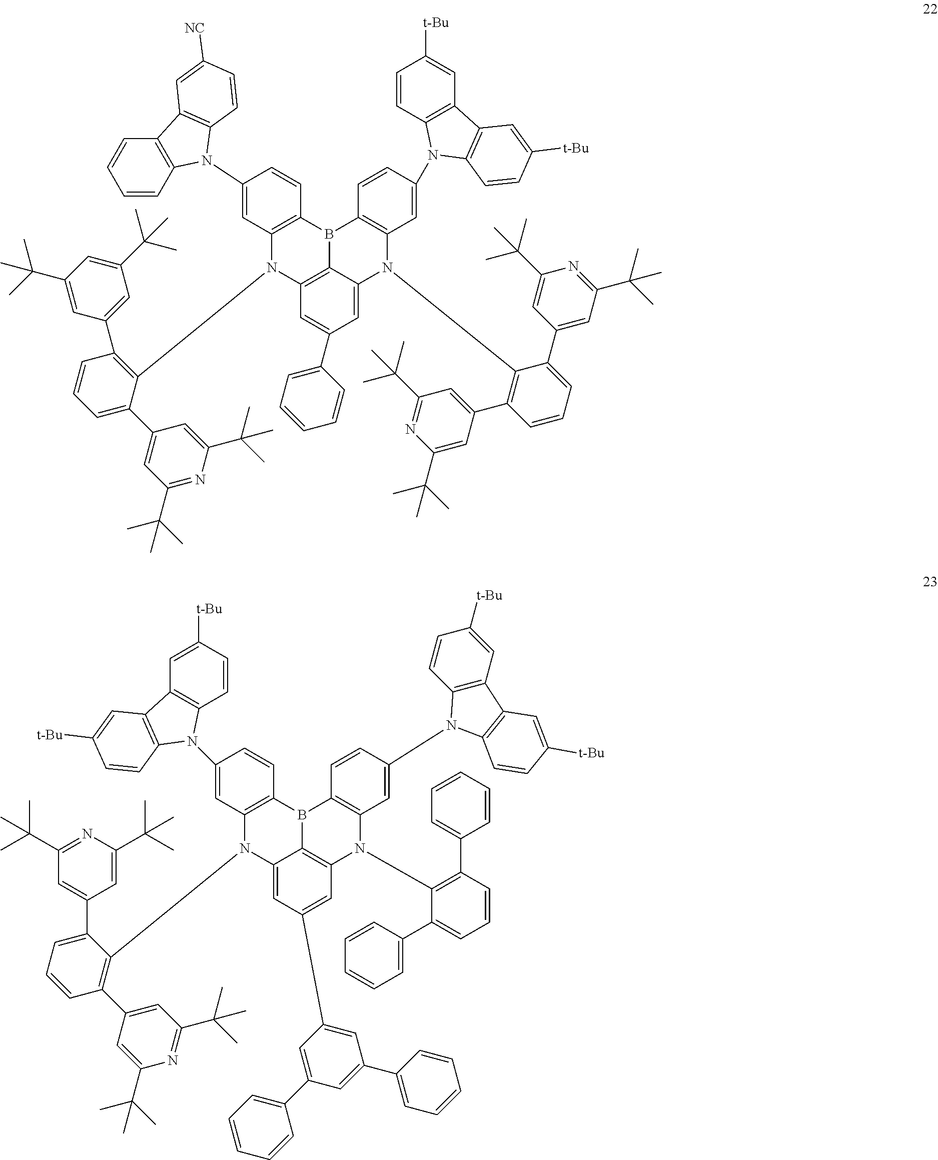 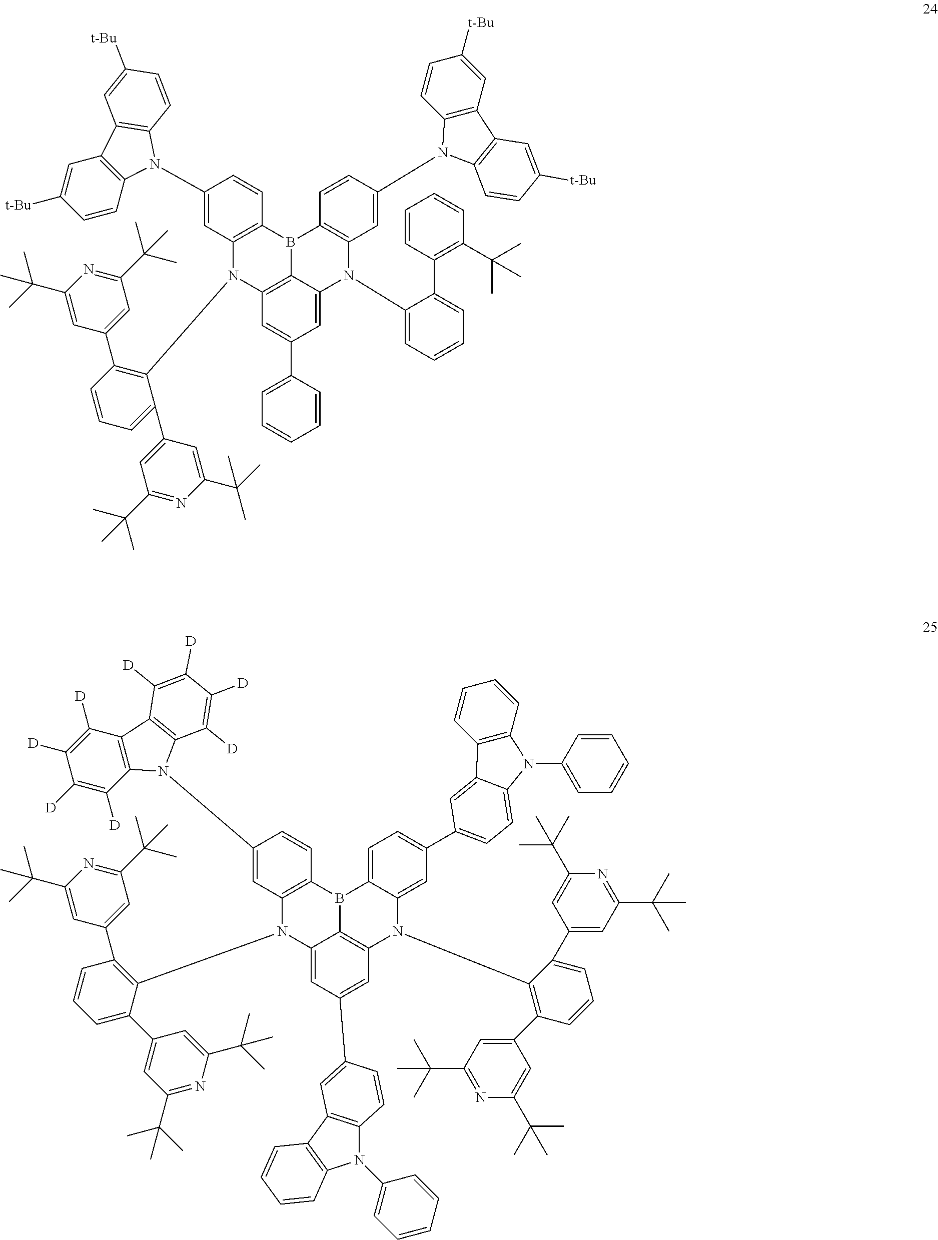 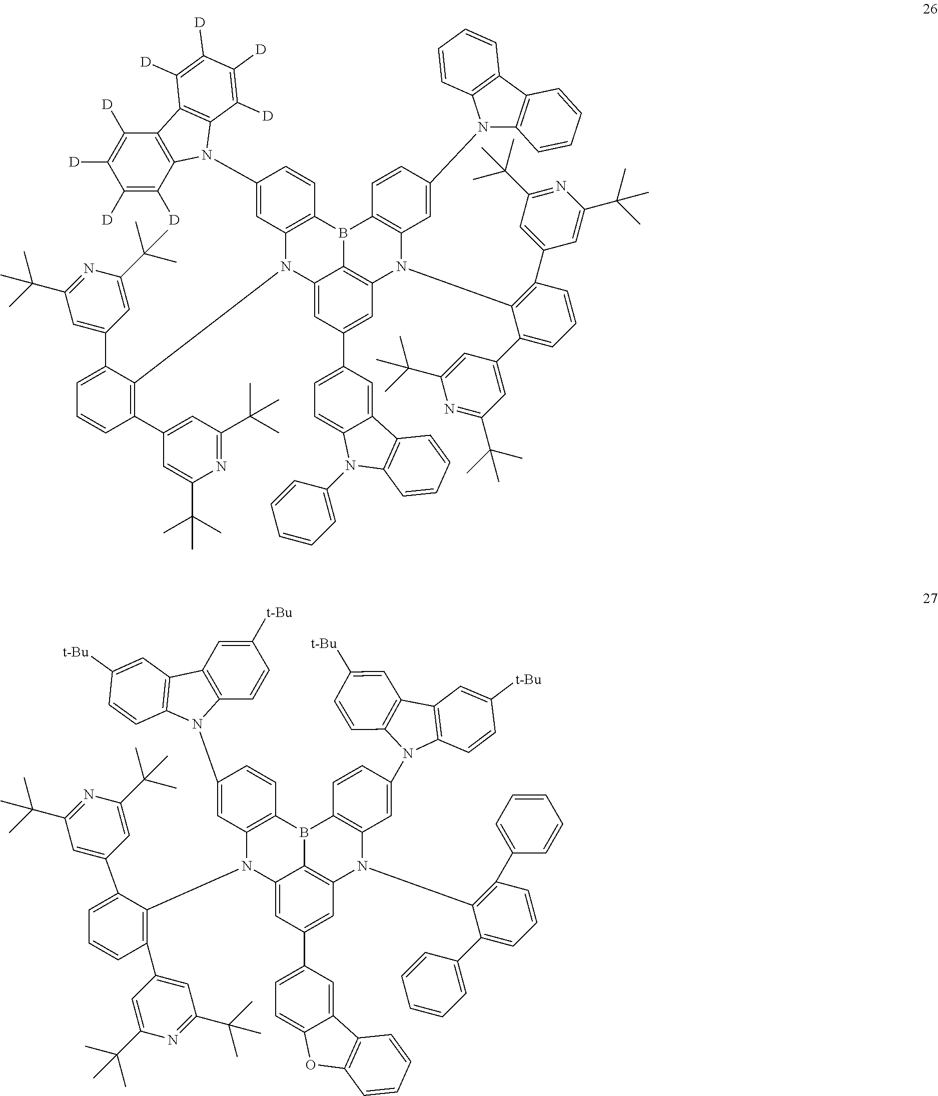 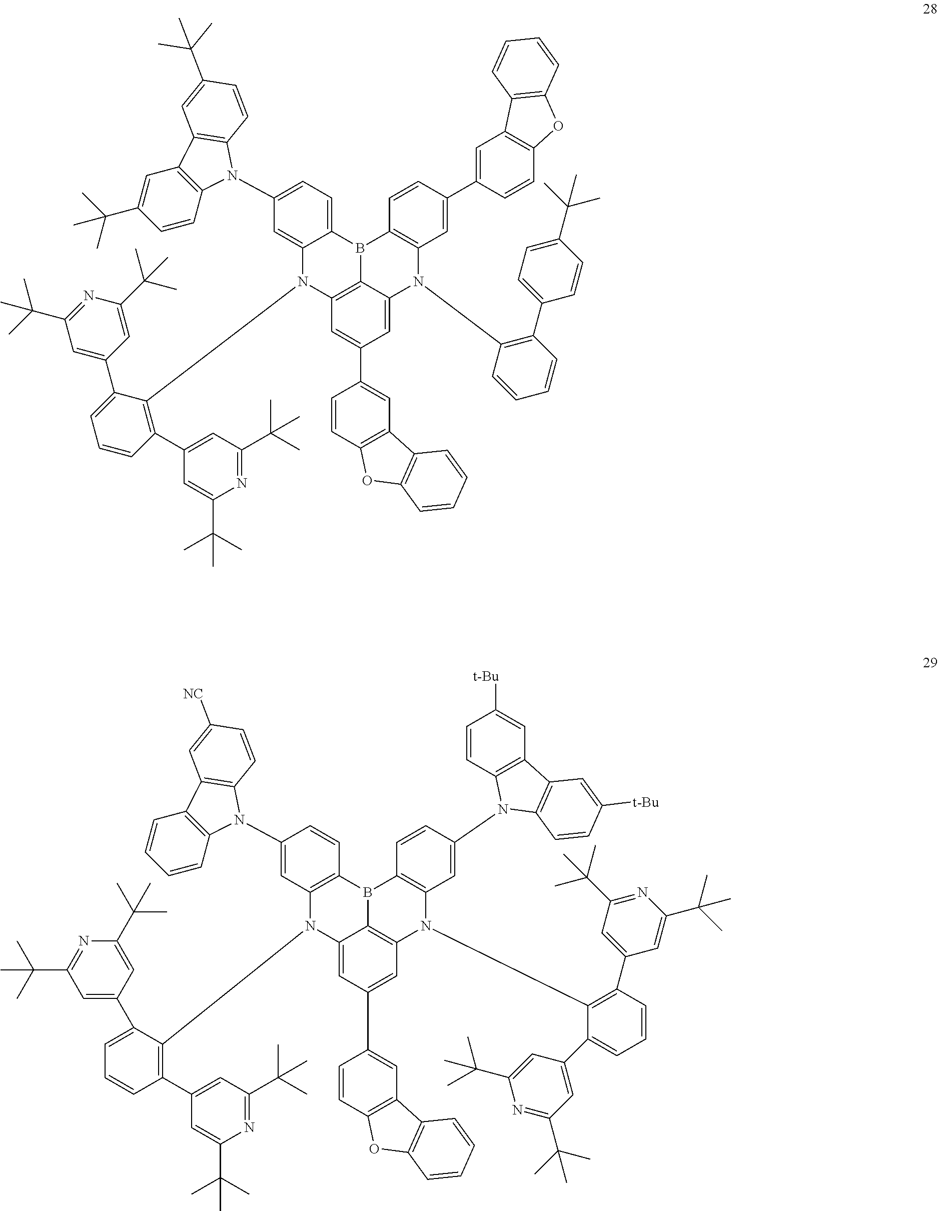 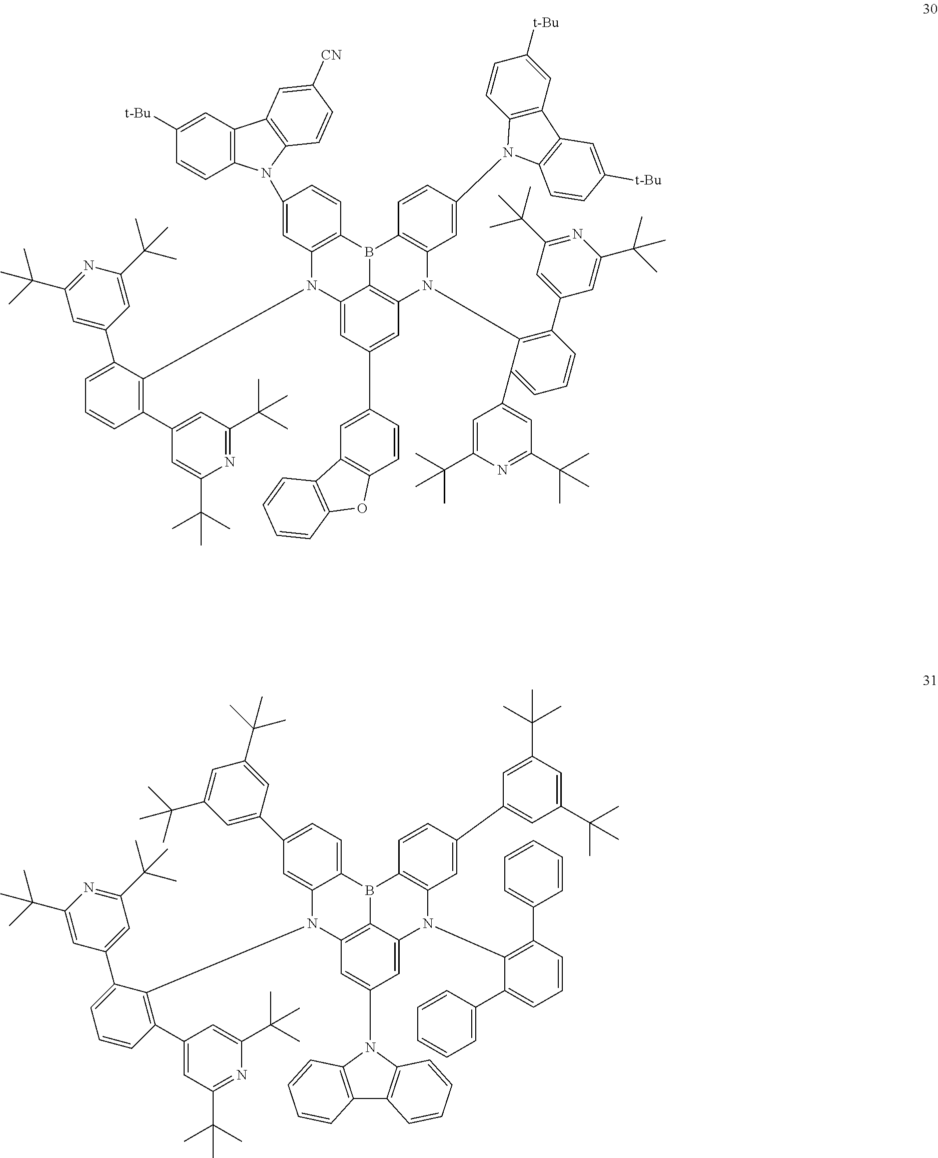 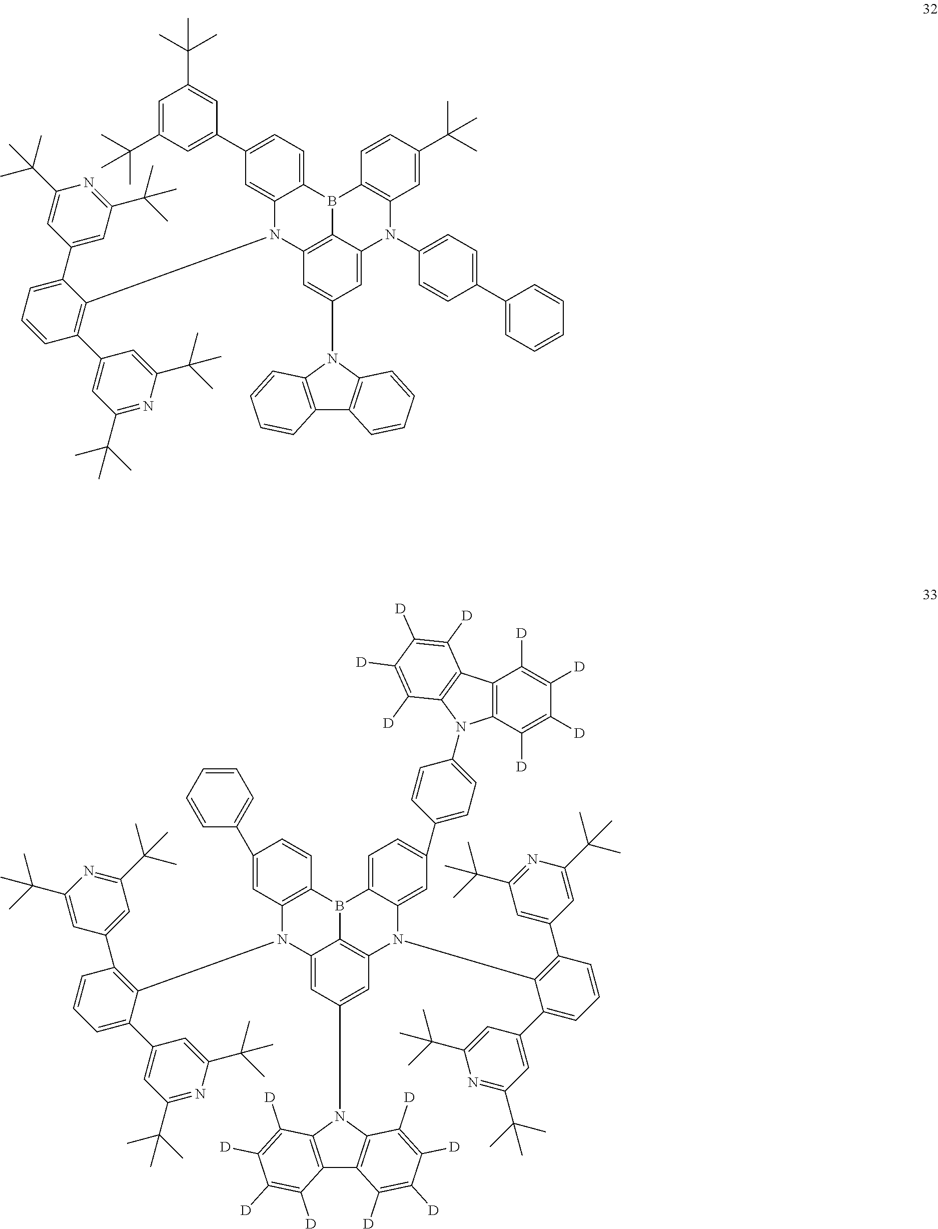 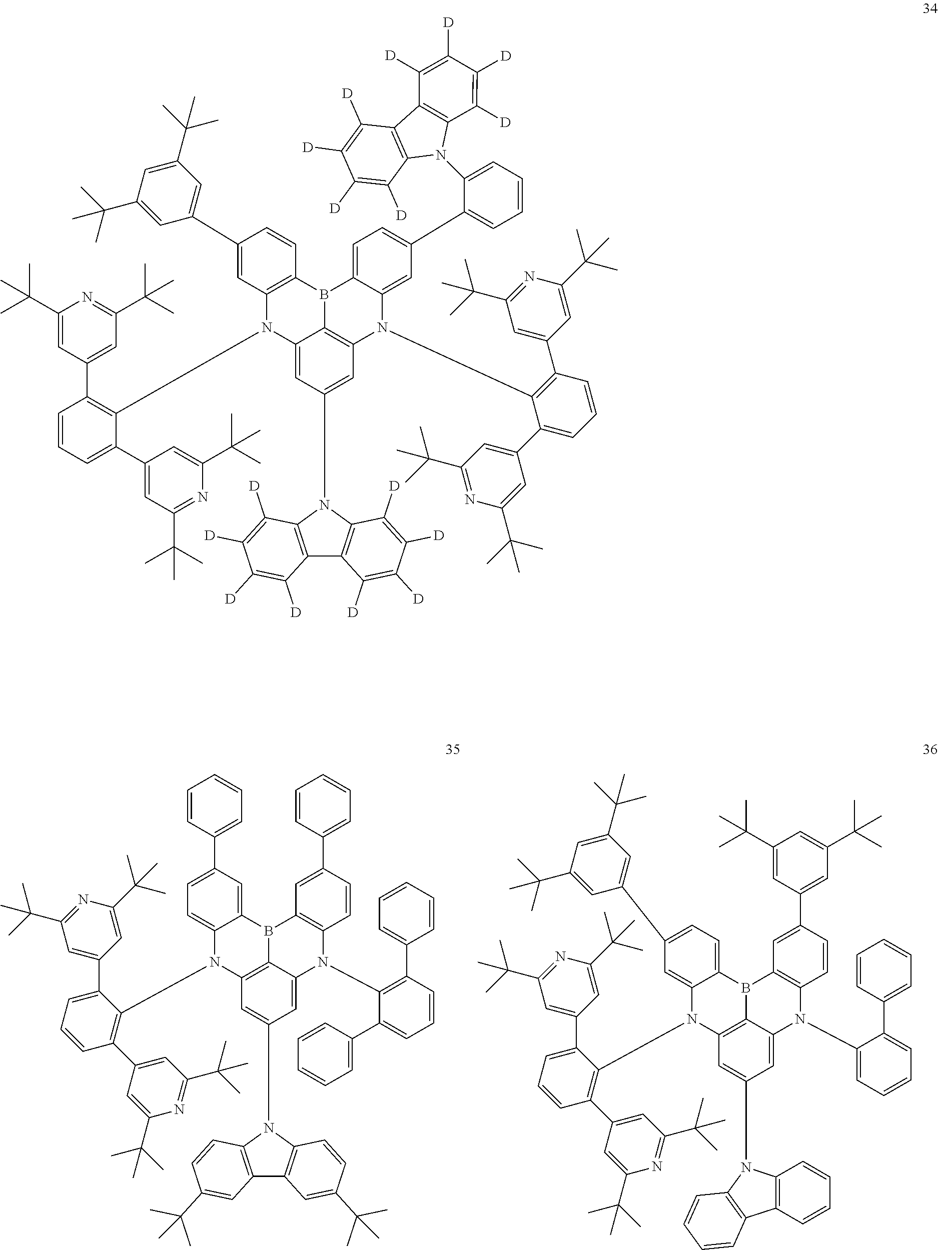 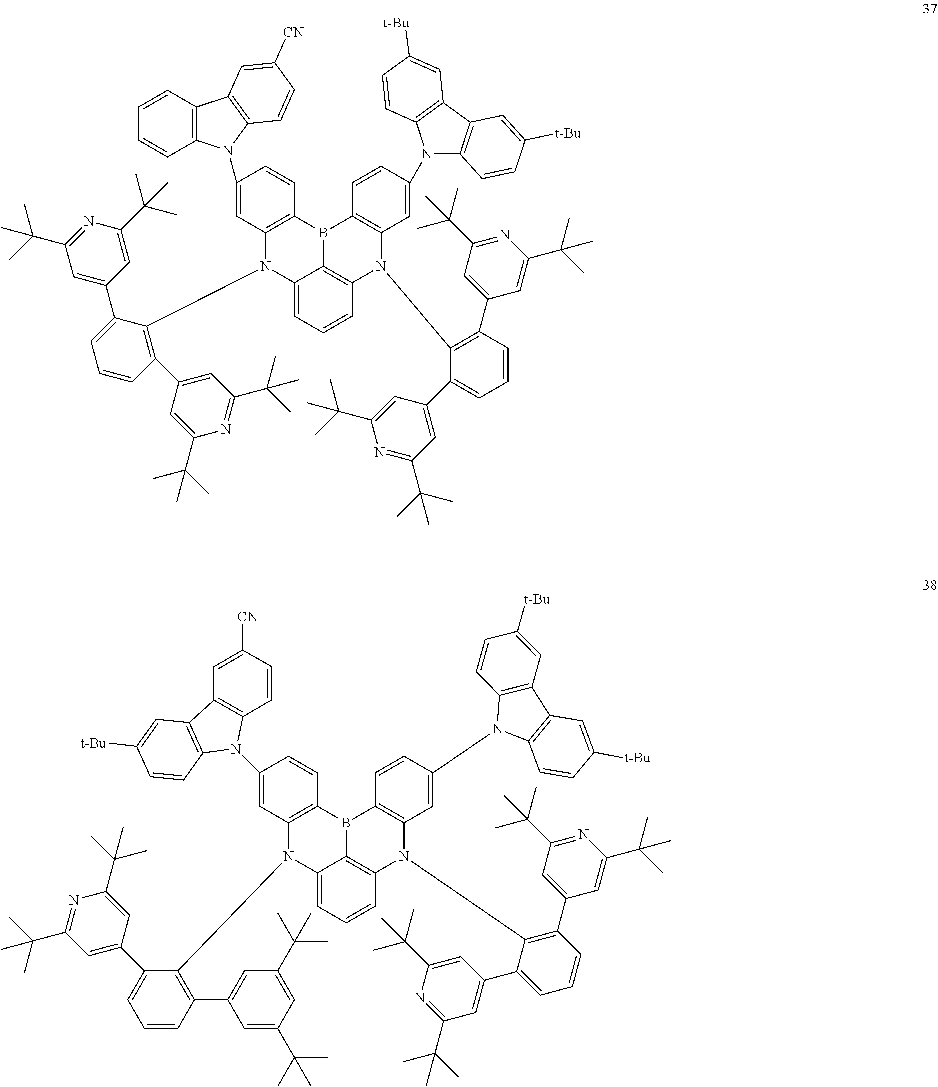 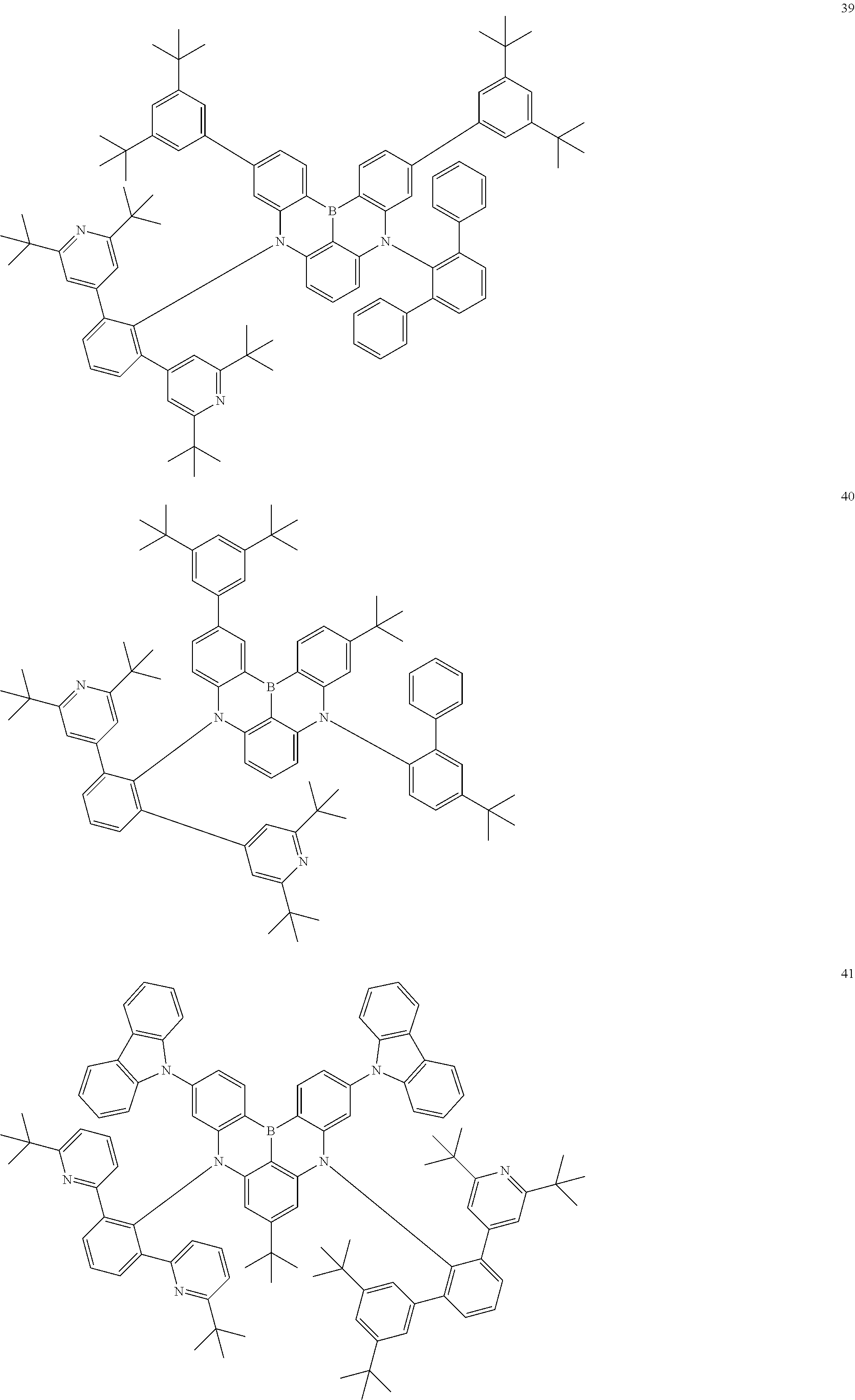 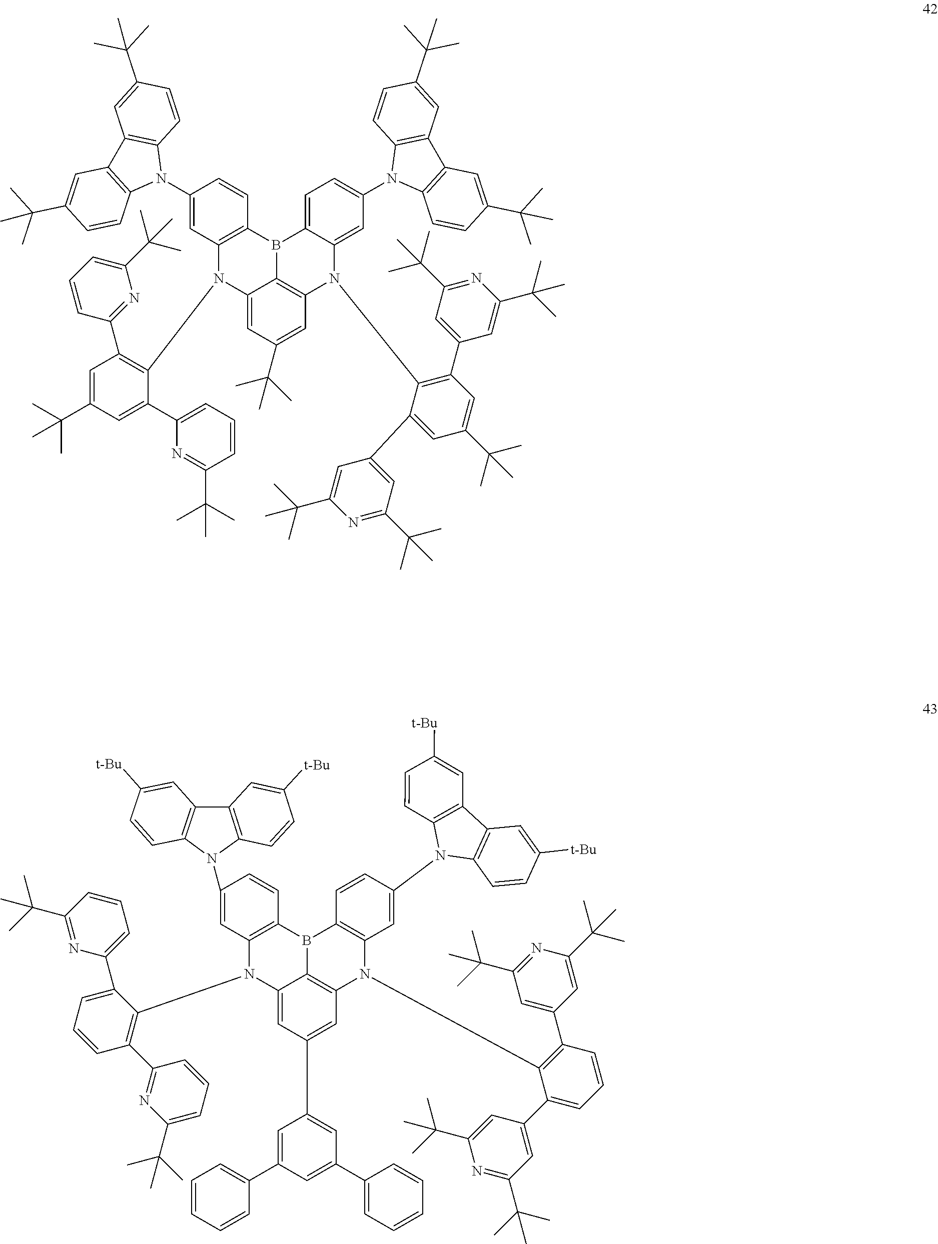 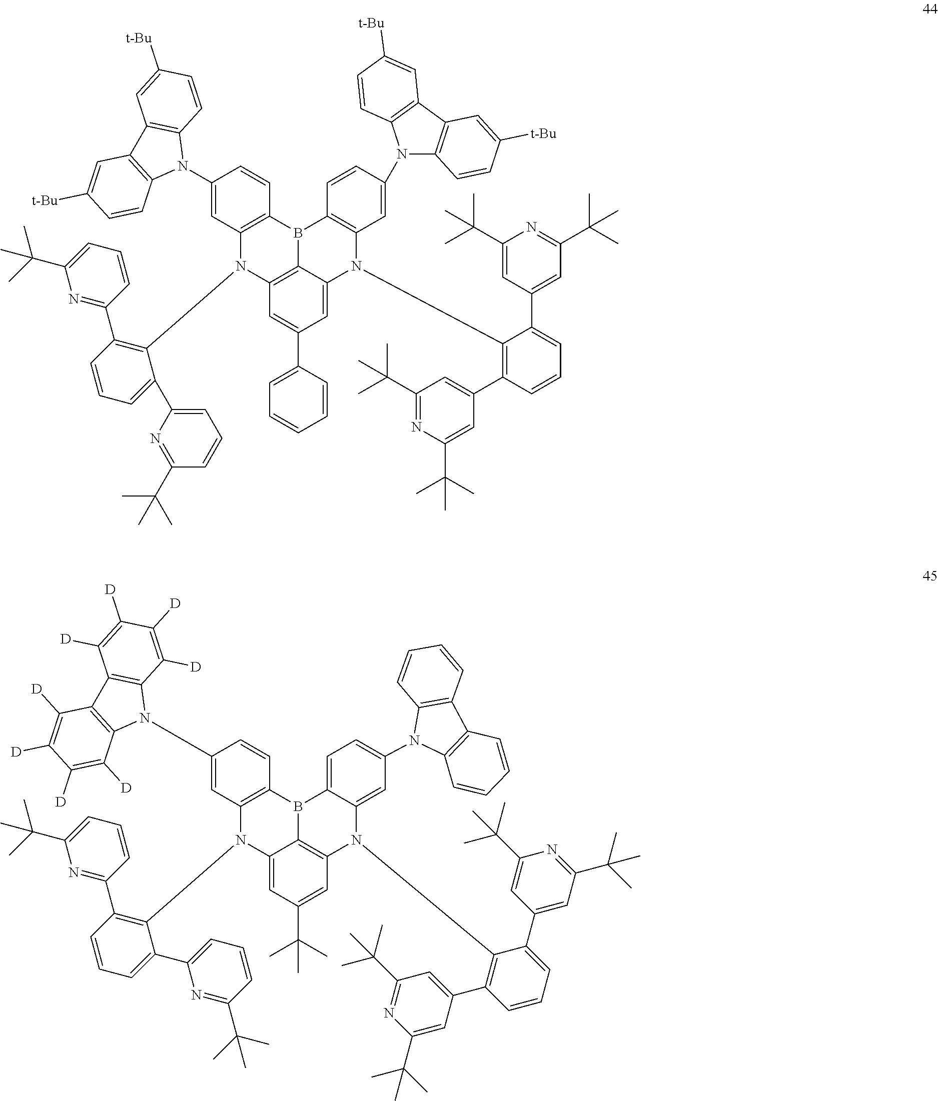 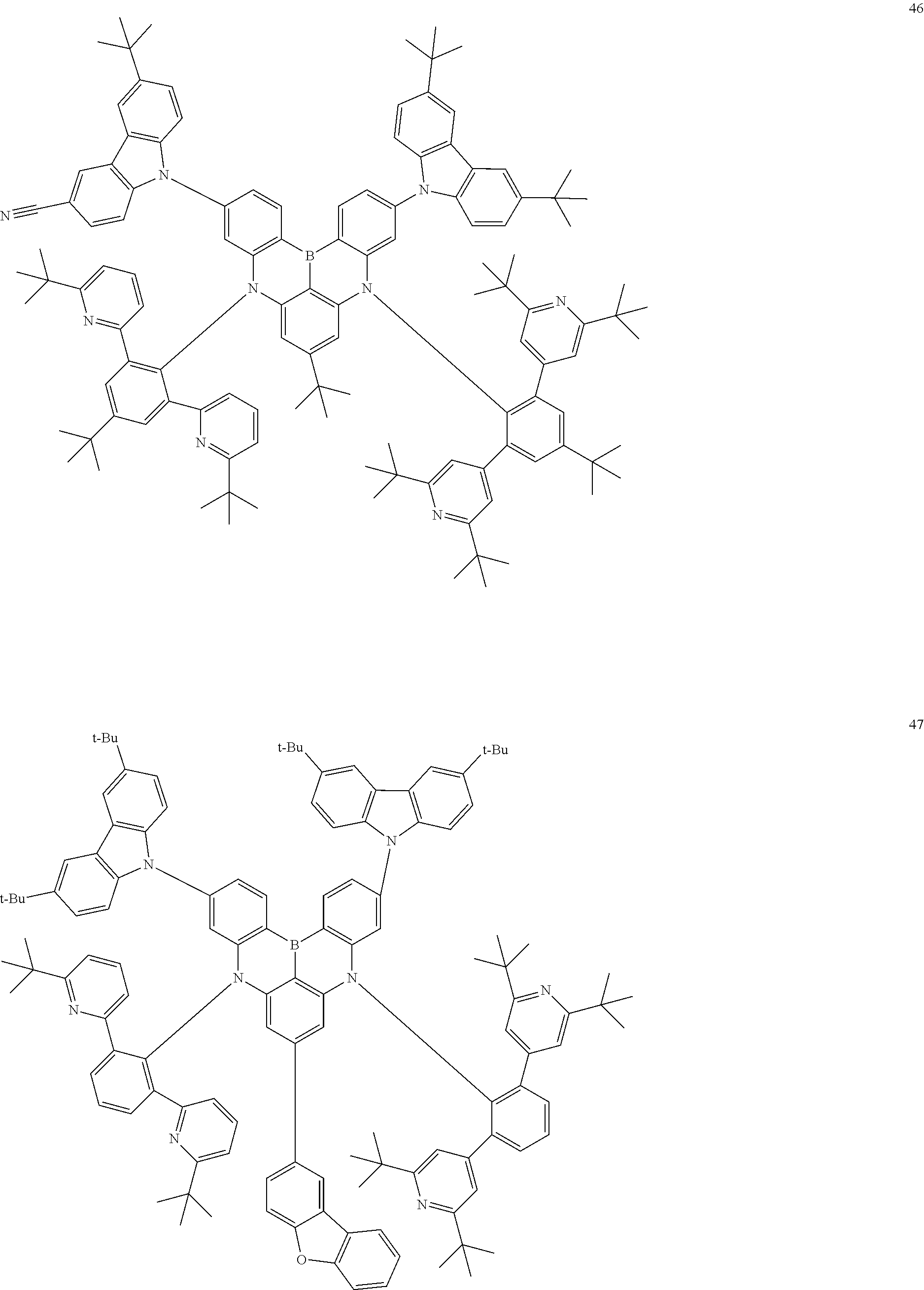 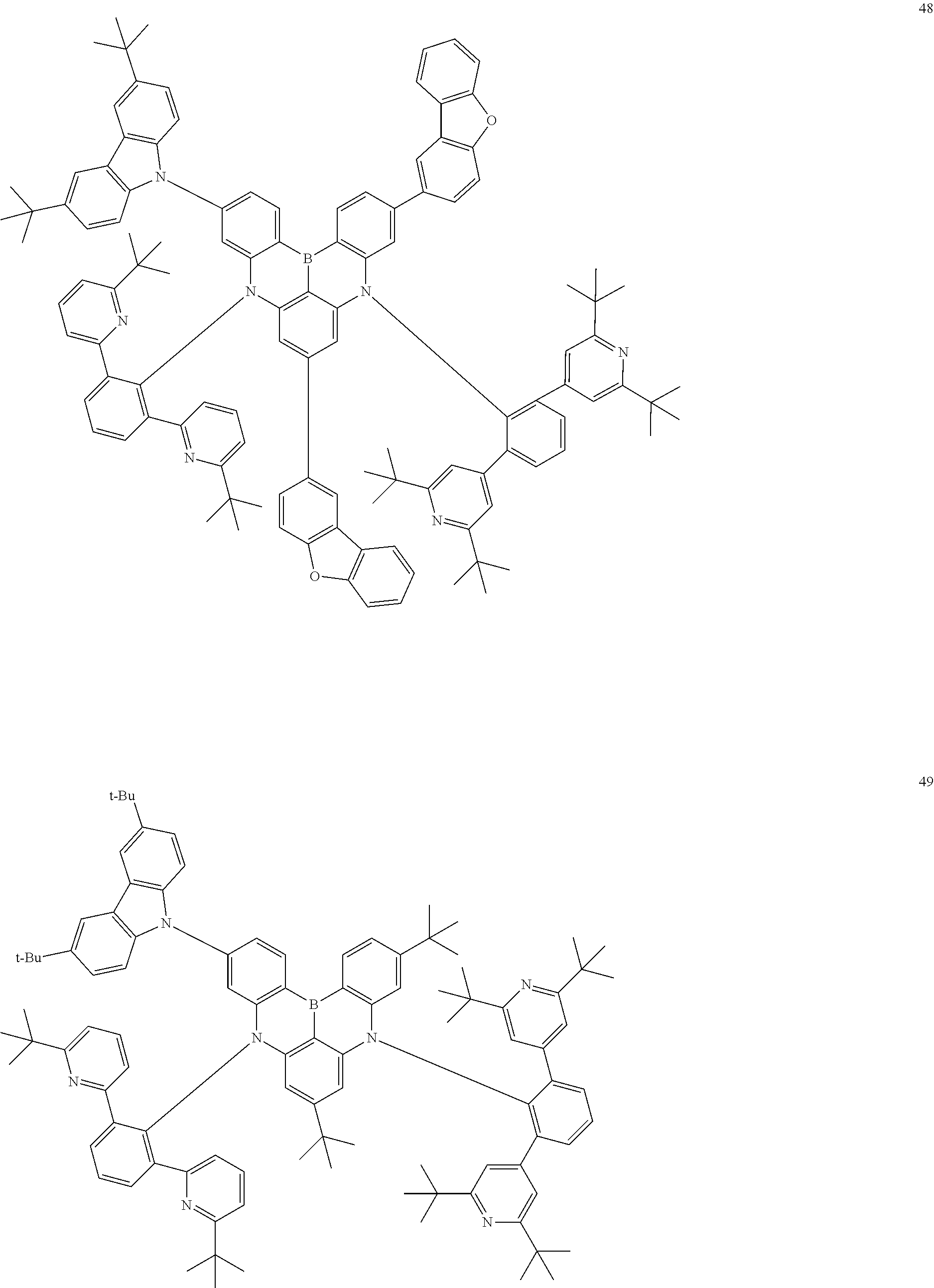 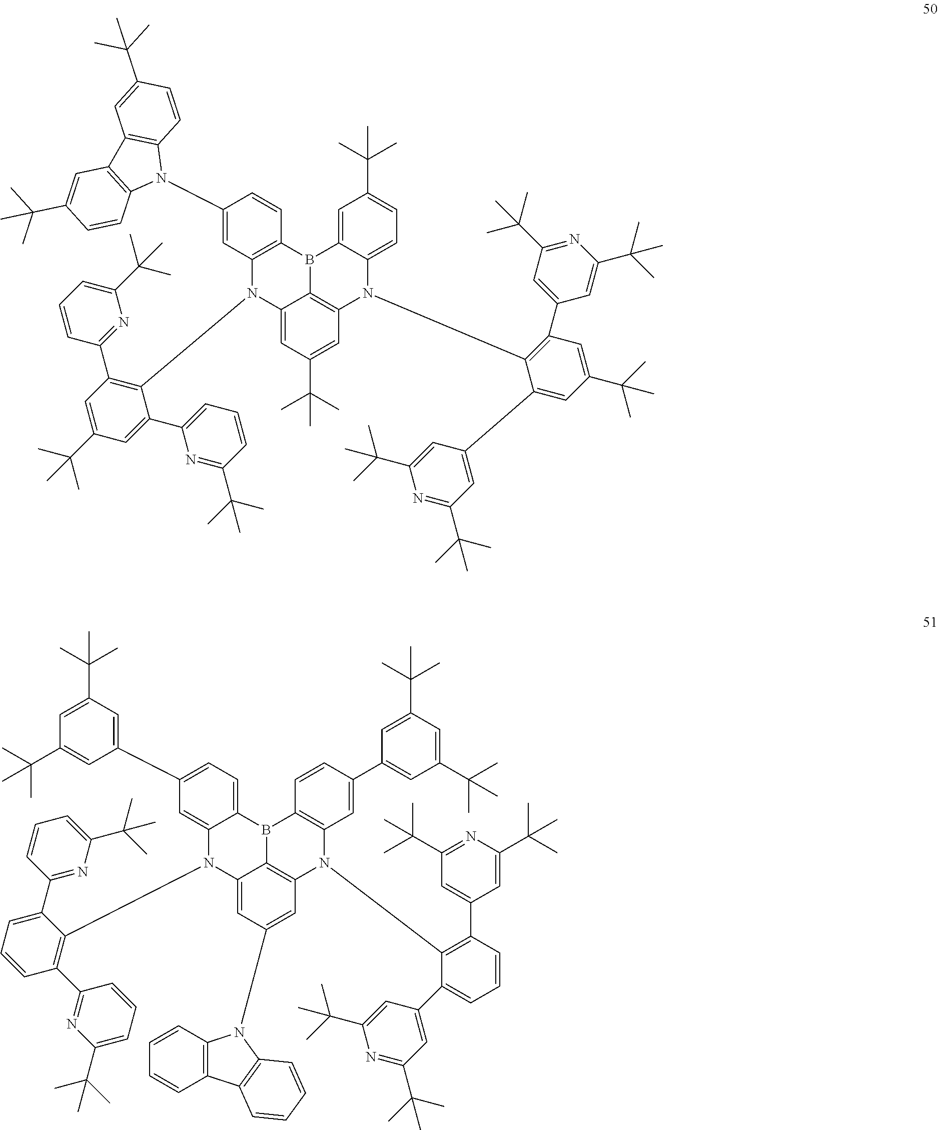 [SMILES: CC(C)(C)c1ccc2c(c1)B1c3ccc(-n4c5ccc(C(C)(C)C)cc5c5cc(C(C)(C)C)ccc54)cc3N(c3c(-c4cccc(C(C)(C)C)n4)cc(C(C)(C)C)cc3-c3cccc(C(C)(C)C)n3)c3cc(C(C)(C)C)cc(c31)N2c1c(-c2cc(C(C)(C)C)nc(C(C)(C)C)c2)cc(C(C)(C)C)cc1-c1cc(C(C)(C)C)nc(C(C)(C)C)c1 ; CC(C)(C)c1cc(-c2ccc3c(c2)N(c2c(-c4cc(C(C)(C)C)nc(C(C)(C)C)c4)cccc2-c2cc(C(C)(C)C)nc(C(C)(C)C)c2)c2cc(-n4c5ccccc5c5ccccc54)cc4c2B3c2ccc(-c3cc(C(C)(C)C)cc(C(C)(C)C)c3)cc2N4c2c(-c3cccc(C(C)(C)C)n3)cccc2-c2cccc(C(C)(C)C)n2)cc(C(C)(C)C)c1] 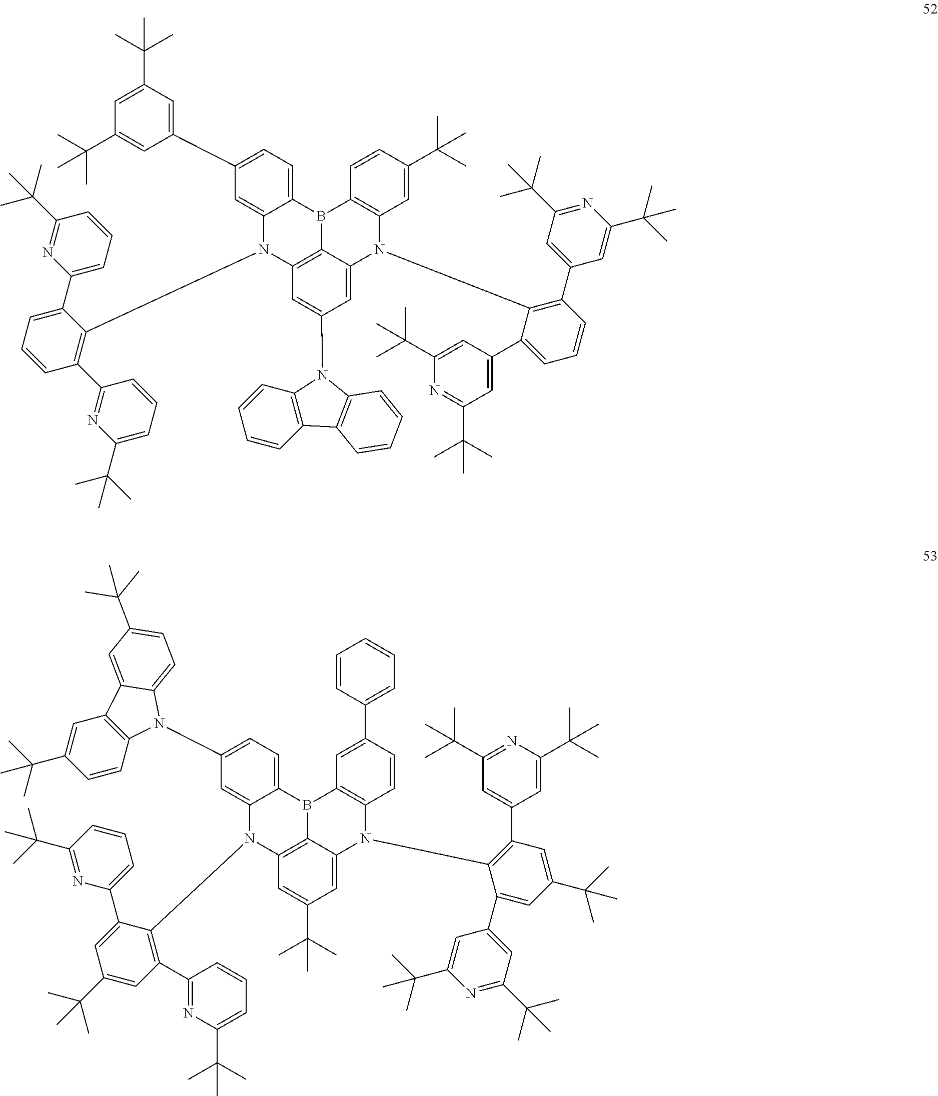 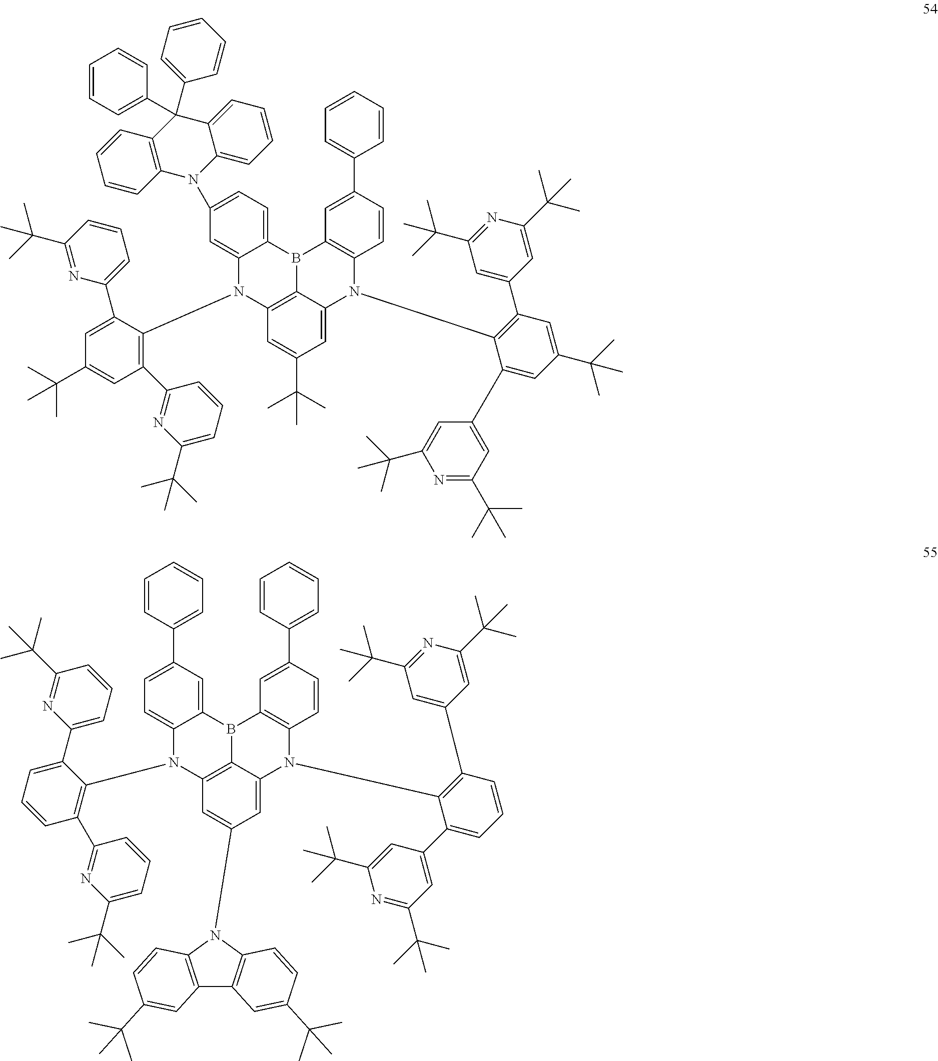 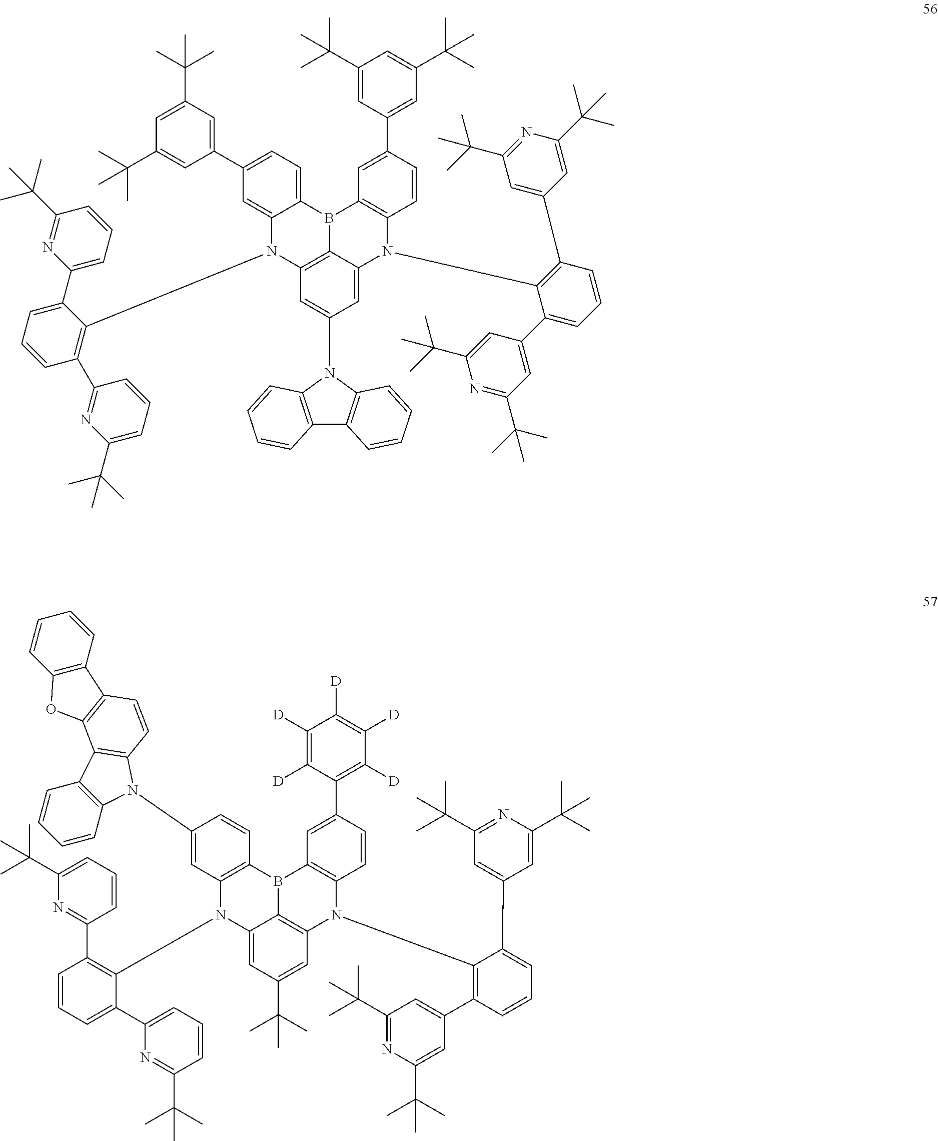 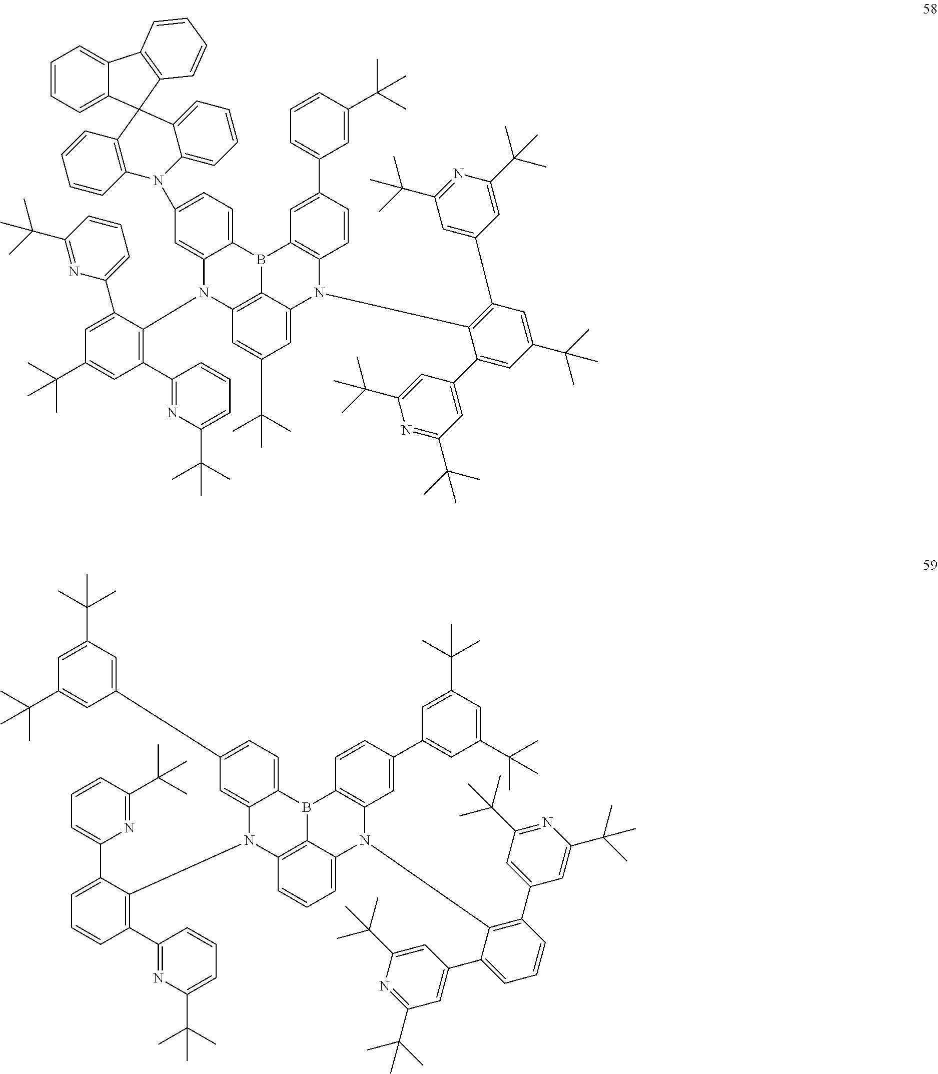 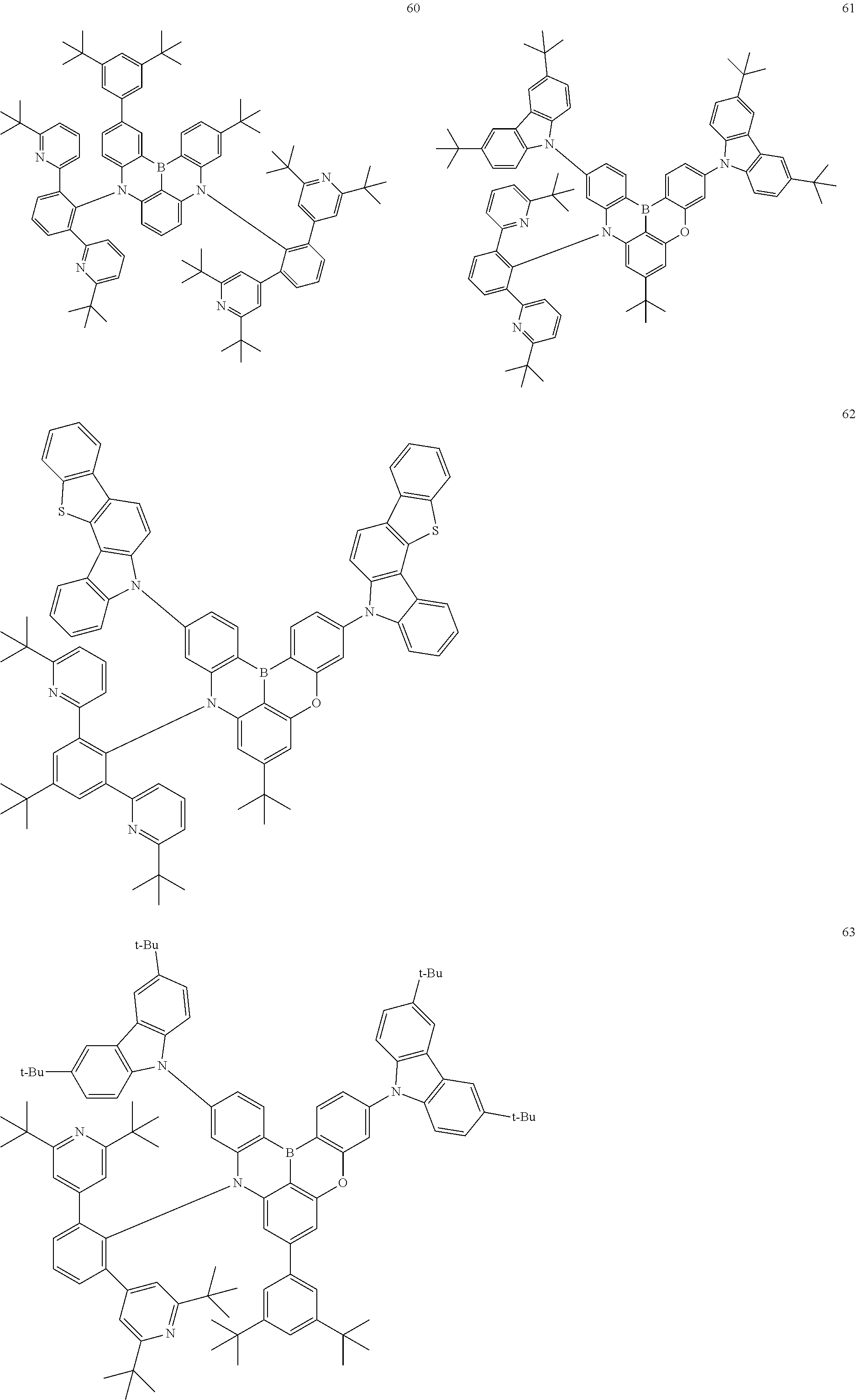 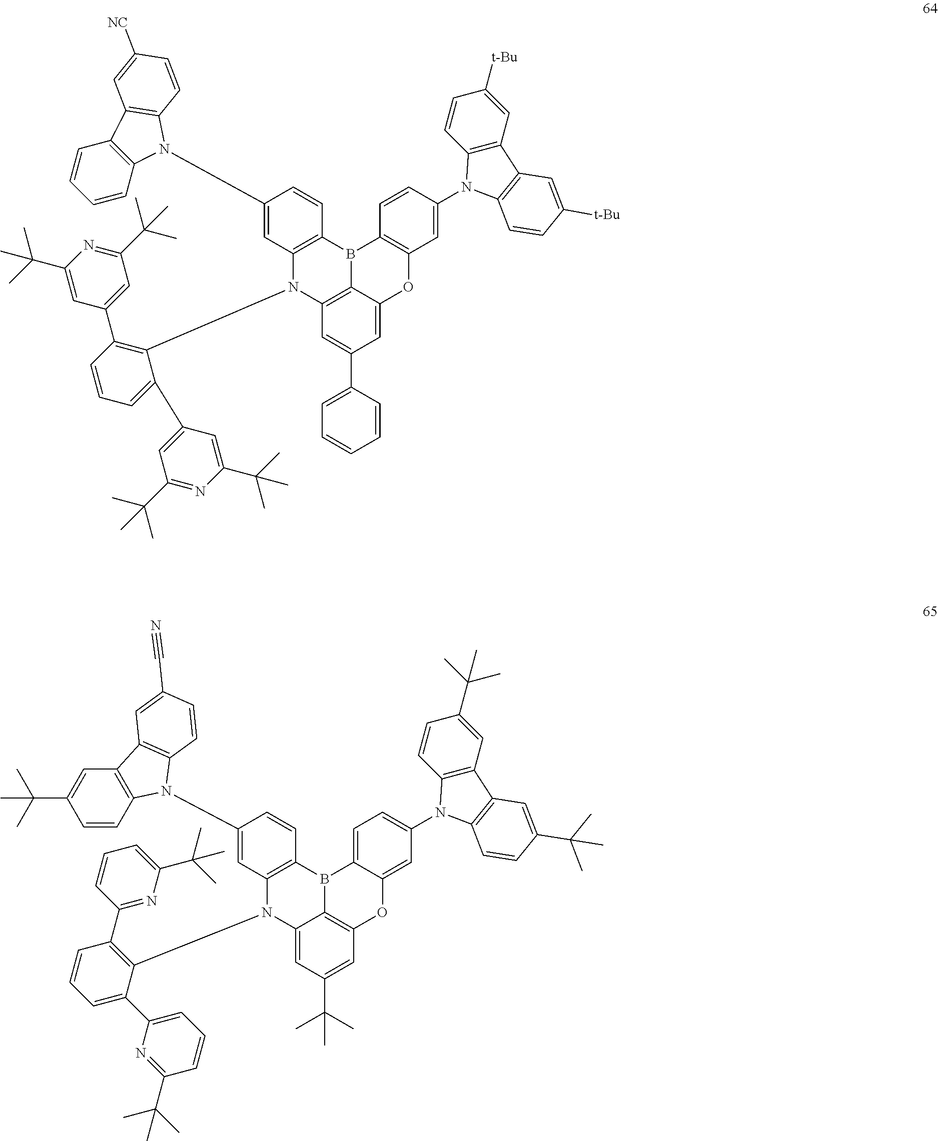 [SMILES: CC(C)(C)c1ccc2c(c1)c1cc(C(C)(C)C)ccc1n2-c1ccc2c(c1)Oc1cc(-c3ccccc3)cc3c1B2c1ccc(-n2c4ccccc4c4cc(C#N)ccc42)cc1N3c1c(-c2cc(C(C)(C)C)nc(C(C)(C)C)c2)cccc1-c1cc(C(C)(C)C)nc(C(C)(C)C)c1 ; CC(C)(C)c1cc2c3c(c1)N(c1c(-c4cccc(C(C)(C)C)n4)cccc1-c1cccc(C(C)(C)C)n1)c1cc(-n4c5ccc(C#N)cc5c5cc(C(C)(C)C)ccc54)ccc1B3c1ccc(-n3c4ccc(C(C)(C)C)cc4c4cc(C(C)(C)C)ccc43)cc1O2] 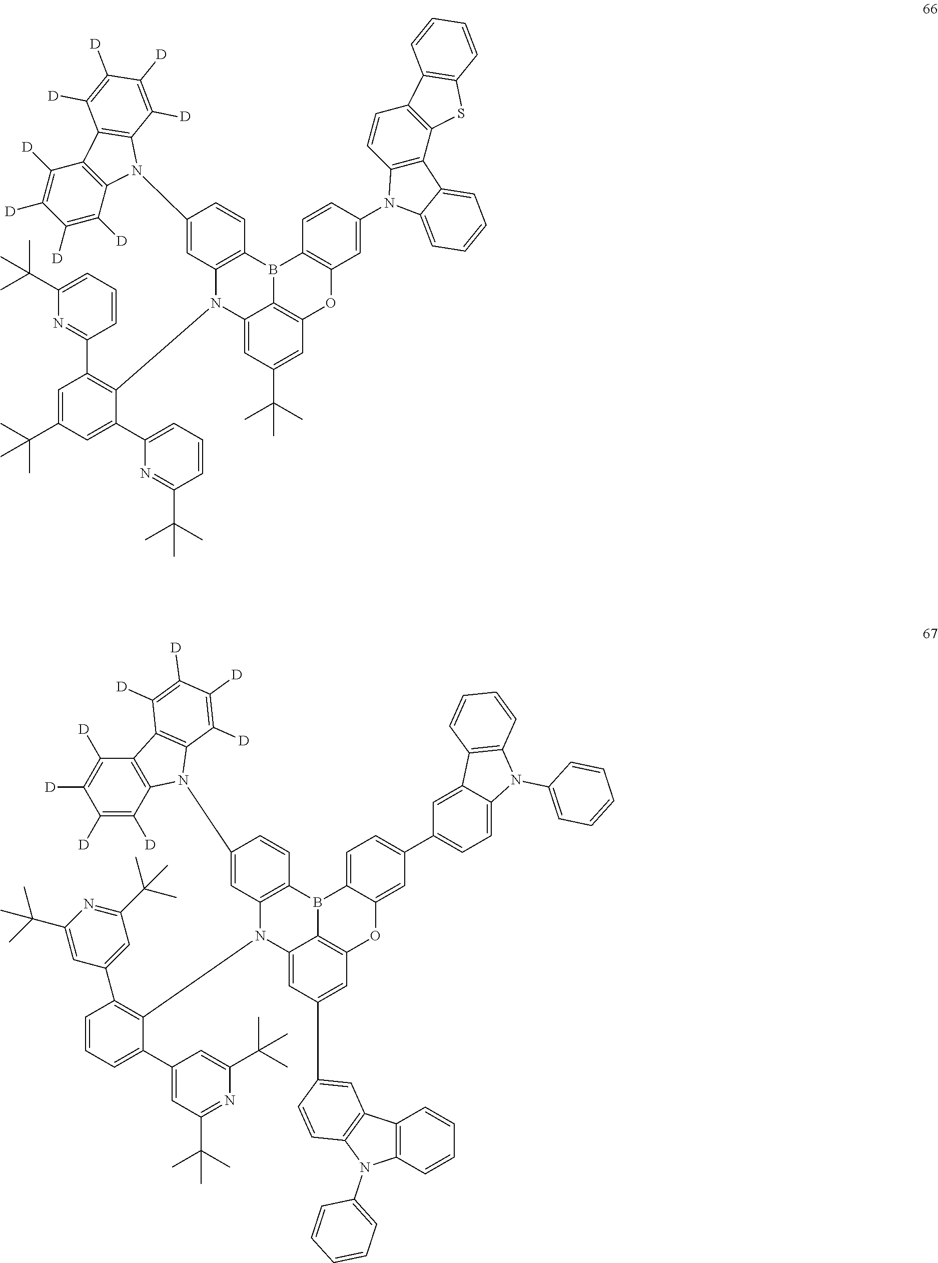 [SMILES: [2H]c1c([2H])c([2H])c2c(c1[2H])c1c([2H])c([2H])c([2H])c([2H])c1n2-c1ccc2c(c1)N(c1c(-c3cccc(C(C)(C)C)n3)cc(C(C)(C)C)cc1-c1cccc(C(C)(C)C)n1)c1cc(C(C)(C)C)cc3c1B2c1ccc(-n2c4ccccc4c4c5sc6ccccc6c5ccc42)cc1O3 ; [2H]c1c([2H])c([2H])c2c(c1[2H])c1c([2H])c([2H])c([2H])c([2H])c1n2-c1ccc2c(c1)N(c1c(-c3cc(C(C)(C)C)nc(C(C)(C)C)c3)cccc1-c1cc(C(C)(C)C)nc(C(C)(C)C)c1)c1cc(-c3ccc4c(c3)c3ccccc3n4-c3ccccc3)cc3c1B2c1ccc(-c2ccc4c(c2)c2ccccc2n4-c2ccccc2)cc1O3] 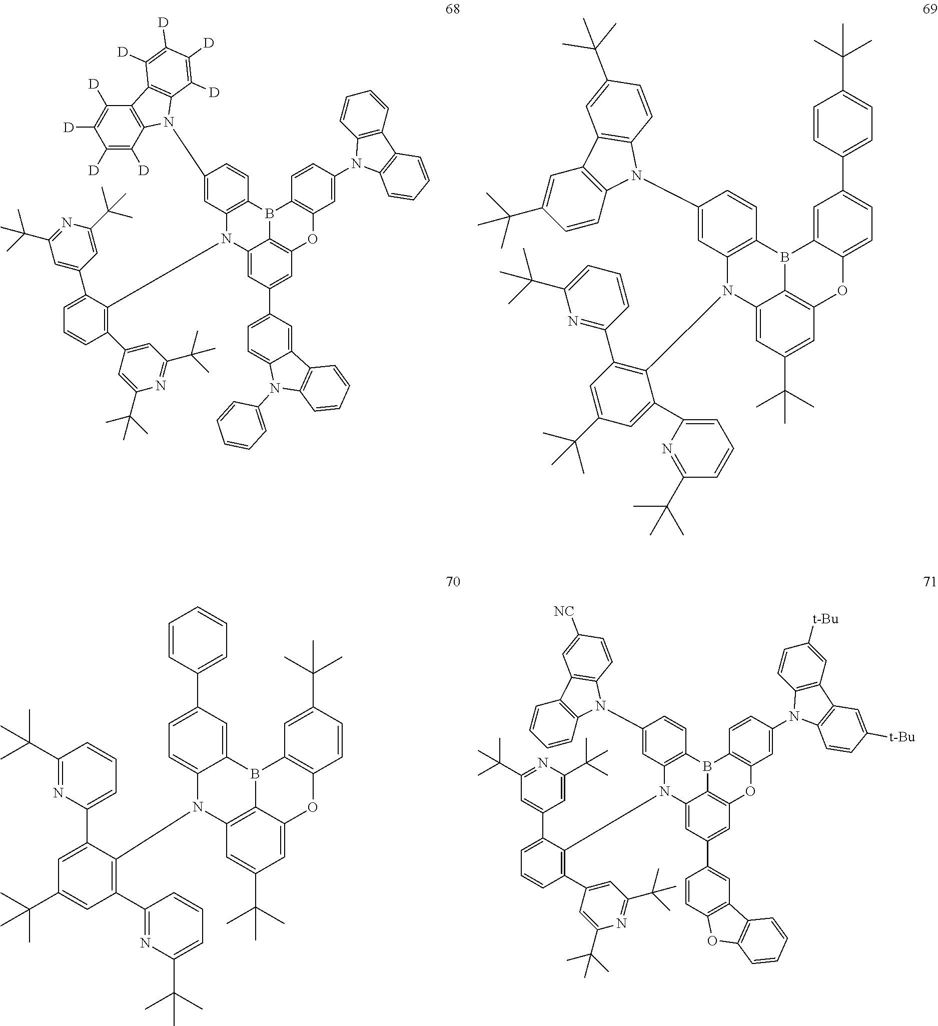 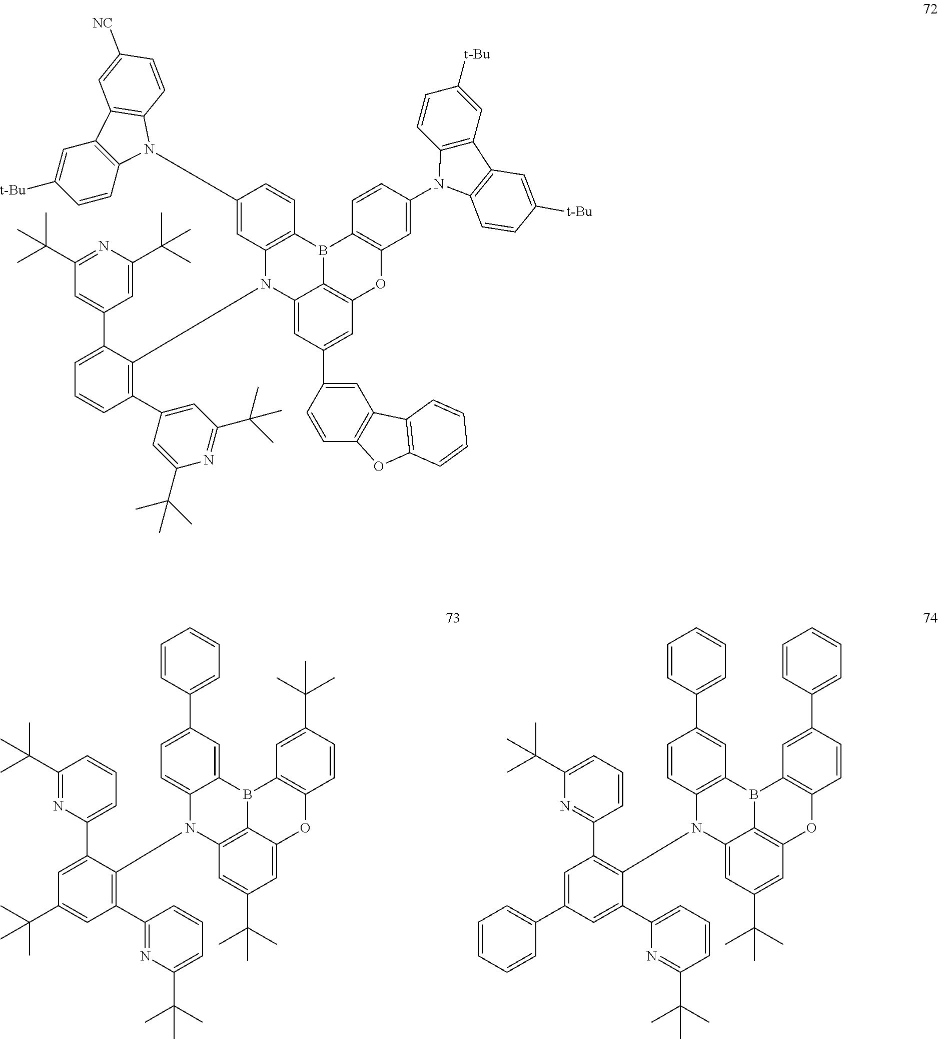 [SMILES: CC(C)(C)c1ccc2c(c1)c1cc(C#N)ccc1n2-c1ccc2c(c1)N(c1c(-c3cc(C(C)(C)C)nc(C(C)(C)C)c3)cccc1-c1cc(C(C)(C)C)nc(C(C)(C)C)c1)c1cc(-c3ccc4oc5ccccc5c4c3)cc3c1B2c1ccc(-n2c4ccc(C(C)(C)C)cc4c4cc(C(C)(C)C)ccc42)cc1O3 ; CC(C)(C)c1ccc2c(c1)B1c3cc(-c4ccccc4)ccc3N(c3c(-c4cccc(C(C)(C)C)n4)cc(C(C)(C)C)cc3-c3cccc(C(C)(C)C)n3)c3cc(C(C)(C)C)cc(c31)O2 ; CC(C)(C)c1cc2c3c(c1)N(c1c(-c4cccc(C(C)(C)C)n4)cc(-c4ccccc4)cc1-c1cccc(C(C)(C)C)n1)c1ccc(-c4ccccc4)cc1B3c1cc(-c3ccccc3)ccc1O2] 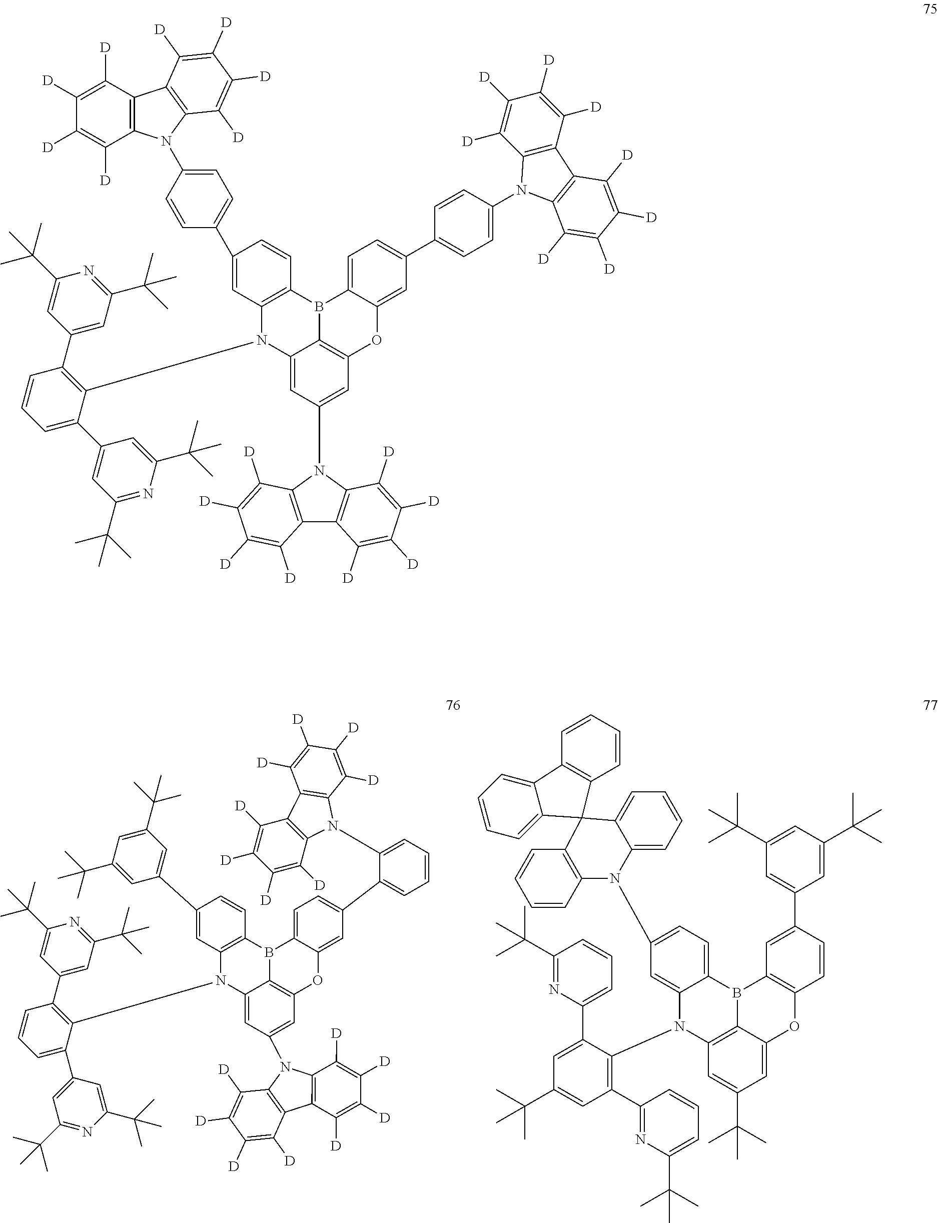 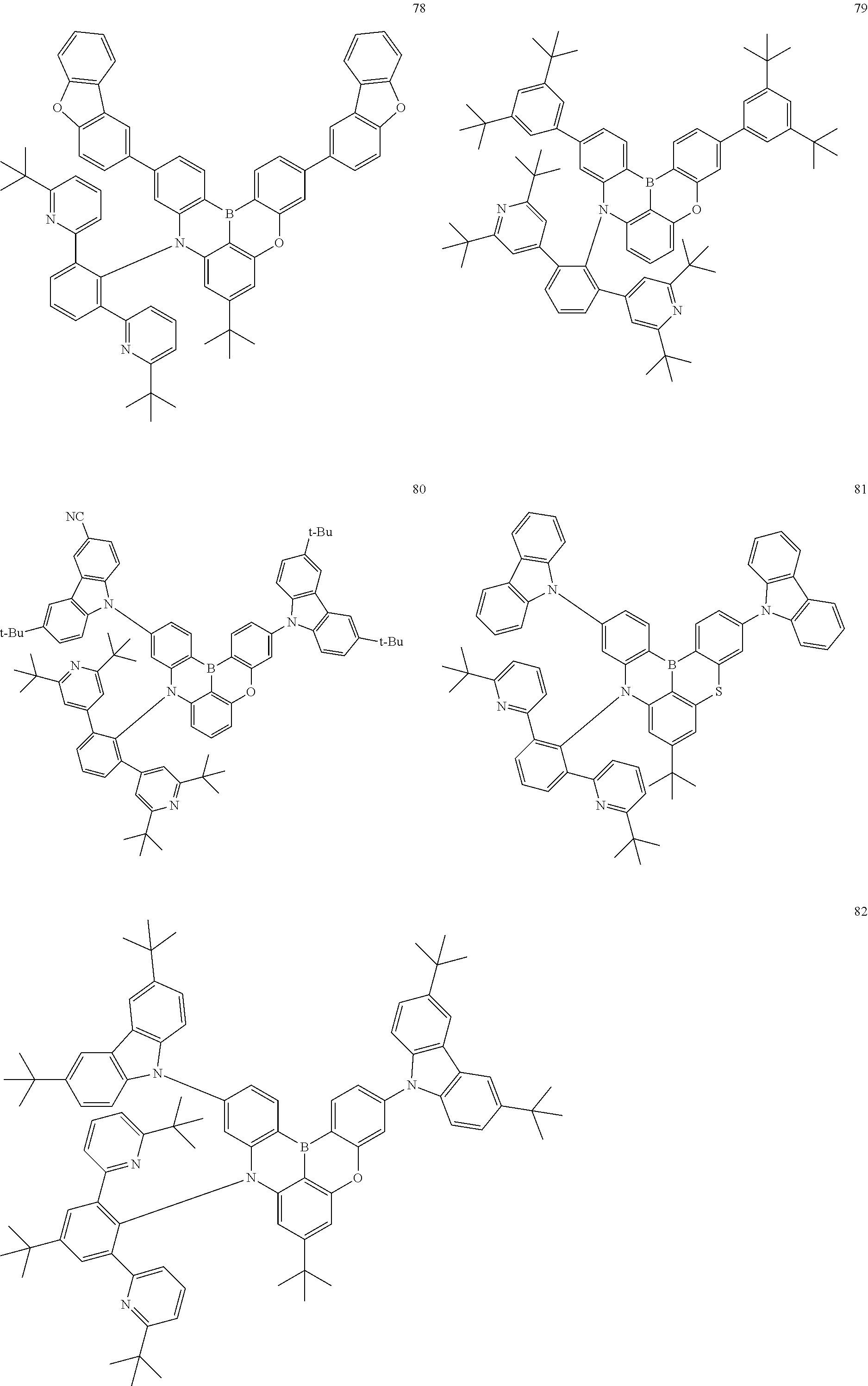 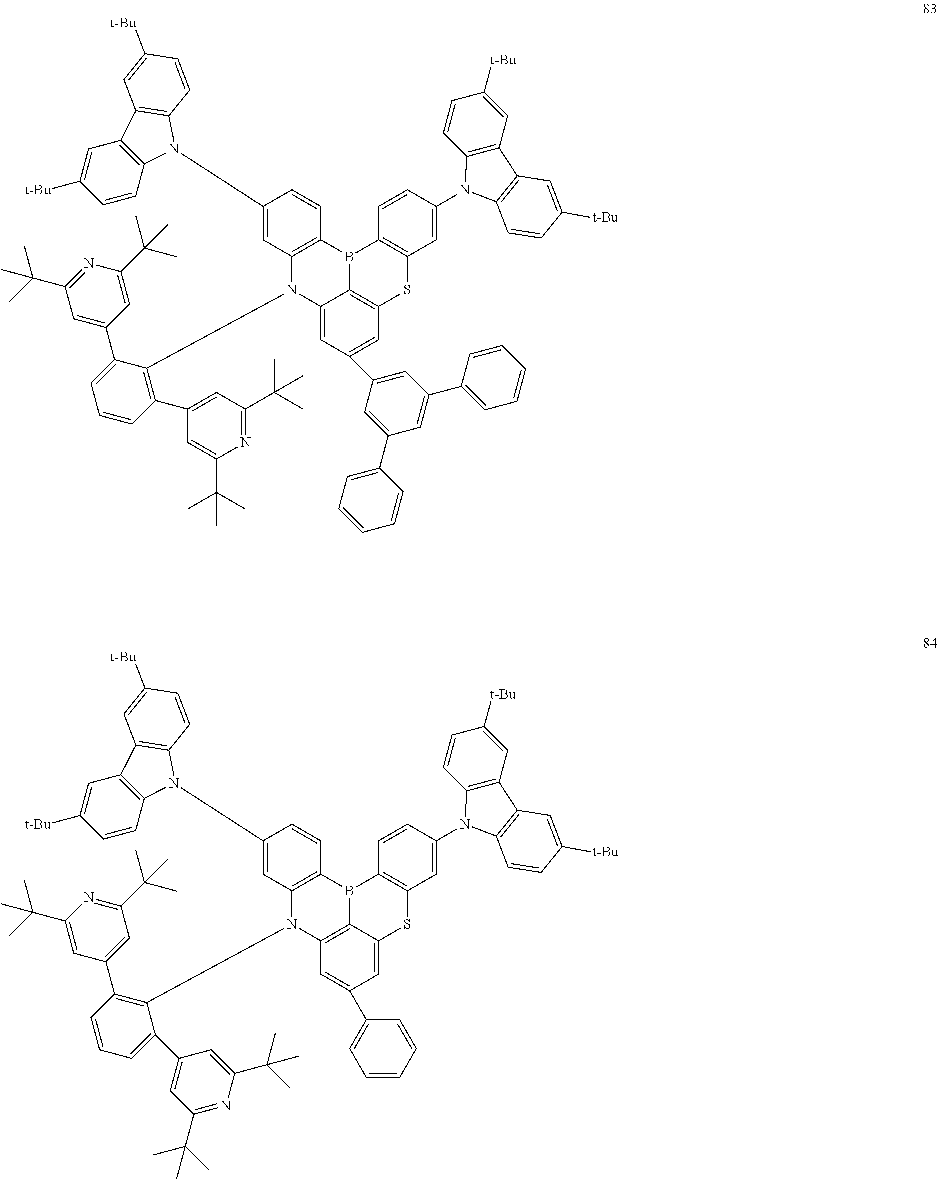 [SMILES: CC(C)(C)c1ccc2c(c1)c1cc(C(C)(C)C)ccc1n2-c1ccc2c(c1)Sc1cc(-c3cc(-c4ccccc4)cc(-c4ccccc4)c3)cc3c1B2c1ccc(-n2c4ccc(C(C)(C)C)cc4c4cc(C(C)(C)C)ccc42)cc1N3c1c(-c2cc(C(C)(C)C)nc(C(C)(C)C)c2)cccc1-c1cc(C(C)(C)C)nc(C(C)(C)C)c1 ; CC(C)(C)c1ccc2c(c1)c1cc(C(C)(C)C)ccc1n2-c1ccc2c(c1)Sc1cc(-c3ccccc3)cc3c1B2c1ccc(-n2c4ccc(C(C)(C)C)cc4c4cc(C(C)(C)C)ccc42)cc1N3c1c(-c2cc(C(C)(C)C)nc(C(C)(C)C)c2)cccc1-c1cc(C(C)(C)C)nc(C(C)(C)C)c1] 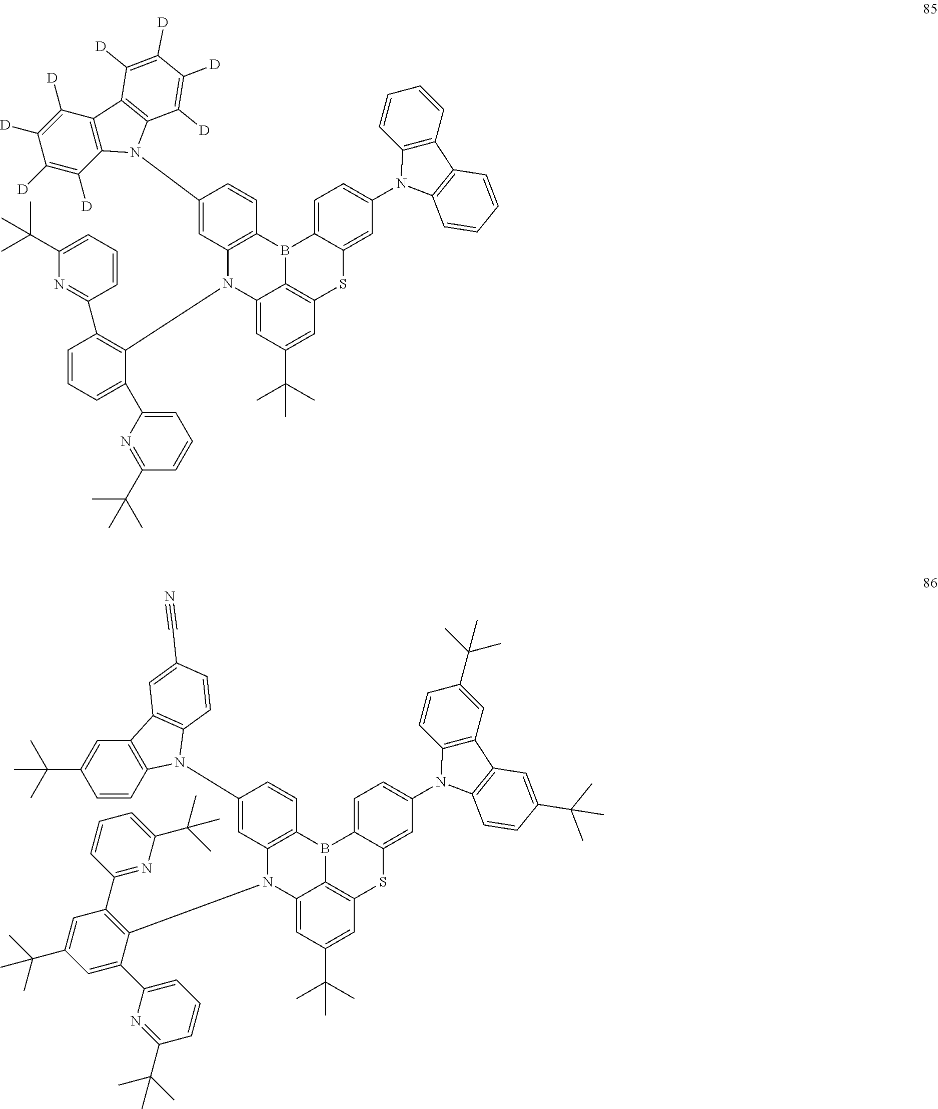 [SMILES: [2H]c1c([2H])c([2H])c2c(c1[2H])c1c([2H])c([2H])c([2H])c([2H])c1n2-c1ccc2c(c1)N(c1c(-c3cccc(C(C)(C)C)n3)cccc1-c1cccc(C(C)(C)C)n1)c1cc(C(C)(C)C)cc3c1B2c1ccc(-n2c4ccccc4c4ccccc42)cc1S3 ; CC(C)(C)c1cc(-c2cccc(C(C)(C)C)n2)c(N2c3cc(-n4c5ccc(C#N)cc5c5cc(C(C)(C)C)ccc54)ccc3B3c4ccc(-n5c6ccc(C(C)(C)C)cc6c6cc(C(C)(C)C)ccc65)cc4Sc4cc(C(C)(C)C)cc2c43)c(-c2cccc(C(C)(C)C)n2)c1] 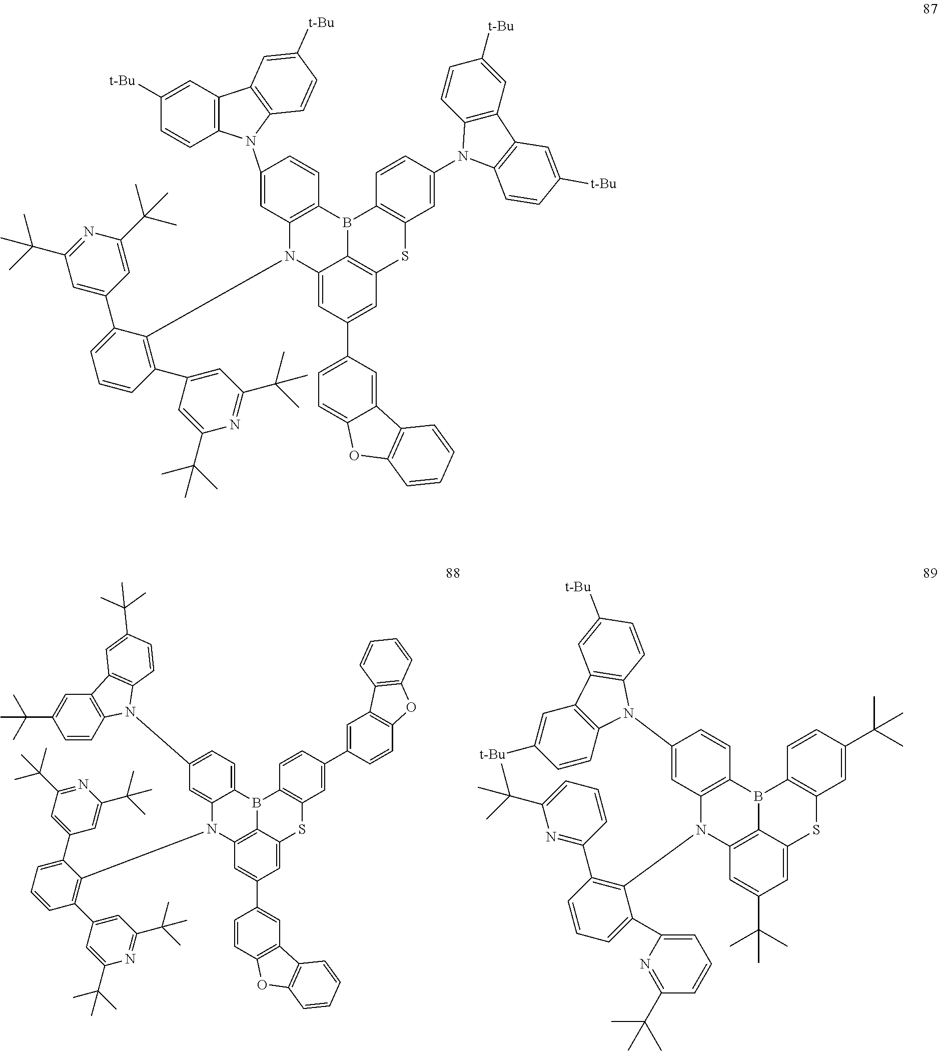 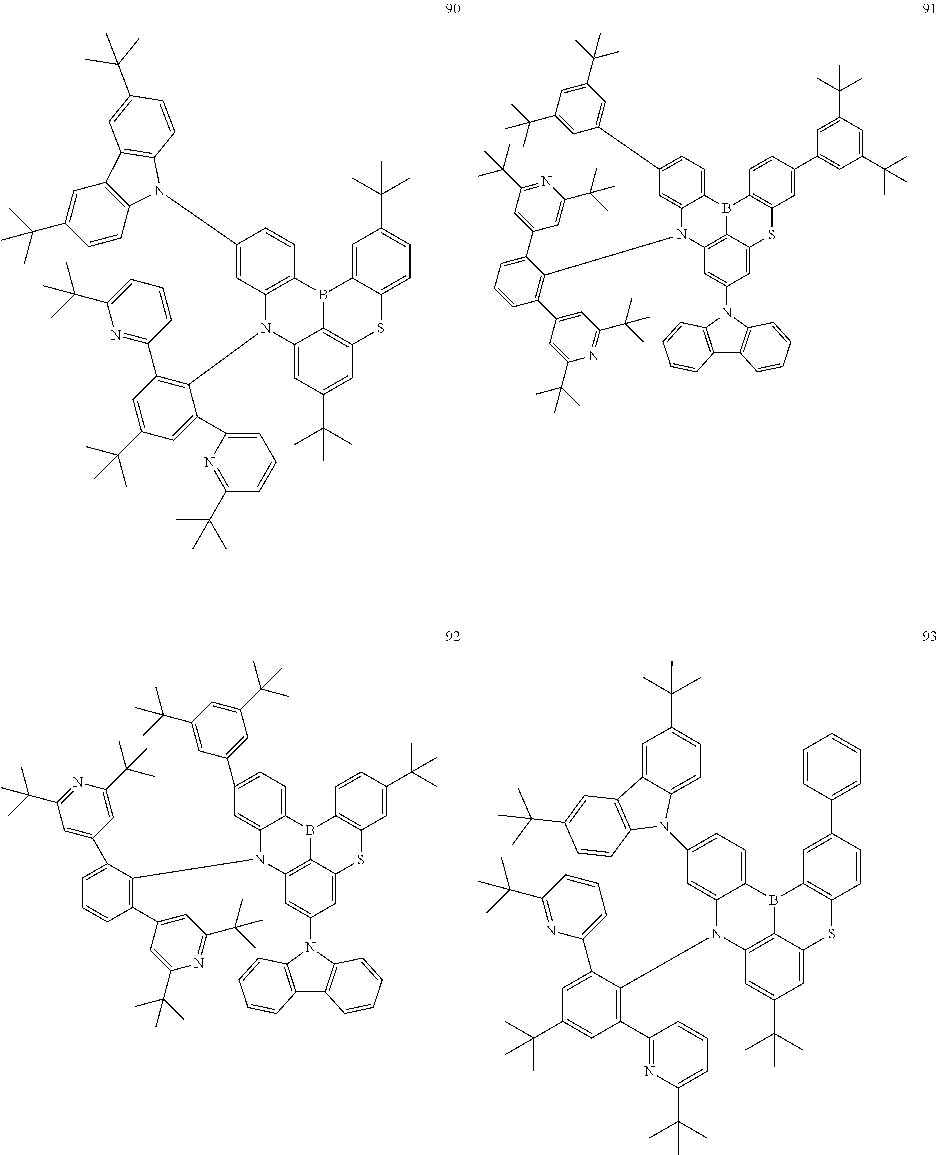 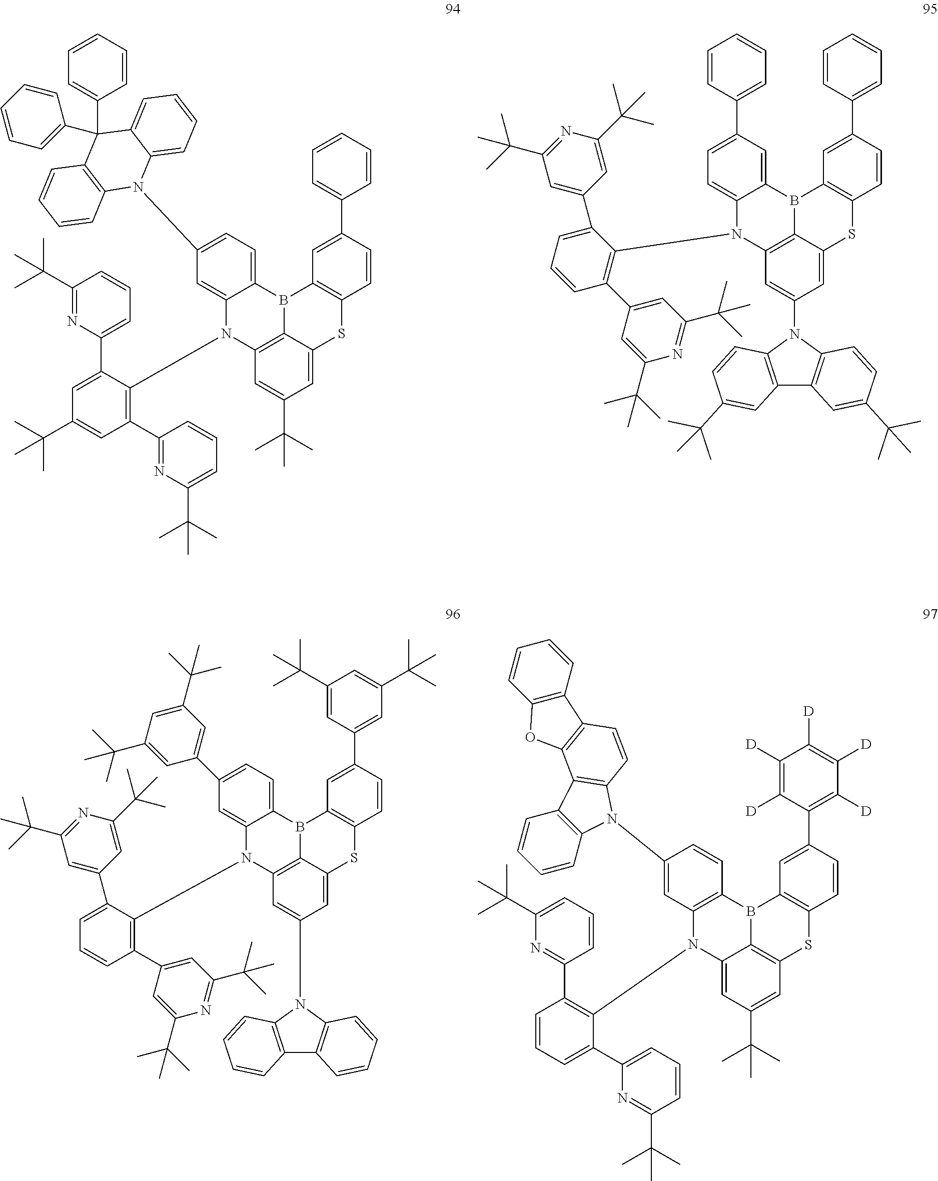 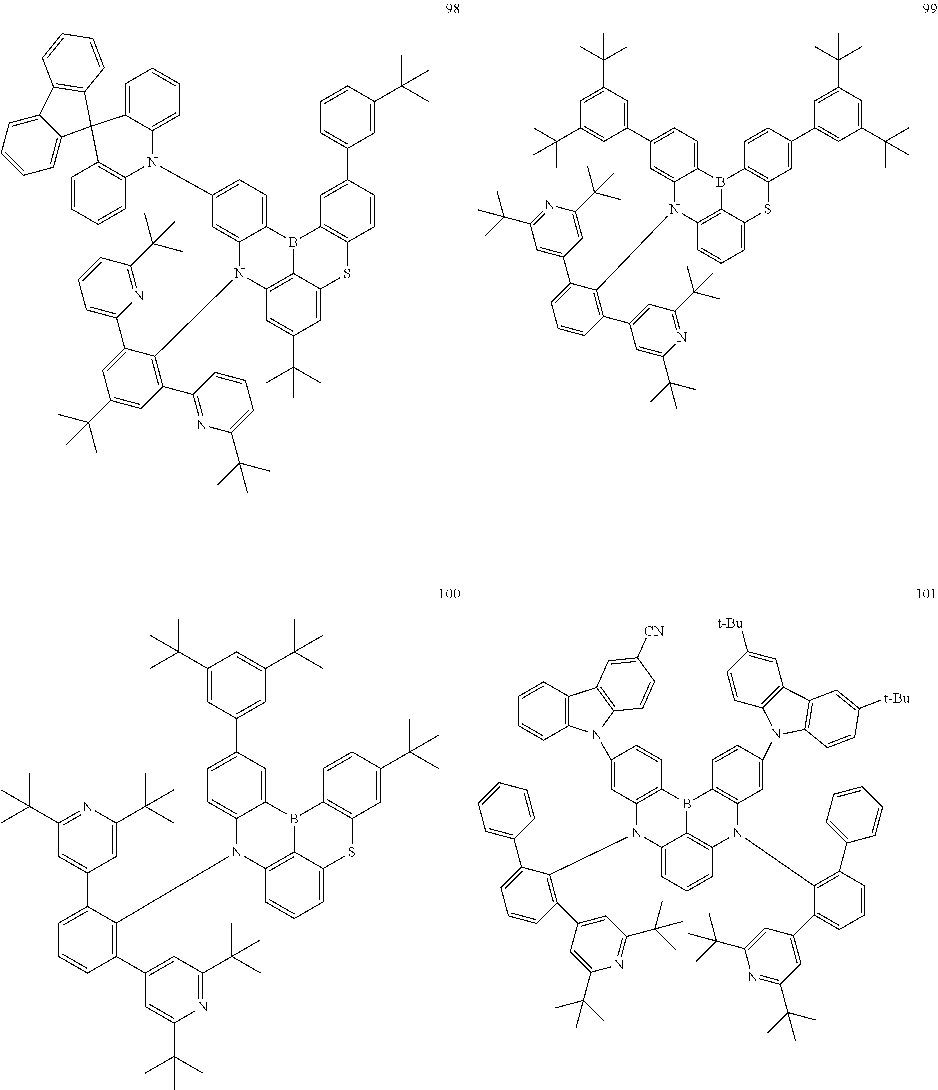 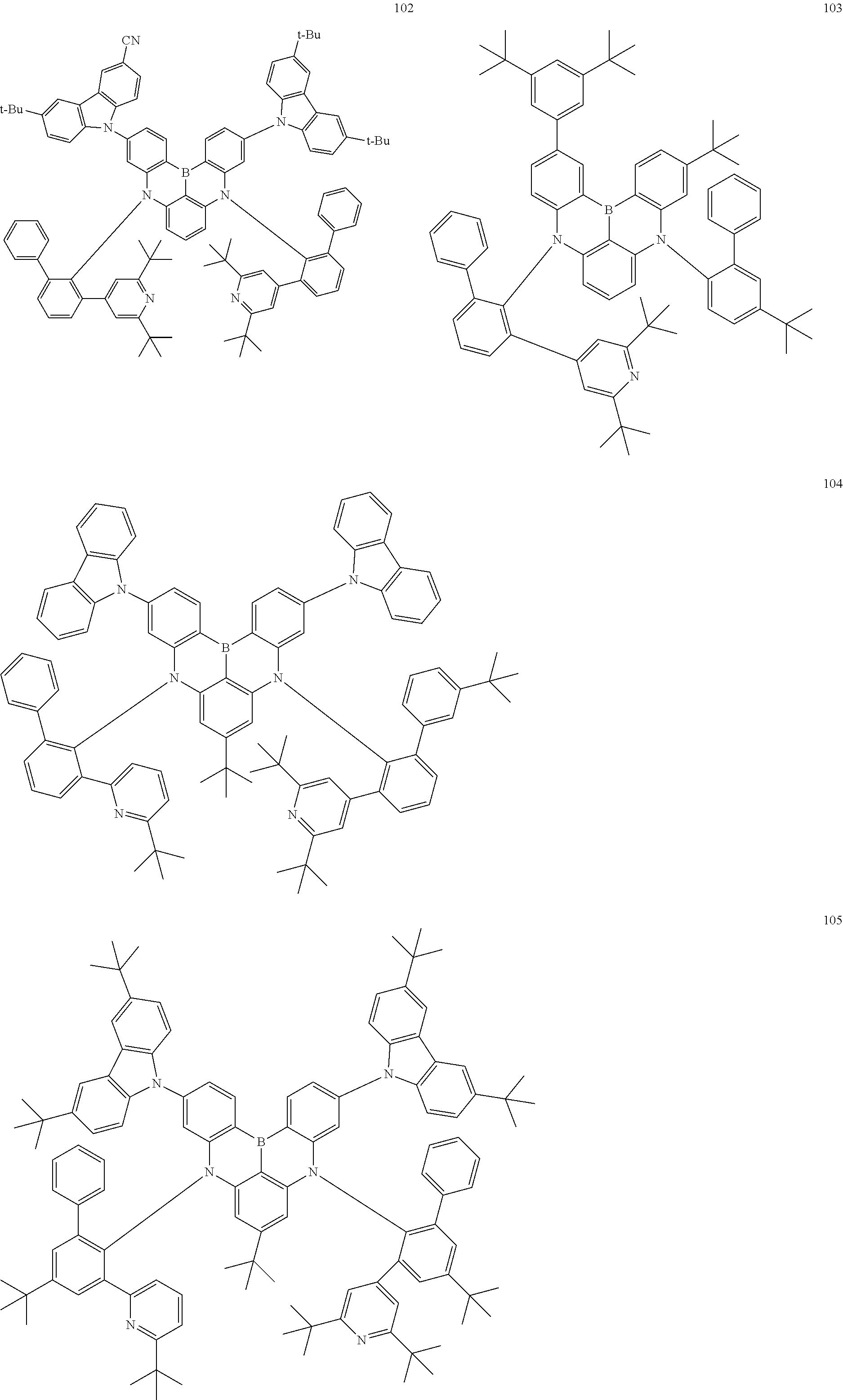 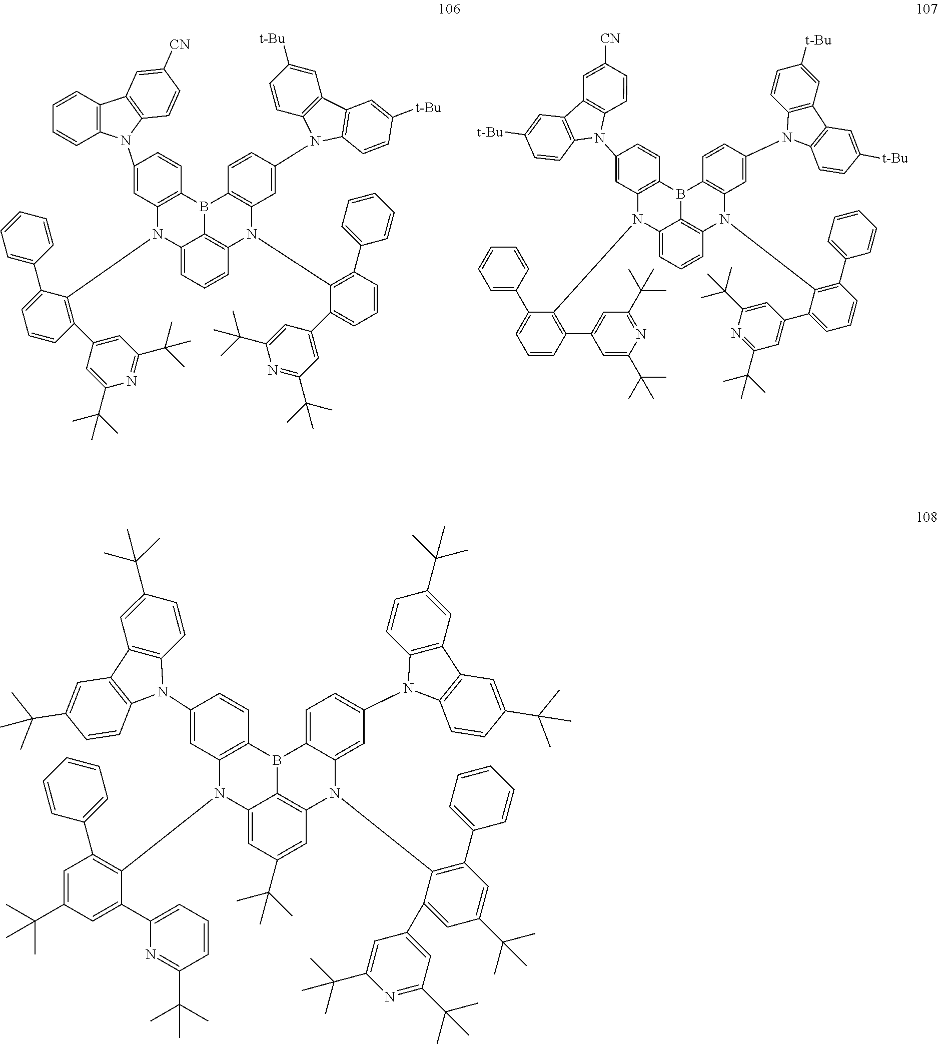 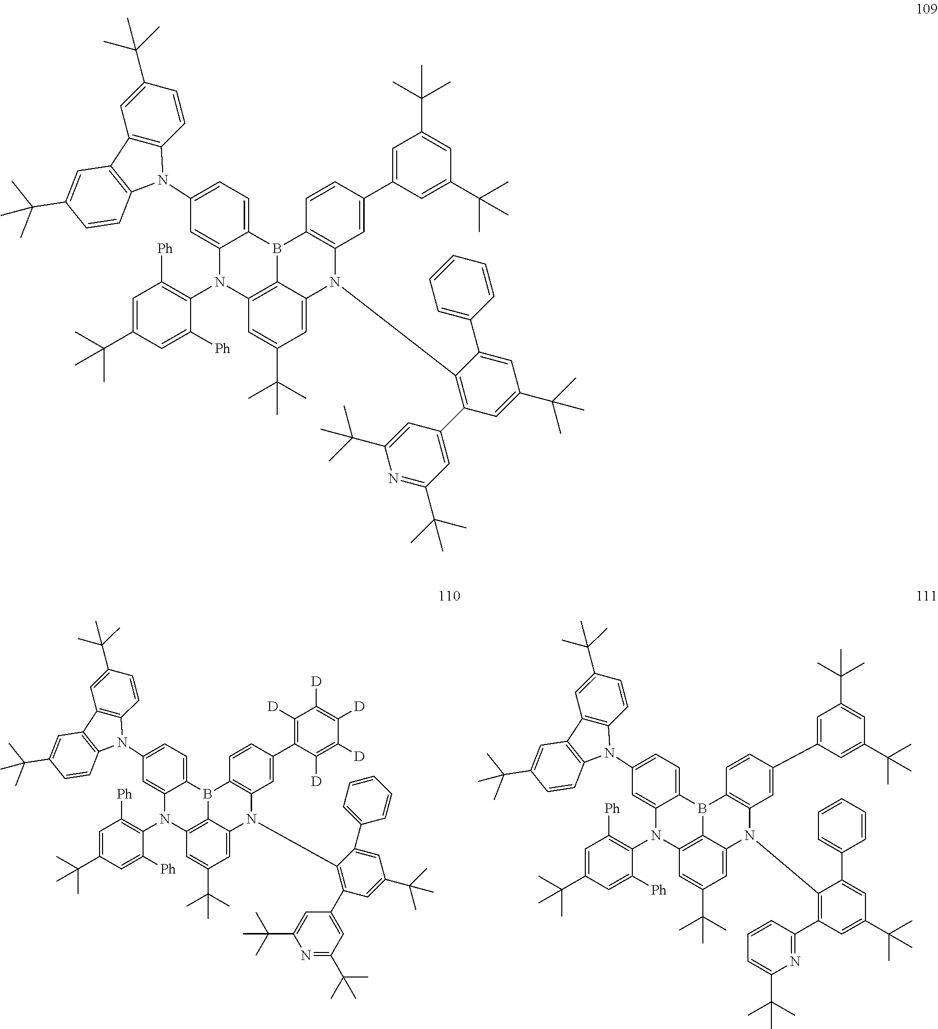 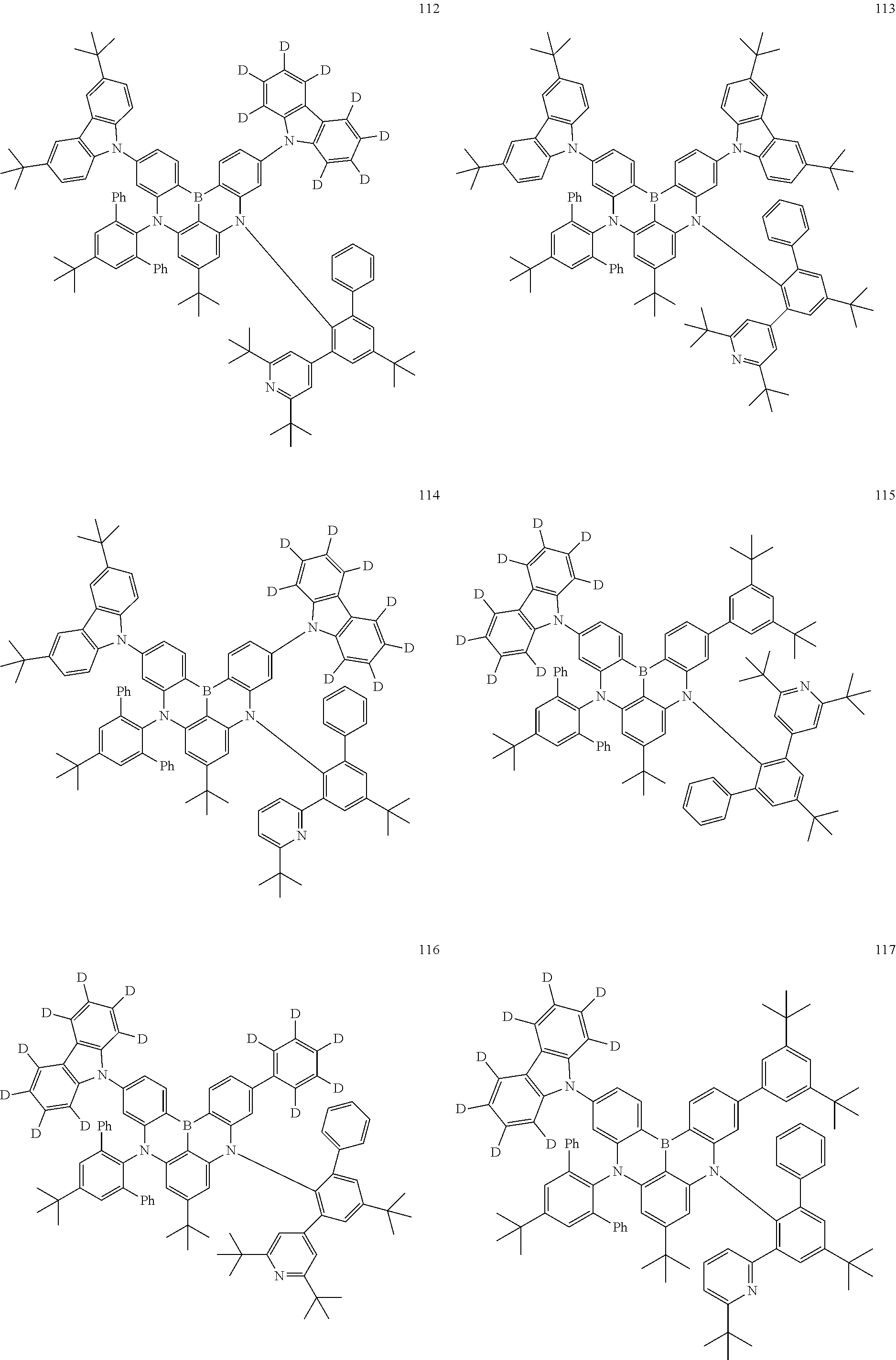 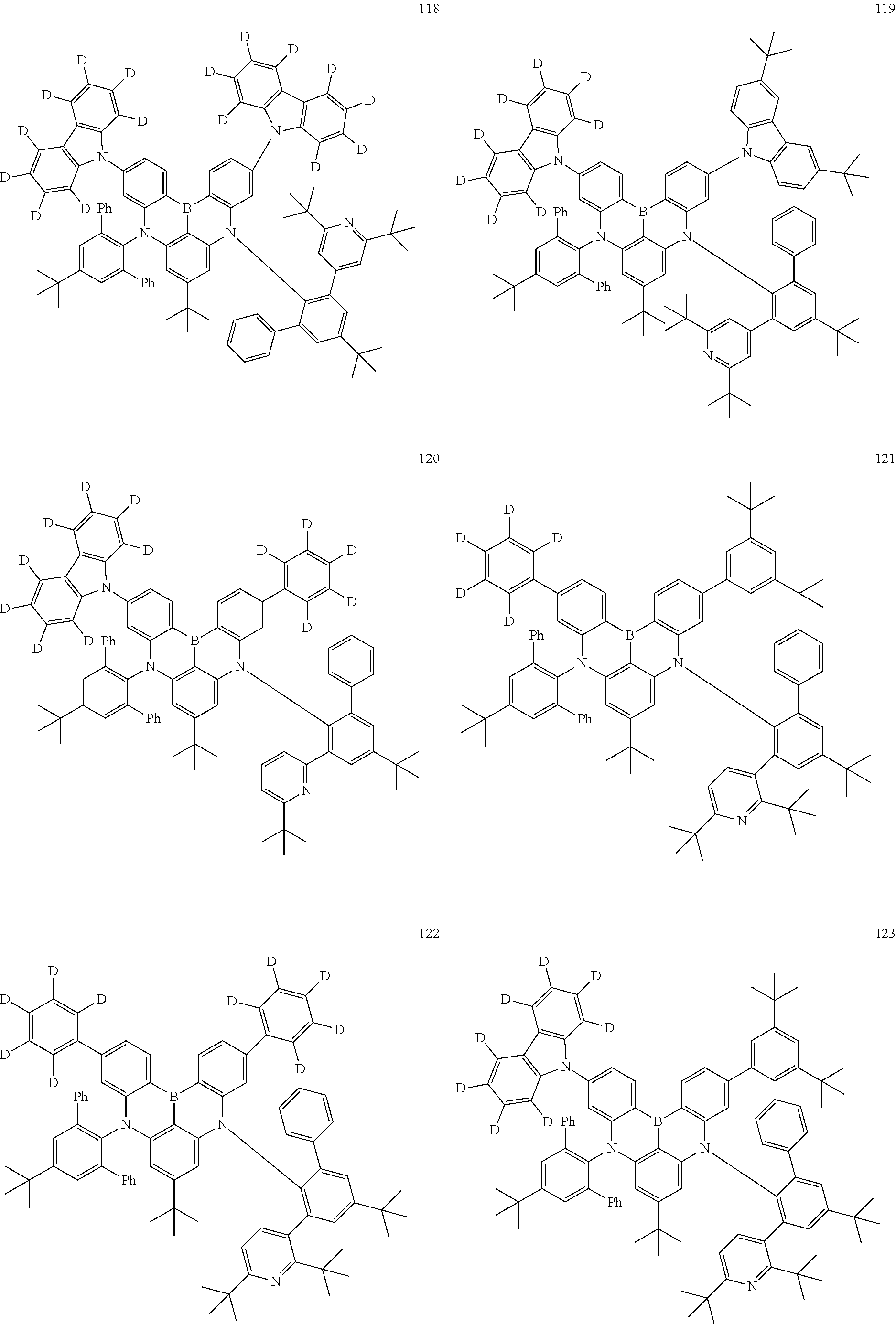 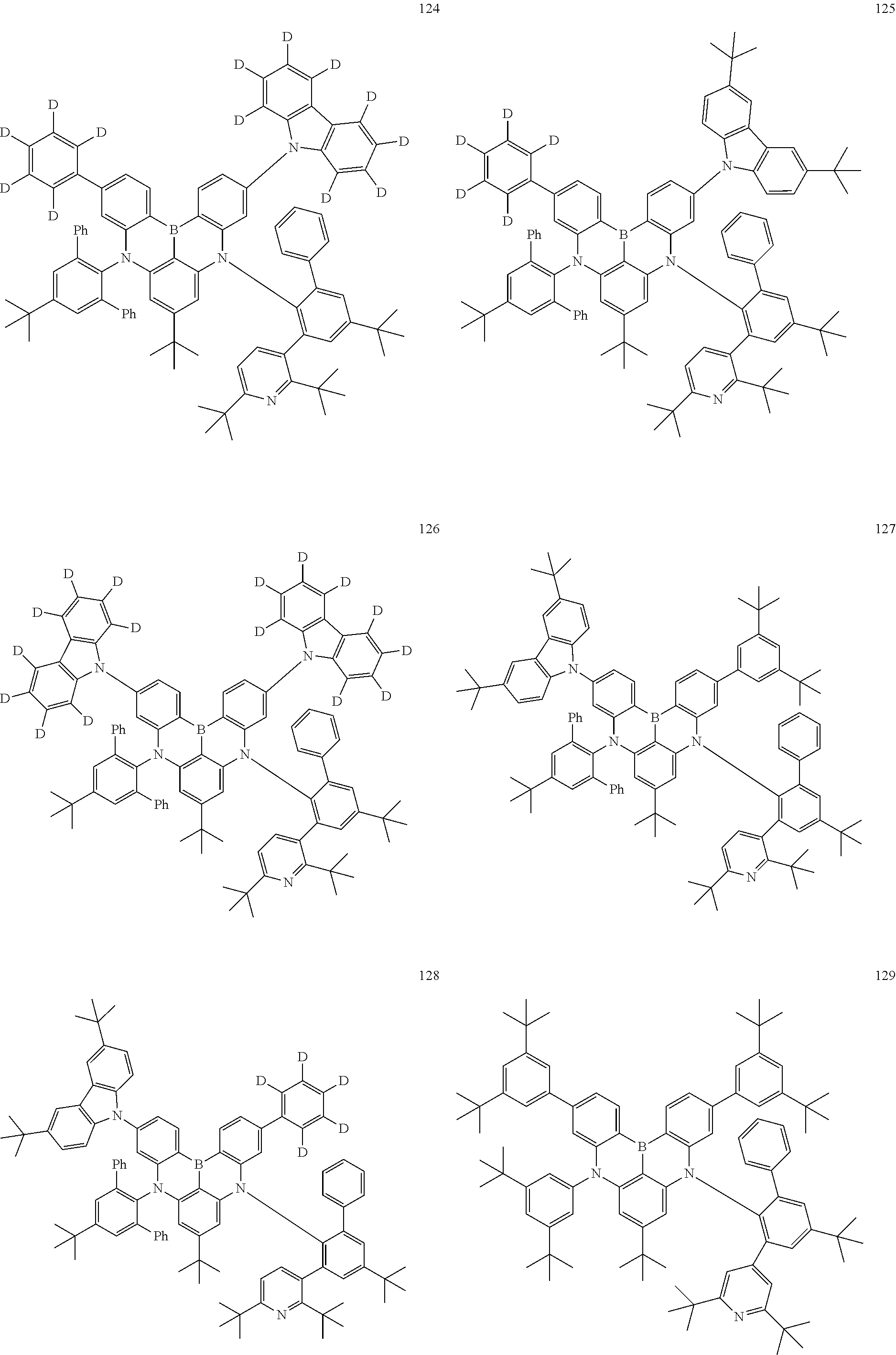 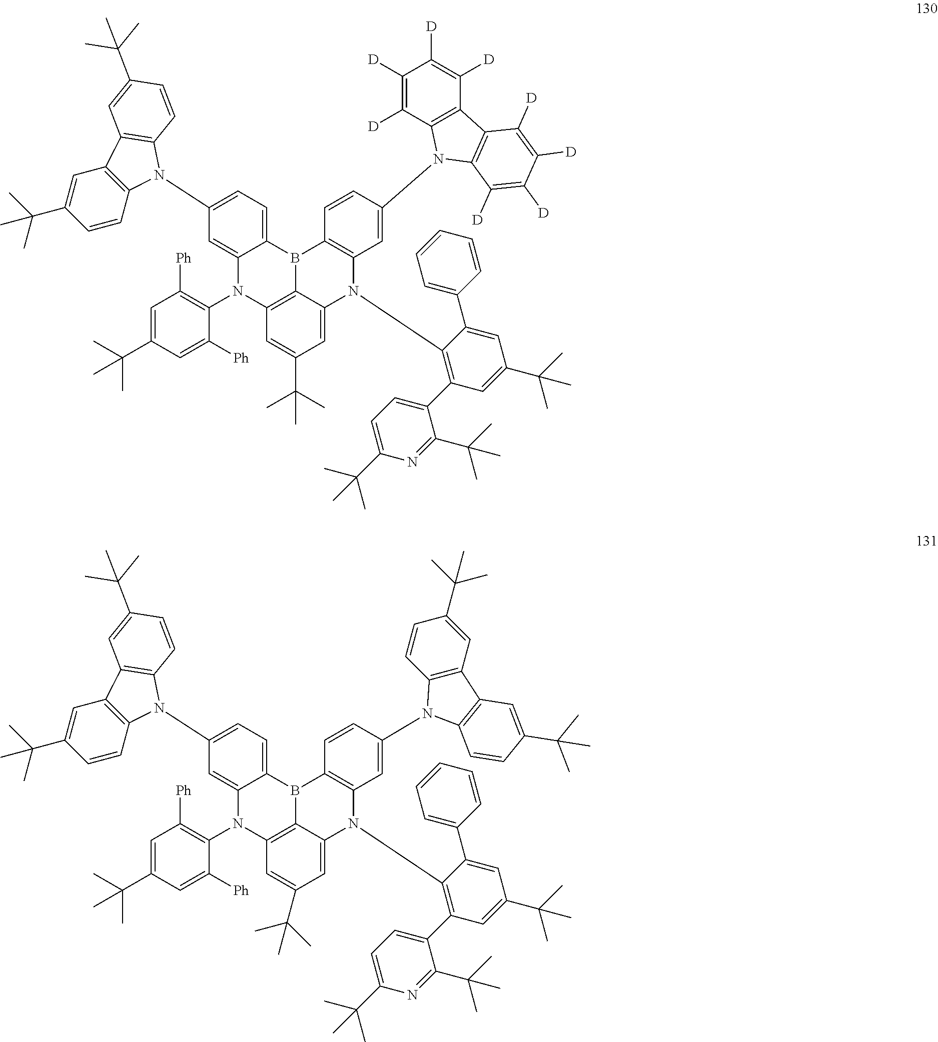 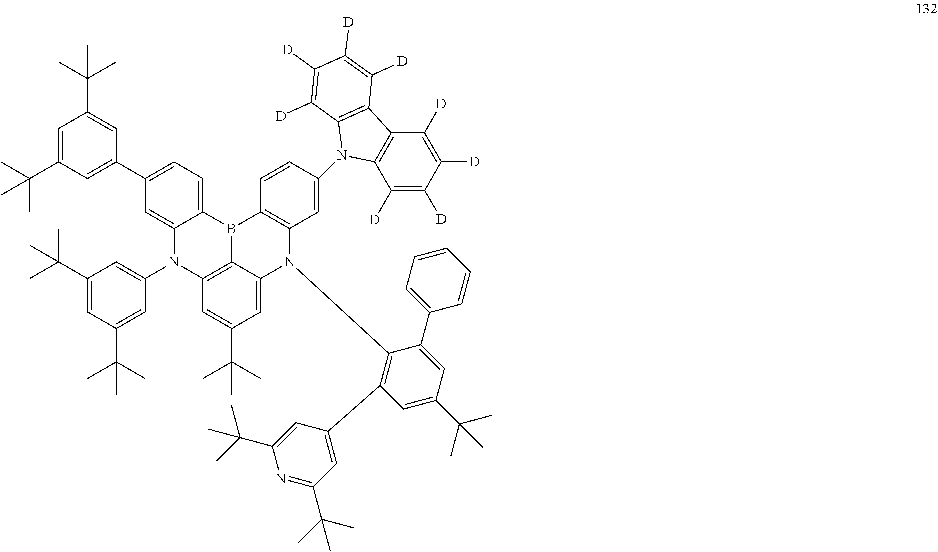 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cc(C(C)(C)C)nc(C(C)(C)C)c1)c1cc(C(C)(C)C)cc3c1B2c1ccc(-c2cc(C(C)(C)C)cc(C(C)(C)C)c2)cc1N3c1cc(C(C)(C)C)cc(C(C)(C)C)c1] 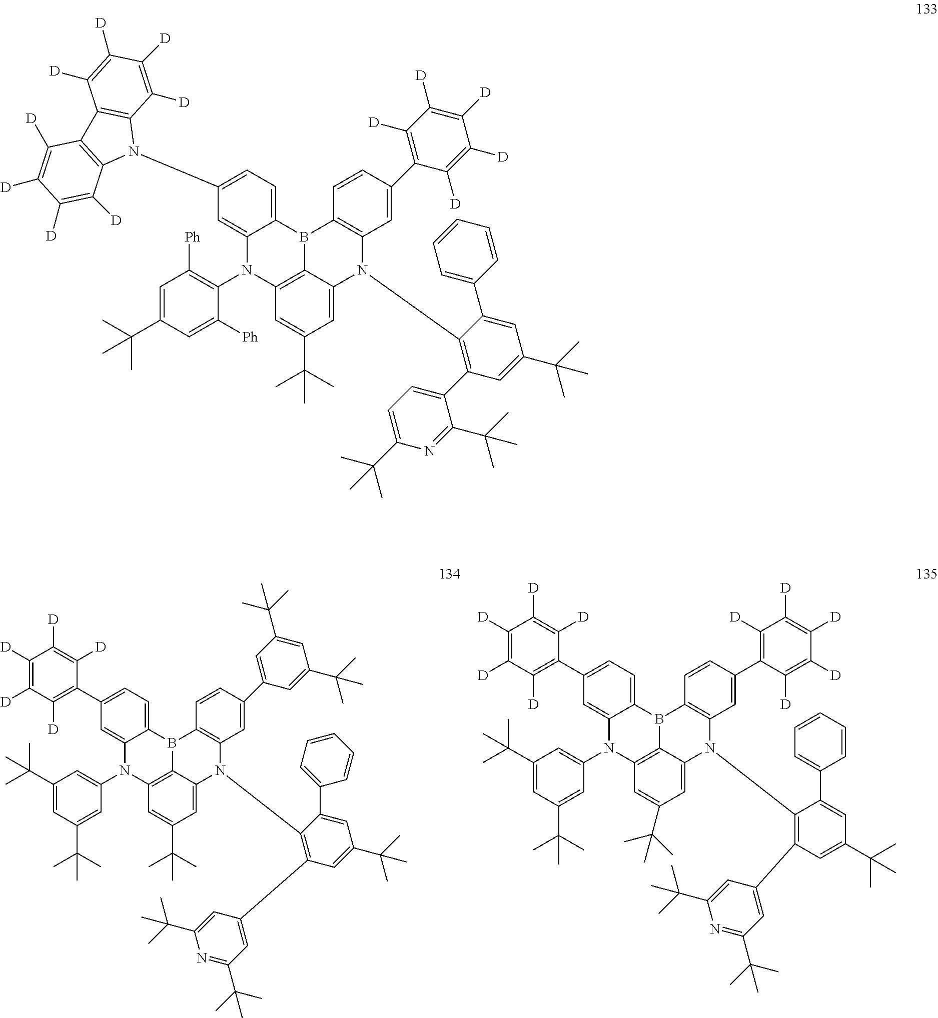 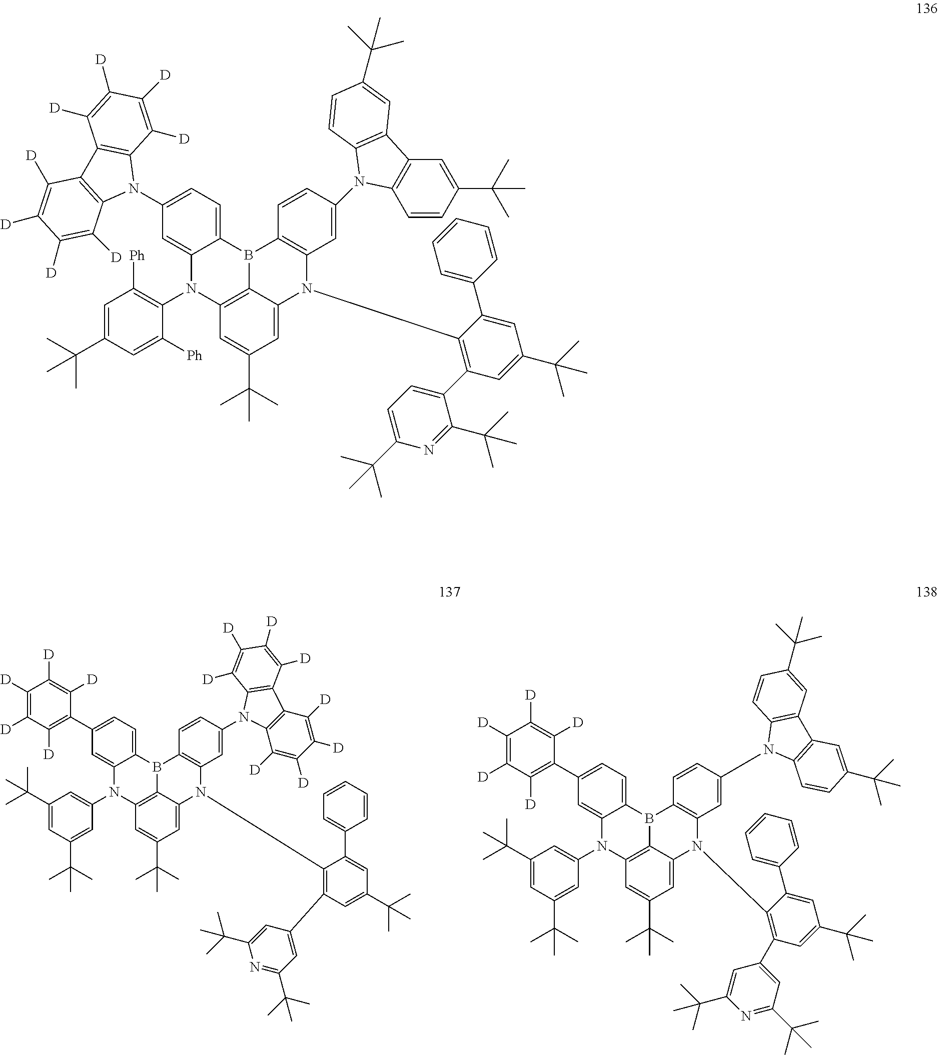 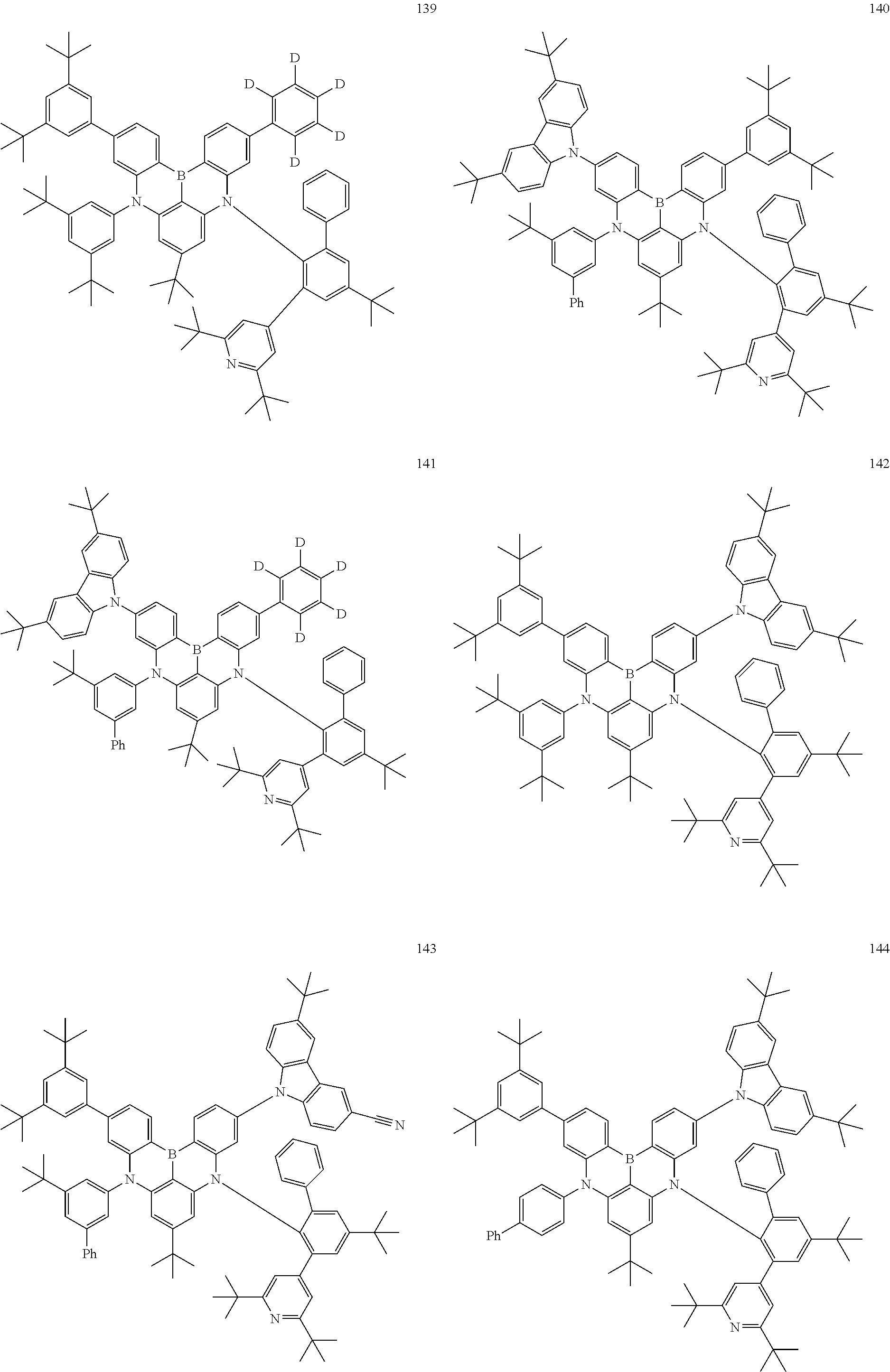 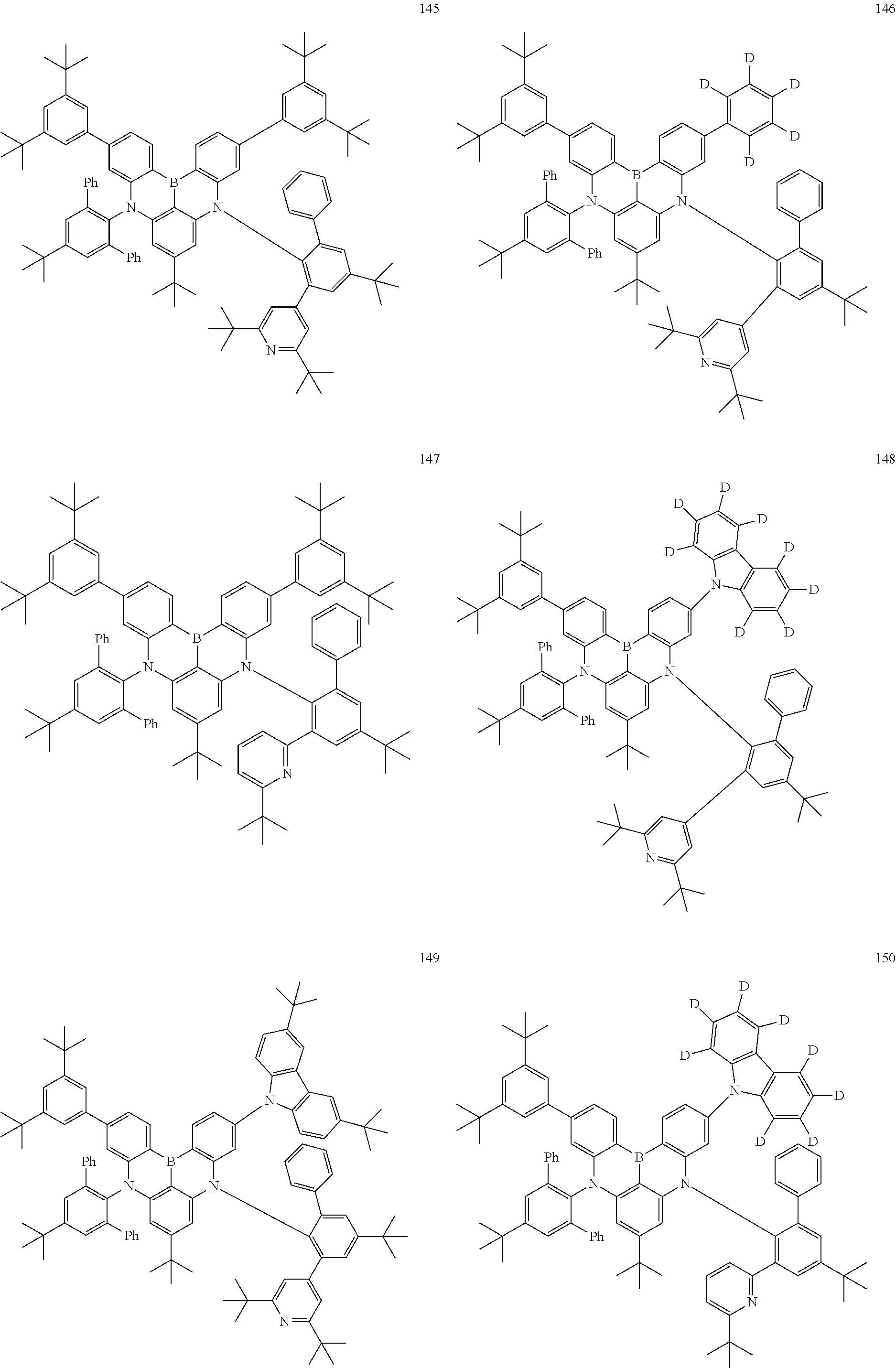 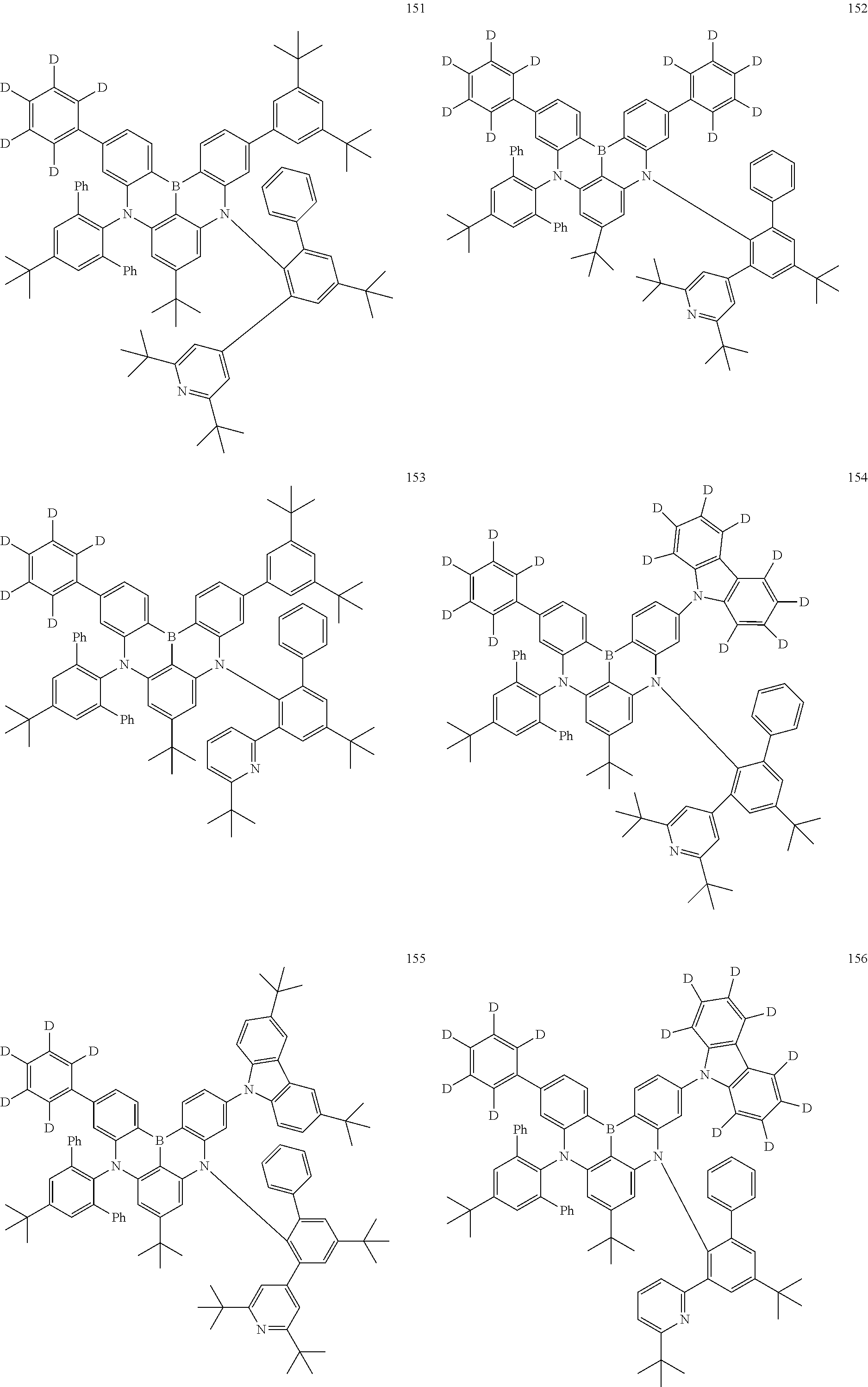 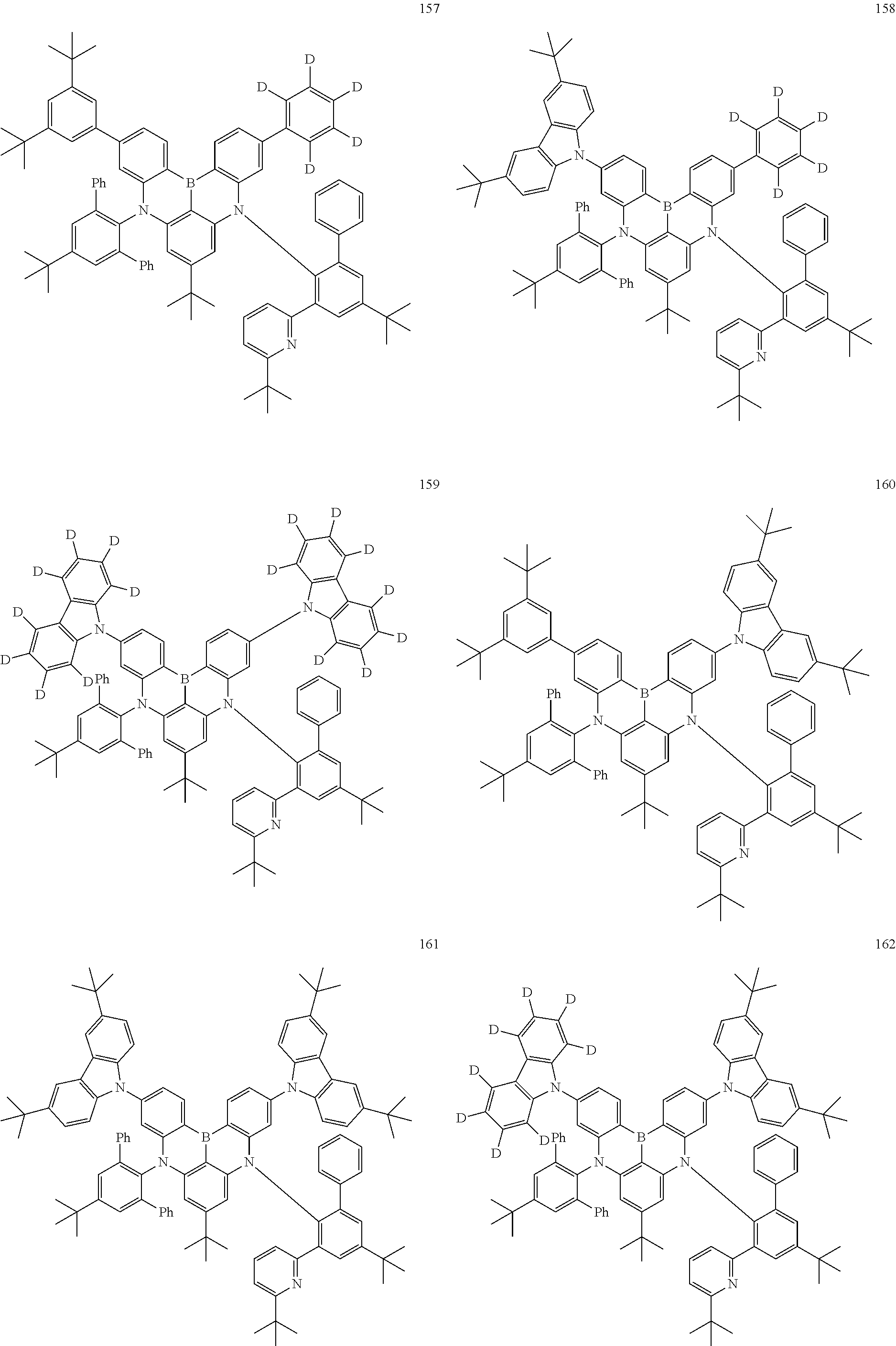 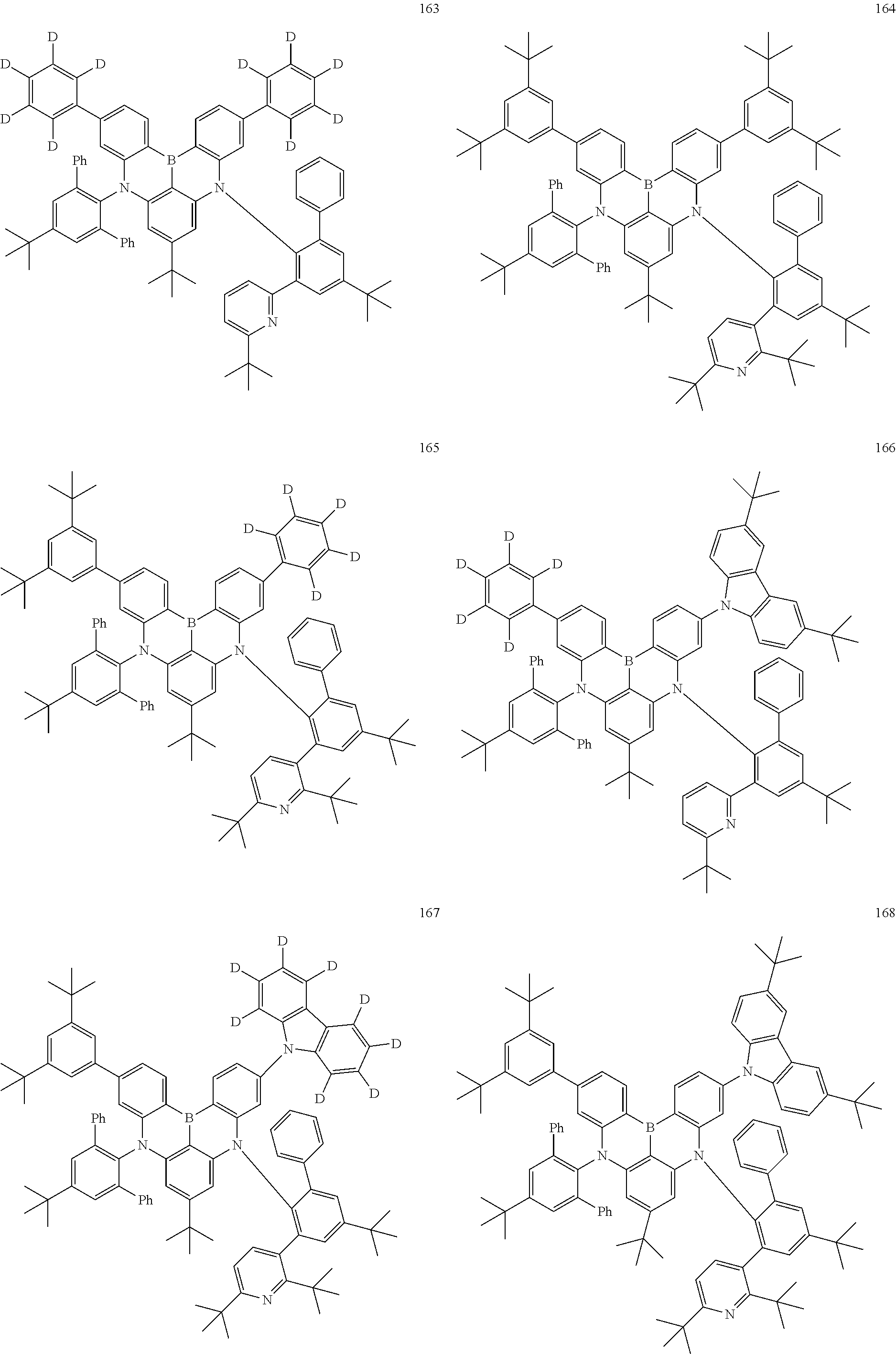 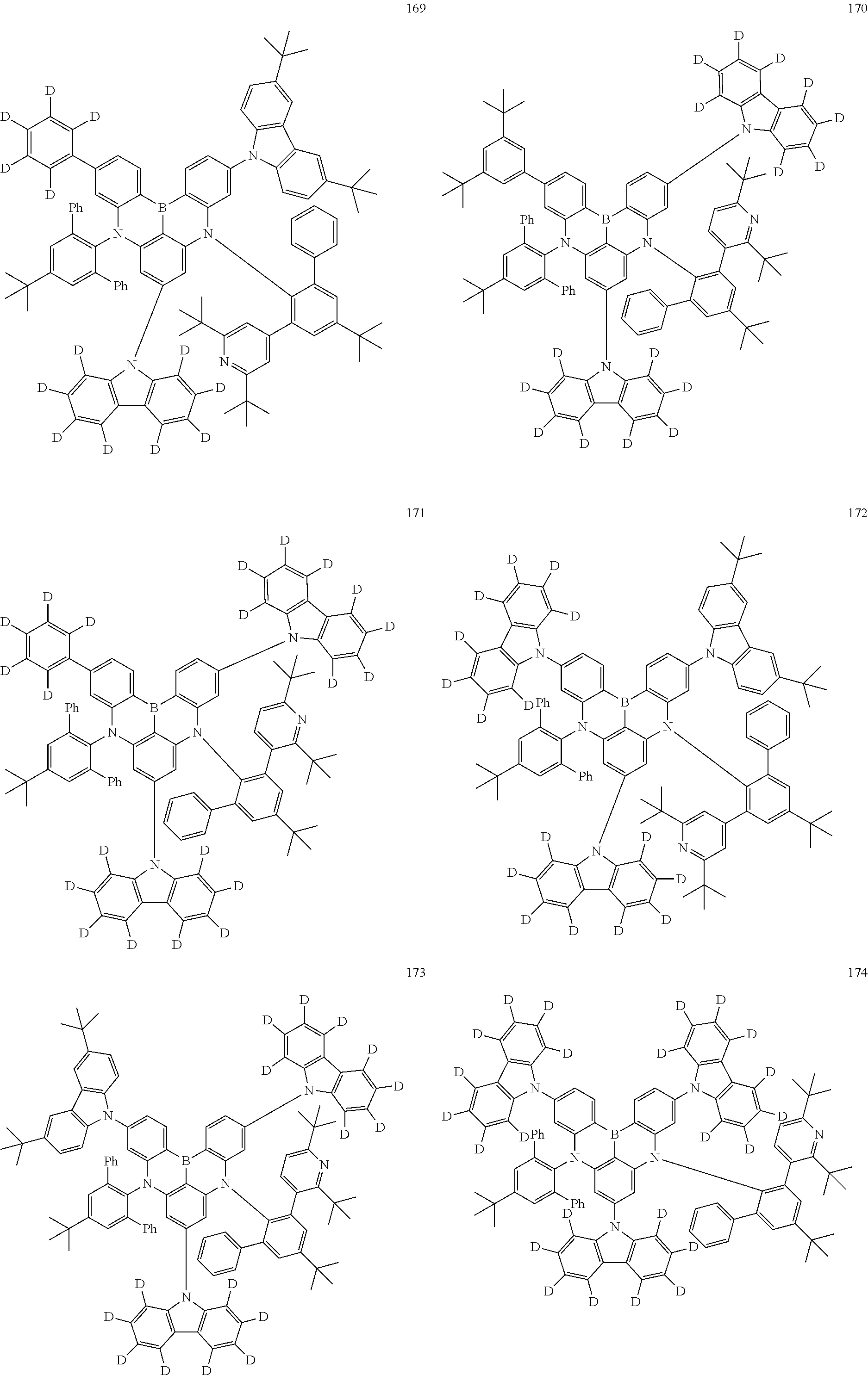 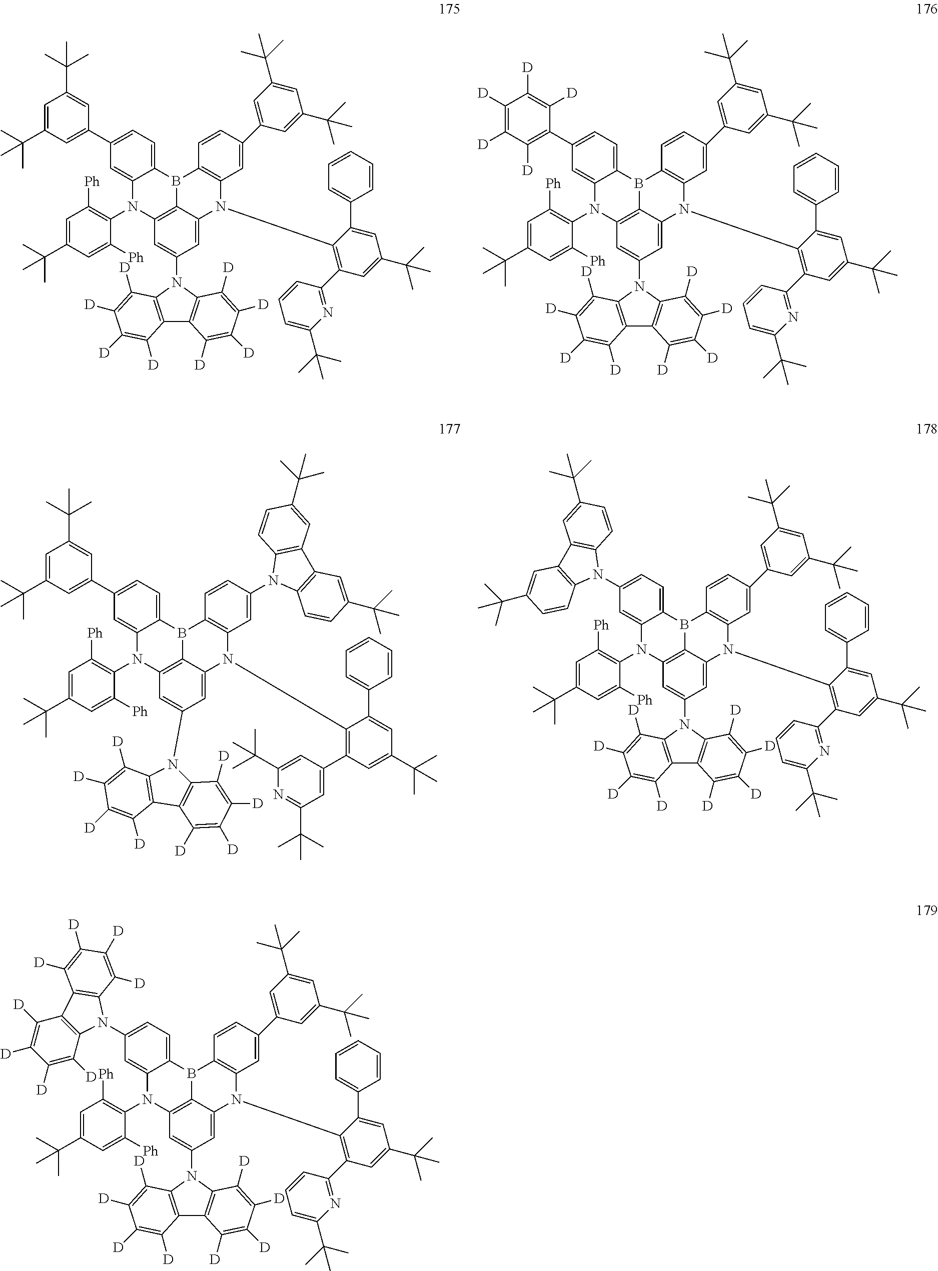 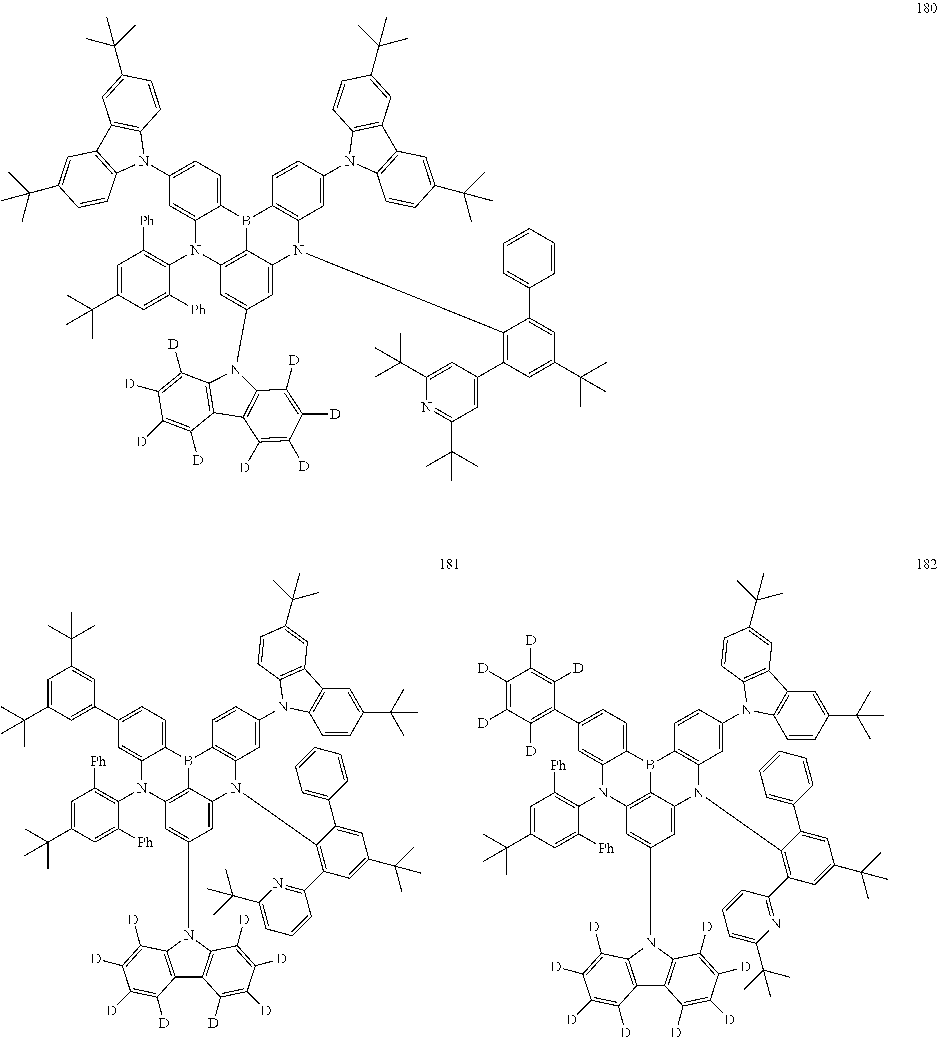 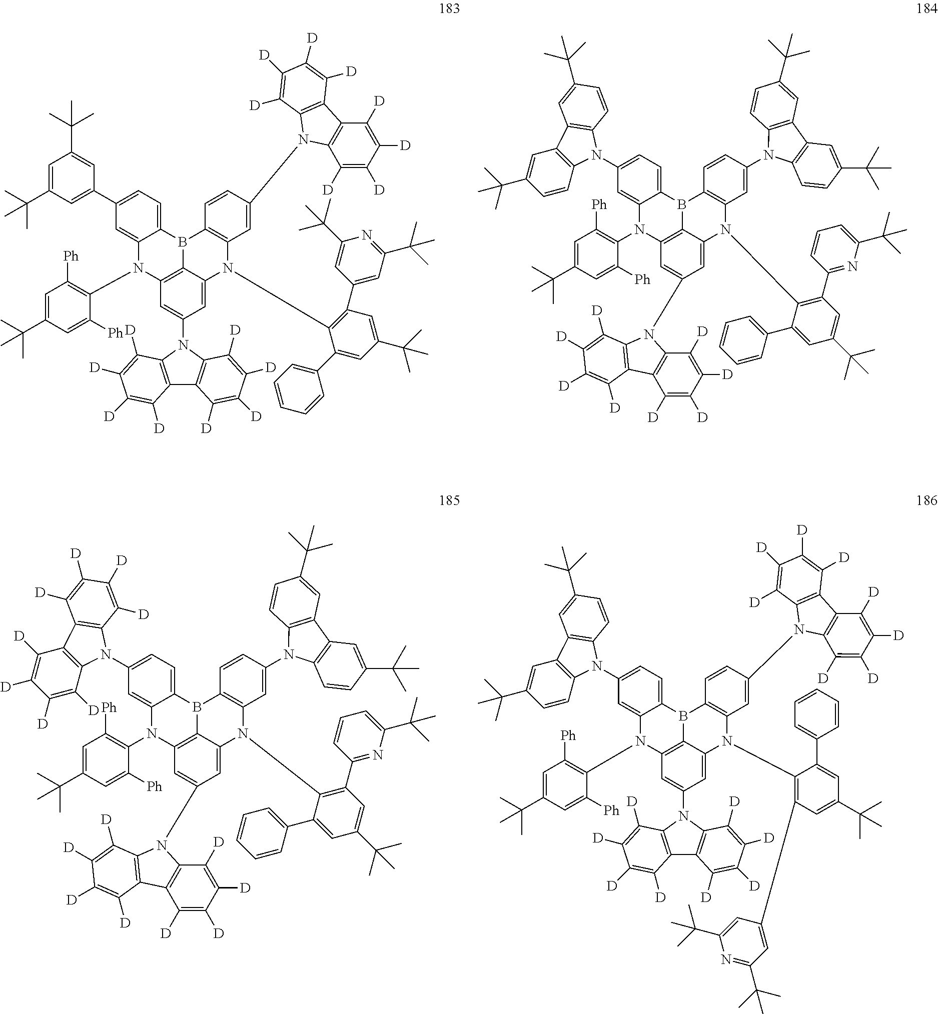 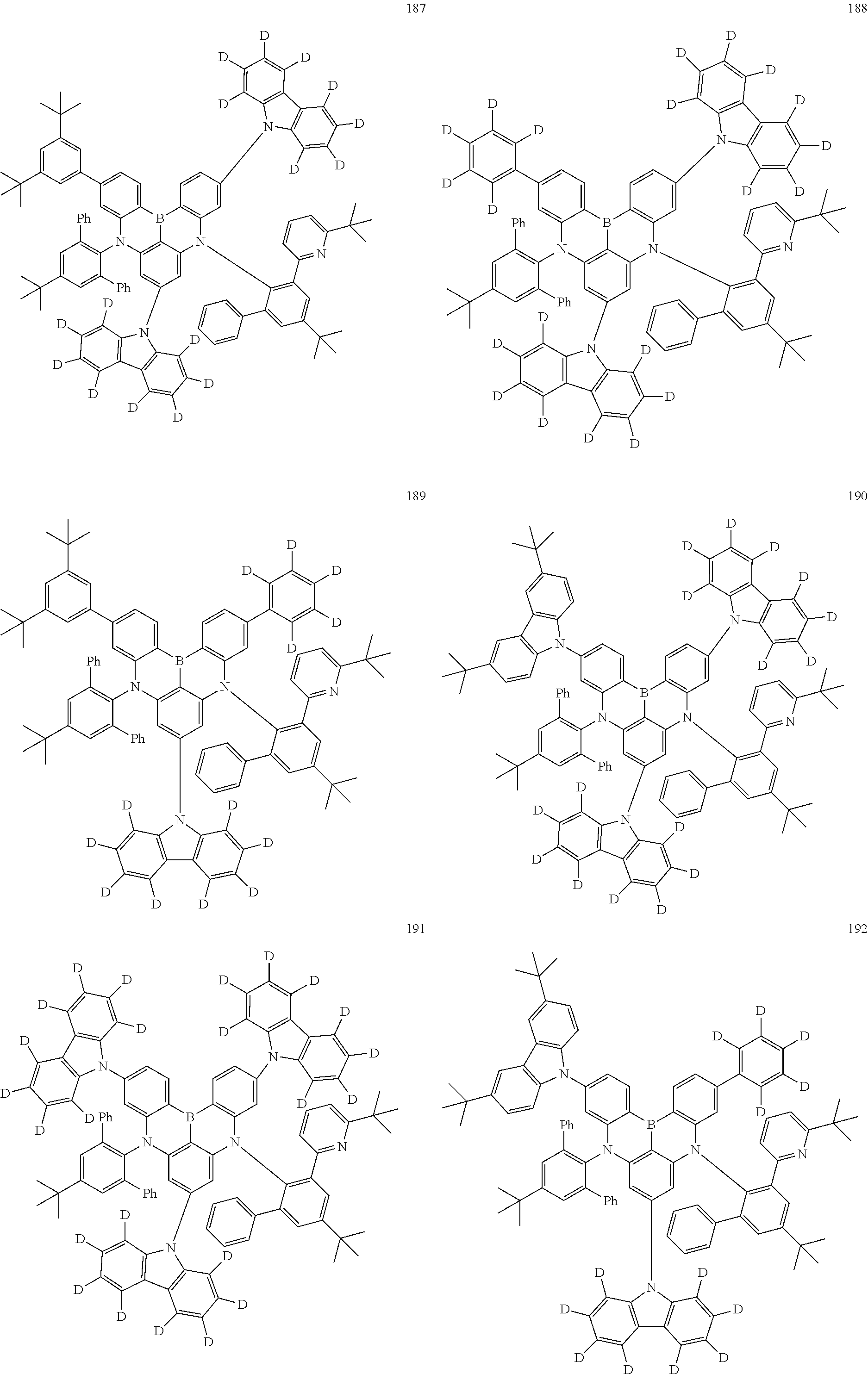 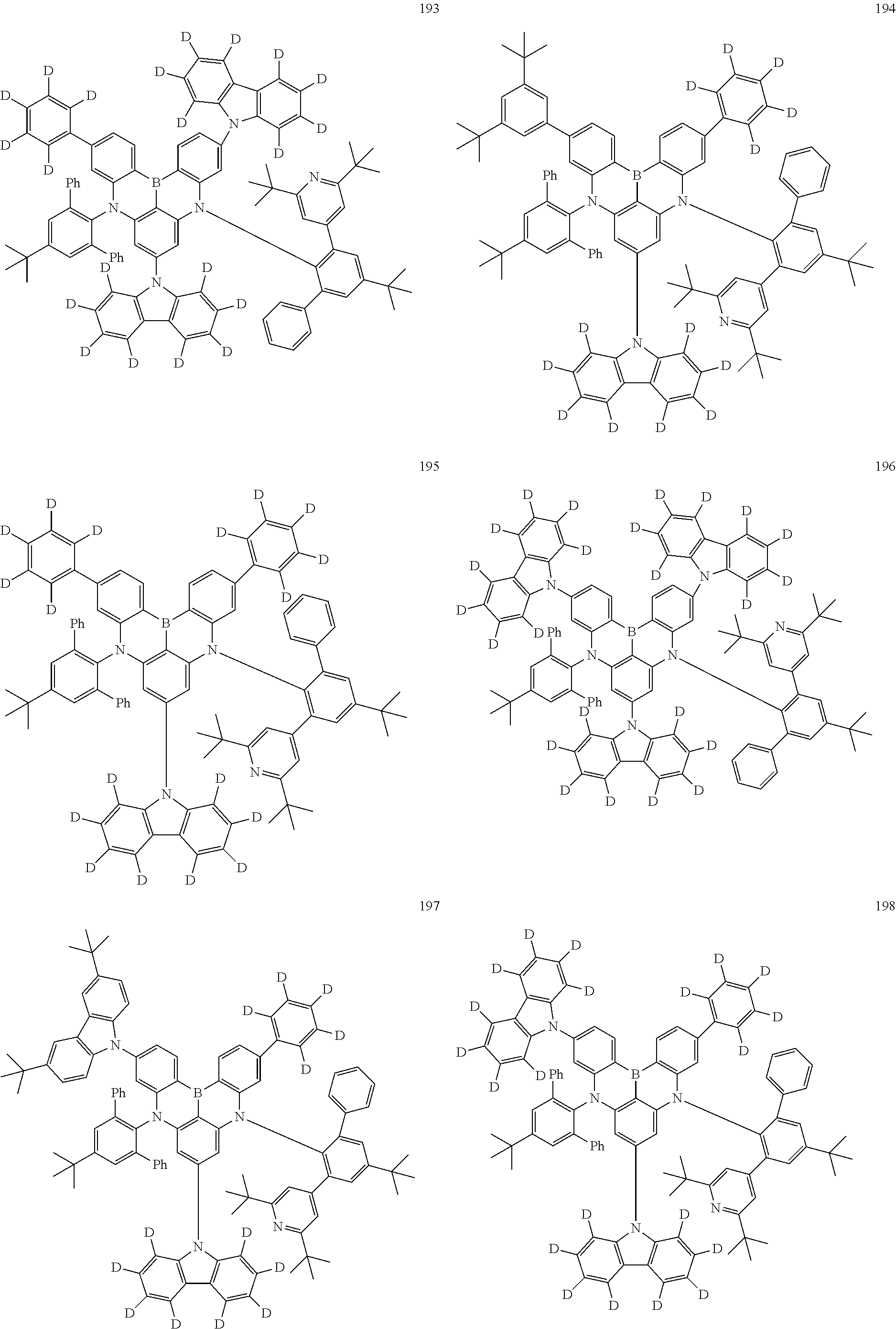 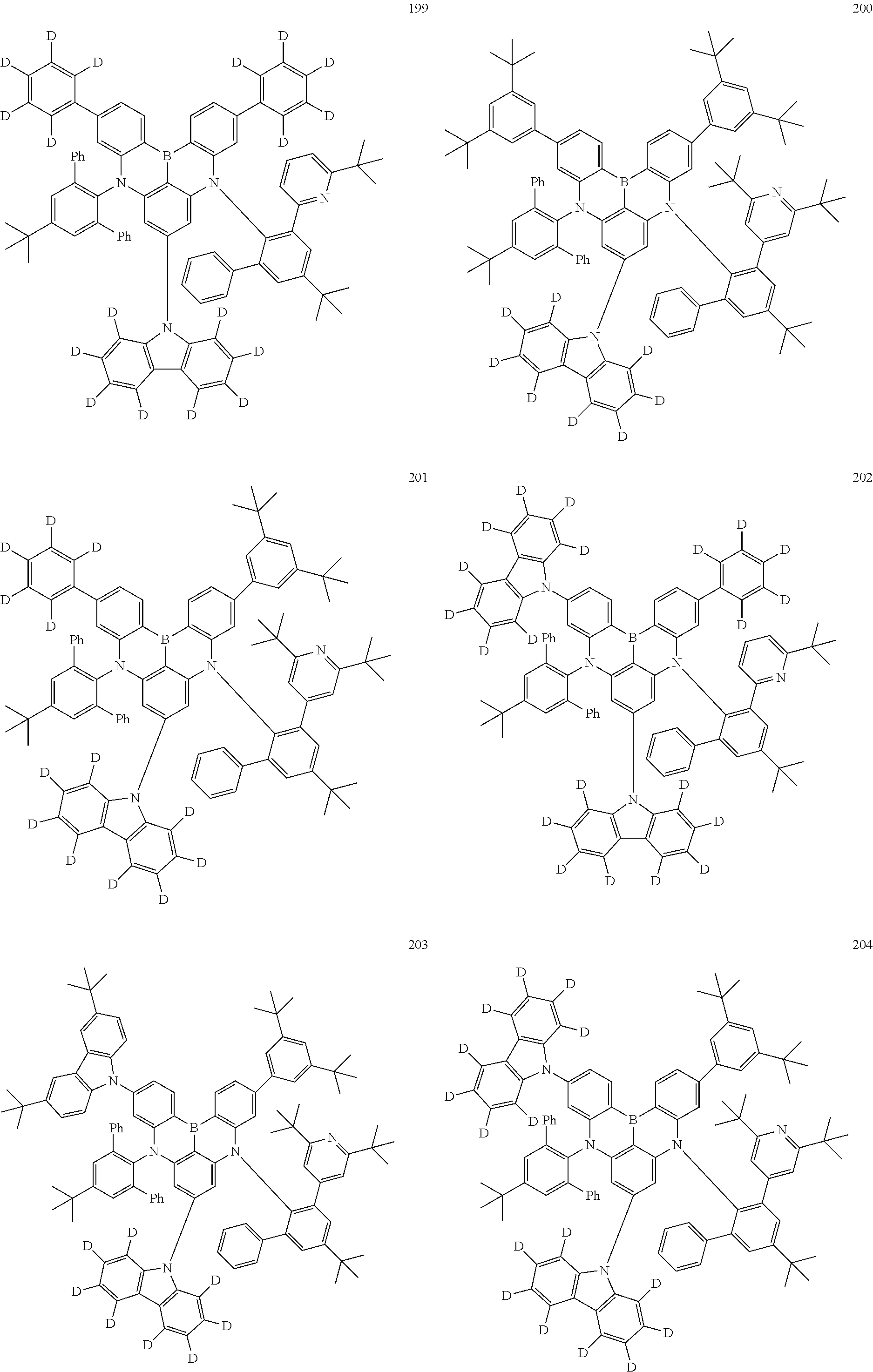 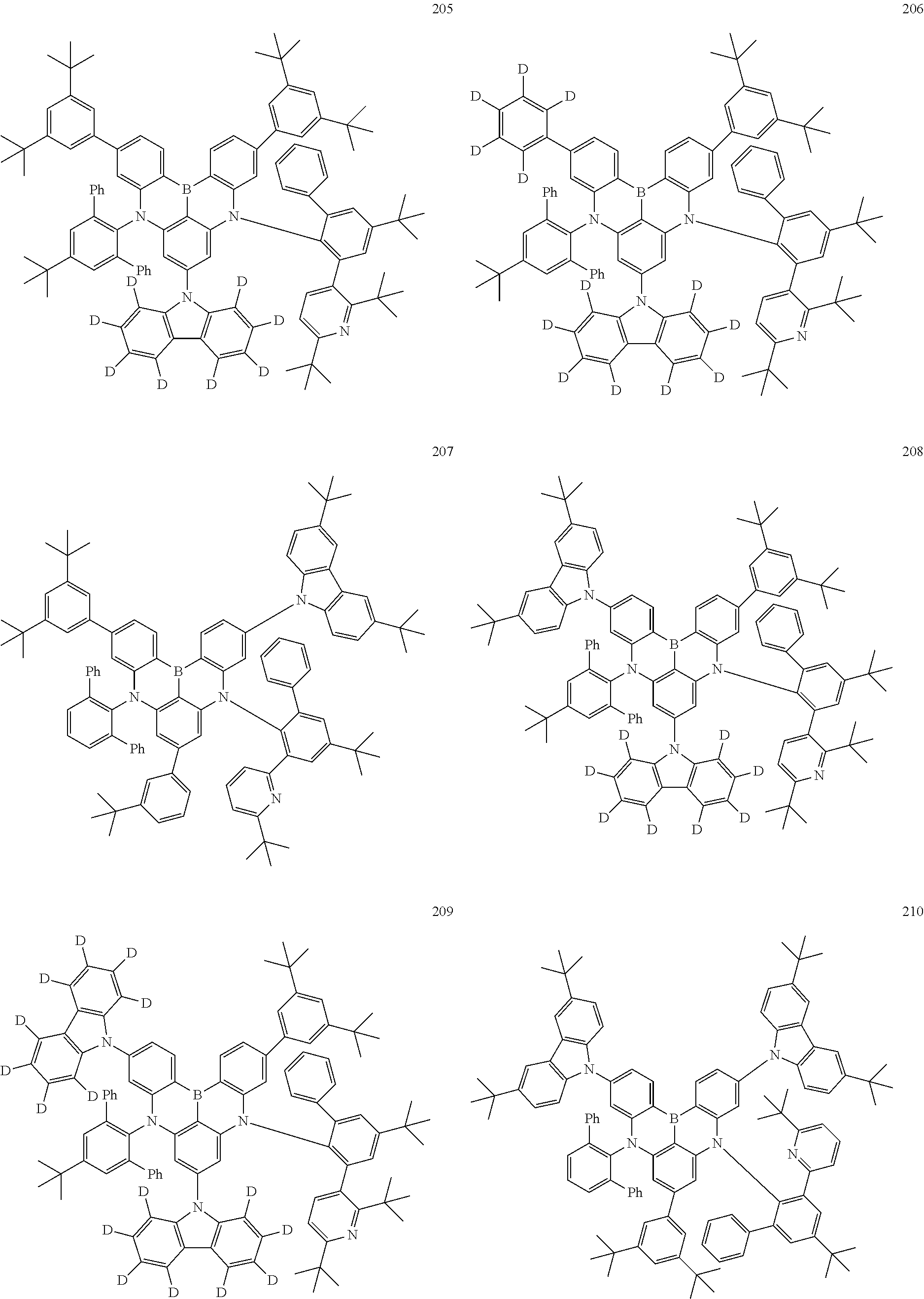 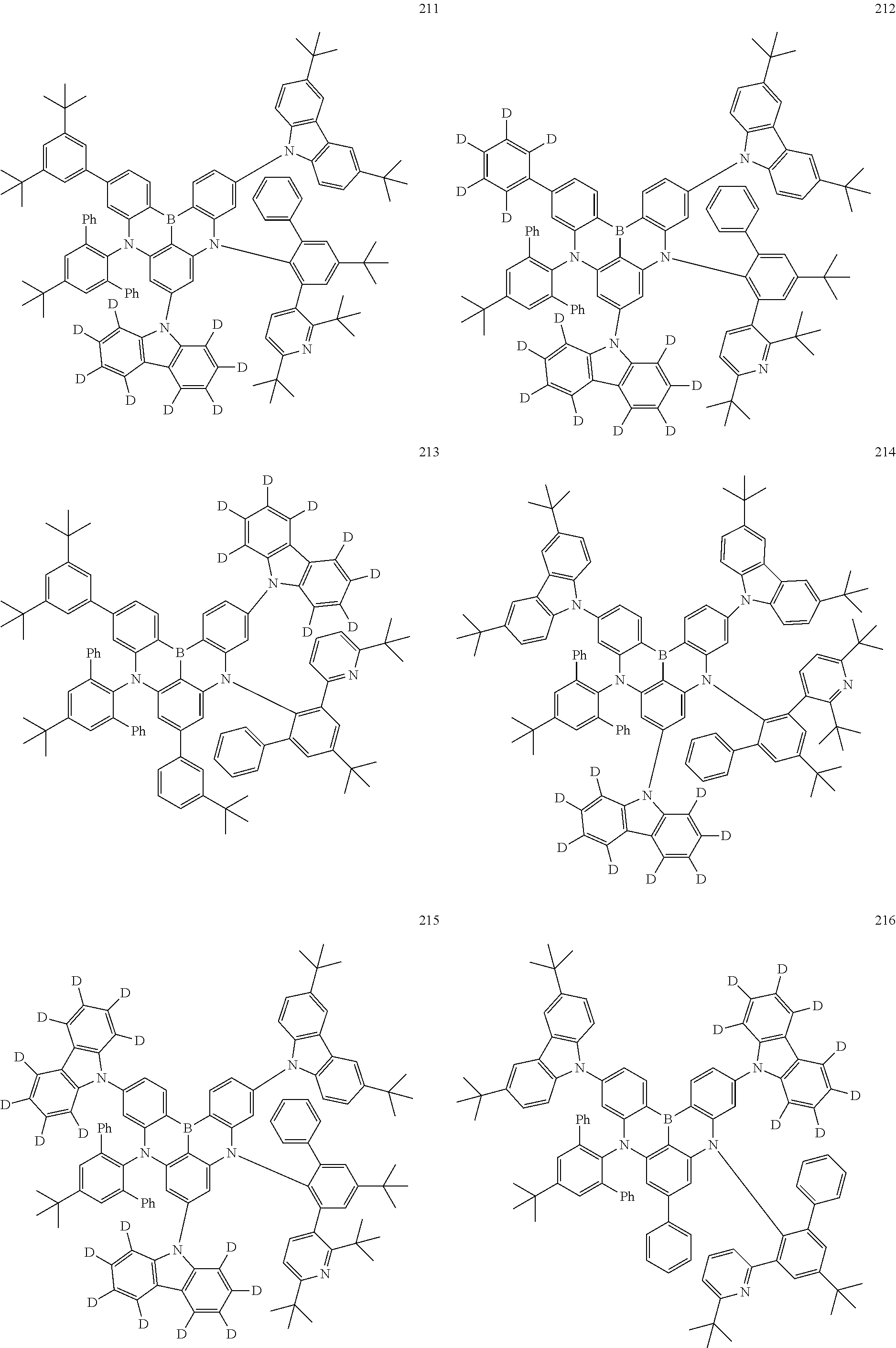 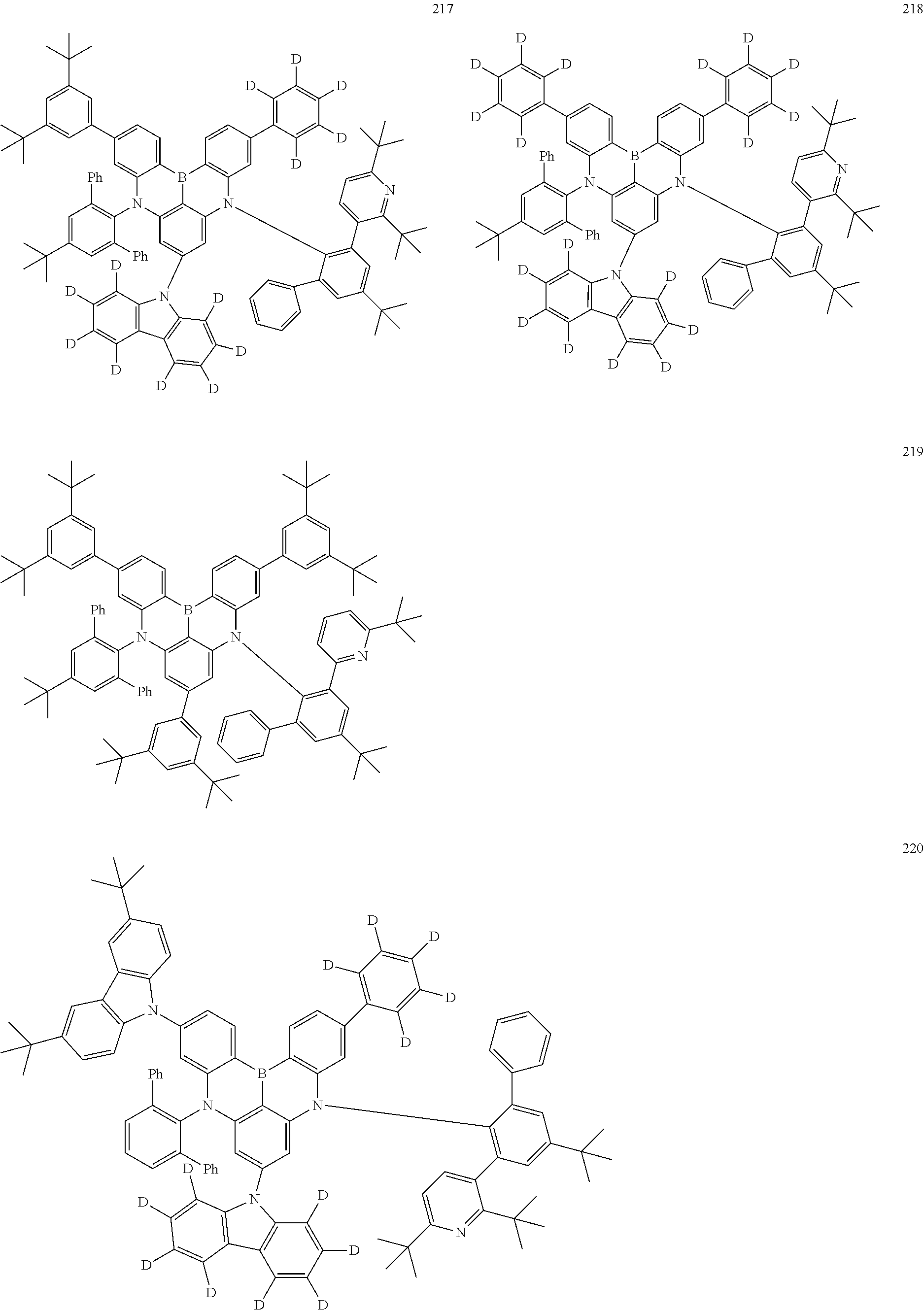 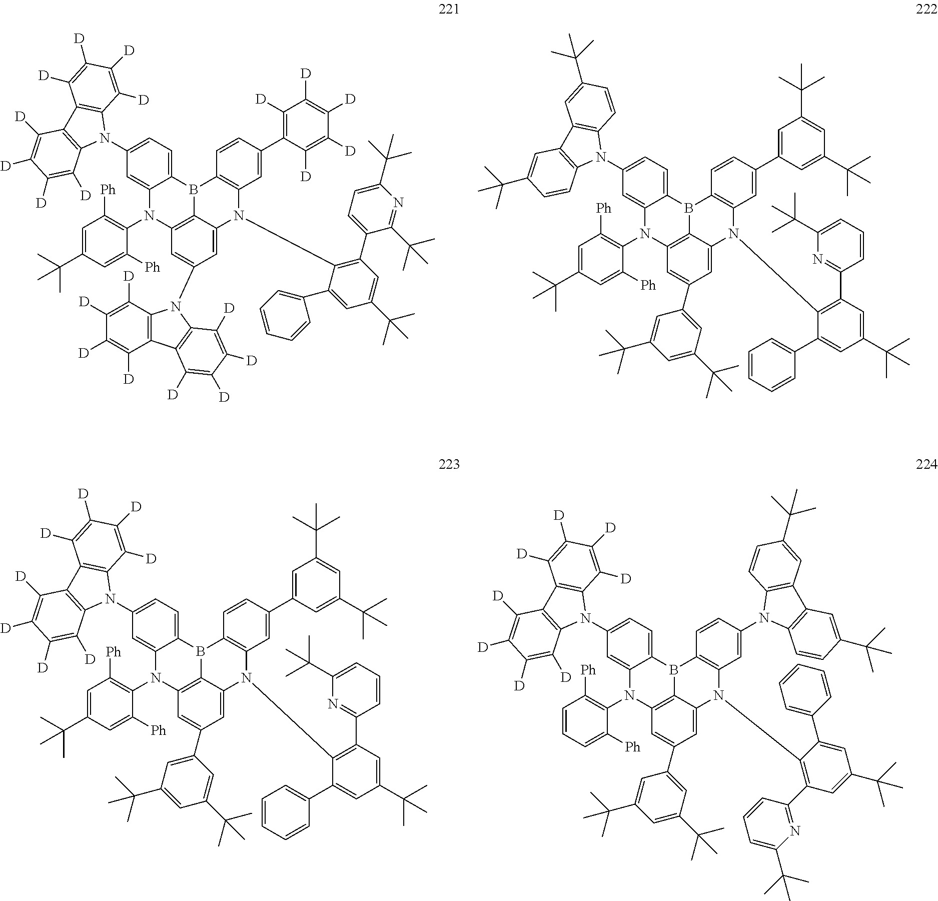 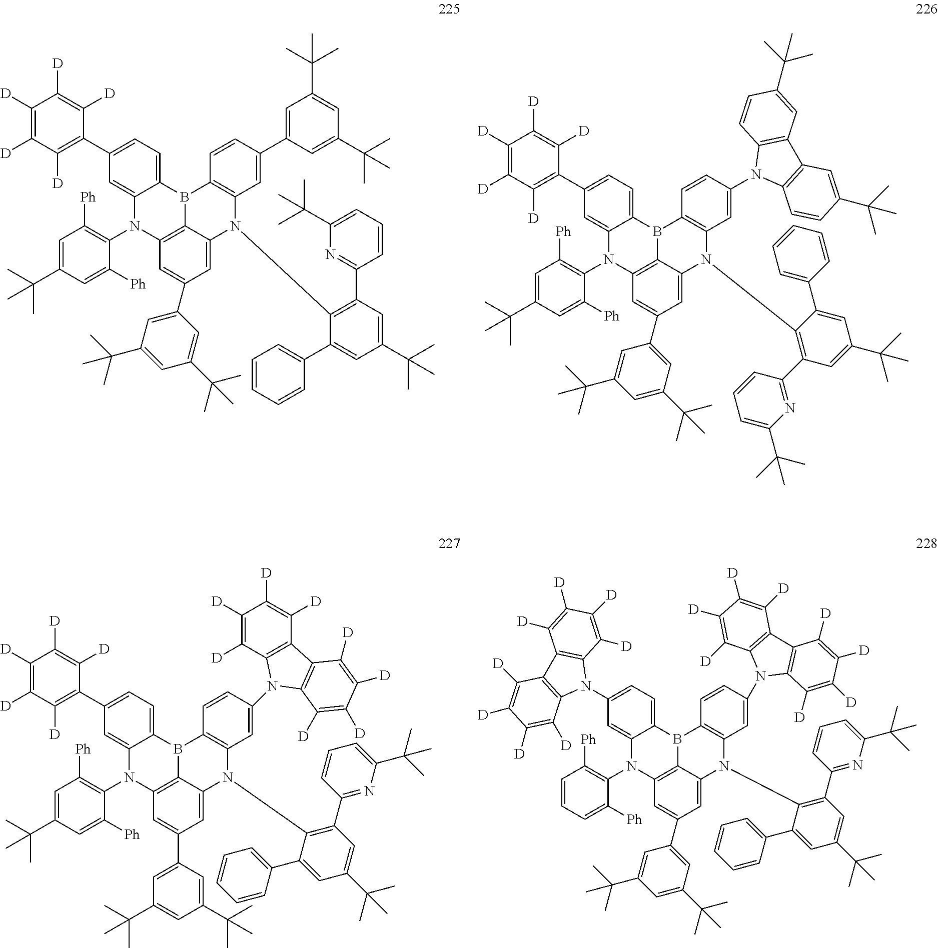 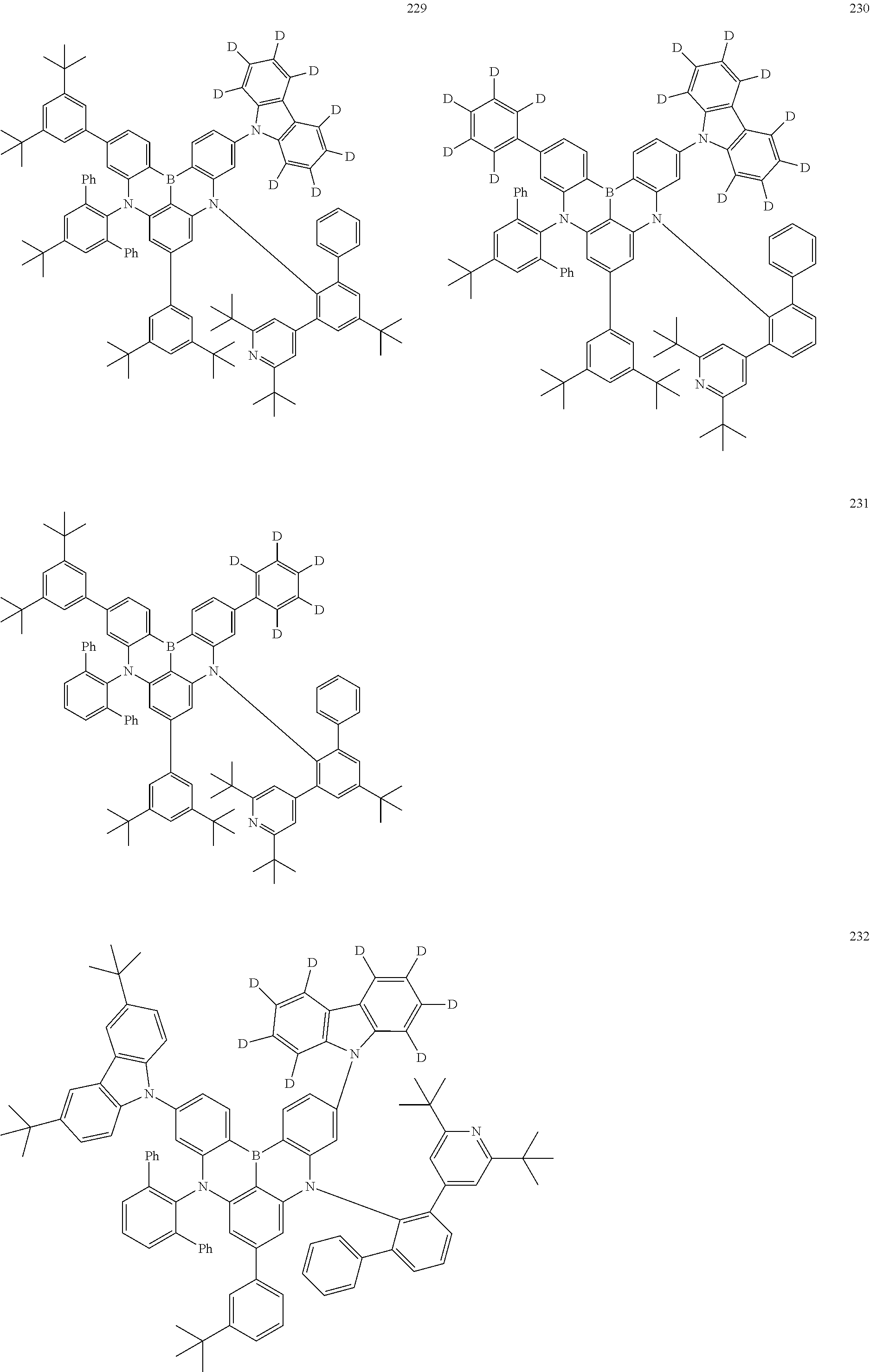 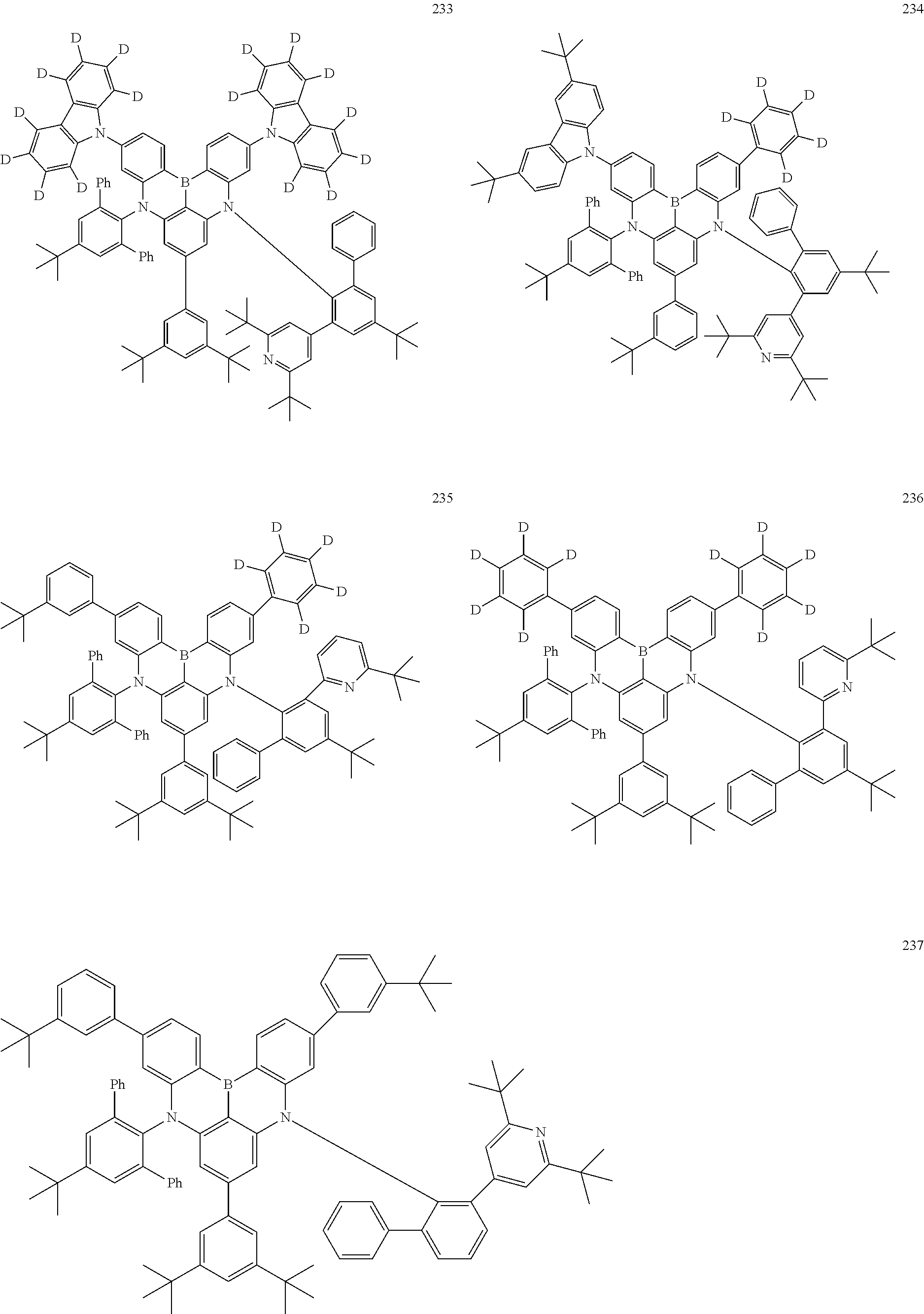 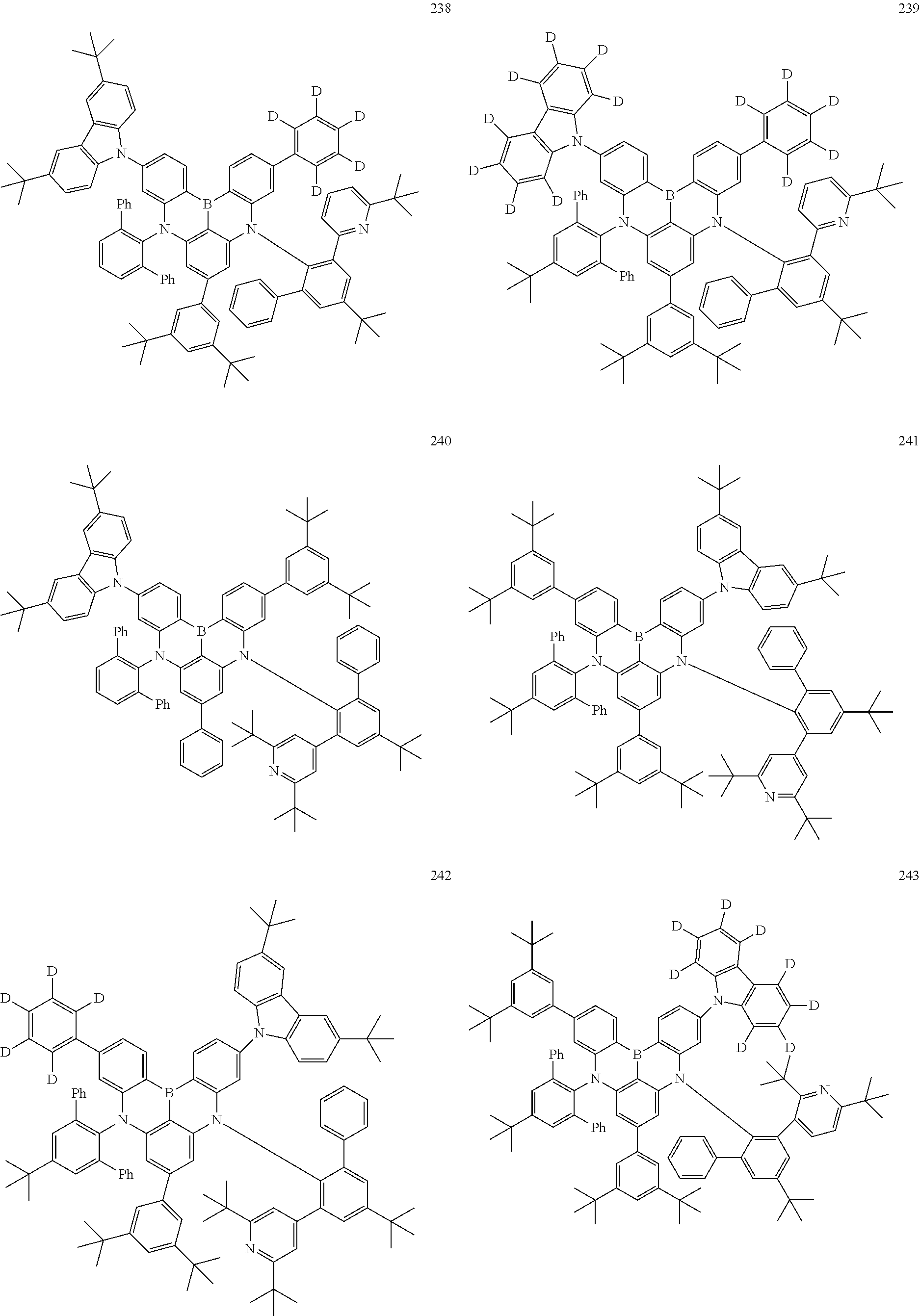 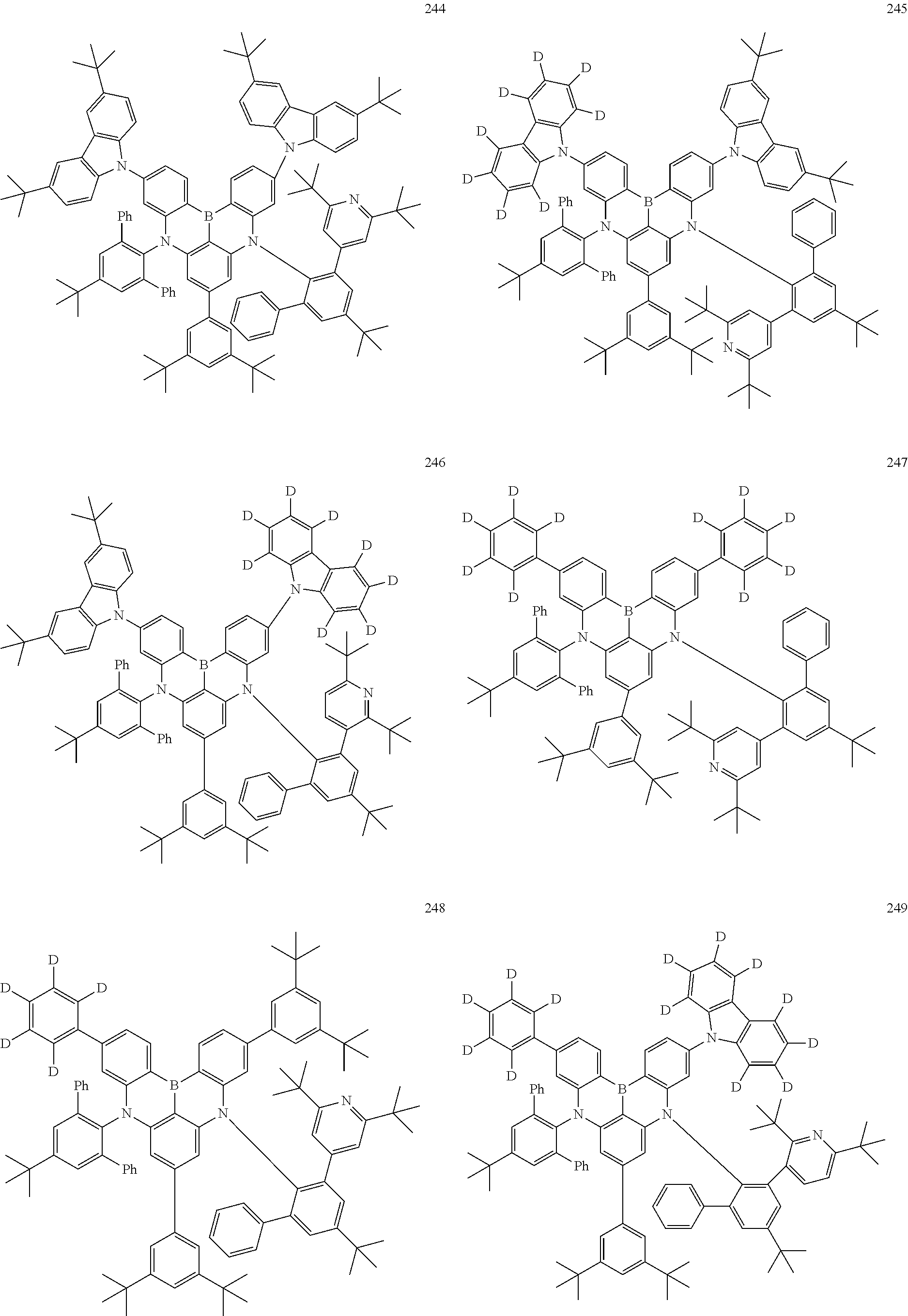 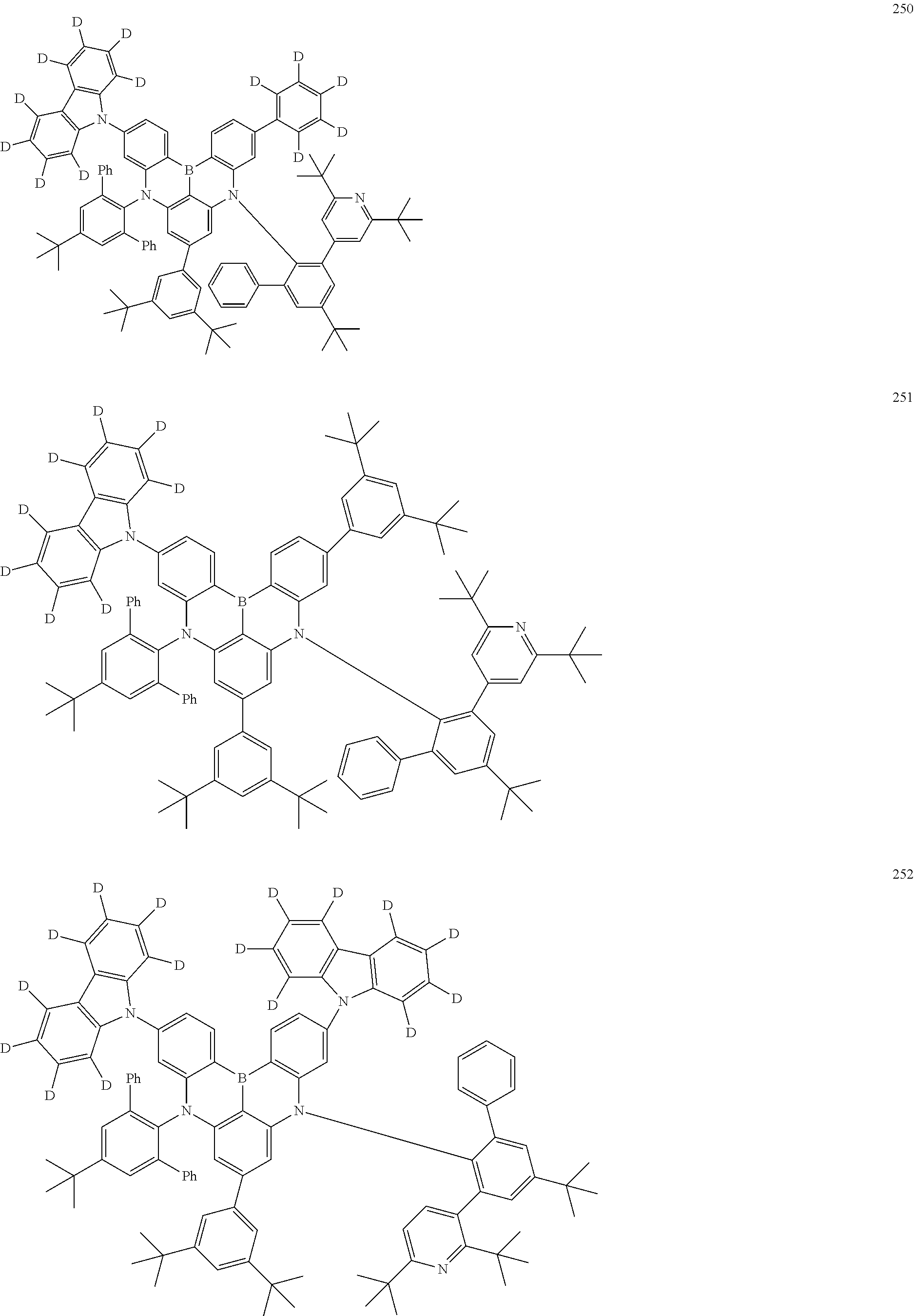 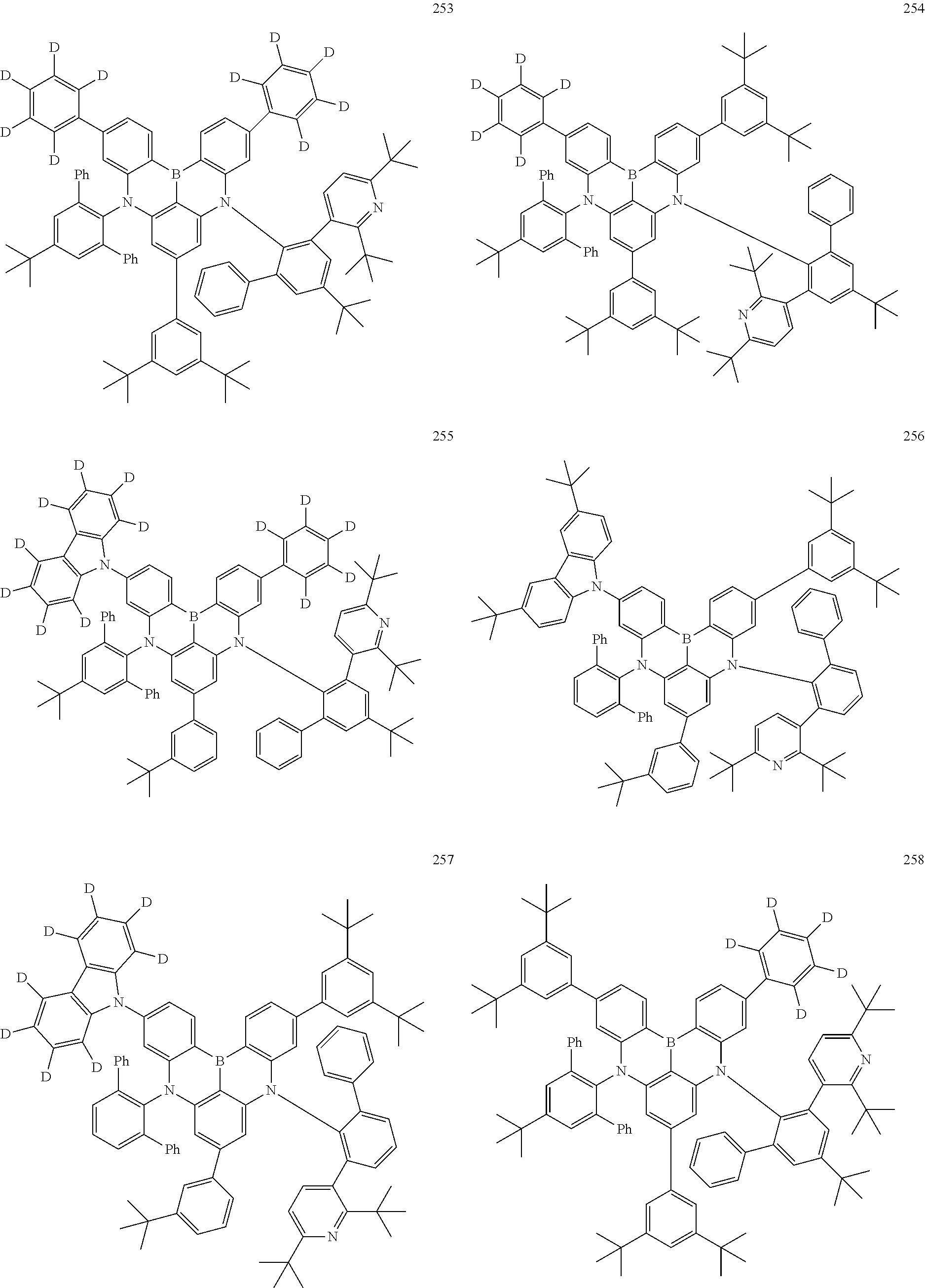 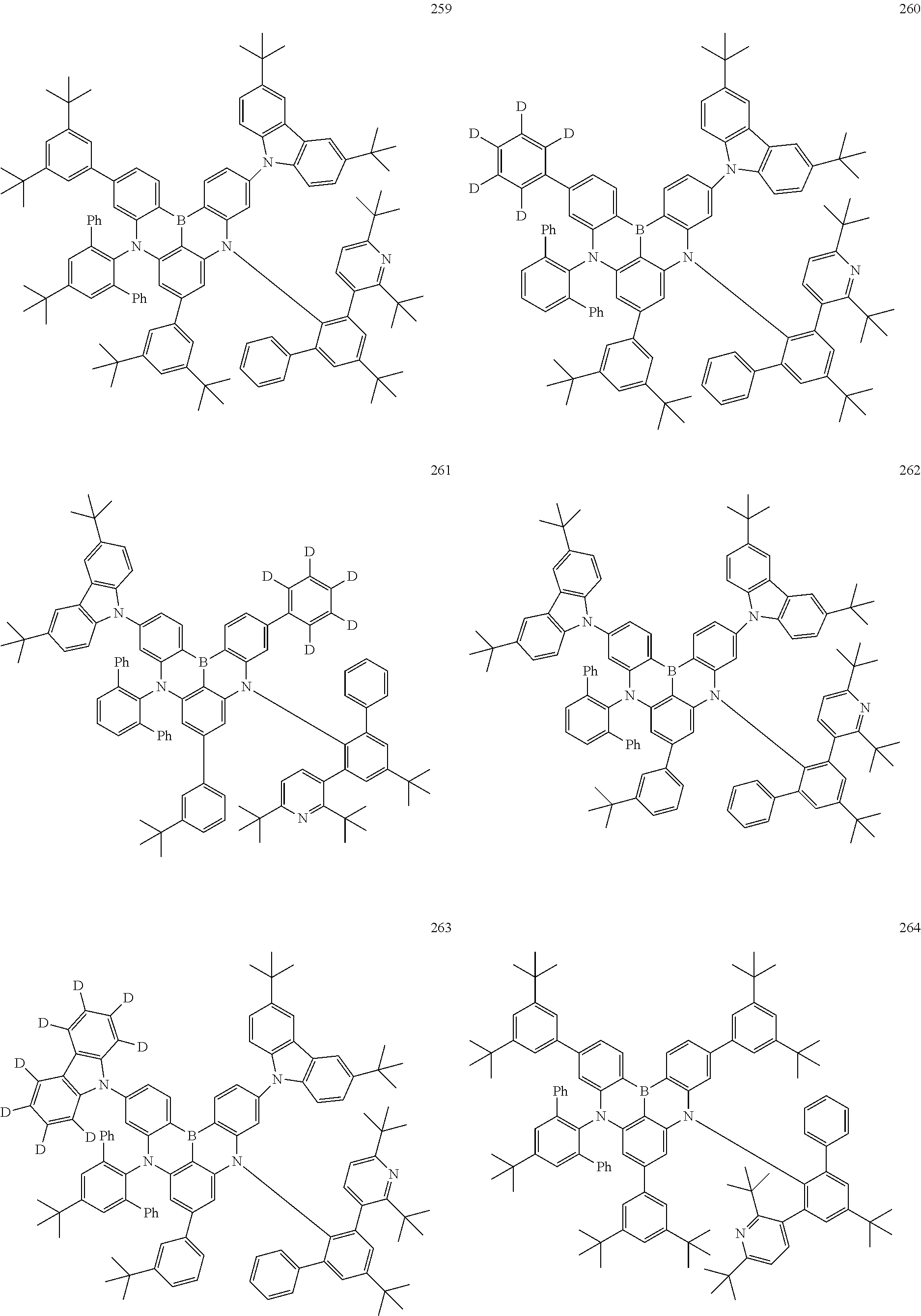
wherein in Compound Group 1,
D represents a deuterium atom,
t-Bu represents an unsubstituted t-butyl group, and
Ph represents an unsubstituted phenyl group.

14. A polycyclic compound represented by Formula 1: 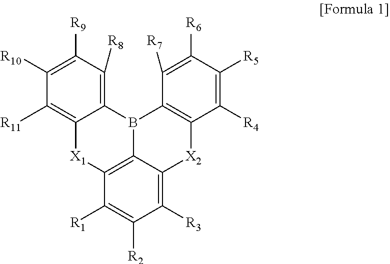
wherein in Formula 1,
at least one of X₁ or X₂ is N(Rₓ₁),
the remainder of X₁ or X₂ is N(Rₓ₂), O or S,
Rₓ₁ is a group represented by one of Formula 2-1 to Formula 2-4, and
Rₓ₂ and R₁ to R₁₁ are each independently a hydrogen atom, a deuterium atom, a halogen atom, a cyano group, a substituted or unsubstituted amine group, a substituted or unsubstituted silyl group, a substituted or unsubstituted alkyl group having 1 to 10 carbon atoms, a substituted or unsubstituted cycloalkyl group having 3 to 10 ring-forming carbon atoms, a substituted or unsubstituted aryl group having 6 to 60 ring-forming carbon atoms, a substituted or unsubstituted heterocycloalkyl group having 2 to 10 ring-forming carbon atoms, or a substituted or unsubstituted heteroaryl group having 2 to 60 ring-forming carbon atoms; 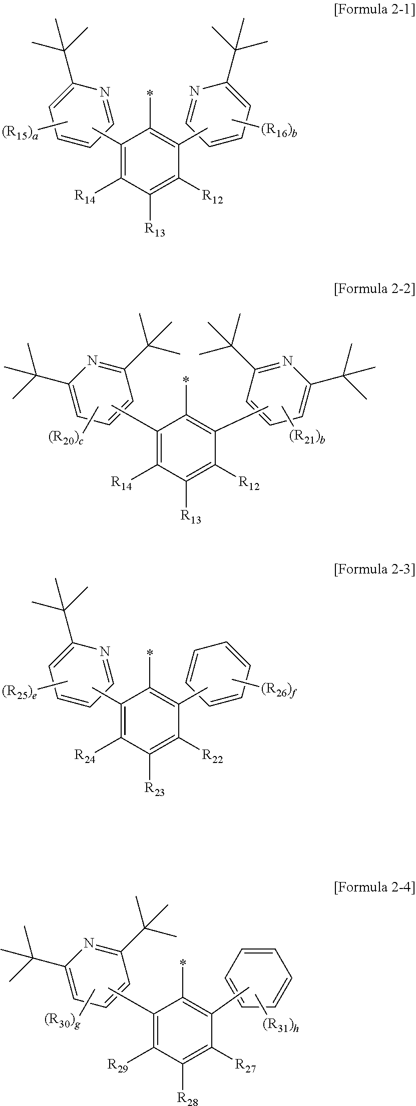
wherein in Formula 2-1 to Formula 2-4,
R₁₂ to R₃₁ are each independently a hydrogen atom, a deuterium atom, a halogen atom, a cyano group, a substituted or unsubstituted amine group, a substituted or unsubstituted silyl group, a substituted or unsubstituted alkyl group having 1 to 10 carbon atoms, a substituted or unsubstituted cycloalkyl group having 3 to 10 ring-forming carbon atoms, a substituted or unsubstituted aryl group having 6 to 60 ring-forming carbon atoms, a substituted or unsubstituted heterocycloalkyl group having 2 to 10 ring-forming carbon atoms, or a substituted or unsubstituted heteroaryl group having 2 to 60 ring-forming carbon atoms,
a, b, and e are each independently an integer from 0 to 3,
c, d, and g are each independently an integer from 0 to 2, and
f and h are each independently an integer from 0 to 5.

15. The polycyclic compound of claim 14, wherein
Formula 2-1 is represented by Formula 3-1,
Formula 2-2 is represented by Formula 3-2,
Formula 2-3 is represented by Formula 3-3, and
Formula 2-4 is represented by Formula 3-4: 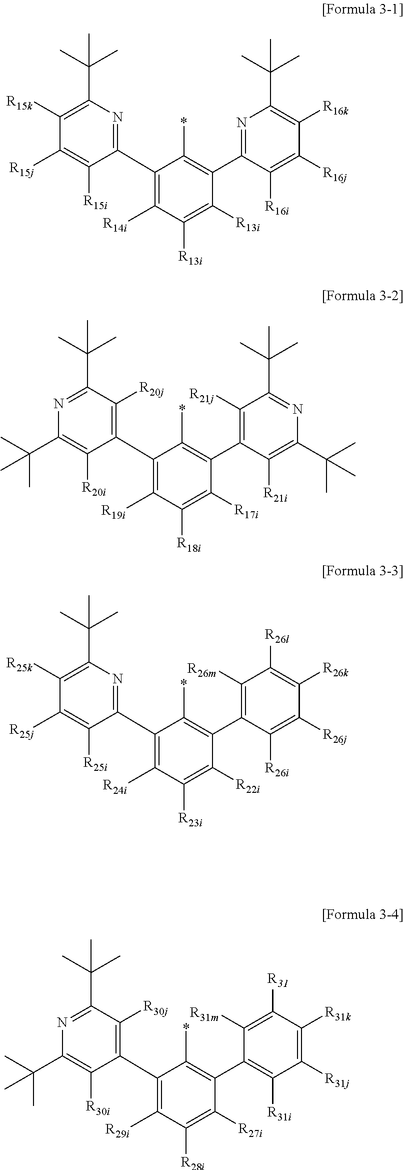
wherein in Formula 3-1 to Formula 3-4,
R₁₂ᵢ, R₁₃ᵢ, R₁₄ᵢ, R₁₅ᵢ to R₁₅ₖ, R₁₆ᵢ to R₁₆ₖ, R₁₇ᵢ, R₁₈ᵢ, R₁₉ᵢ, R₂₀ᵢ, R₂₀ⱼ, R₂₁ᵢ, R₂₁ⱼ, R₂₂ᵢ, R₂₃ᵢ, R₂₄ᵢ, R₂₅ᵢ to R₂₅ₖ, R₂₆ᵢ to R₂₆ₘ, R₂₇ᵢ, R₂₈ᵢ, R₂₉ᵢ, R₃₀ᵢ, R₃₀ⱼ, and R₃₁ᵢ to R₃₁ₘ are each independently a hydrogen atom, a deuterium atom, a substituted or unsubstituted alkyl group having 1 to 10 carbon atoms, or a substituted or unsubstituted aryl group having 6 to 60 ring-forming carbon atoms.

16. The polycyclic compound of claim 14, wherein Formula 1 is represented by Formula 4: 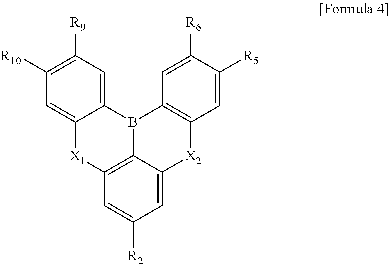
wherein in Formula 4,
R₂, R₅, R₆, R₉, R₁₀, X₁, and X₂ are the same as defined in Formula 1.

17. The polycyclic compound of claim 16, wherein Formula 4 is represented by one of Formula 4-1 to Formula 4-3: 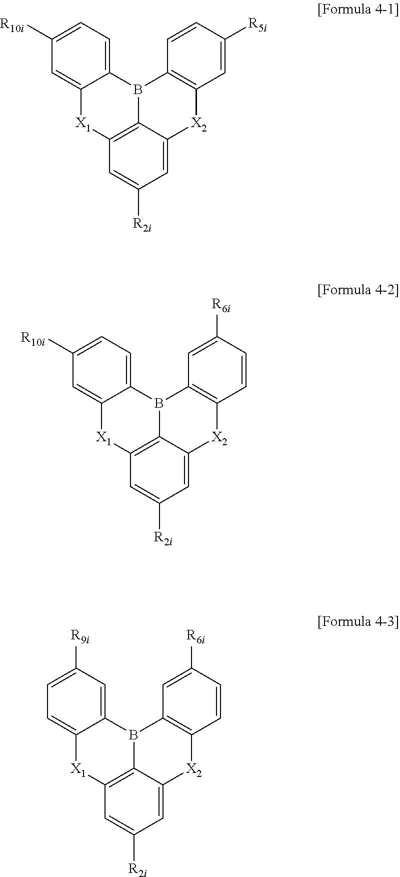
wherein in Formula 4-1 to Formula 4-3,
R₂ᵢ, R₅ᵢ, R₆ᵢ, R₉ᵢ, and R₁₀ᵢ are each independently a hydrogen atom, a deuterium atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms, and
X₁ and X₂ are the same as defined in Formula 1.

18. The polycyclic compound of claim 14, wherein Formula 1 is represented by one of Formula 5-1 to Formula 5-7: 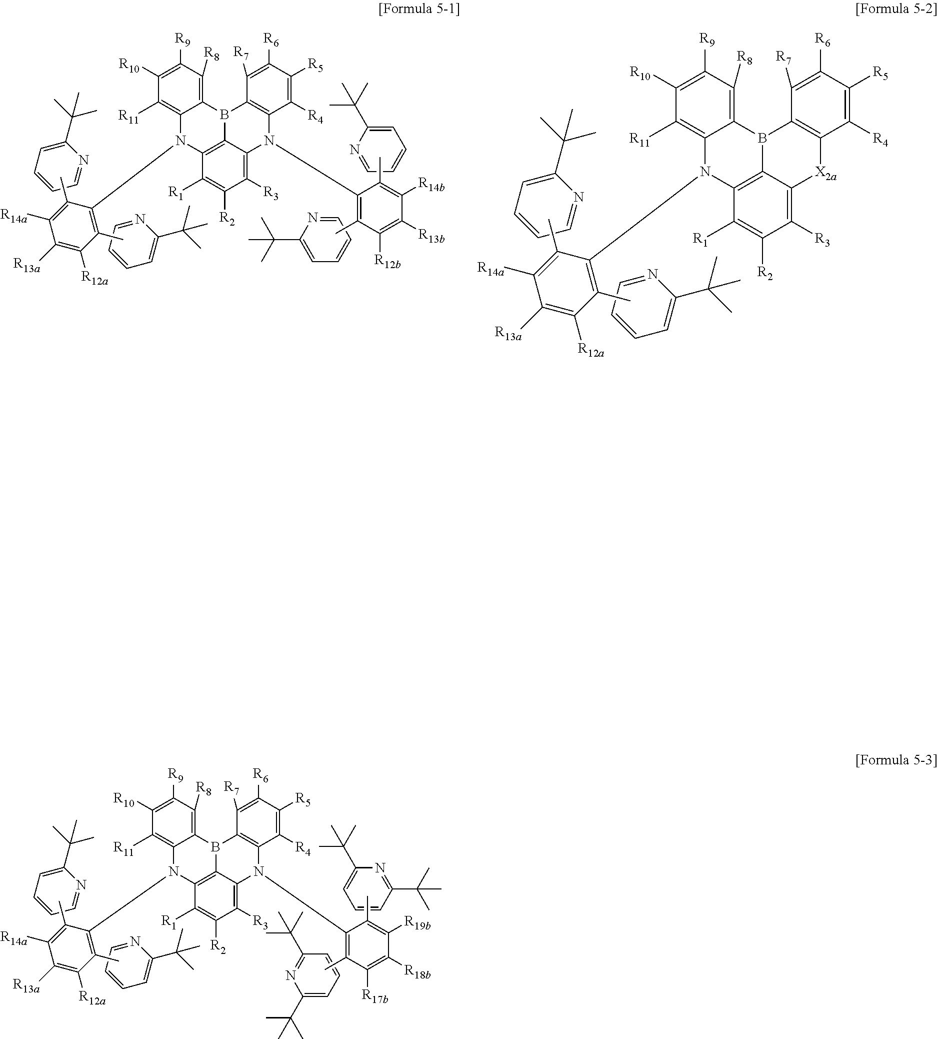 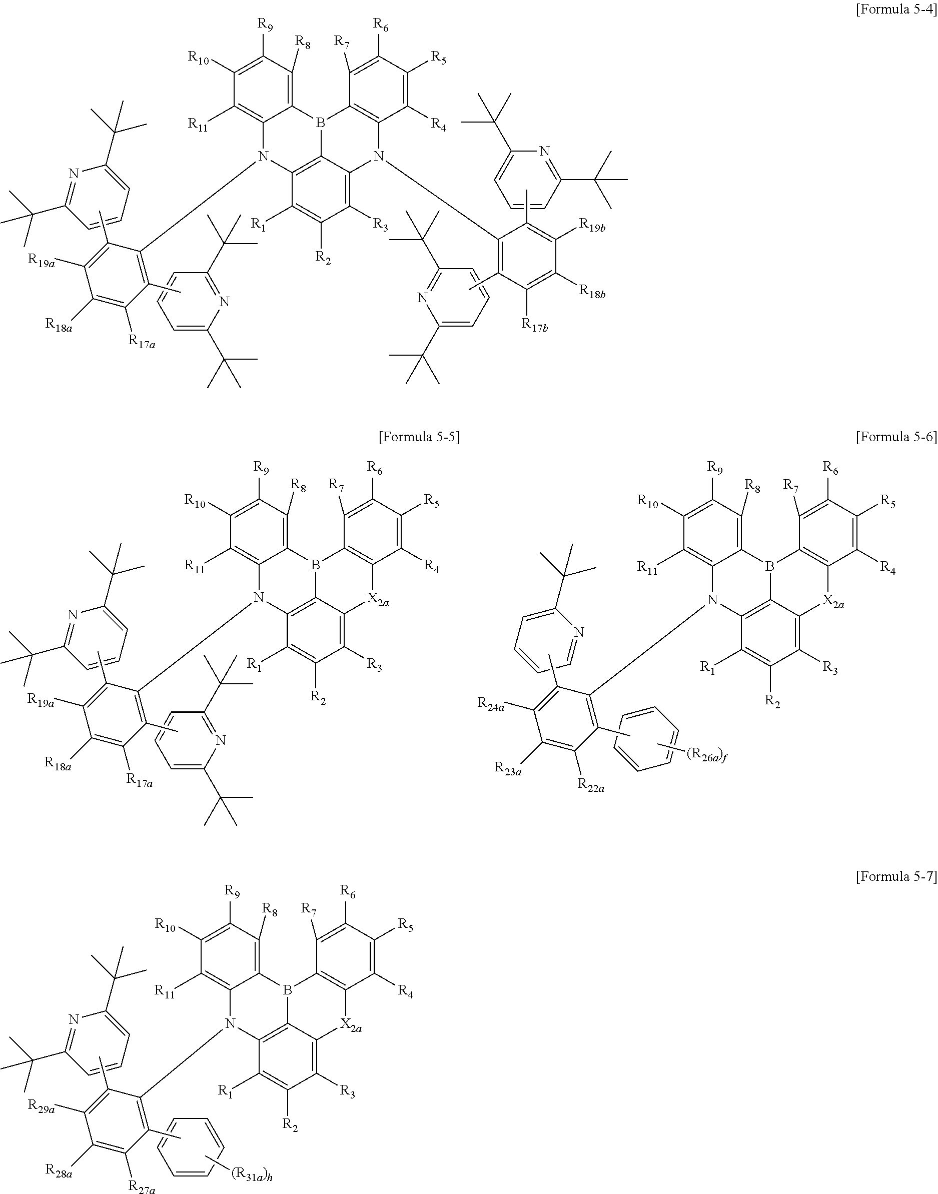
wherein in Formula 5-1 to Formula 5-7,
R₁₂ₐ to R₁₄ₐ, R_{12b} to R_{14b}, R₁₇ₐ to R₁₉ₐ, R_{17b} to R_{19b}, R₂₂ₐ to R₂₄ₐ, R₂₆ₐ, R₂₇ₐ to R₂₉ₐ, and R₃₁ₐ are each independently a hydrogen atom, a deuterium atom, a substituted or unsubstituted alkyl group having 1 to 10 carbon atoms, or a substituted or unsubstituted aryl group having 6 to 60 ring-forming carbon atoms,
X₂ₐ is N(Rₓ₂), O or S, and
f, h, Rₓ₂, and R₁ to R₁₁ are the same as defined in Formula 1.

19. The polycyclic compound of claim 14, wherein Formula 1 is represented by one of Formula 6-1 to Formula 6-7: 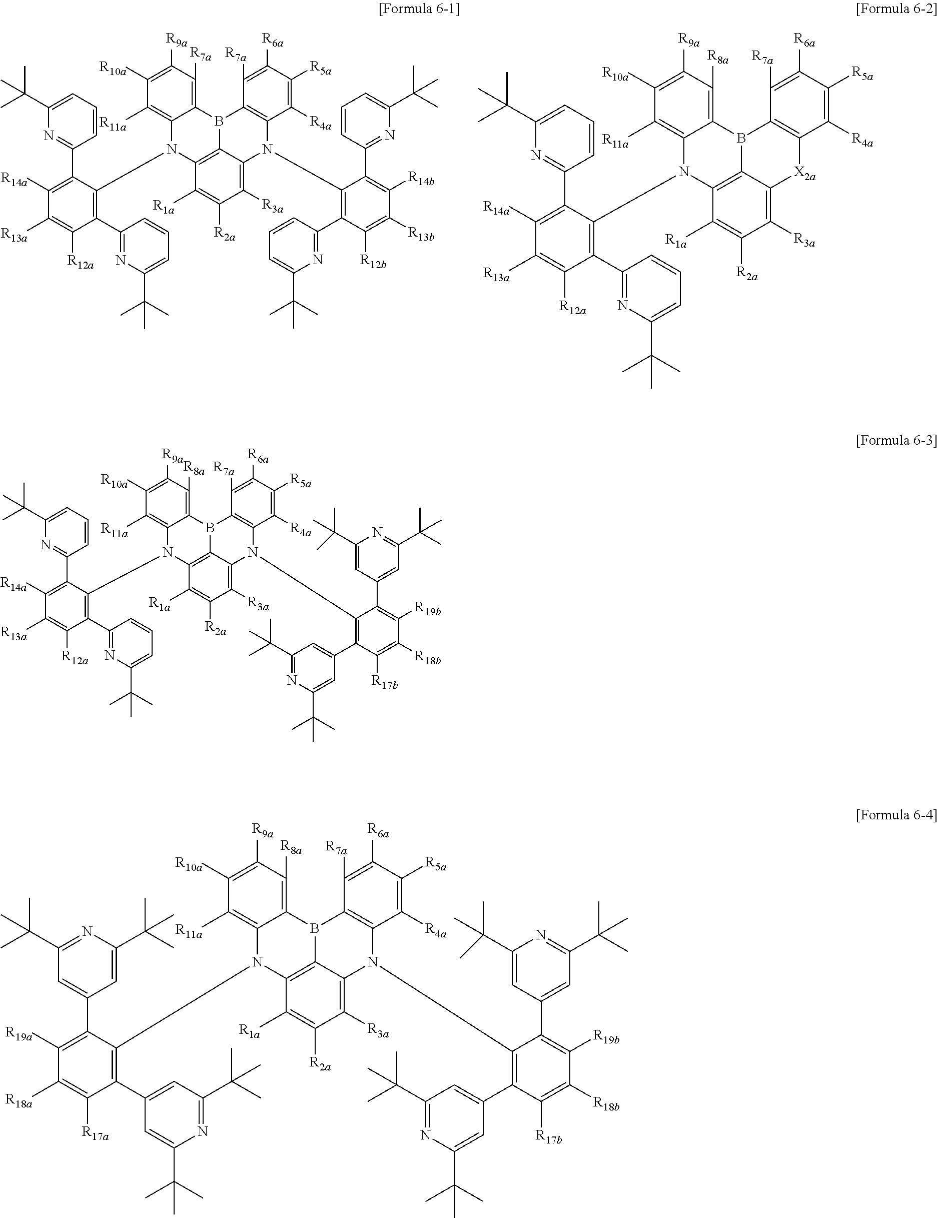 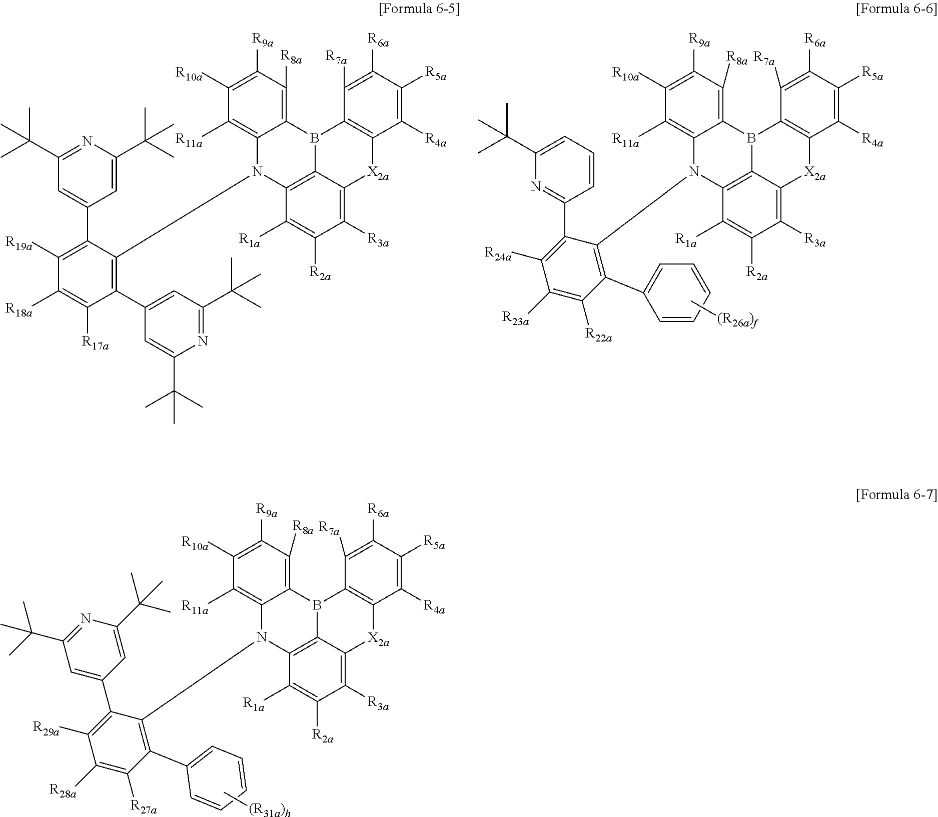
wherein in Formula 6-1 to Formula 6-7,
R₁ₐ to R₁₁ₐ are each independently a hydrogen atom, a deuterium atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms,
R₁₂ₐ to R₁₄ₐ, R_{12b} to R_{14b}, R₁₇ₐ to R₁₉ₐ, R_{17b} to R_{19b}, R₂₂ₐ to R₂₄ₐ, R₂₆ₐ, R₂₇ₐ to R₂₉ₐ, and R₃₁ₐ are each independently a hydrogen atom, a deuterium atom, a substituted or unsubstituted alkyl group having 1 to 10 carbon atoms, or a substituted or unsubstituted aryl group having 6 to 60 ring-forming carbon atoms,
X₂ₐ is N(Rₓ₂), O or S, and
f, h, and Rₓ₂ are the same as defined in Formula 1.

20. The polycyclic compound of claim 14, wherein Formula 1 is represented by one of Formula 7-1 to Formula 7-7: 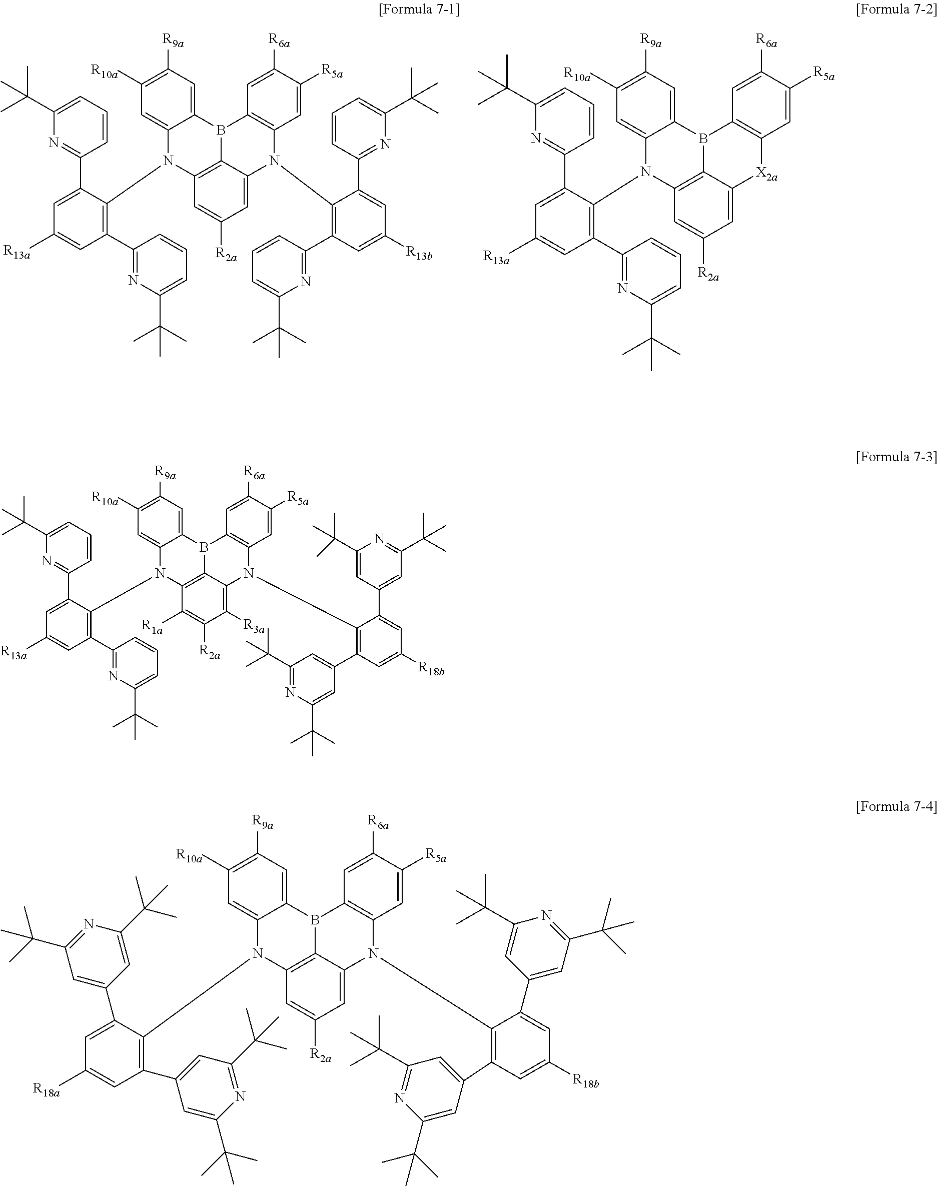 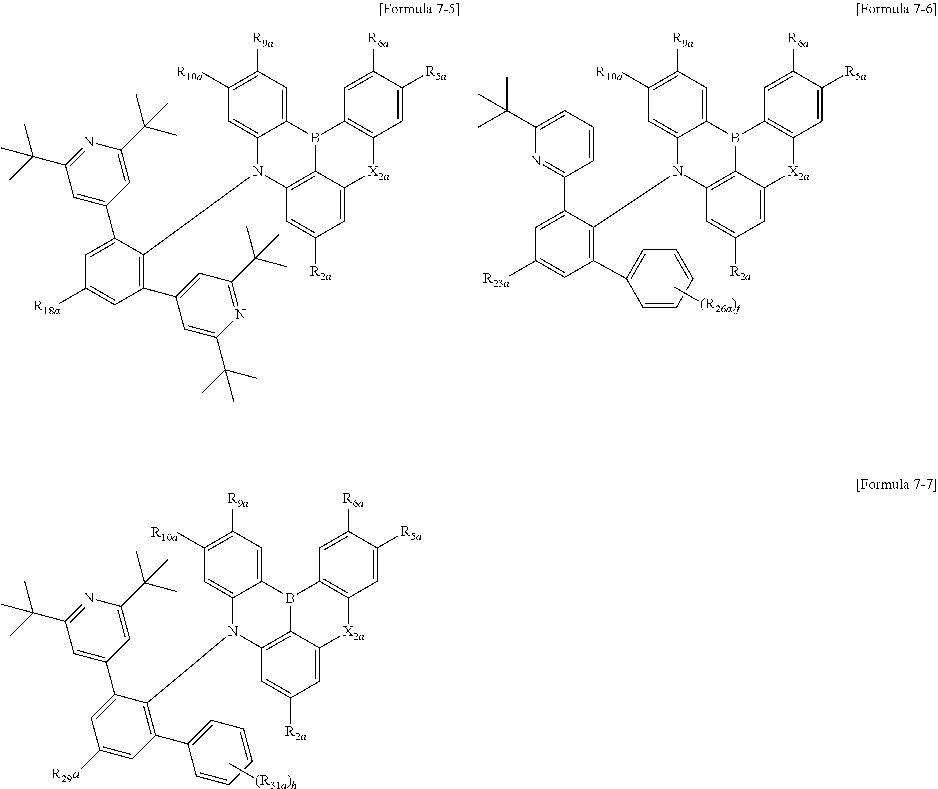
wherein in Formula 7-1 to Formula 7-7,
R₂ₐ, R₅ₐ, R₆ₐ, R₉ₐ, and R₁₀ₐ are each independently a hydrogen atom, a deuterium atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms,
R₁₃ₐ, R_{13b} R₁₈ₐ, R_{18b}, R₂₃ₐ, R₂₆ₐ, R₂₈ₐ, and R₃₁ₐ are each independently a hydrogen atom, a deuterium atom, a substituted or unsubstituted alkyl group having 1 to 10 carbon atoms, or a substituted or unsubstituted aryl group having 6 to 60 ring-forming carbon atoms,
X₂ₐ is N(Rₓ₂), O or S, and
f, h, and Rₓ₂ are the same as defined in Formula 1.

21. The polycyclic compound of claim 14, wherein Rₓ₂ is a substituted or unsubstituted aryl group having 6 to 30 ring-forming carbon atoms.

22. The polycyclic compound of claim 14, wherein R₁₂ to R₃₁ are each independently a hydrogen atom, a deuterium atom, a substituted or unsubstituted t-butyl group, or a substituted or unsubstituted phenyl group.

23. The polycyclic compound of claim 14, wherein R₁ to R₁₁ are each independently:
a hydrogen atom or a deuterium atom; or
a group represented by one of Formula RS-1 to Formula RS-5: 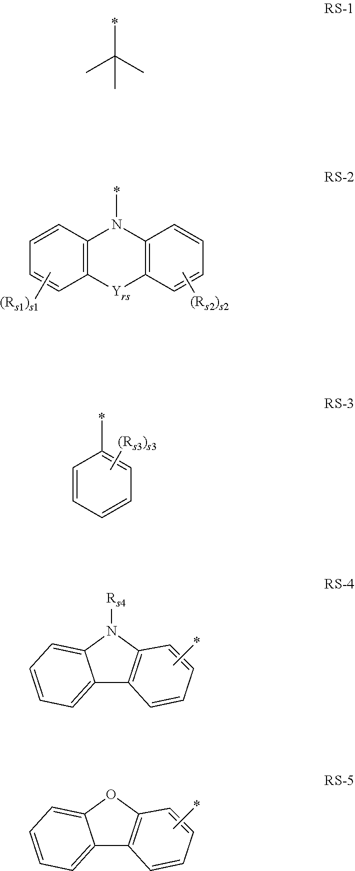
wherein in Formula RS-2,
Yᵣₛ is a direct linkage or C(Rₛₐ₁)(Rₛₐ₂),
Rₛ₁, Rₛ₂, Rₛₐ₁, and Rₛₐ₂ are each independently a hydrogen atom, a deuterium atom, a cyano group, or a substituted or unsubstituted alkyl group having 1 to 10 carbon atoms, or are bonded to an adjacent group to form a ring, and
s1 and s2 are each independently an integer from 0 to 4, and
wherein in Formula RS-3 and Formula RS-4,
Rₛ₃ and Rₛ₄ are each independently a hydrogen atom, a deuterium atom, a substituted or unsubstituted alkyl group having 1 to 10 carbon atoms, or a substituted or unsubstituted aryl group having 6 to 15 ring-forming carbon atoms, and
s3 is an integer from 0 to 5.

24. The polycyclic compound of claim 14, wherein the polycyclic compound represented by Formula 1 is selected from Compound Group 1:
[Compound Group 1] 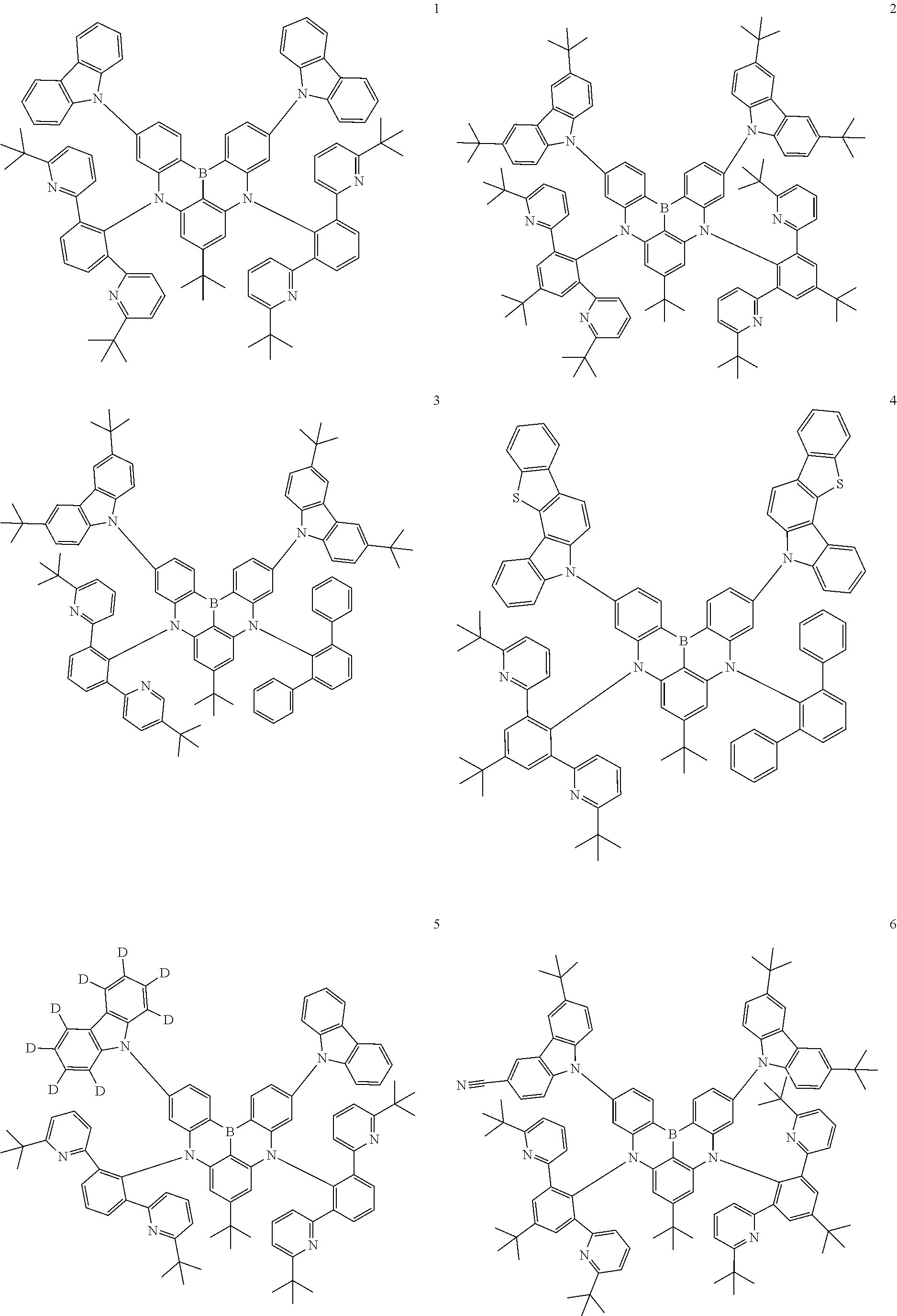 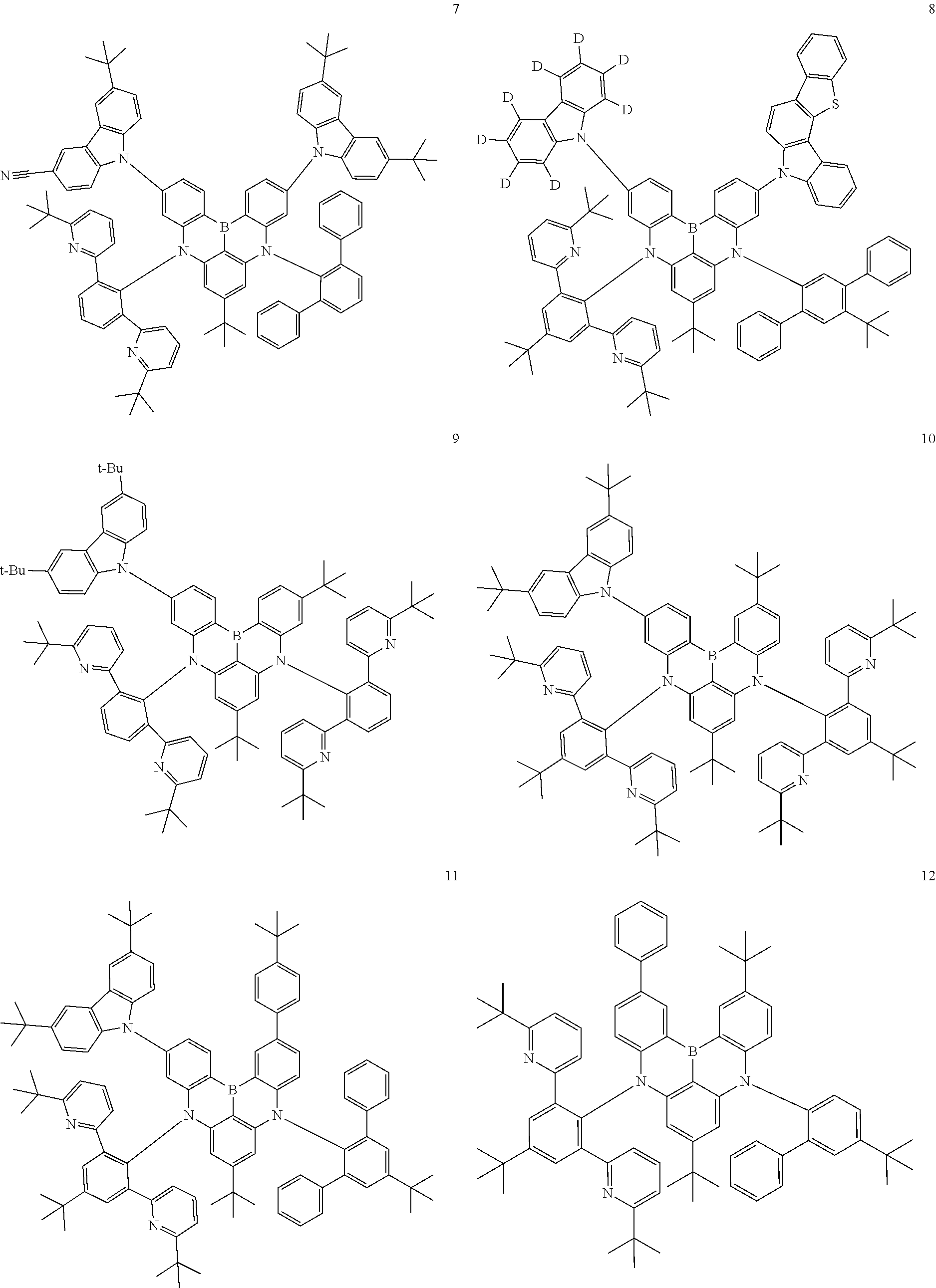 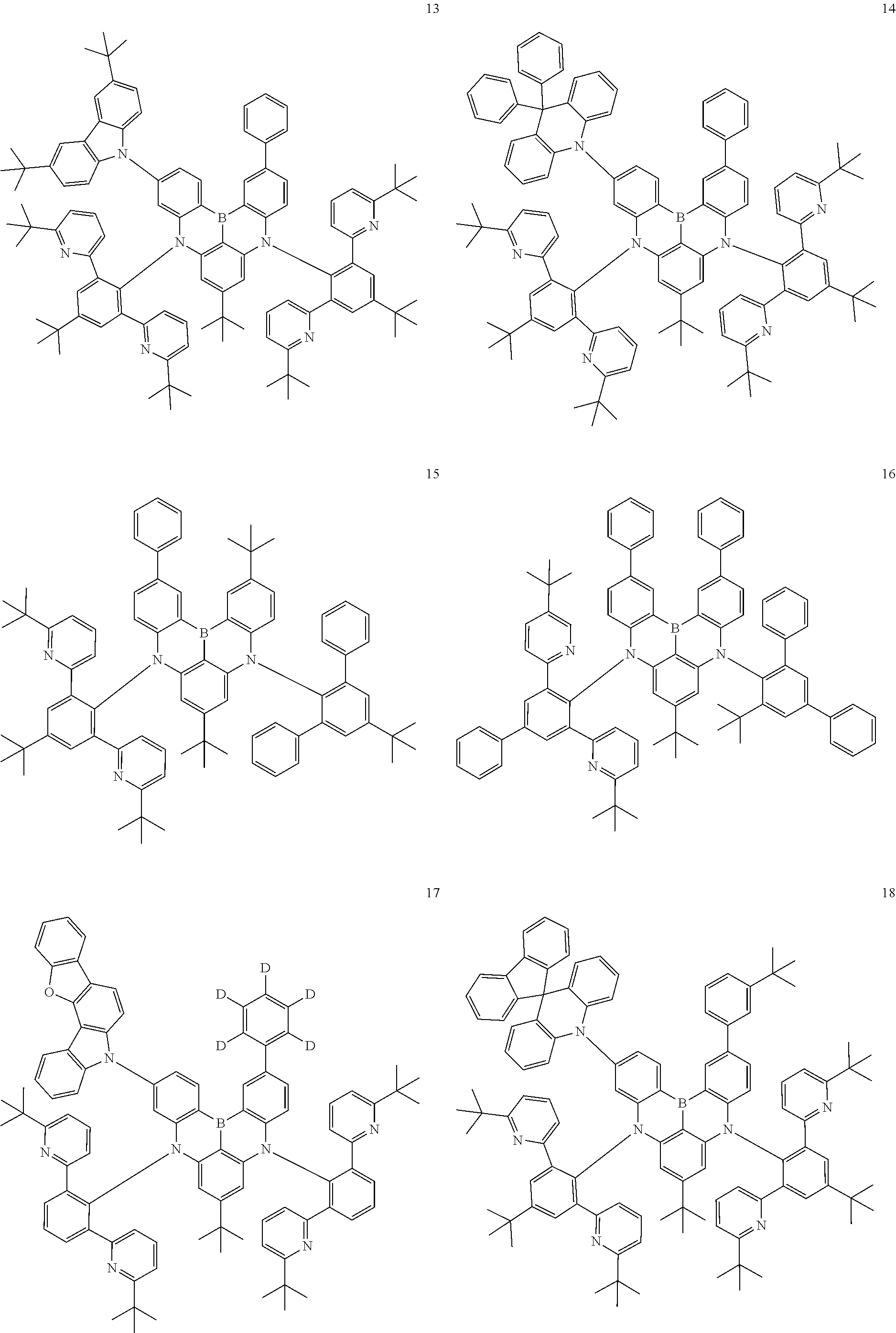 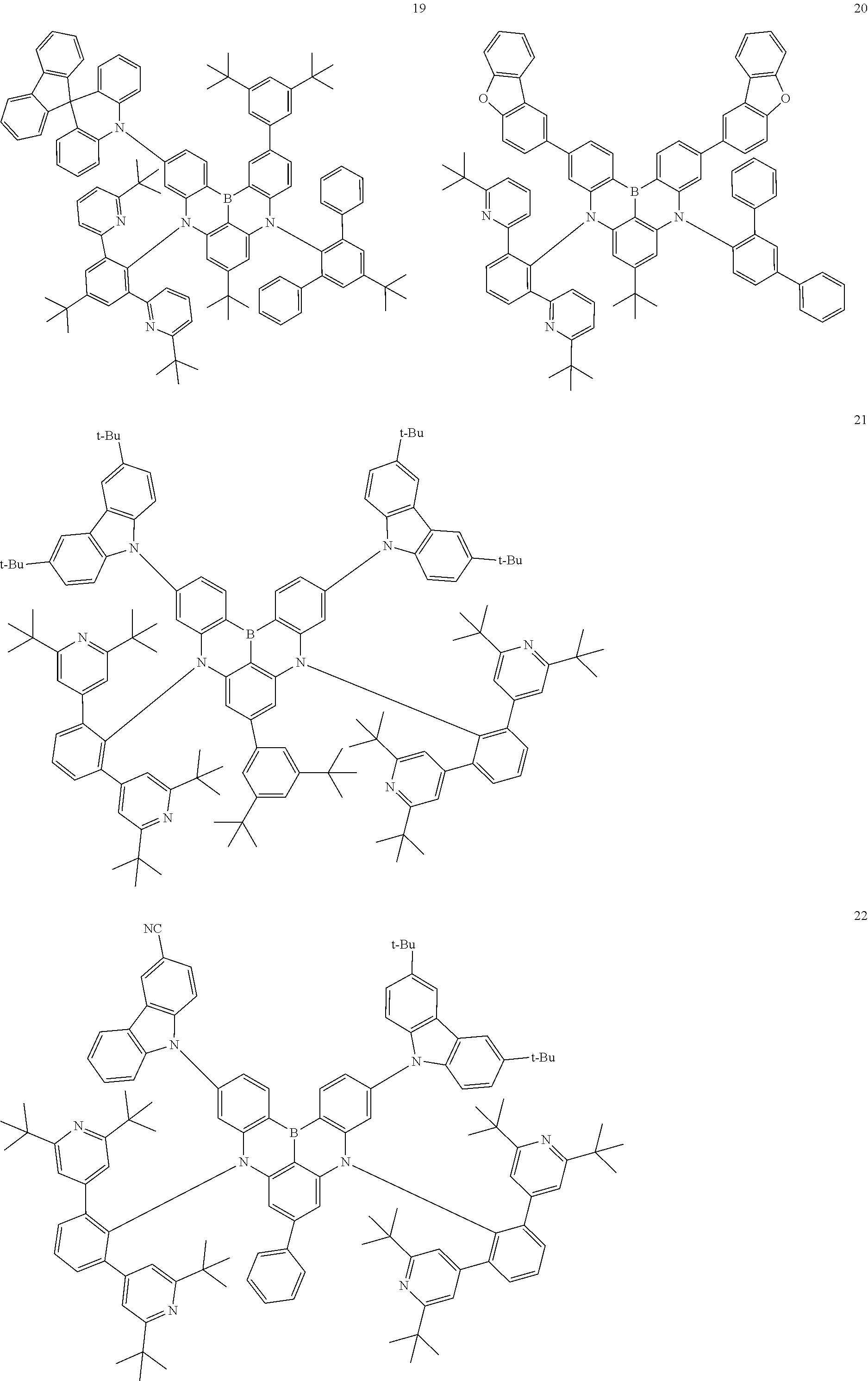 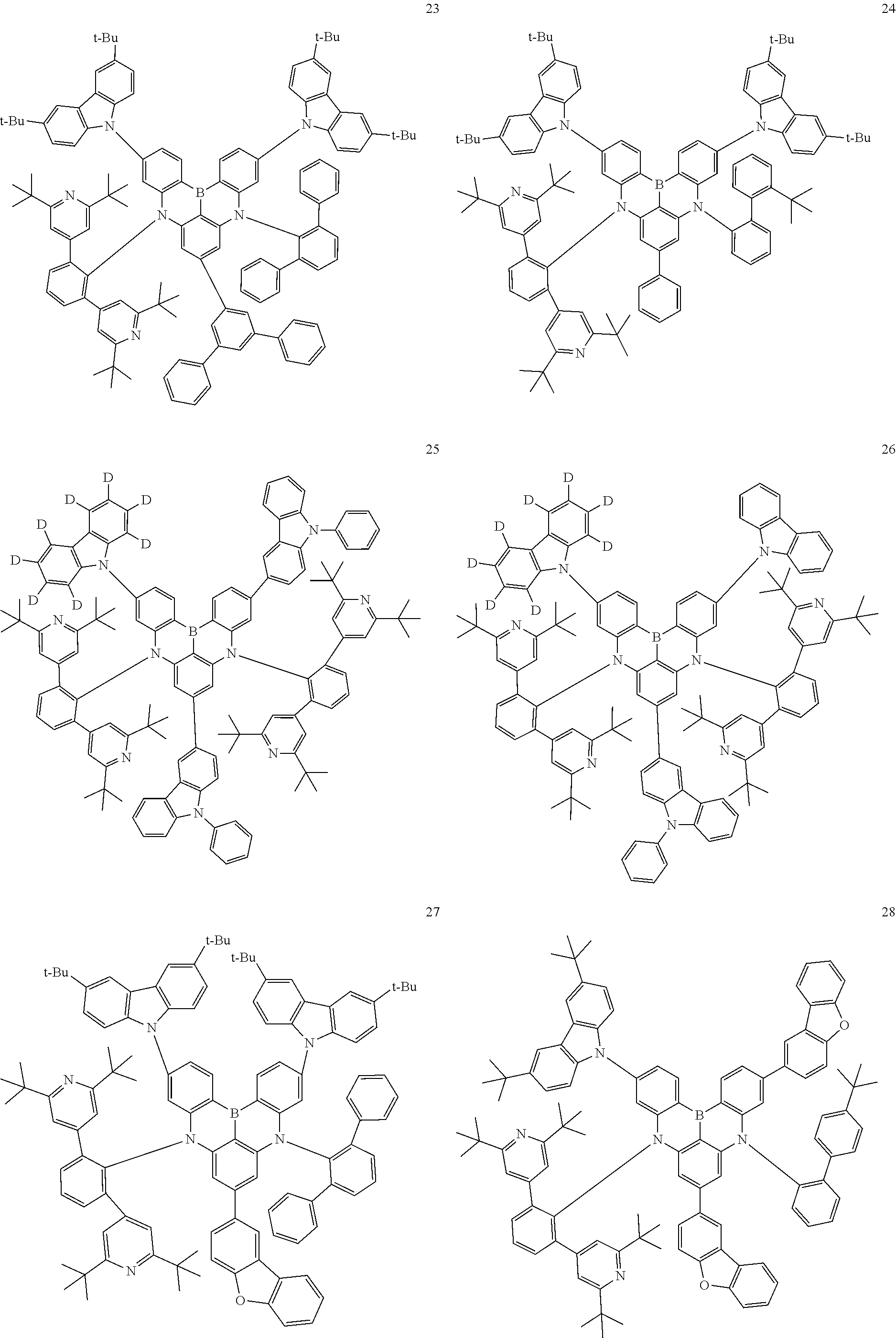 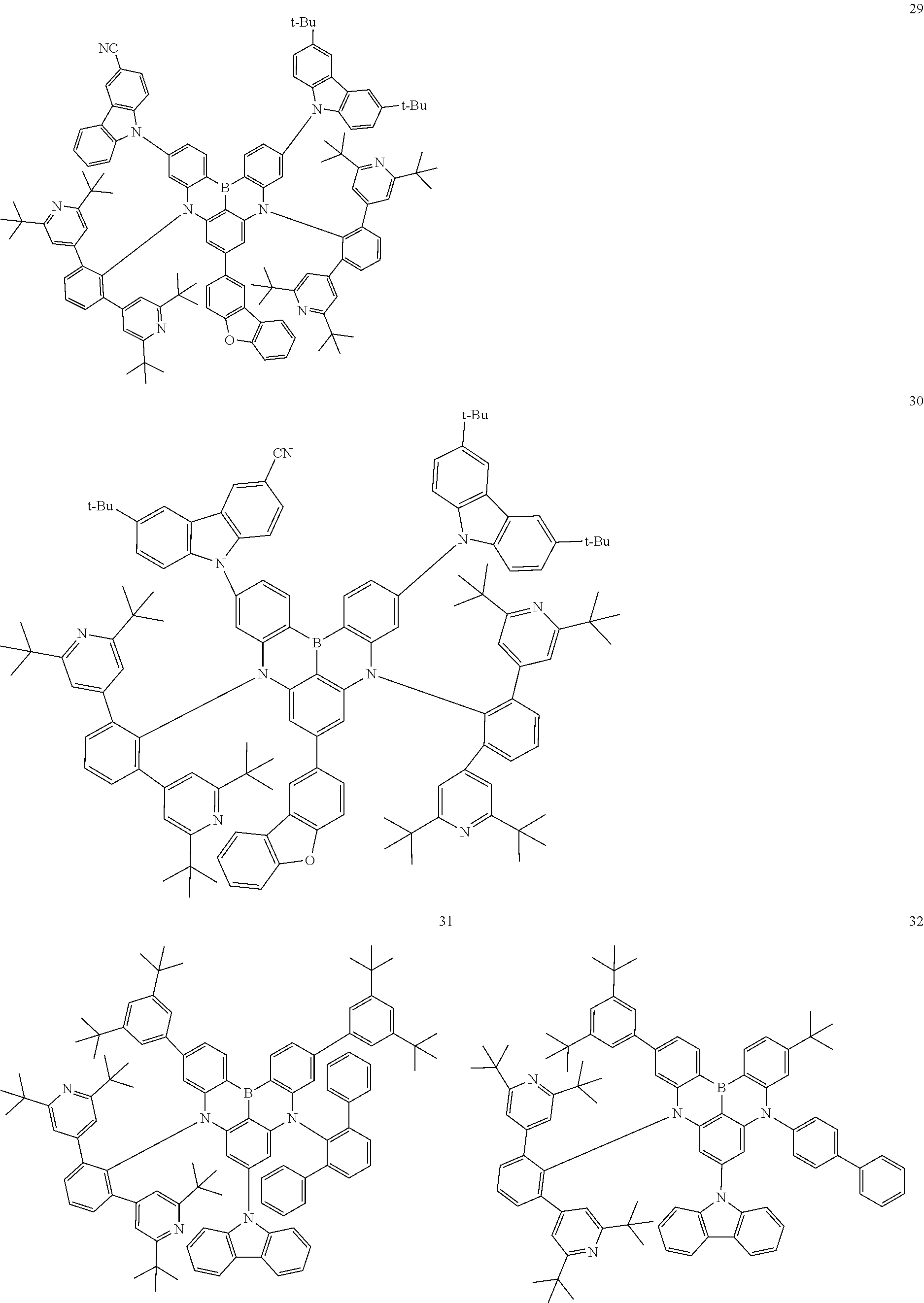 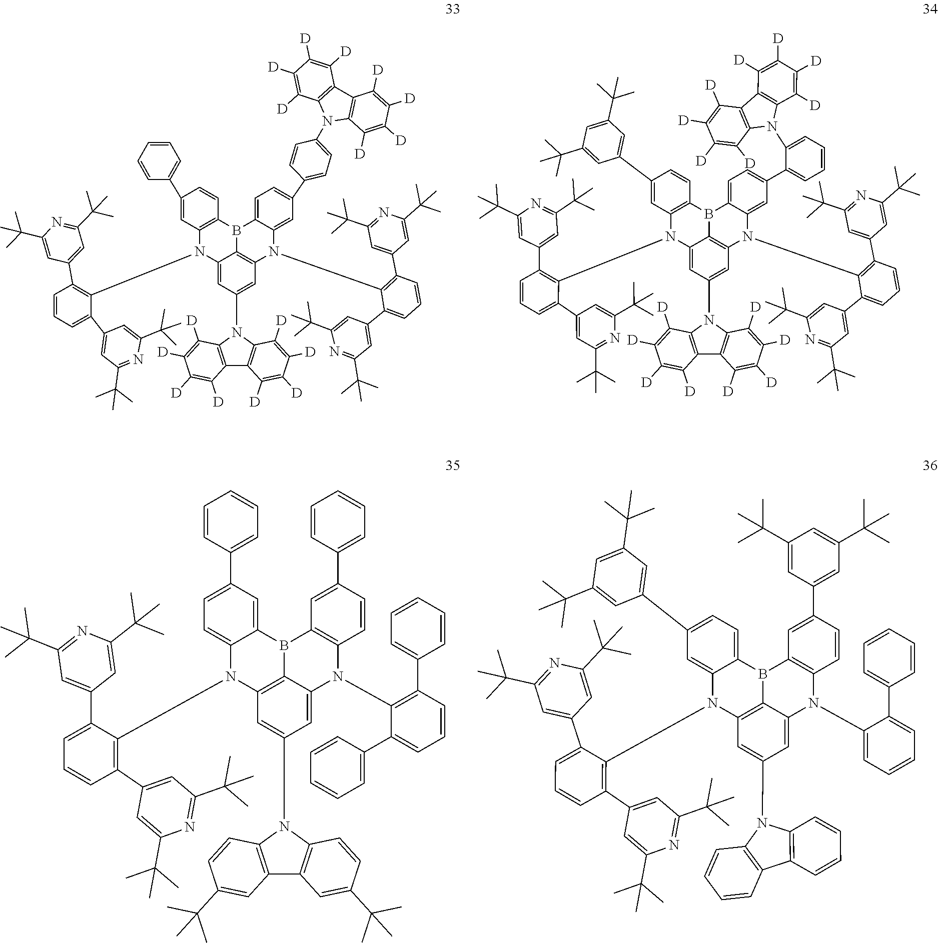 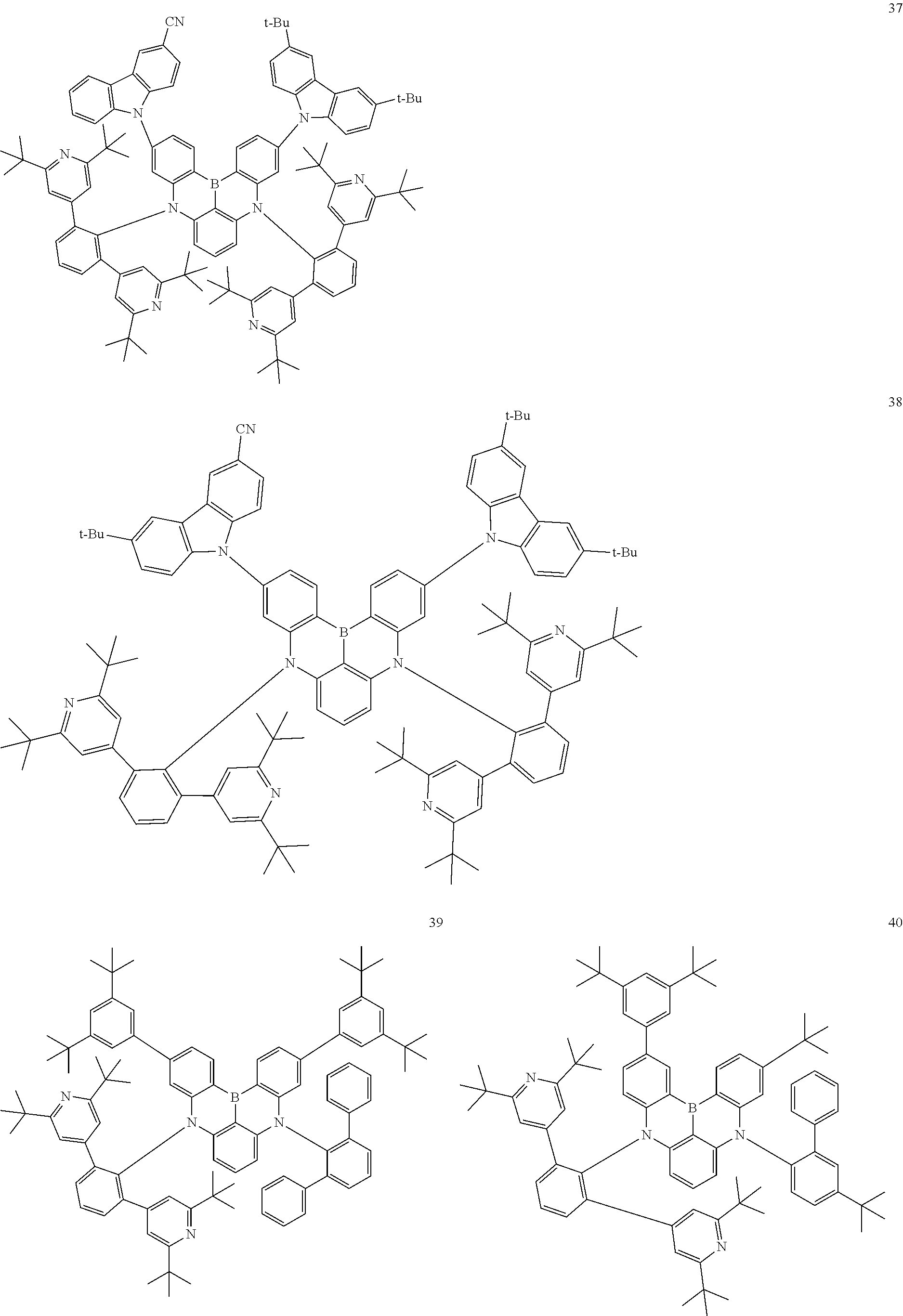 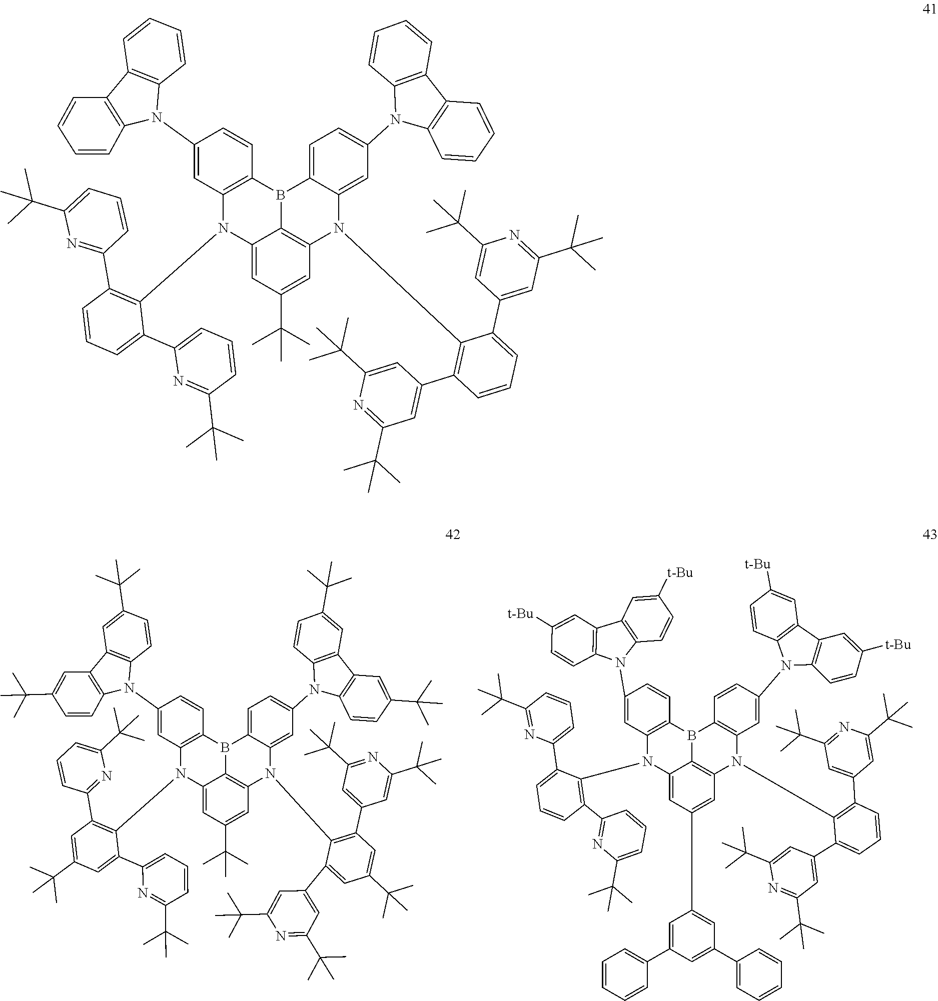 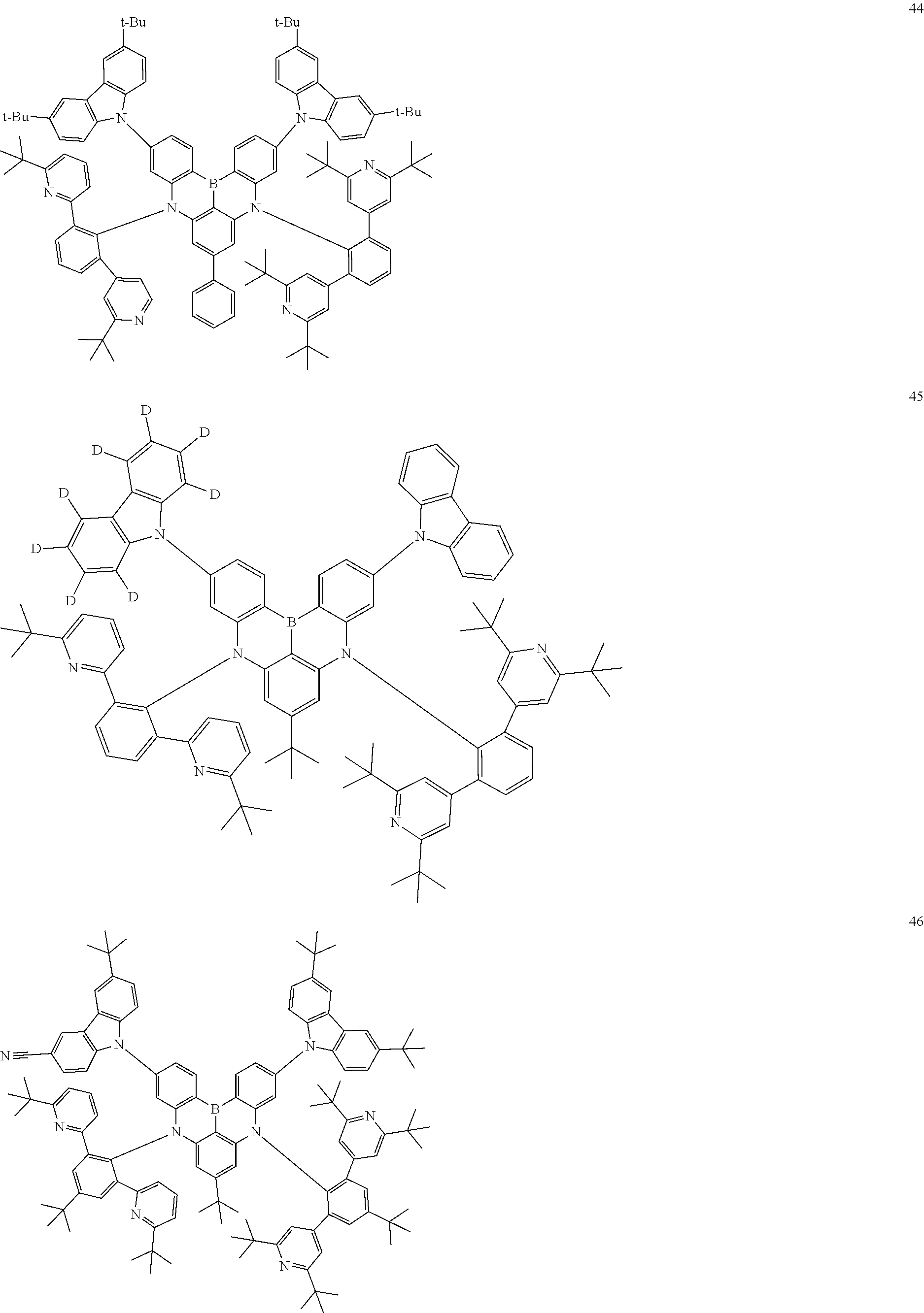 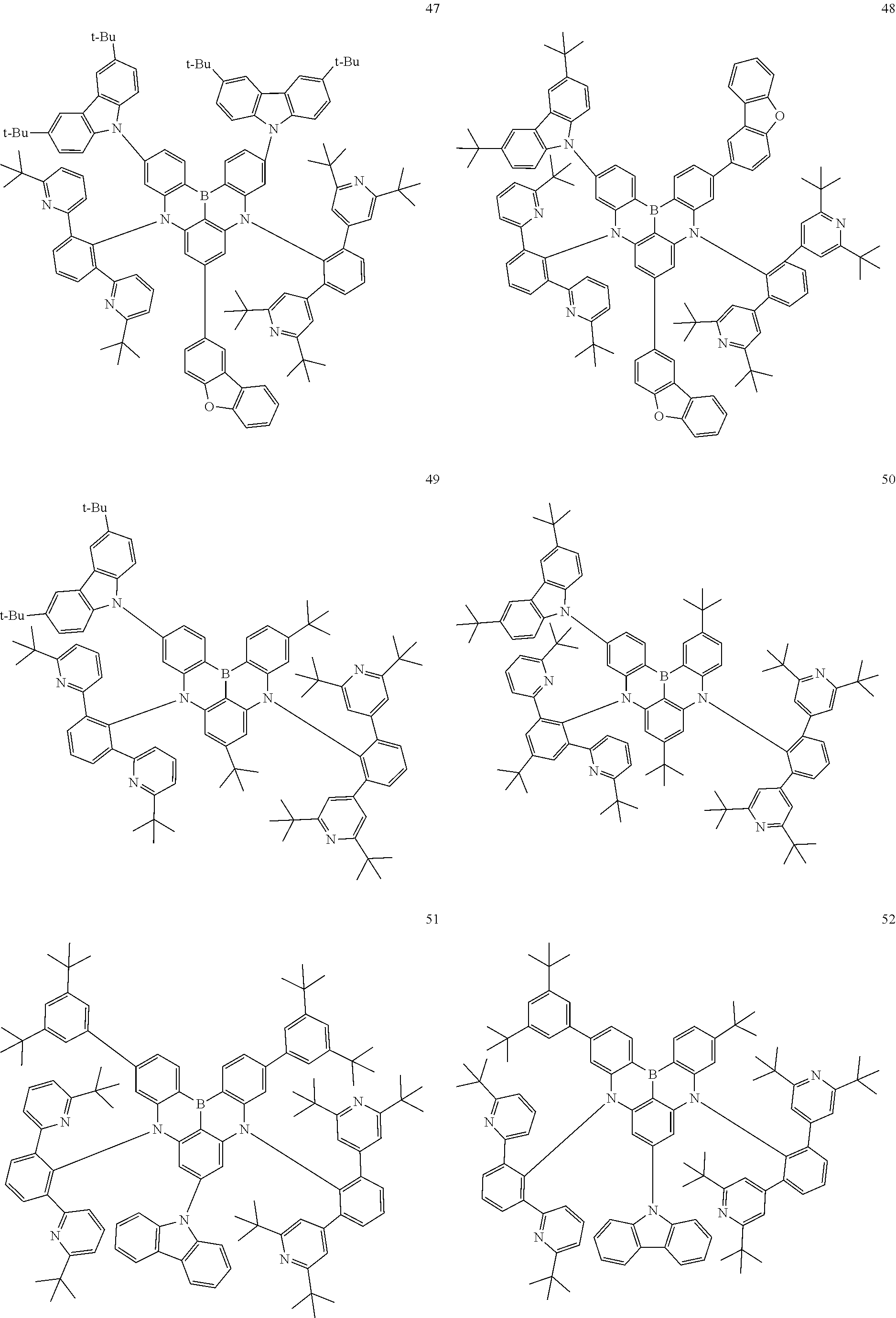 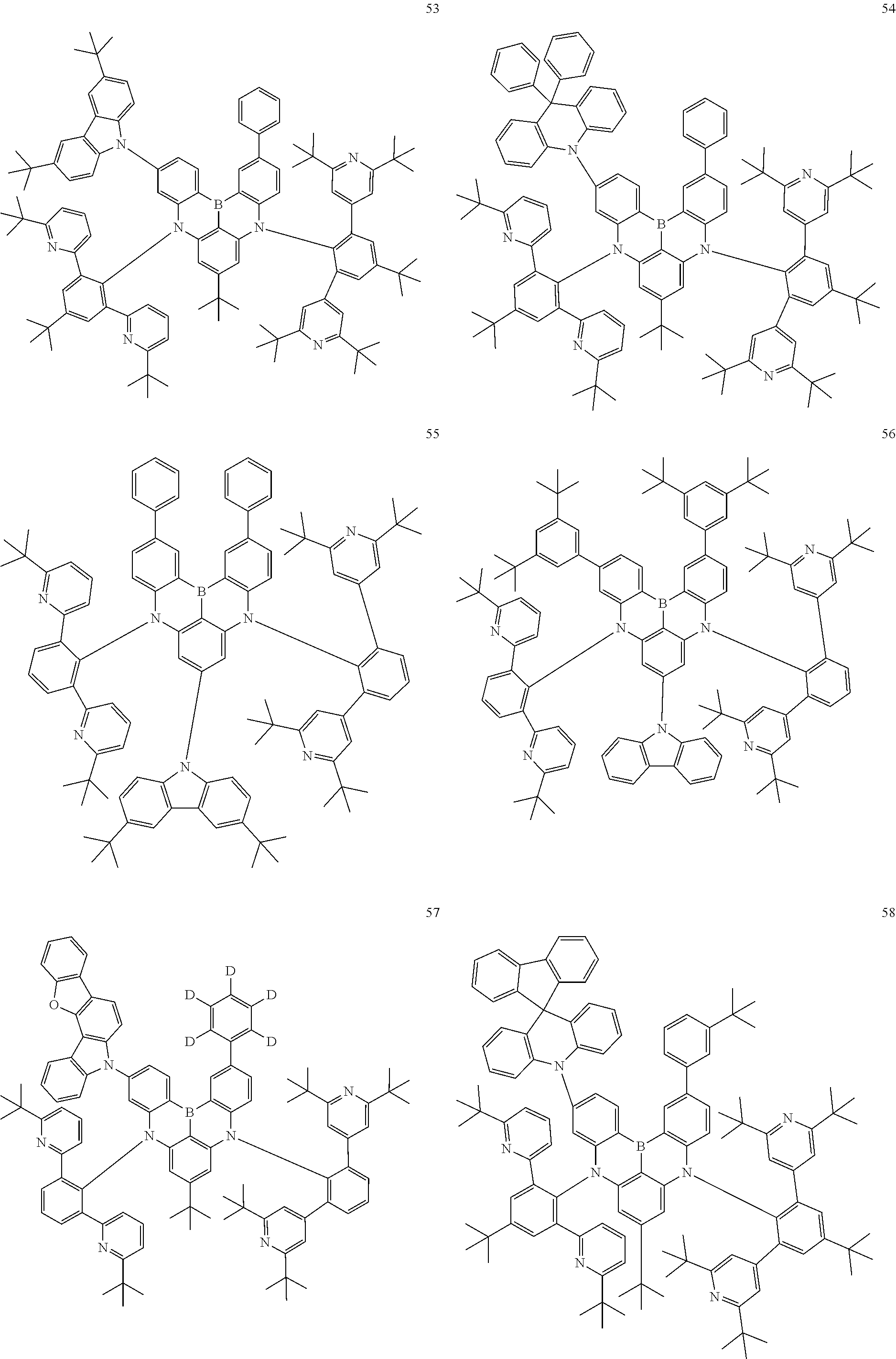 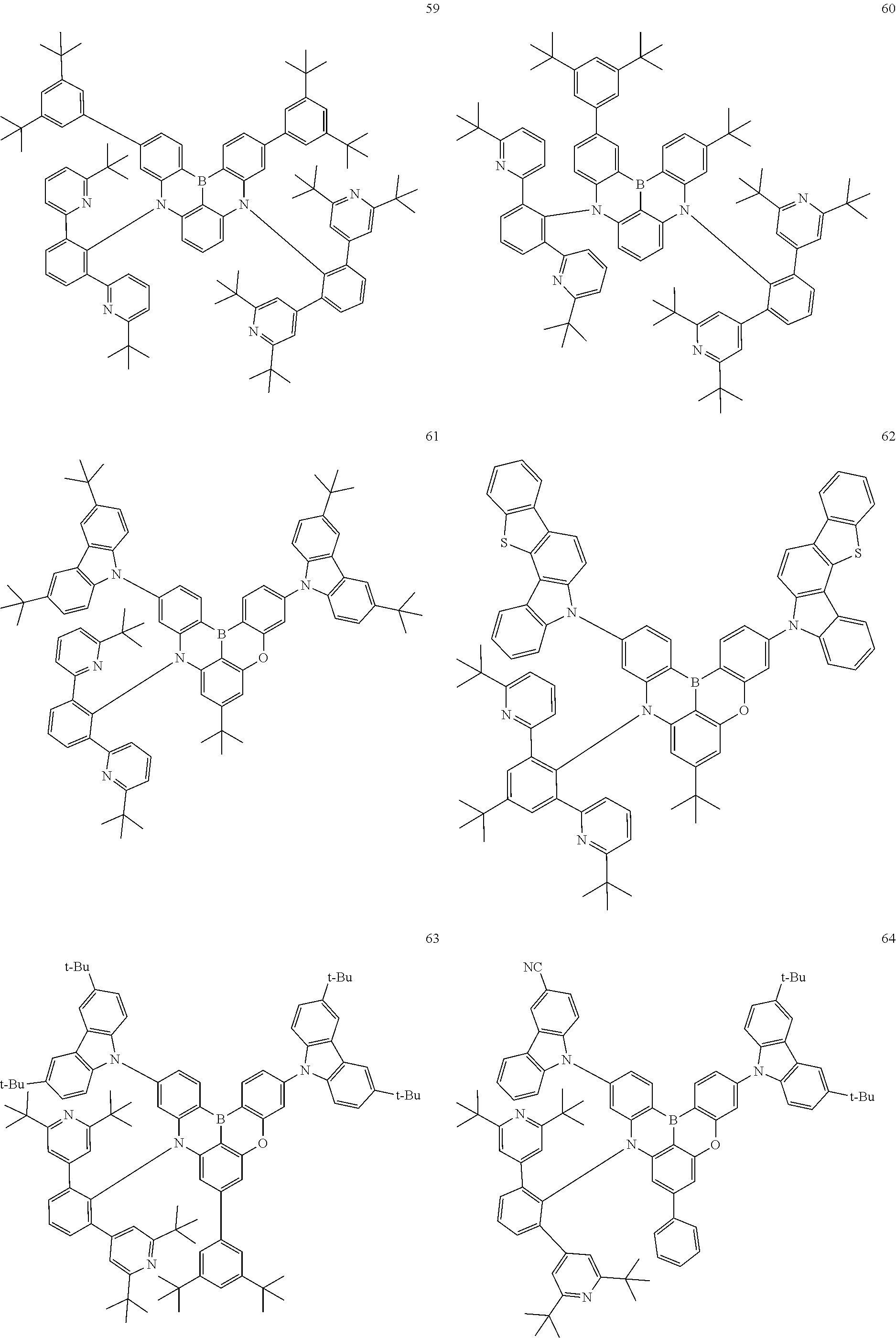 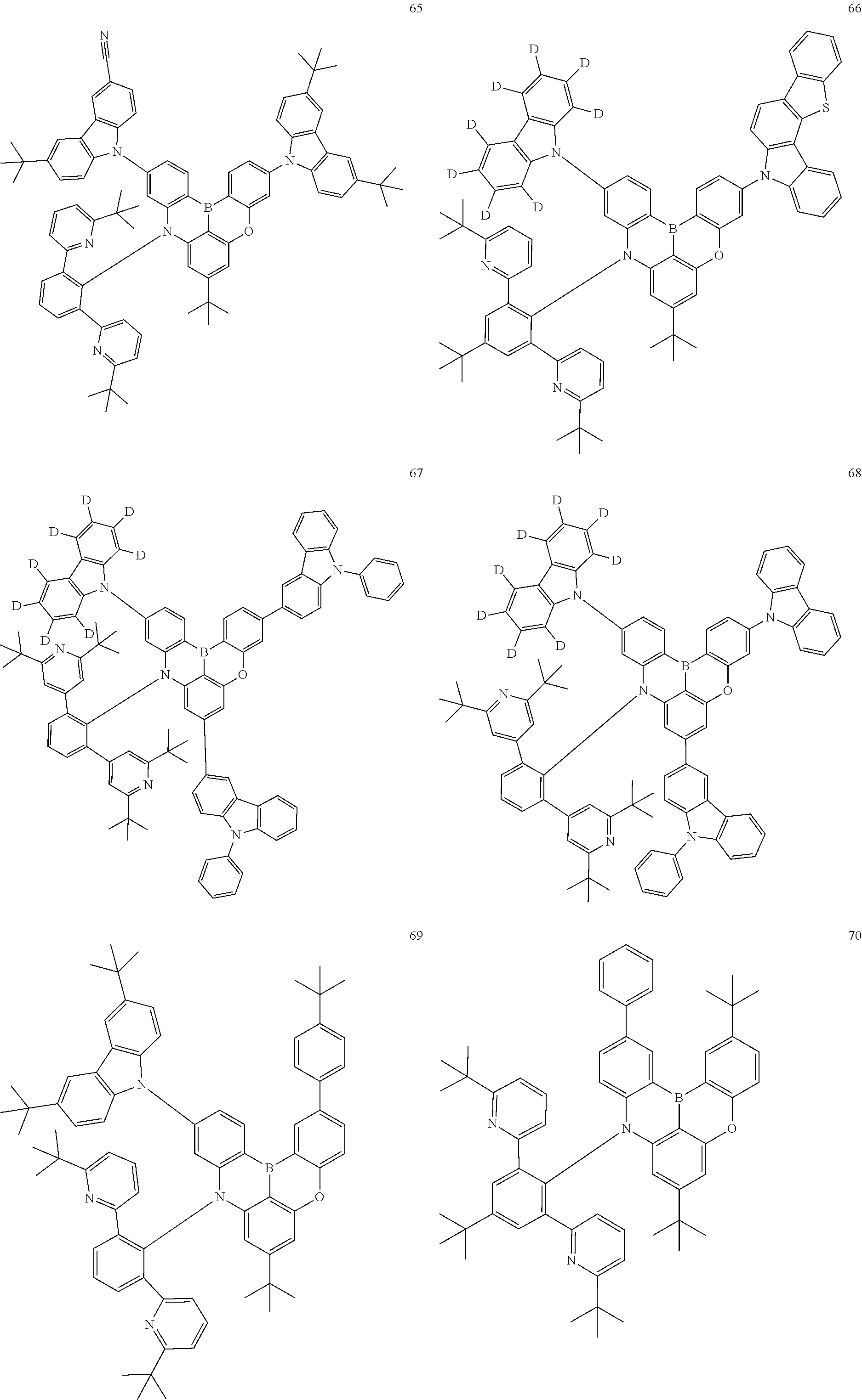 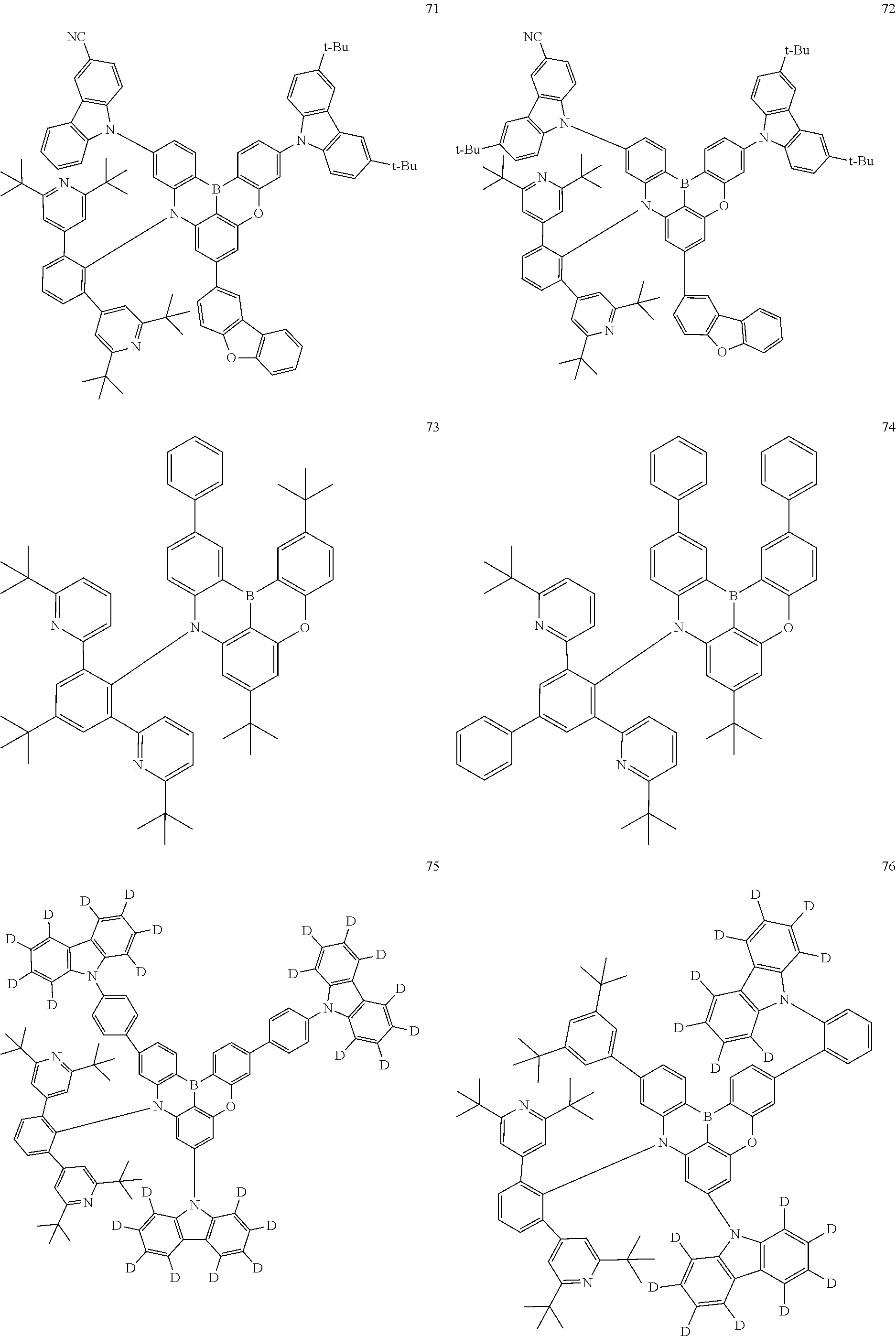 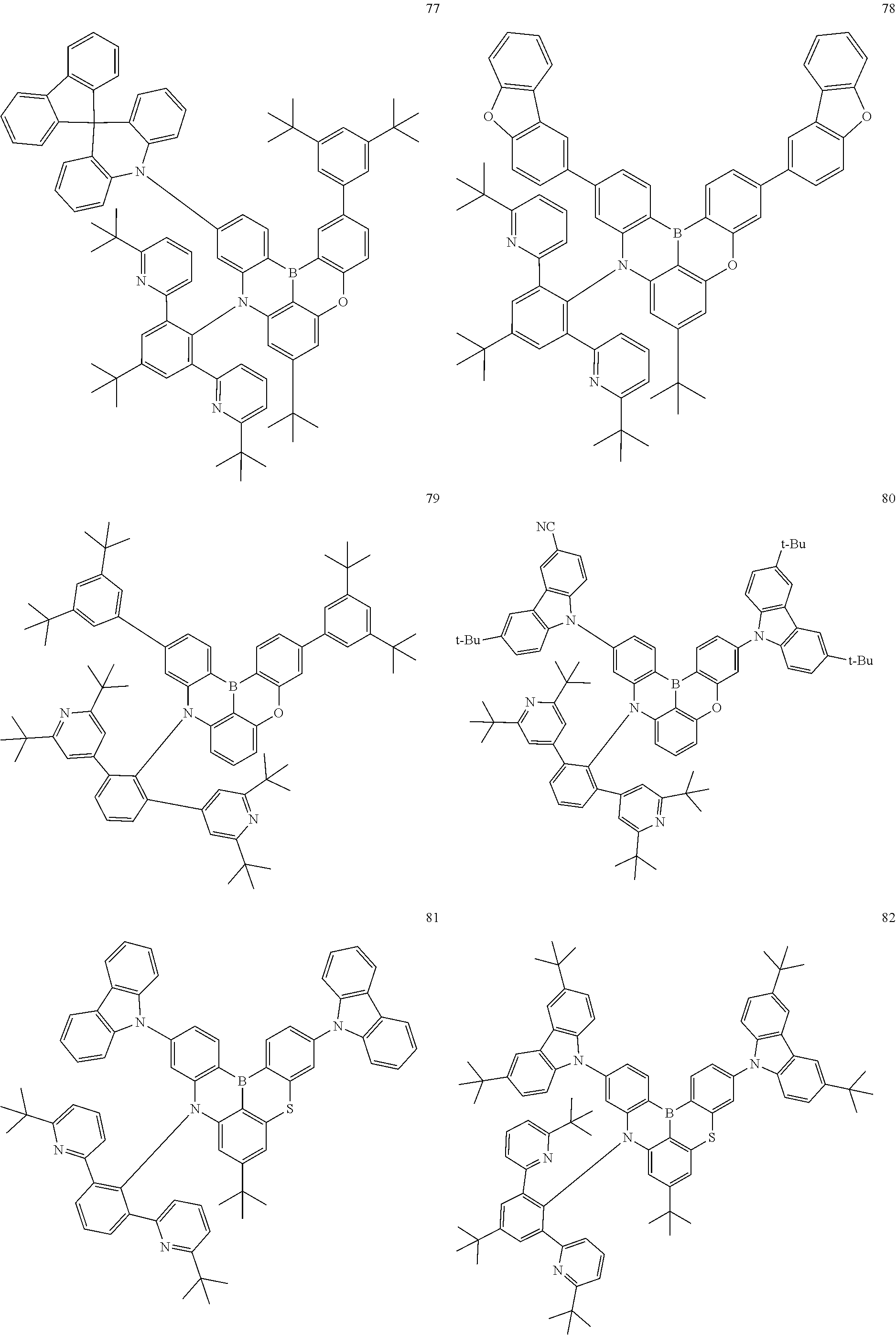 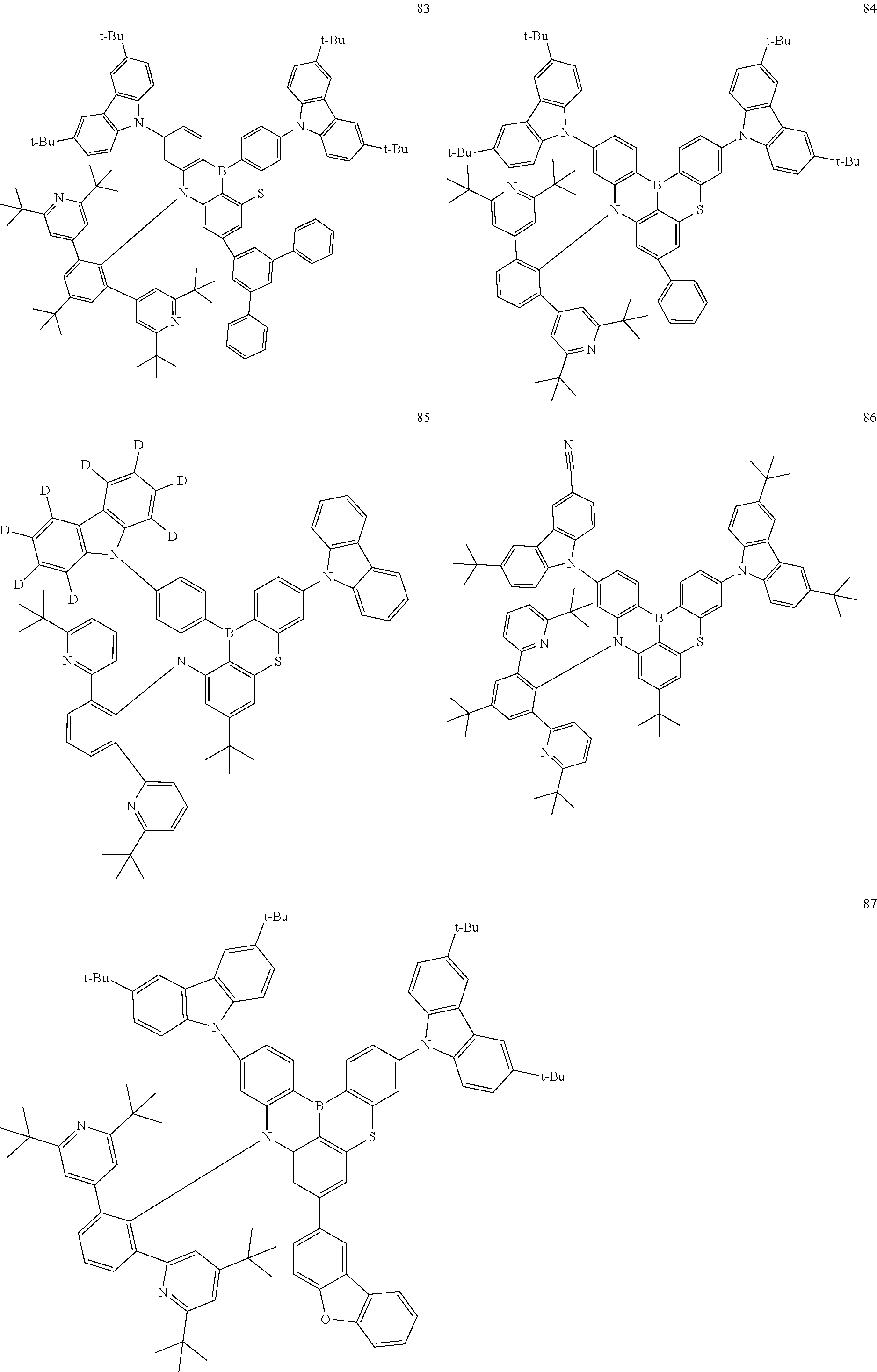 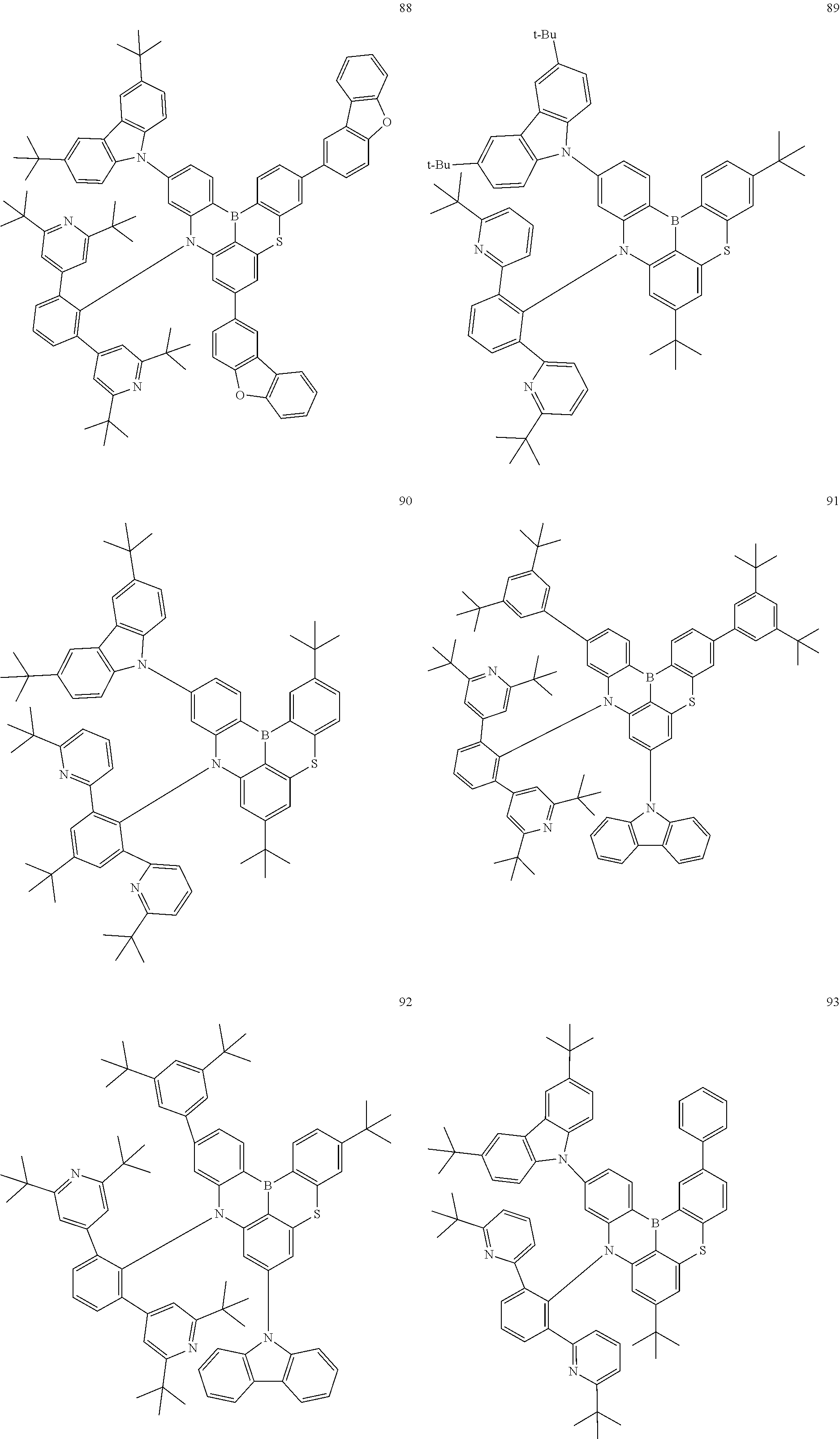 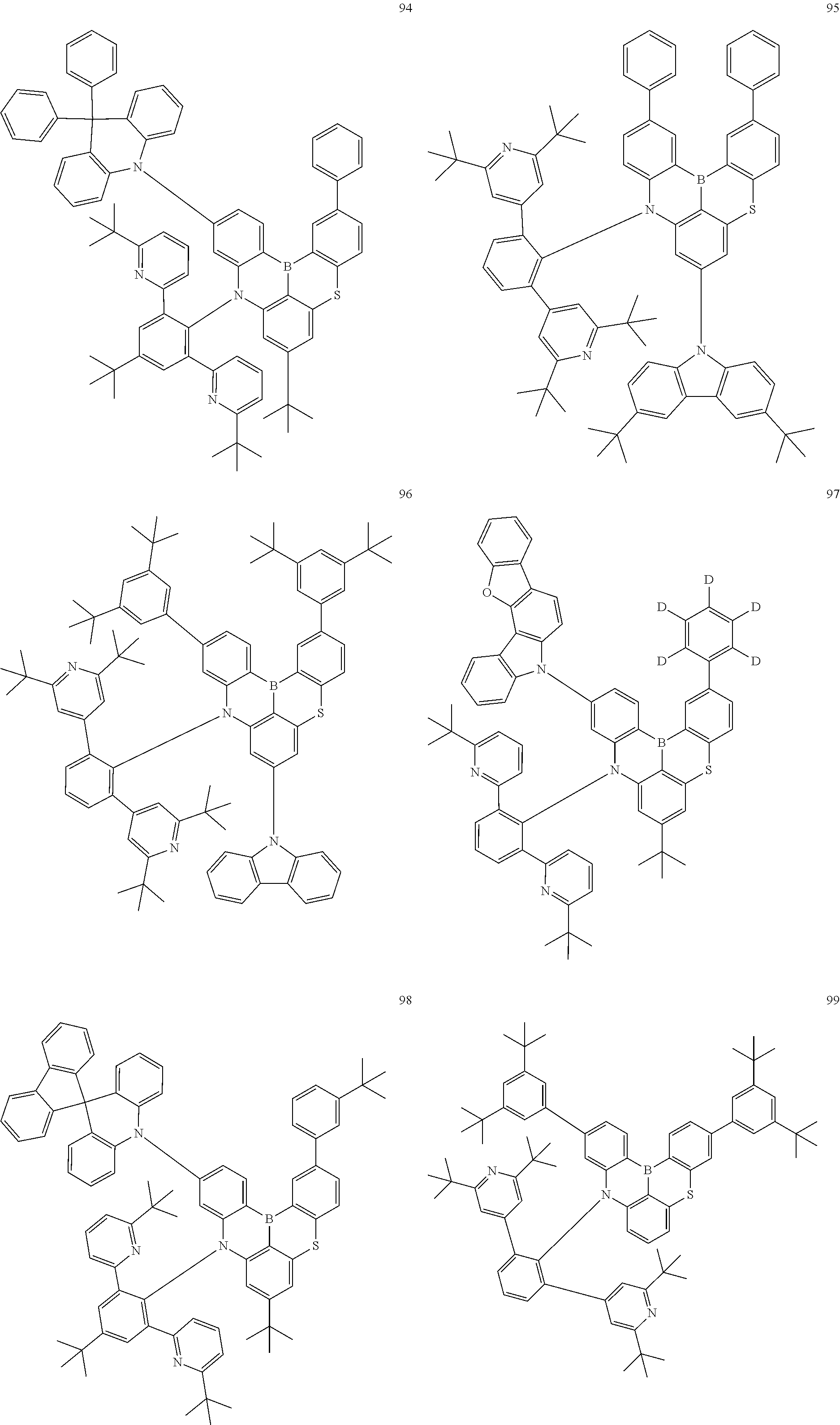 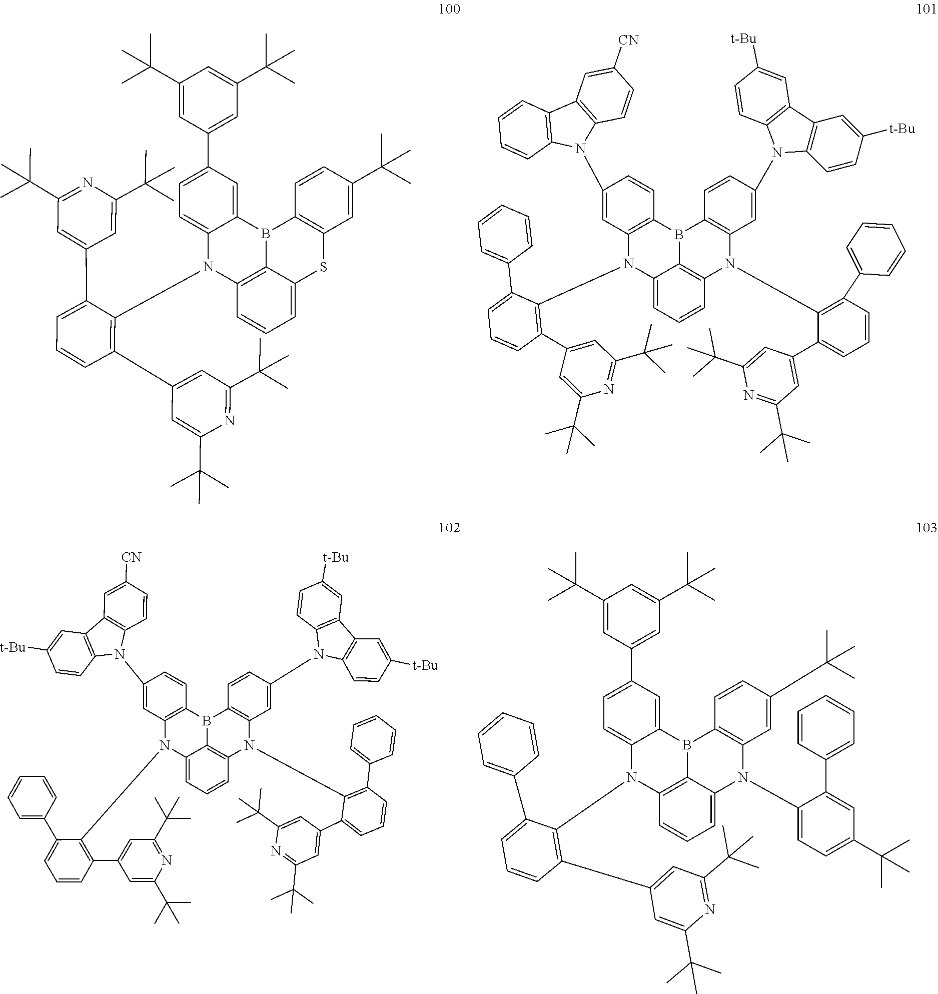 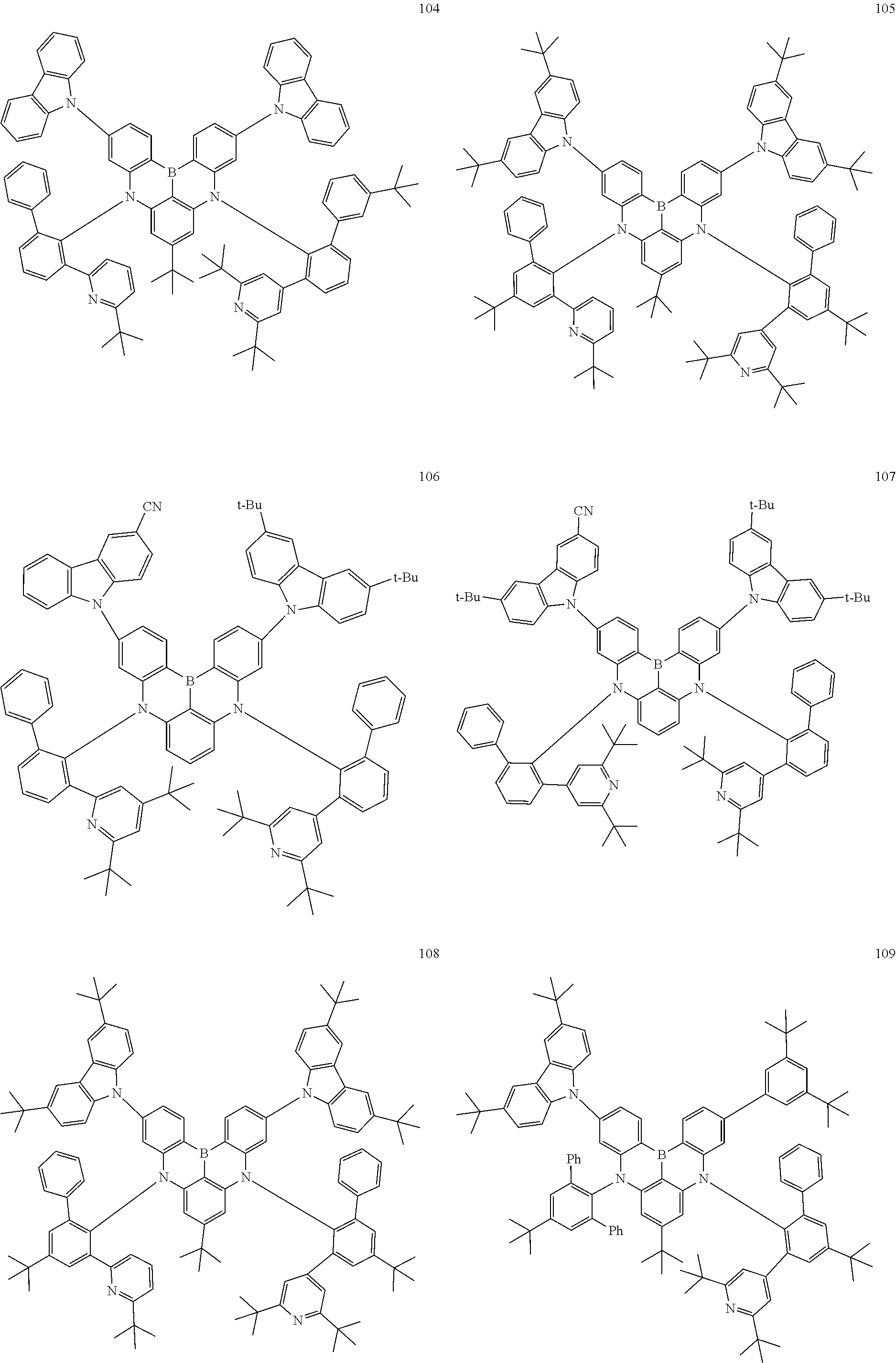 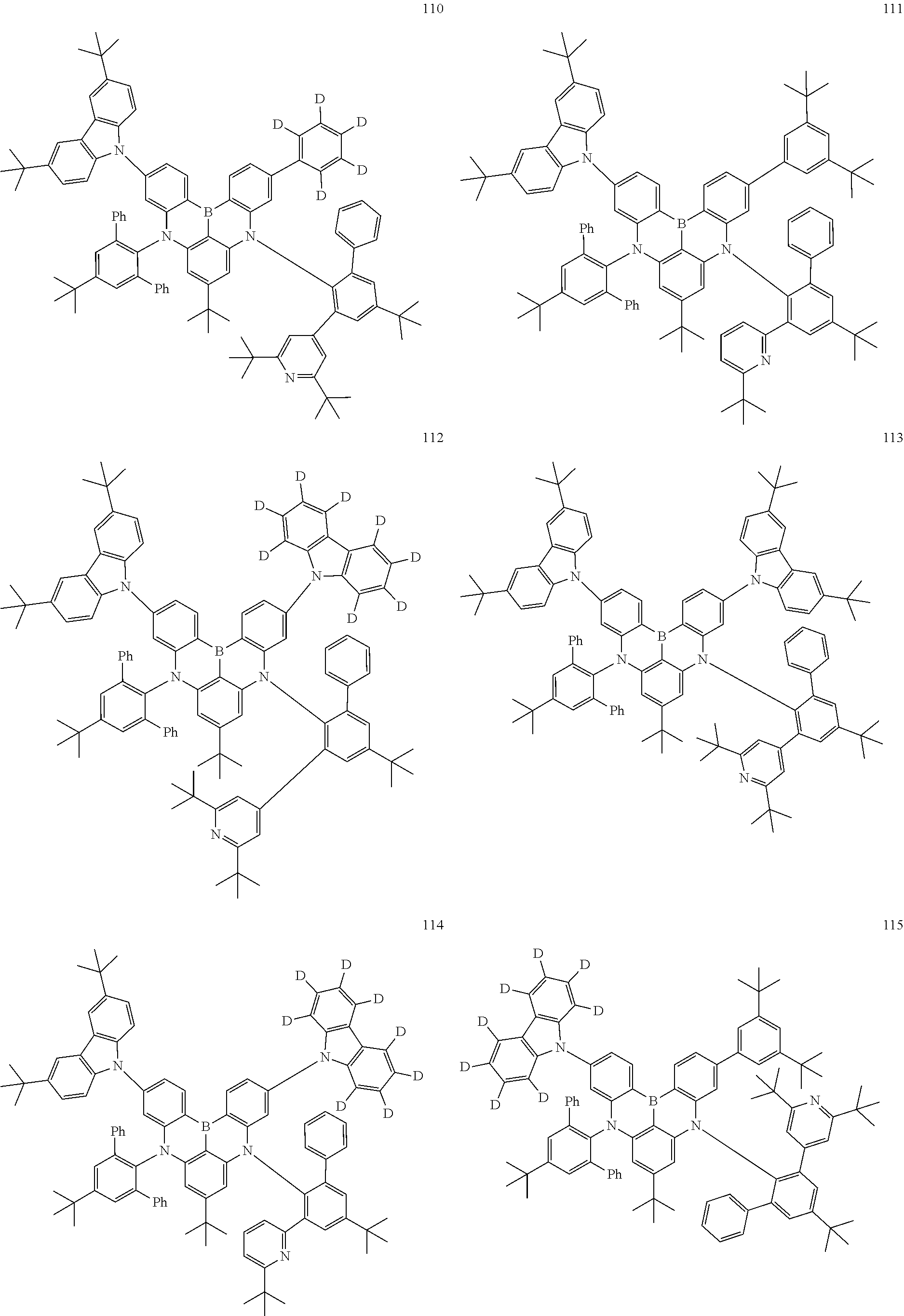 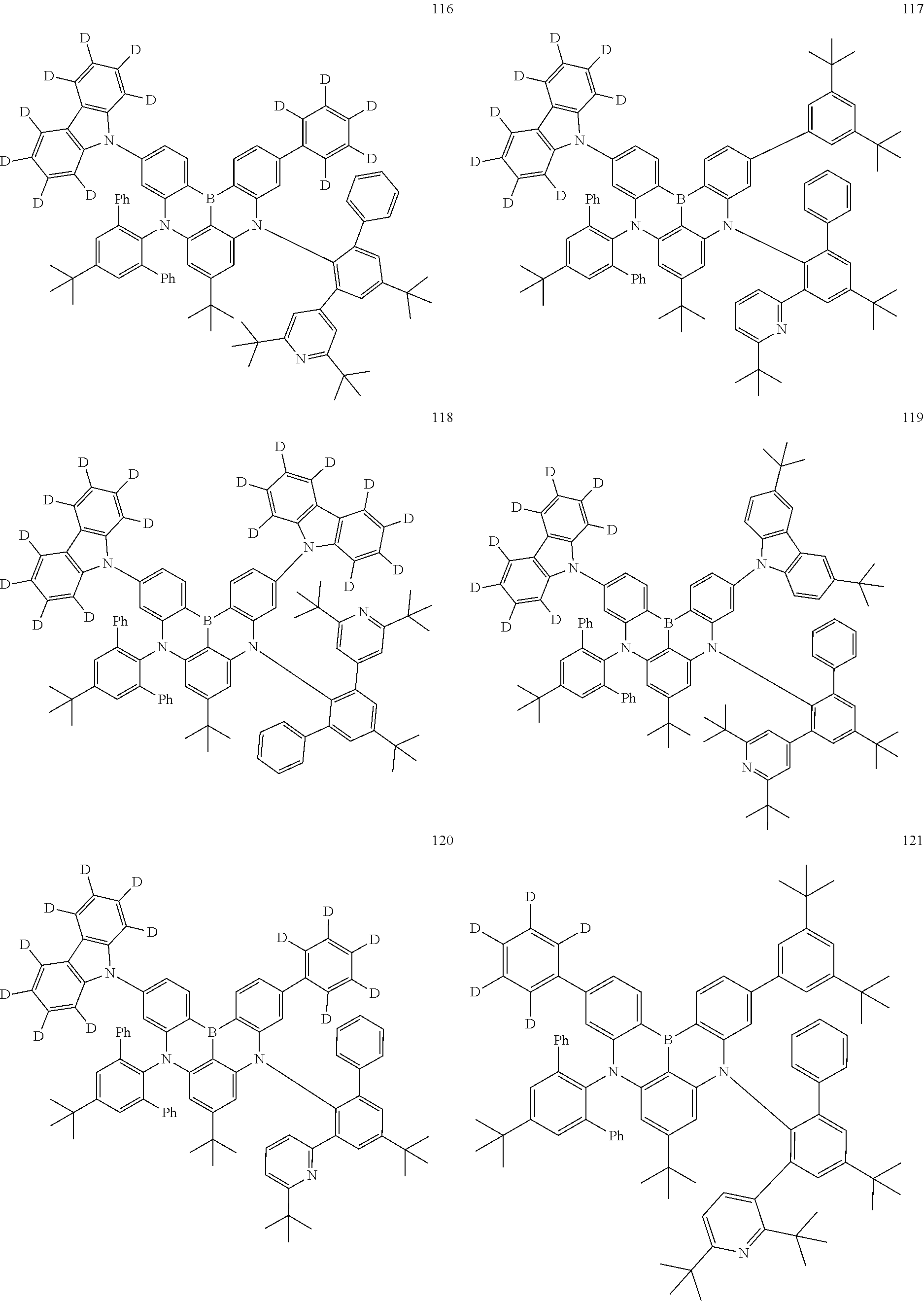 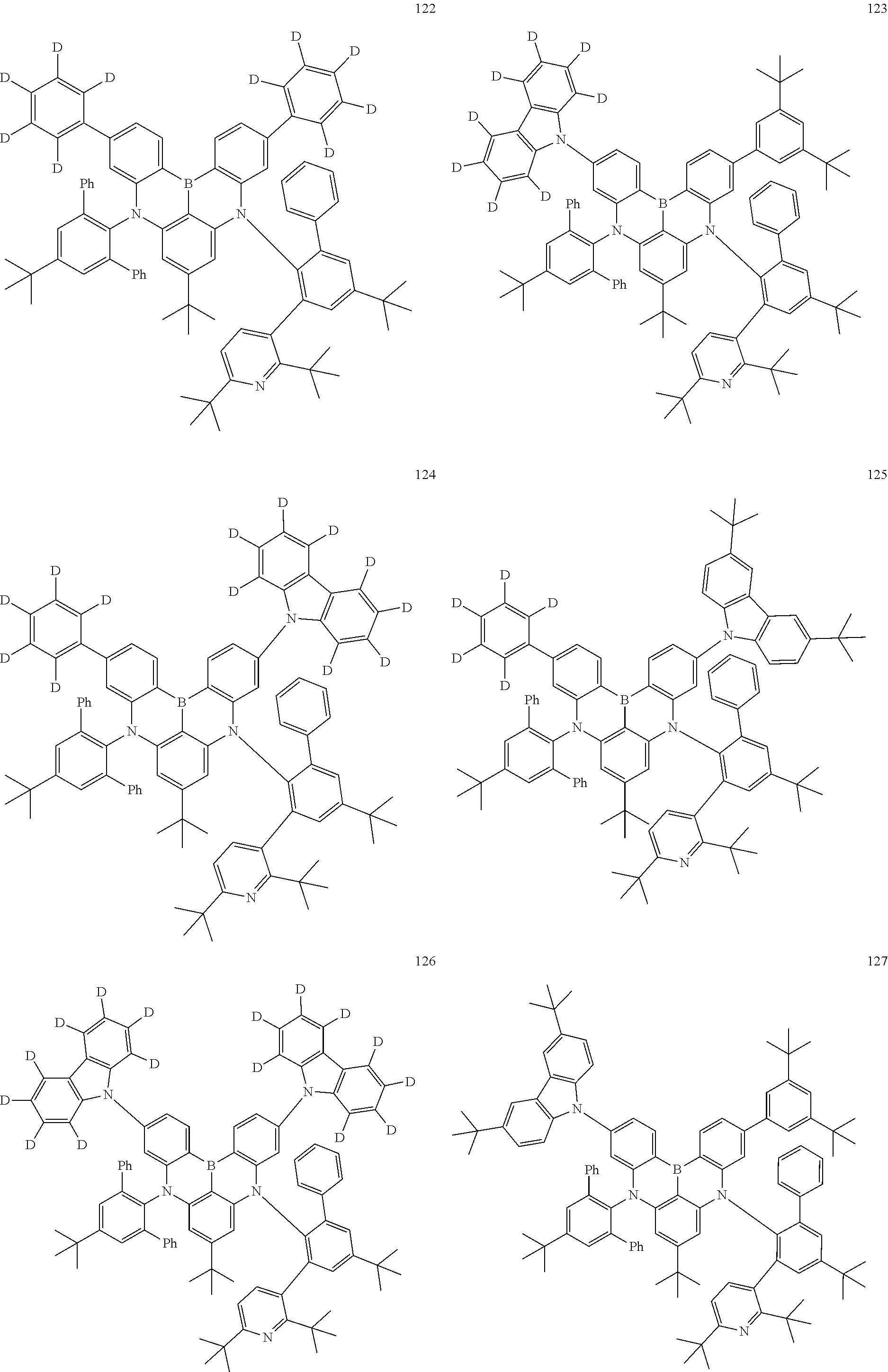 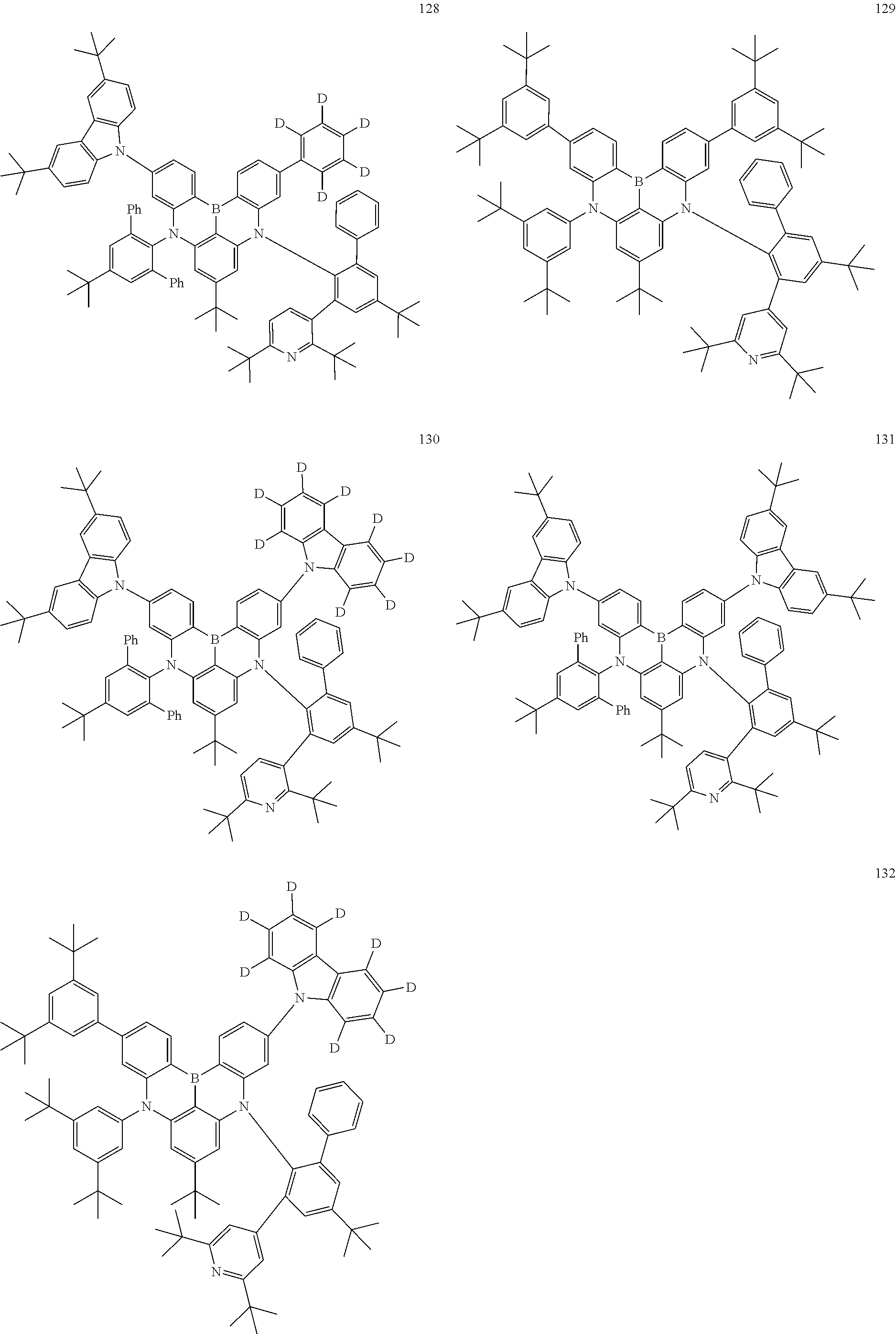 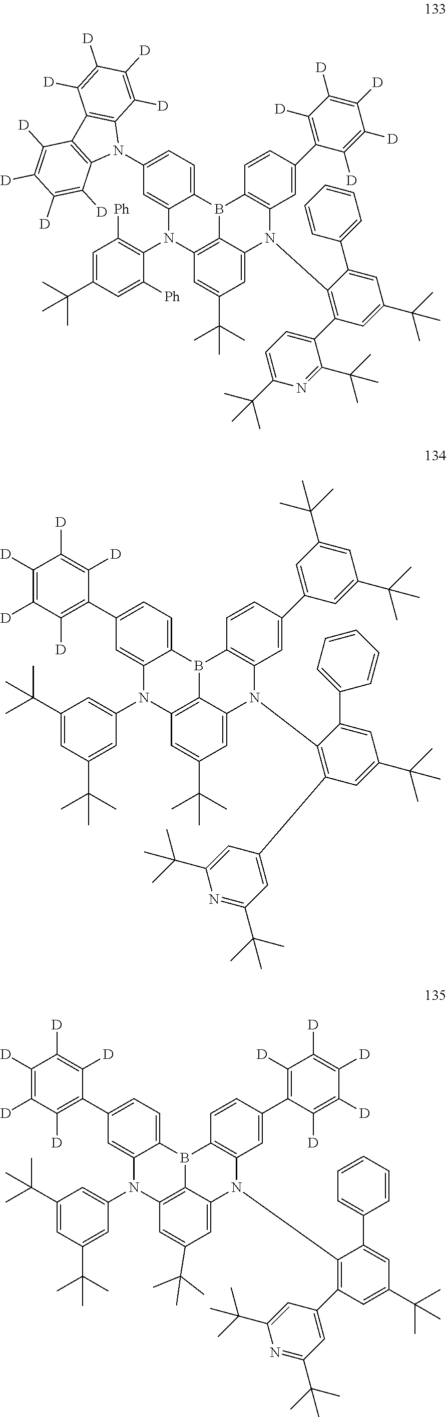 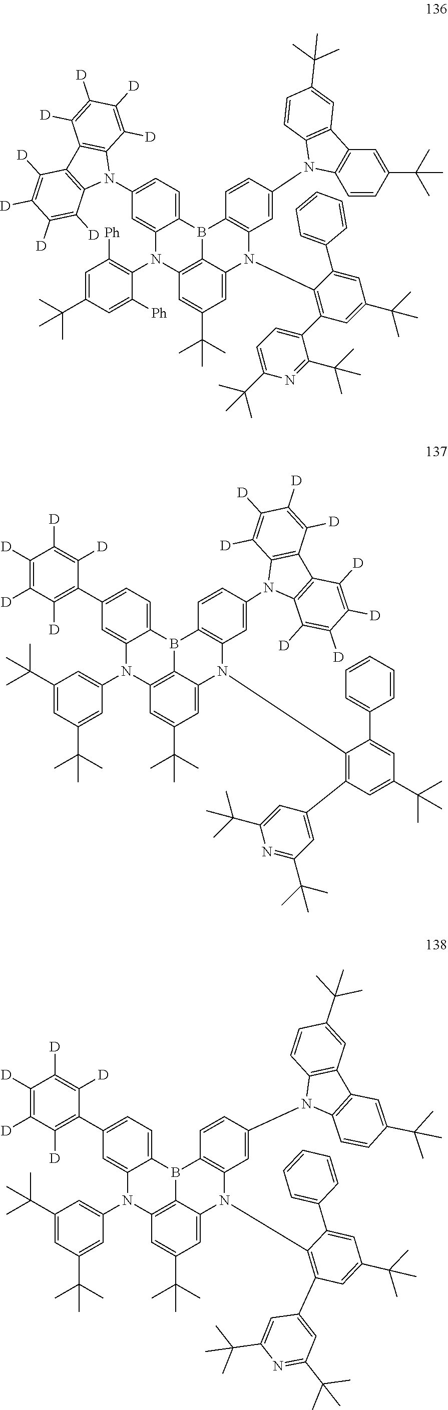 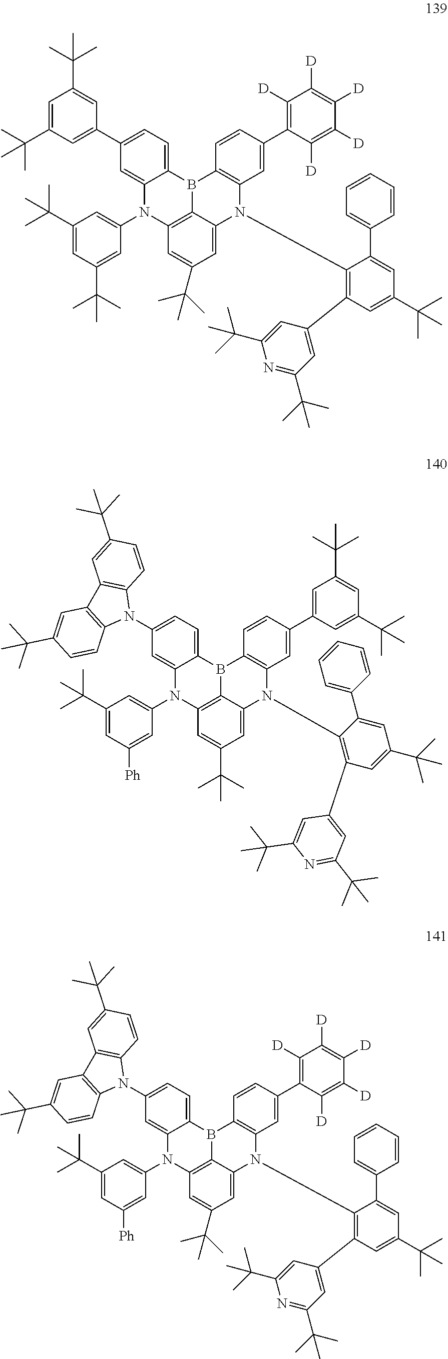 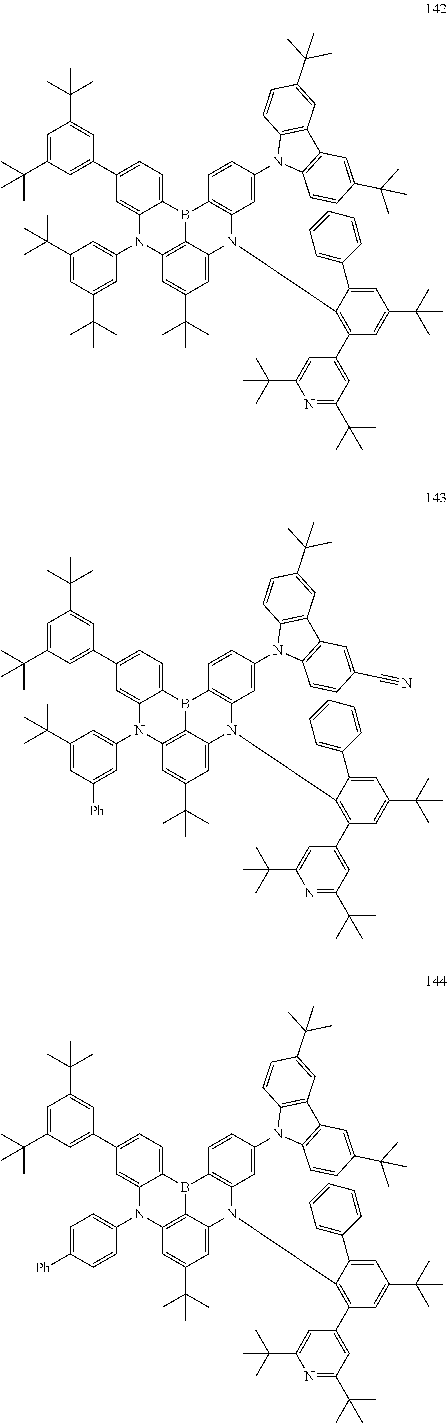 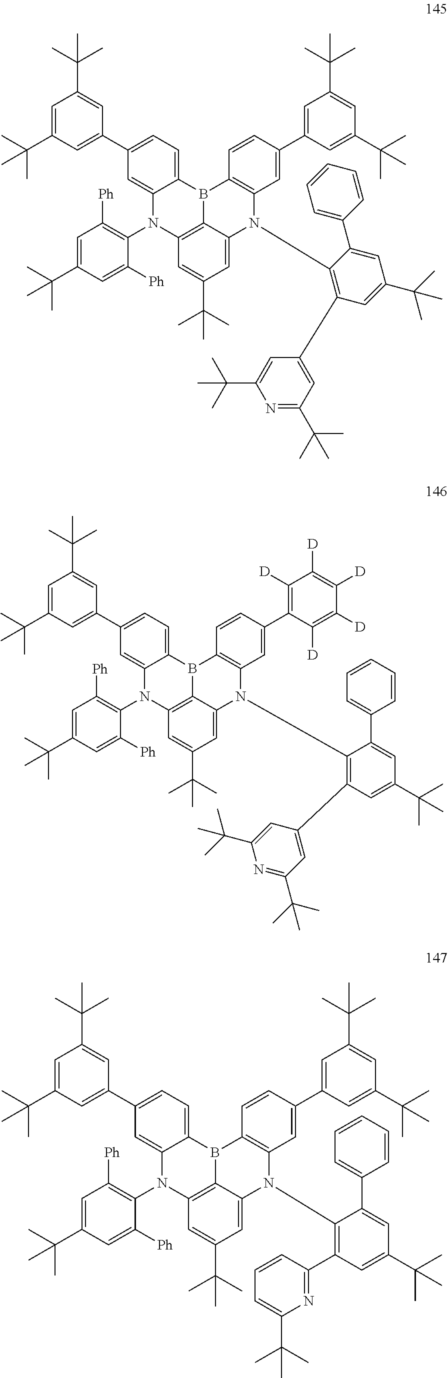 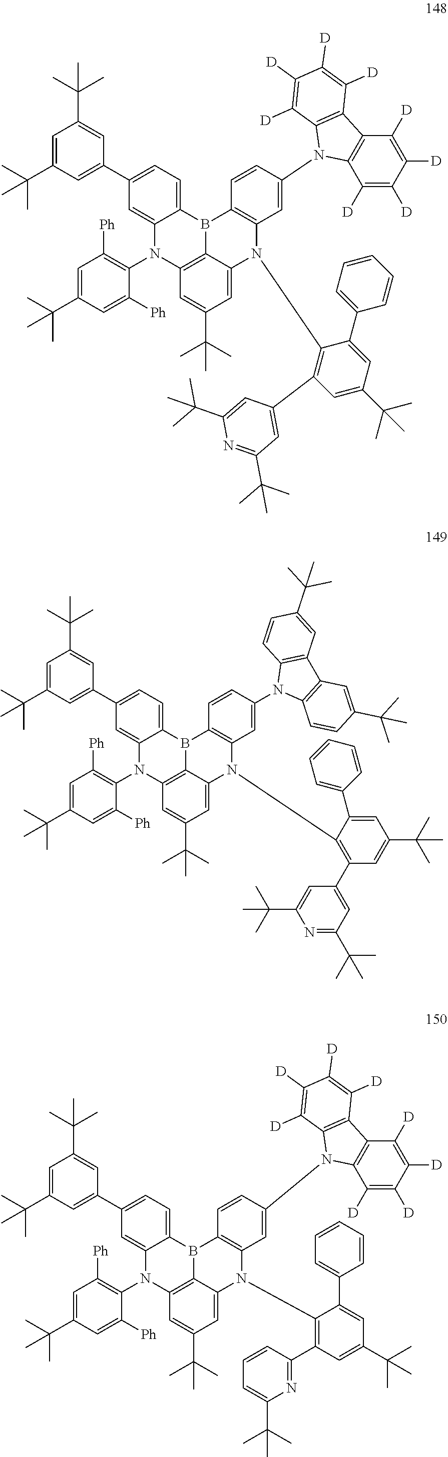 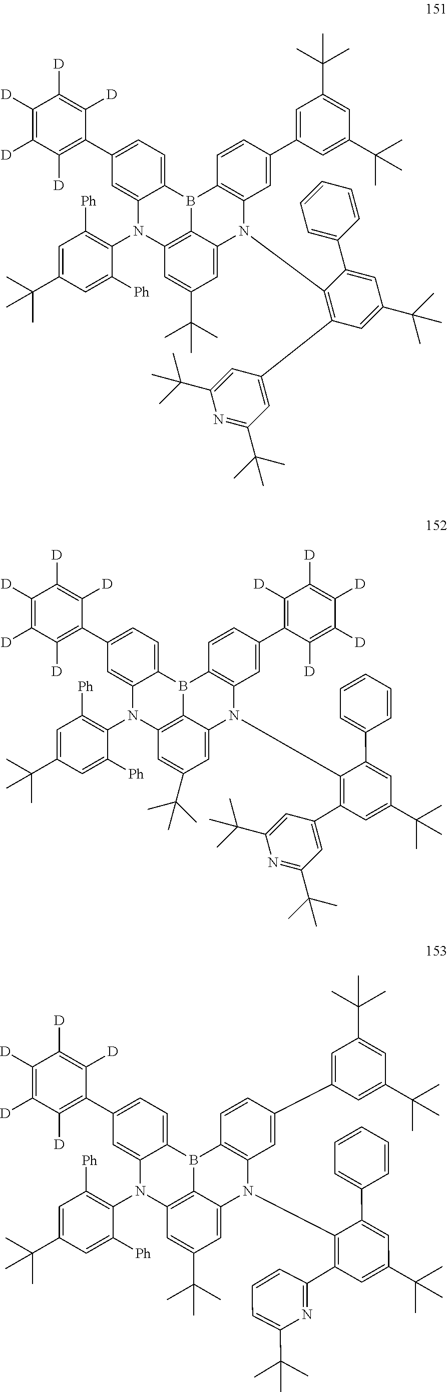 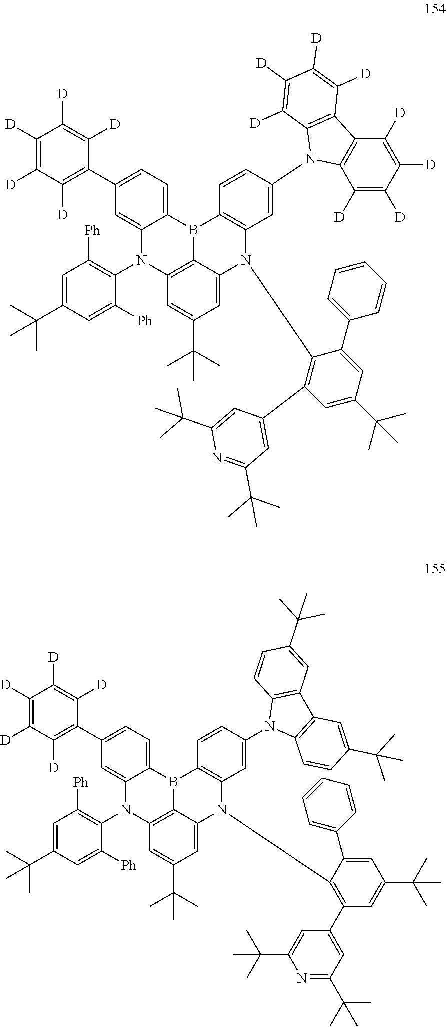 [SMILES: [2H]c1c([2H])c([2H])c(-c2ccc3c(c2)N(c2c(-c4ccccc4)cc(C(C)(C)C)cc2-c2ccccc2)c2cc(C(C)(C)C)cc4c2B3c2ccc(-n3c5c([2H])c([2H])c([2H])c([2H])c5c5c([2H])c([2H])c([2H])c([2H])c53)cc2N4c2c(-c3ccccc3)cc(C(C)(C)C)cc2-c2cc(C(C)(C)C)nc(C(C)(C)C)c2)c([2H])c1[2H] ; [2H]c1c([2H])c([2H])c(-c2ccc3c(c2)N(c2c(-c4ccccc4)cc(C(C)(C)C)cc2-c2ccccc2)c2cc(C(C)(C)C)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2cc(C(C)(C)C)nc(C(C)(C)C)c2)c([2H])c1[2H]] 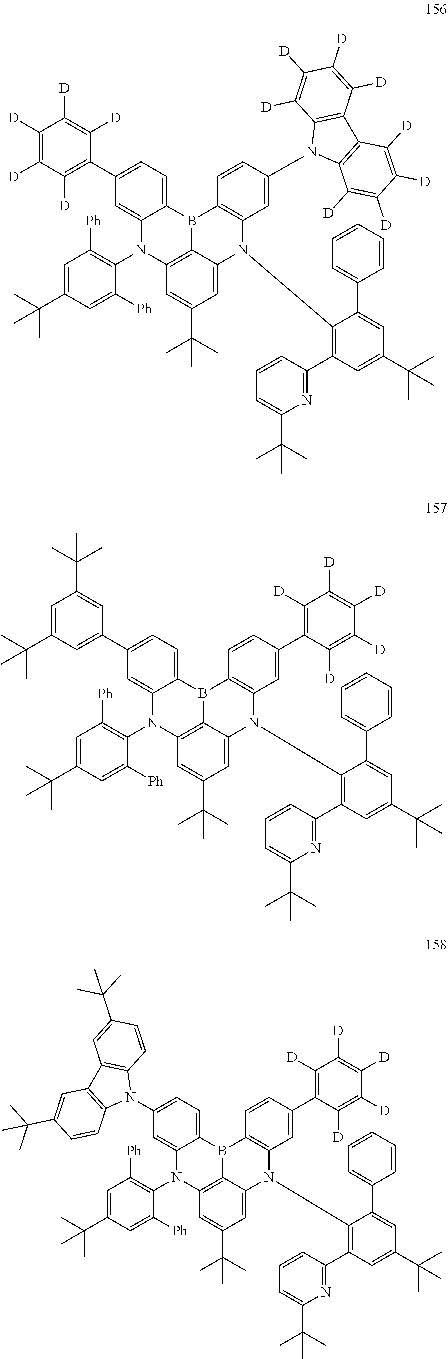 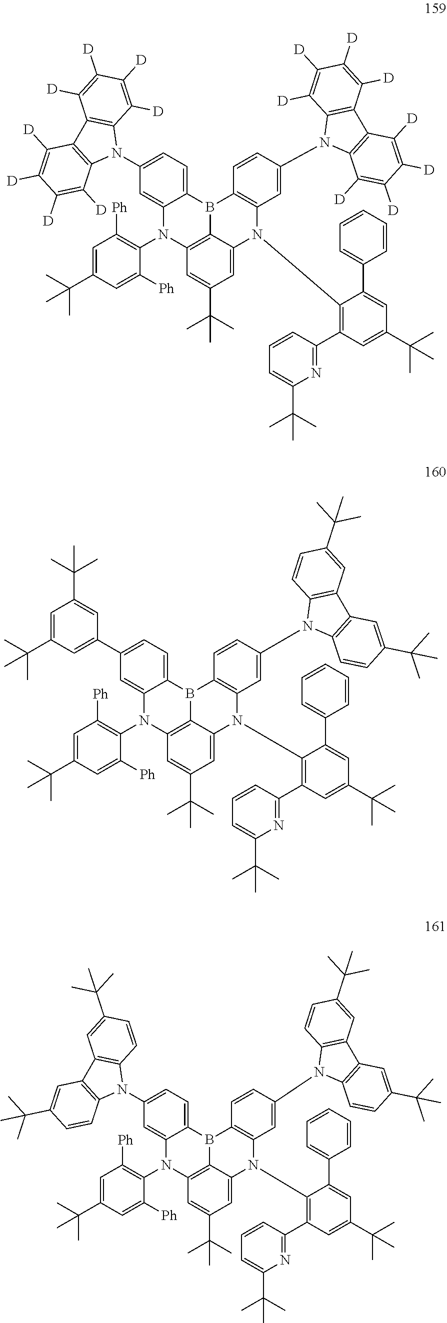 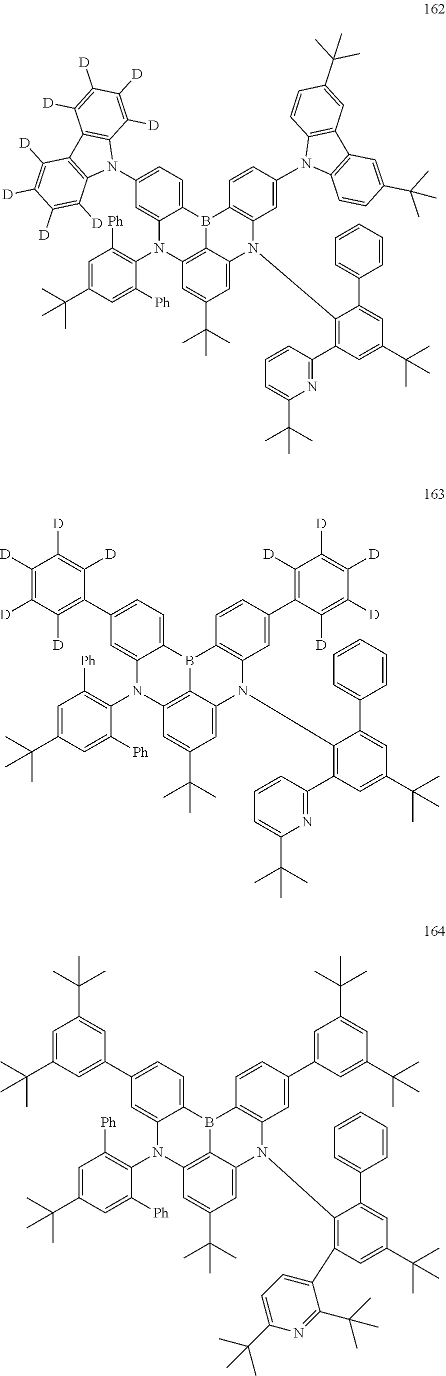 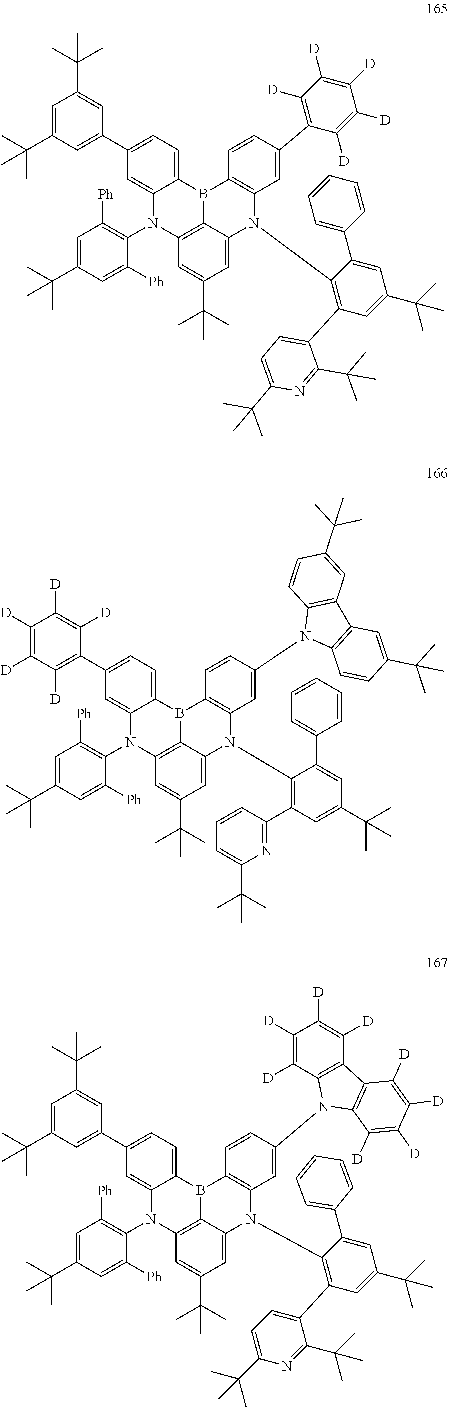 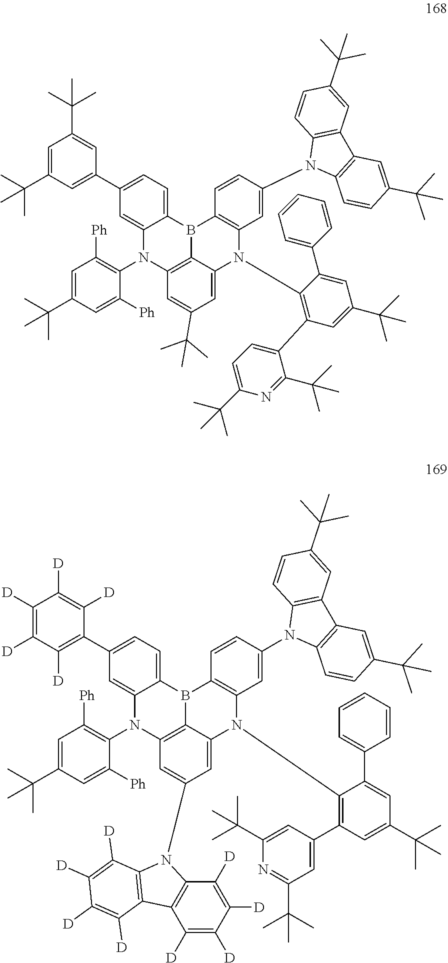 [SMILES: CC(C)(C)c1cc(-c2ccc3c(c2)N(c2c(-c4ccccc4)cc(C(C)(C)C)cc2-c2ccccc2)c2cc(C(C)(C)C)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2ccc(C(C)(C)C)nc2C(C)(C)C)cc(C(C)(C)C)c1 ; [2H]c1c([2H])c([2H])c(-c2ccc3c(c2)N(c2c(-c4ccccc4)cc(C(C)(C)C)cc2-c2ccccc2)c2cc(-n4c5c([2H])c([2H])c([2H])c([2H])c5c5c([2H])c([2H])c([2H])c([2H])c54)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2cc(C(C)(C)C)nc(C(C)(C)C)c2)c([2H])c1[2H]] 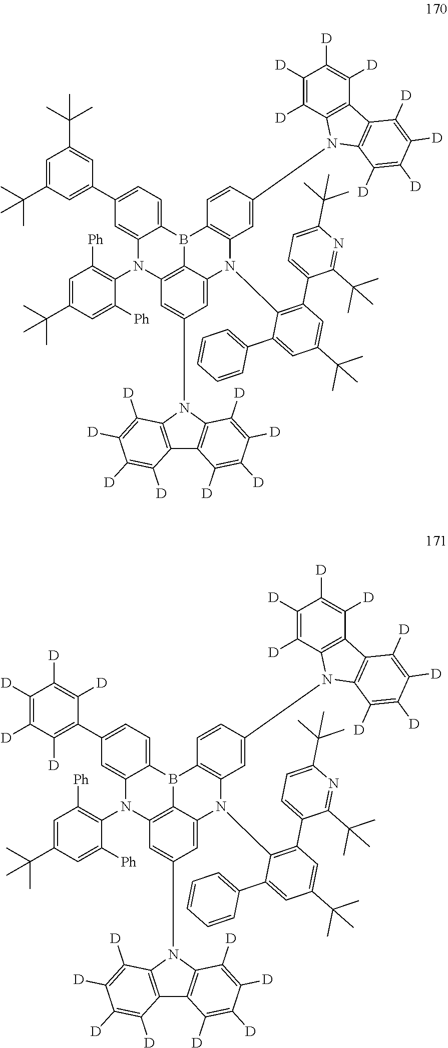 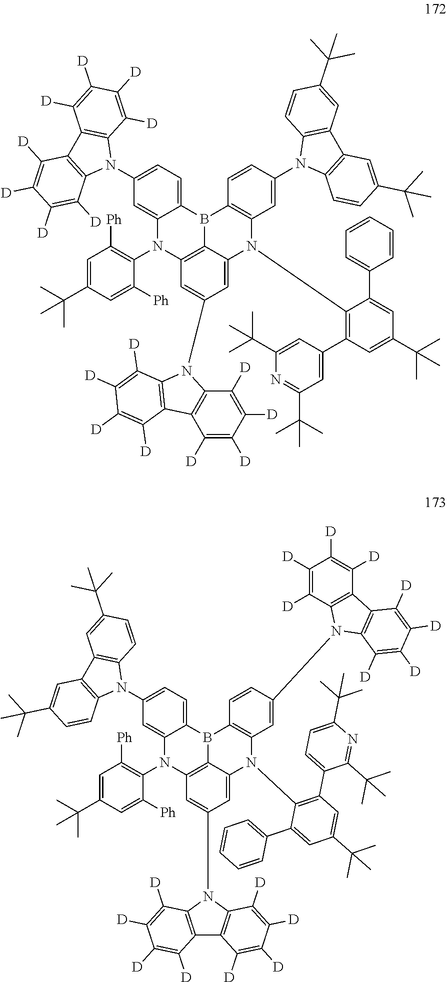 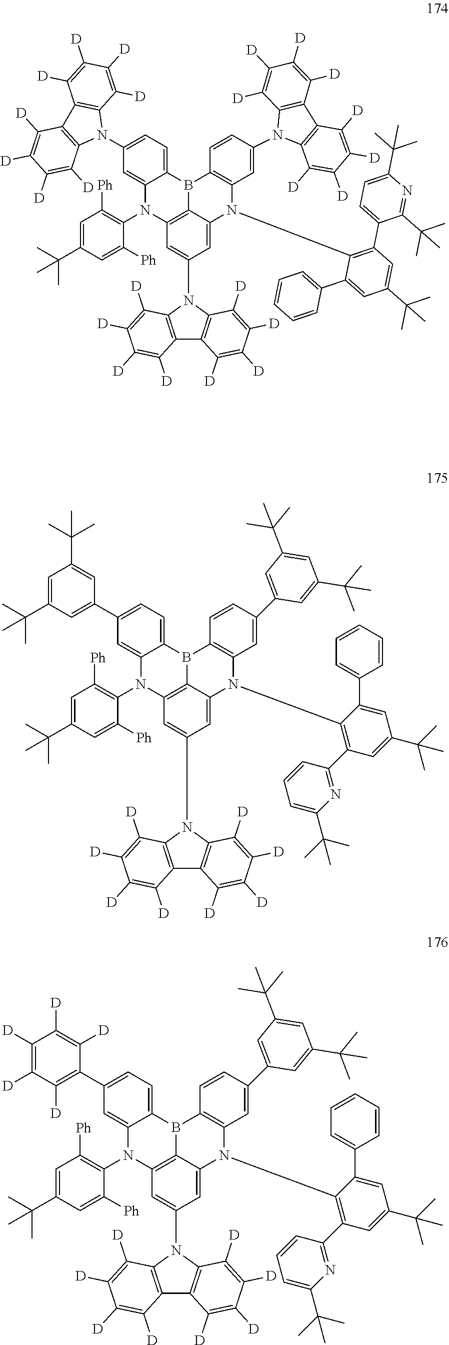 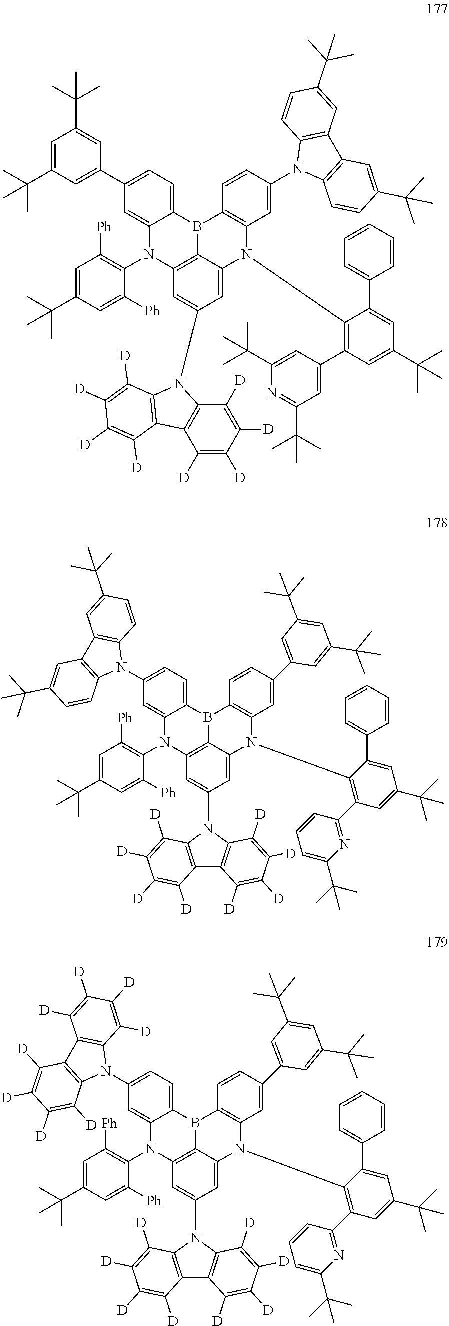 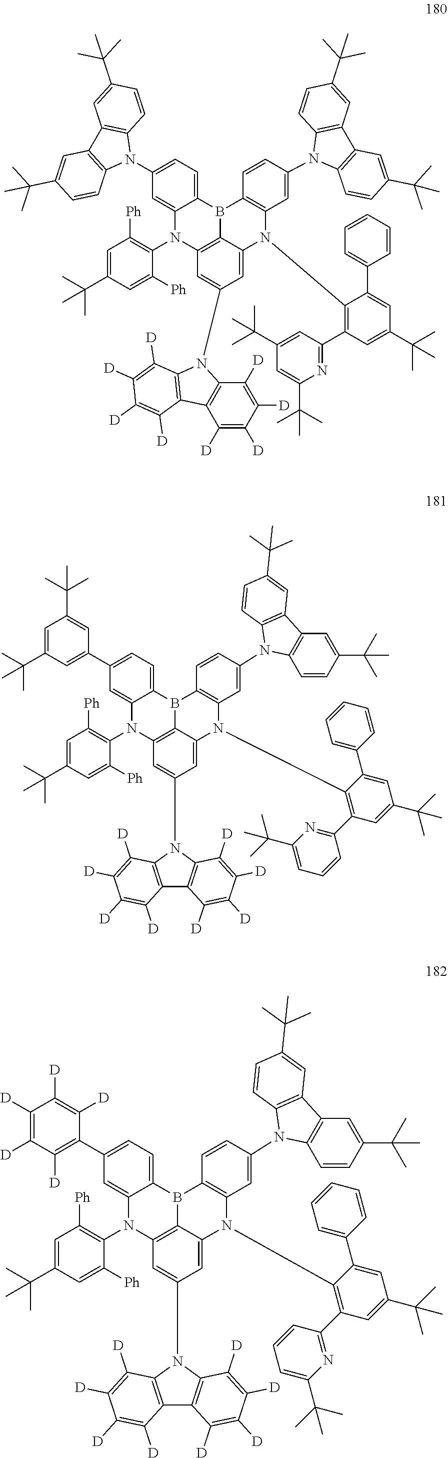 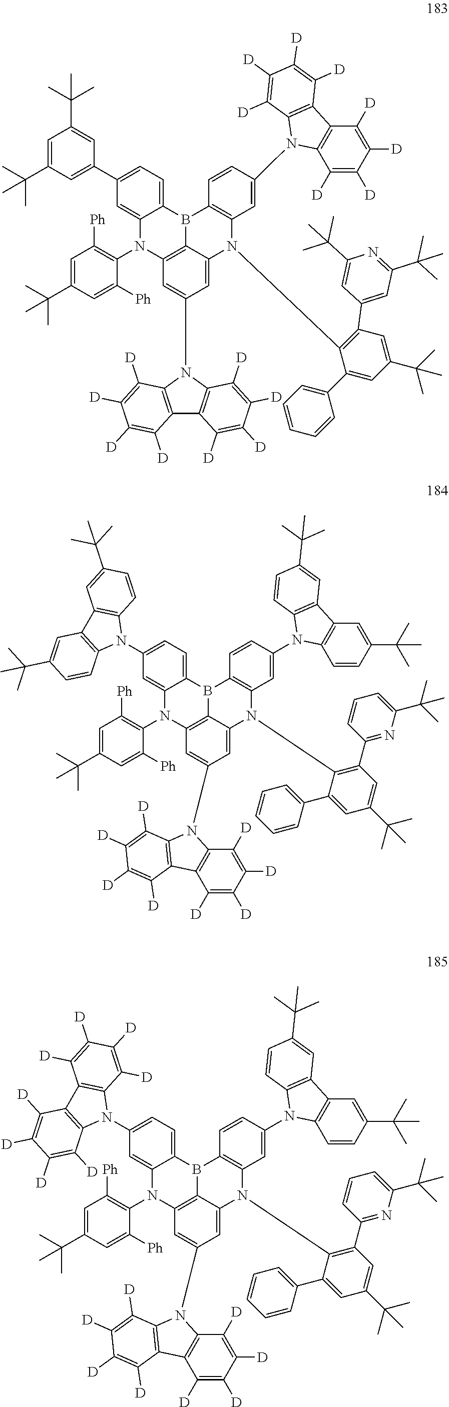 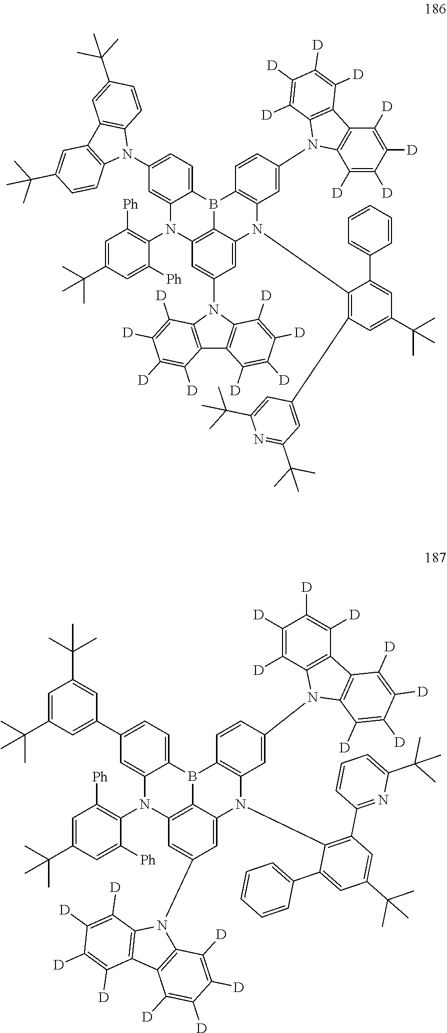 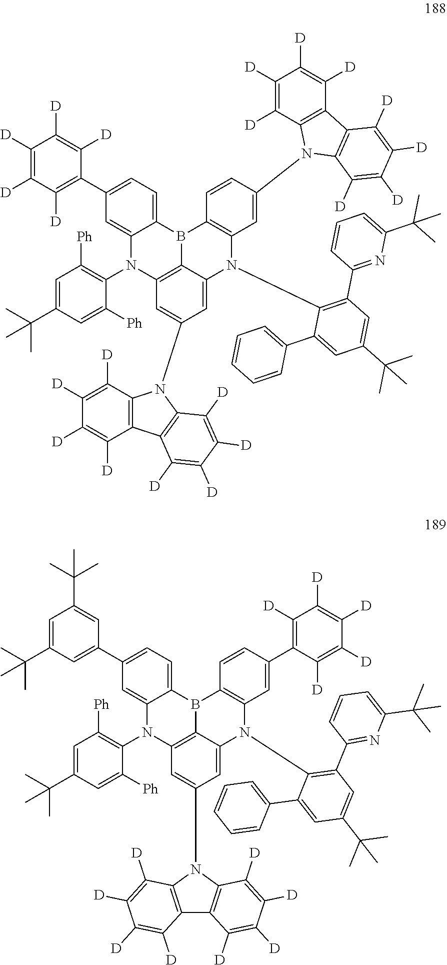 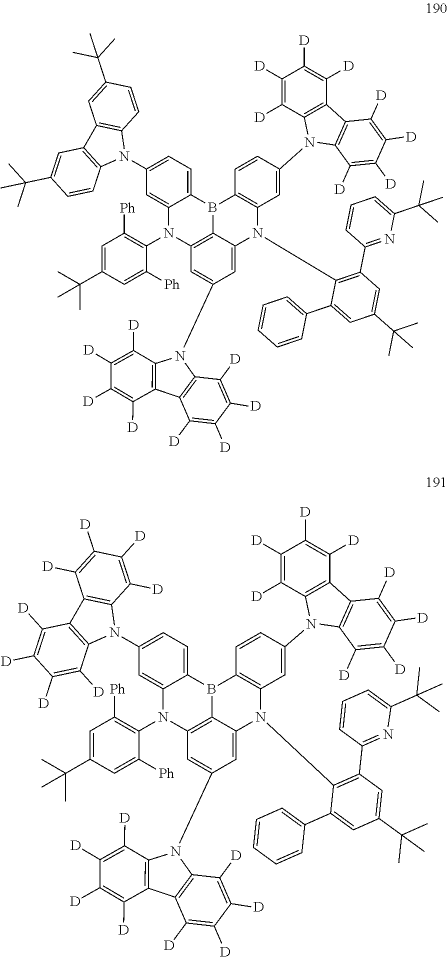 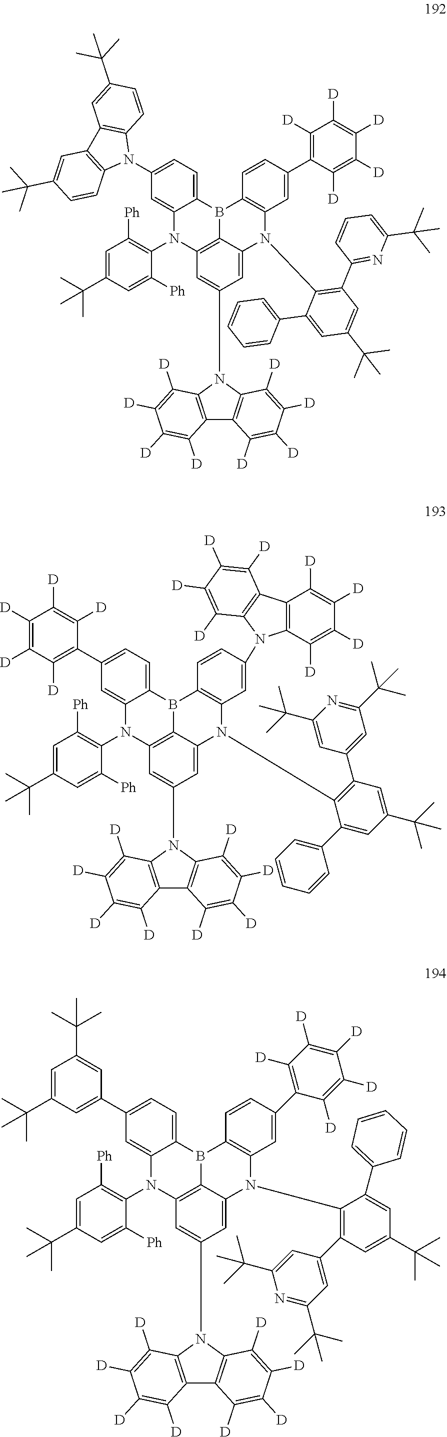 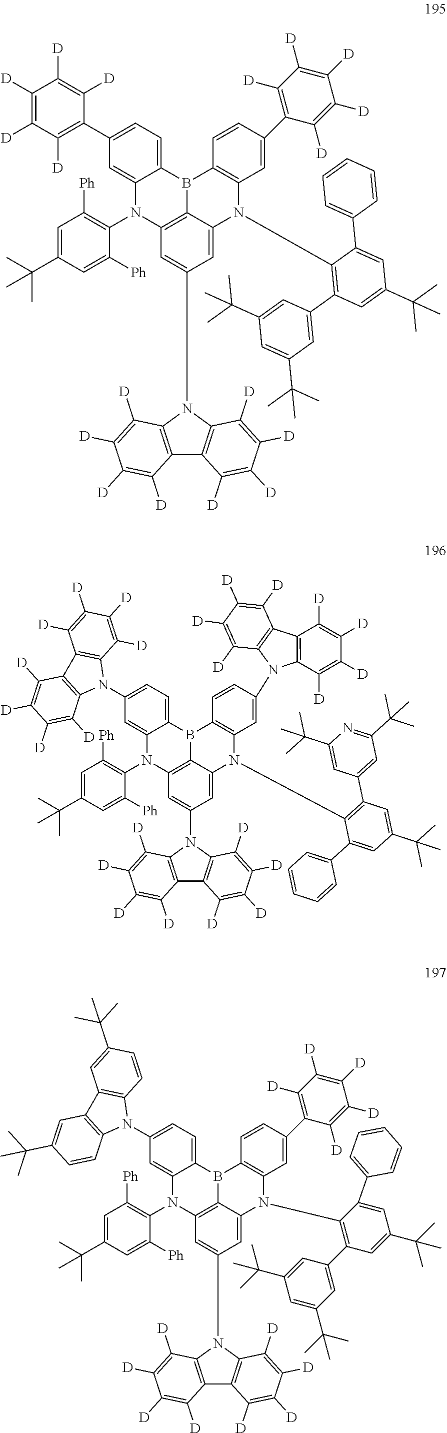 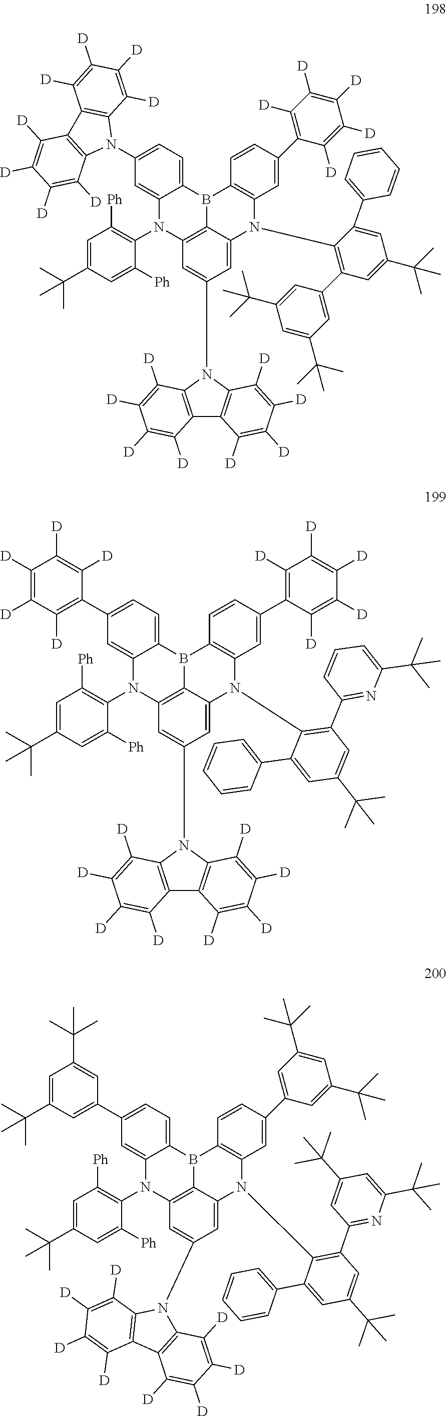 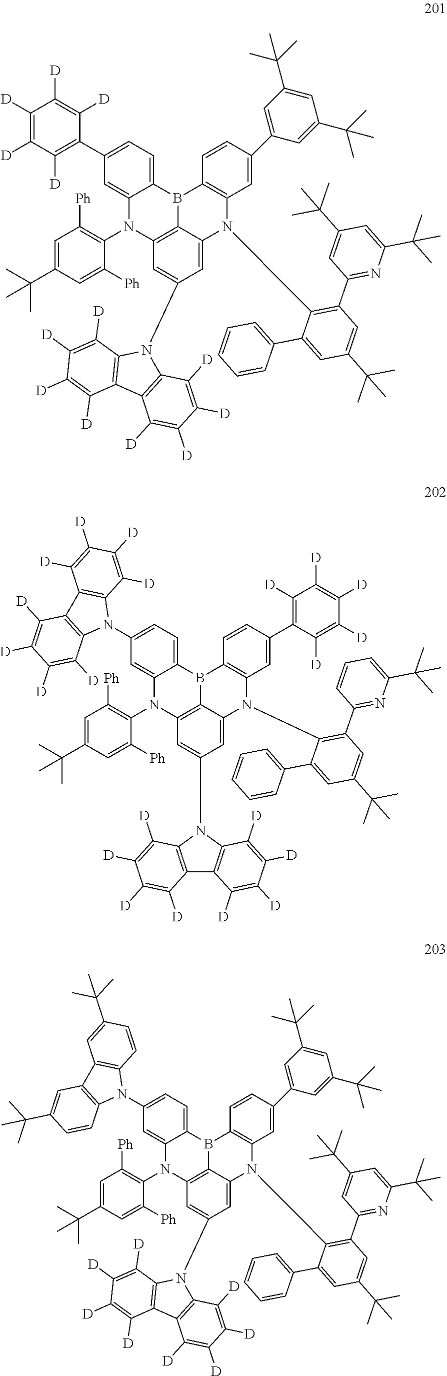 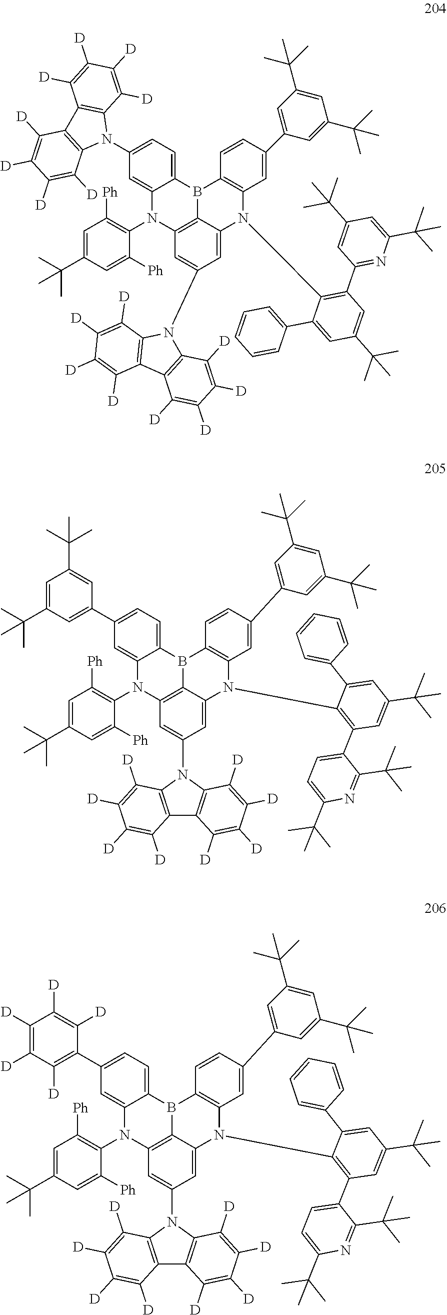 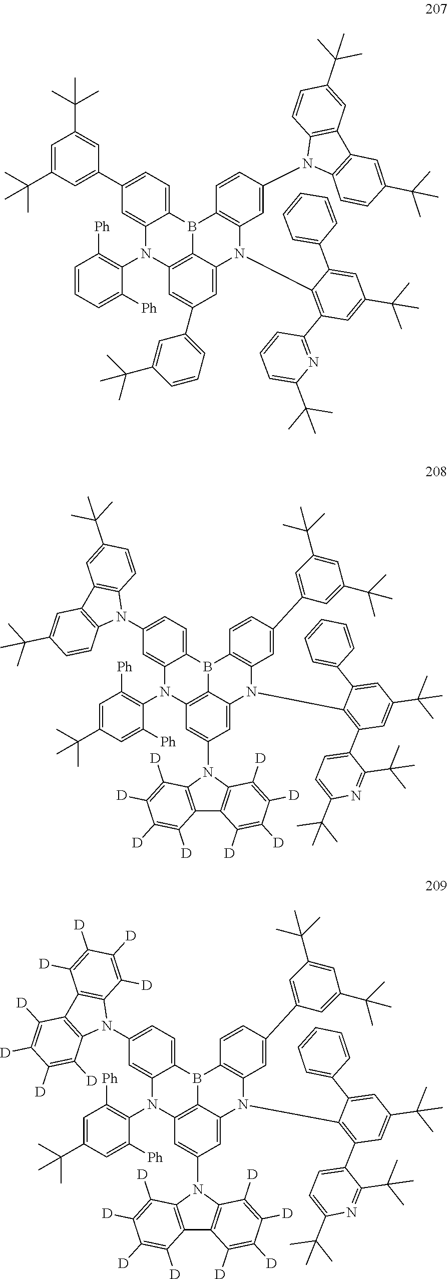 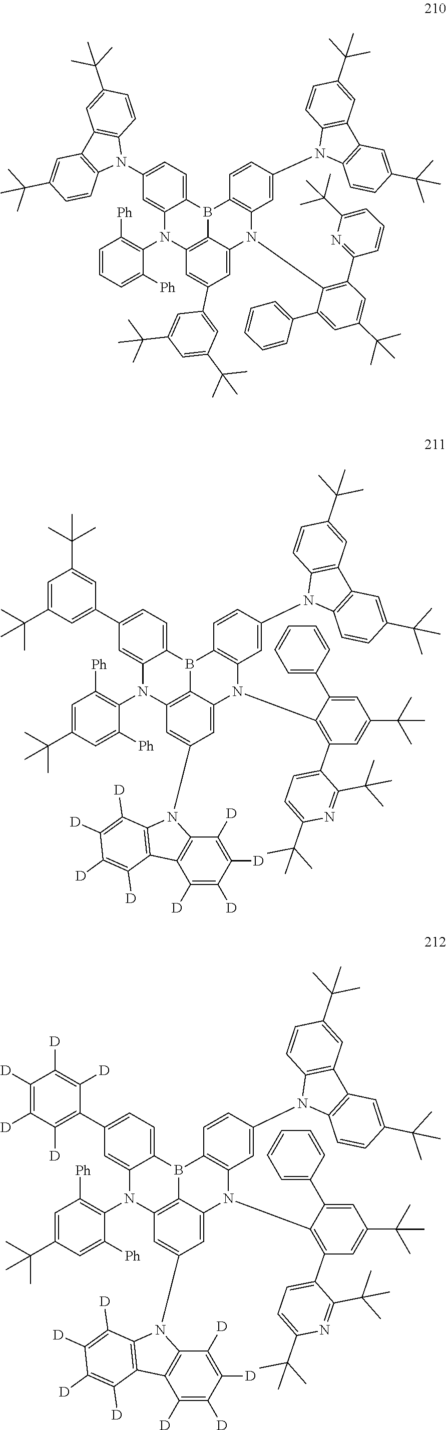 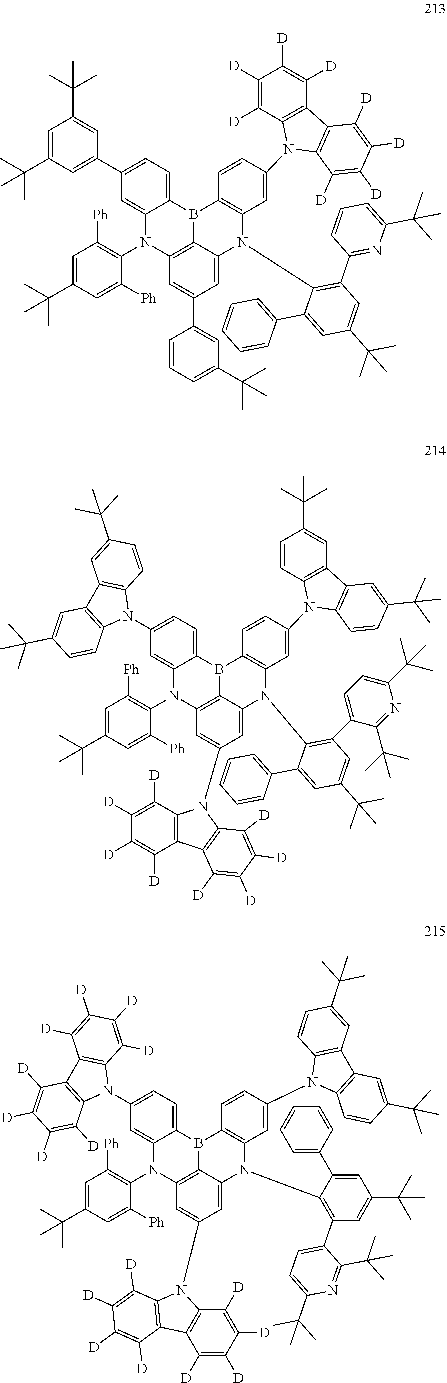 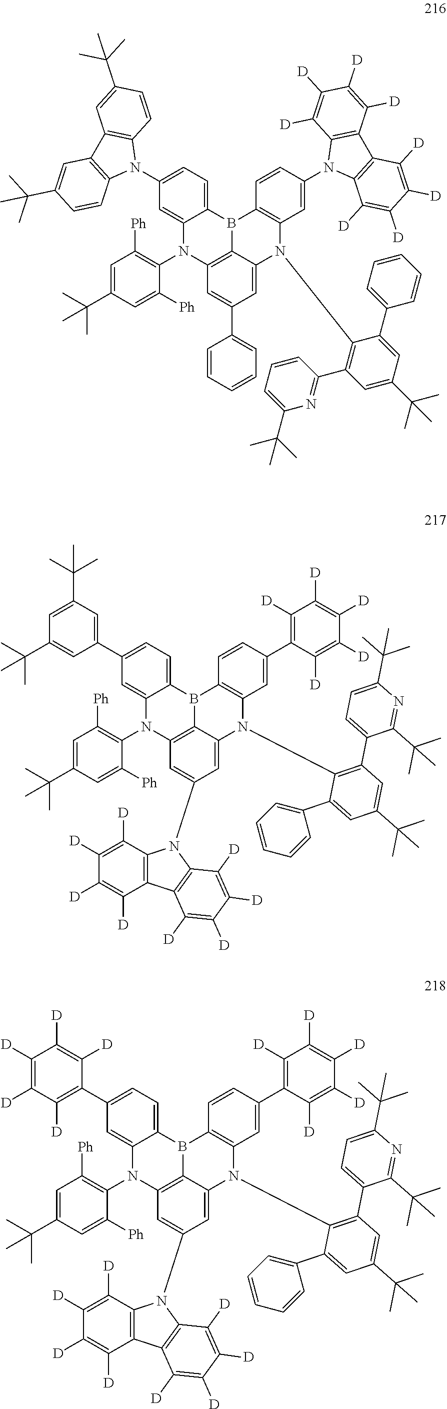 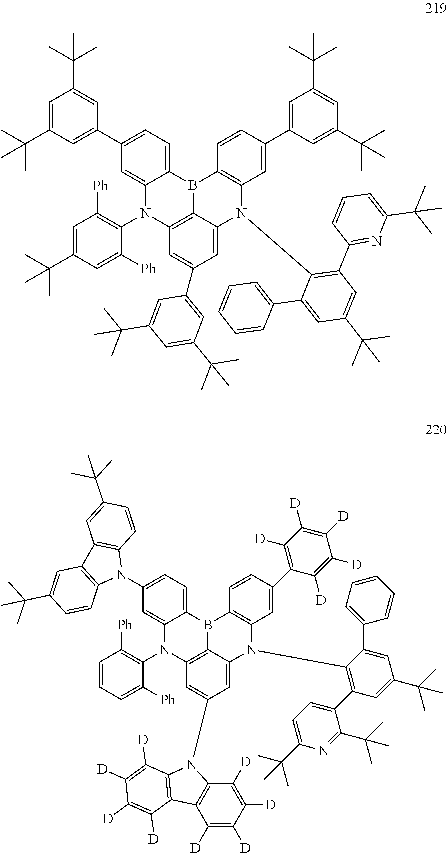 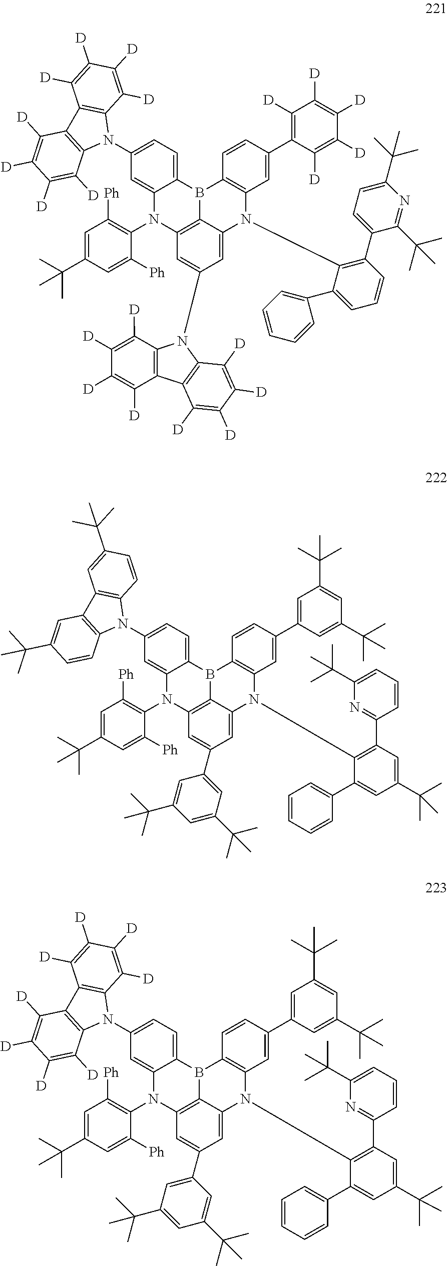 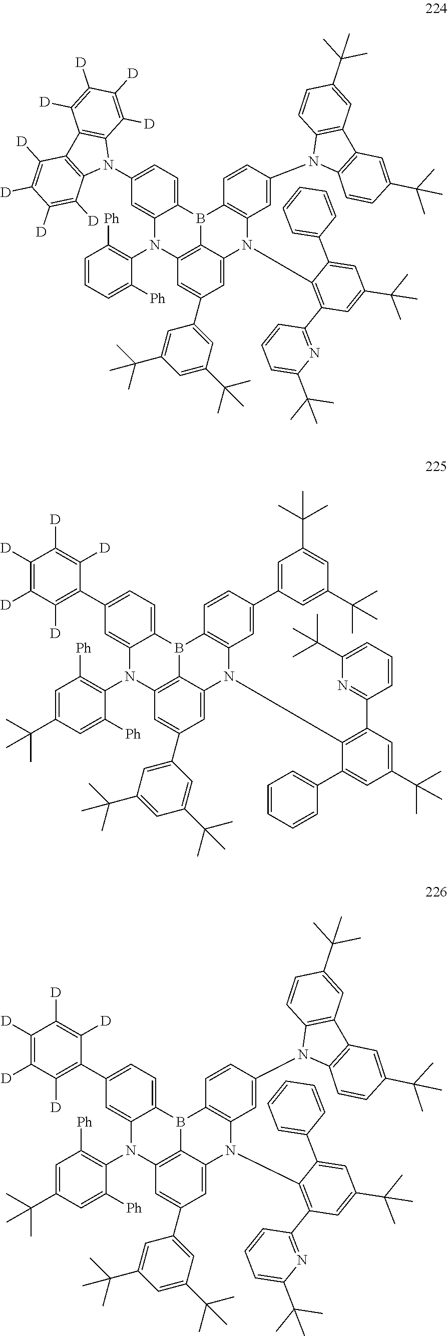 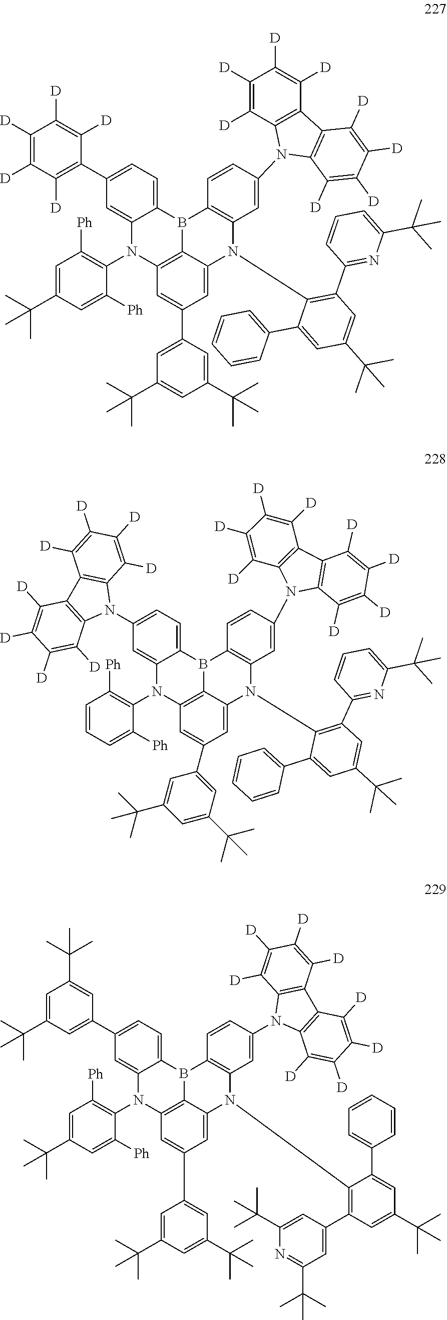 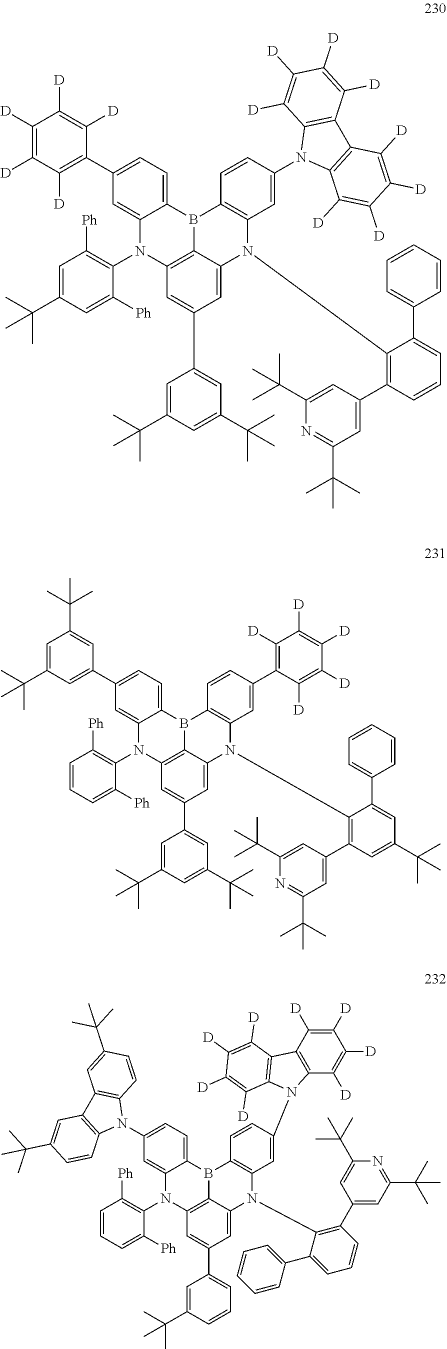 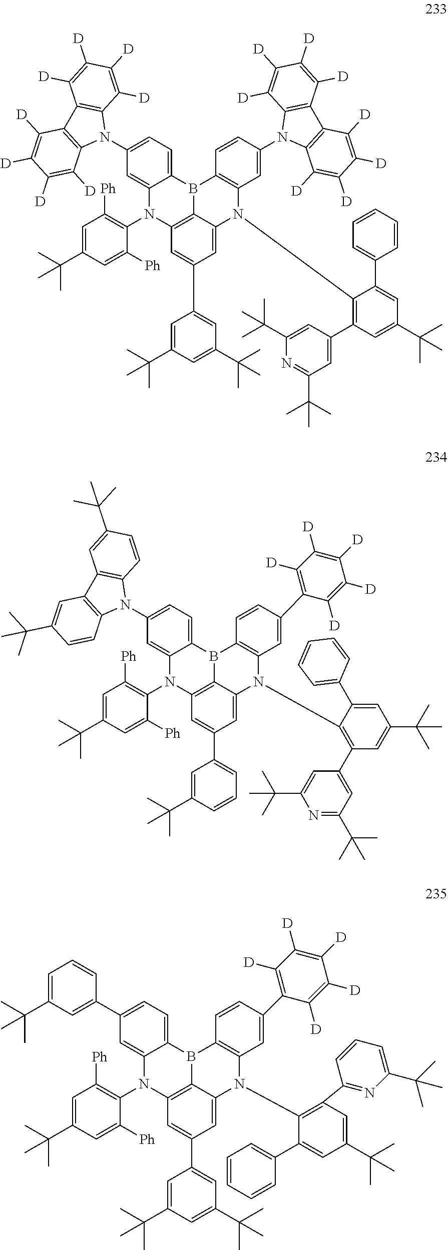 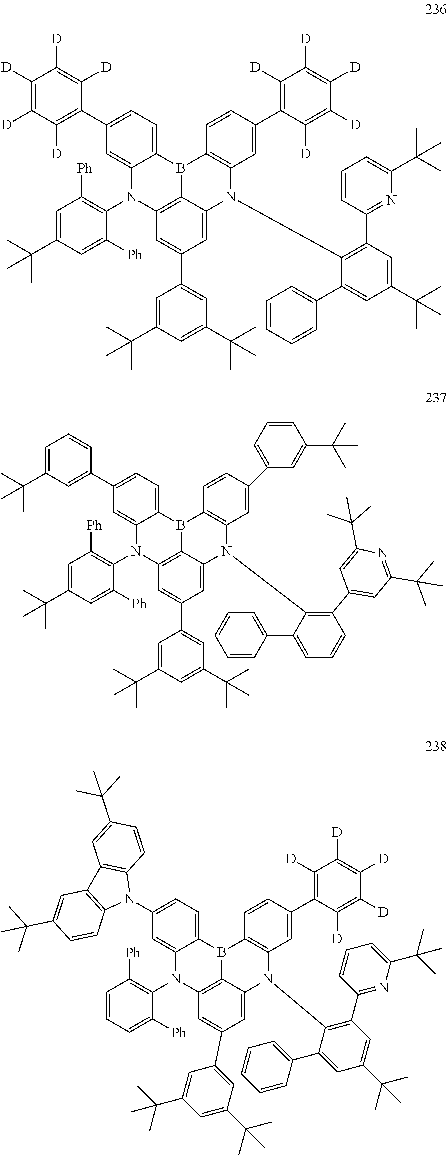 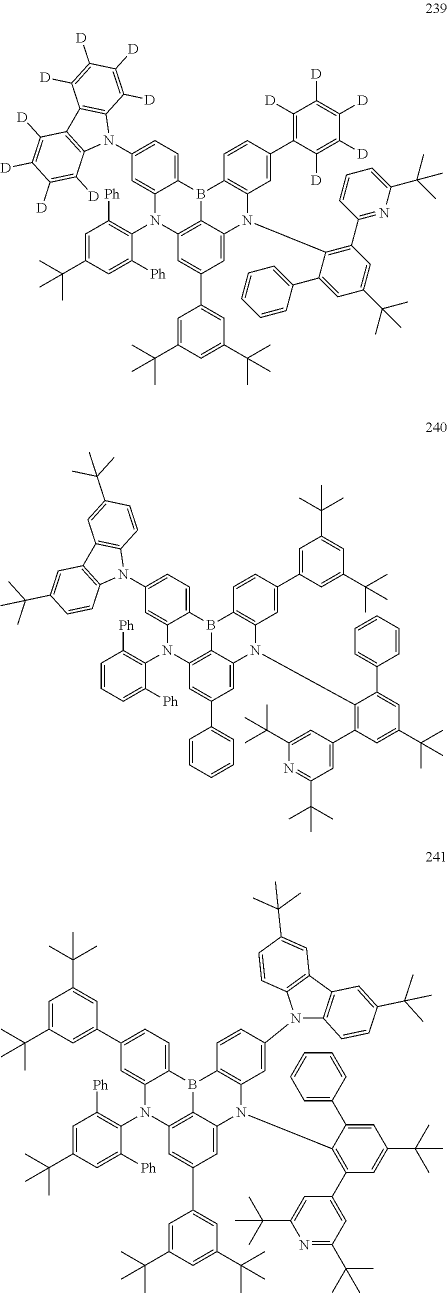 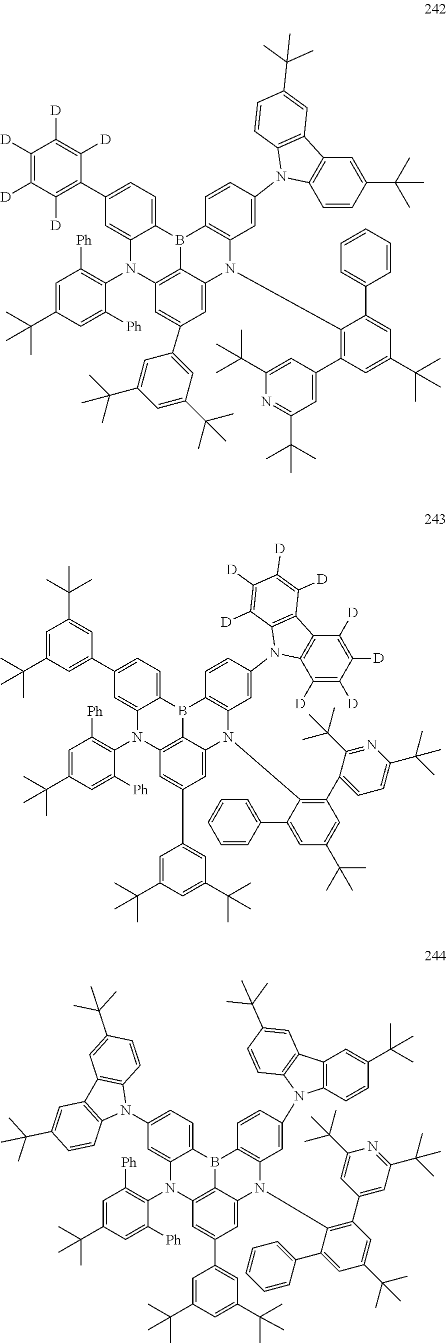 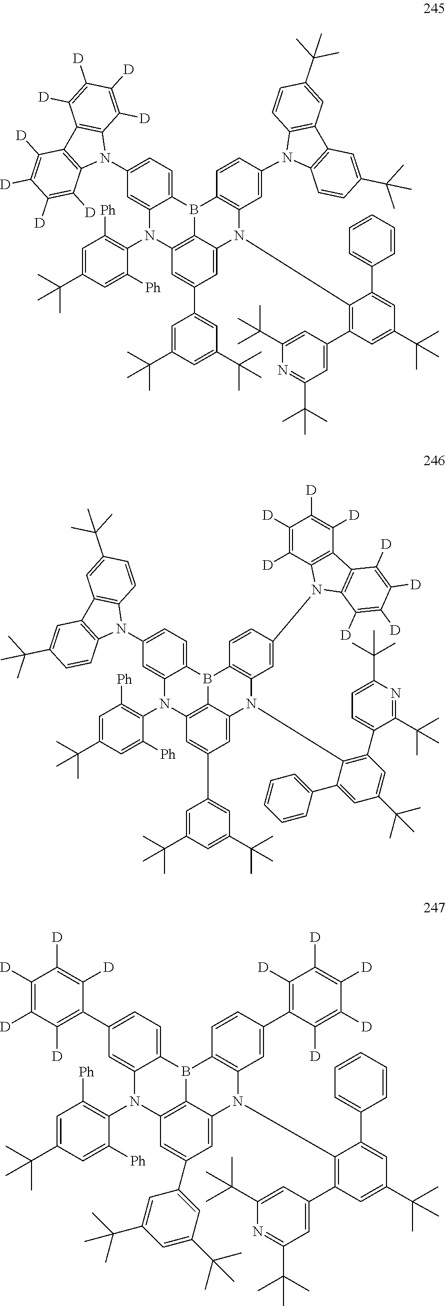 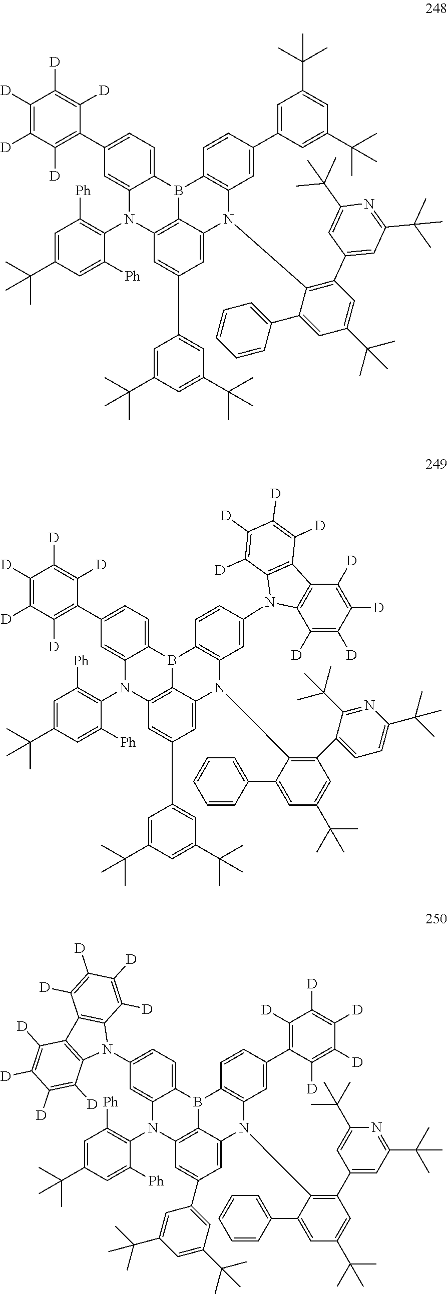 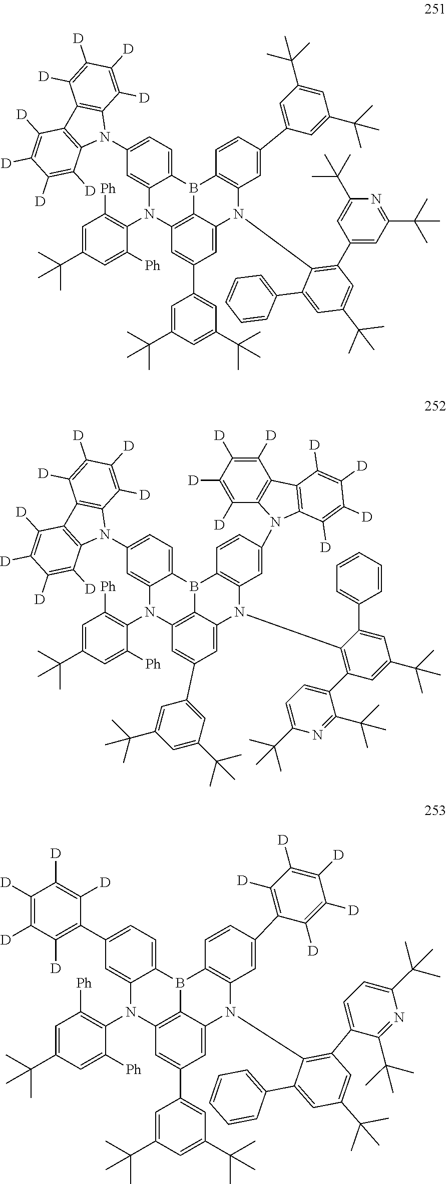 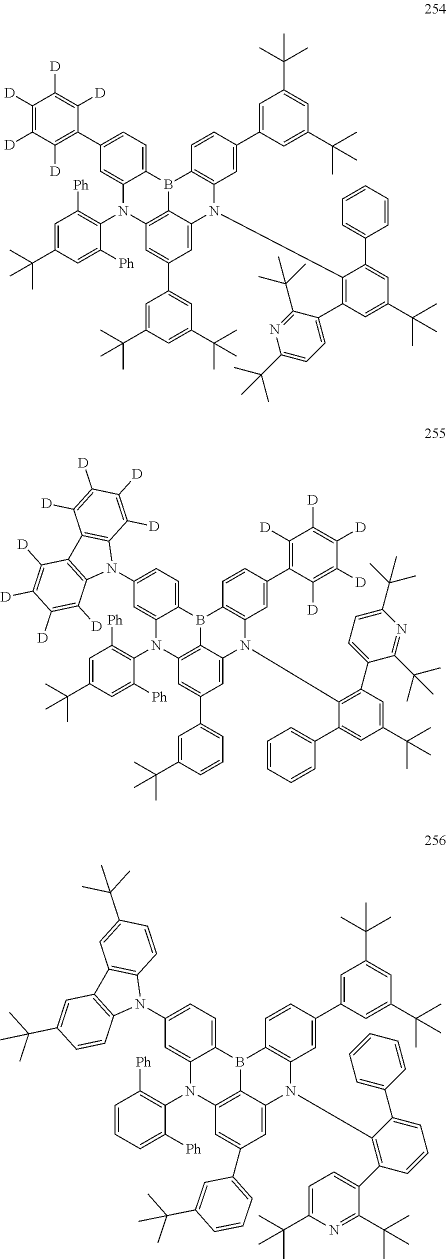 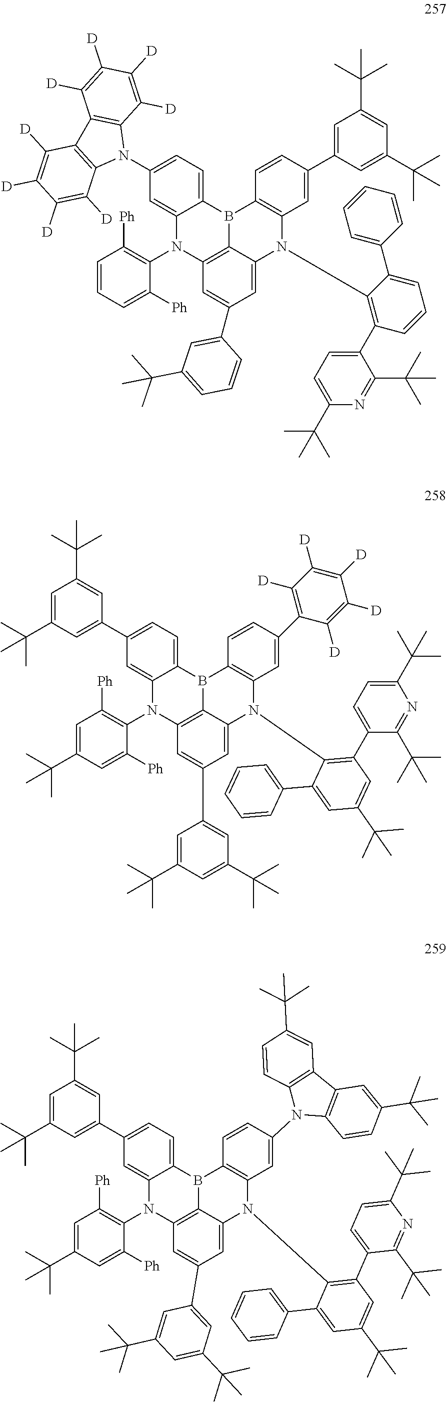 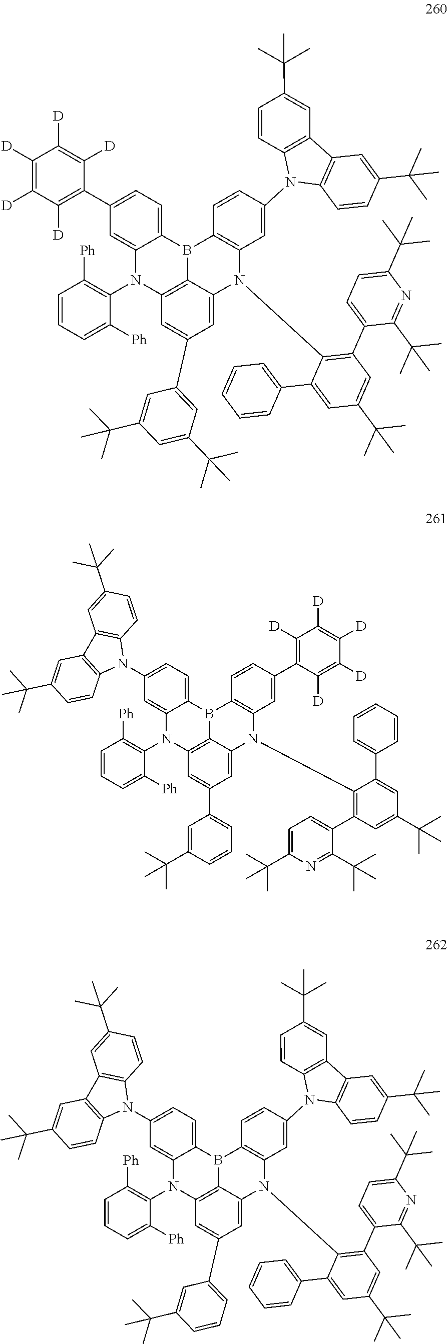 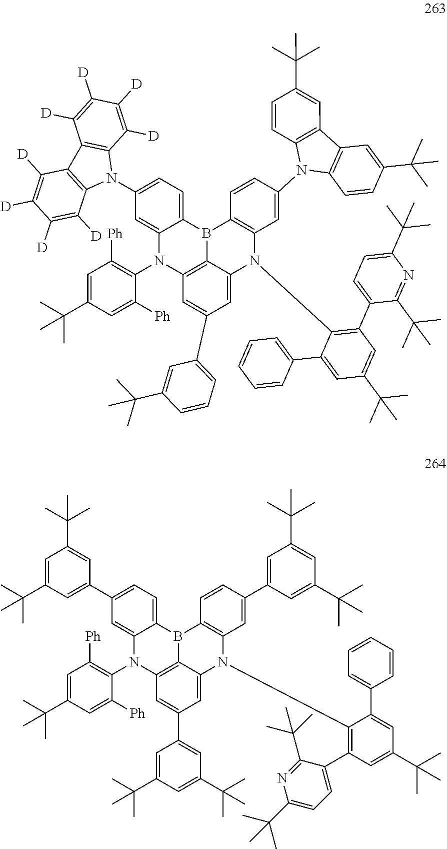
wherein in Compound Group 1,
D represents a deuterium atom,
t-Bu represents an unsubstituted t-butyl group, and
Ph represents an unsubstituted phenyl group.
